(19) United States
(12) Patent Application Publication
(10) Pub. No.: US 2026/0305058 A1
(43) Pub. Date: Oct. 1, 2026

(54) LIGHT EMITTING ELEMENT, FUSED POLYCYCLIC COMPOUND FOR LIGHT EMITTING ELEMENT, AND ELECTRONIC APPARATUS INCLUDING THE LIGHT EMITTING ELEMENT

(71) Applicant: Samsung Display Co., LTD., Yongin-si (KR)

(72) Inventors: Yuta KAWANO, Yokohama-shi (JP); Yuuki MIYAZAKI, Yokohama-shi (JP)

(21) Appl. No.: 19/453,159

(22) Filed: Jan. 20, 2026

(30) Foreign Application Priority Data
Mar. 19, 2025 (JP) 2025-044563

(51) Int. Cl. H10K 50/11; H10K 59/38; H10K 85/60; H10K 102/00

(52) U.S. Cl. CPC H10K 50/11; H10K 59/38; H10K 85/626; H10K 85/633; H10K 85/636; H10K 85/6572; H10K 85/6574; H10K 85/658; H10K 2102/331

(57) ABSTRACT

Provided is a light-emitting element including a first electrode, a second electrode disposed on the first electrode, an emission layer disposed between the first electrode and the second electrode, wherein the emission layer includes a first compound represented by Formula 1. Therefore, the light-emitting element may exhibit high emission efficiency.

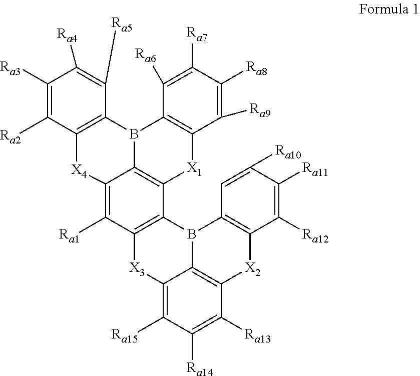

wherein the substituent groups of Formula 1 are as defined herein.

### CROSS-REFERENCE TO RELATED APPLICATIONS

This application claims priority to and the benefit of Japanese Patent Application No. 2025-044563, filed on Mar. 19, 2025, and all the benefits accruing therefrom under 35 U.S.C. § 119, the entire content of which is hereby incorporated by reference.

### BACKGROUND

The present disclosure relates to a light-emitting element, a fused polycyclic compound used in a light-emitting element, and an electronic apparatus including the light-emitting element.

Recently, developments of an organic electroluminescence display device or the like as an image display device have been actively conducted. The organic electroluminescence display device or the like is a display device including a so-called self-luminous-type light-emitting element, in which holes and electrons respectively injected from a first electrode and a second electrode recombine in an emission layer, thereby causing an emission material in the emission layer to emit light, and thereby to implement a display.

For application of a light-emitting element to a display device, improvements in efficiency and the like are required, and development of materials for the light-emitting element, which may stably achieve the requirements, is increasingly demanded.

### SUMMARY

The present disclosure provides a light-emitting element with improved emission efficiency and an electronic apparatus including the same.

The present disclosure also provides a fused polycyclic compound which is a material for a light-emitting element and improves emission efficiency.

An aspect provides a light-emitting element including a first electrode, a second electrode disposed on the first electrode, an emission layer disposed between the first electrode and the second electrode, wherein the emission layer includes a first compound represented by Formula 1.

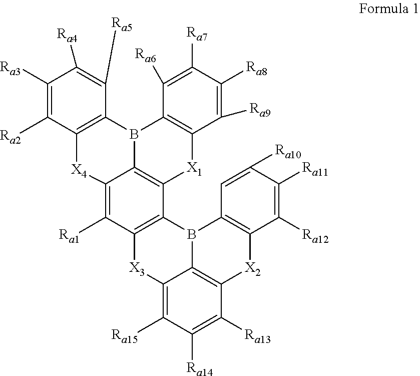

In Formula 1, X₁ to X₄ are each independently O, S, or NRₙ, wherein at least one of X₁ to X₄ is NRₙ, each Rₙ is independently a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, E_{w}, or a group represented by Formula 2, each E_{w} is independently a fluorine atom, a cyano group, a nitro group, a trifluoromethyl group, a substituted or unsubstituted formyl group, a substituted or unsubstituted pyridine group, a substituted or unsubstituted pyrimidine group, a substituted or unsubstituted pyrazole group, or a substituted or unsubstituted triazine group, Rₐ₁ to Rₐ₉ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w}, adjacent two or more of Rₐ₂ to Rₐ₉ are optionally bonded together to form a ring, and Rₐ₁₀ to Rₐ₁₅ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

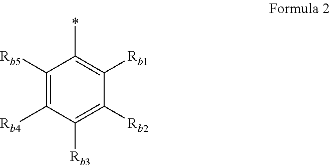

In Formula 2, R_{b1} to R_{b5} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w}, the first compound optionally includes a deuterium atom, wherein, the first compound satisfies at least one of Condition 1 to 3:

### Condition 1

at least one of Rₙ is E_{w},

### Condition 2

at least one of Rₙ is represented by Formula 2 and, and
at least one of R_{b1} to R_{b5} is E_{w},

### Condition 3

at least one of Rₐ₁ to Rₐ₉ is E_{w}.

In an embodiment, the emission layer may further include at least one of a second compound represented by Formula HT-1, a third compound represented by Formula ET-1, or a fourth compound represented by Formula D-1.

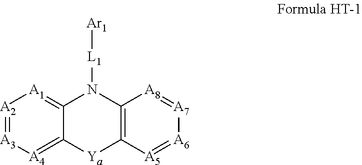

In Formula HT-1, A₁ to A₈ may be each independently N or CR₅₁, L₁ may be a direct linkage, a substituted or unsubstituted arylene group having 6 to 30 ring-forming carbon atoms, or a substituted or unsubstituted heteroarylene group having 2 to 30 ring-forming carbon atoms, Ya may be a direct linkage, CR₅₂R₅₃, or SiR₅₄R₅₅, Ar₁ may be a substituted or unsubstituted aryl group having 6 to 30 ring-forming carbon atoms, or a substituted or unsubstituted heteroaryl group having 2 to 30 ring-forming carbon atoms, R₅₁ to R₅₅ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or R₅₁ to R₅₅ are optionally bonded to an adjacent group to form a ring.

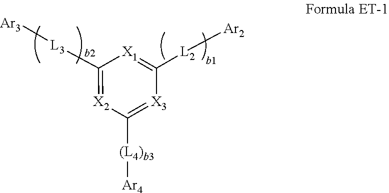

In Formula ET-1, X₁ to X₃ are each independently N or CR₅₆, wherein at least one of X₁ to X₃ is N, R₅₆ may each independently be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may be each independently an integer of 0 to 10, Ar₂ to Ar₄ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L₂ to L₄ may be each independently a direct linkage, a substituted or unsubstituted arylene group having 6 to 30 ring-forming carbon atoms, or a substituted or unsubstituted heteroarylene group having 2 to 30 ring-forming carbon atoms.

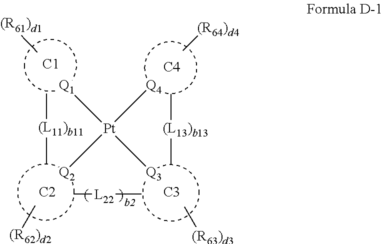

In Formula D-1, Q₁ to Q₄ may be each independently C or N, ring C1 to ring C4 may be each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms, L₁₁ to L₁₃ may be each independently a direct linkage, *—O—*, *—S—*,

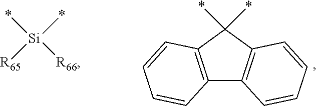

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 may be each independently 0 or 1, R₆₁ to R₆₆ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may be each independently an integer of 0 to 4.

In an embodiment, Formula 1 may be represented by one of Formula 1-A1 to Formula 1-A5:

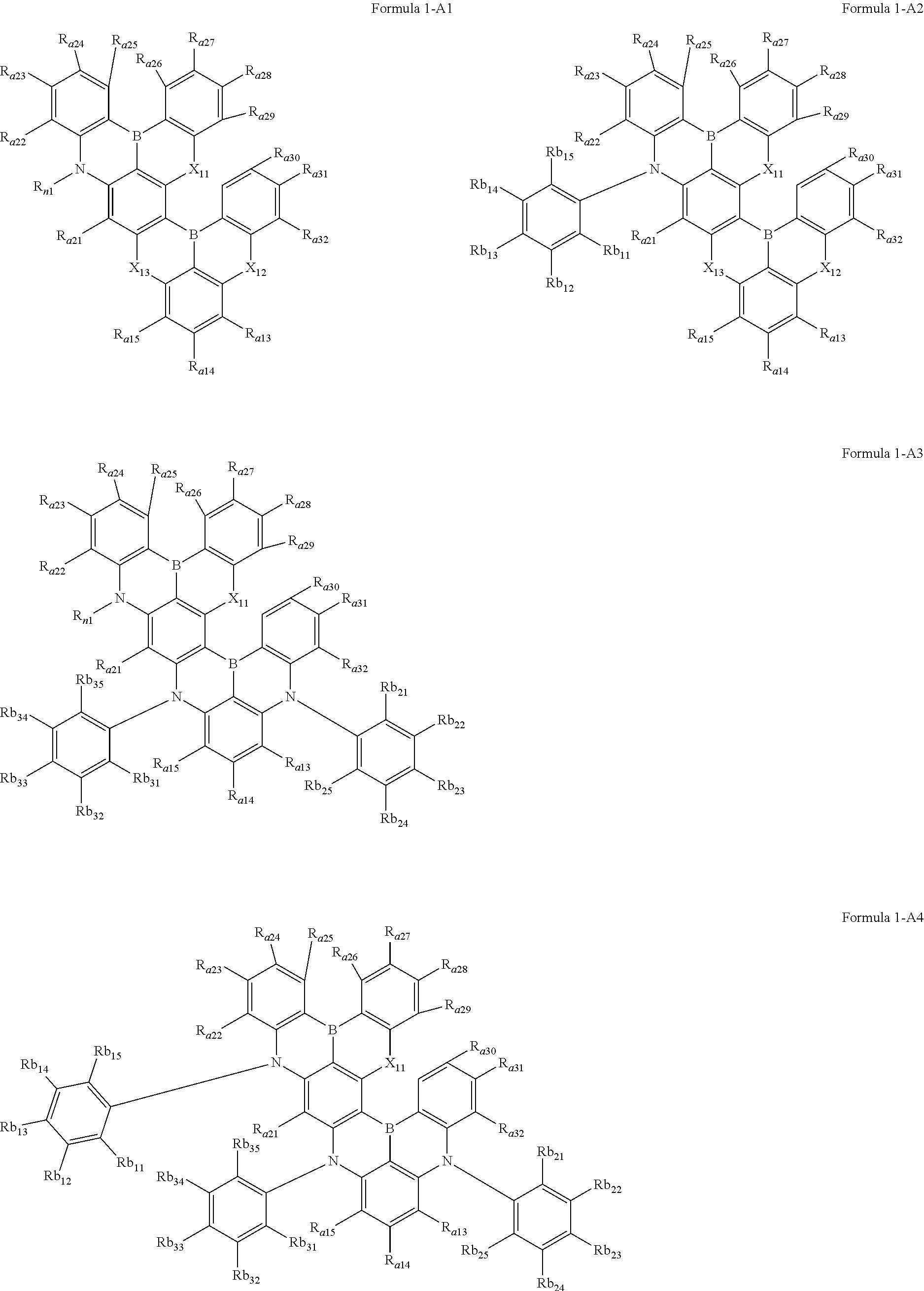

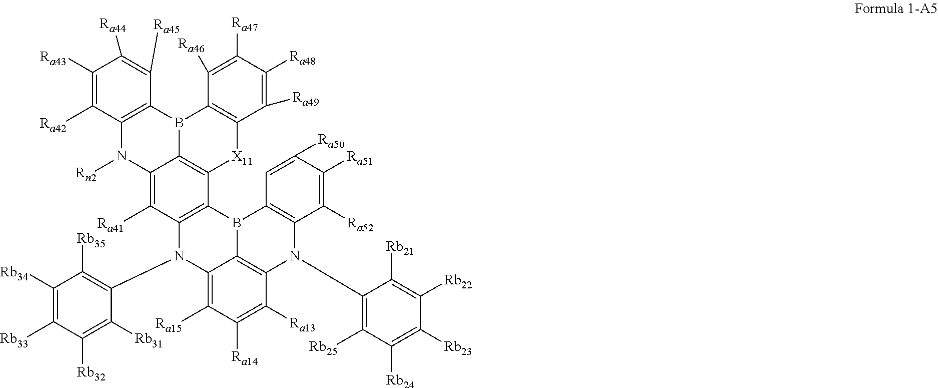

In Formula 1-A1 and Formula 1-A3, Rₙ₁ may be E_{w}, in Formula 1-A2 and Formula 1-A₄, at least one of R_{b11} to R_{b15} may be E_{w}, and the others may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, in Formula 1-A5, Rₙ₂ may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, at least one among Rₐ₄₁ to Rₐ₄₉ may be E_{w}, and the others may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, Rₐ₅₀ to Rₐ₅₂ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, in Formula 1-A1 to Formula 1-A5, X₁₁ to X₁₃ may be each independently O or S, Rₐ₂₁ to Rₐ₃₂ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, R_{b21} to R_{b25}, and R_{b31} to R_{b35} may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Rₐ₁₃ to Rₐ₁₅ may be the same as defined in Formula 1.

In an embodiment, Formula 1-A4 above may be represented by one of Formula 1-A41 to Formula 1-A43.

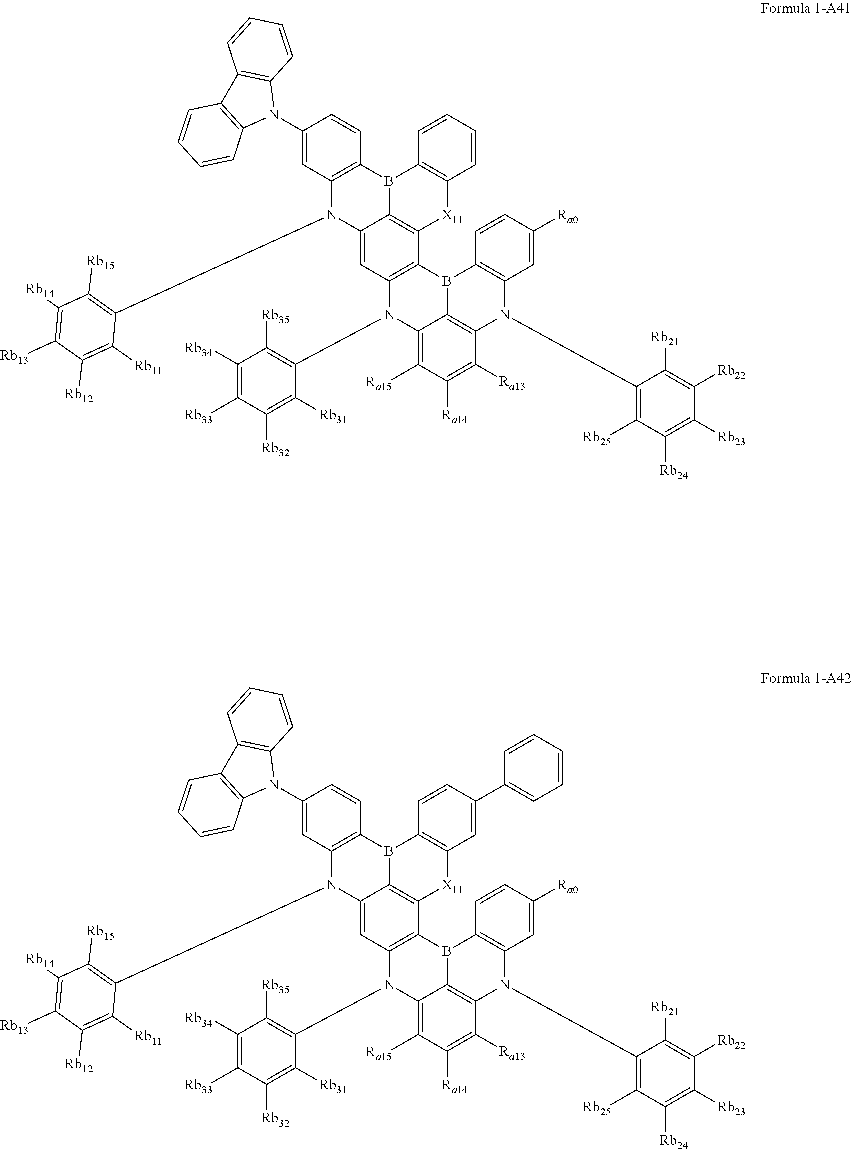

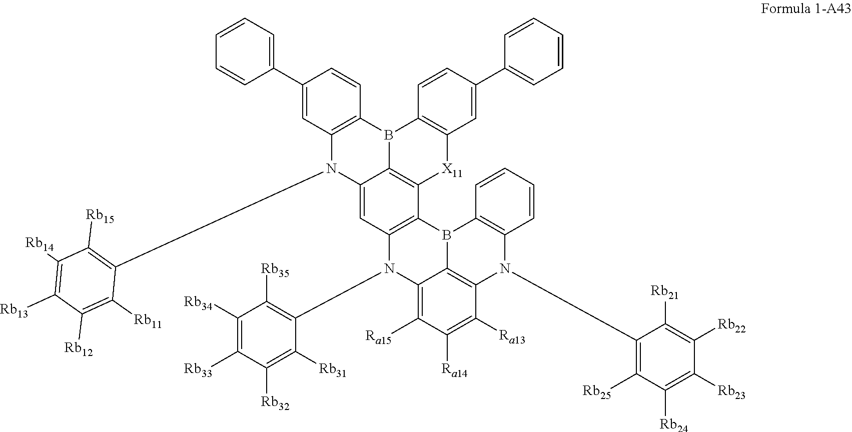

In Formula 1-A41 to Formula 1-A43, Ra₀ may be a hydrogen atom, a deuterium atom, or a substituted or unsubstituted phenyl group. Rₐ₁₃ to Rₐ₁₅, R_{b11} to R_{b15}, R_{b21} to R_{b25}, R_{b31} to R_{b35}, and X₁₁ may be the same as defined in Formula 1-A4.

In an embodiment, in Formula 1-A2 and Formula 1-A4, a first cyclic group including R_{b11} to R_{b15} may be represented by one of R1-B1 to R1-B144:

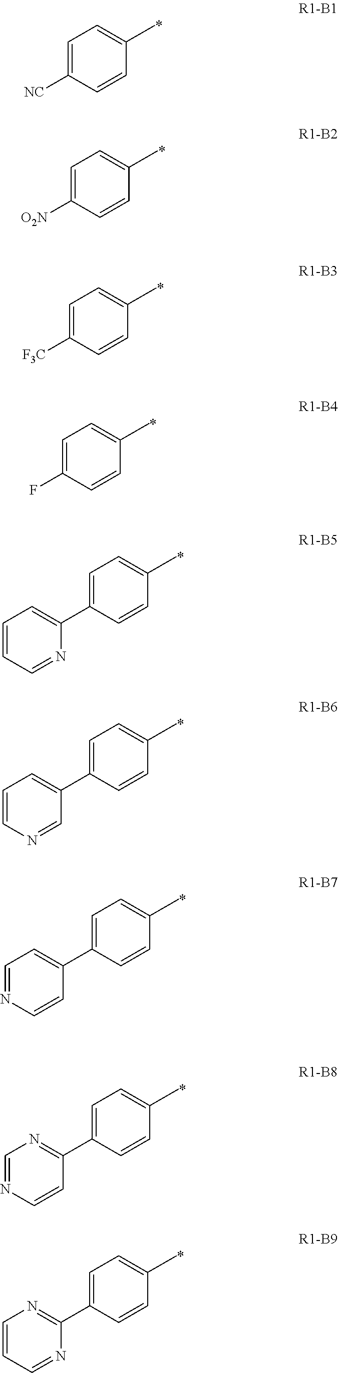

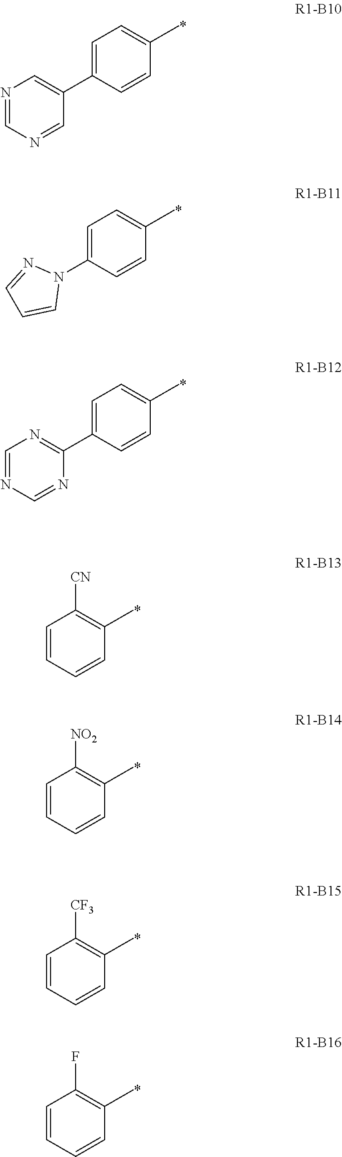

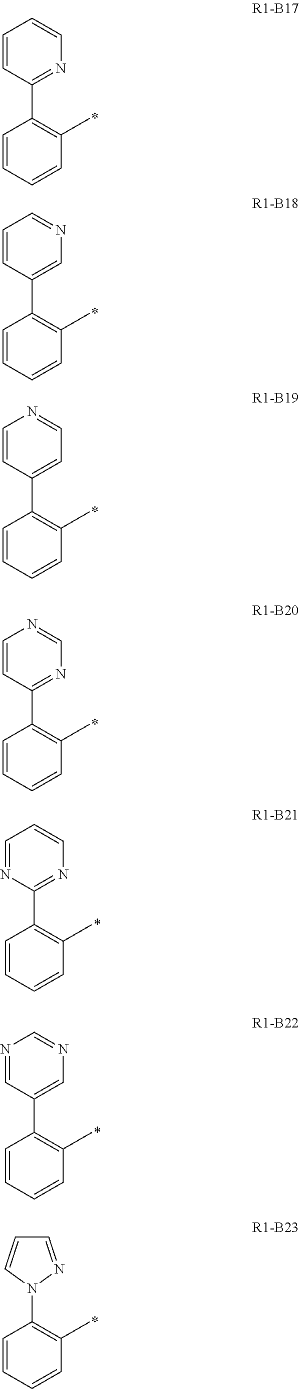

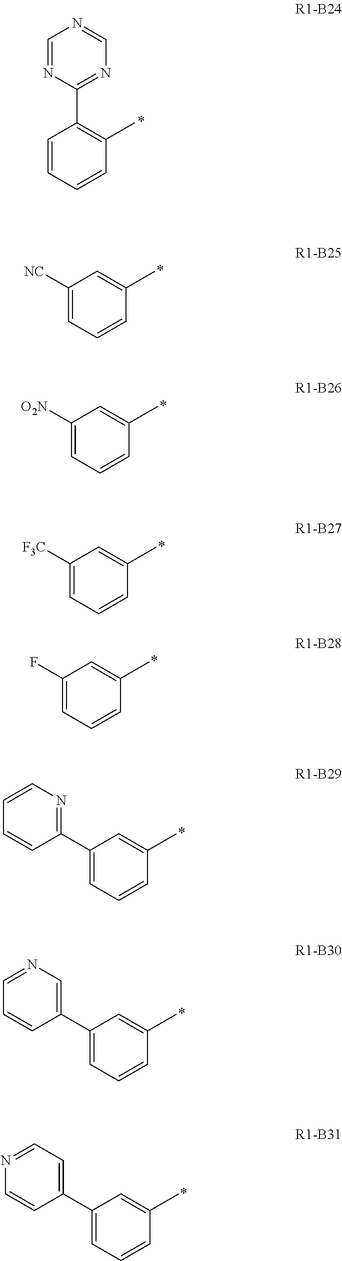

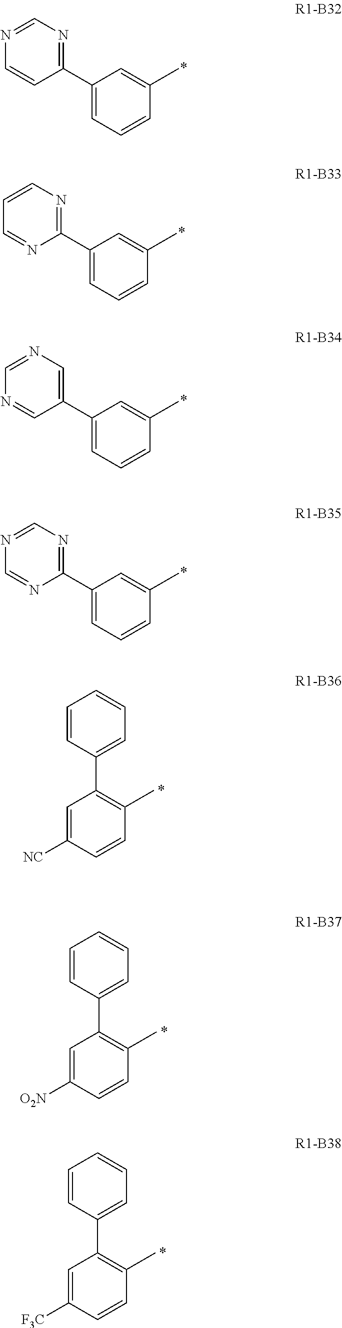

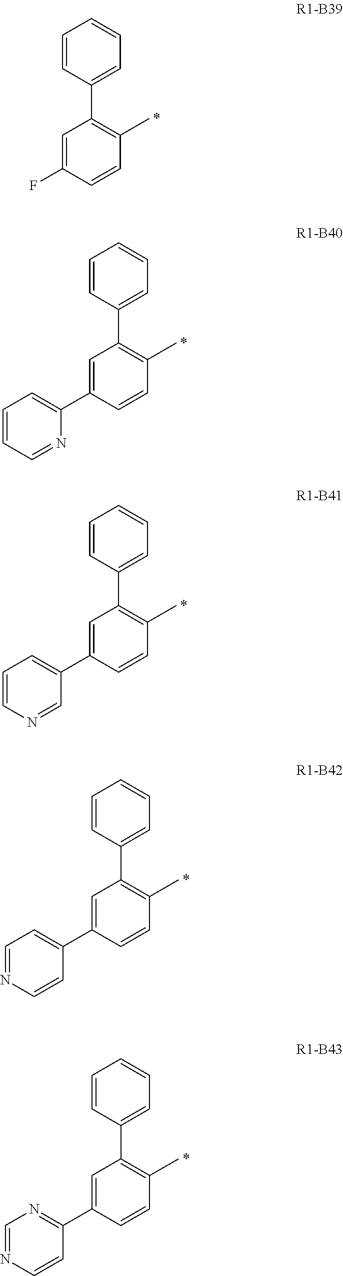 [SMILES: Cc1ccc(F)cc1-c1ccccc1 ; Cc1ccc(-c2ccccn2)cc1-c1ccccc1 ; Cc1ccc(-c2cccnc2)cc1-c1ccccc1 ; Cc1ccc(-c2ccncc2)cc1-c1ccccc1 ; Cc1ccc(-c2ccncn2)cc1-c1ccccc1]

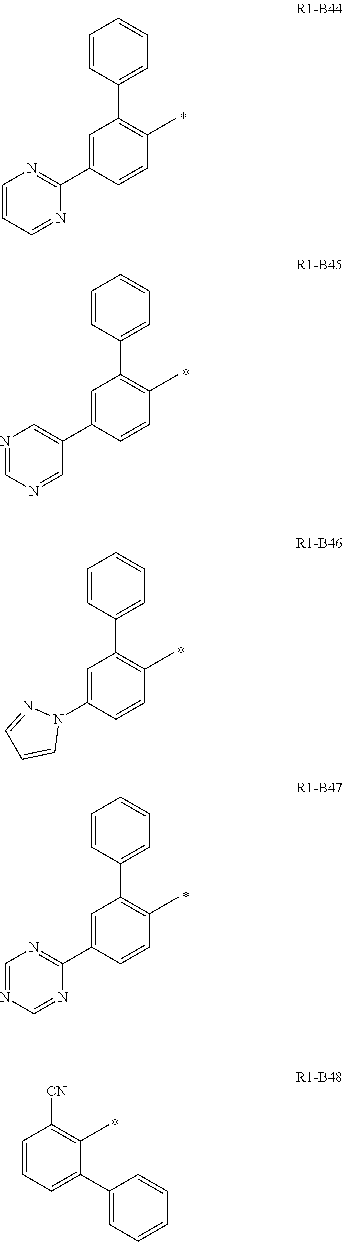 [SMILES: Cc1ccc(-c2ncccn2)cc1-c1ccccc1 ; Cc1ccc(-c2cncnc2)cc1-c1ccccc1 ; Cc1ccc(-n2cccn2)cc1-c1ccccc1 ; Cc1ccc(-c2ncncn2)cc1-c1ccccc1 ; Cc1c(C#N)cccc1-c1ccccc1]

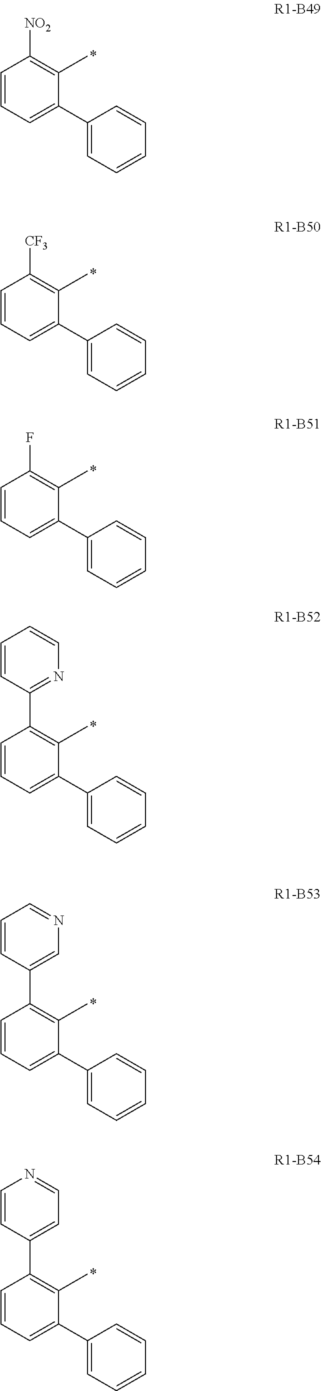 [SMILES: Cc1c(-c2ccccc2)cccc1[N+](=O)[O-] ; Cc1c(-c2ccccc2)cccc1C(F)(F)F ; Cc1c(F)cccc1-c1ccccc1 ; Cc1c(-c2ccccc2)cccc1-c1ccccn1 ; Cc1c(-c2ccccc2)cccc1-c1cccnc1 ; Cc1c(-c2ccccc2)cccc1-c1ccncc1]

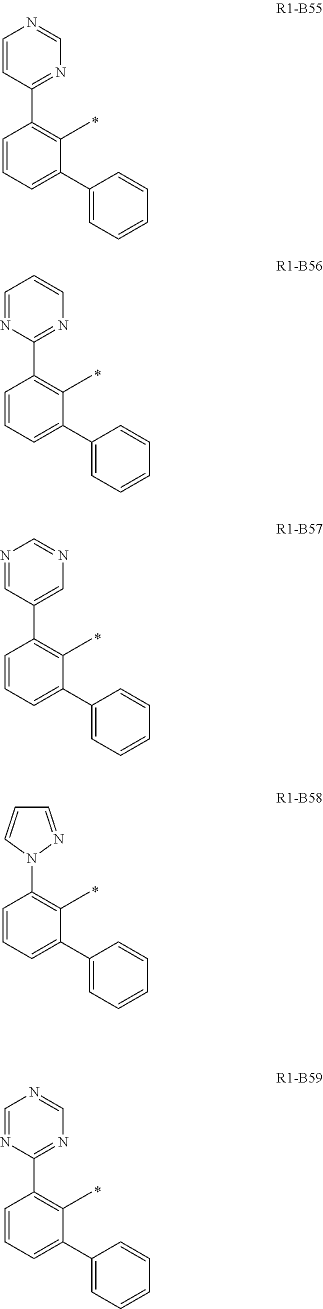 [SMILES: Cc1c(-c2ccccc2)cccc1-c1ccncn1 ; Cc1c(-c2ccccc2)cccc1-c1ncccn1 ; Cc1c(-c2ccccc2)cccc1-c1cncnc1 ; Cc1c(-c2ccccc2)cccc1-n1cccn1 ; Cc1c(-c2ccccc2)cccc1-c1ncncn1]

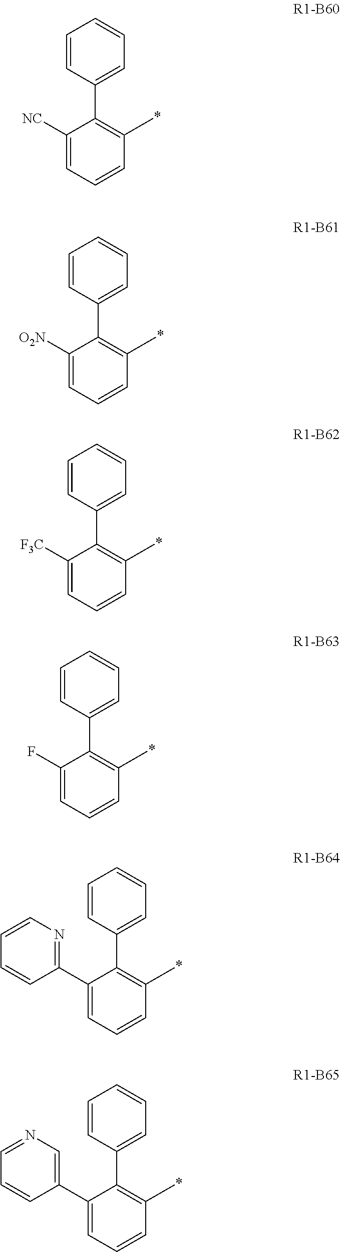

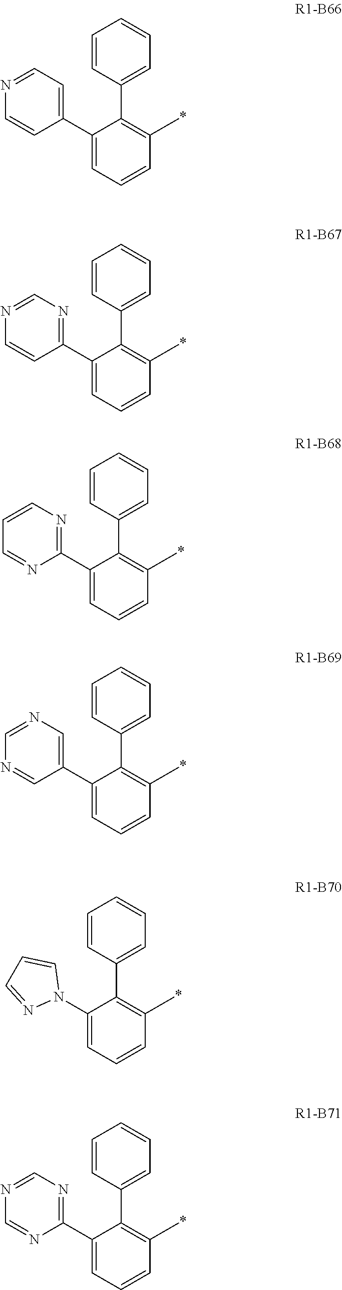

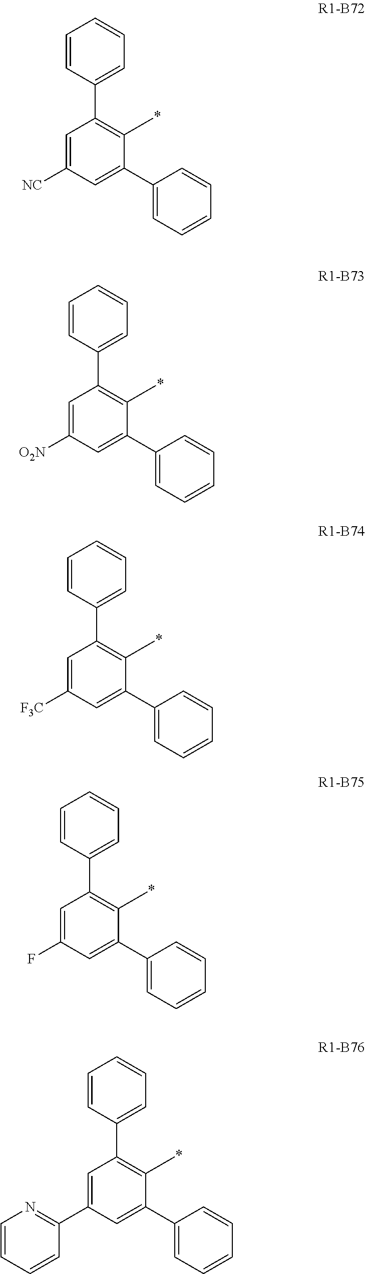 [SMILES: Cc1c(-c2ccccc2)cc(C#N)cc1-c1ccccc1 ; Cc1c(-c2ccccc2)cc([N+](=O)[O-])cc1-c1ccccc1 ; Cc1c(-c2ccccc2)cc(C(F)(F)F)cc1-c1ccccc1 ; Cc1c(-c2ccccc2)cc(F)cc1-c1ccccc1 ; Cc1c(-c2ccccc2)cc(-c2ccccn2)cc1-c1ccccc1]

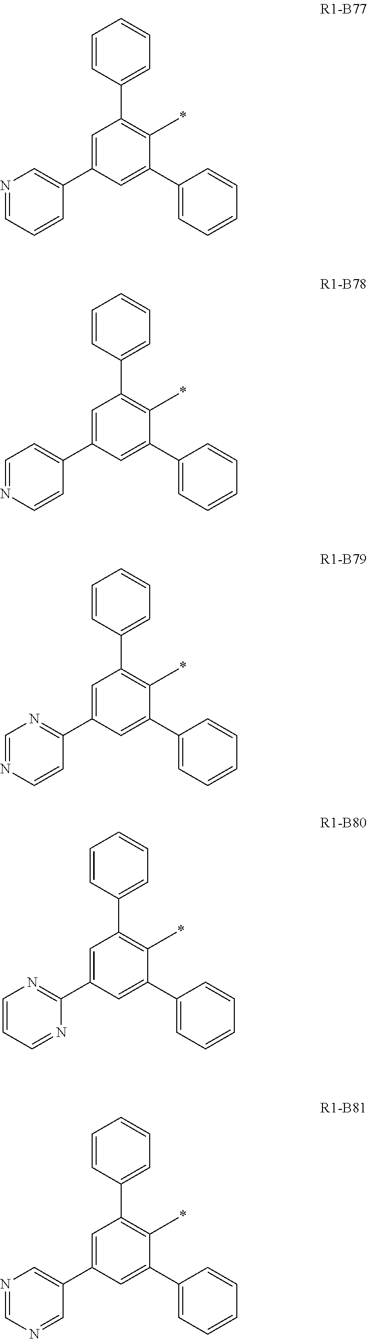 [SMILES: Cc1c(-c2ccccc2)cc(-c2cccnc2)cc1-c1ccccc1 ; Cc1c(-c2ccccc2)cc(-c2ccncc2)cc1-c1ccccc1 ; Cc1c(-c2ccccc2)cc(-c2ccncn2)cc1-c1ccccc1 ; Cc1c(-c2ccccc2)cc(-c2ncccn2)cc1-c1ccccc1 ; Cc1c(-c2ccccc2)cc(-c2cncnc2)cc1-c1ccccc1]

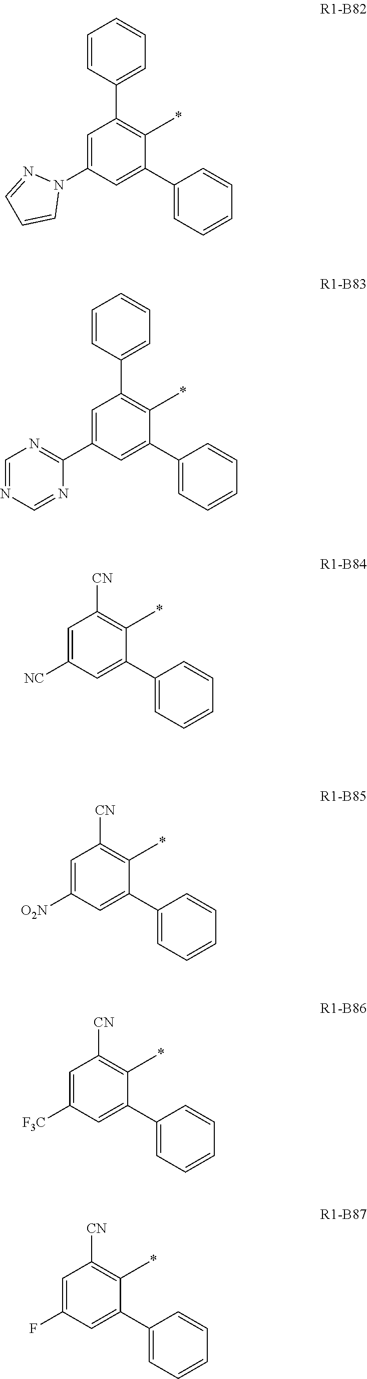 [SMILES: Cc1c(-c2ccccc2)cc(-n2cccn2)cc1-c1ccccc1 ; Cc1c(-c2ccccc2)cc(-c2ncncn2)cc1-c1ccccc1 ; Cc1c(C#N)cc(C#N)cc1-c1ccccc1 ; Cc1c(C#N)cc([N+](=O)[O-])cc1-c1ccccc1 ; Cc1c(C#N)cc(C(F)(F)F)cc1-c1ccccc1 ; Cc1c(C#N)cc(F)cc1-c1ccccc1]

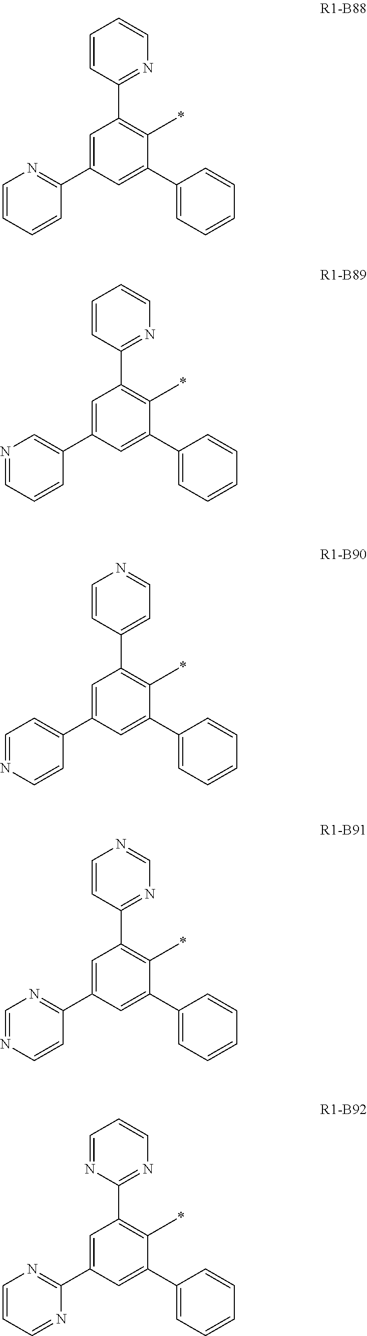 [SMILES: Cc1c(-c2ccccc2)cc(-c2ccccn2)cc1-c1ccccn1 ; Cc1c(-c2ccccc2)cc(-c2cccnc2)cc1-c1ccccn1 ; Cc1c(-c2ccccc2)cc(-c2ccncc2)cc1-c1ccncc1 ; Cc1c(-c2ccccc2)cc(-c2ccncn2)cc1-c1ccncn1 ; Cc1c(-c2ccccc2)cc(-c2ncccn2)cc1-c1ncccn1]

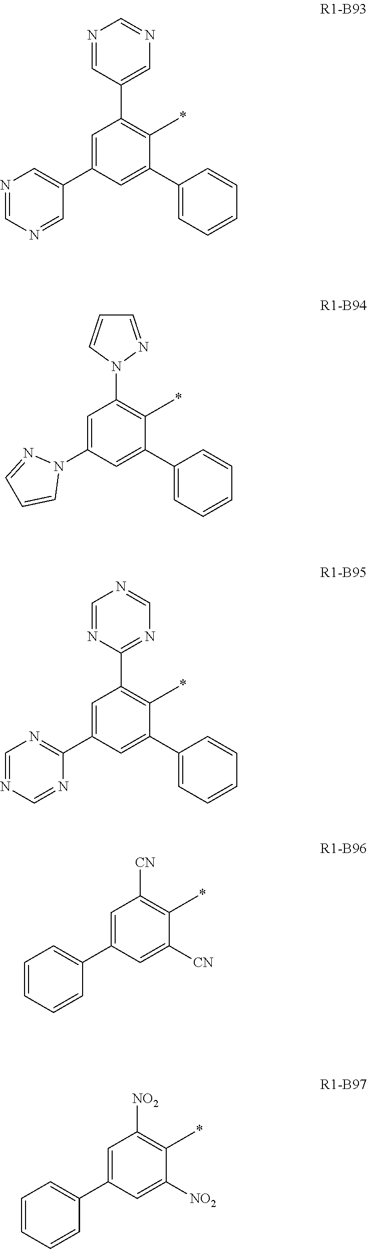 [SMILES: Cc1c(-c2ccccc2)cc(-c2cncnc2)cc1-c1cncnc1 ; Cc1c(-c2ccccc2)cc(-n2cccn2)cc1-n1cccn1 ; Cc1c(-c2ccccc2)cc(-c2ncncn2)cc1-c1ncncn1 ; Cc1c(C#N)cc(-c2ccccc2)cc1C#N ; Cc1c([N+](=O)[O-])cc(-c2ccccc2)cc1[N+](=O)[O-]]

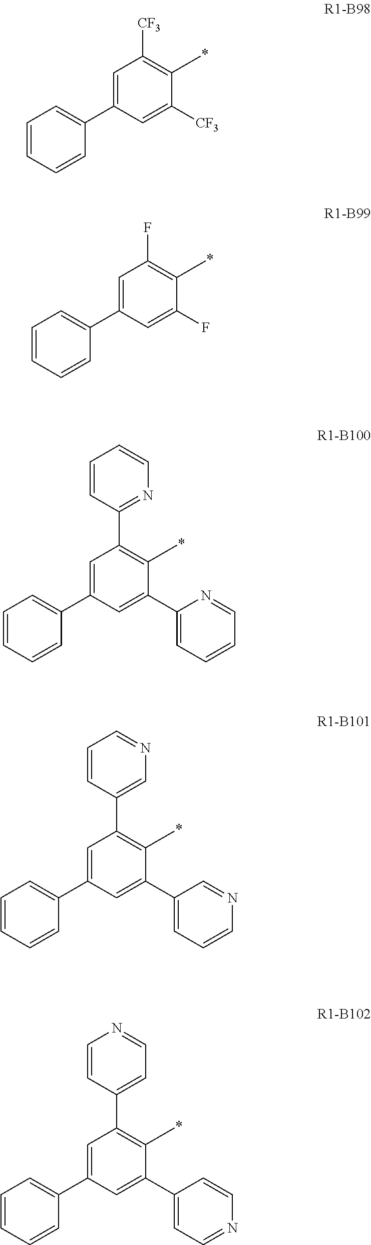 [SMILES: Cc1c(C(F)(F)F)cc(-c2ccccc2)cc1C(F)(F)F ; Cc1c(F)cc(-c2ccccc2)cc1F ; Cc1c(-c2ccccn2)cc(-c2ccccc2)cc1-c1ccccn1 ; Cc1c(-c2cccnc2)cc(-c2ccccc2)cc1-c1cccnc1 ; Cc1c(-c2ccncc2)cc(-c2ccccc2)cc1-c1ccncc1]

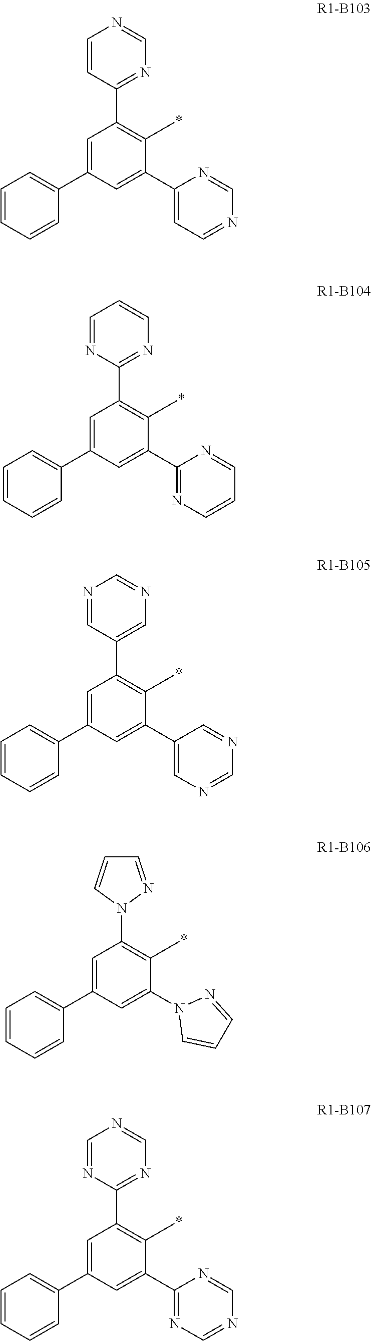 [SMILES: Cc1c(-c2ccncn2)cc(-c2ccccc2)cc1-c1ccncn1 ; Cc1c(-c2ncccn2)cc(-c2ccccc2)cc1-c1ncccn1 ; Cc1c(-c2cncnc2)cc(-c2ccccc2)cc1-c1cncnc1 ; Cc1c(-n2cccn2)cc(-c2ccccc2)cc1-n1cccn1 ; Cc1c(-c2ncncn2)cc(-c2ccccc2)cc1-c1ncncn1]

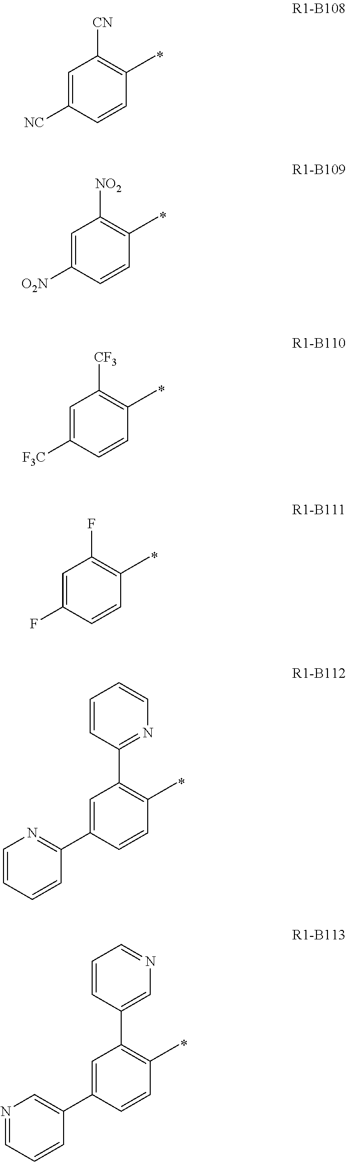

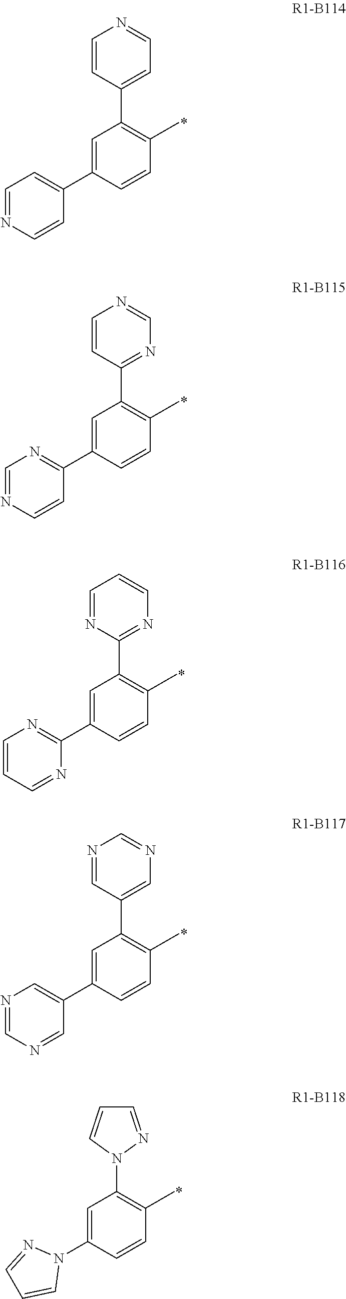 [SMILES: Cc1ccc(-c2ccncc2)cc1-c1ccncc1 ; Cc1ccc(-c2ccncn2)cc1-c1ccncn1 ; Cc1ccc(-c2ncccn2)cc1-c1ncccn1 ; Cc1ccc(-c2cncnc2)cc1-c1cncnc1 ; Cc1ccc(-n2cccn2)cc1-n1cccn1]

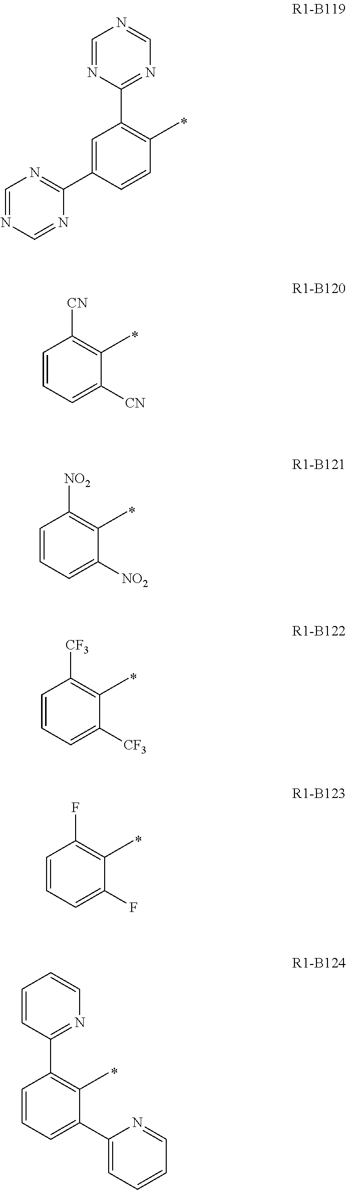

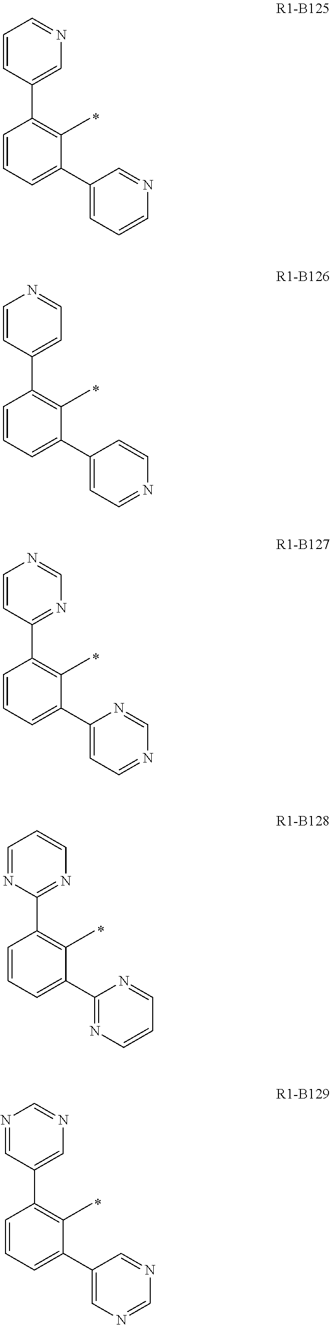 [SMILES: Cc1c(-c2cccnc2)cccc1-c1cccnc1 ; Cc1c(-c2ccncc2)cccc1-c1ccncc1 ; Cc1c(-c2ccncn2)cccc1-c1ccncn1 ; Cc1c(-c2ncccn2)cccc1-c1ncccn1 ; Cc1c(-c2cncnc2)cccc1-c1cncnc1]

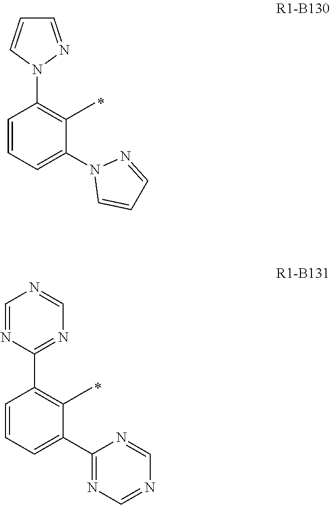 [SMILES: Cc1c(-n2cccn2)cccc1-n1cccn1 ; Cc1c(-c2ncncn2)cccc1-c1ncncn1]

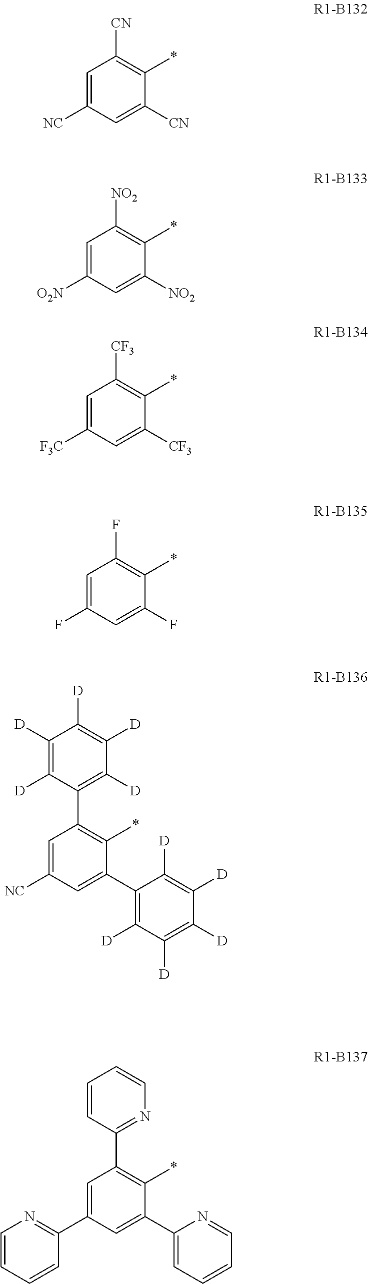 [SMILES: *c1c(C#N)cc(C#N)cc1C#N ; *c1c([N+](=O)[O-])cc([N+](=O)[O-])cc1[N+](=O)[O-] ; *c1c(C(F)(F)F)cc(C(F)(F)F)cc1C(F)(F)F ; *c1c(F)cc(F)cc1F ; *c1c(-c2c([2H])c([2H])c([2H])c([2H])c2[2H])cc(C#N)cc1-c1c([2H])c([2H])c([2H])c([2H])c1[2H] ; *c1c(-c2ccccn2)cc(-c2ccccn2)cc1-c1ccccn1]

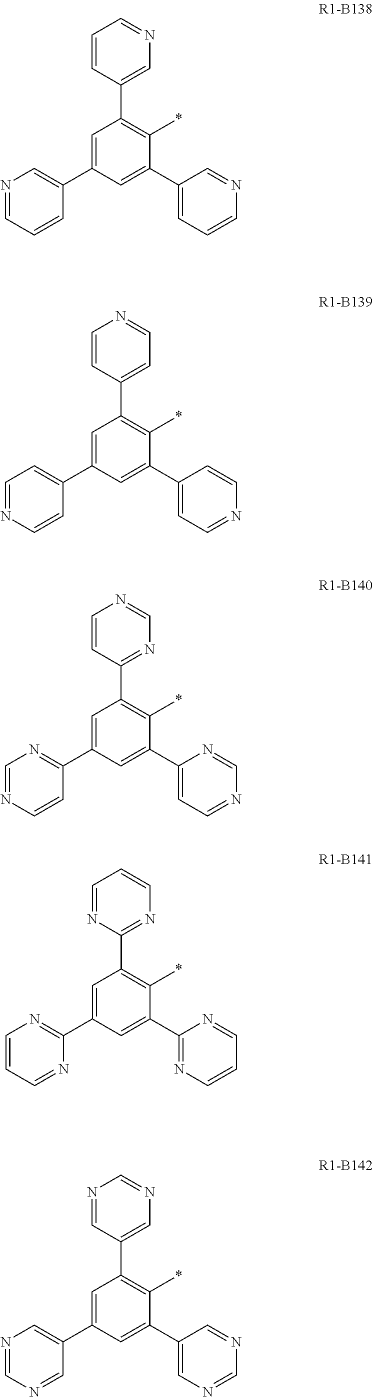 [SMILES: *c1c(-c2cccnc2)cc(-c2cccnc2)cc1-c1cccnc1 ; *c1c(-c2ccncc2)cc(-c2ccncc2)cc1-c1ccncc1 ; *c1c(-c2ccncn2)cc(-c2ccncn2)cc1-c1ccncn1 ; *c1c(-c2ncccn2)cc(-c2ncccn2)cc1-c1ncccn1 ; *c1c(-c2cncnc2)cc(-c2cncnc2)cc1-c1cncnc1]

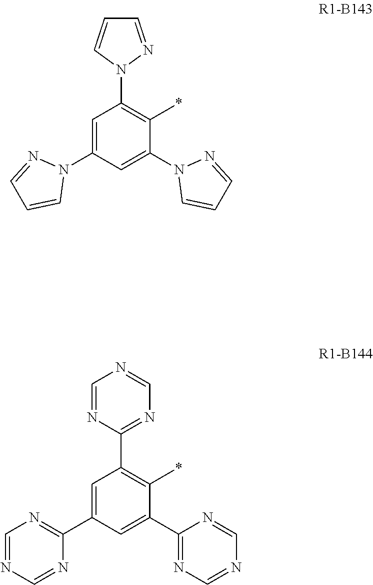 [SMILES: *c1c(-n2cccn2)cc(-n2cccn2)cc1-n1cccn1 ; *c1c(-c2ncncn2)cc(-c2ncncn2)cc1-c1ncncn1]

In R1-B136, D is a deuterium atom.

In an embodiment, in Formula 1-A3 to Formula 1-A5, a second cyclic group including R_{b21} to R_{b25}, and a third cyclic group including R_{b31} to R_{b35} may be each independently represented by one of R2-B1 to R2-B4:

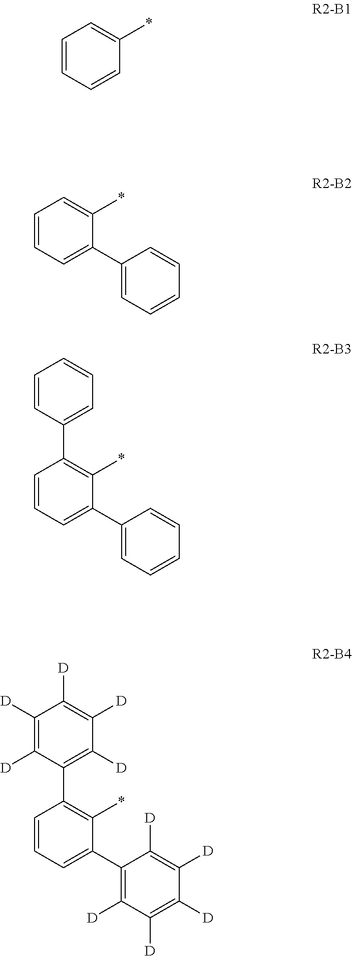 [SMILES: *c1ccccc1 ; *c1ccccc1-c1ccccc1 ; *c1c(-c2ccccc2)cccc1-c1ccccc1 ; *c1c(-c2c([2H])c([2H])c([2H])c([2H])c2[2H])cccc1-c1c([2H])c([2H])c([2H])c([2H])c1[2H]]

In R2-B4, D is a deuterium atom.

In an embodiment, Formula 1 may be represented by Formula 1-B.

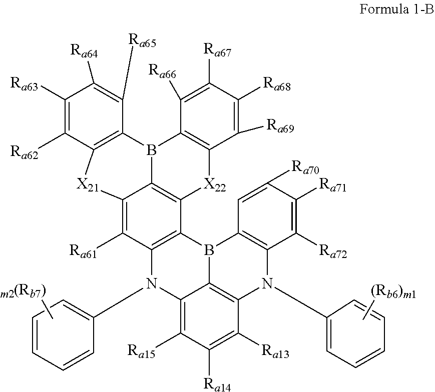

In Formula 1-B, X₂₁ and X₂₂ are each independently O, S, or NRₙ₃, wherein at least one among X₂₁ and X₂₂ is NRₙ₃, each Rₙ₃ may independently be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, E_{w}, or may be a group represented by Formula 2, m1 and m2 may be each independently an integer of 0 to 5, R_{b6} and R_{b7} may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w}, Rₐ₆₁ to Rₐ₆₉ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w}, Rₐ₇₀ to Rₐ₇₂ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, at least one among Rₙ₃, R_{b6}, R_{b7}, and Rₐ₆₁ to Rₐ₆₉ may include E_{w}. Rₐ₁₃ to Rₐ₁₅ may be the same as defined in Formula 1.

In an embodiment, in Formula 1, Rₐ₁₃ to Rₐ₁₅ may be each independently a hydrogen atom, a deuterium atom, a halogen atom, or a substituted or unsubstituted t-butyl group.

In an embodiment, a fused polycyclic compound is represented by Formula 1.

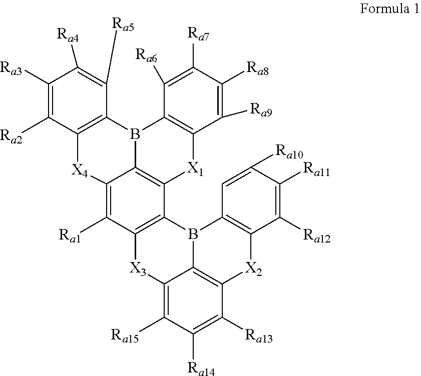

In Formula 1, X₁ to X₄ are each independently O, S, or NRₙ, wherein at least one of X₁ to X₄ is NRₙ, each Rₙ is independently a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, E_{w}, or a group represented by Formula 2, each E_{w} is independently a fluorine atom, a cyano group, a nitro group, a trifluoromethyl group, a substituted or unsubstituted formyl group, a substituted or unsubstituted pyridine group, a substituted or unsubstituted pyrimidine group, a substituted or unsubstituted pyrazole group, or a substituted or unsubstituted triazine group, Rₐ₁ to Rₐ₉ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w}, adjacent two or more of Rₐ₂ to Rₐ₉ are optionally bonded together to form a ring, and Rₐ₁₀ to Rₐ₁₅ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

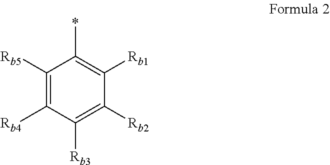

In Formula 2, R_{b1} to R_{b5} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w}, wherein the fused polycyclic compound may include a deuterium atom, and wherein the fused polycyclic compound satisfies at least one of Condition 1 to 3:

### Condition 1

at least one of Rₙ is E_{w},

### Condition 2

at least one of Rₙ is represented by Formula 2, and
at least one of R_{b1} to R_{b5} in Formula 2 is E_{w},

### Condition 3

at least one of Rₐ₁ to Rₐ₉ is E_{w}.

In an embodiment, an electronic apparatus includes a display device which provides an image, the display device includes a base layer, a circuit layer disposed on the base layer, and a display element layer disposed on the circuit layer and including a light-emitting element, the light-emitting element includes a first electrode, a second electrode disposed on the first electrode, and an emission layer disposed between the first electrode and the second electrode, wherein the emission layer includes a fused polycyclic compound represented by Formula 1.

In an embodiment, the electronic apparatus may further include at least one of a light control layer, or a color filter layer, wherein the light control layer may include quantum dots, and the color filter layer may include a pigment or a dye.

In an embodiment, the electronic apparatus may further include at least one of a processor, a memory, or a power module.

### BRIEF DESCRIPTION OF THE FIGURES

The accompanying drawings are included to provide a further understanding of the detailed description, and are incorporated in and constitute a part of this specification. The drawings illustrate embodiments and, together with the detailed description, serve to explain principles of the inventive concept. In the drawings:

FIG. 1 is a plan view illustrating a display device according to an embodiment;

FIG. 2 is a cross-sectional view illustrating a portion taken along line I-I′ in FIG. 1;

FIG. 3 is a cross-sectional view schematically illustrating a light-emitting element according to an embodiment;

FIG. 4 is a cross-sectional view schematically illustrating a light-emitting element according to an embodiment;

FIG. 5 is a cross-sectional view schematically illustrating a light-emitting element according to an embodiment;

FIG. 6 is a cross-sectional view schematically illustrating a light-emitting element according to an embodiment;

FIG. 7 is a cross-sectional view illustrating a display device according to an embodiment;

FIG. 8 is a cross-sectional view illustrating a display device according to an embodiment;

FIG. 9 is a cross-sectional view illustrating a display device according to an embodiment;

FIG. 10 is a cross-sectional view illustrating a display device according to an embodiment;

FIG. 11 is a view illustrating an interior of a vehicle in which a display device according to an embodiment is disposed;

FIG. 12 is a perspective view illustrating an electronic apparatus according to an embodiment;

FIG. 13 is an exploded perspective view illustrating an electronic apparatus according to an embodiment;

FIG. 14 is a block diagram of an electronic apparatus according to an embodiment; and

FIG. 15 illustrates schematic views of electronic apparatuses according to various embodiments.

### DETAILED DESCRIPTION

The accompanying drawings are included to provide a further understanding of the subject matter, and are incorporated in and constitute a part of this detailed description. The subject matter may, however, be embodied in different forms and should not be construed as limited to the embodiments set forth herein. Rather, these embodiments are provided so that this disclosure will be thorough and complete, and will fully convey the scope of the subject matter to those skilled in the art.

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

It will be understood that, although the terms first, second, etc. may be used herein to describe various elements, components, regions, layers and/or sections, these elements, components, regions, layers, and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) as used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the specification, the term “substituted or unsubstituted” may mean substituted or unsubstituted with at least one substituent that is a deuterium atom, a halogen atom, a cyano group, a nitro group, an amine group, an amino group, a silyl group, an oxy group, a thio group, a sulfinyl group, a sulfonyl group, a carbonyl group, a boron group, a selenium group, a phosphine oxide group, a phosphine sulfide group, an alkyl group, an alkenyl group, an alkynyl group, a hydrocarbon ring group, an aryl group, or a heterocyclic group. In addition, each of the substituents exemplified above may be substituted or unsubstituted. For example, a biphenyl group may be interpreted as an aryl group or a phenyl group substituted with a phenyl group.

In the specification, the phrase “bonded to an adjacent group to form a ring” may mean that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by being bonded to each other may be connected to another ring to form a spiro structure.

In the specification, the term “adjacent group” may mean a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbon atoms in the alkyl group may be 1 to 60, 1 to 50, 1 to 30, 1 to 20, 1 to 10, or 1 to 6. Non-limiting examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, or the like, but the embodiments are not limited thereto.

In the specification, a cycloalkyl group may mean a cyclic alkyl group. The number of carbon atoms in the cycloalkyl group may be 3 to 60, 3 to 50, 3 to 30, 3 to 20, or 3 to 10. Non-limiting examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, an adamantyl group, a 1-adamantyl group, a 2-adamantyl group, an isobornyl group, a bicycloheptyl group, or the like, but embodiments are not limited thereto.

In the specification, an alkenyl group means a hydrocarbon group including at least one carbon double bond in the middle or terminal of an alkyl group having 2 or more carbon atoms. The alkenyl group may be linear or branched. The number of carbon atoms in the alkenyl group is not specifically limited, but may be 2 to 60, 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, or the like, but embodiments are not limited thereto.

In the specification, an alkynyl group means a hydrocarbon group including at least one carbon triple bond in the middle or terminal of an alkyl group having 2 or more carbon atoms. The alkynyl group may be linear or branched. Although the number of carbon atoms is not specifically limited, it may be 2 to 30, 2 to 20, or 2 to 10. Specific non-limiting examples of the alkynyl group may include an ethynyl group, a propynyl group, or the like, but embodiments are not limited thereto.

In the specification, the hydrocarbon ring group means any functional group or substituent derived from an aliphatic hydrocarbon ring. The number of ring-forming carbon atoms in the hydrocarbon ring group may be 5 to 60, 5 to 30, or 5 to 20.

In the specification, an aryl group means any functional group or substituent derived from an aromatic hydrocarbon ring. The aryl group may be a monocyclic aryl group or a polycyclic aryl group. The number of ring-forming carbon atoms in the aryl group may be 5 to 60, 6 to 60, 6 to 30, 6 to 20, or 6 to 15. Non-limiting examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, or the like, but embodiments are not limited thereto.

In the specification, the fluorenyl group may be substituted, and two substituents may be bonded to each other to form a spiro structure. Non-limiting examples of the substituted fluorenyl group are as follows. However, embodiments are not limited thereto.

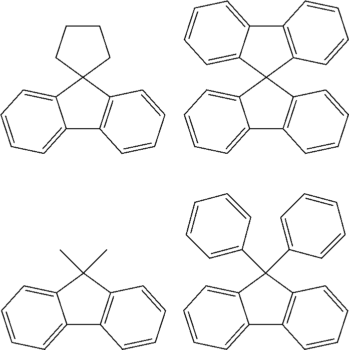

The heterocyclic group herein means any functional group or substituent derived from a ring containing at least one of B, O, N, P, Si, S, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si, S or Se as a heteroatom. If the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 60, 3 to 30, 2 to 30, 2 to 20, or 2 to 10.

In the specification, the aliphatic heterocyclic group may include at least one of B, O, N, P, Si, S, or Se as a heteroatom. The number of ring-forming carbon atoms in the aliphatic heterocyclic group may be 2 to 60, 3 to 30, 2 to 30, 2 to 20, or 2 to 10. Non-limiting examples of the aliphatic heterocyclic group may include an oxirane group, a thiirane group, a pyrrolidine group, a piperidine group, a tetrahydrofuran group, a tetrahydrothiophene group, a thiane group, a tetrahy dropyran group, a 1,4-dioxane group, or the like, but embodiments are not limited thereto.

In the specification, the heteroaryl group may contain at least one of B, O, N, P, Si, S or Se as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 3 to 30, 2 to 30, 2 to 20, or 2 to 10. Non-limiting examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, or the like, but embodiments are not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the silyl group includes an alkylsilyl group and an arylsilyl group. Non-limiting examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, or the like, but embodiments are not limited thereto.

In the specification, the number of ring-forming carbon atoms in the carbonyl group is not specifically limited, but may be 1 to 40, 1 to 30, or 1 to 20. For example, the carbonyl group may have the following structures, but embodiments are not limited thereto.

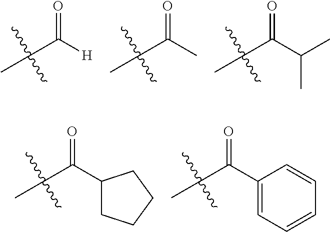

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may mean that a sulfur atom is bonded to the alkyl group or the aryl group as defined above. Non-limiting examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, or the like, but embodiments are not limited thereto.

In the specification, an oxy group may mean that an oxygen atom is bonded to the alkyl group or the aryl group as defined above. The oxy group may include an alkoxy group and an aryl oxy group. The alkoxy group may be a linear chain, a branched chain, or a ring chain. The number of carbon atoms in the alkoxy group is not specifically limited, but may be, for example, 1 to 20 or 1 to 10. Non-limiting examples of the oxy group may include methoxy, ethoxy, n-propoxy, isopropoxy, butoxy, pentyloxy, hexyloxy, octyloxy, nonyloxy, decyloxy, benzyloxy, or the like, but embodiments are not limited thereto.

The boron group herein may mean that a boron atom is bonded to the alkyl group or the aryl group as defined above. The boron group includes an alkyl boron group and an aryl boron group. Non-limiting examples of the boron group may include a dimethylboron group, a diethylboron group, a t-butylmethylboron group, a diphenylboron group, a phenylboron group, or the like, but embodiments are not limited thereto.

In the specification, the number of carbon atoms in an amine group is not specifically limited, but may be 1 to 50, 1 to 30, or 1 to 20. The amine group may include an alkyl amine group and an aryl amine group. Non-limiting examples of the amine group may include a methylamine group, a dimethylamine group, a phenylamine group, a diphenylamine group, a naphthylamine group, a 9-methyl-anthracenylamine group, or the like, but embodiments are not limited thereto.

In the specification, a selenium (Se) group may include an alkyl selenium group and an aryl selenium group. The selenium group may mean a group in which a selenium atom is bonded to the above-defined alkyl group or aryl group. Non-limiting examples of the selenium group may include a methyl selenium group, an ethyl selenium group, a propyl selenium group, a pentyl selenium group, a hexyl selenium group, an octyl selenium group, a dodecyl selenium group, a cyclopentyl selenium group, a cyclohexyl selenium group, a phenyl selenium group, a naphthyl selenium group, or the like. However, embodiments are not limited thereto.

In the specification, the alkyl group among an alkylthio group, an alkylsulfoxy group, an alkylaryl group, an alkylamino group, an alkyl boron group, an alkyl silyl group, an alkyl amine group, and an alkyl selenium group is the same as the examples of the alkyl group described above.

In the specification, the aryl group among an aryloxy group, an arylthio group, an arylsulfoxy group, an arylamino group, an arylboron group, an arylsilyl group, an arylamine group, and an aryl selenium group is the same as the examples of the aryl group described above.

In the specification, a direct linkage may mean a single bond. In the specification,

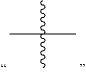

and “-*” mean a position to be connected.

Hereinafter, embodiments will be described in further detail with reference to the accompanying drawings.

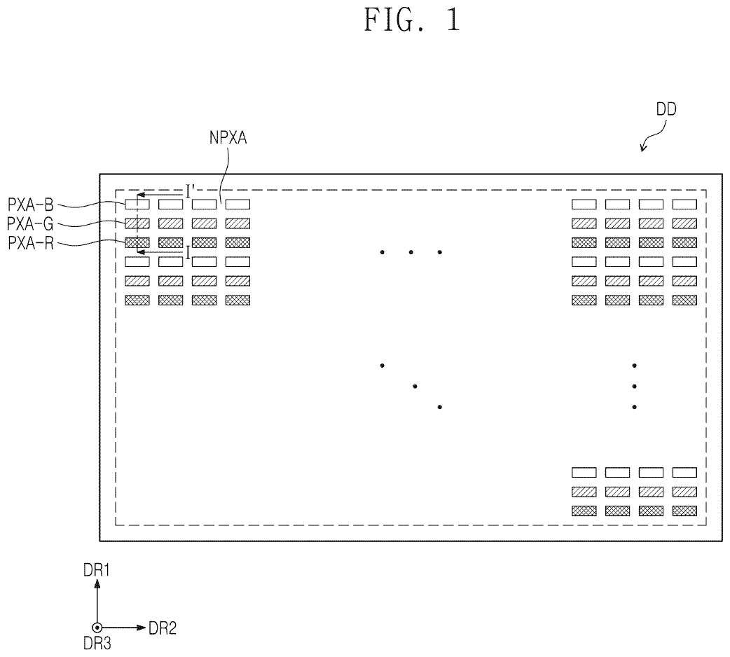

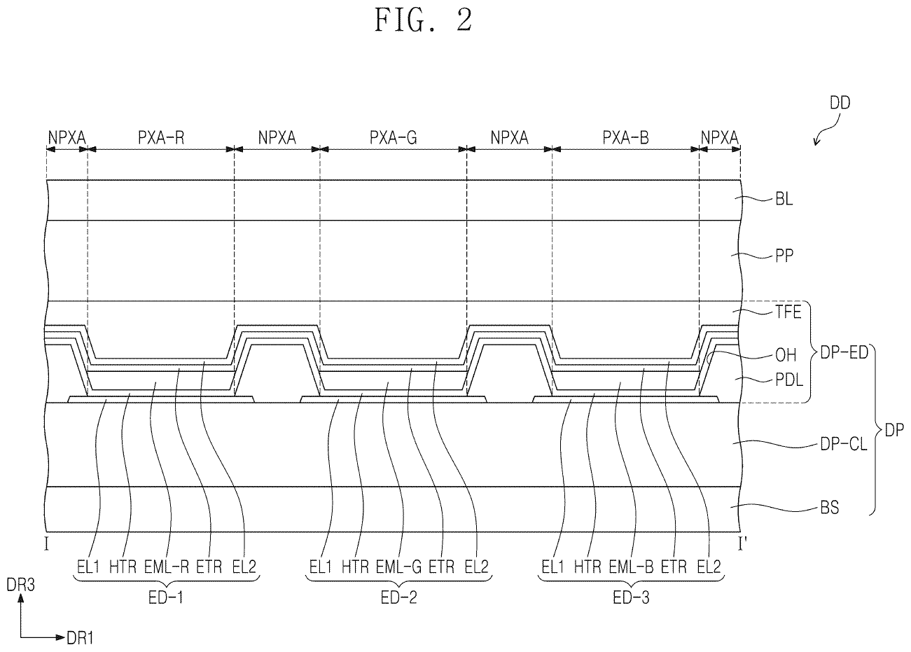

FIG. 1 is a plan view illustrating an embodiment of a display device DD. FIG. 2 is a cross-sectional view of the display device DD of the embodiment. FIG. 2 is a cross-sectional view illustrating a part taken along line I-I′ of FIG. 1.

The display device DD may include a display panel DP and an optical layer PP disposed on the display panel DP. The display panel DP includes light-emitting elements ED-1, ED-2, and ED-3. The display device DD may include a plurality of light-emitting elements ED-1, ED-2, and ED-3. The optical layer PP may be disposed on the display panel DP to control reflected light in the display panel DP due to external light. The optical layer PP may include, for example, a polarization layer or a color filter layer. Unlike the configuration illustrated in the drawing, the optical layer PP may be omitted from the display device DD of an embodiment.

A base substrate BL may be disposed on the optical layer PP. The base substrate BL may be a member which provides a base surface on which the optical layer PP disposed. The base substrate BL may be a glass substrate, a metal substrate, a plastic substrate, or the like. However, embodiments are not limited thereto, and the base substrate BL may be an inorganic layer, an organic layer, or a composite material layer. In addition, unlike the configuration illustrated, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-containing resin, a silicone-containing resin, or an epoxy-containing resin.

The display panel DP may include a base layer BS, a circuit layer DP-CL provided on the base layer BS, and the display element layer DP-ED. The display element layer DP-ED may include a pixel defining film PDL, the light-emitting elements ED-1, ED-2, and ED-3 disposed between portions of the pixel defining film PDL, and an encapsulation layer TFE disposed on the light-emitting elements ED-1, ED-2, and ED-3.

The base layer BS may be a member which provides a base surface on which the display element layer DP-ED is disposed. The base layer BS may be a glass substrate, a metal substrate, a plastic substrate, or the like. However, the embodiment is not limited thereto, and the base layer BS may be an inorganic layer, an organic layer, or a composite material layer.

In an embodiment, the circuit layer DP-CL is disposed on the base layer BS, and the circuit layer DP-CL may include a plurality of transistors (not shown). Each of the transistors (not shown) may include a control electrode, an input electrode, and an output electrode. For example, the circuit layer DP-CL may include a switching transistor and a driving transistor for driving the light-emitting elements ED-1, ED-2, and ED-3 of the display element layer DP-ED.

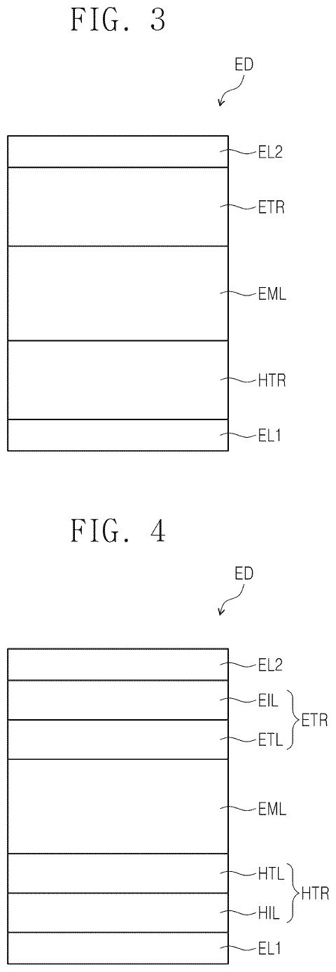

Each of the light-emitting elements ED-1, ED-2, and ED-3 may have a structure of each light-emitting element ED of embodiments according to FIGS. 3 to 6, which will be described herein. Each of the light-emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light-emitting elements ED-1, ED-2, and ED-3 are disposed in openings OH defined in the pixel defining film PDL, and the hole transport region HTR, the electron transport region ETR, and the second electrode EL2 are provided as a common layer in the entire light-emitting elements ED-1, ED-2, and ED-3. However, embodiments are not limited thereto, and unlike the configuration illustrated in FIG. 2, the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light-emitting elements ED-1, ED-2, and ED-3 in an embodiment may be provided by being patterned in an inkjet printing method.

The encapsulation layer TFE may cover the light-emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, or the like, but embodiments are not particularly limited thereto. The encapsulation-organic film may include an acrylic-containing compound, an epoxy-containing compound, or the like. The encapsulation-organic film may include a photopolymerizable organic material, but embodiments are not particularly limited thereto.

The encapsulation layer TFE may be disposed on the second electrode EL2 and may be disposed filling the opening OH.

Referring to FIGS. 1 and 2, the display device DD may include a non-light emitting region NPXA and light emitting regions PXA-R, PXA-G, and PXA-B. The light emitting regions PXA-R, PXA-G, and PXA-B may be regions in which light generated by the respective light-emitting elements ED-1, ED-2, and ED-3 is emitted. The light emitting regions PXA-R, PXA-G, and PXA-B may be spaced apart from each other on a plane.

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In the specification, the light emitting regions PXA-R, PXA-G, and PXA-B may respectively correspond to pixels. The pixel defining film PDL may divide the light-emitting elements ED-1, ED-2, and ED-3. The emission layers EML-R, EML-G, and EML-B of the light-emitting elements ED-1, ED-2, and ED-3 may be disposed in openings OH defined in the pixel defining film PDL and separated from each other.

The light emitting regions PXA-R, PXA-G, and PXA-B may be divided into a plurality of groups according to the color of light generated from the light-emitting elements ED-1, ED-2, and ED-3. In the display device DD of an embodiment illustrated in FIGS. 1 and 2, three light emitting regions PXA-R, PXA-G, and PXA-B, which emit red light, green light, and blue light, respectively, are exemplarily illustrated. For example, the display device DD of an embodiment may include the red light emitting region PXA-R, the green light emitting region PXA-G, and the blue light emitting region PXA-B that are separated from each other.

In the display device DD according to an embodiment, the plurality of light-emitting elements ED-1, ED-2 and ED-3 may emit light beams having wavelengths different from each other. For example, in an embodiment, the display device DD may include a first light-emitting element ED-1 that emits red light, a second light-emitting element ED-2 that emits green light, and a third light-emitting element ED-3 that emits blue light. That is, the red light emitting region PXA-R, the green light emitting region PXA-G, and the blue light emitting region PXA-B of the display device DD may correspond to the first light-emitting element ED-1, the second light-emitting element ED-2, and the third light-emitting element ED-3, respectively.

However, embodiments are not limited thereto, and the first to third light-emitting elements ED-1, ED-2, and ED-3 may emit light beams in the same wavelength range or at least one light-emitting element may emit a light beam in a wavelength range different from the others. For example, the first to third light-emitting elements ED-1, ED-2, and ED-3 may all emit blue light.

The light emitting regions PXA-R, PXA-G, and PXA-B in the display device DD according to an embodiment may be arranged in a stripe form. Referring to FIG. 1, the plurality of red light emitting regions PXA-R, the plurality of green light emitting regions PXA-G, and the plurality of blue light emitting regions PXA-B each may be arranged along a second directional axis DR2. In addition, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but embodiments are not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may mean areas when viewed on a plane defined by the first directional axis DR1 and the second directional axis DR2.

An arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the characteristics of display quality required in the display device DD. For example, the arrangement form of the light emitting regions PXA-R, PXA-G, and PXA-B may be a pentile (PENTILER) arrangement form or a diamond (Diamond Pixel®) arrangement form.

In addition, the areas of the light emitting regions PXA-R, PXA-G, and PXA-B may be different from each other. For example, in an embodiment, the area of the green light emitting region PXA-G may be smaller than that of the blue light emitting region PXA-B, but embodiments are not limited thereto.

Hereinafter, FIG. 3 to FIG. 6 are cross-sectional views schematically showing light-emitting elements according to embodiments. The light-emitting element ED of an embodiment may include a first electrode EL1, a hole transport region HTR, an emission layer EML, an electron transport region ETR, and a second electrode EL2 stacked in order.

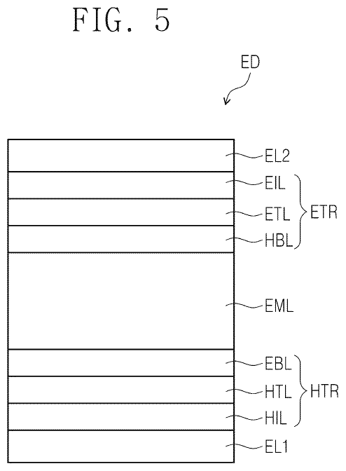

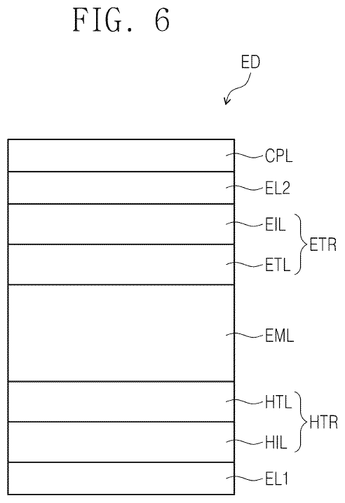

Compared with FIG. 3, FIG. 4 illustrates a cross-sectional view of a light-emitting element ED of an embodiment, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light-emitting element ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Unlike the configuration illustrated in FIG. 5, the hole injection layer HIL may be omitted in the hole transport region HTR. Compared with FIG. 4, FIG. 6 illustrates a cross-sectional view of a light-emitting element ED of an embodiment including a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In addition, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, a compound of two or more selected from among these, a mixture of two or more selected from among these, or an oxide thereof.

If the first electrode EL1 is the transmissive electrode, the first electrode EL1 may include a transparent metal oxide such as indium tin oxide (ITO), indium zinc oxide (IZO), zinc oxide (ZnO), indium tin zinc oxide (ITZO), or a combination thereof. If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). Alternatively, the first electrode EL1 may have a multilayer structure including a reflective film or a transflective film formed of the above-described materials, and a transparent conductive film formed of ITO, IZO, ZnO, ITZO, or the like. For example, the first electrode EL1 may have a three-layer structure of ITO/Ag/ITO, but embodiments are not limited thereto. In addition, embodiments are not limited thereto, and the first electrode EL1 may include the above-described metal materials, combinations of at least two metal materials of the above-described metal materials, oxides of the above-described metal materials, or the like. The thickness of the first electrode EL1 may be from about 700 angstroms (Å) to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer, an emission-auxiliary layer (not shown), or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In addition, the hole transport region HTR may have a single layer structure formed of a plurality of different materials, or a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, a laser induced thermal imaging (LITI) method, or the like, but embodiments are not limited thereto.

The hole transport region HTR may include a compound represented by Formula H-1 below:

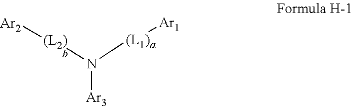

In Formula H-1, L₁ and L₂ may be each independently a direct linkage, a substituted or unsubstituted arylene group having 6 to 30 ring-forming carbon atoms, or a substituted or unsubstituted heteroarylene group having 2 to 30 ring-forming carbon atoms. a and b may be each independently an integer of 0 to 10. When a or b is an integer of 2 or greater, a plurality of L₁'s and L₂'s may be each independently a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. Alternatively, the compound represented by Formula H-1 above may be a diamine compound in which at least one among Ar₁ to Ar₃ includes the amine group as a substituent. In addition, the compound represented by Formula H-1 above may be a carbazole-containing compound including a substituted or unsubstituted carbazole group in at least one of Ar₁ or Ar₂, or a fluorene-containing compound including a substituted or unsubstituted fluorene group in at least one of Ar₁ or Ar₂.

The compound represented by Formula H-1 may be represented by one of the compounds in Compound Group H. However, the compounds listed in Compound Group H below are examples, and the compounds represented by Formula H-1 are not limited to those represented by Compound Group H:

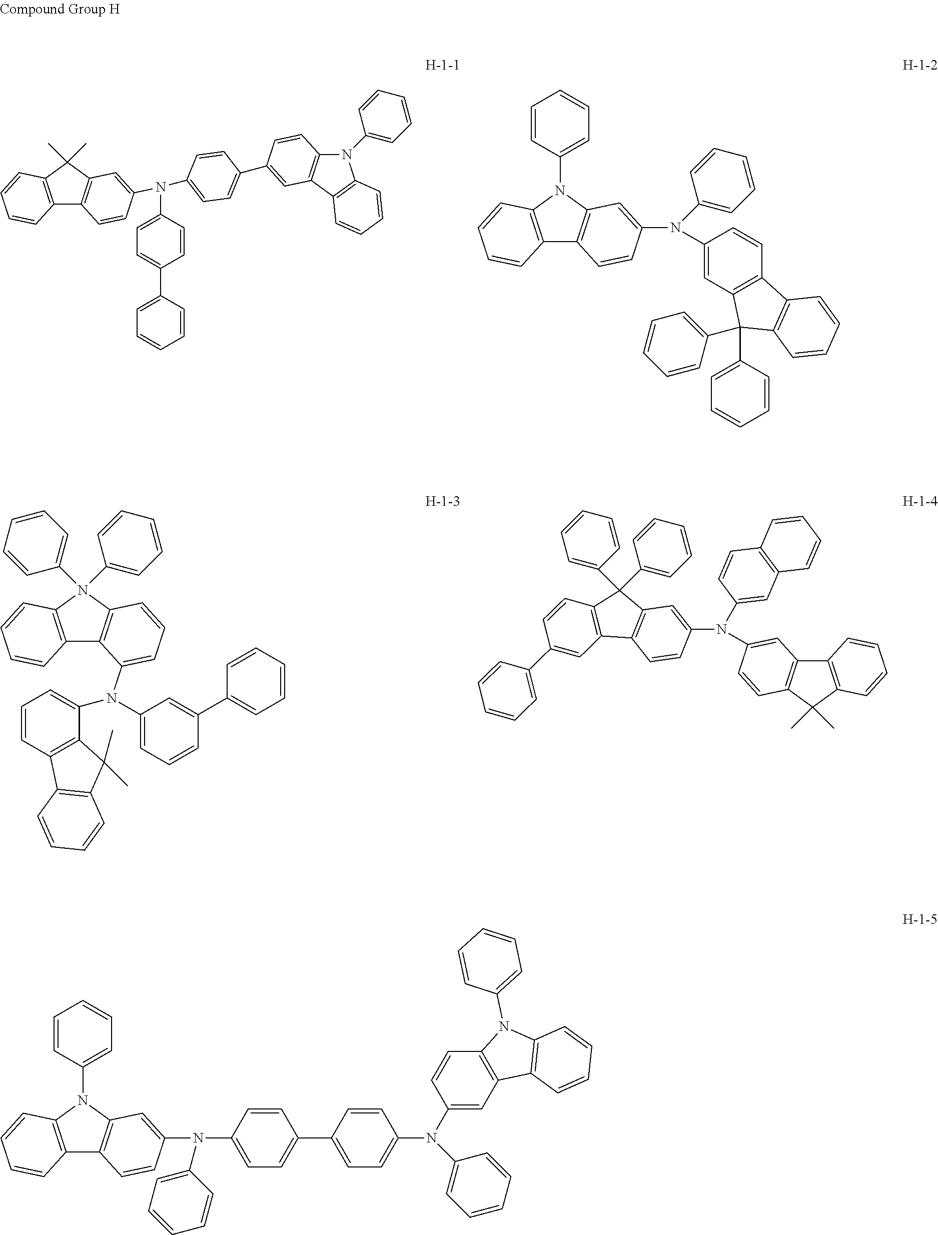

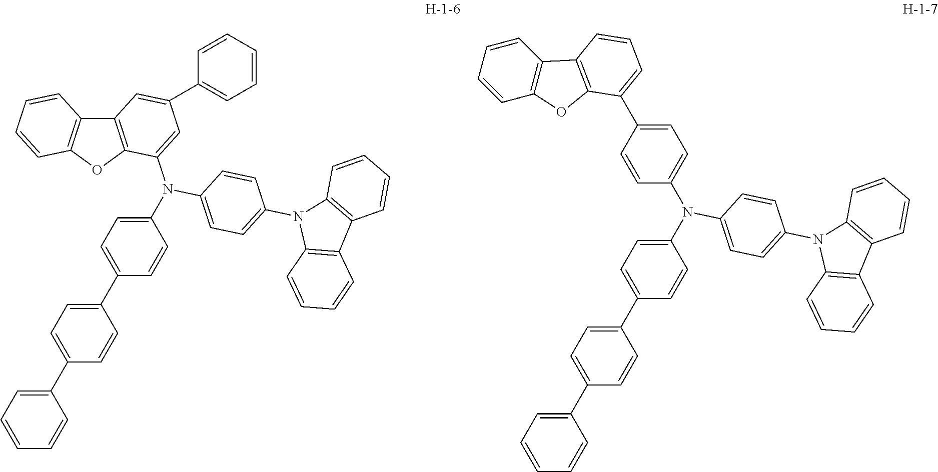 [SMILES: c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

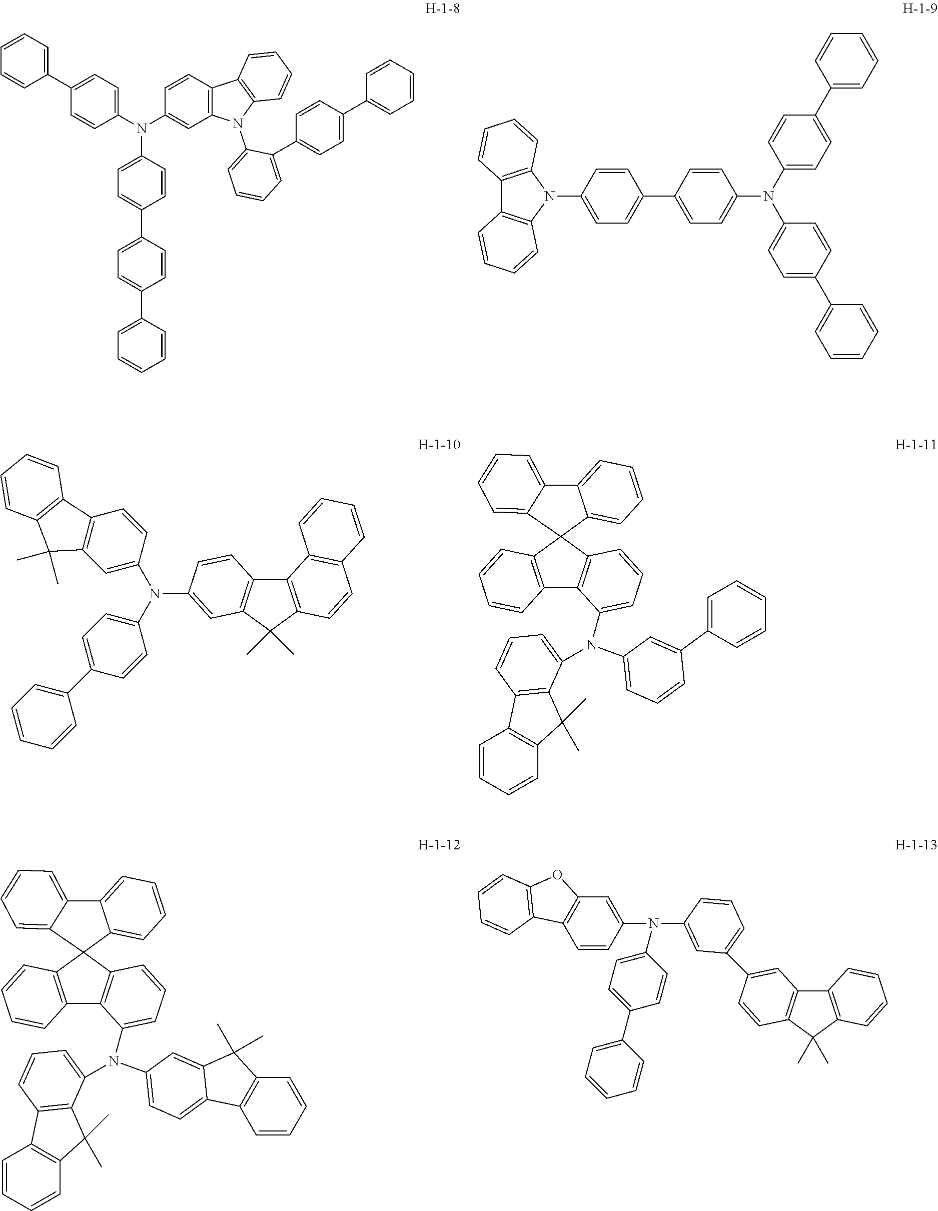

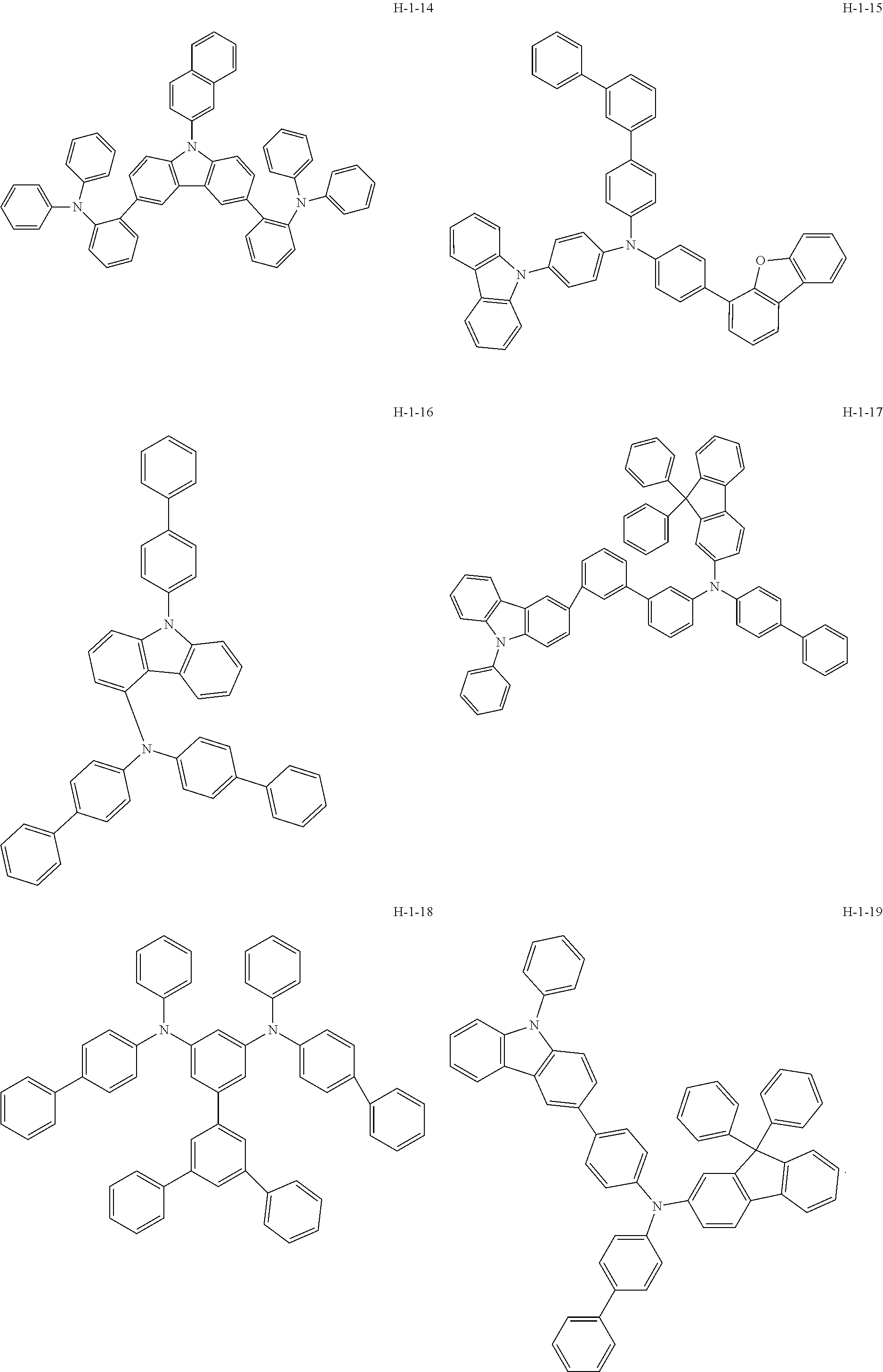

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N (2-naphthyl)-N-phenylamino]-triphenylamine (2-TNATA), poly(3,4-ethlenedioxythiophene)/poly(4-styrenesulfonate) (PEDOT/PSS) polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), or the like, but embodiments are not limited thereto.

The hole transport region HTR may include a carbazole-containing derivative such as N-phenyl carbazole or polyvinyl carbazole, a fluorene-containing derivative, a triphenylamine-containing derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), or the like, but embodiments are not limited thereto

In addition, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), or the like, but embodiments are not limited thereto.

The hole transport region HTR may include the above-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 30 Å to about 1,000 Å. For example, when the hole transport region HTR includes the electron blocking layer EBL, the electron blocking layer EBL may have a thickness of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′,8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), or the like, but embodiments are not limited thereto.

As described herein, the hole transport region HTR may further include at least one of the buffer layer (not shown) or the electron blocking layer EBL in addition to the hole injection layer HIL and the hole transport layer HTL. The buffer layer (not shown) may compensate for a resonance distance according to the wavelength of light emitted from the emission layer EML and may thus increase light emission efficiency. A material that may be included in the hole transport region HTR may be used as a material to be included in the buffer layer (not shown). The electron blocking layer EBL is a layer that serves to prevent the electron injection from the electron transport region ETR to the hole transport region HTR.

In an embodiment, the emission layer EML may include a first compound according to an embodiment. The emission layer EML according to an embodiment may further include at least one of second to fourth compounds. The second compound may include a fused ring system with three rings, which contains a nitrogen atom as a ring-forming atom. The third compound may include a hexagonal cyclic group containing at least one nitrogen atom as a ring-forming atom. The fourth compound may include an organometallic complex. The second to fourth compounds will be described herein in detail.

As used herein, the first compound may be referred to as a fused polycyclic compound according to an embodiment. The fused polycyclic compound according to an embodiment may include a core structure and a substituent E_{w} bonded to the core structure. The fused polycyclic compound according to an embodiment may include, as a core structure, a fused ring with nine rings, which contains four heteroatoms and two boron atoms as ring-forming atoms. At least one of the four heteroatoms may be N, and the others may be each independently O or S. The substituent E_{w} may be an electron withdrawing group. The substituent E_{w} is a fluorine atom, a cyano group, a nitro group, a trifluoromethyl group, a substituted or unsubstituted formyl group, a substituted or unsubstituted pyridine group, a substituted or unsubstituted pyrimidine group, a substituted or unsubstituted pyrazole group, or a substituted or unsubstituted triazine group. The substituent E_{w} may be directly bonded to the core structure or indirectly bonded to the core structure in such a way that the substituent is included in at least one of the four heteroatoms. Therefore, the fused polycyclic compound according to an embodiment may exhibit improved charge transfer (CT) characteristics, and the RISC may be promoted. The light-emitting element ED including the fused polycyclic compound according to an embodiment may exhibit high emission efficiency.

The light-emitting element ED according to an embodiment may include the fused polycyclic compound according to an embodiment. The fused polycyclic compound according to an embodiment may be represented by Formula 1.

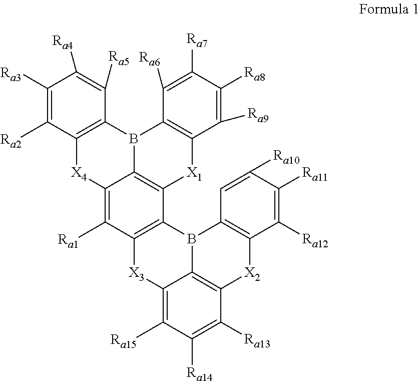

In Formula 1, X₁ to X₄ are each independently O, S, or NRₙ, wherein at least one of X₁ to X₄ is NRₙ. For example, X₄ is NRₙ, and X₁ to X₃ may be each independently O or S. Alternatively, X₂ to X₄ may be each independently NRₙ, and X₁ may be O or S.

Each Rₙ is independently a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, E_{w}, or a group represented by Formula 2.

Each E_{w} is independently a fluorine atom, a cyano group, a nitro group, a trifluoromethyl group, a substituted or unsubstituted formyl group, a substituted or unsubstituted pyridine group, a substituted or unsubstituted pyrimidine group, a substituted or unsubstituted pyrazole group, or a substituted or unsubstituted triazine group. For example, E_{w} may be a fluorine atom, a cyano group, a nitro group, a trifluoromethyl group, an unsubstituted pyridine group, an unsubstituted pyrimidine group, an unsubstituted pyrazole group, or an unsubstituted triazine group.

Rₐ₁ to Rₐ₉ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w}. Adjacent two or more of Rₐ₂ to Rₐ₉ are optionally bonded together to form a ring.

In Formula 1, Rₐ₁₀ to Rₐ₁₅ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ₁₃ to Rₐ₁₅ may be each independently a hydrogen atom, a deuterium atom, or a substituted or unsubstituted t-butyl group.

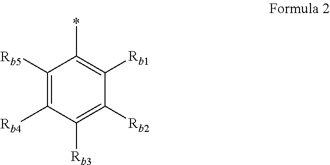

In Formula 2, R_{b1} to R_{b5} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w}. For example, R_{b1} to R_{b5} may be each independently a hydrogen atom, a deuterium atom, a substituted or unsubstituted aryl group having 6 to 30 ring-forming carbon atoms, or E_{w}.

The fused polycyclic compound according to an embodiment may include a chemical structure in which any hydrogen atom in a molecule is optionally substituted with a deuterium atom. The fused polycyclic compound according to an embodiment may include a deuterium atom, or a substituent substituted with a deuterium atom. For example, in Formula 1, at least one of R_{b1} to R_{b5} may be a deuterium atom, or a group substituted with a deuterium atom. However, this is an example, and embodiments are not limited thereto.

The fused polycyclic compound of Formula 1 satisfies at least one of Condition 1 to 3.

### Condition 1

at least one Rₙ is E_{w}

### Condition 2

at least one Rₙ is represented by Formula 2, and
at least one of R_{b1} to R_{b5} in Formula 2 is E_{w}

### Condition 3

at least one among Rₐ₁ to Rₐ₉ is E_{w}.

The fused polycyclic compound of Formula 1, which satisfies at least one among Conditions 1 to 3, includes a substituent E_{w}, introduced to at least one of Rₐ₁ to Rₐ₉, or X₁ to X₄ in Formula 1. The fused polycyclic compound of Formula 1, which satisfies at least one of Conditions 1 to 3, includes an electron withdrawing group introduced in at least one among Rₐ₁ to Rₐ₉, or X₁ to X₄ in Formula 1.

In an embodiment, Formula 1 may be represented by any one of Formula 1-A1 to Formula 1-A5. Formula 1-A1 to Formula 1-A5 may represent Formulae in which X₁ to X₄ in Formula 1 are specified.

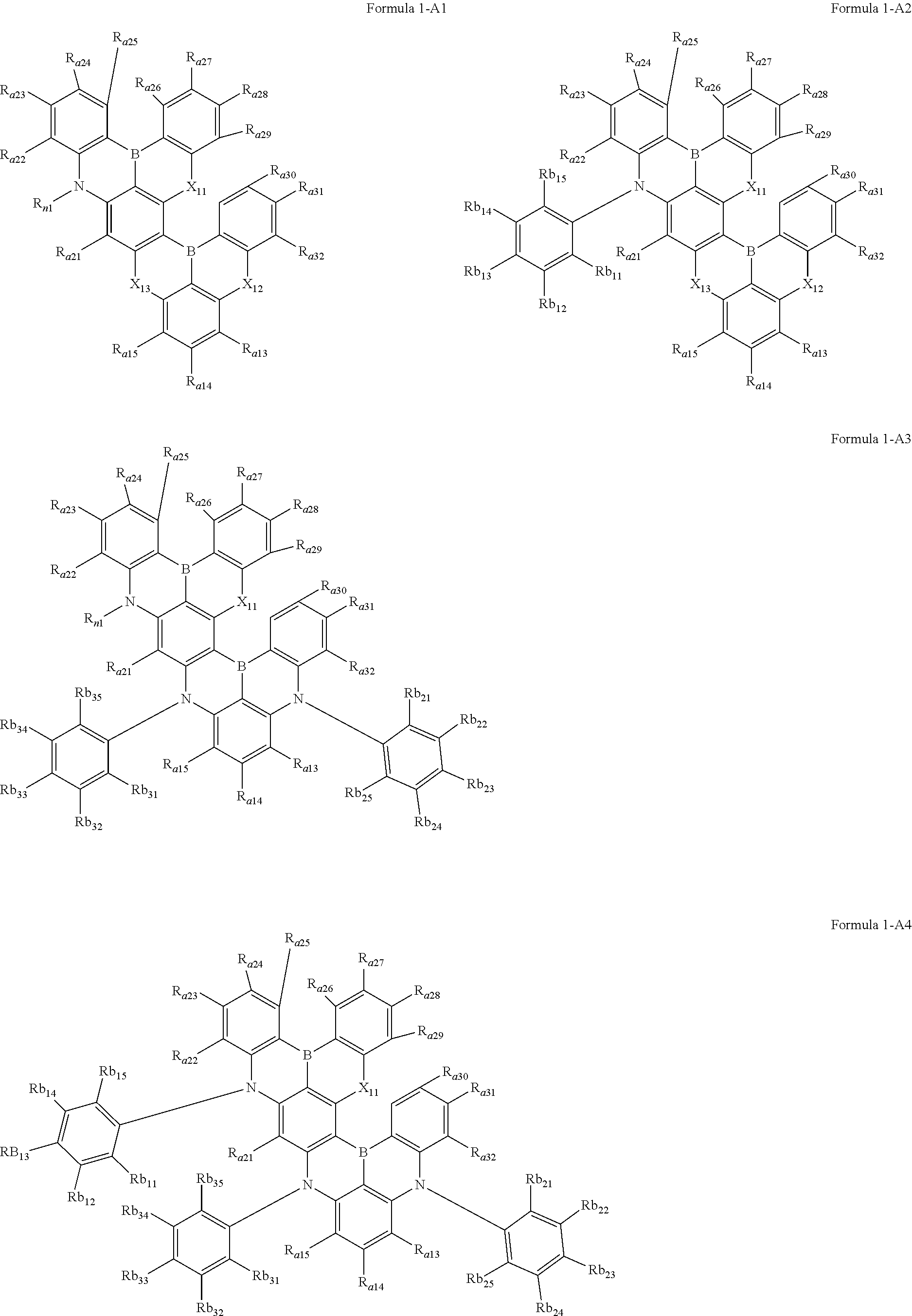

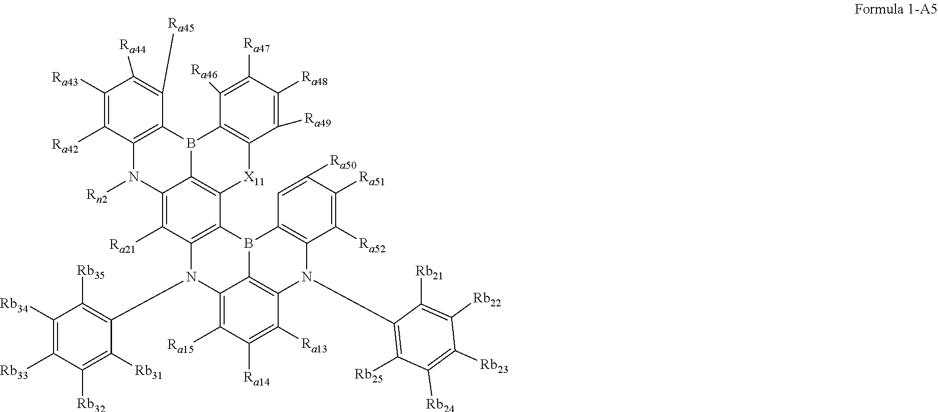

Formula 1-A1 and Formula 1-A3 may each correspond to the above-described first case. Formula 1-A2 and Formula 1-A4 may each correspond to the above-described second case. Formula 1-A5 may correspond to the above-described third case. The details described in Formula 1 may be similarly applied to Rₐ₁₃ to Rₐ₁₅ in Formula 1-A1 to Formula 1-A5.

In Formula 1-A1 to Formula 1-A5, X₁₁ to X₁₃ may be each independently O or S. Rₐ₂₁ to Rₐ₃₂ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R_{b21} to R_{b25}, and R_{b31} to R_{b35} may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 1-A1 to Formula 1-A3, Rₙ₁ may be E_{w}. For example, Rₙ₁ may be an unsubstituted pyrazole group.

In Formula 1-A2 and Formula 1-A4, at least one among R_{b11} to R_{b15} may be E_{w}, and the others may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, the others, among R_{b11} to R_{b15}, which are not E_{w}, may be each independently a hydrogen atom, a deuterium atom, or a substituted or unsubstituted phenyl group.

In Formula 1-A5, Rₙ₂ may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Rₐ₅₀ to Rₐ₅₂ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 1-A5, at least one among Rₐ₄₁ to Rₐ₄₉ may be E_{w}, and the others may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ₄₇ may be E_{w}.

In Formula 1-A1 to Formula 1-A4, Rₐ₂₁ to Rₐ₃₂ may be each independently a hydrogen atom, a deuterium atom, a substituted or unsubstituted phenyl group, or a substituted or unsubstituted carbazole group. In Formula 1-A2 and Formula 1-A4, a first cyclic group including R_{b11} to R_{b15} may be represented by any one among R1-B1 to R1-B144. In R1-B136, D is a deuterium atom.

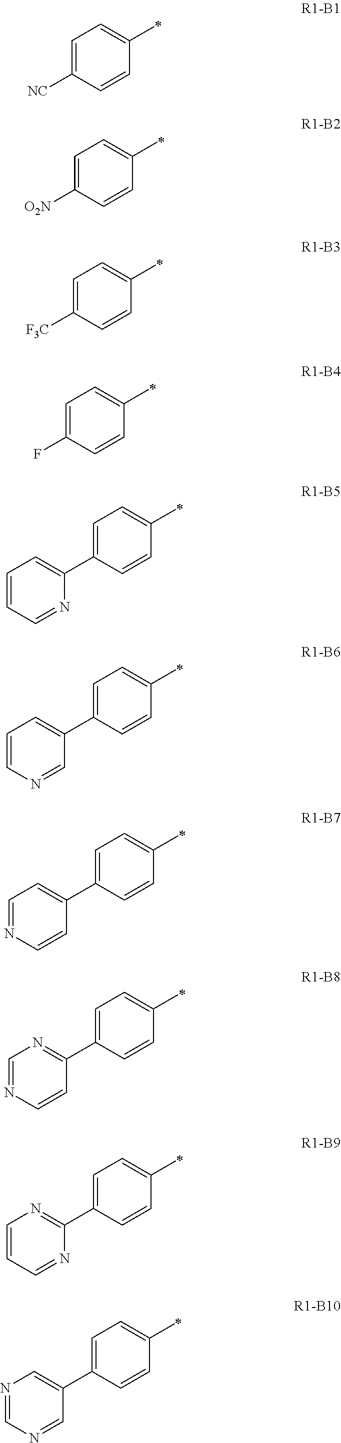

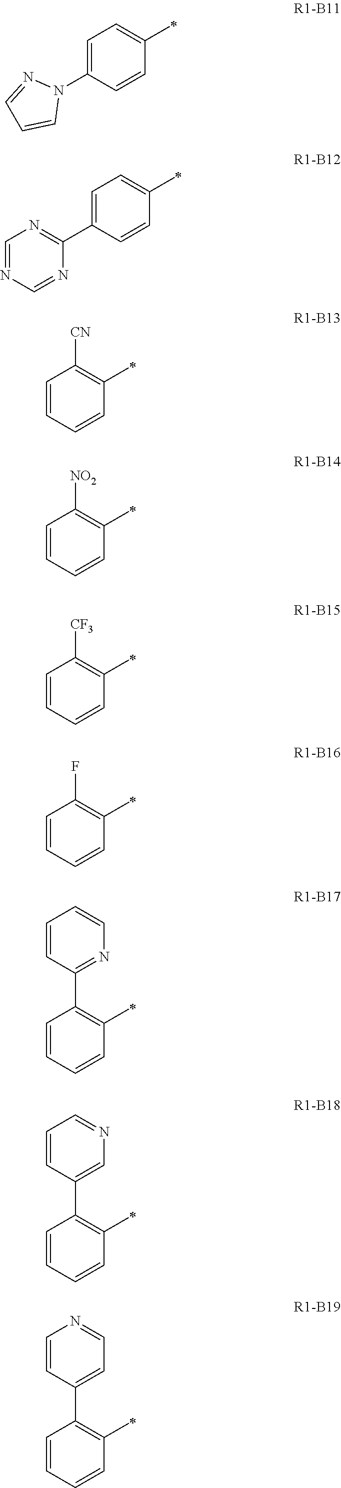

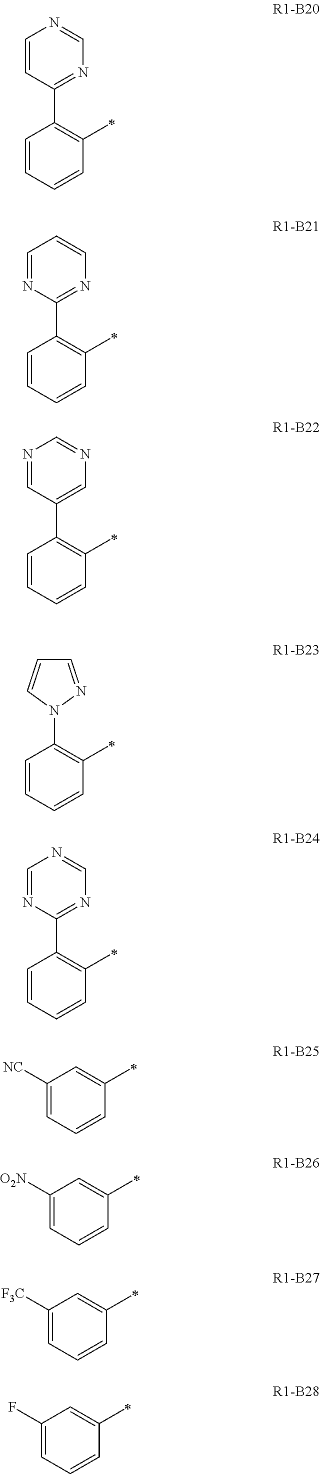

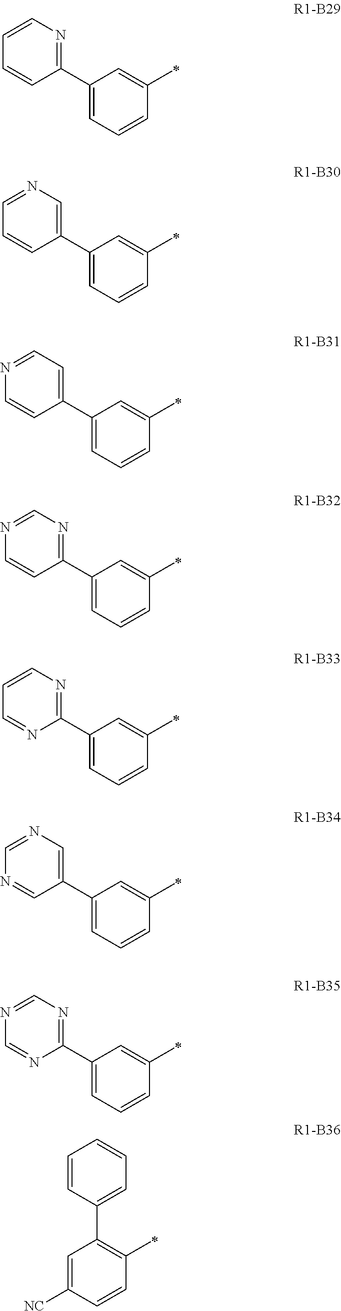

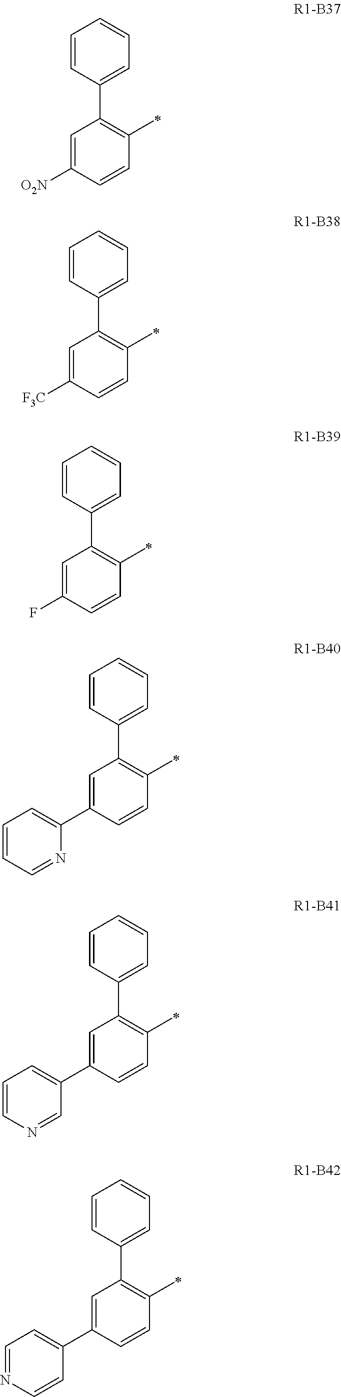

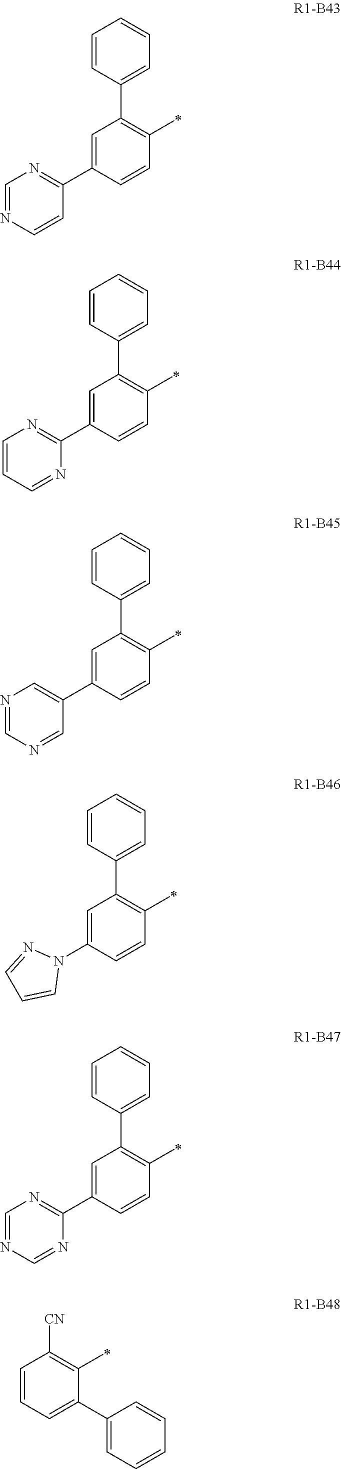

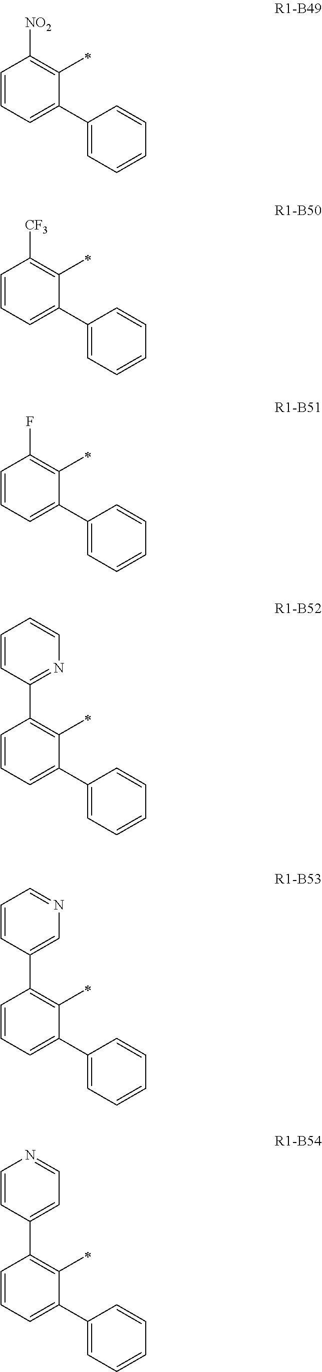

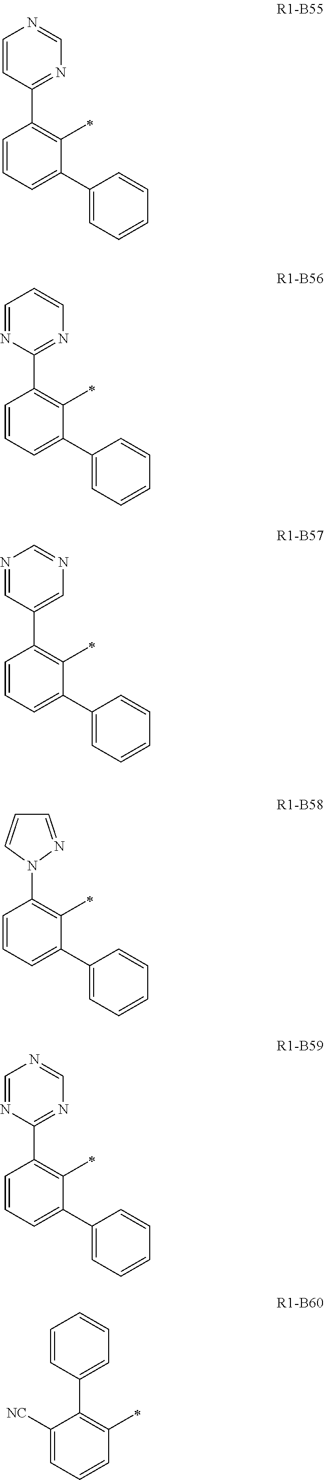

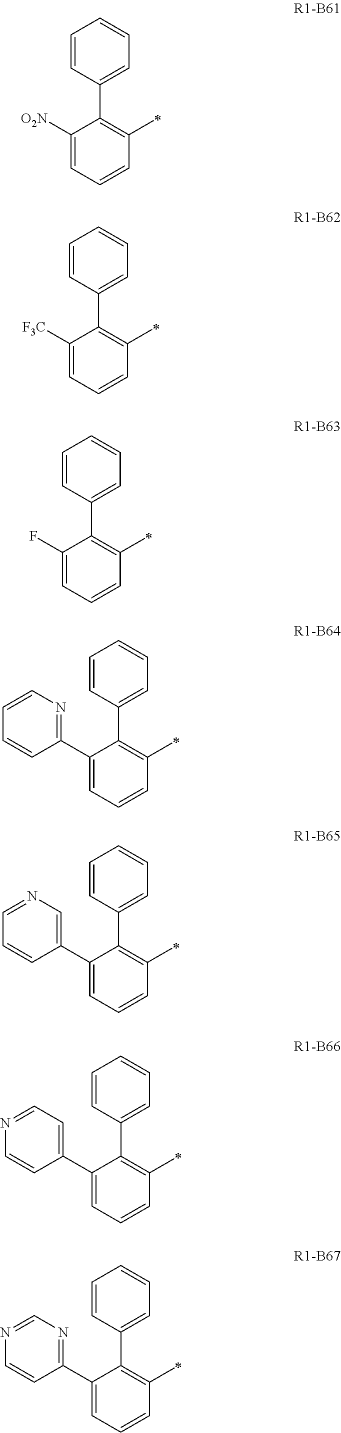

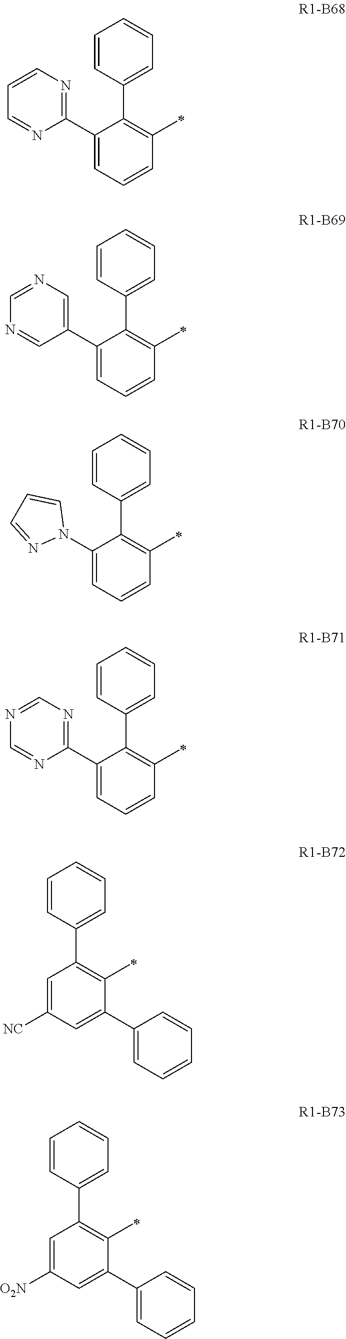

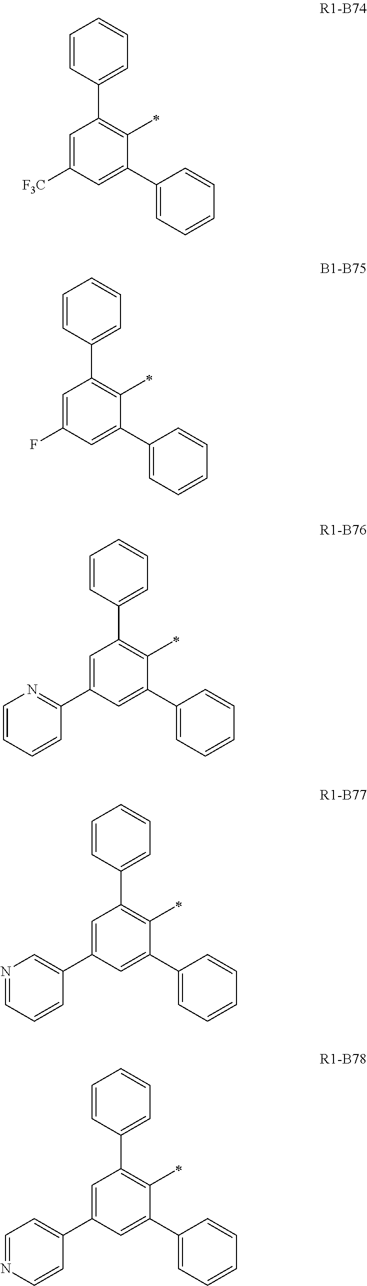

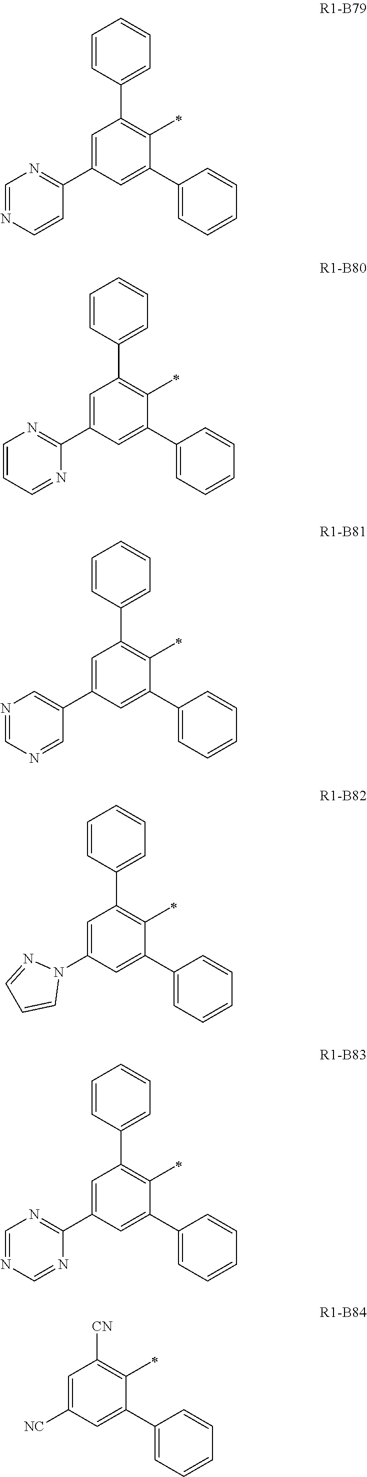

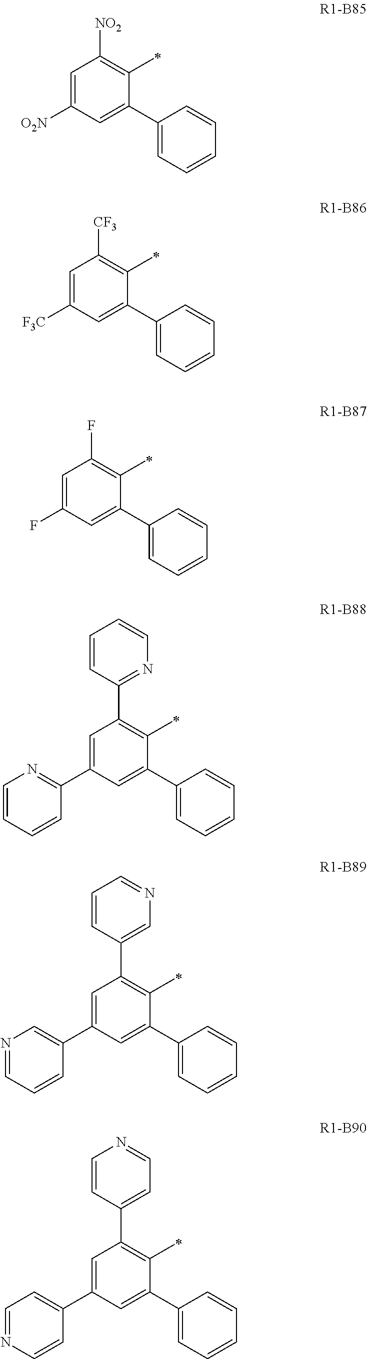

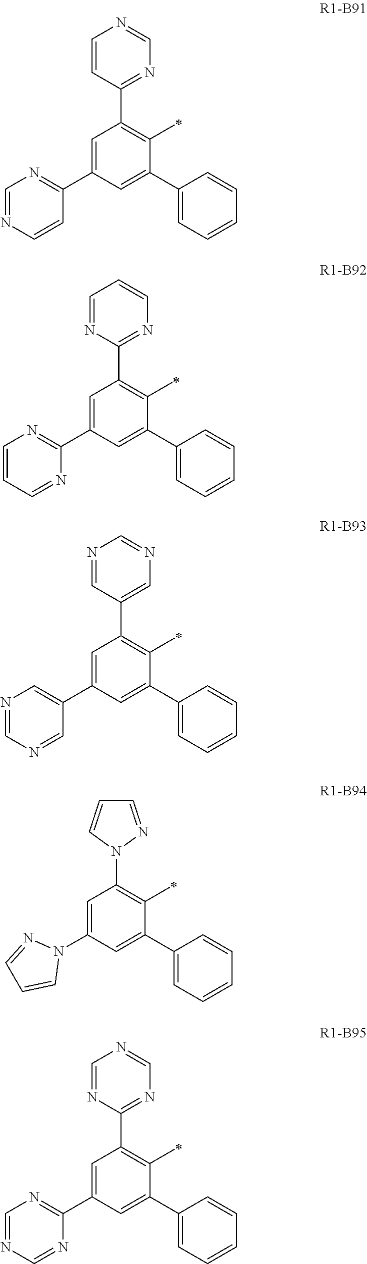

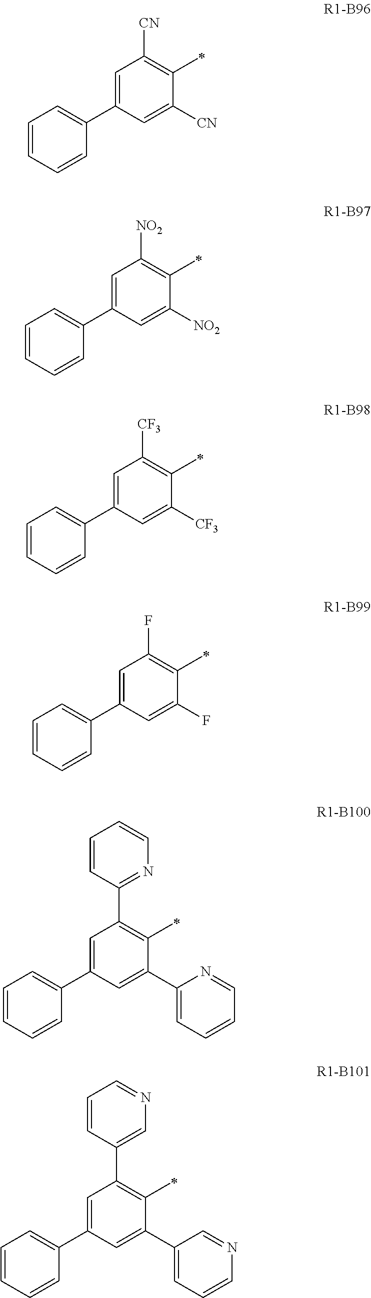

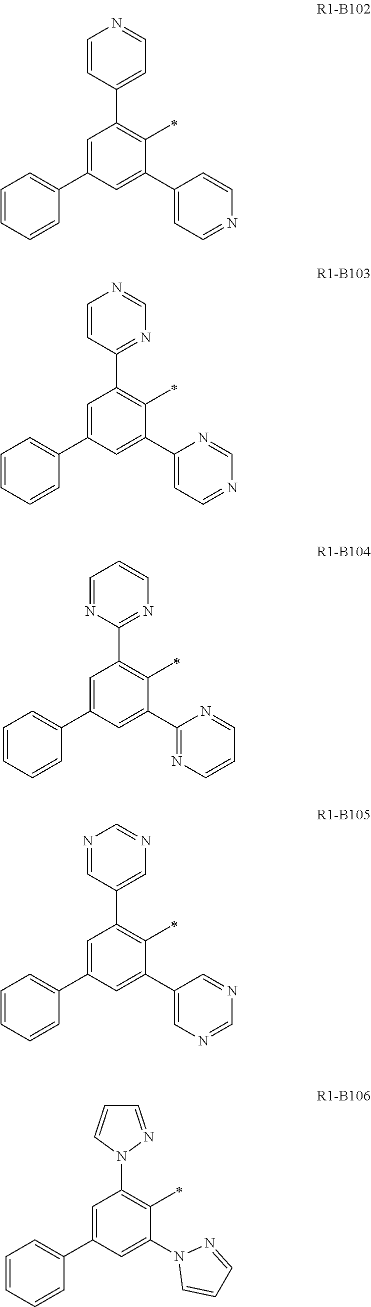

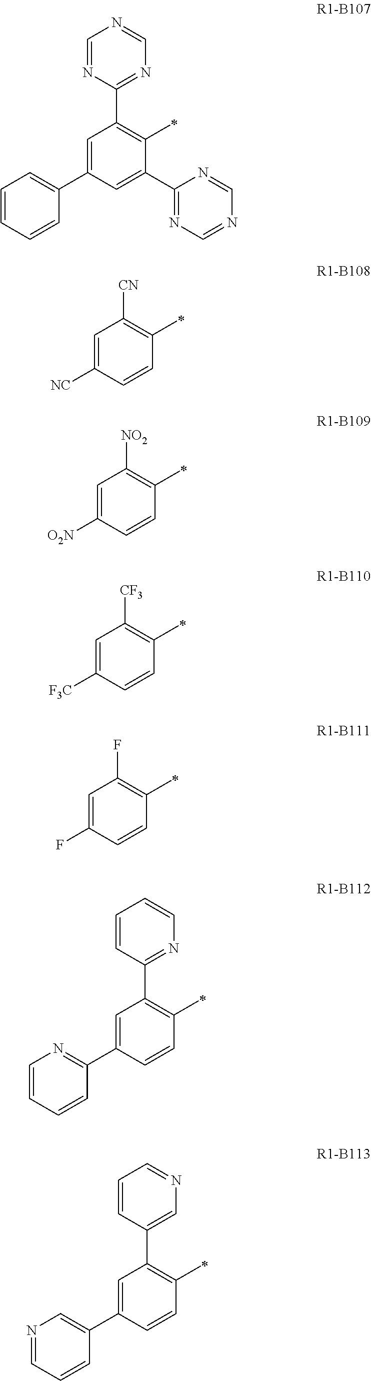

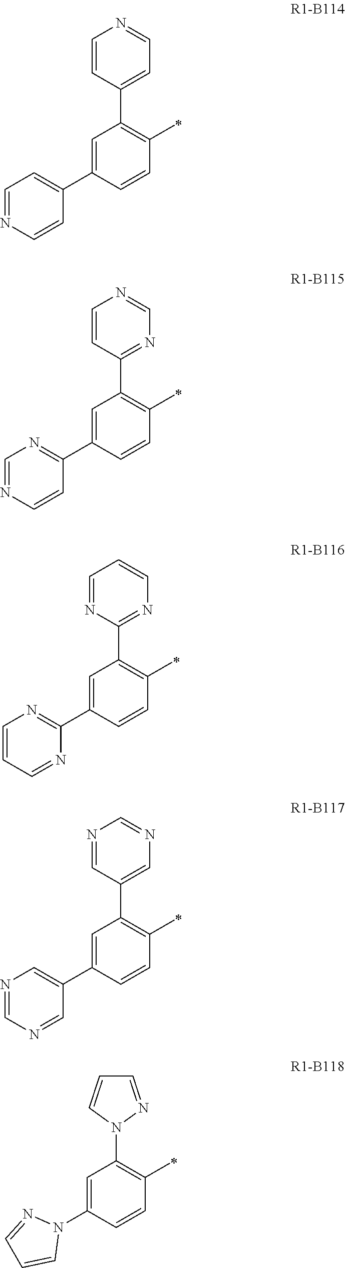

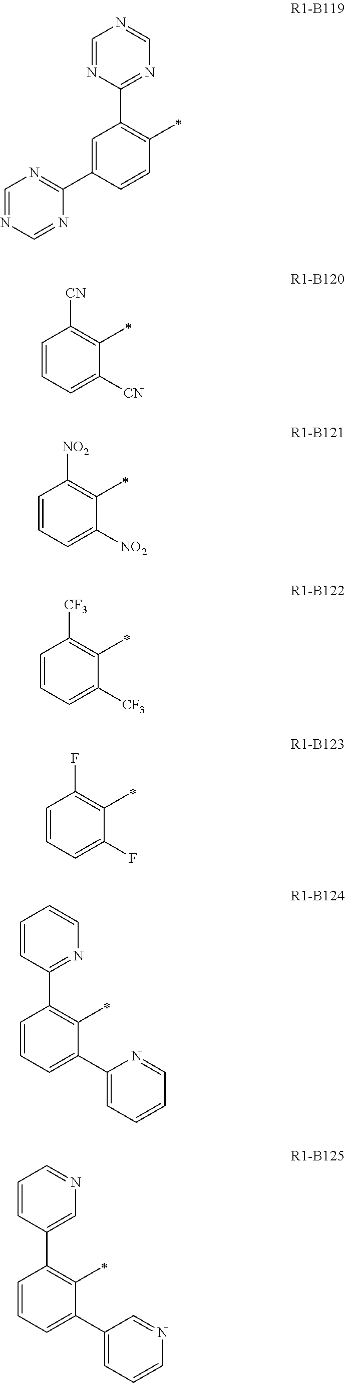

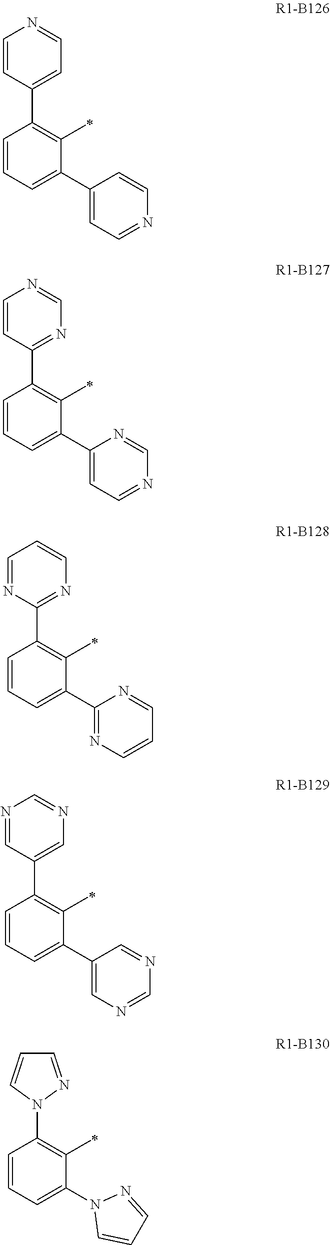

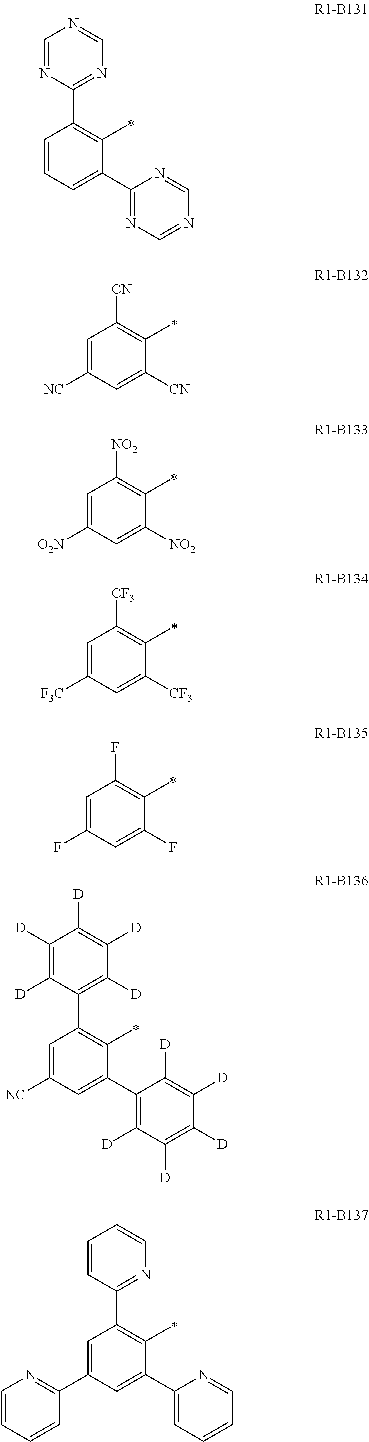

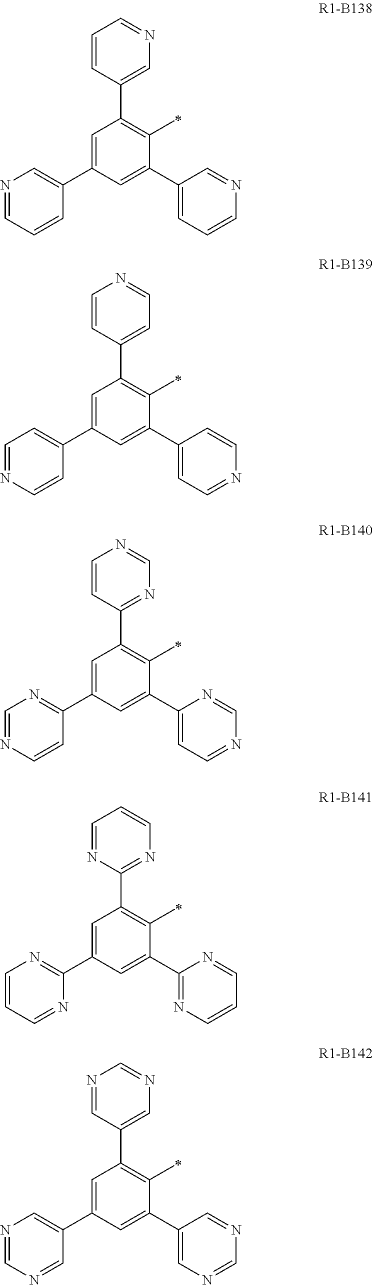

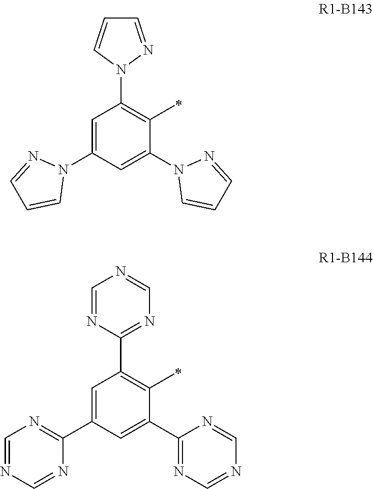

In Formula 1-A3 to Formula 1-A5, a second cyclic group including R_{b21} to R_{b25}, and a third cyclic group including R_{b31} to R_{b35} may be each independently represented by one of R2-B1 to R2-B4. In R2-B4, D is a deuterium atom.

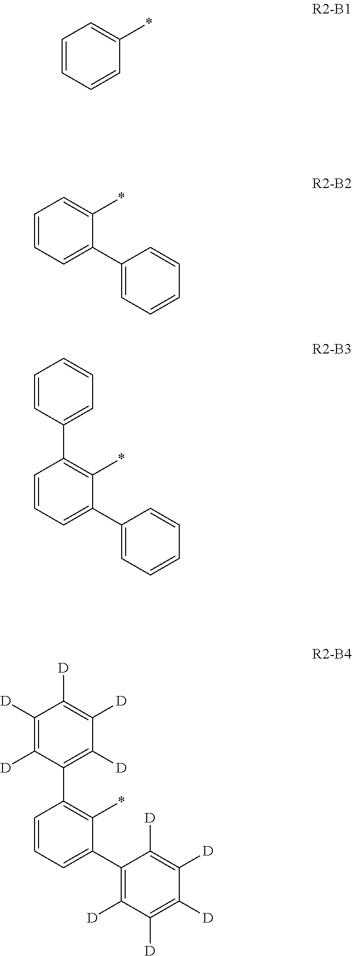 [SMILES: *c1ccccc1 ; *c1ccccc1-c1ccccc1 ; *c1c(-c2ccccc2)cccc1-c1ccccc1 ; *c1c(-c2c([2H])c([2H])c([2H])c([2H])c2[2H])cccc1-c1c([2H])c([2H])c([2H])c([2H])c1[2H]]

In an embodiment, Formula 1-A4 may be represented by one of Formula 1-A41 to Formula 1-A43. Formula 1-A41 to Formula 1-A43 may represent Formulae in which Rₐ₂₁ to Rₐ₃₂ in Formula 1-A4 are specified.

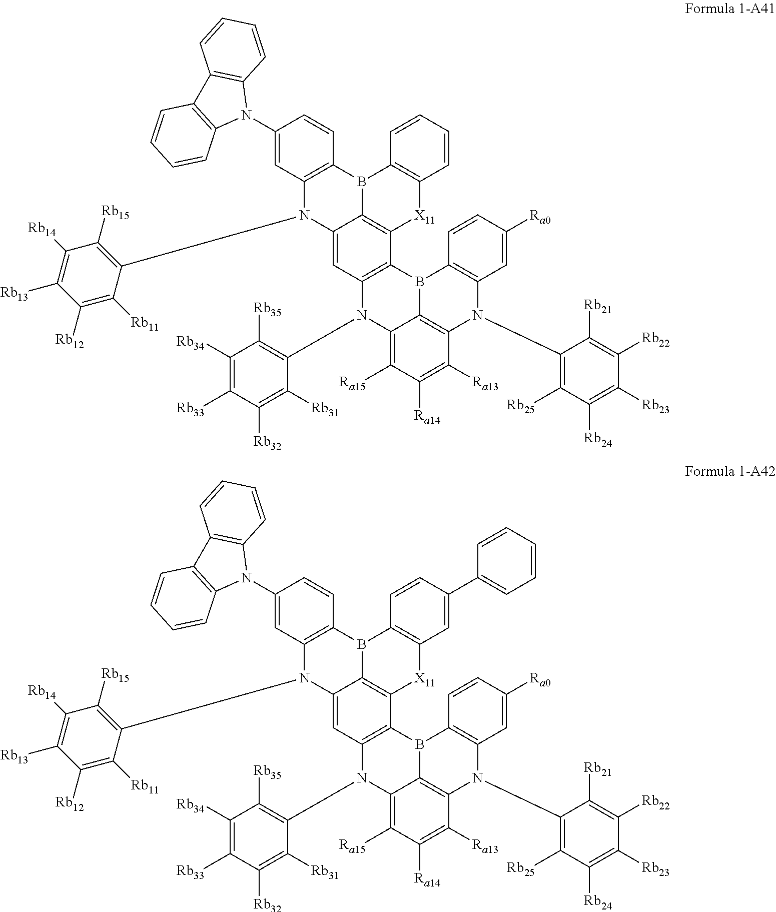

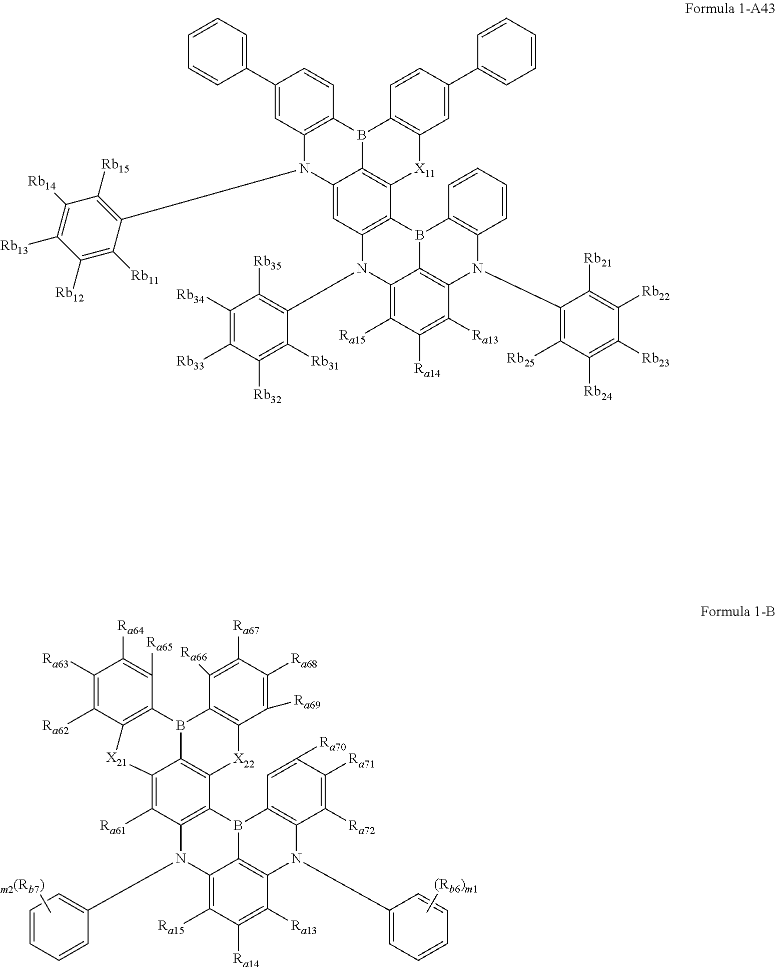

The details described in Formula 1-A4 may be similarly applied to Rₐ₁₃ to Rₐ₁₅, R_{b11} to R_{b15}, R_{b21} to R_{b25}, R_{b31} to R_{b35}, and X₁₁ in Formula 1-A41 to Formula 1-A43. Ra₀ may be a hydrogen atom, a deuterium atom, or a substituted or unsubstituted phenyl group.

In an embodiment, Formula 1 may be represented by Formula 1-B. Formula 1-B may represent a formula in which X₂ and X₃ in Formula 1 are specified.

The details described in Formula 1 may be similarly applied to Rₐ₁₃ to Rₐ₁₅ in Formula 1-B. At least one among X₂₁ and X₂₂ may be NRₙ₃, and the others may be O or S. Rₙ₃ may be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, E_{w}, or a group represented by Formula 2.

In Formula 1-B, m1 and m2 may be each independently an integer of 0 to 5. R_{b6} and R_{b7} may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w}. A fourth cyclic group including (R_{b6})ₘ₁ and a fifth cyclic group including (R_{b7})ₘ₂ may be each independently represented by any one among R2-B1 to R2-B4, described herein previously.

If m1 is an integer of 2 or greater, a plurality of R_{b6} may be the same or at least one thereof may be different from the others. A case where m1 is 0 may be the same as a case where m1 is 5 and five R_{b6} are hydrogen atoms. If m2 is an integer of 2 or greater, a plurality of R_{b7} may be the same or at least one thereof may be different from the others. A case where m2 is 0 may be the same as a case where m2 is 5 and five R_{b7} are hydrogen atoms.

In Formula 1-B, Rₐ₆₁ to Rₐ₆₉ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w}. Rₐ₇₀ to Rₐ₇₂ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 1-B, at least one of Rₙ₃, R_{b6}, R_{b7}, and Rₐ₆₁ to Rₐ₆₉ may include E_{w}. The wording of including E_{w} indicates that the at least one among Rₙ₃, R_{b6}, R_{b7}, and Rₐ₆₁ to Rₐ₆₉ is E_{w}, or that the at least one among Rₙ₃, R_{b6}, R₆₇, and Rₐ₆₁ to Rₐ₆₉ is substituted with E_{w}. That is, at least one among Rₙ₃, R_{b6}, R_{b7}, and Rₐ₆₁ to Rₐ₇₂ may be E_{w}, or may be substituted with E_{w}.

Formula 1 may be represented by one of compounds in Compound Group 1. The fused polycyclic compound according to an embodiment may be represented by one of the compounds in Compound Group 1. The light-emitting element ED according to an embodiment may include at least one of the compounds in Compound Group 1. The emission layer EML may include at least one of the compounds in Compound Group 1. In Compound Group 1, D is a deuterium atom. C₆D₅ is a moiety in which five hydrogen atoms in a phenyl group are all substituted with deuterium atoms.

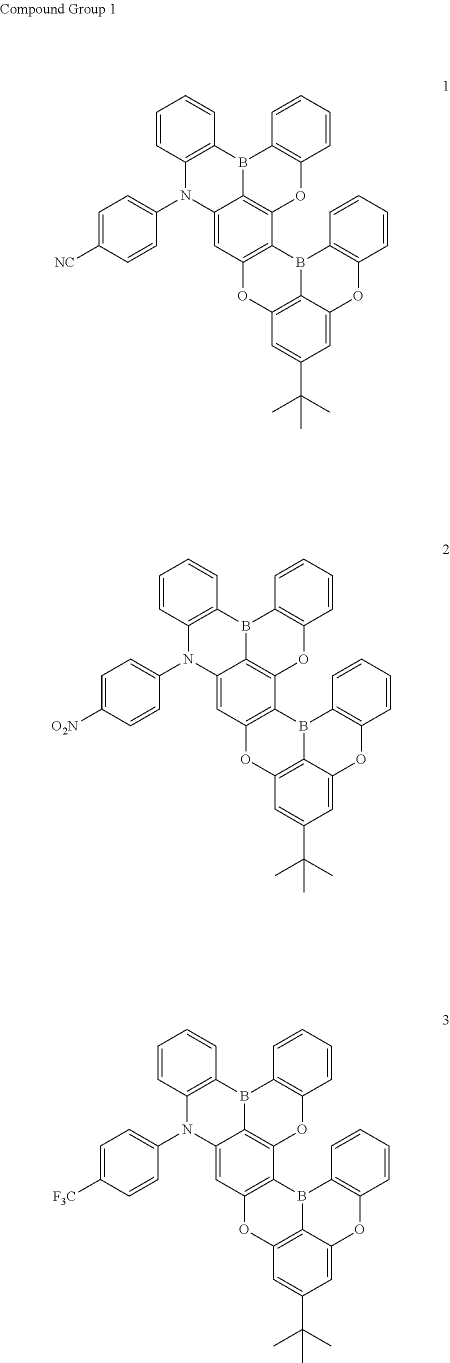 [SMILES: CC(C)(C)c1cc2c3c(c1)Oc1cc4c5c(c1B3c1ccccc1O2)Oc1ccccc1B5c1ccccc1N4c1ccc(C#N)cc1 ; CC(C)(C)c1cc2c3c(c1)Oc1cc4c5c(c1B3c1ccccc1O2)Oc1ccccc1B5c1ccccc1N4c1ccc([N+](=O)[O-])cc1 ; CC(C)(C)c1cc2c3c(c1)Oc1cc4c5c(c1B3c1ccccc1O2)Oc1ccccc1B5c1ccccc1N4c1ccc(C(F)(F)F)cc1]

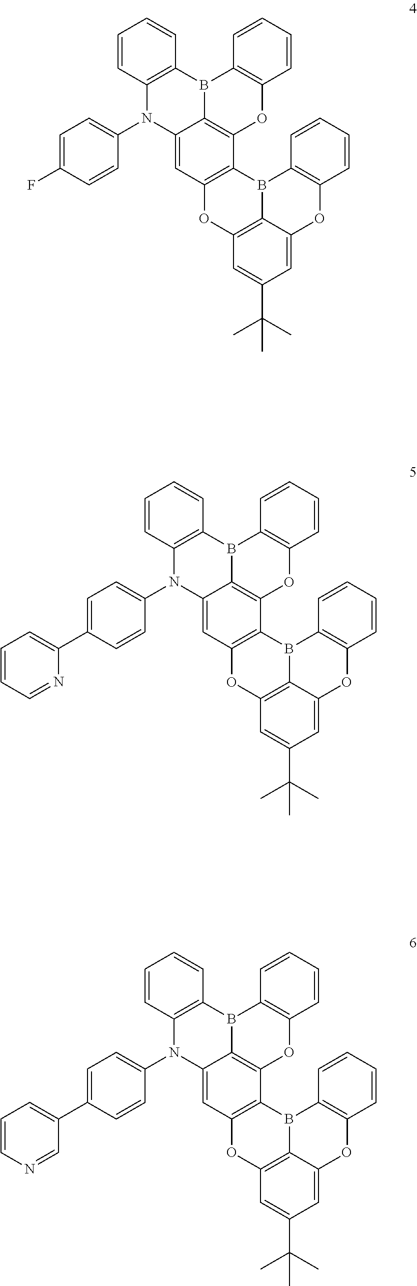 [SMILES: CC(C)(C)c1cc2c3c(c1)Oc1cc4c5c(c1B3c1ccccc1O2)Oc1ccccc1B5c1ccccc1N4c1ccc(F)cc1 ; CC(C)(C)c1cc2c3c(c1)Oc1cc4c5c(c1B3c1ccccc1O2)Oc1ccccc1B5c1ccccc1N4c1ccc(-c2ccccn2)cc1 ; CC(C)(C)c1cc2c3c(c1)Oc1cc4c5c(c1B3c1ccccc1O2)Oc1ccccc1B5c1ccccc1N4c1ccc(-c2cccnc2)cc1]

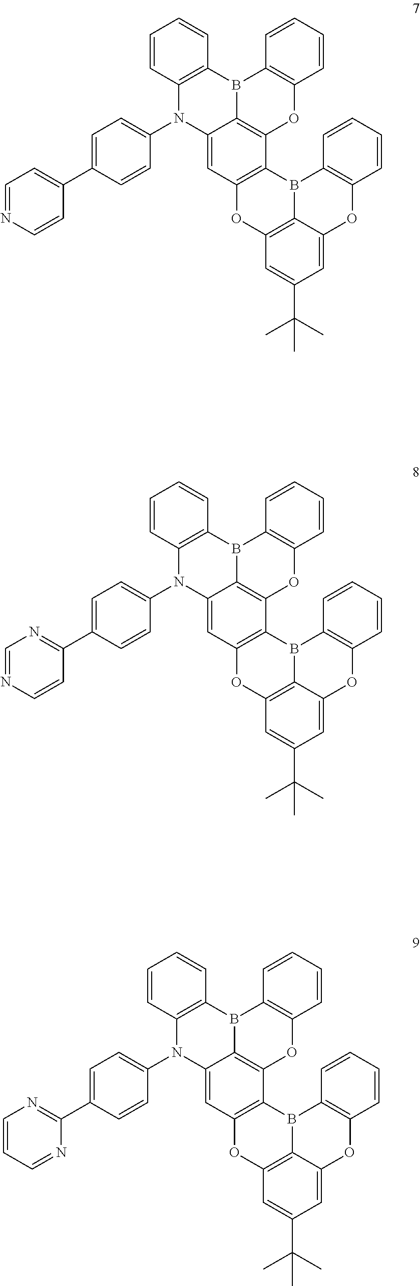 [SMILES: CC(C)(C)c1cc2c3c(c1)Oc1cc4c5c(c1B3c1ccccc1O2)Oc1ccccc1B5c1ccccc1N4c1ccc(-c2ccncc2)cc1 ; CC(C)(C)c1cc2c3c(c1)Oc1cc4c5c(c1B3c1ccccc1O2)Oc1ccccc1B5c1ccccc1N4c1ccc(-c2ccncn2)cc1 ; CC(C)(C)c1cc2c3c(c1)Oc1cc4c5c(c1B3c1ccccc1O2)Oc1ccccc1B5c1ccccc1N4c1ccc(-c2ncccn2)cc1]

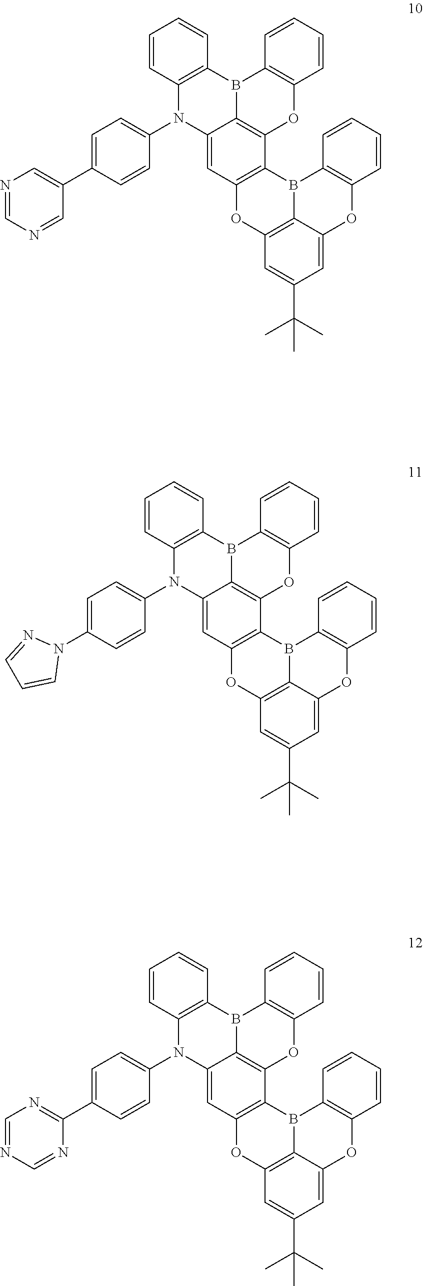 [SMILES: CC(C)(C)c1cc2c3c(c1)Oc1cc4c5c(c1B3c1ccccc1O2)Oc1ccccc1B5c1ccccc1N4c1ccc(-c2cncnc2)cc1 ; CC(C)(C)c1cc2c3c(c1)Oc1cc4c5c(c1B3c1ccccc1O2)Oc1ccccc1B5c1ccccc1N4c1ccc(-n2cccn2)cc1 ; CC(C)(C)c1cc2c3c(c1)Oc1cc4c5c(c1B3c1ccccc1O2)Oc1ccccc1B5c1ccccc1N4c1ccc(-c2ncncn2)cc1]

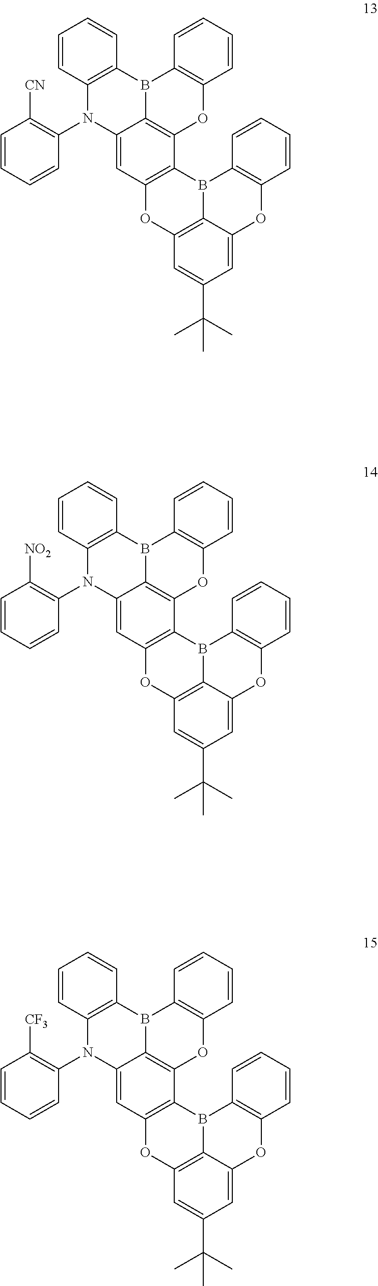 [SMILES: CC(C)(C)c1cc2c3c(c1)Oc1cc4c5c(c1B3c1ccccc1O2)Oc1ccccc1B5c1ccccc1N4c1ccccc1C#N ; CC(C)(C)c1cc2c3c(c1)Oc1cc4c5c(c1B3c1ccccc1O2)Oc1ccccc1B5c1ccccc1N4c1ccccc1[N+](=O)[O-] ; CC(C)(C)c1cc2c3c(c1)Oc1cc4c5c(c1B3c1ccccc1O2)Oc1ccccc1B5c1ccccc1N4c1ccccc1C(F)(F)F]

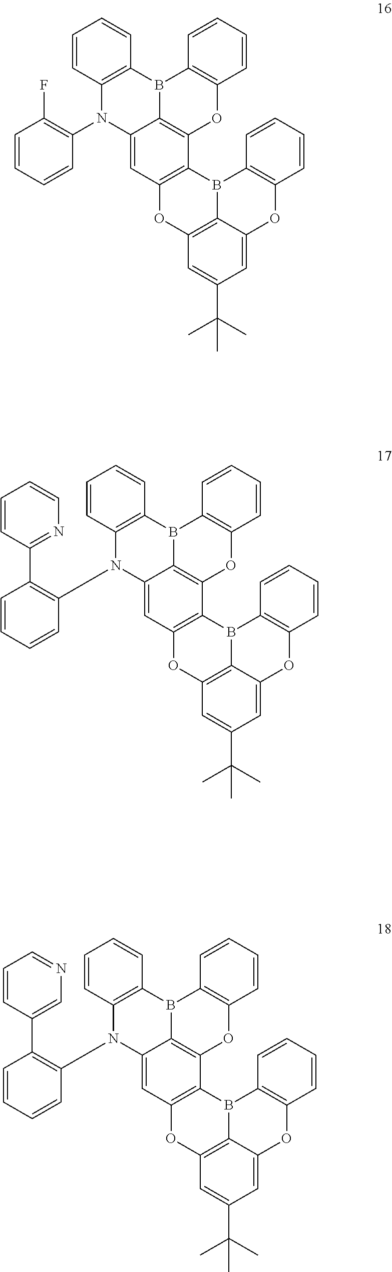 [SMILES: CC(C)(C)c1cc2c3c(c1)Oc1cc4c5c(c1B3c1ccccc1O2)Oc1ccccc1B5c1ccccc1N4c1ccccc1F ; CC(C)(C)c1cc2c3c(c1)Oc1cc4c5c(c1B3c1ccccc1O2)Oc1ccccc1B5c1ccccc1N4c1ccccc1-c1ccccn1 ; CC(C)(C)c1cc2c3c(c1)Oc1cc4c5c(c1B3c1ccccc1O2)Oc1ccccc1B5c1ccccc1N4c1ccccc1-c1cccnc1]

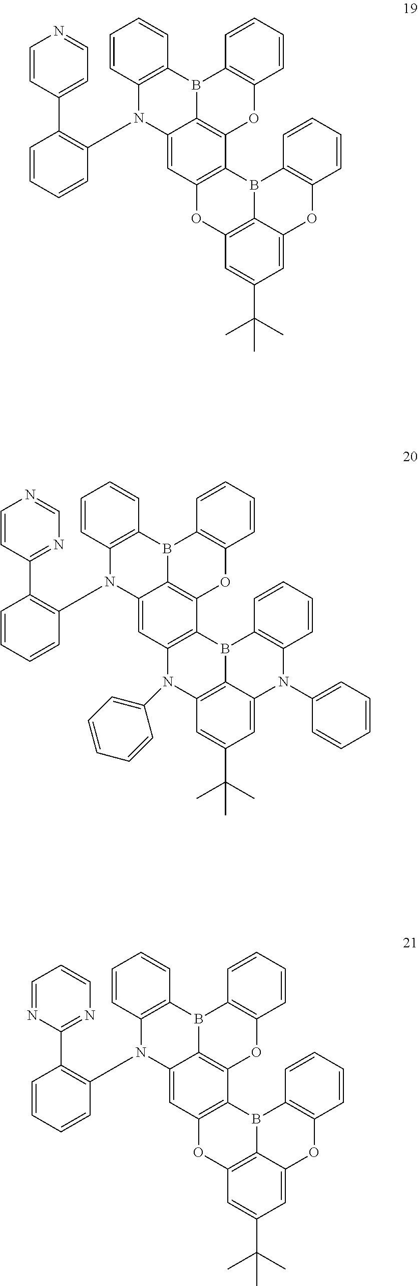 [SMILES: CC(C)(C)c1cc2c3c(c1)Oc1cc4c5c(c1B3c1ccccc1O2)Oc1ccccc1B5c1ccccc1N4c1ccccc1-c1ccncc1 ; CC(C)(C)c1cc2c3c(c1)N(c1ccccc1)c1cc4c5c(c1B3c1ccccc1N2c1ccccc1)Oc1ccccc1B5c1ccccc1N4c1ccccc1-c1ccncn1 ; CC(C)(C)c1cc2c3c(c1)Oc1cc4c5c(c1B3c1ccccc1O2)Oc1ccccc1B5c1ccccc1N4c1ccccc1-c1ncccn1]

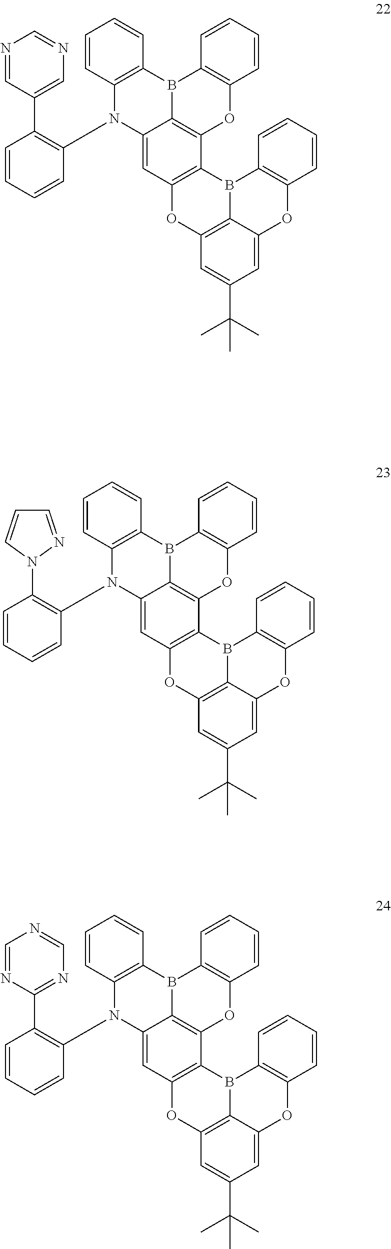 [SMILES: CC(C)(C)c1cc2c3c(c1)Oc1cc4c5c(c1B3c1ccccc1O2)Oc1ccccc1B5c1ccccc1N4c1ccccc1-c1cncnc1 ; CC(C)(C)c1cc2c3c(c1)Oc1cc4c5c(c1B3c1ccccc1O2)Oc1ccccc1B5c1ccccc1N4c1ccccc1-n1cccn1 ; CC(C)(C)c1cc2c3c(c1)Oc1cc4c5c(c1B3c1ccccc1O2)Oc1ccccc1B5c1ccccc1N4c1ccccc1-c1ncncn1]

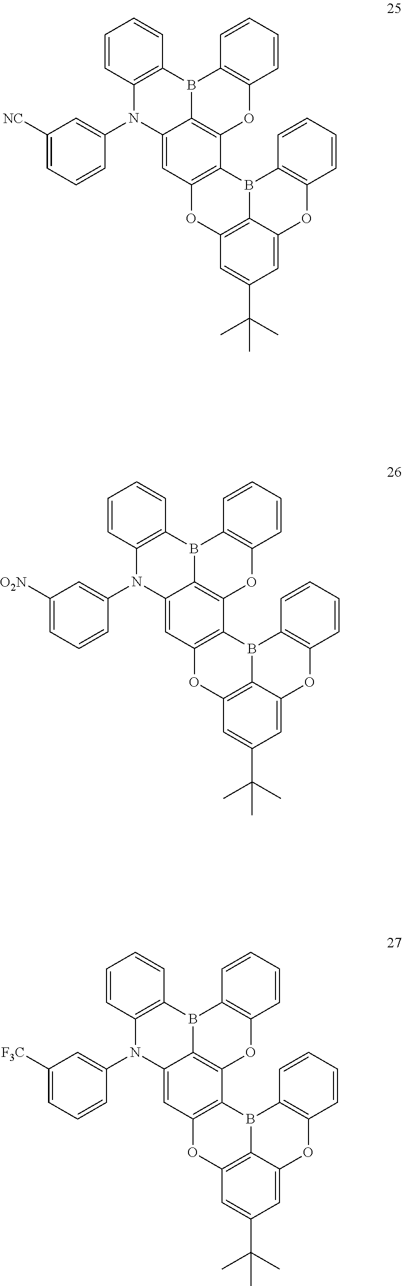 [SMILES: CC(C)(C)c1cc2c3c(c1)Oc1cc4c5c(c1B3c1ccccc1O2)Oc1ccccc1B5c1ccccc1N4c1cccc(C#N)c1 ; CC(C)(C)c1cc2c3c(c1)Oc1cc4c5c(c1B3c1ccccc1O2)Oc1ccccc1B5c1ccccc1N4c1cccc([N+](=O)[O-])c1 ; CC(C)(C)c1cc2c3c(c1)Oc1cc4c5c(c1B3c1ccccc1O2)Oc1ccccc1B5c1ccccc1N4c1cccc(C(F)(F)F)c1]

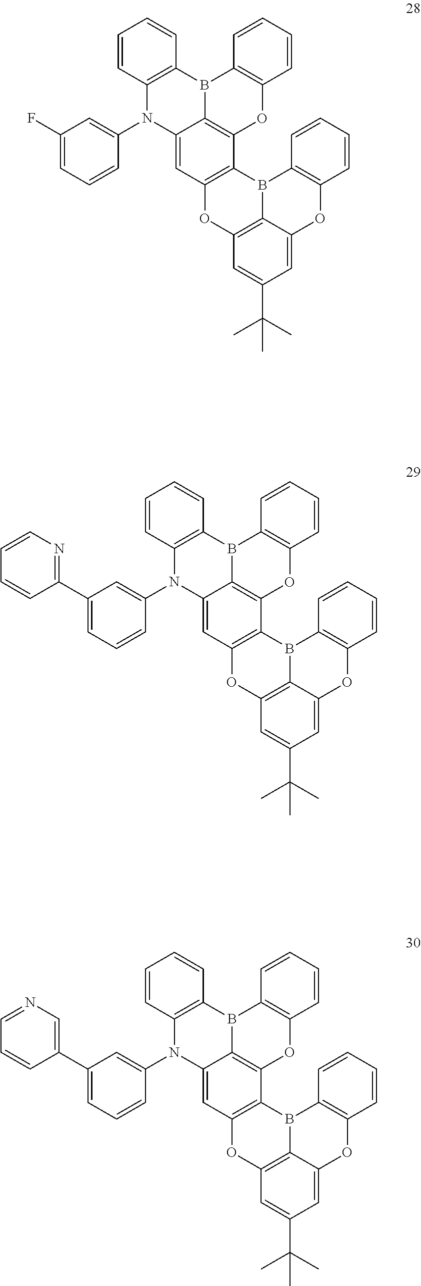 [SMILES: CC(C)(C)c1cc2c3c(c1)Oc1cc4c5c(c1B3c1ccccc1O2)Oc1ccccc1B5c1ccccc1N4c1cccc(F)c1 ; CC(C)(C)c1cc2c3c(c1)Oc1cc4c5c(c1B3c1ccccc1O2)Oc1ccccc1B5c1ccccc1N4c1cccc(-c2ccccn2)c1 ; CC(C)(C)c1cc2c3c(c1)Oc1cc4c5c(c1B3c1ccccc1O2)Oc1ccccc1B5c1ccccc1N4c1cccc(-c2cccnc2)c1]

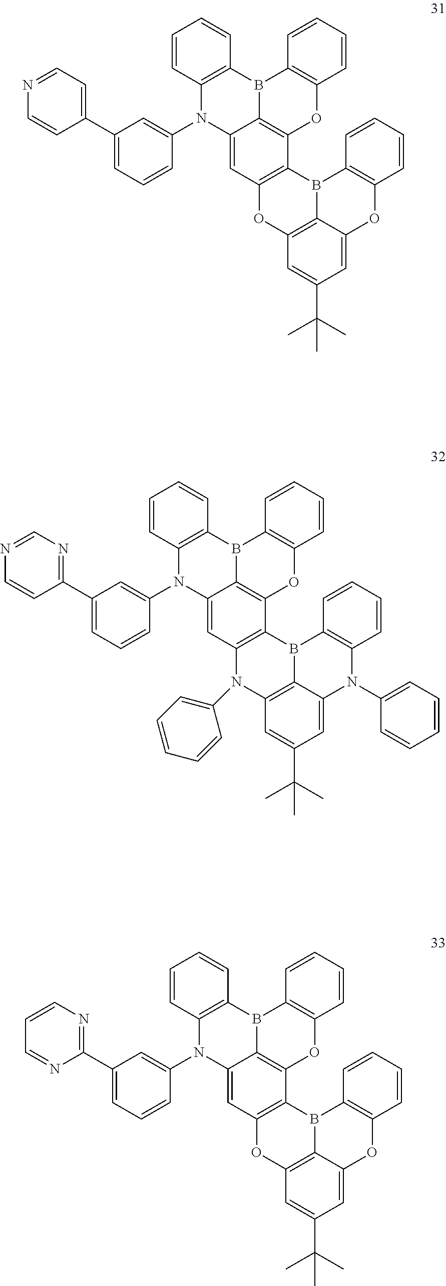 [SMILES: CC(C)(C)c1cc2c3c(c1)Oc1cc4c5c(c1B3c1ccccc1O2)Oc1ccccc1B5c1ccccc1N4c1cccc(-c2ccncc2)c1 ; CC(C)(C)c1cc2c3c(c1)N(c1ccccc1)c1cc4c5c(c1B3c1ccccc1N2c1ccccc1)Oc1ccccc1B5c1ccccc1N4c1cccc(-c2ccncn2)c1 ; CC(C)(C)c1cc2c3c(c1)Oc1cc4c5c(c1B3c1ccccc1O2)Oc1ccccc1B5c1ccccc1N4c1cccc(-c2ncccn2)c1]

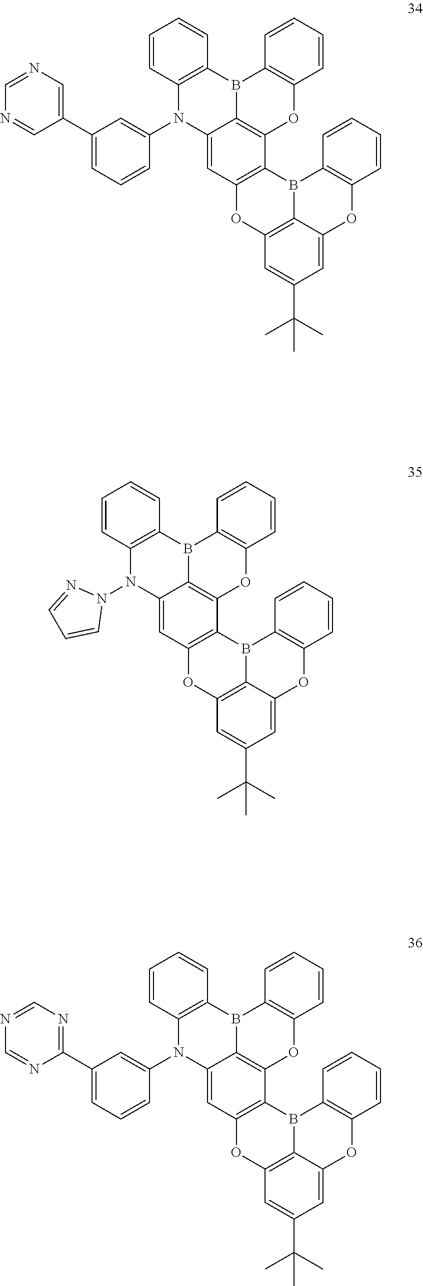 [SMILES: CC(C)(C)c1cc2c3c(c1)Oc1cc4c5c(c1B3c1ccccc1O2)Oc1ccccc1B5c1ccccc1N4c1cccc(-c2cncnc2)c1 ; CC(C)(C)c1cc2c3c(c1)Oc1cc4c5c(c1B3c1ccccc1O2)Oc1ccccc1B5c1ccccc1N4n1cccn1 ; CC(C)(C)c1cc2c3c(c1)Oc1cc4c5c(c1B3c1ccccc1O2)Oc1ccccc1B5c1ccccc1N4c1cccc(-c2ncncn2)c1]

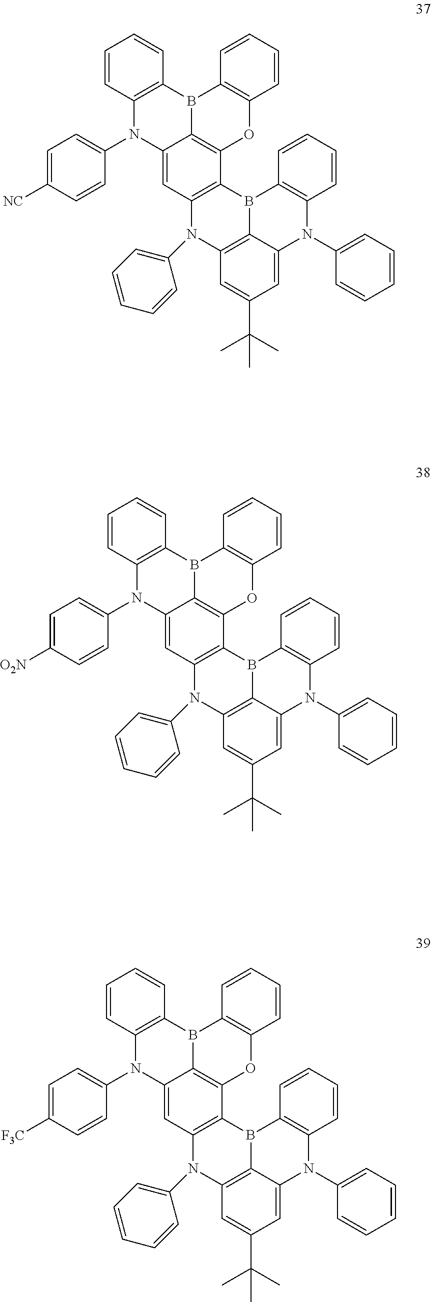 [SMILES: CC(C)(C)c1cc2c3c(c1)N(c1ccccc1)c1cc4c5c(c1B3c1ccccc1N2c1ccccc1)Oc1ccccc1B5c1ccccc1N4c1ccc(C#N)cc1 ; CC(C)(C)c1cc2c3c(c1)N(c1ccccc1)c1cc4c5c(c1B3c1ccccc1N2c1ccccc1)Oc1ccccc1B5c1ccccc1N4c1ccc([N+](=O)[O-])cc1 ; CC(C)(C)c1cc2c3c(c1)N(c1ccccc1)c1cc4c5c(c1B3c1ccccc1N2c1ccccc1)Oc1ccccc1B5c1ccccc1N4c1ccc(C(F)(F)F)cc1]

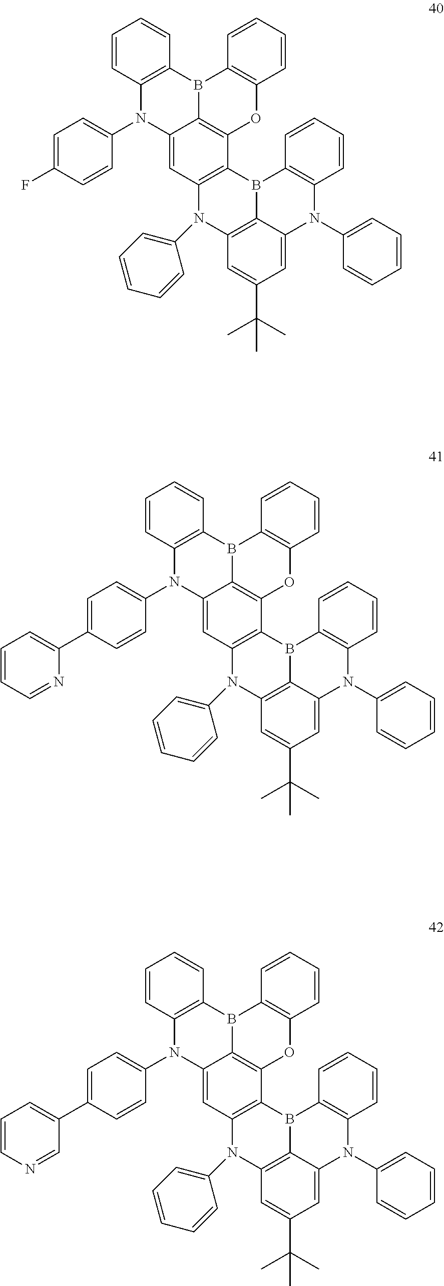 [SMILES: CC(C)(C)c1cc2c3c(c1)N(c1ccccc1)c1cc4c5c(c1B3c1ccccc1N2c1ccccc1)Oc1ccccc1B5c1ccccc1N4c1ccc(F)cc1 ; CC(C)(C)c1cc2c3c(c1)N(c1ccccc1)c1cc4c5c(c1B3c1ccccc1N2c1ccccc1)Oc1ccccc1B5c1ccccc1N4c1ccc(-c2ccccn2)cc1 ; CC(C)(C)c1cc2c3c(c1)N(c1ccccc1)c1cc4c5c(c1B3c1ccccc1N2c1ccccc1)Oc1ccccc1B5c1ccccc1N4c1ccc(-c2cccnc2)cc1]

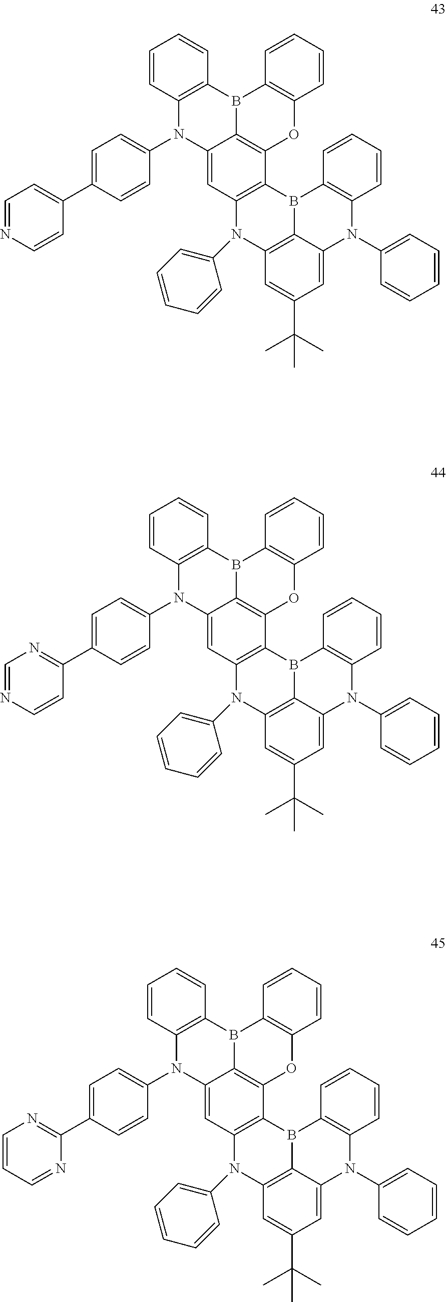 [SMILES: CC(C)(C)c1cc2c3c(c1)N(c1ccccc1)c1cc4c5c(c1B3c1ccccc1N2c1ccccc1)Oc1ccccc1B5c1ccccc1N4c1ccc(-c2ccncc2)cc1 ; CC(C)(C)c1cc2c3c(c1)N(c1ccccc1)c1cc4c5c(c1B3c1ccccc1N2c1ccccc1)Oc1ccccc1B5c1ccccc1N4c1ccc(-c2ccncn2)cc1 ; CC(C)(C)c1cc2c3c(c1)N(c1ccccc1)c1cc4c5c(c1B3c1ccccc1N2c1ccccc1)Oc1ccccc1B5c1ccccc1N4c1ccc(-c2ncccn2)cc1]

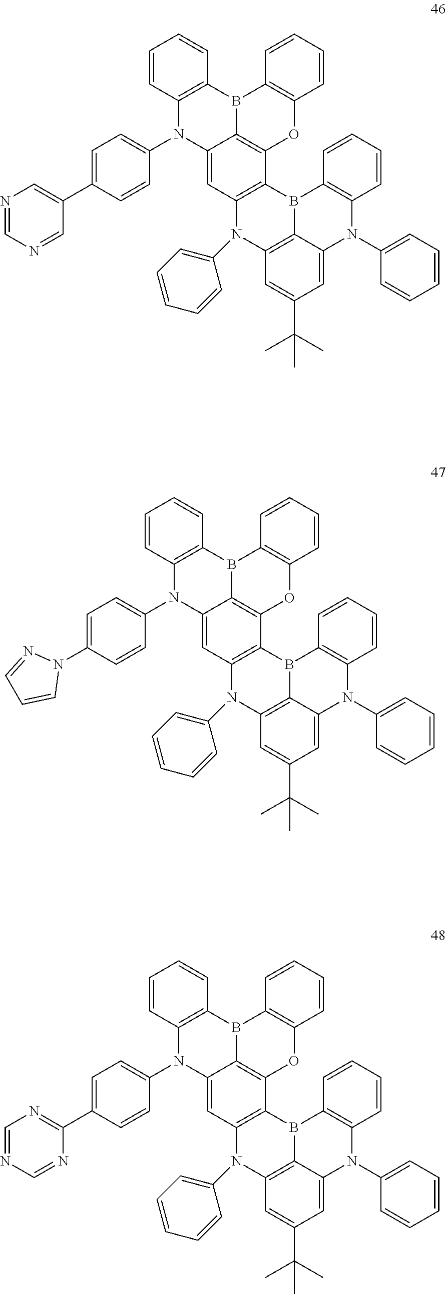 [SMILES: CC(C)(C)c1cc2c3c(c1)N(c1ccccc1)c1cc4c5c(c1B3c1ccccc1N2c1ccccc1)Oc1ccccc1B5c1ccccc1N4c1ccc(-c2cncnc2)cc1 ; CC(C)(C)c1cc2c3c(c1)N(c1ccccc1)c1cc4c5c(c1B3c1ccccc1N2c1ccccc1)Oc1ccccc1B5c1ccccc1N4c1ccc(-n2cccn2)cc1 ; CC(C)(C)c1cc2c3c(c1)N(c1ccccc1)c1cc4c5c(c1B3c1ccccc1N2c1ccccc1)Oc1ccccc1B5c1ccccc1N4c1ccc(-c2ncncn2)cc1]

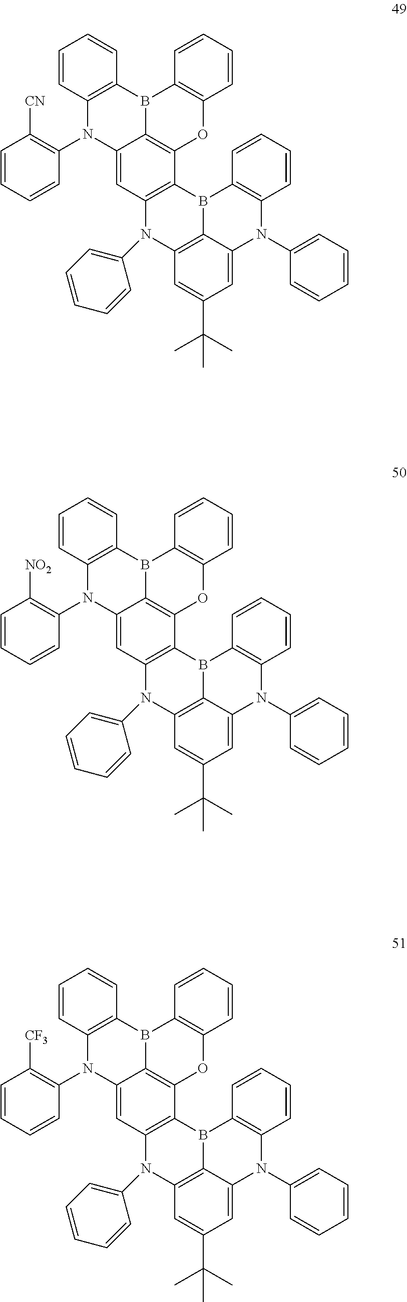 [SMILES: CC(C)(C)c1cc2c3c(c1)N(c1ccccc1)c1cc4c5c(c1B3c1ccccc1N2c1ccccc1)Oc1ccccc1B5c1ccccc1N4c1ccccc1C#N ; CC(C)(C)c1cc2c3c(c1)N(c1ccccc1)c1cc4c5c(c1B3c1ccccc1N2c1ccccc1)Oc1ccccc1B5c1ccccc1N4c1ccccc1[N+](=O)[O-] ; CC(C)(C)c1cc2c3c(c1)N(c1ccccc1)c1cc4c5c(c1B3c1ccccc1N2c1ccccc1)Oc1ccccc1B5c1ccccc1N4c1ccccc1C(F)(F)F]

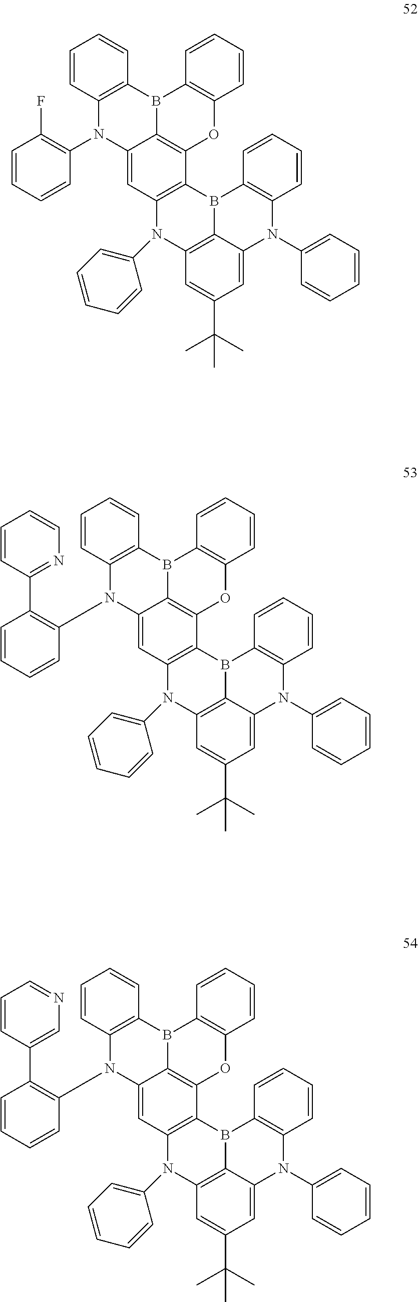 [SMILES: CC(C)(C)c1cc2c3c(c1)N(c1ccccc1)c1cc4c5c(c1B3c1ccccc1N2c1ccccc1)Oc1ccccc1B5c1ccccc1N4c1ccccc1F ; CC(C)(C)c1cc2c3c(c1)N(c1ccccc1)c1cc4c5c(c1B3c1ccccc1N2c1ccccc1)Oc1ccccc1B5c1ccccc1N4c1ccccc1-c1ccccn1 ; CC(C)(C)c1cc2c3c(c1)N(c1ccccc1)c1cc4c5c(c1B3c1ccccc1N2c1ccccc1)Oc1ccccc1B5c1ccccc1N4c1ccccc1-c1cccnc1]

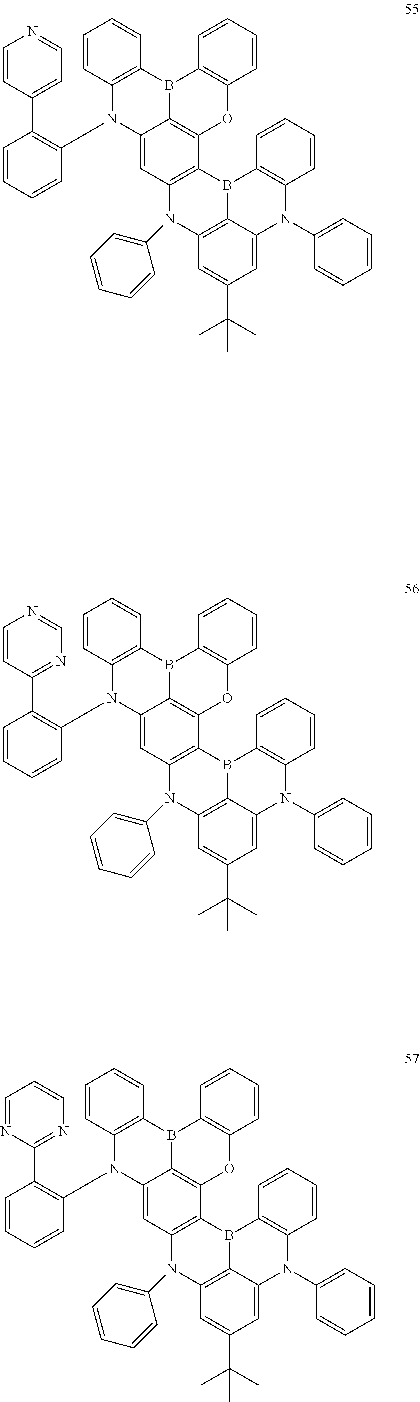 [SMILES: CC(C)(C)c1cc2c3c(c1)N(c1ccccc1)c1cc4c5c(c1B3c1ccccc1N2c1ccccc1)Oc1ccccc1B5c1ccccc1N4c1ccccc1-c1ccncc1 ; CC(C)(C)c1cc2c3c(c1)N(c1ccccc1)c1cc4c5c(c1B3c1ccccc1N2c1ccccc1)Oc1ccccc1B5c1ccccc1N4c1ccccc1-c1ccncn1 ; CC(C)(C)c1cc2c3c(c1)N(c1ccccc1)c1cc4c5c(c1B3c1ccccc1N2c1ccccc1)Oc1ccccc1B5c1ccccc1N4c1ccccc1-c1ncccn1]

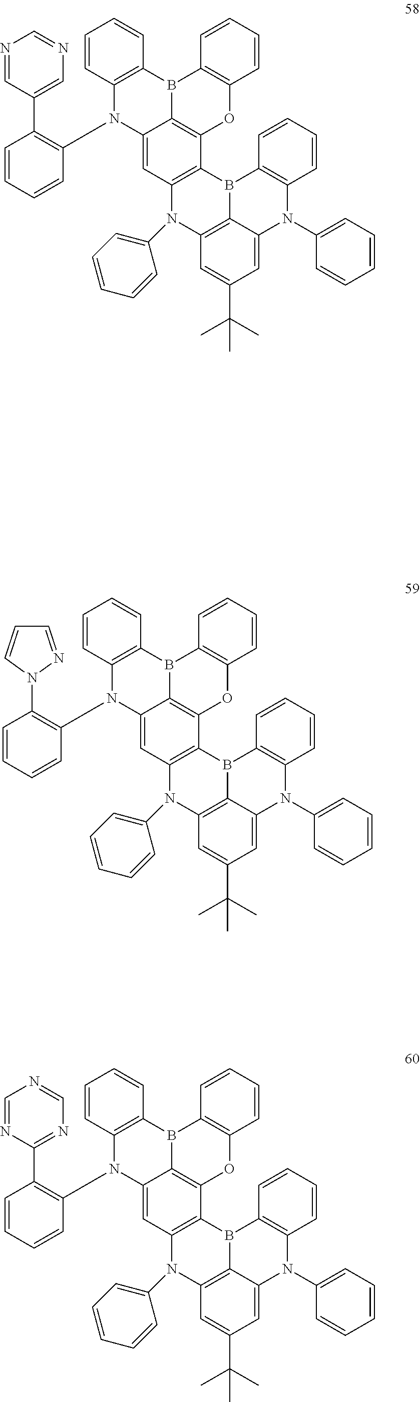 [SMILES: CC(C)(C)c1cc2c3c(c1)N(c1ccccc1)c1cc4c5c(c1B3c1ccccc1N2c1ccccc1)Oc1ccccc1B5c1ccccc1N4c1ccccc1-c1cncnc1 ; CC(C)(C)c1cc2c3c(c1)N(c1ccccc1)c1cc4c5c(c1B3c1ccccc1N2c1ccccc1)Oc1ccccc1B5c1ccccc1N4c1ccccc1-n1cccn1 ; CC(C)(C)c1cc2c3c(c1)N(c1ccccc1)c1cc4c5c(c1B3c1ccccc1N2c1ccccc1)Oc1ccccc1B5c1ccccc1N4c1ccccc1-c1ncncn1]

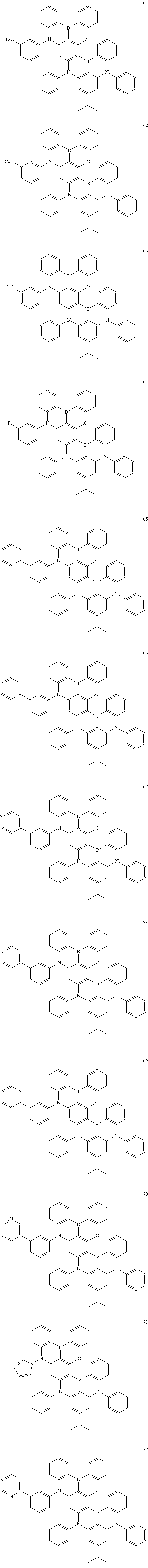

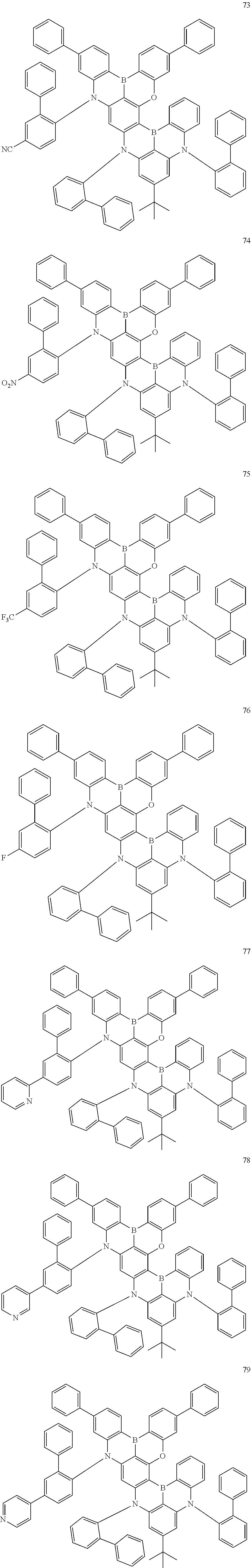

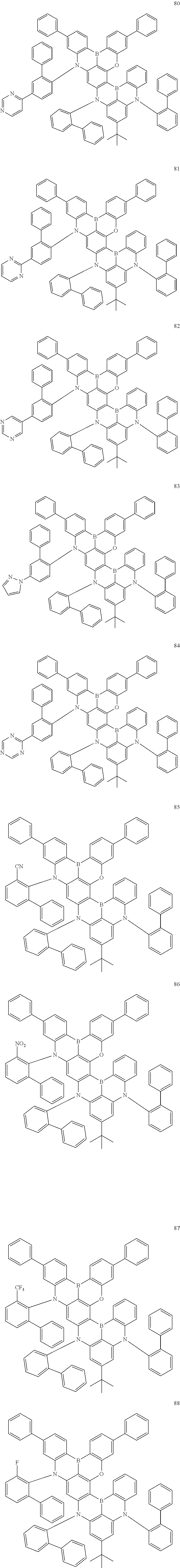

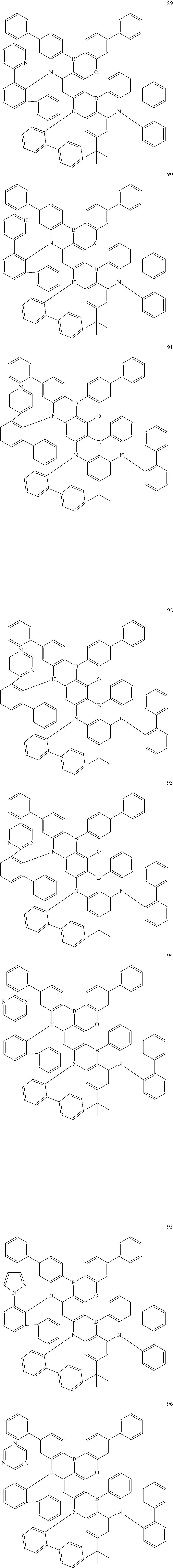

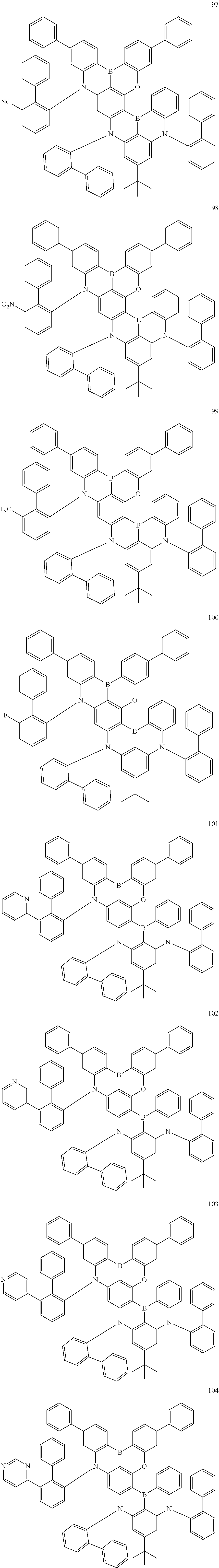

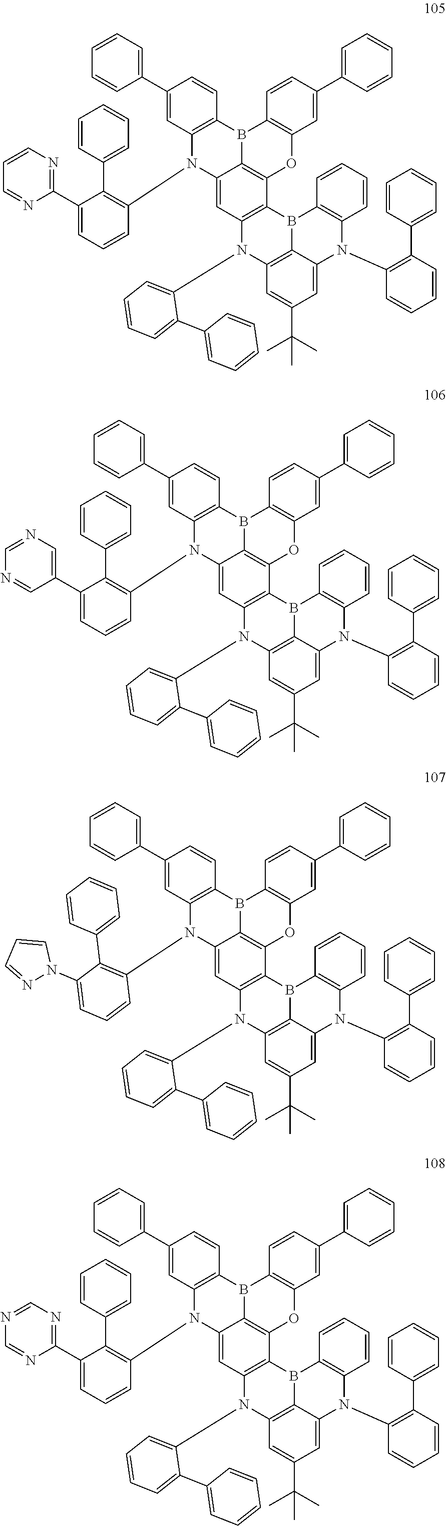

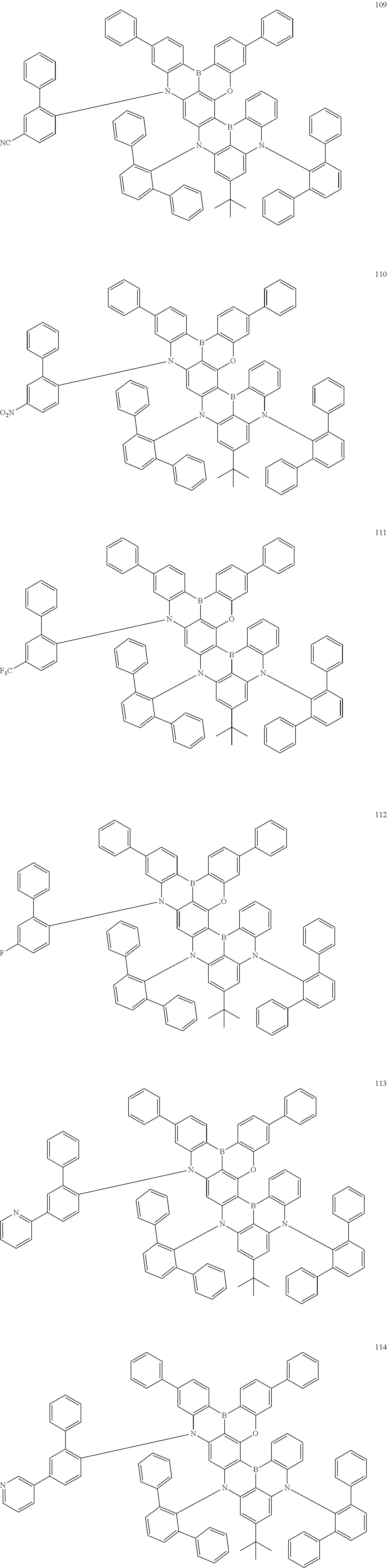

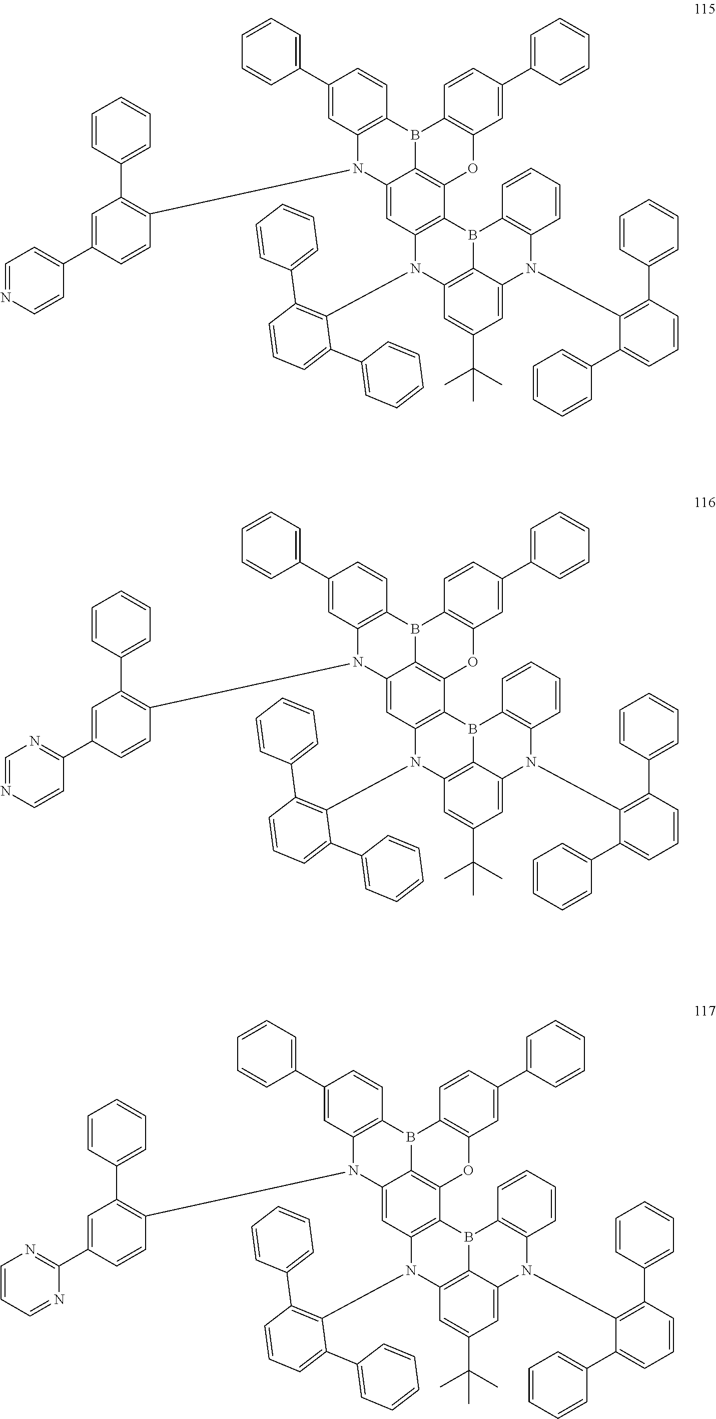

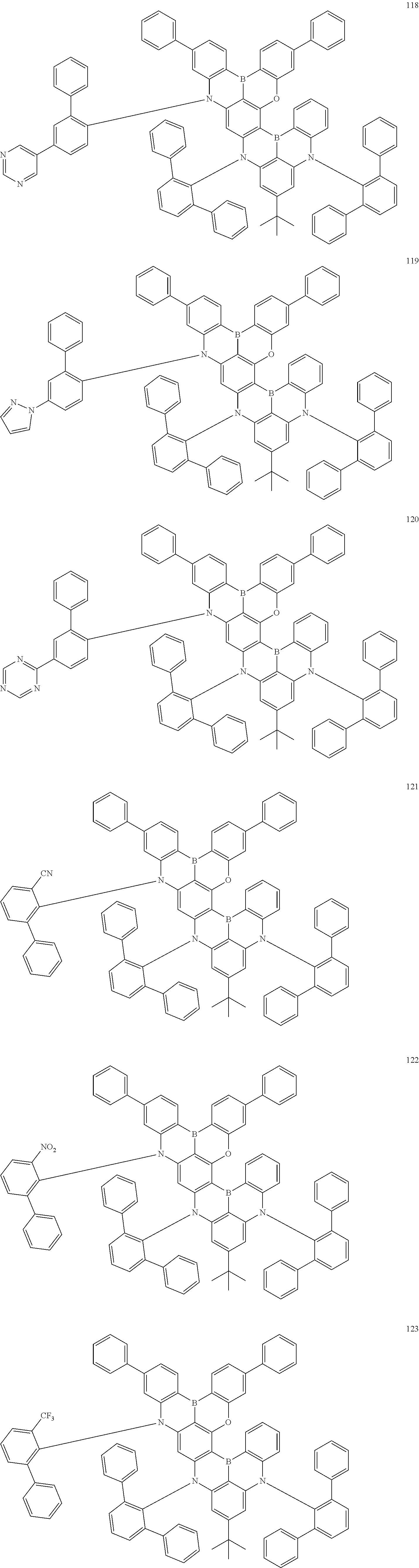

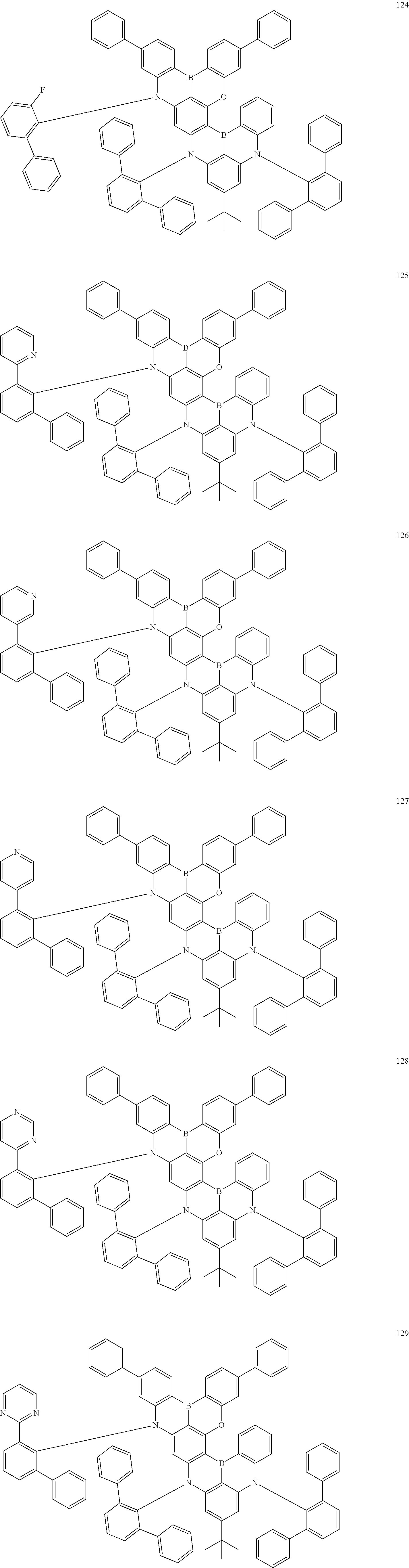

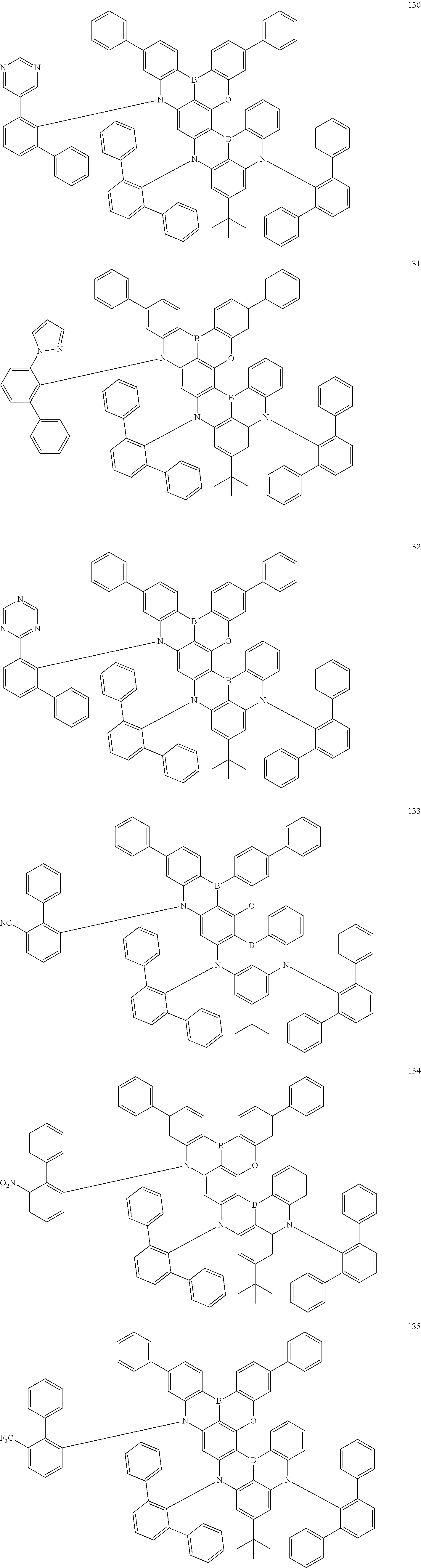

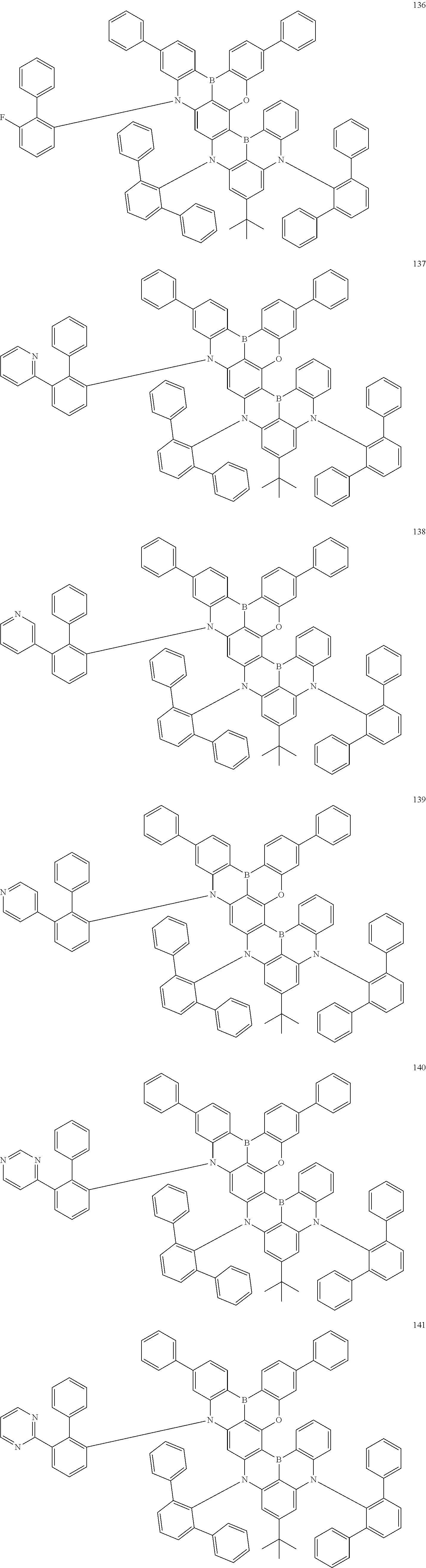

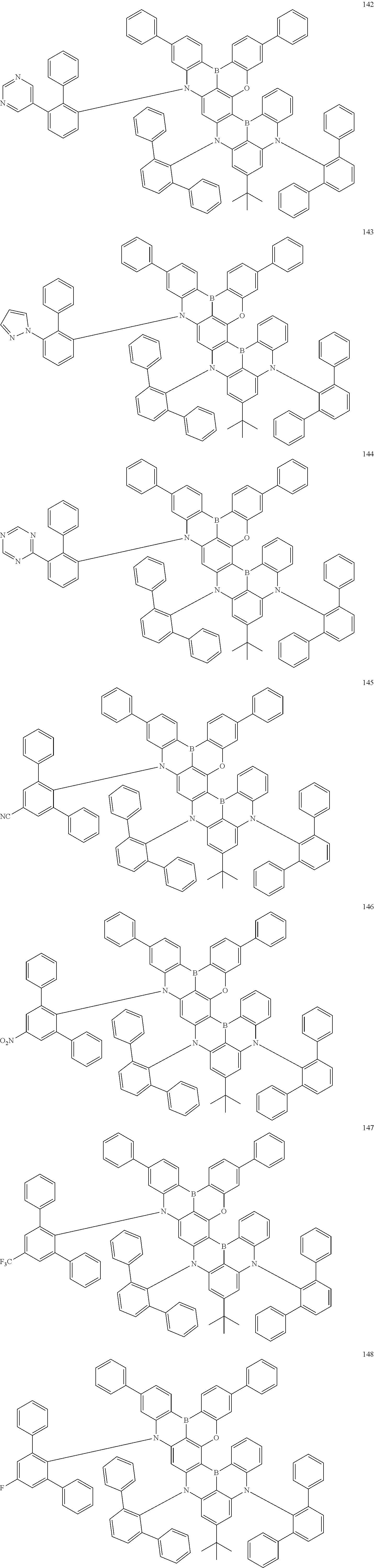

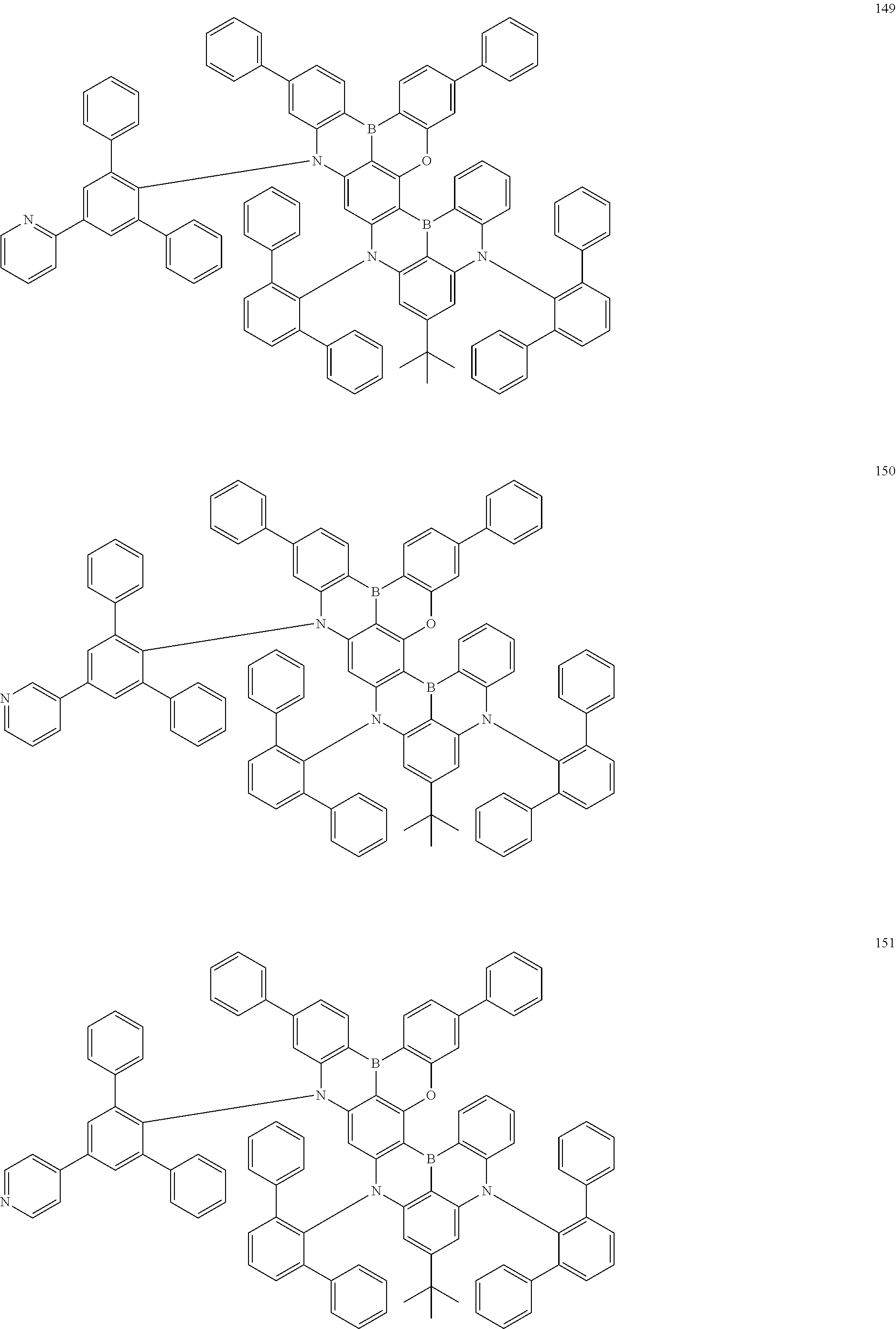

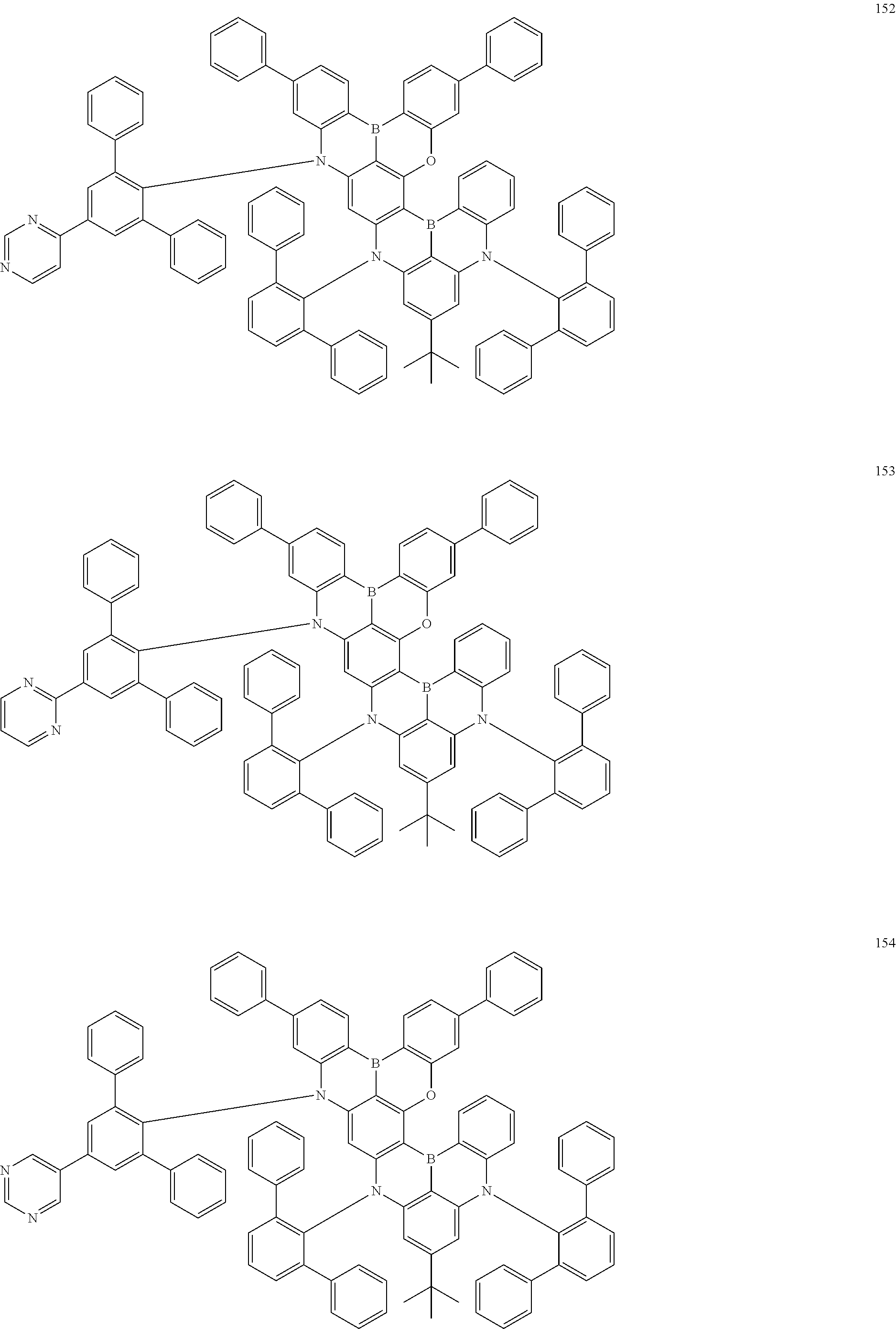

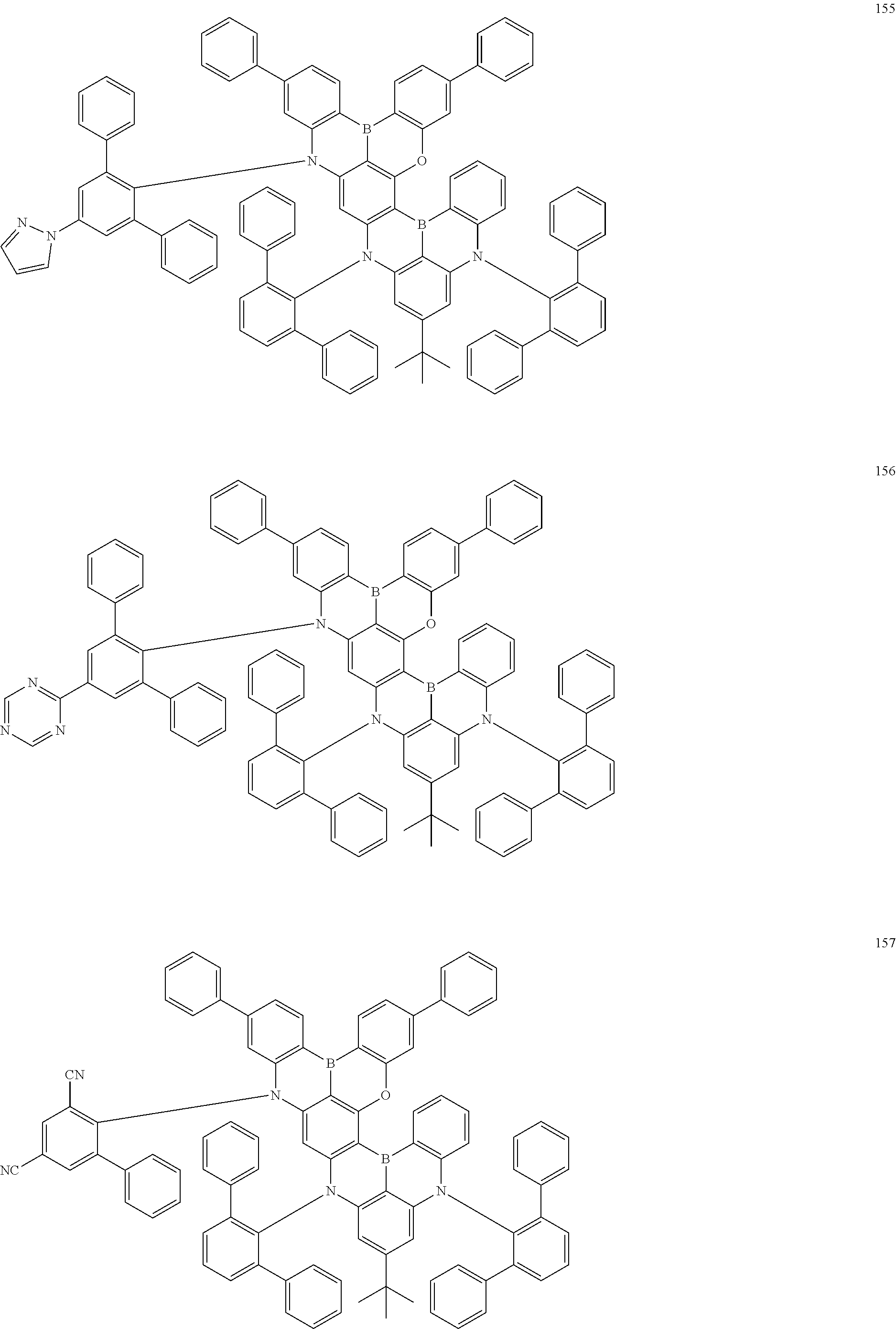

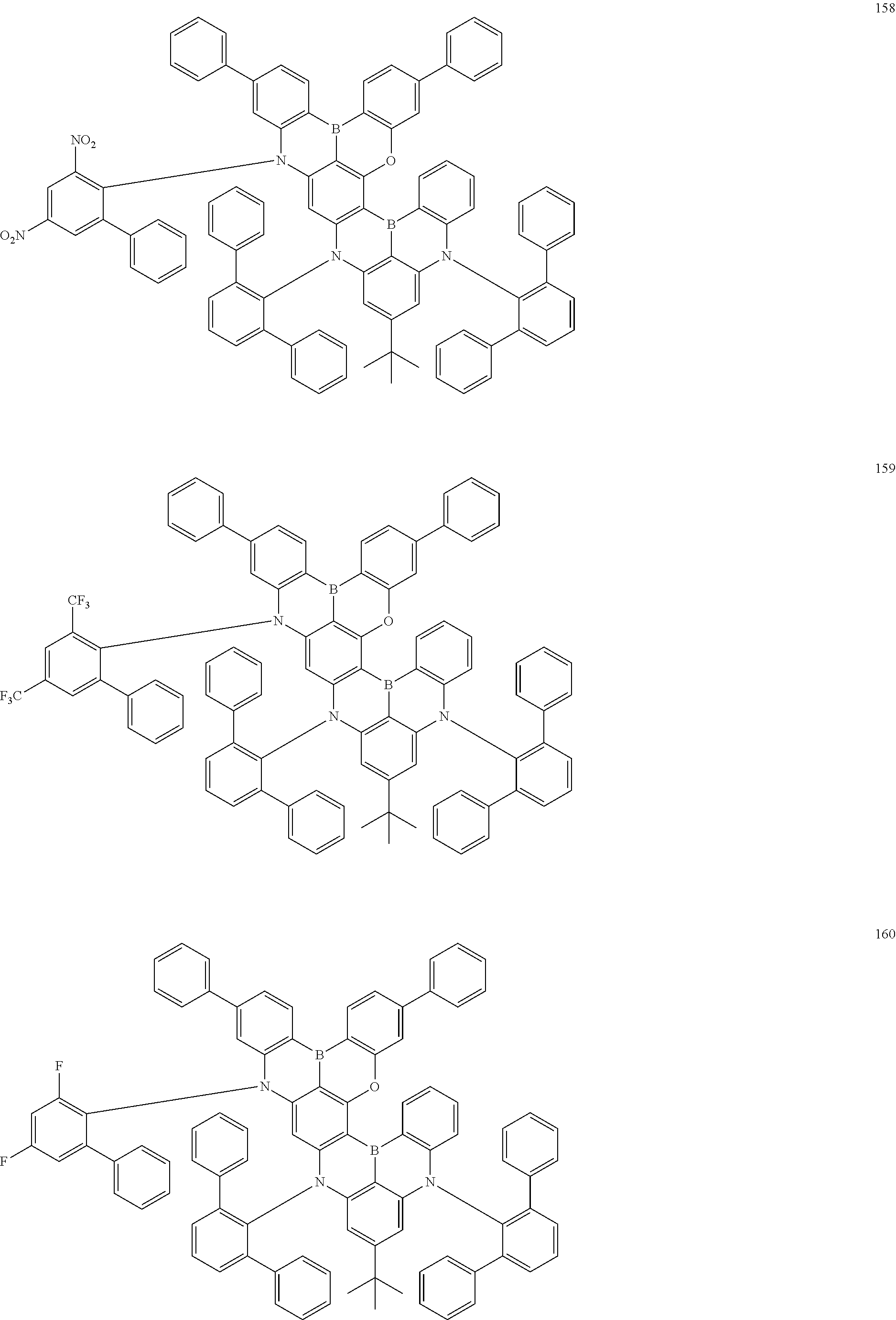

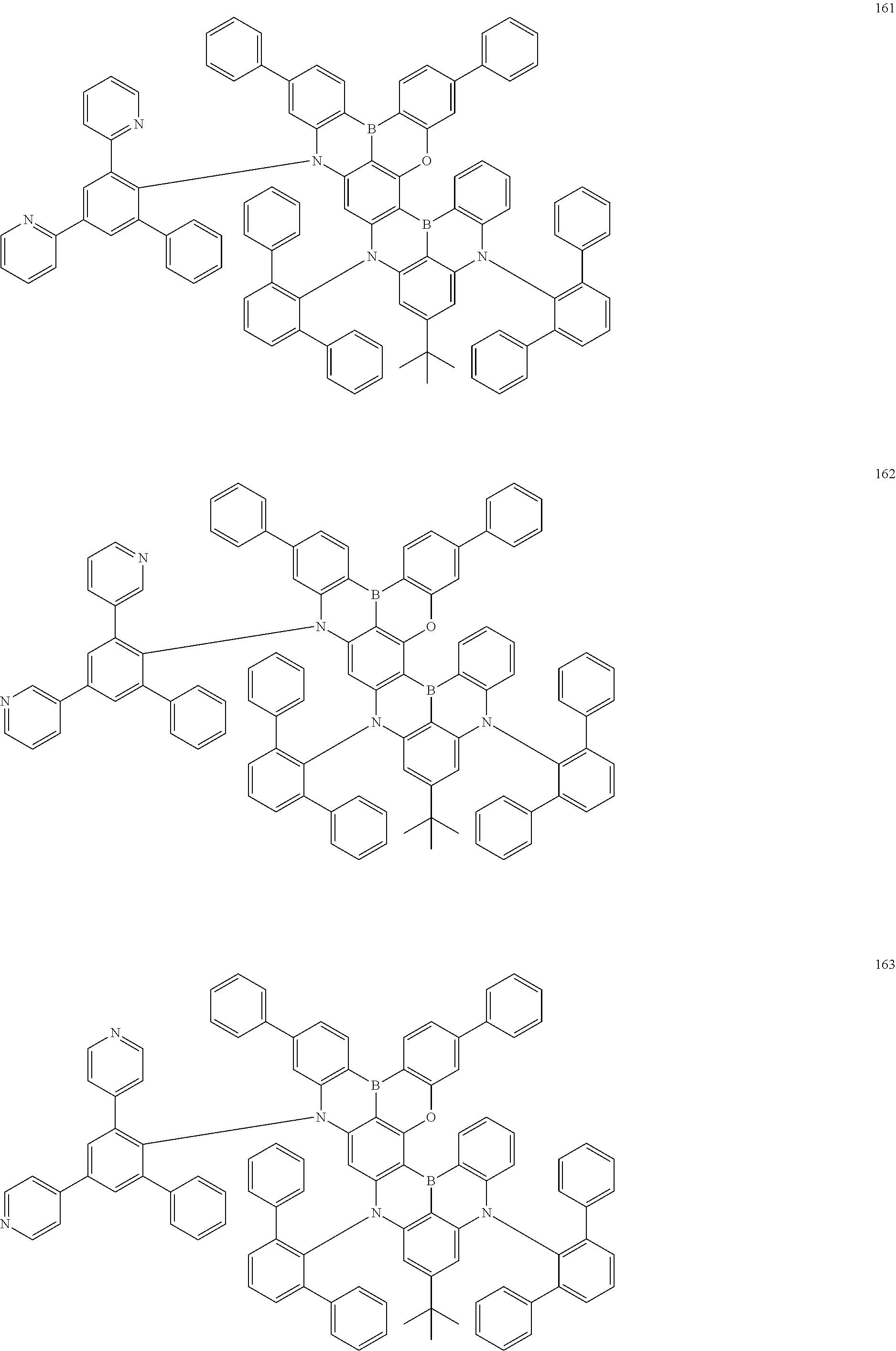

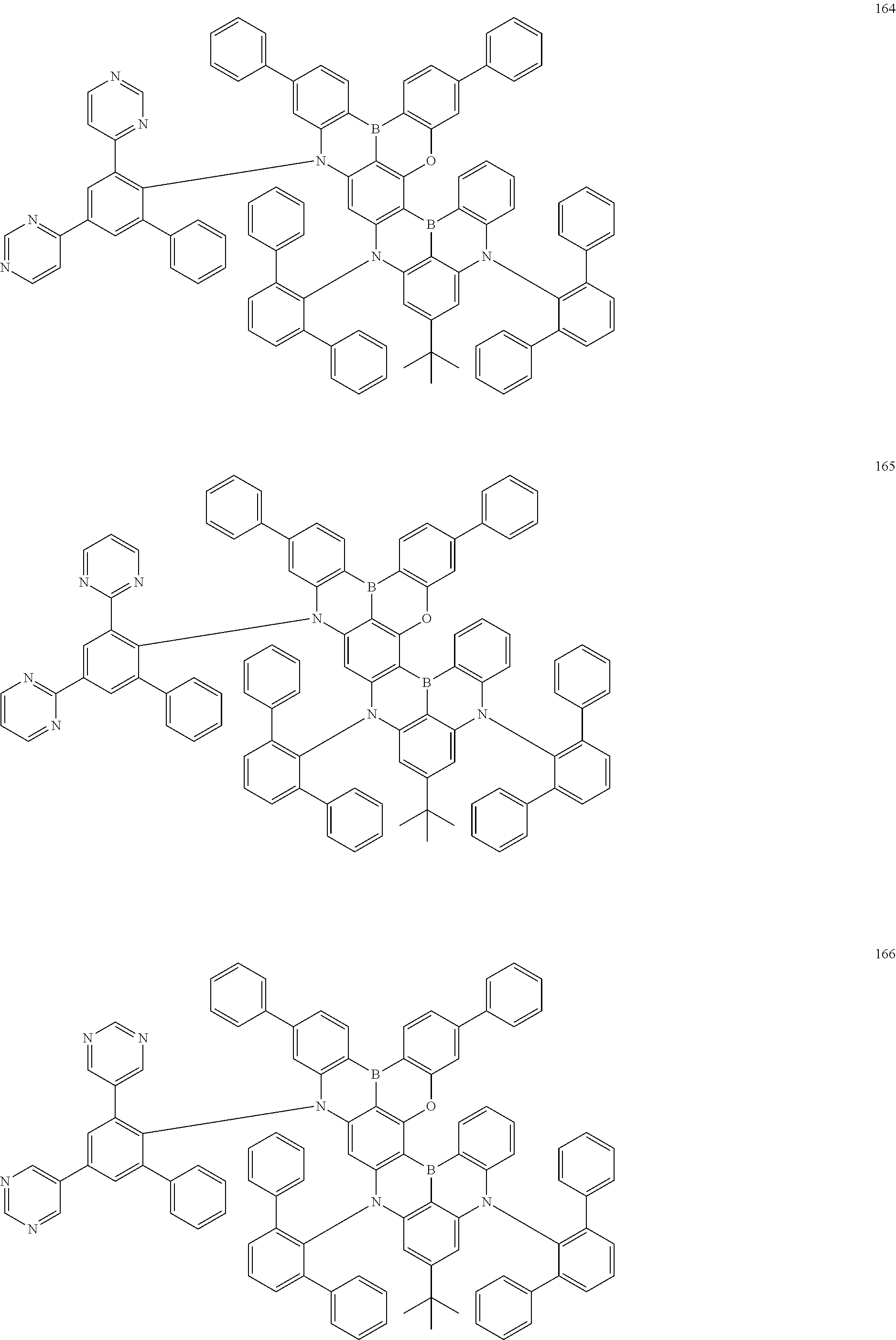

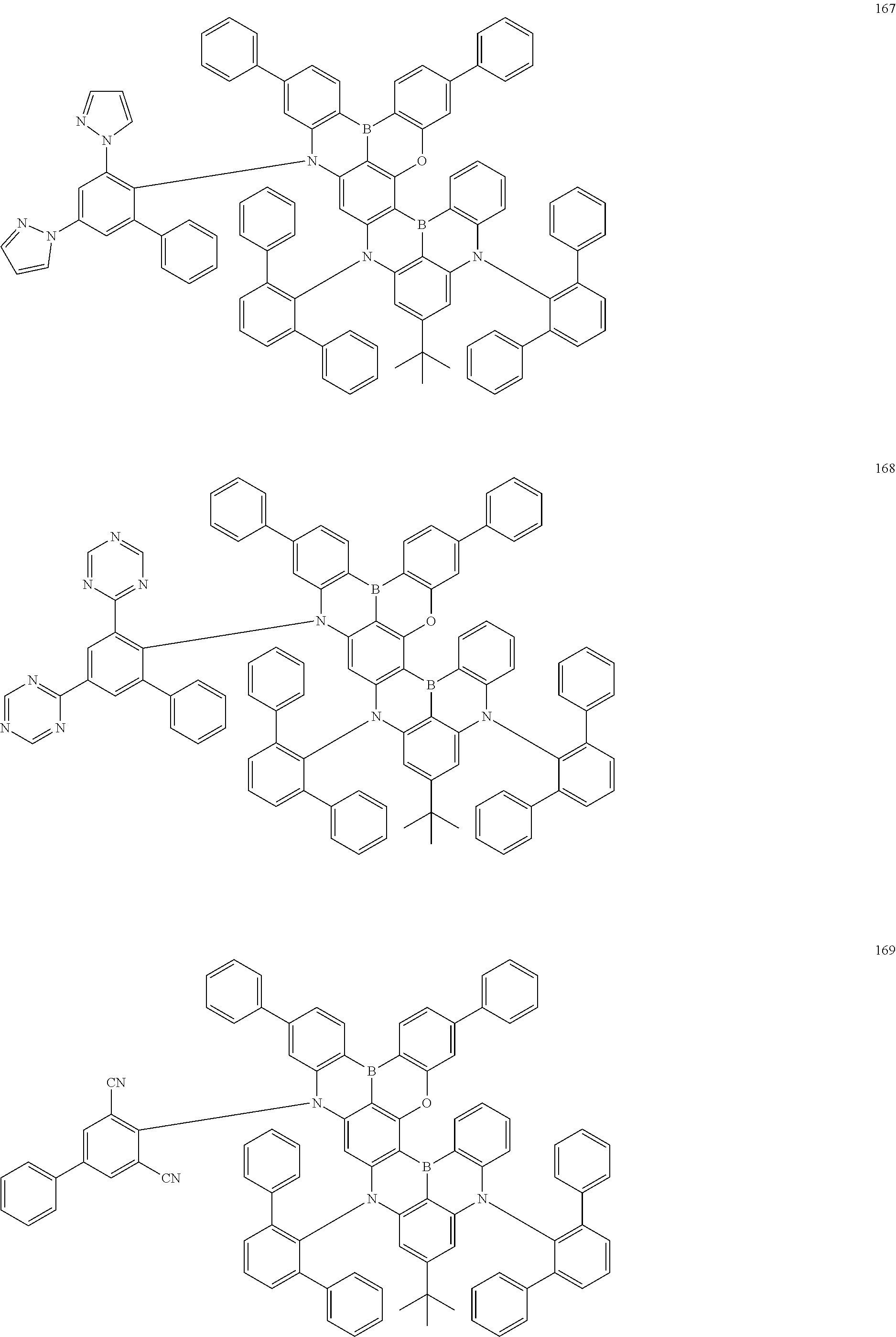

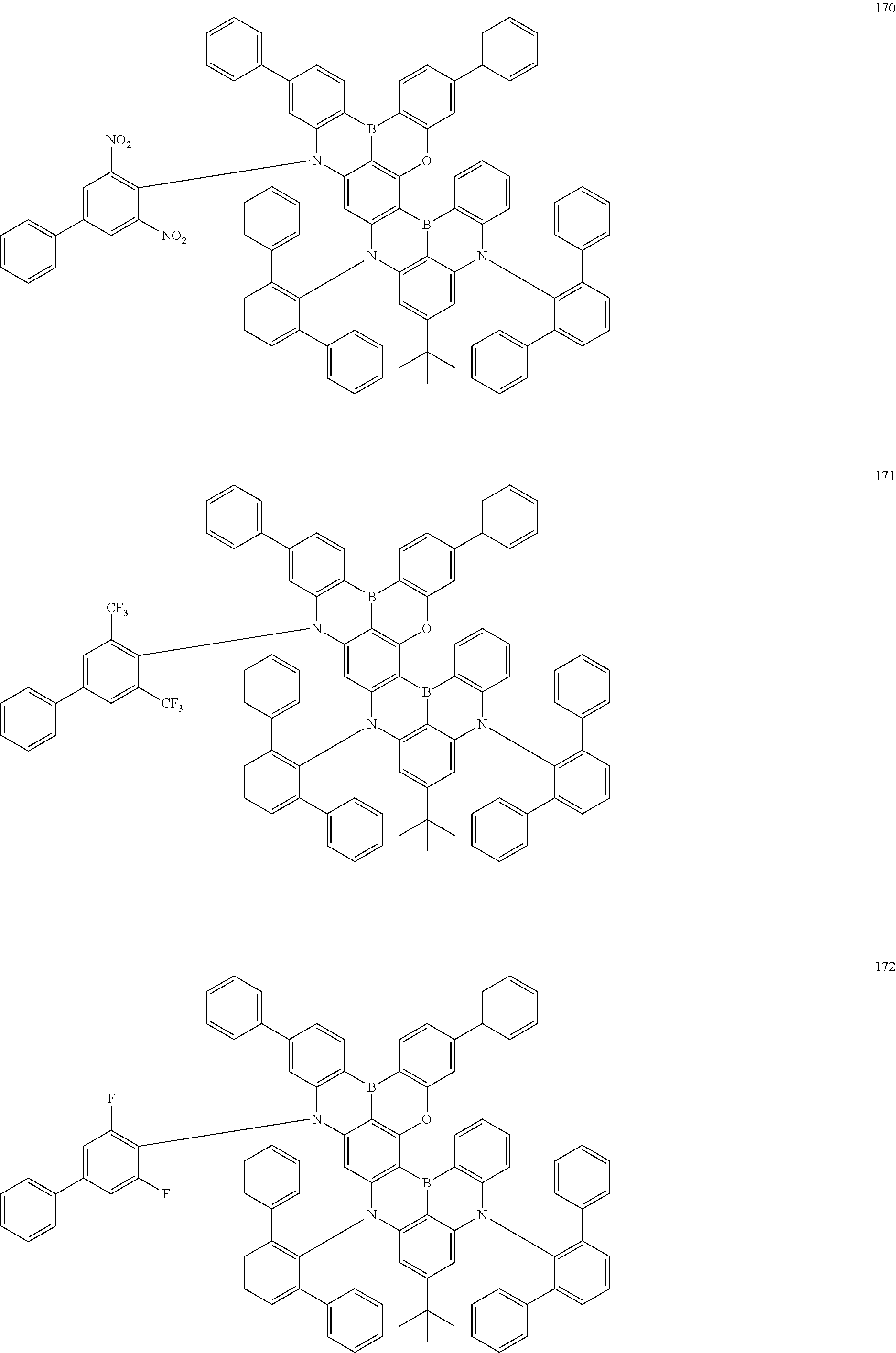

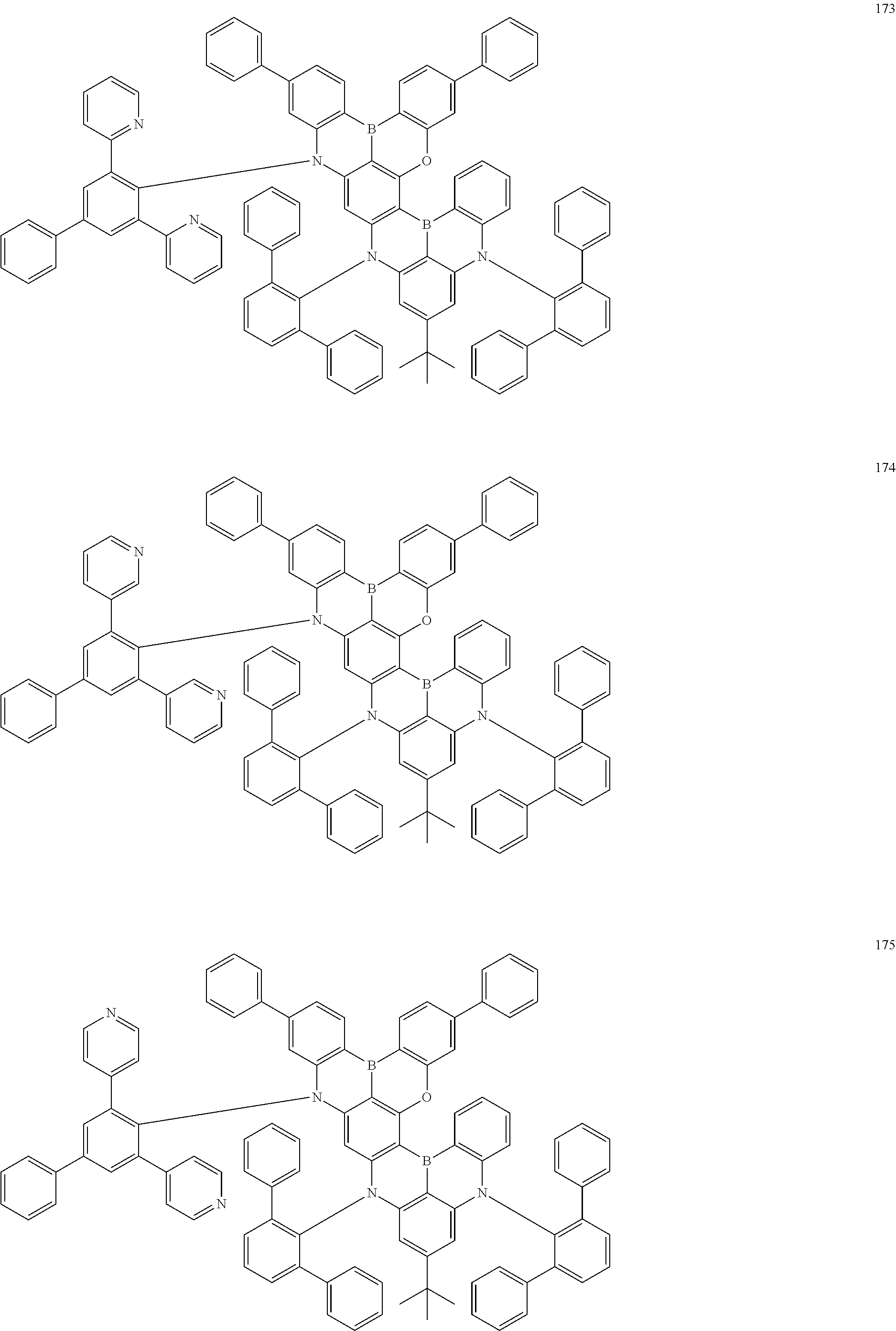

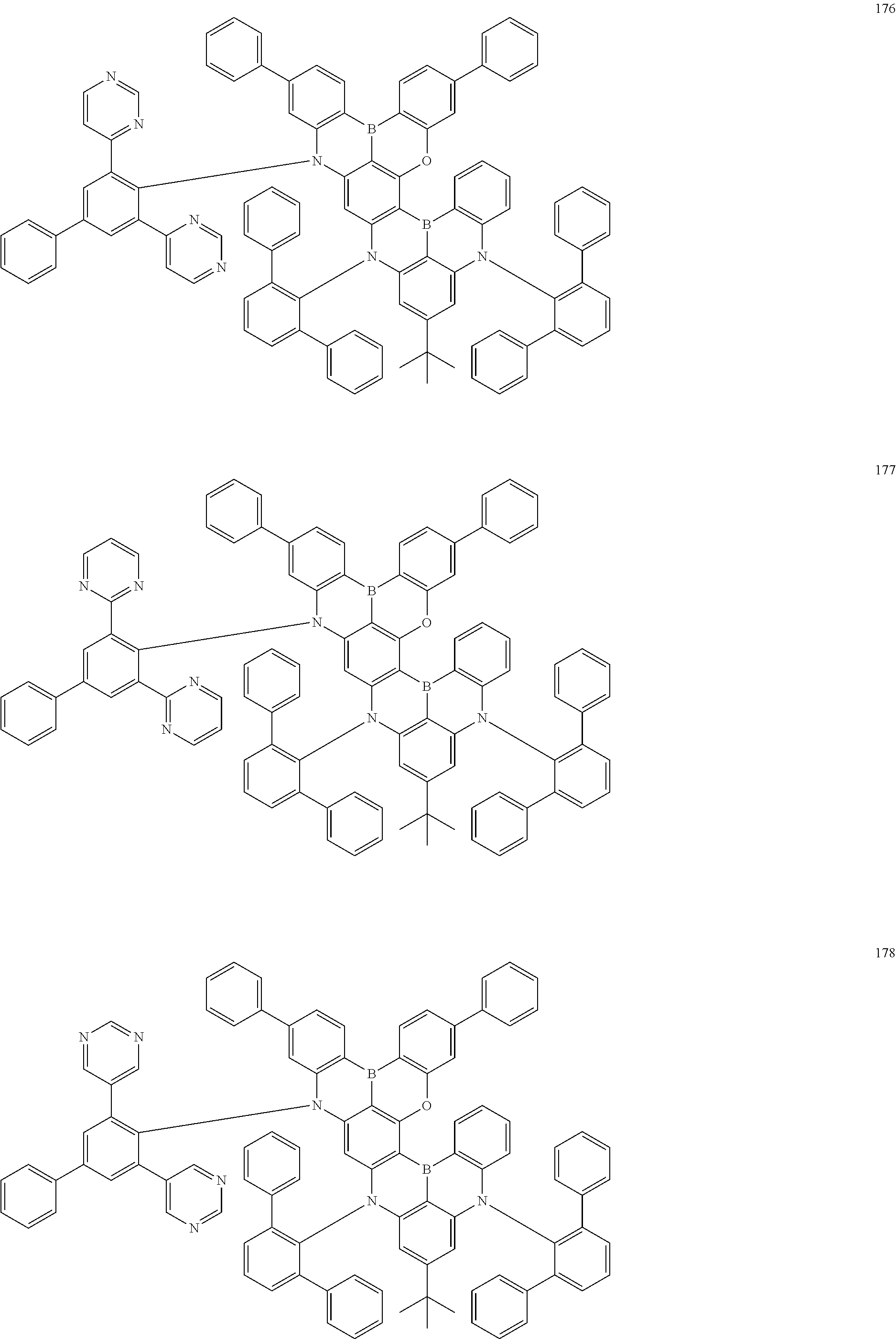

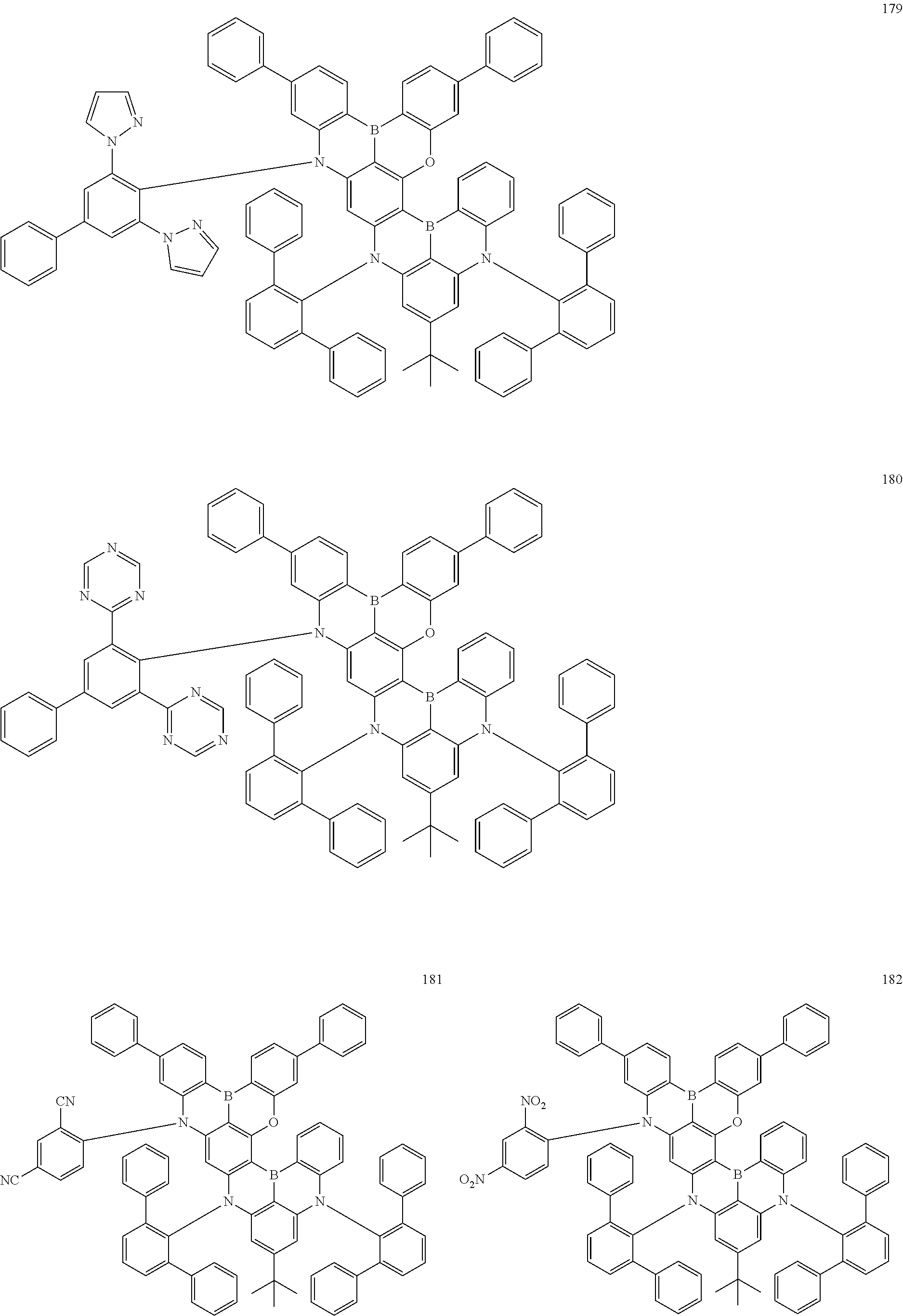

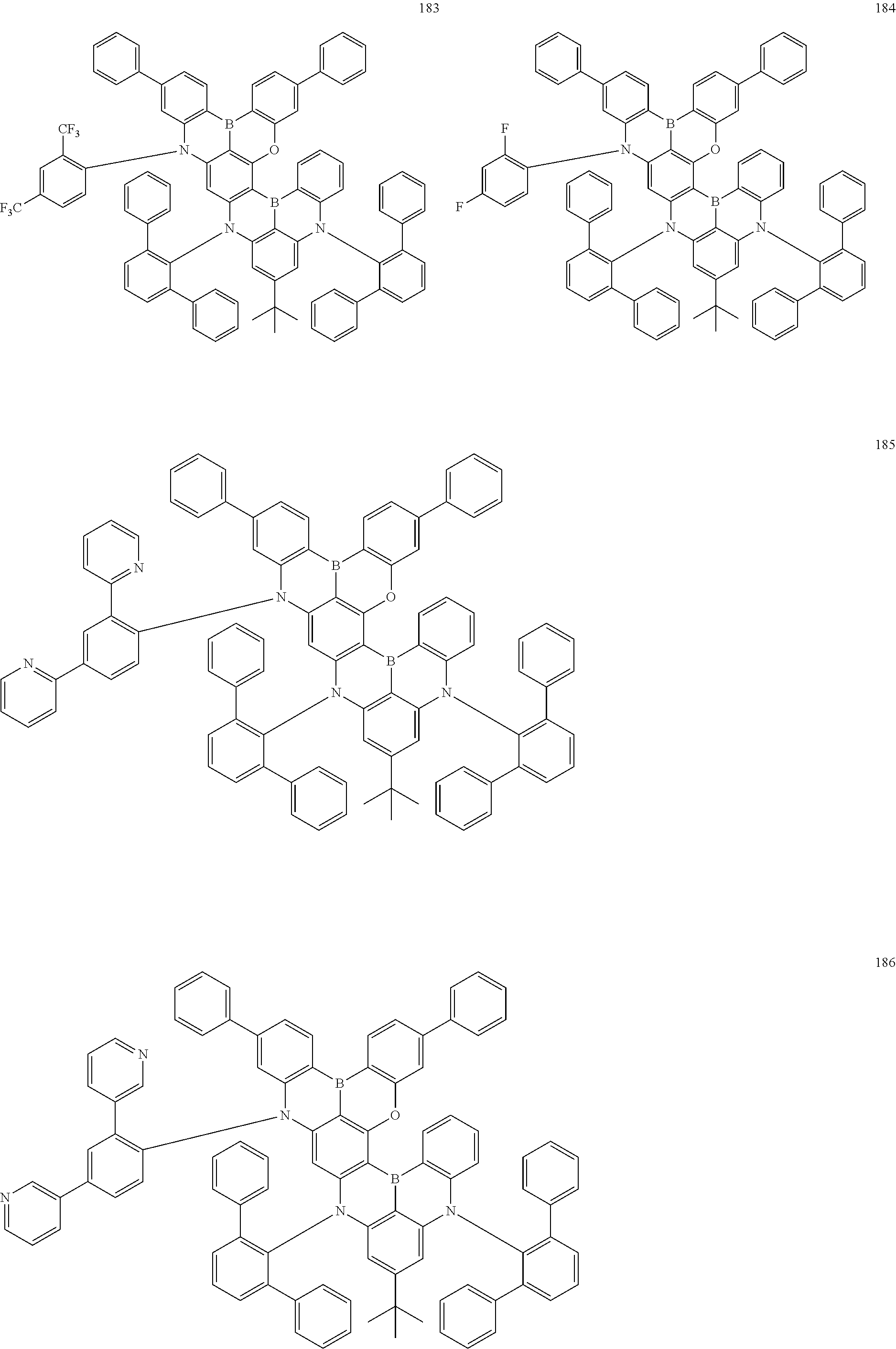

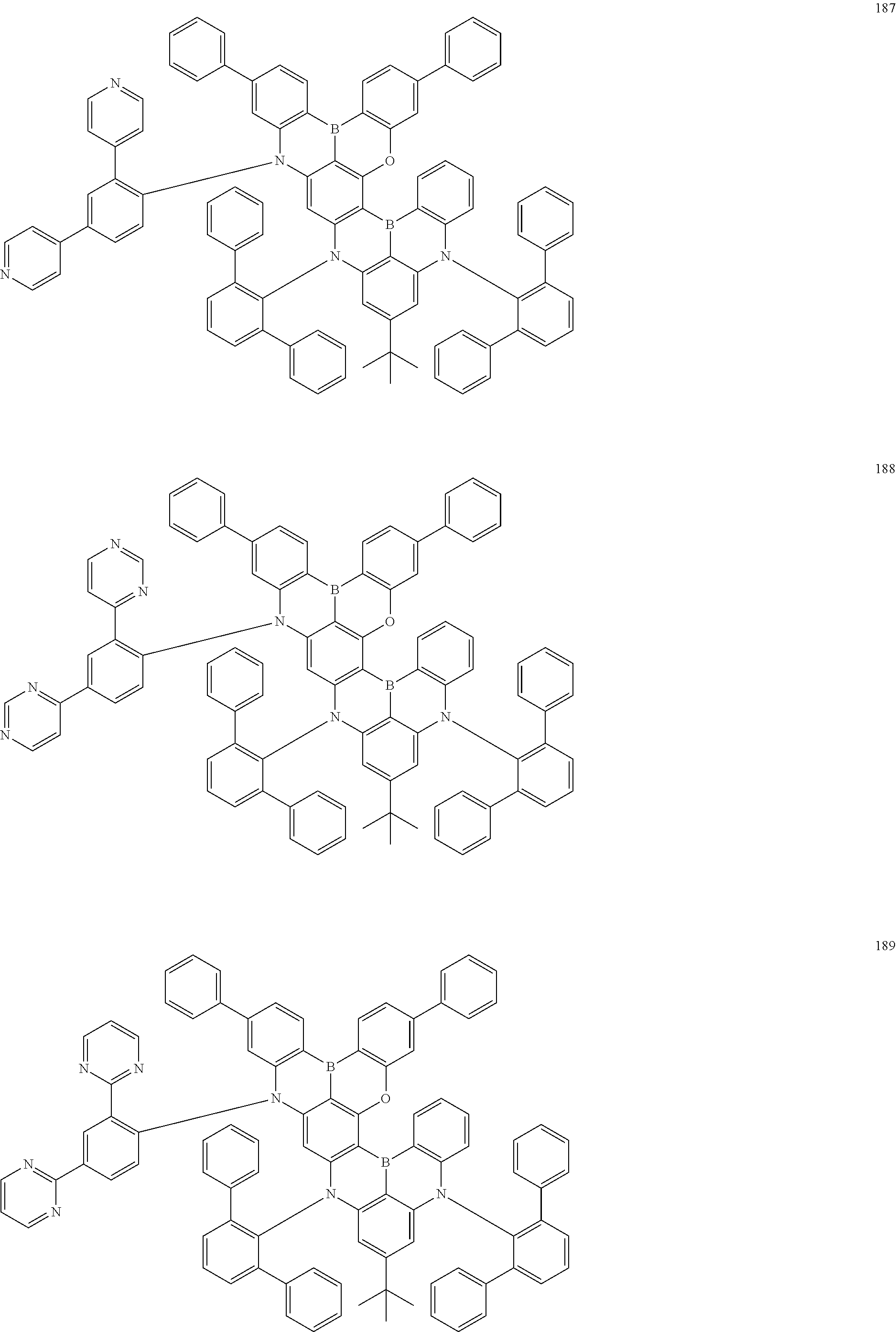

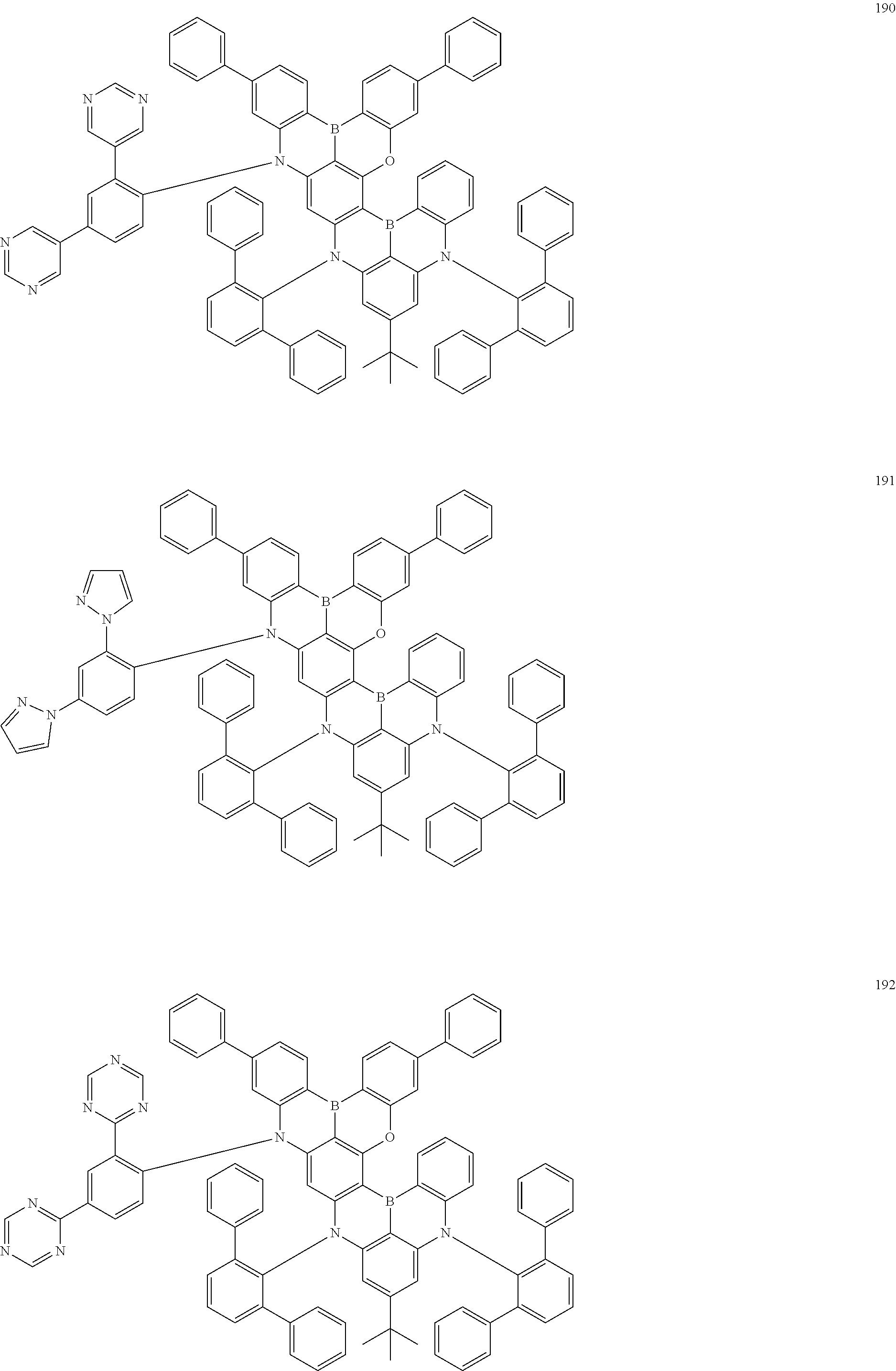

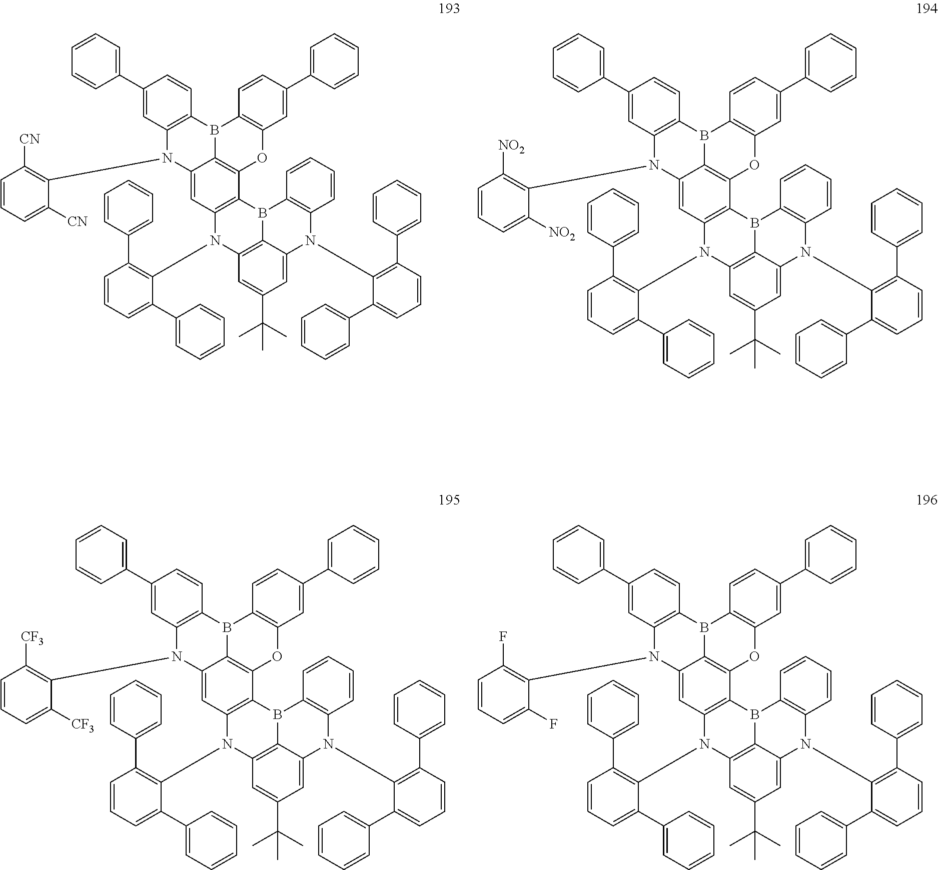

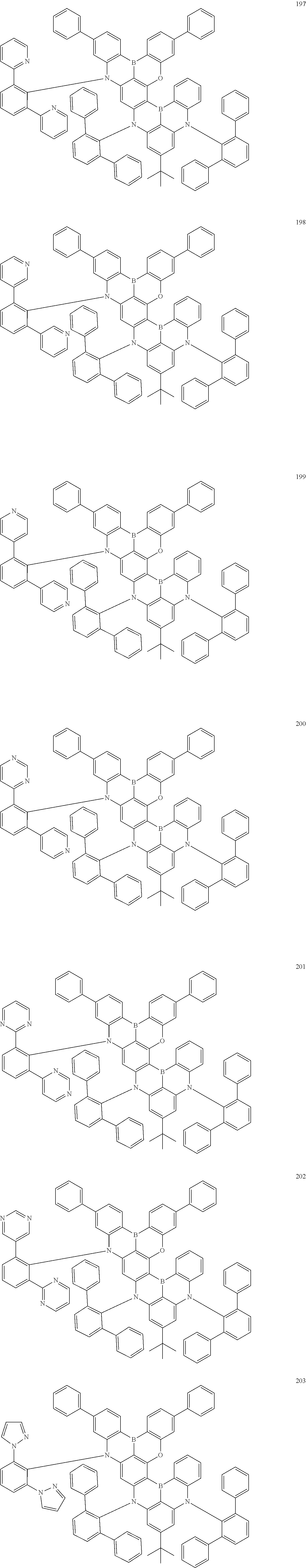

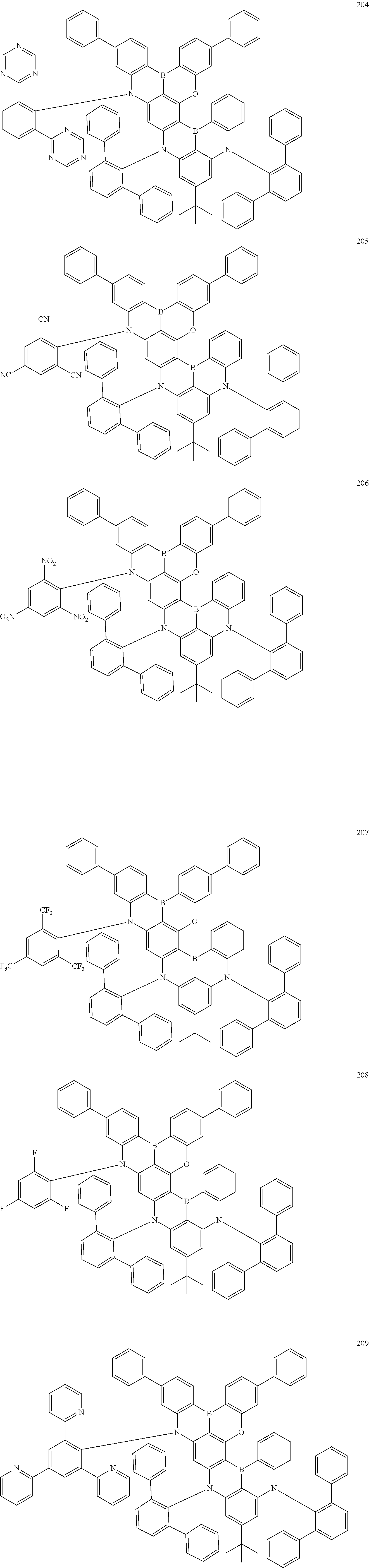

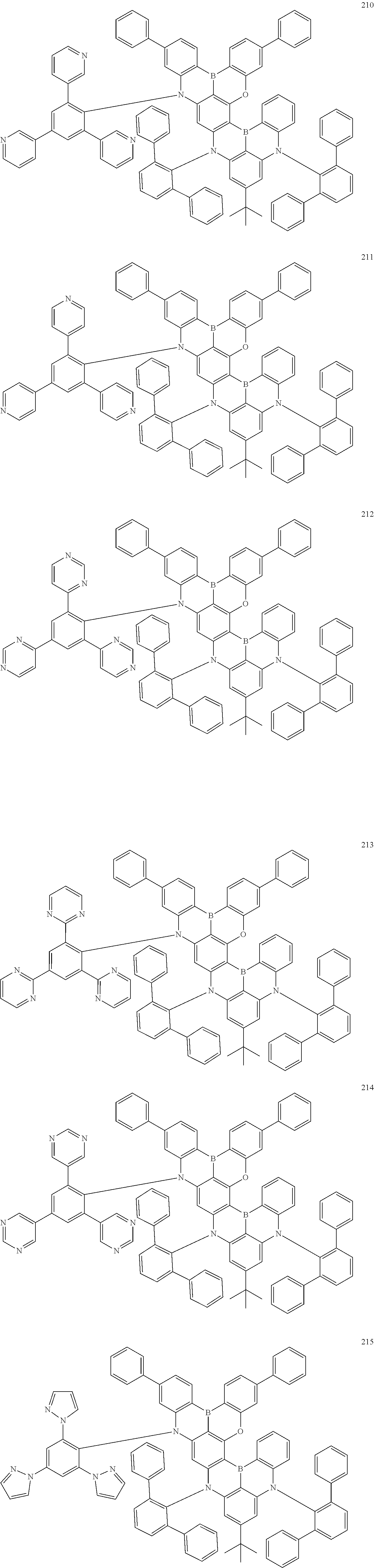

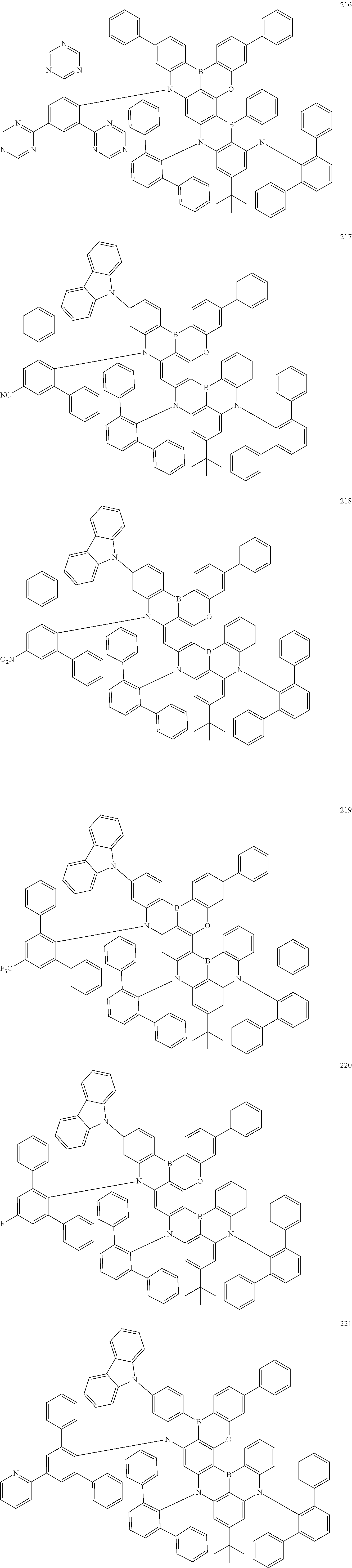

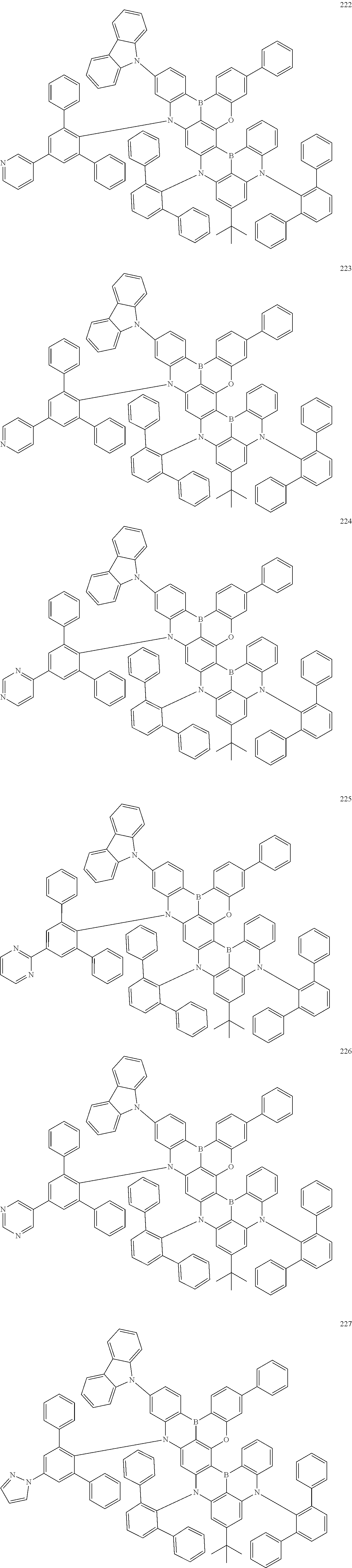

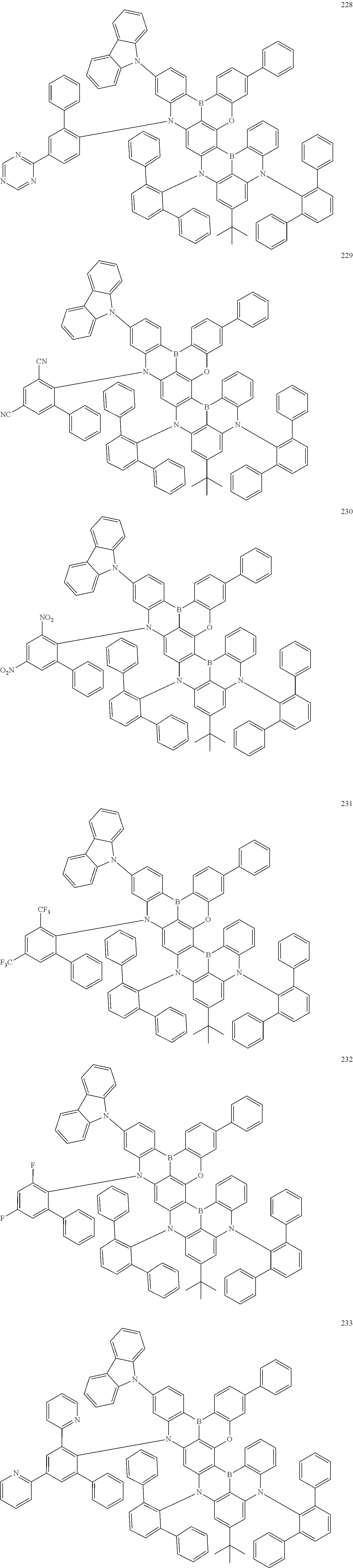

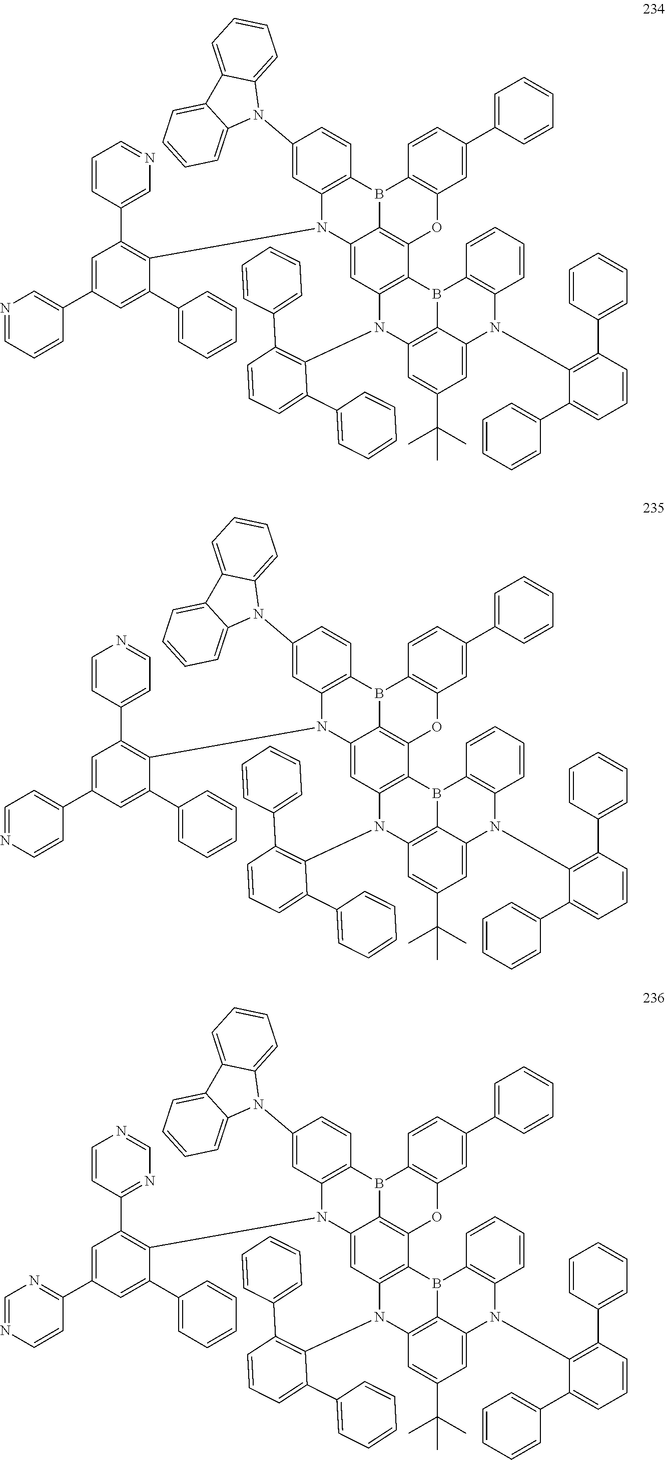

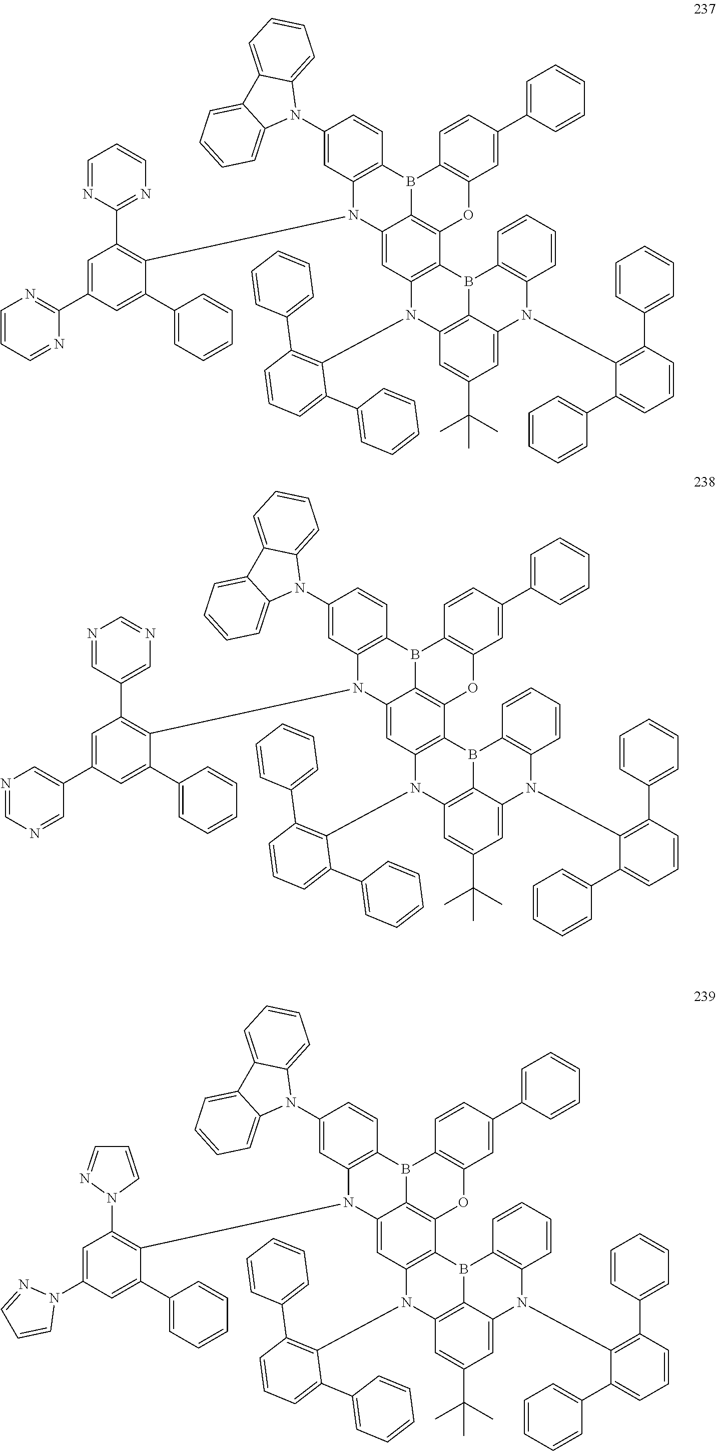

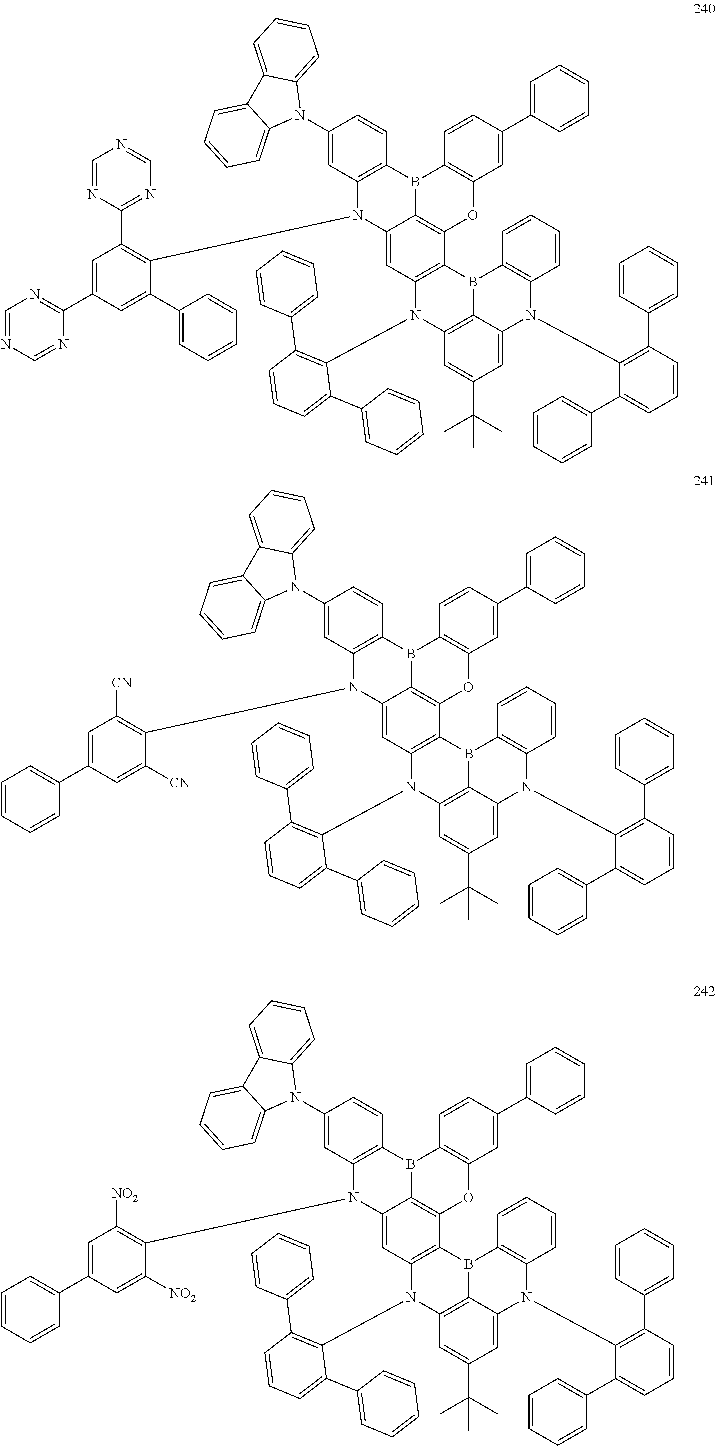

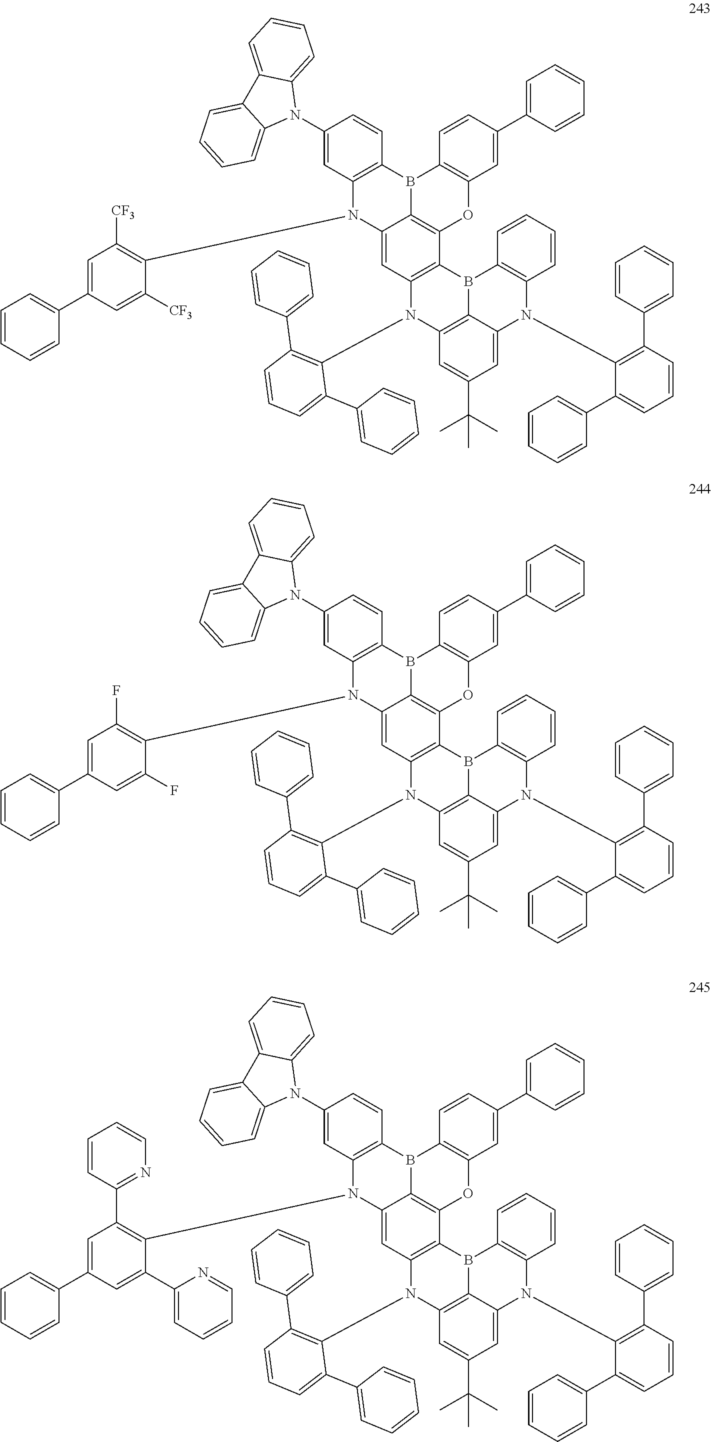

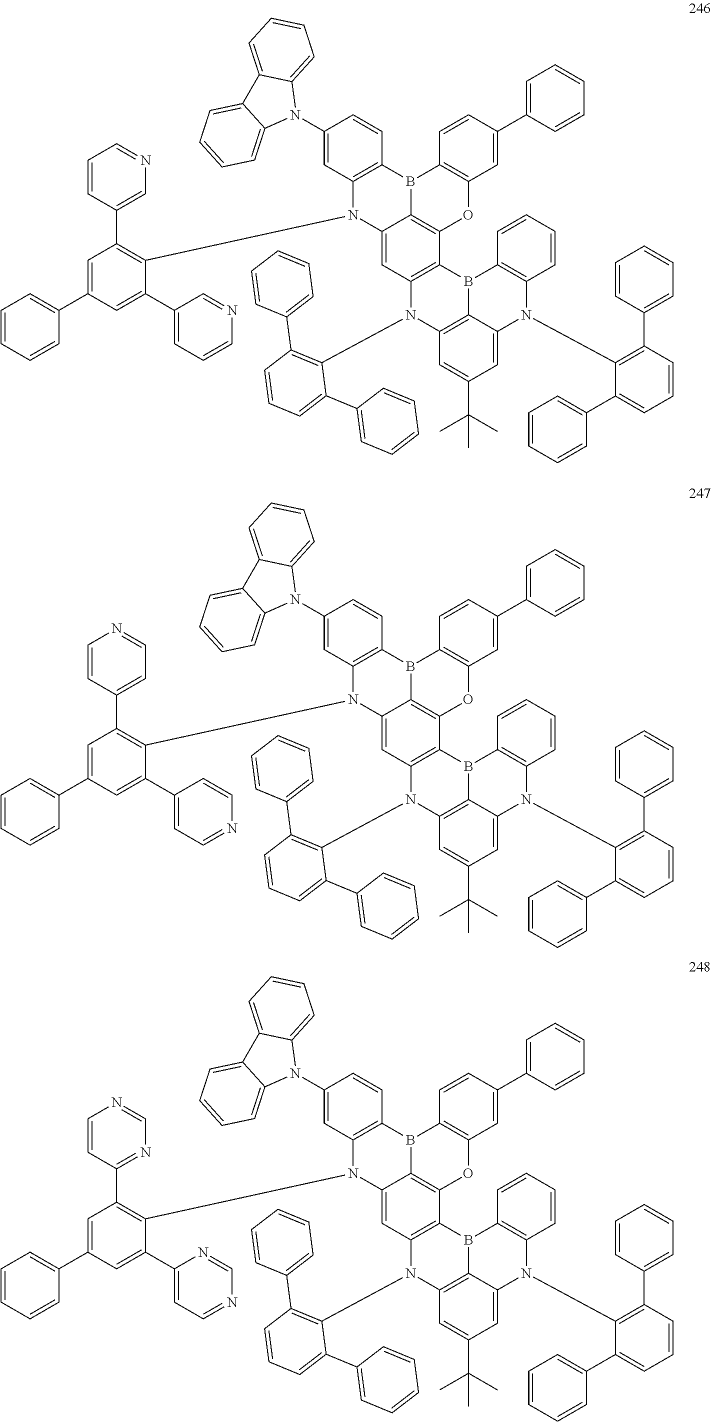

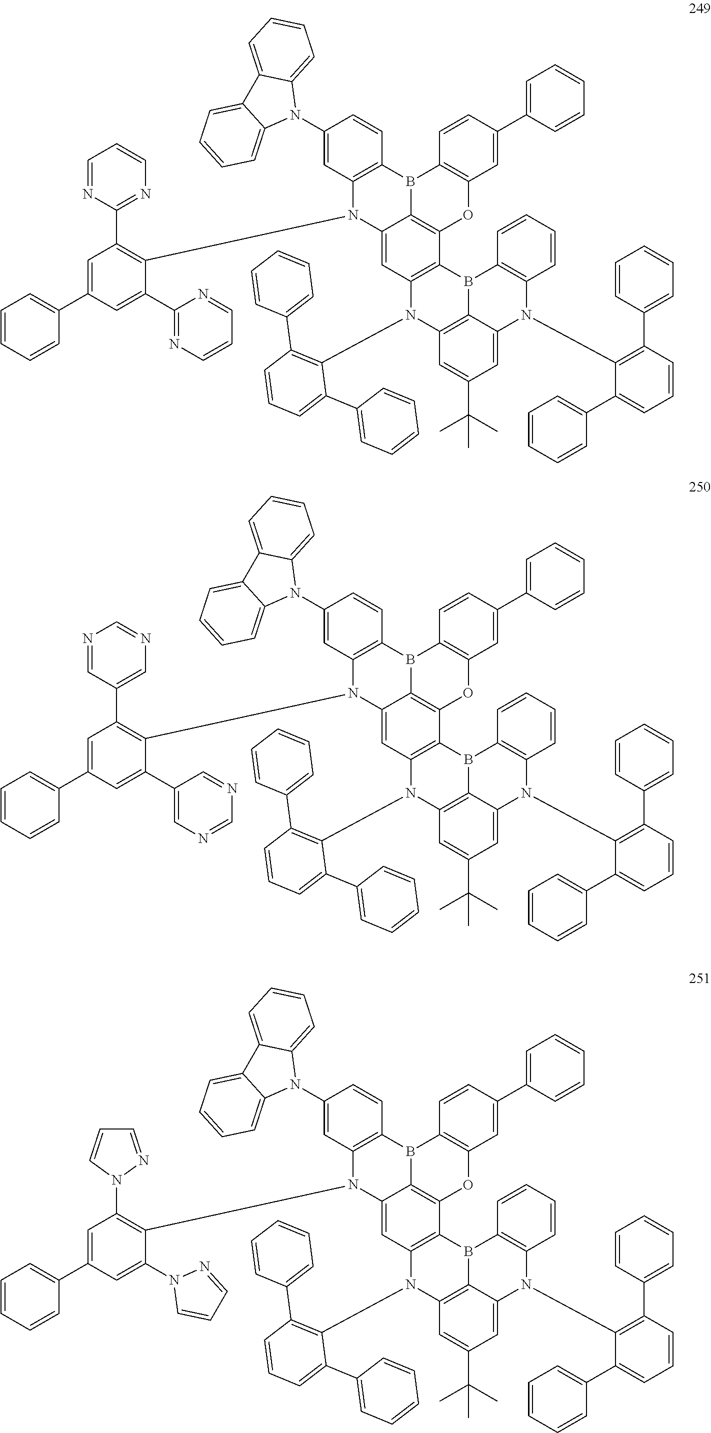

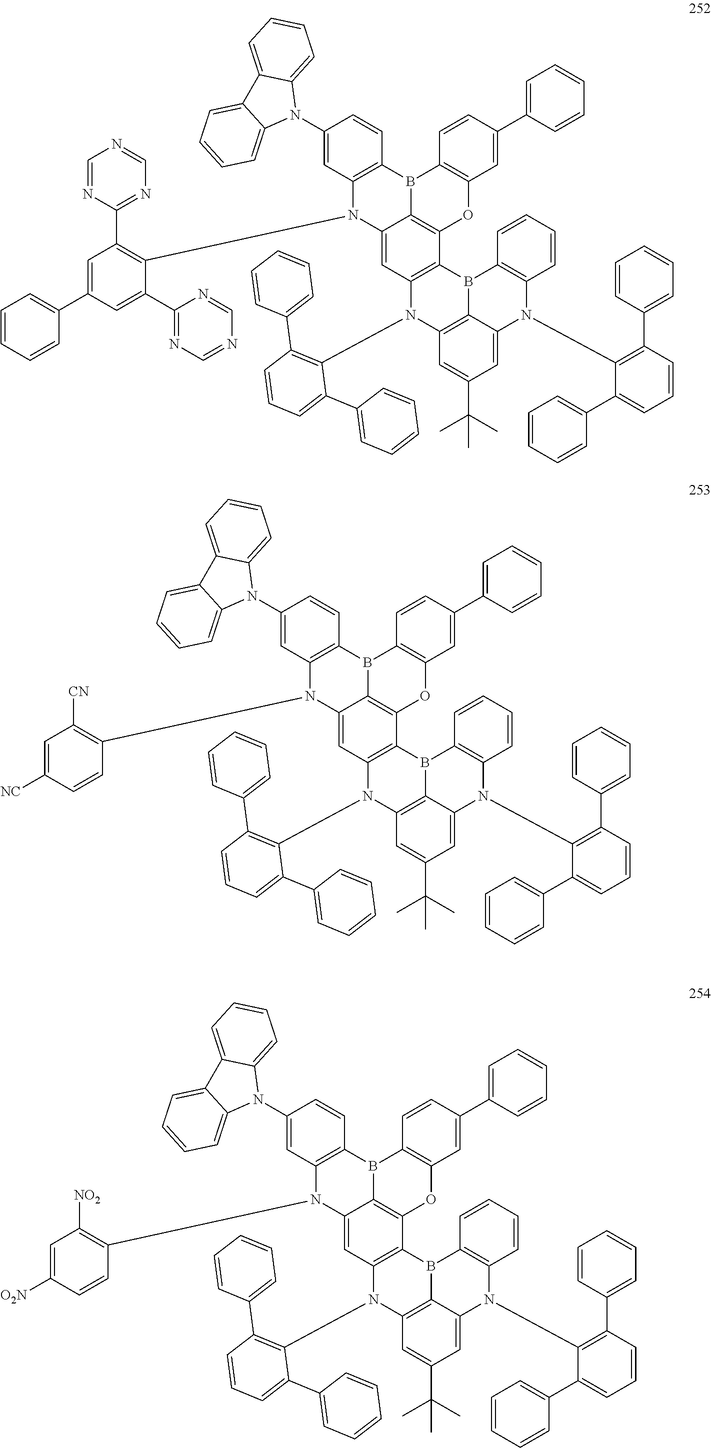

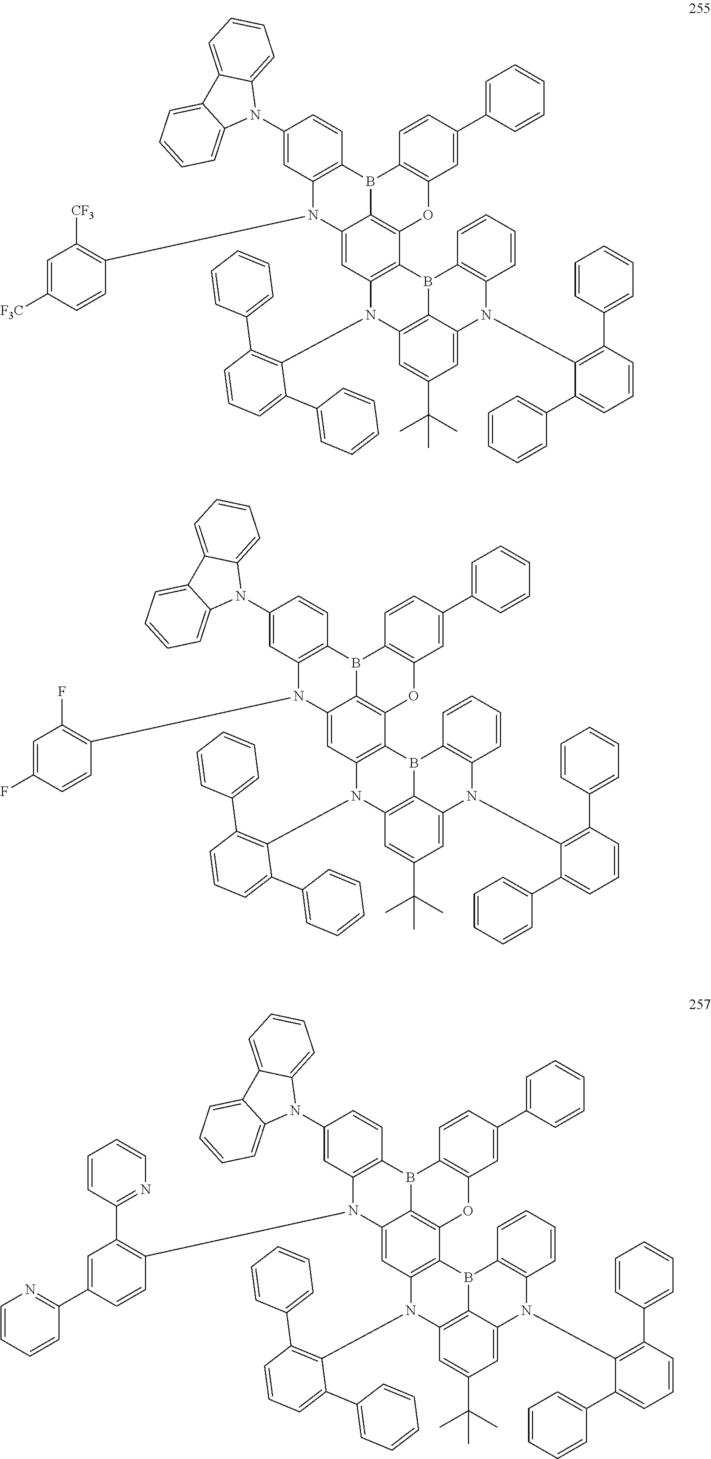

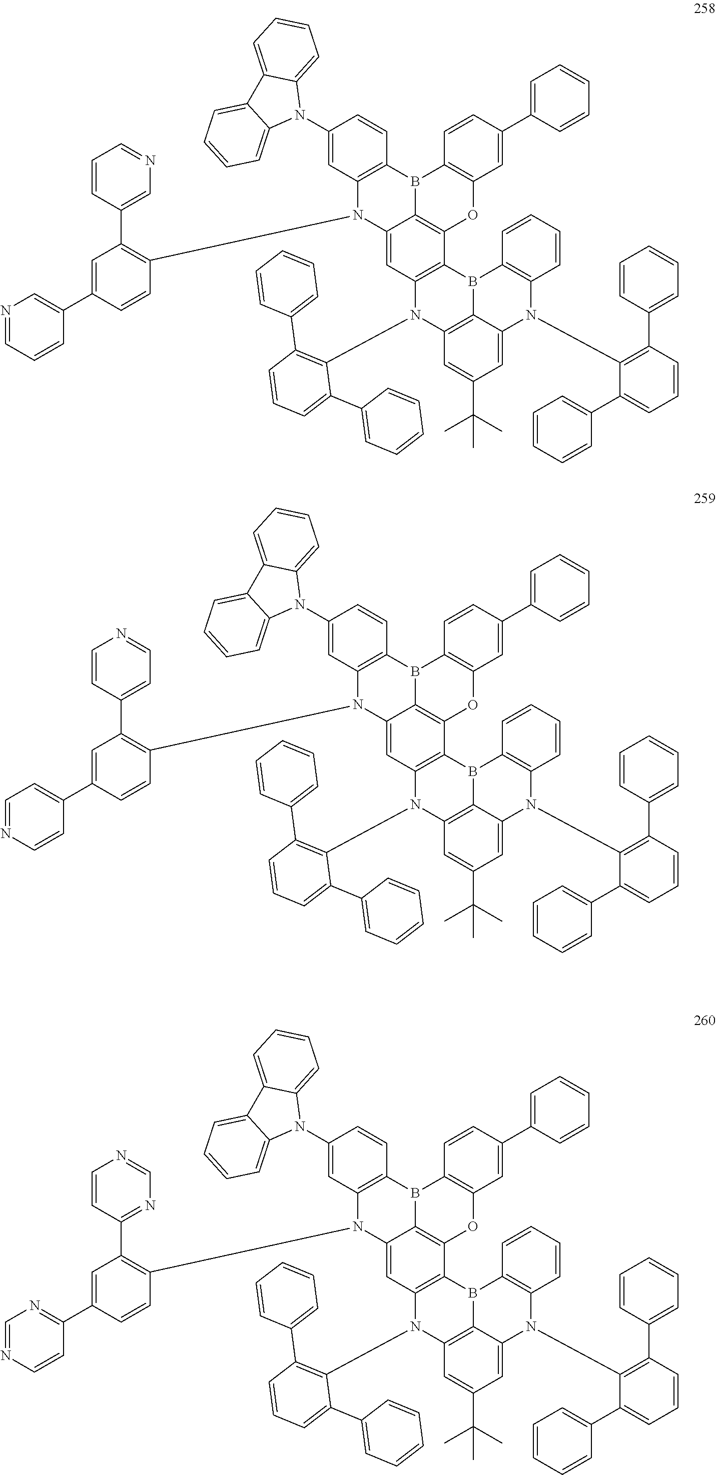

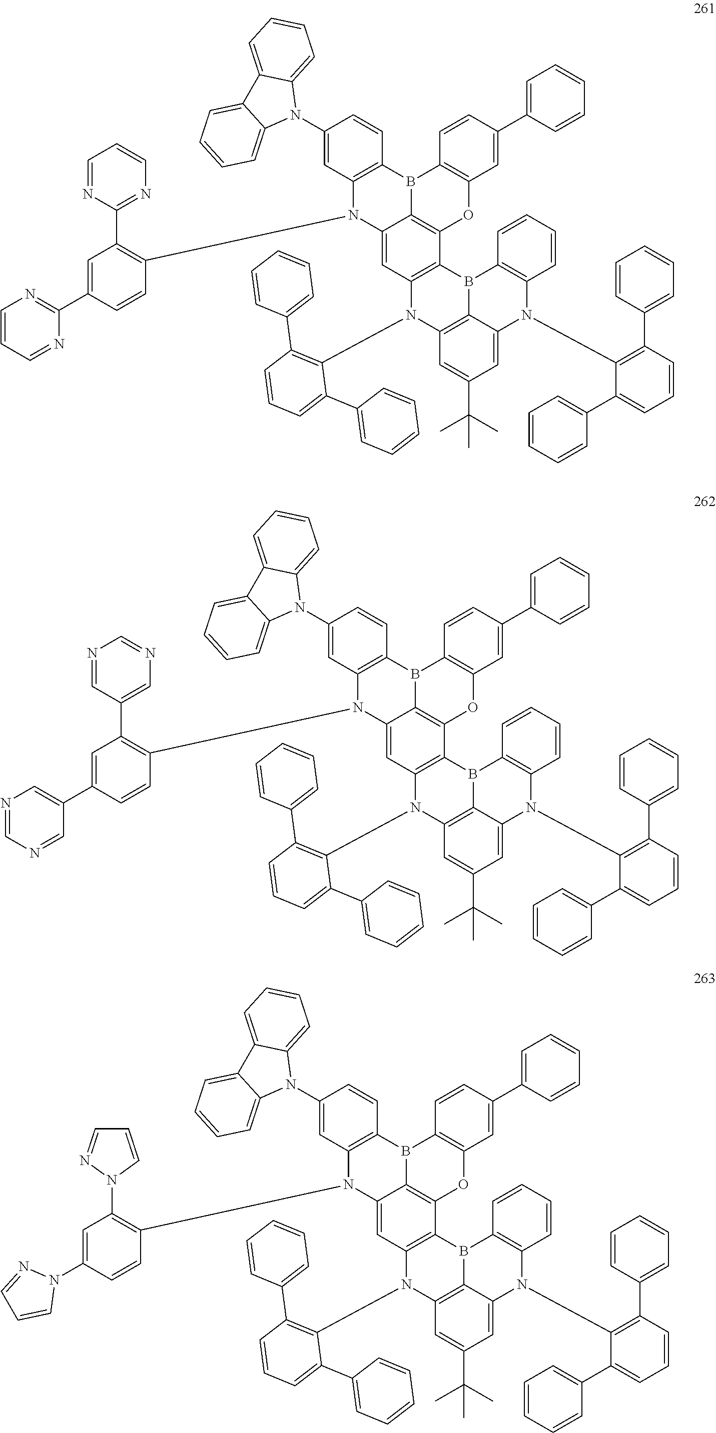

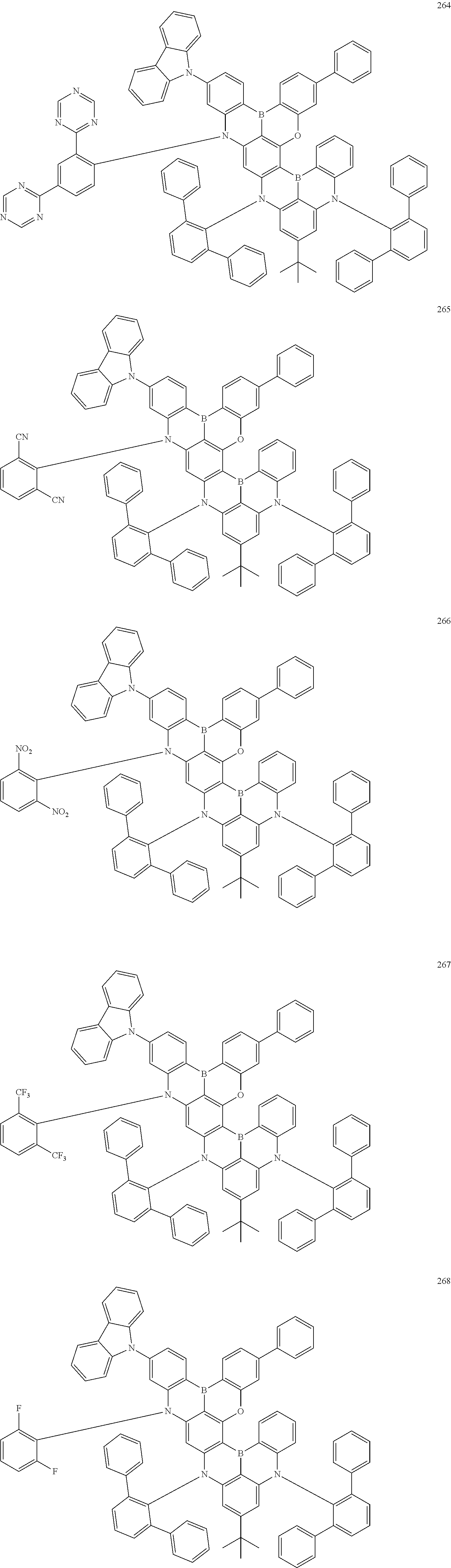

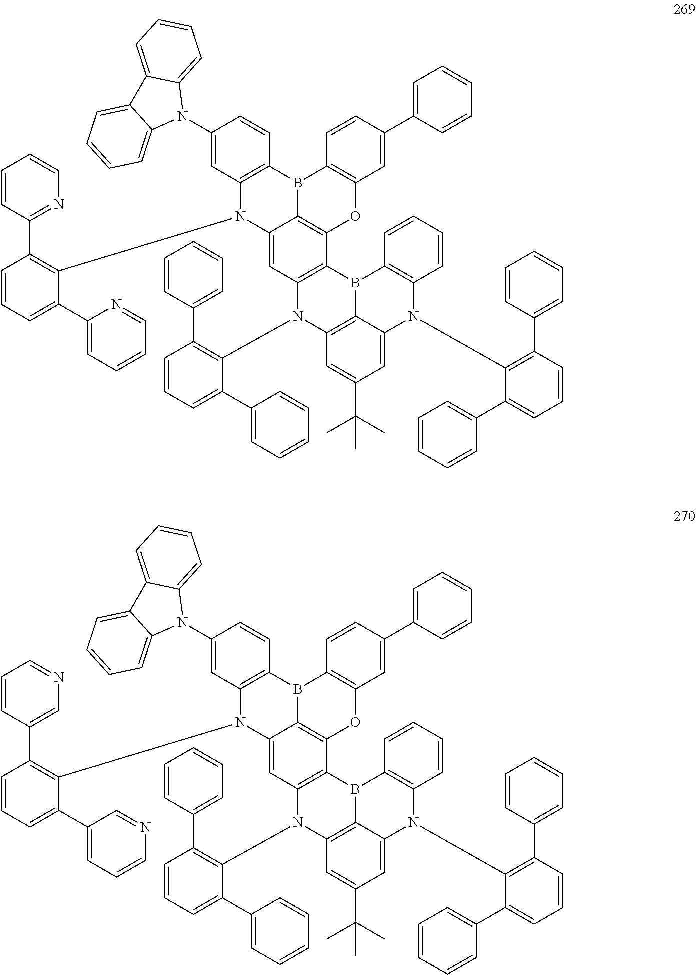 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccccn2)cccc1-c1ccccn1 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2cccnc2)cccc1-c1cccnc1]

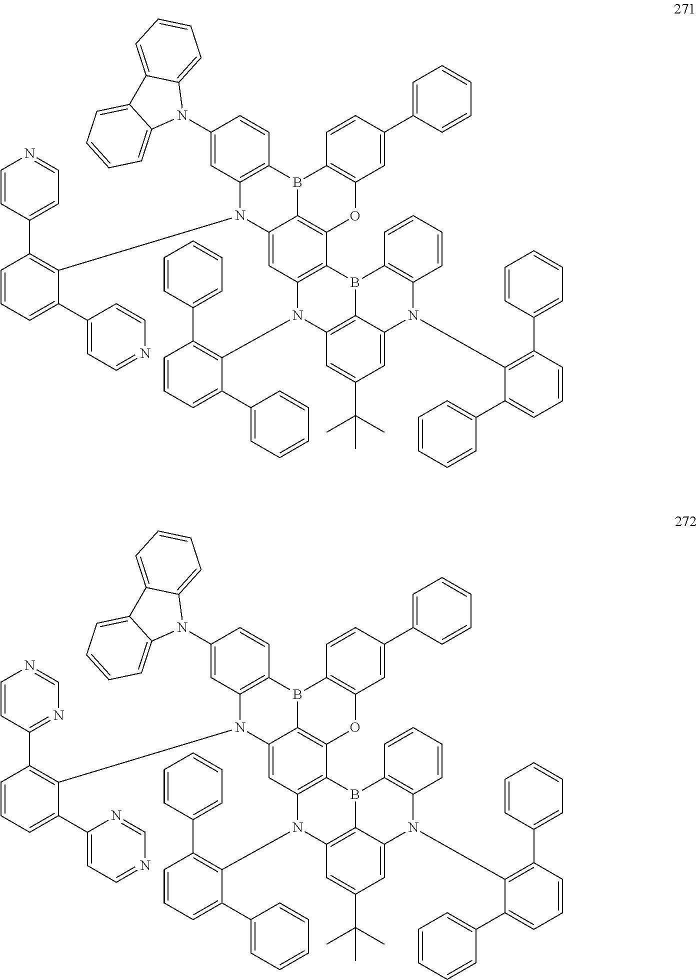 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccncc2)cccc1-c1ccncc1 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccncn2)cccc1-c1ccncn1]

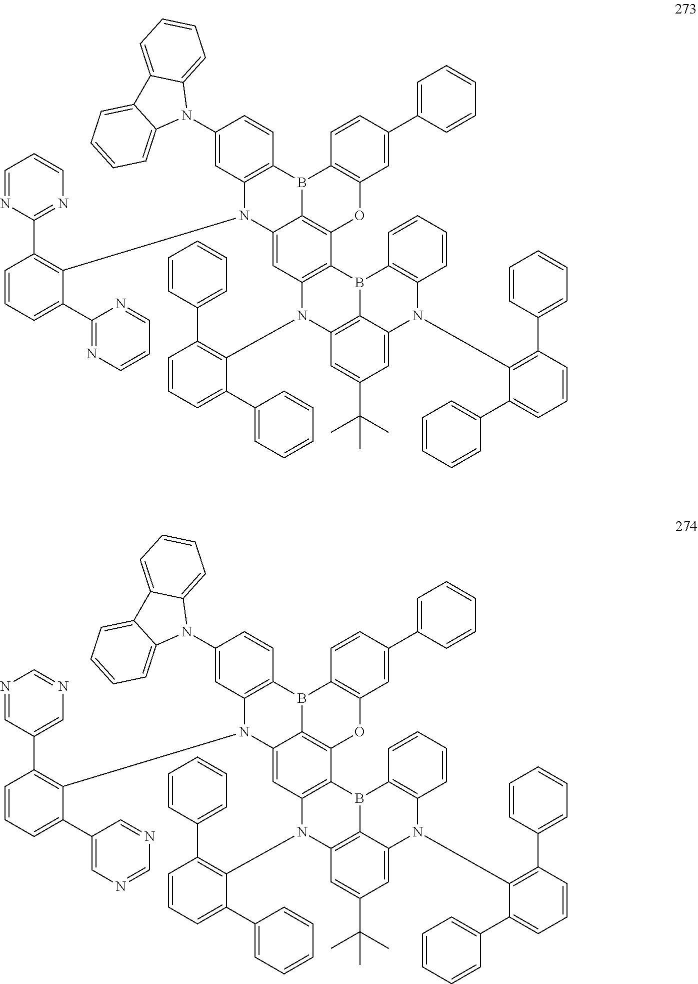 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2ncccn2)cccc1-c1ncccn1 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2cncnc2)cccc1-c1cncnc1]

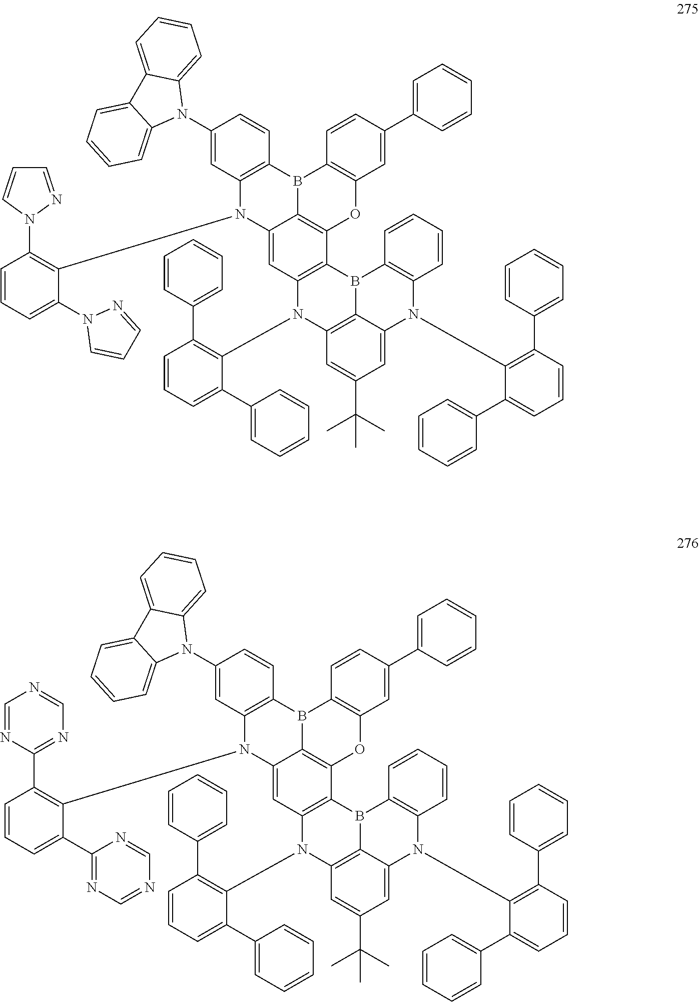 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-n2cccn2)cccc1-n1cccn1 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2ncncn2)cccc1-c1ncncn1]

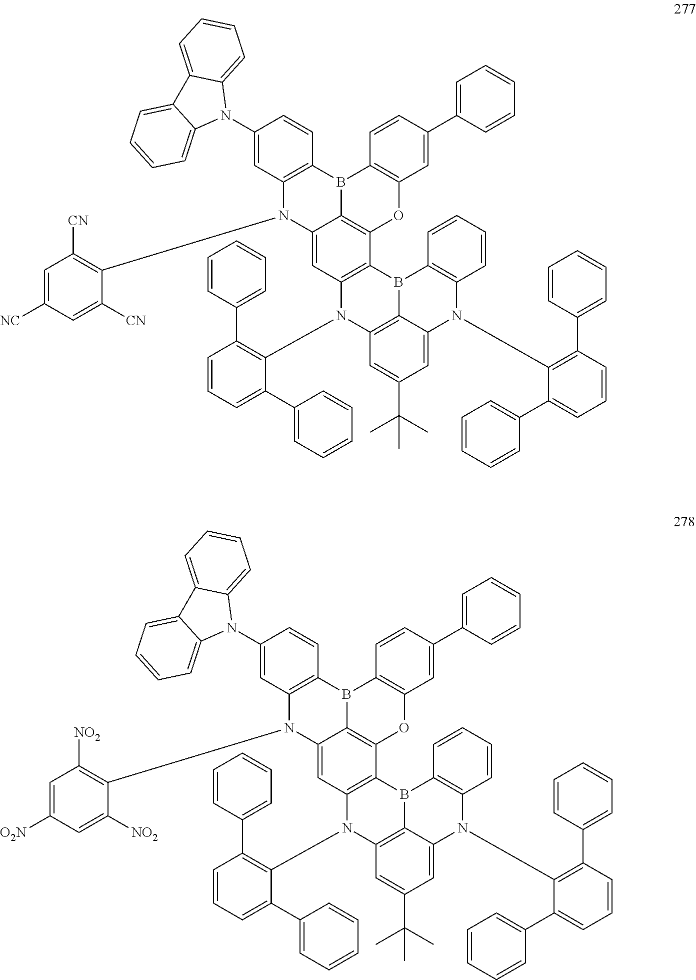 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(C#N)cc(C#N)cc1C#N ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c([N+](=O)[O-])cc([N+](=O)[O-])cc1[N+](=O)[O-]]

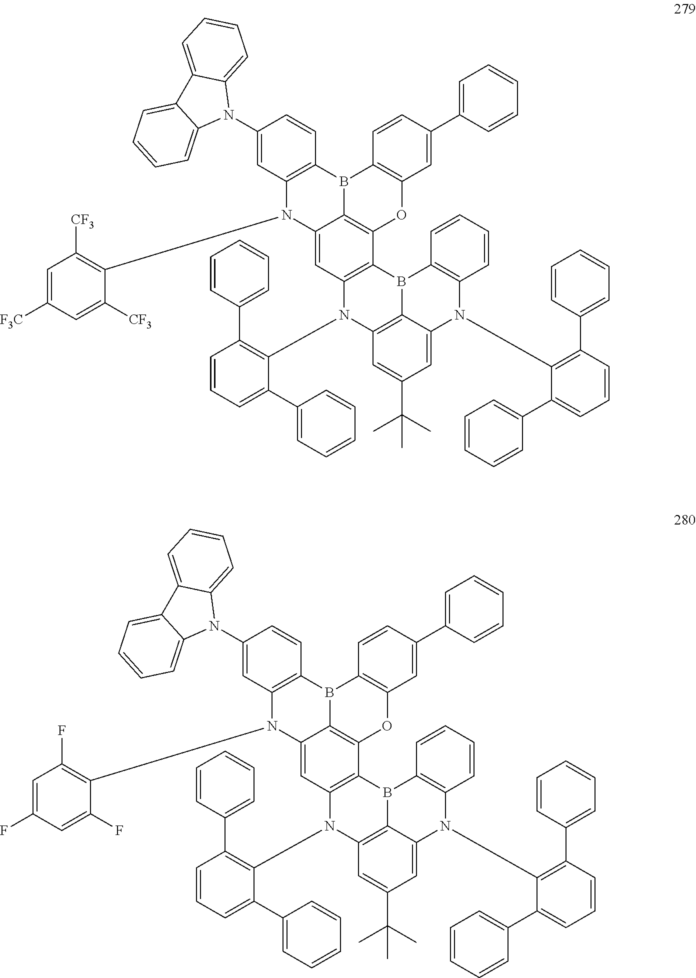 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(C(F)(F)F)cc(C(F)(F)F)cc1C(F)(F)F ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(F)cc(F)cc1F]

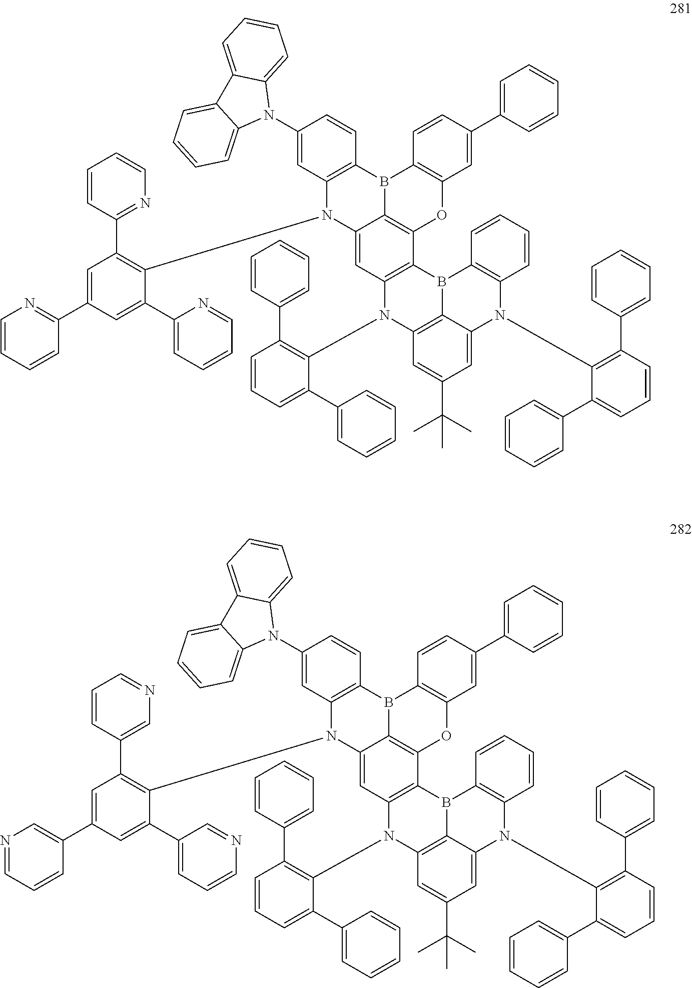 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccccn2)cc(-c2ccccn2)cc1-c1ccccn1 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2cccnc2)cc(-c2cccnc2)cc1-c1cccnc1]

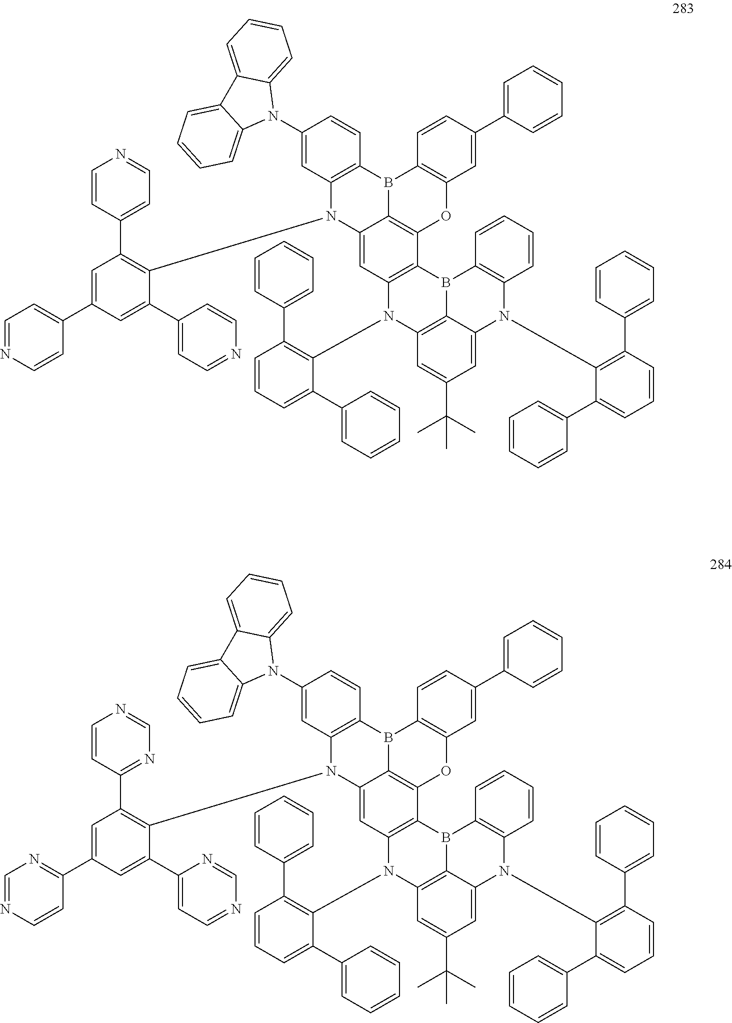 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccncc2)cc(-c2ccncc2)cc1-c1ccncc1 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccncn2)cc(-c2ccncn2)cc1-c1ccncn1]

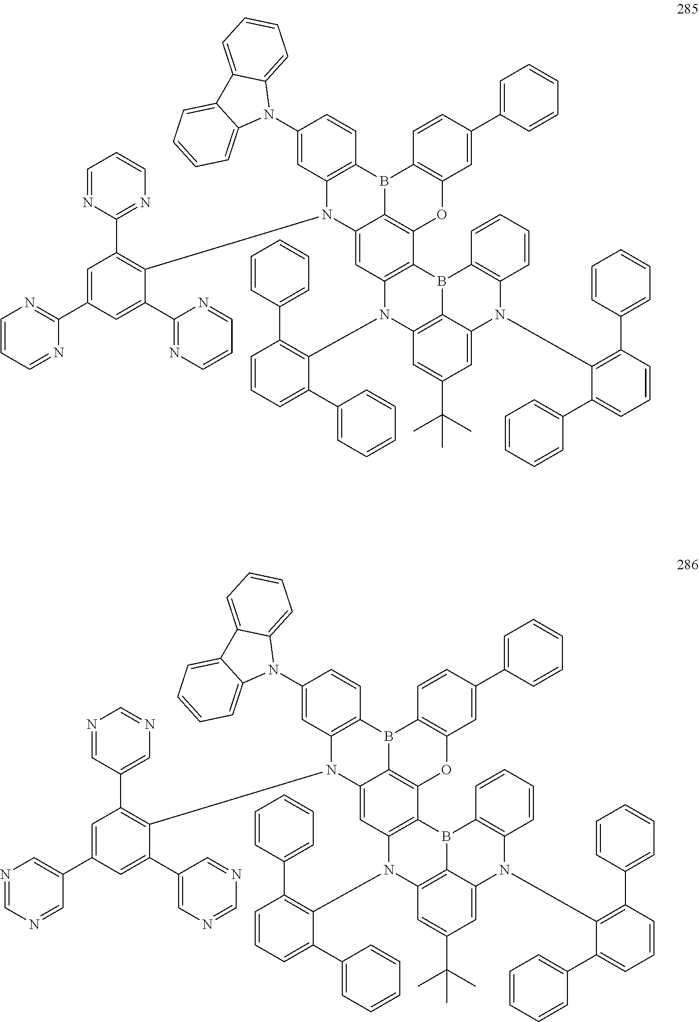 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2ncccn2)cc(-c2ncccn2)cc1-c1ncccn1 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2cncnc2)cc(-c2cncnc2)cc1-c1cncnc1]

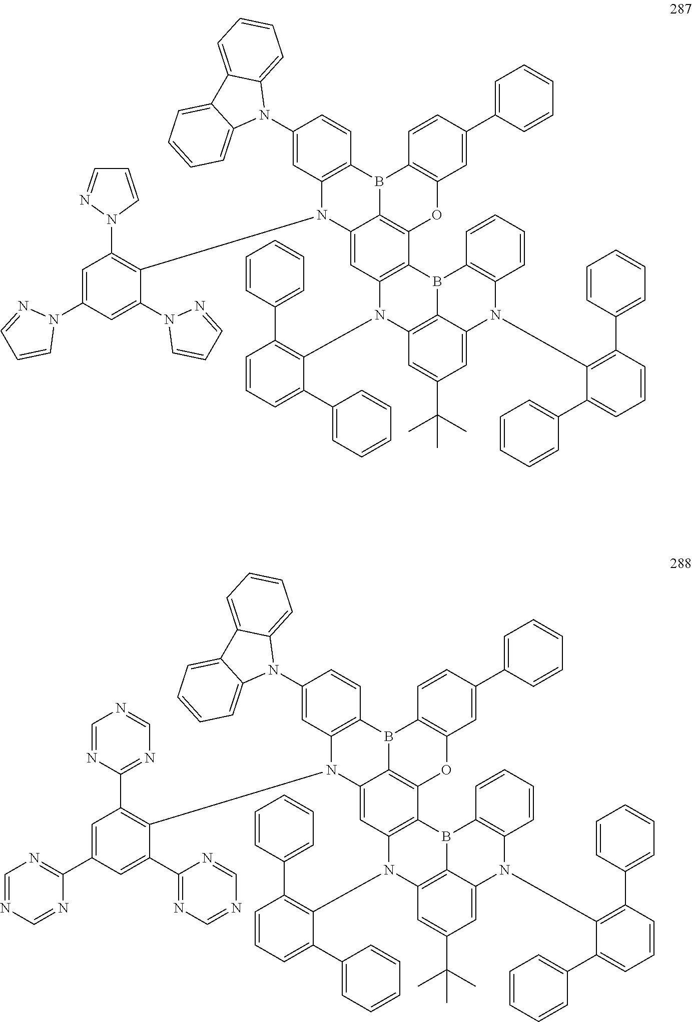 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-n2cccn2)cc(-n2cccn2)cc1-n1cccn1 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2ncncn2)cc(-c2ncncn2)cc1-c1ncncn1]

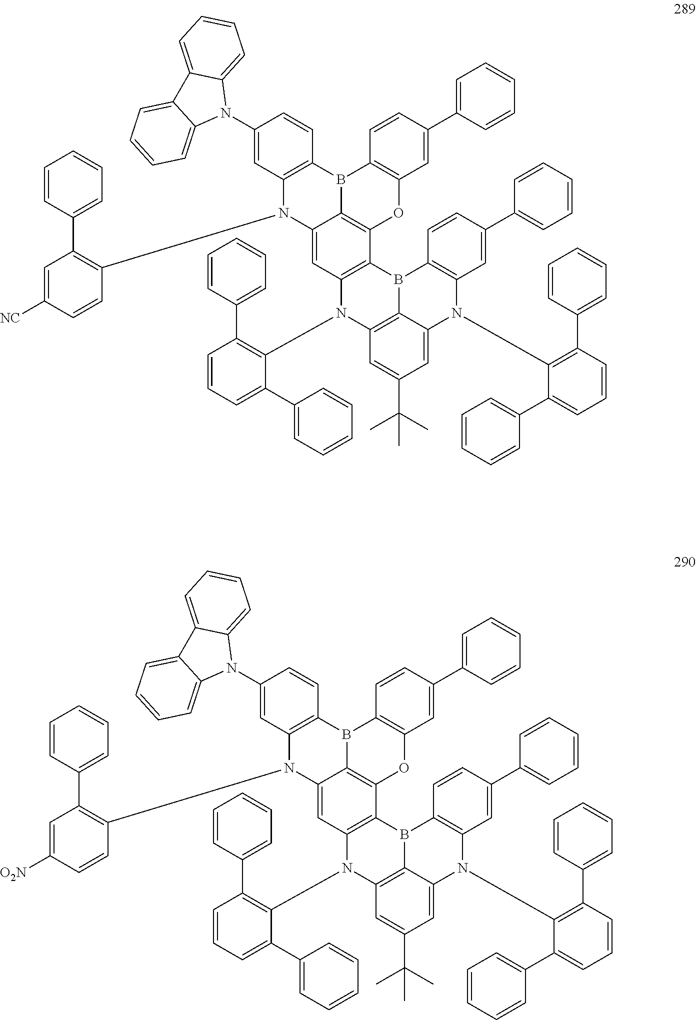 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(C#N)cc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc([N+](=O)[O-])cc1-c1ccccc1]

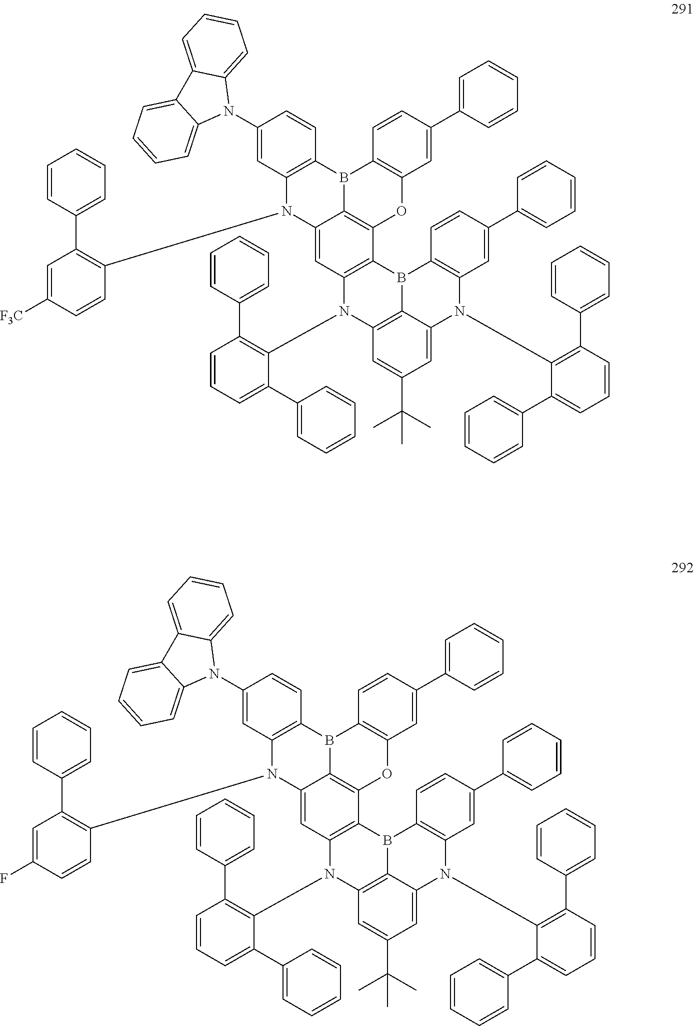 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(C(F)(F)F)cc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(F)cc1-c1ccccc1]

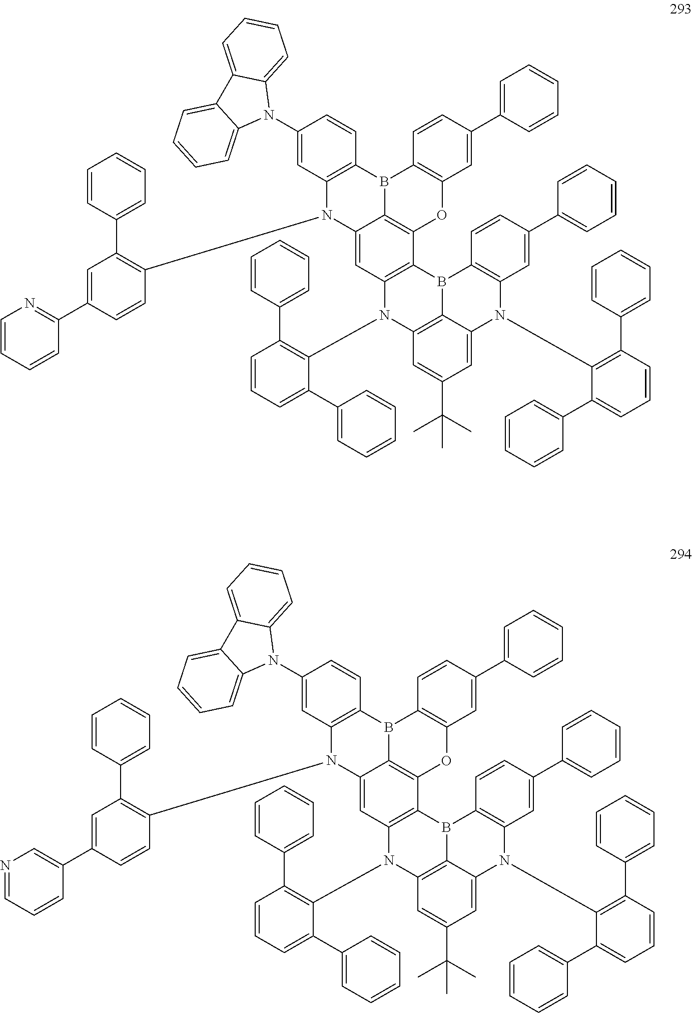 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ccccn2)cc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2cccnc2)cc1-c1ccccc1]

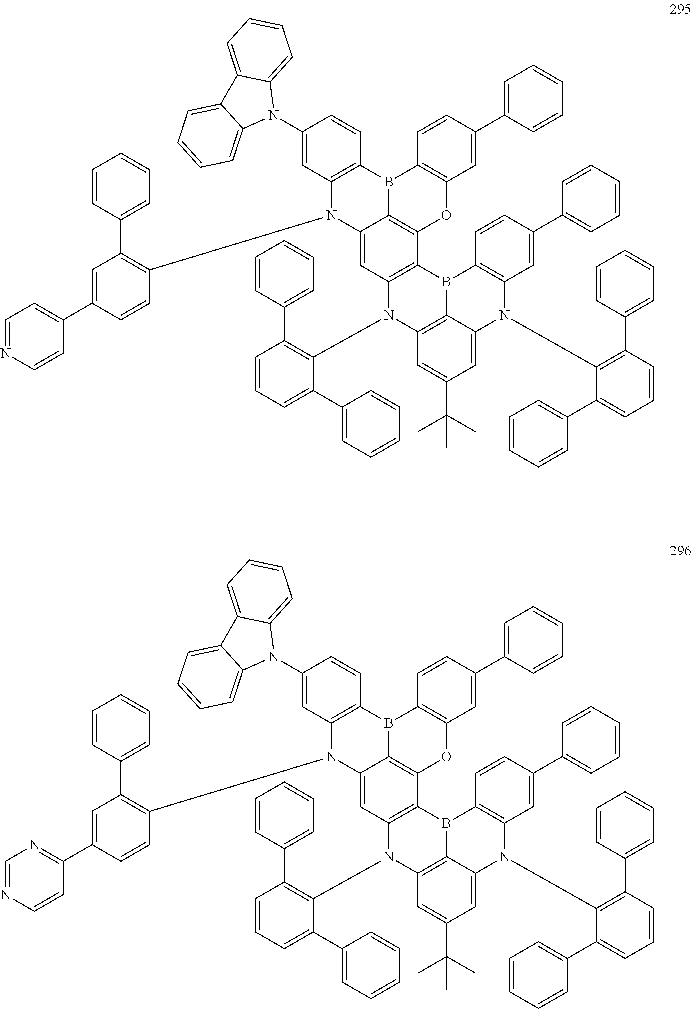 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ccncc2)cc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ccncn2)cc1-c1ccccc1]

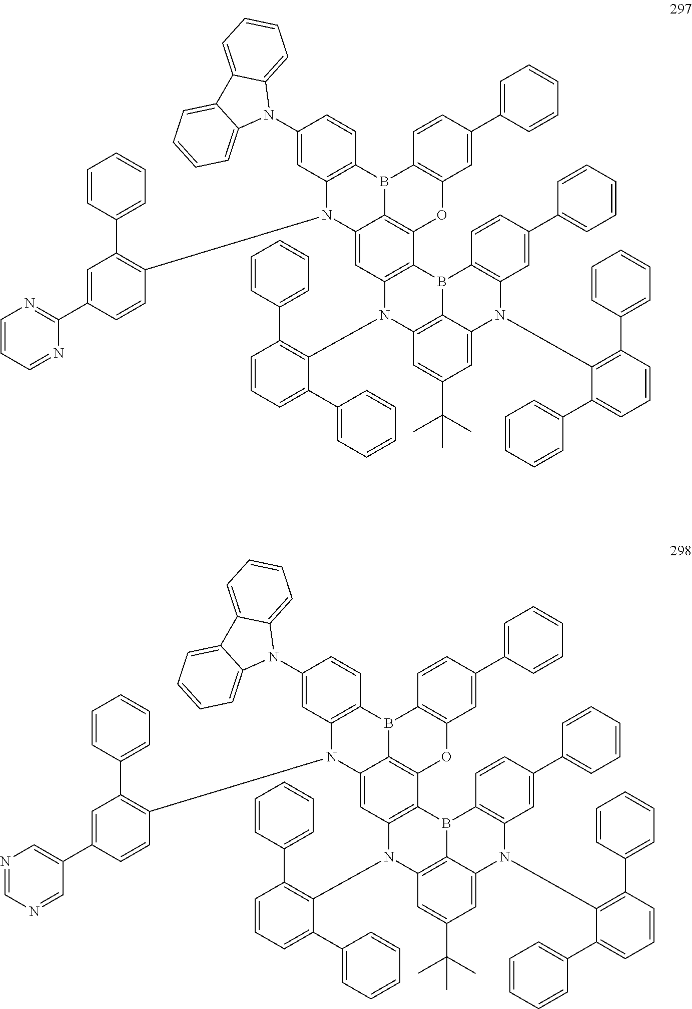 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ncccn2)cc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2cncnc2)cc1-c1ccccc1]

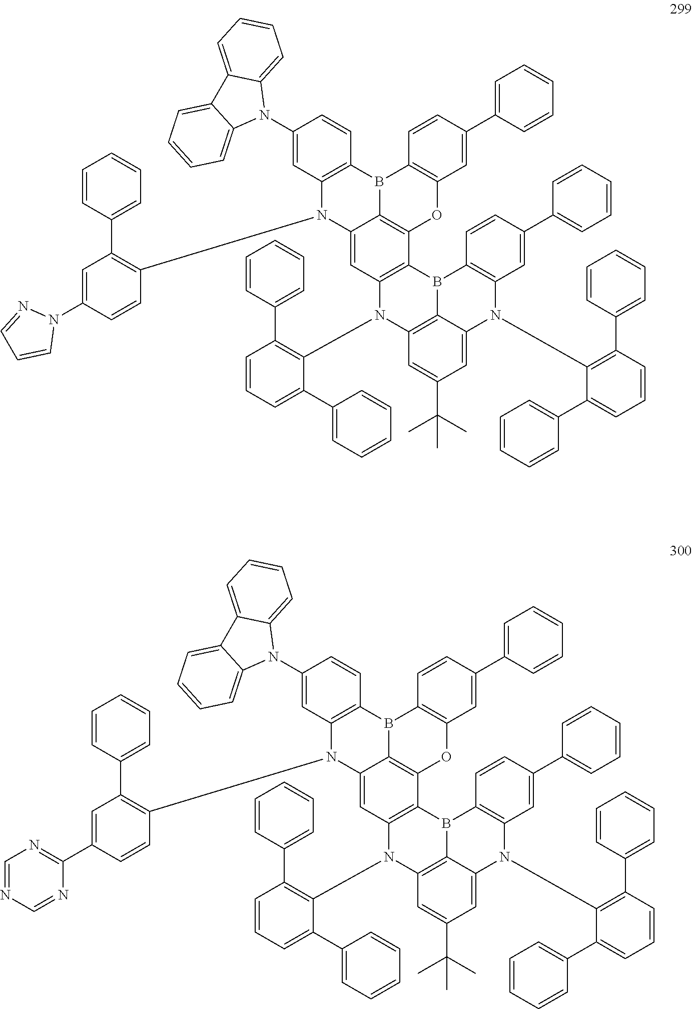 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-n2cccn2)cc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ncncn2)cc1-c1ccccc1]

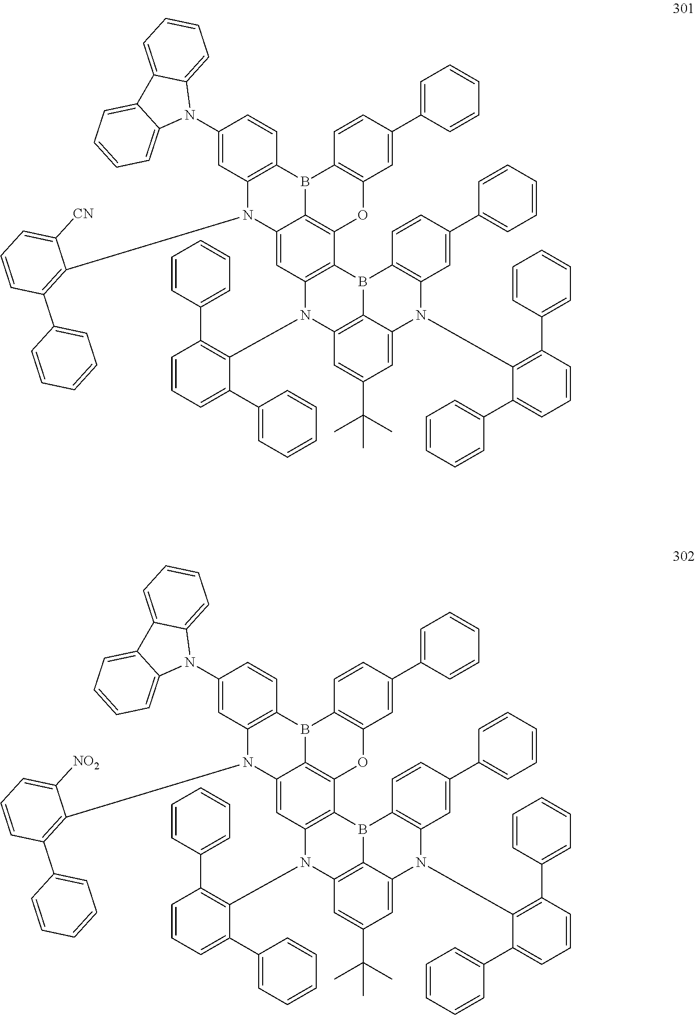 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(C#N)cccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccccc2)cccc1[N+](=O)[O-]]

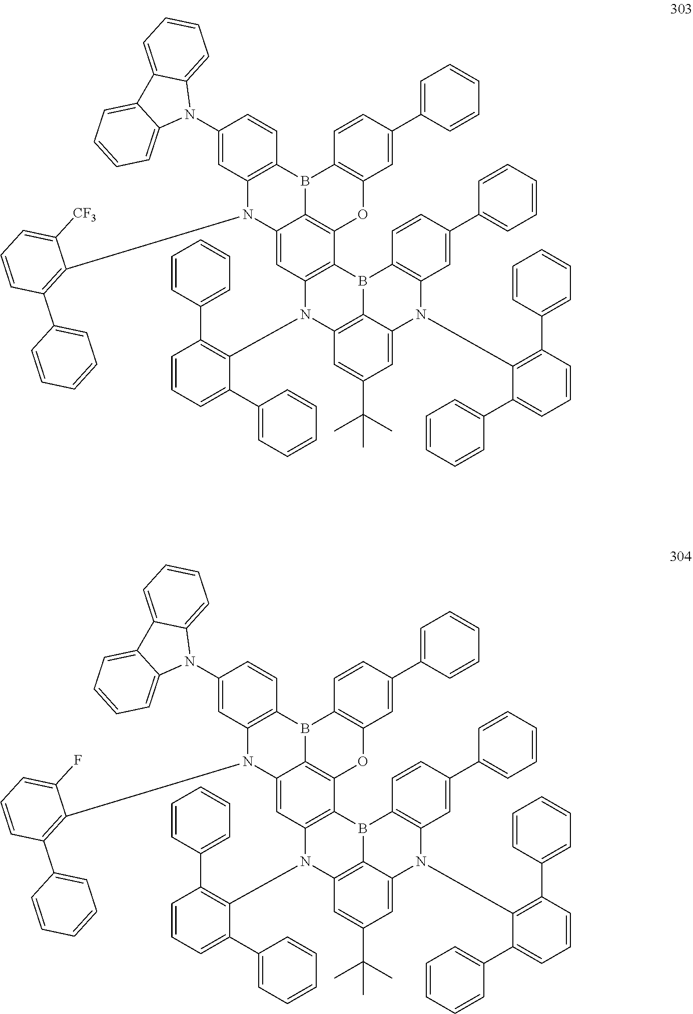 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccccc2)cccc1C(F)(F)F ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(F)cccc1-c1ccccc1]

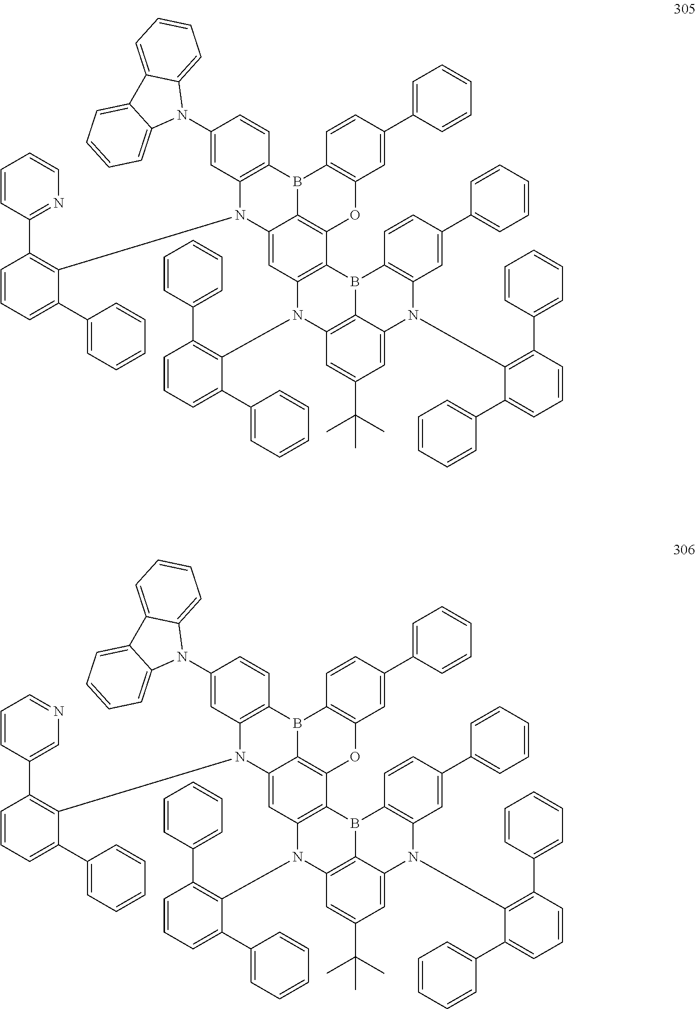 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccccc2)cccc1-c1ccccn1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccccc2)cccc1-c1cccnc1]

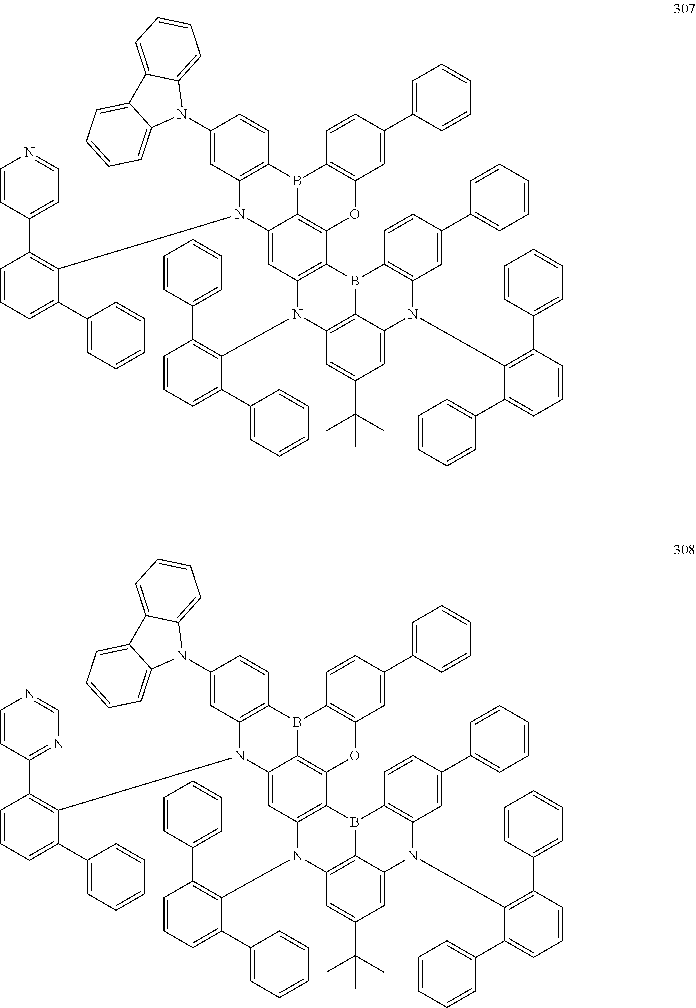 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccccc2)cccc1-c1ccncc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccccc2)cccc1-c1ccncn1]

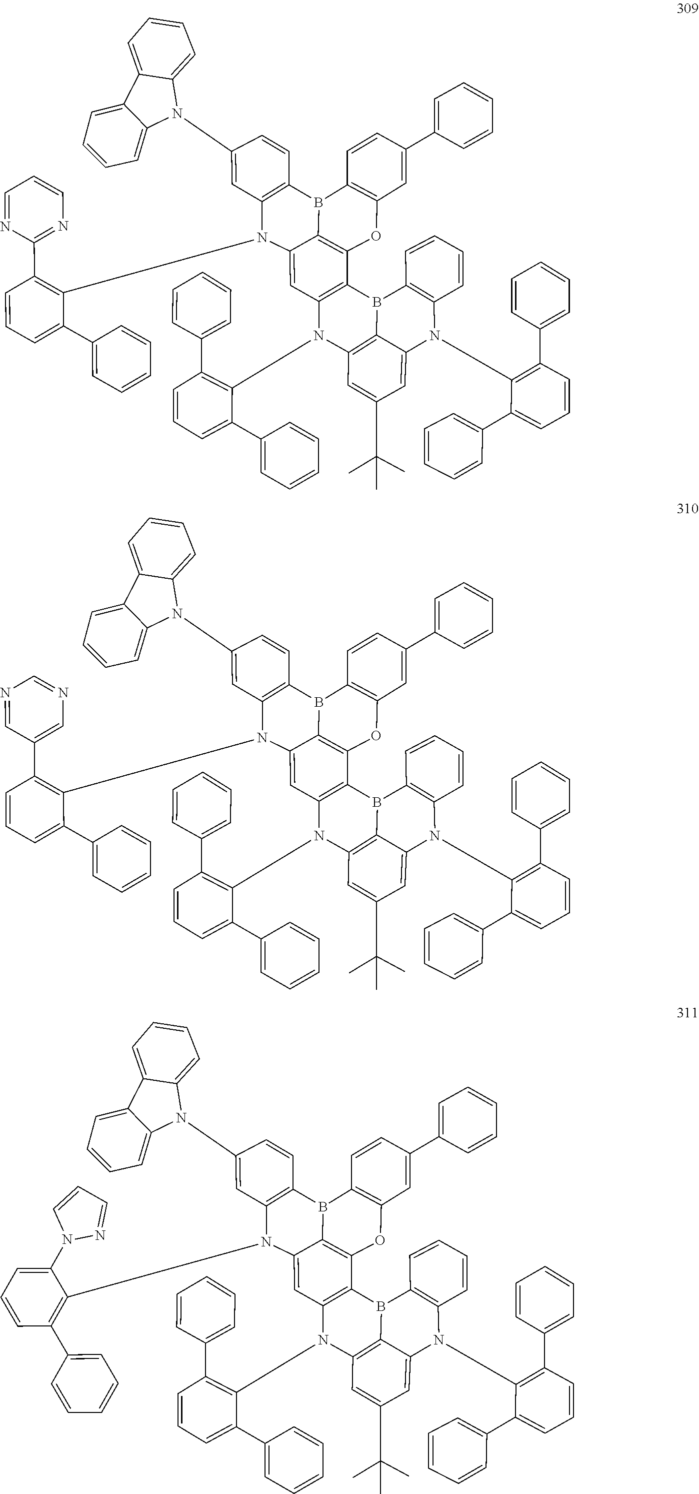

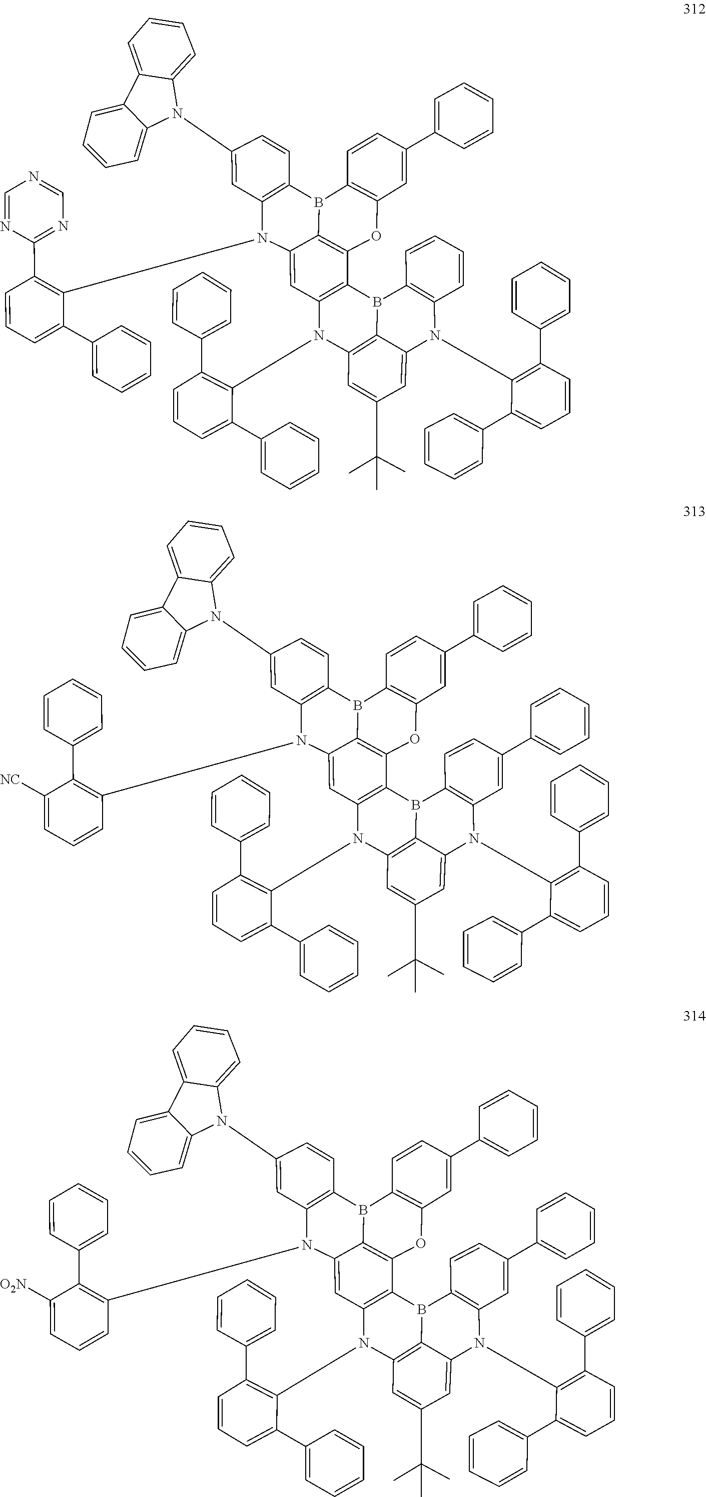

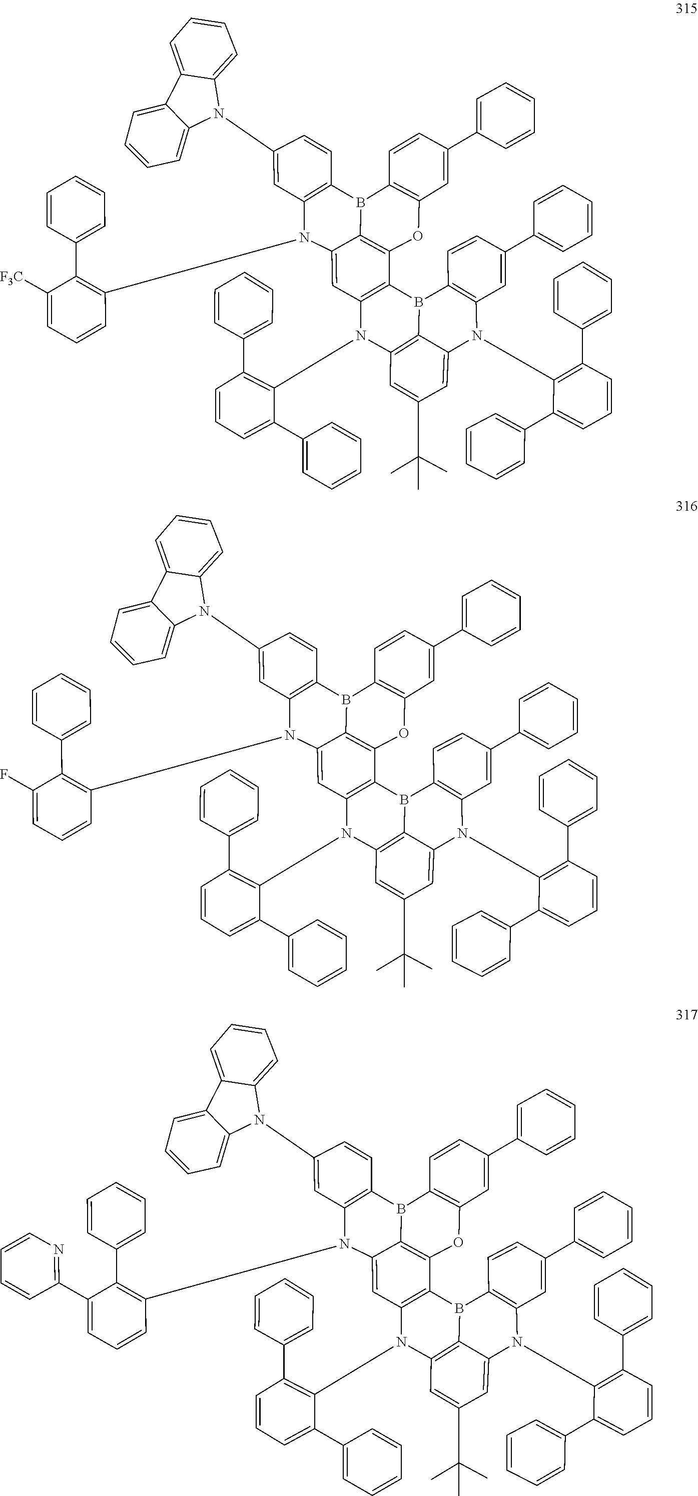

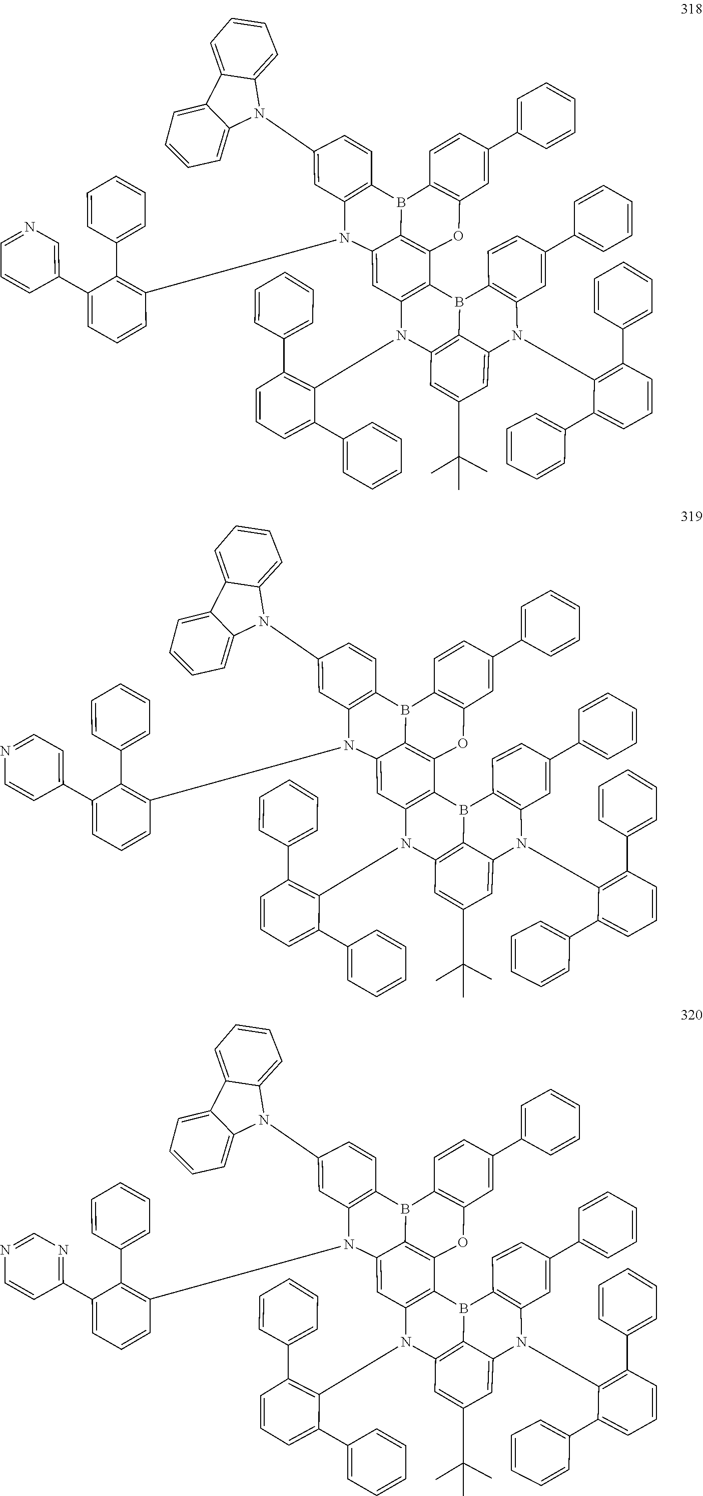

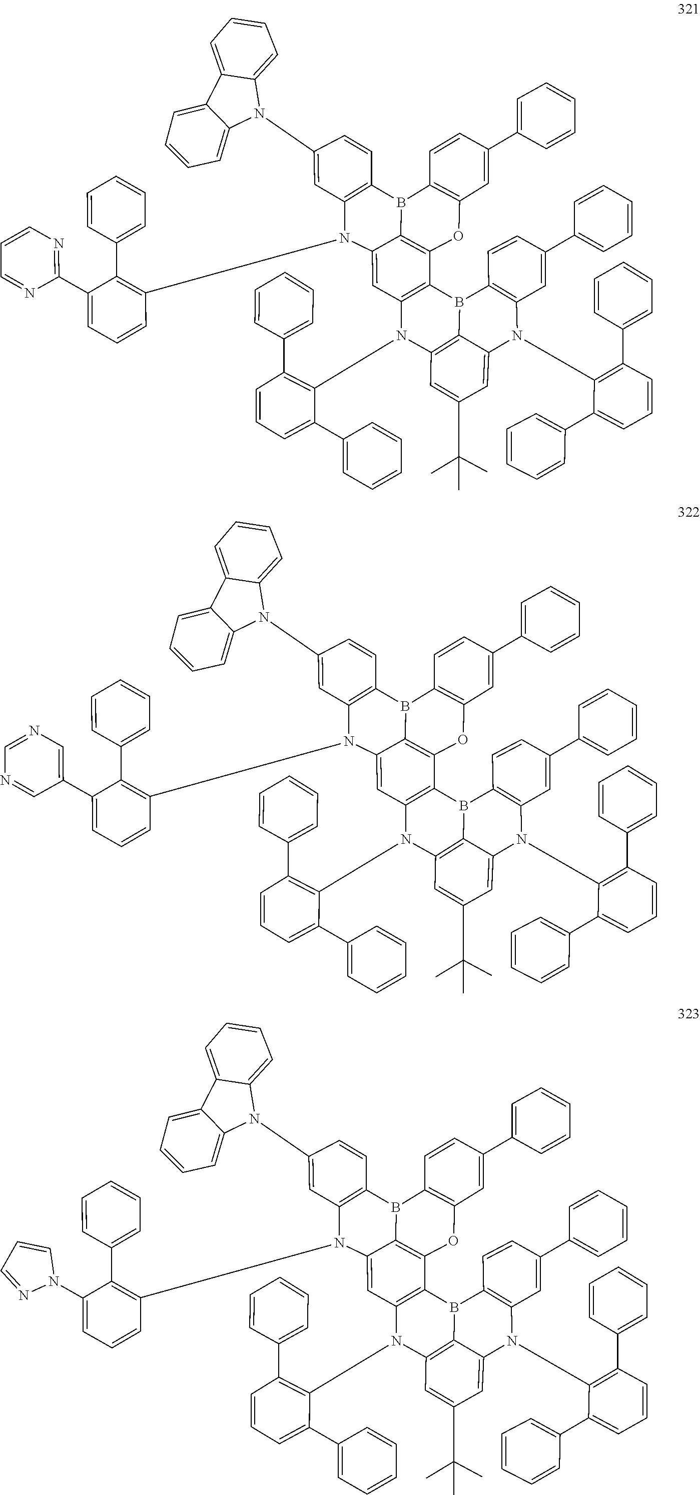

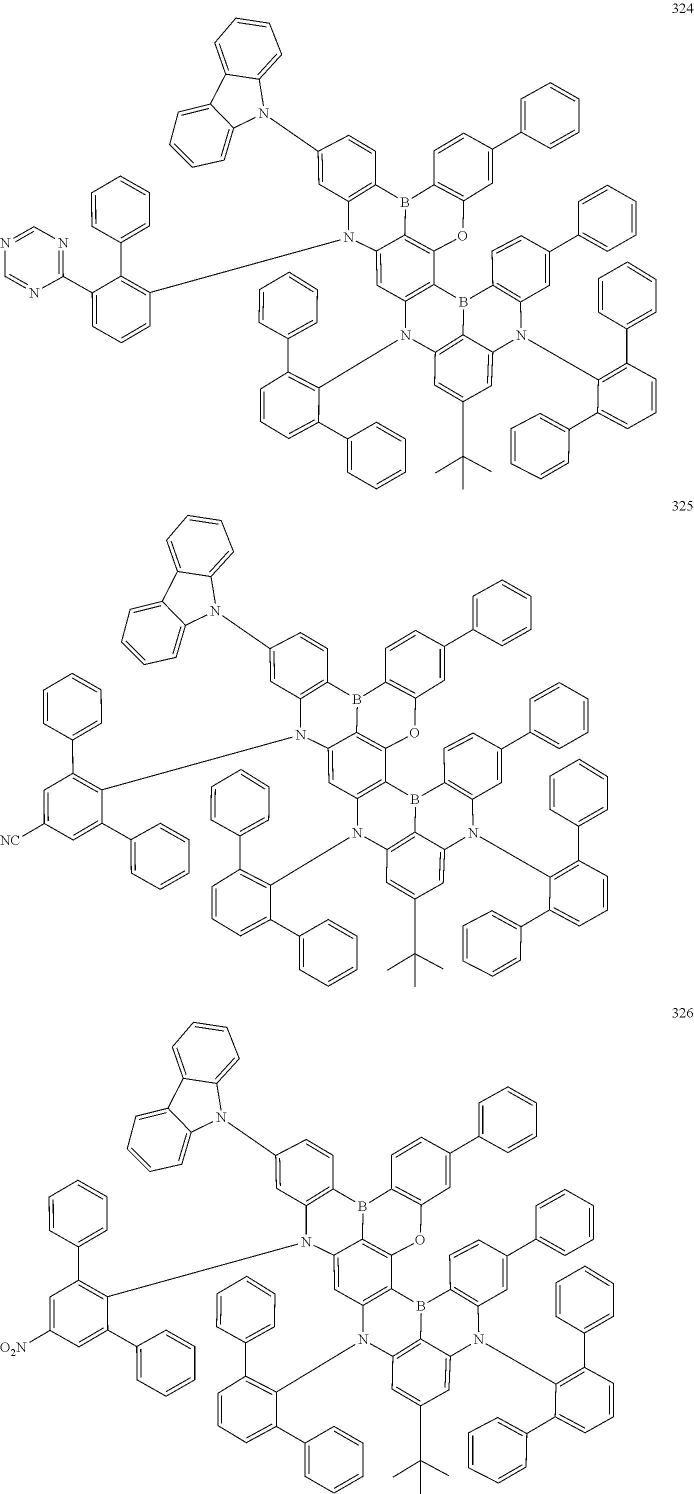

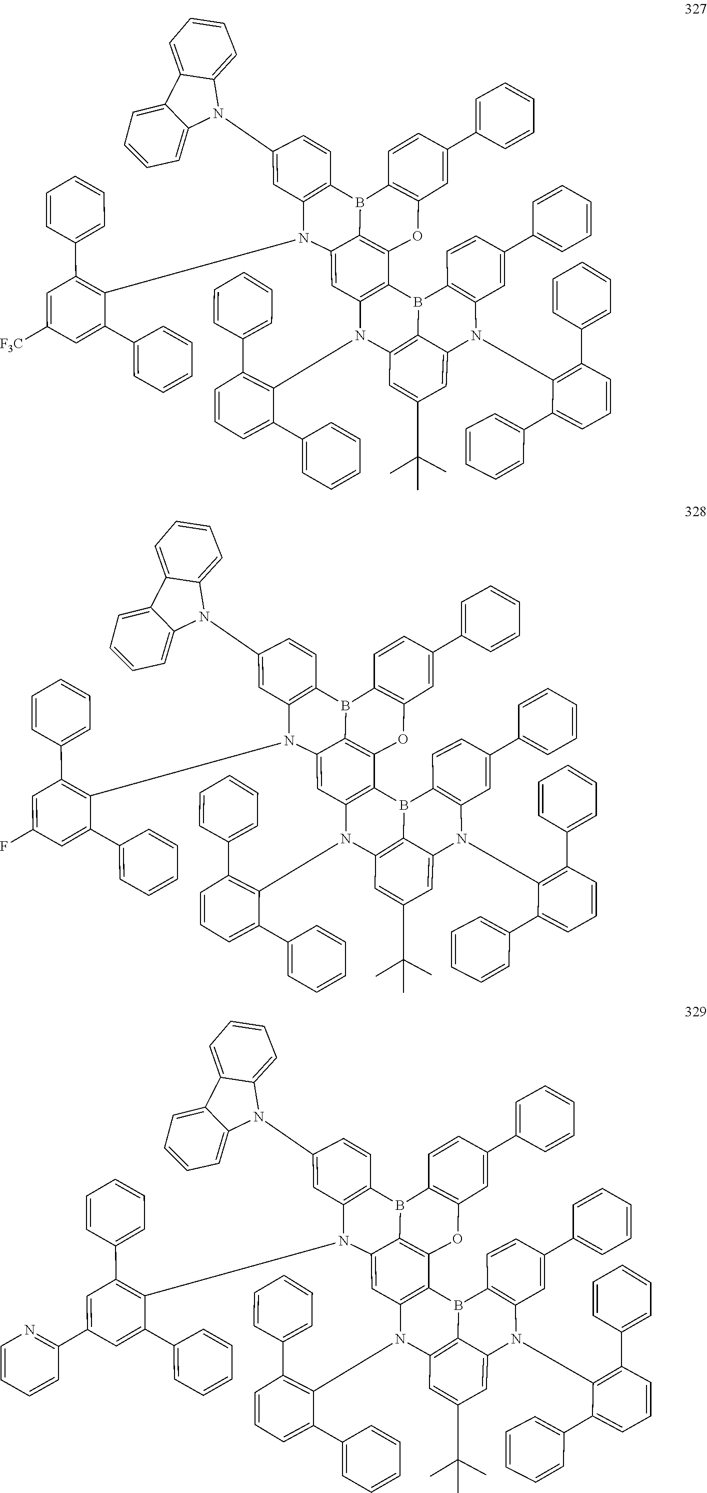

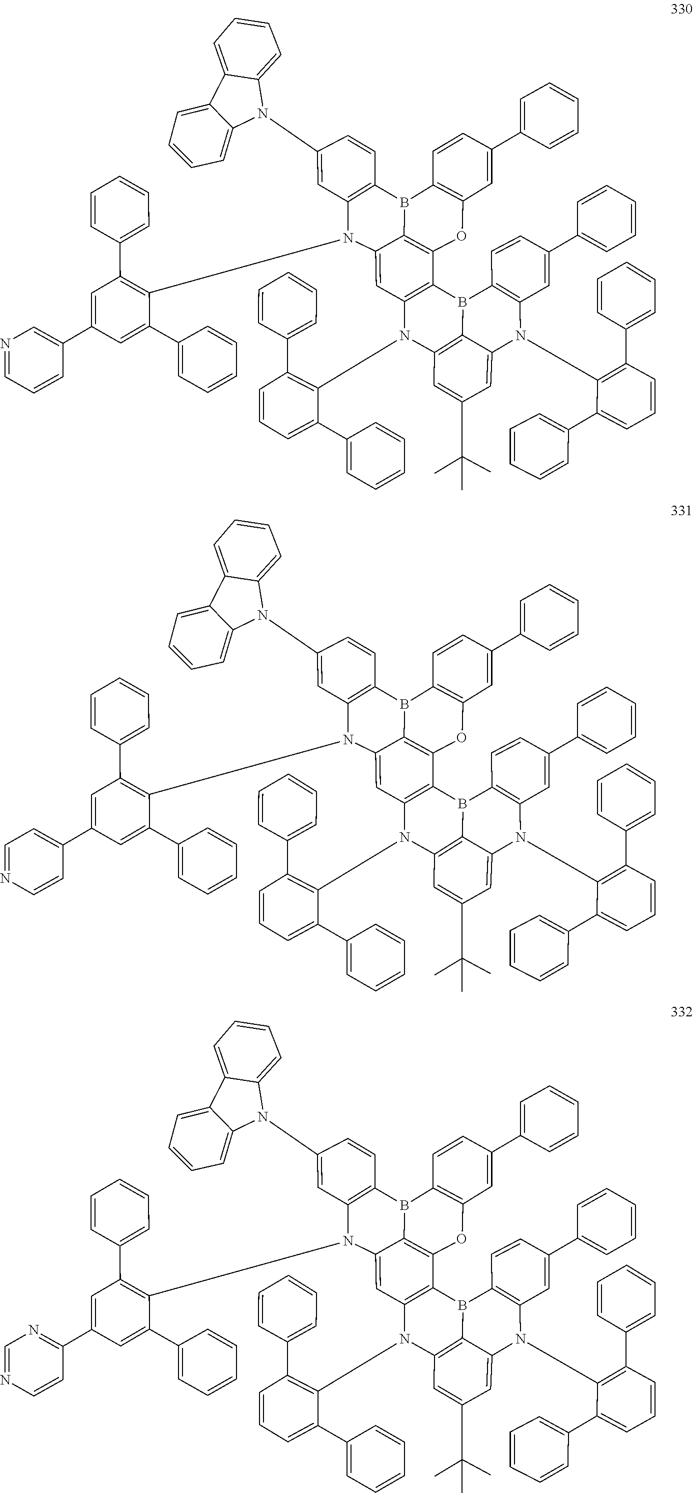

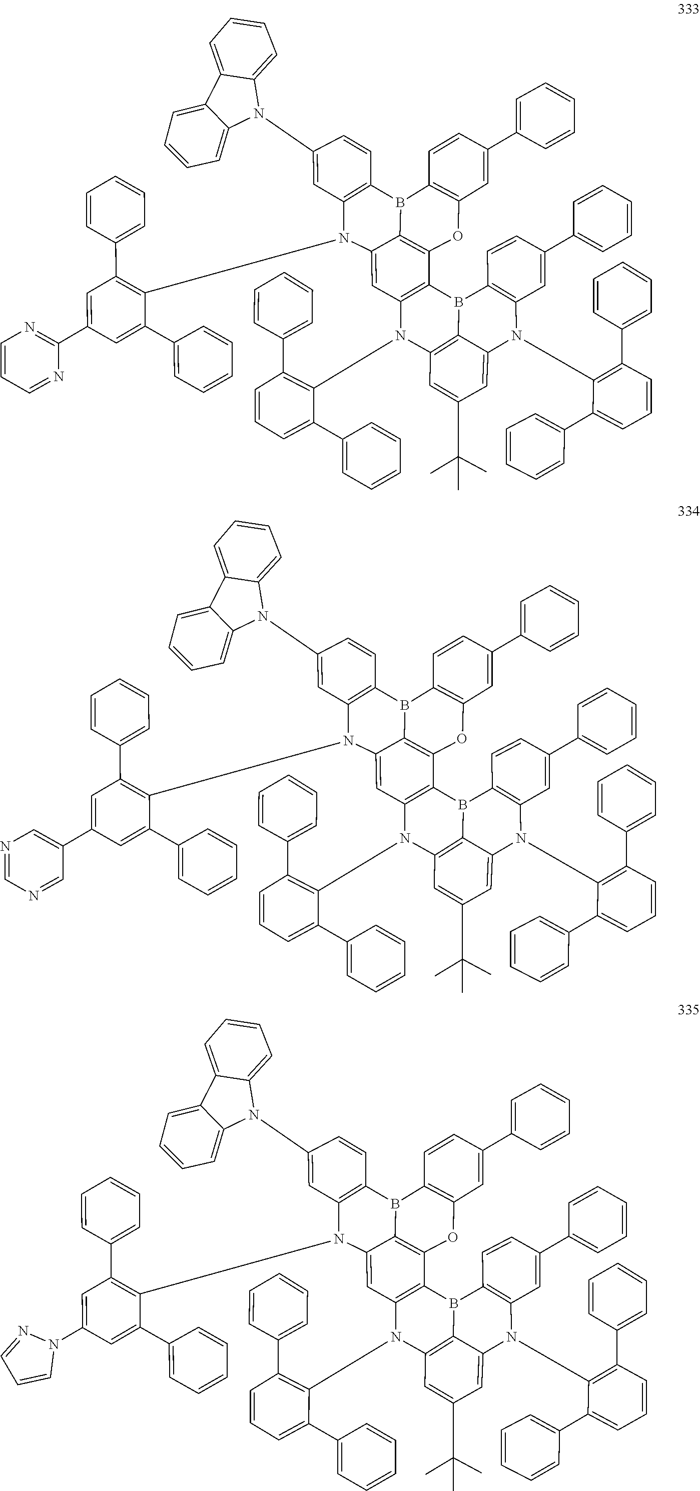

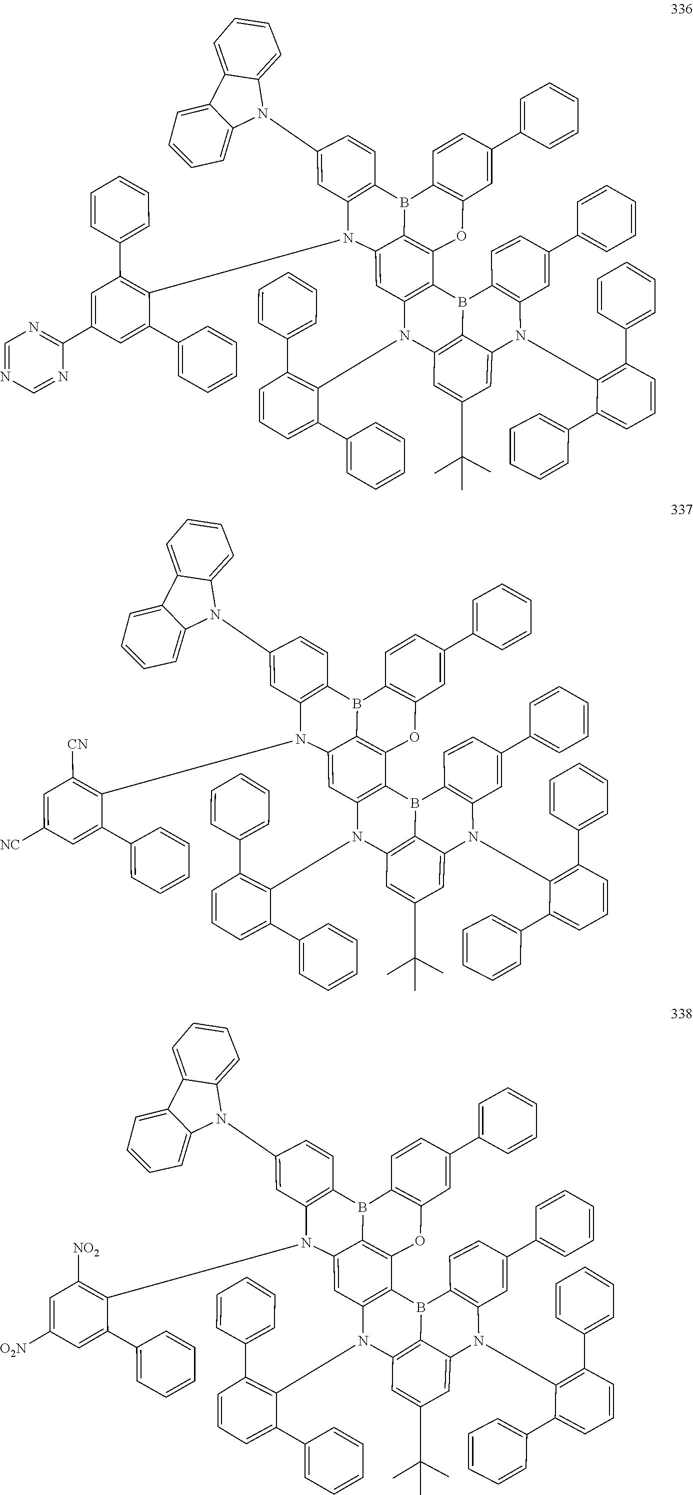

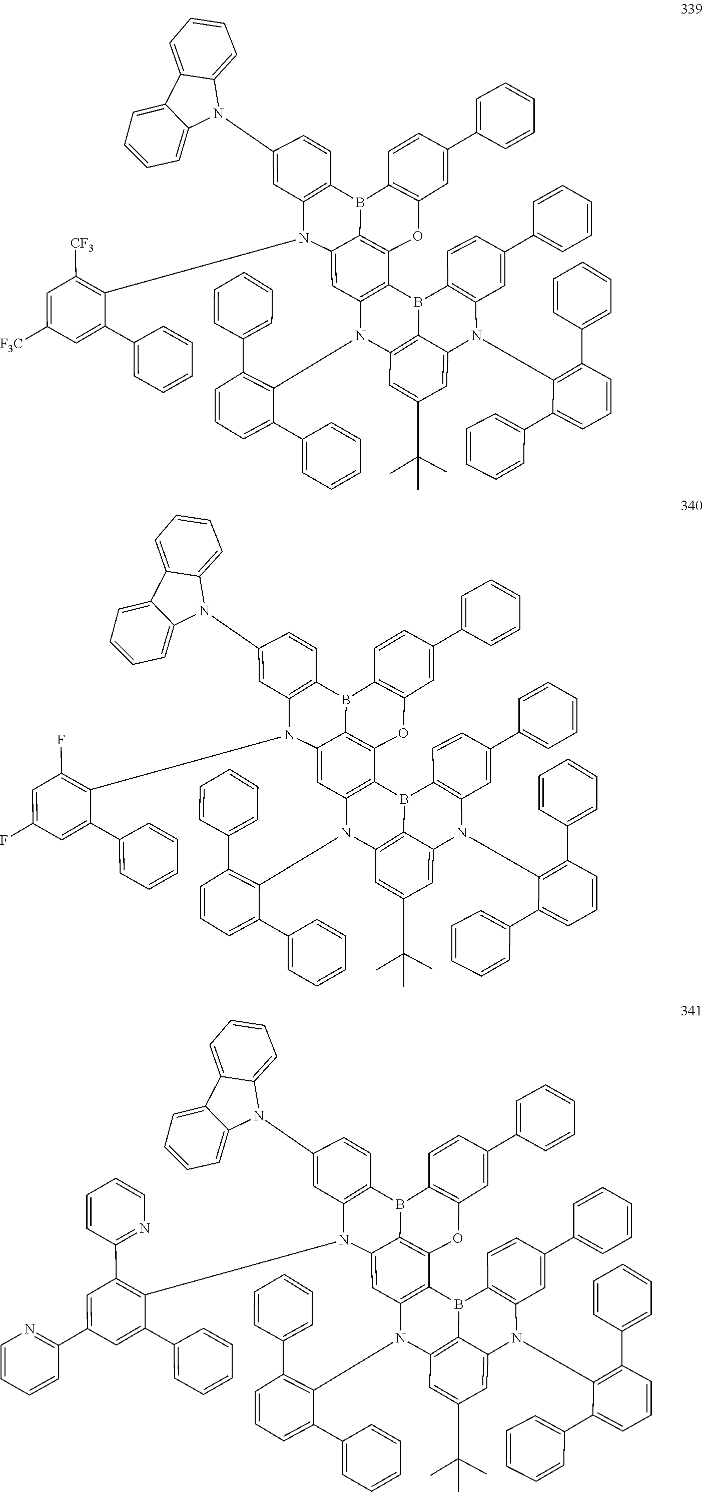

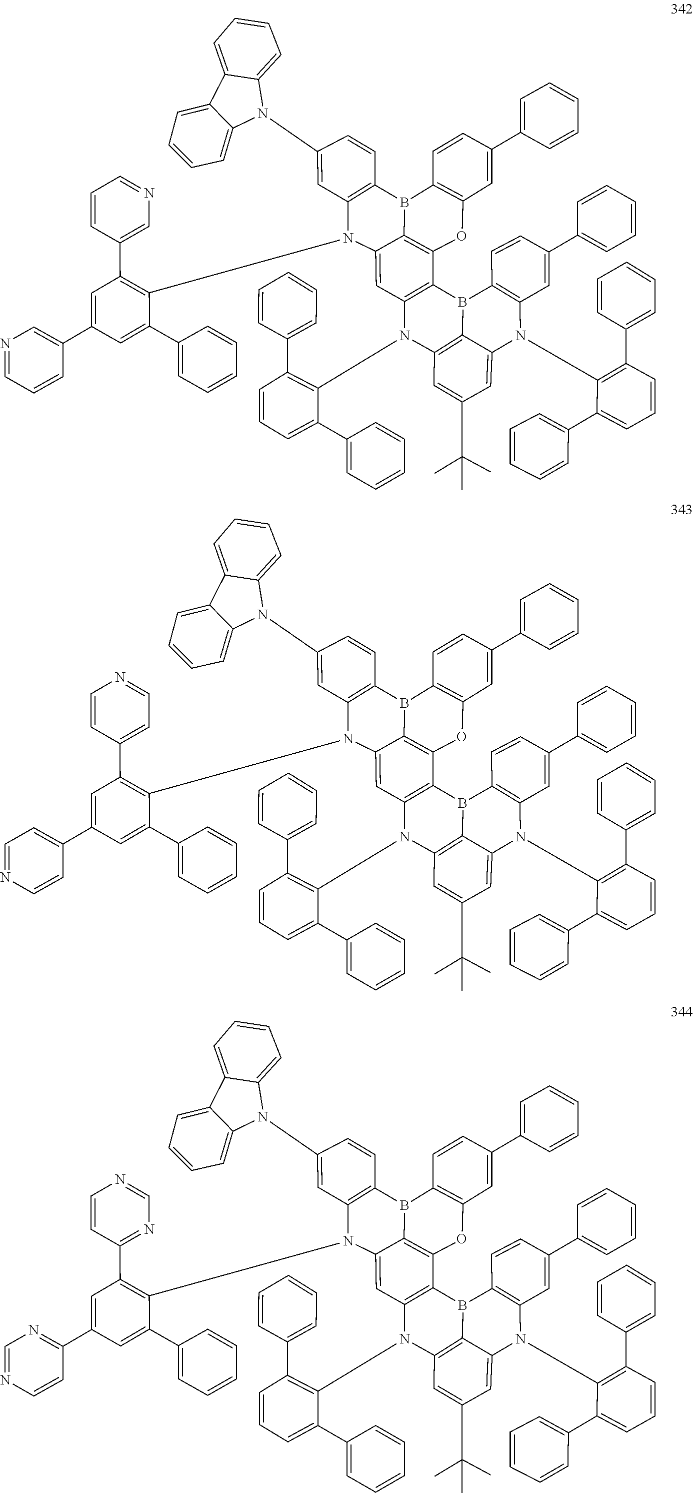

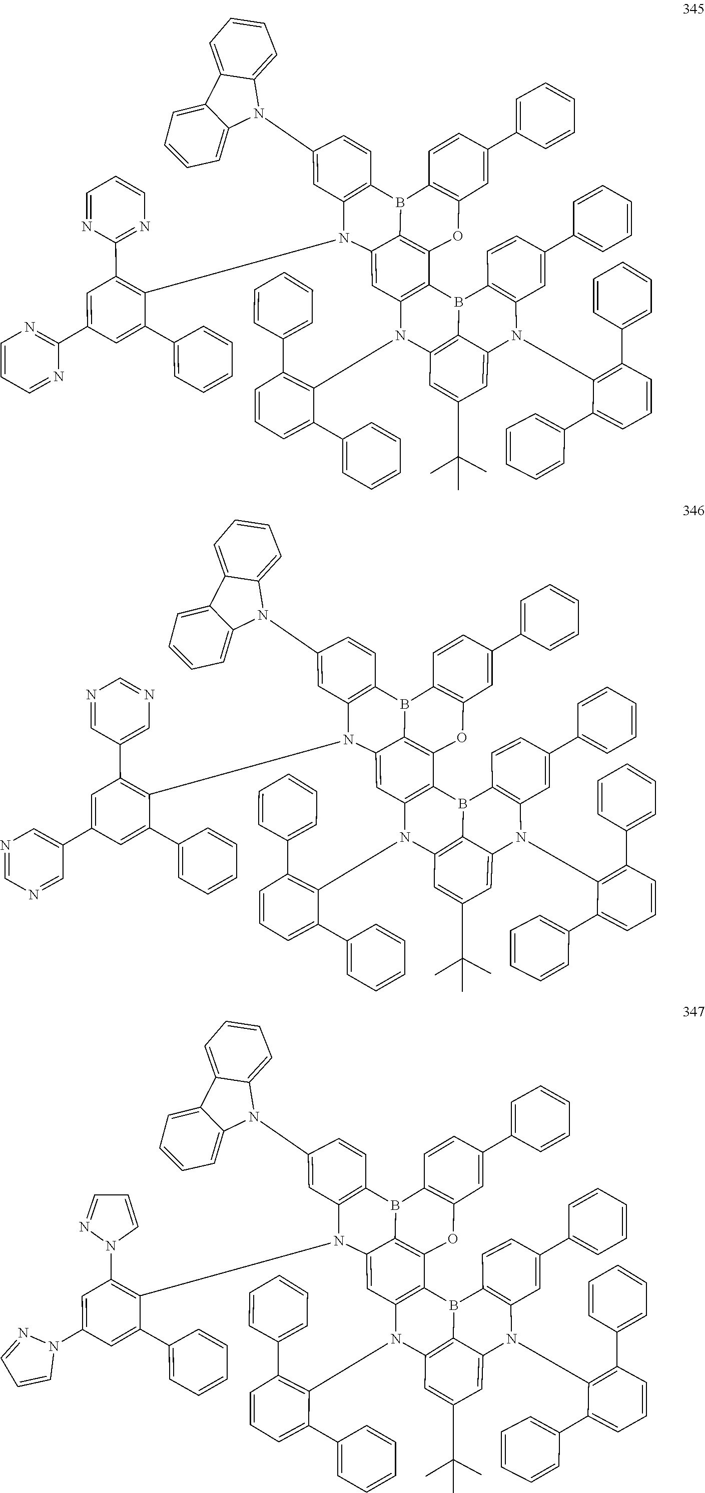

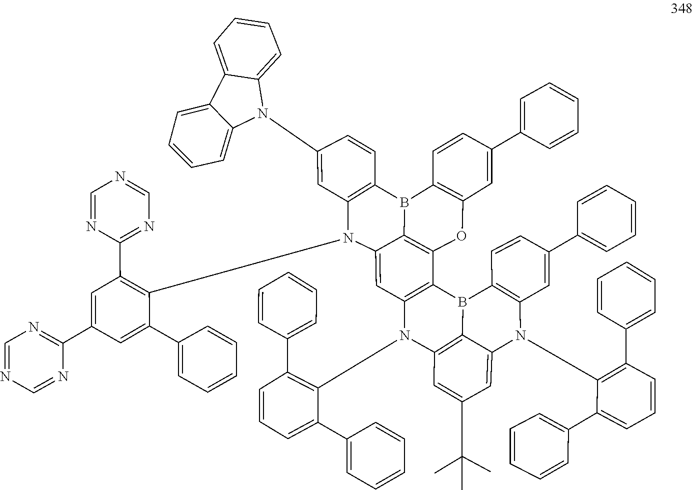

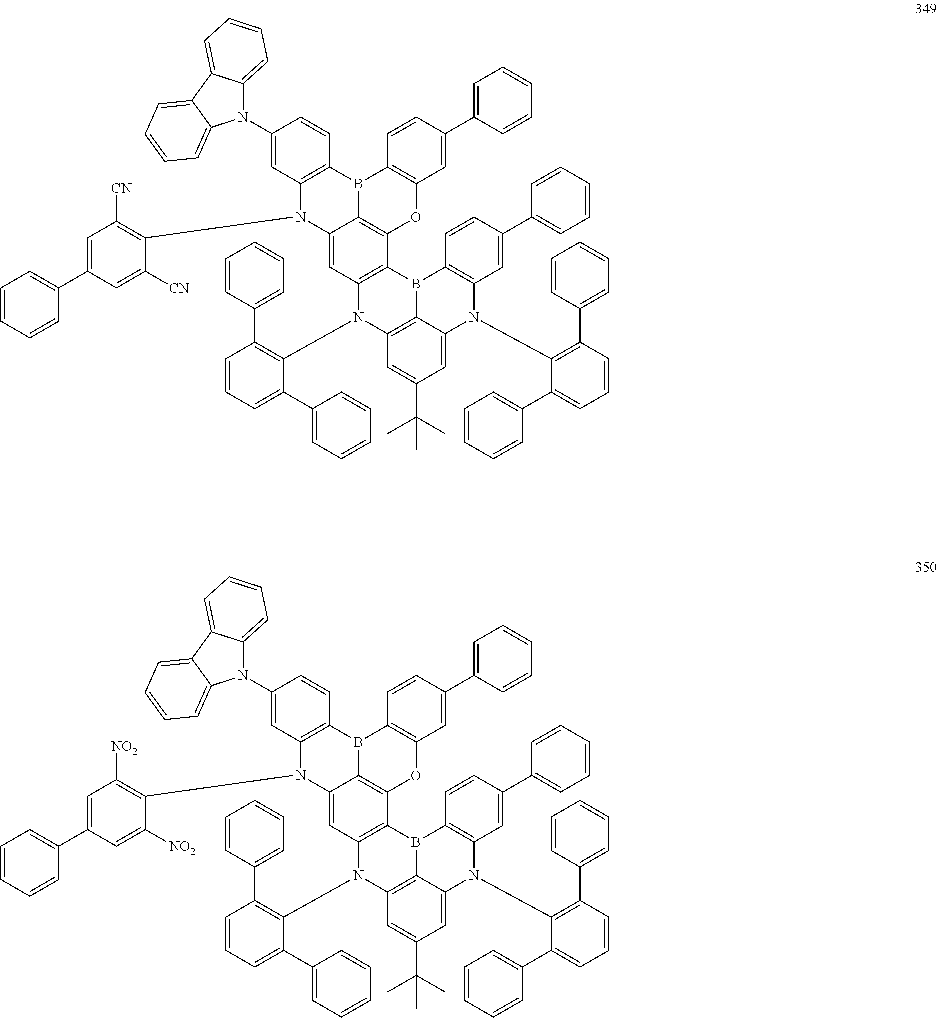 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(C#N)cc(-c2ccccc2)cc1C#N ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c([N+](=O)[O-])cc(-c2ccccc2)cc1[N+](=O)[O-]]

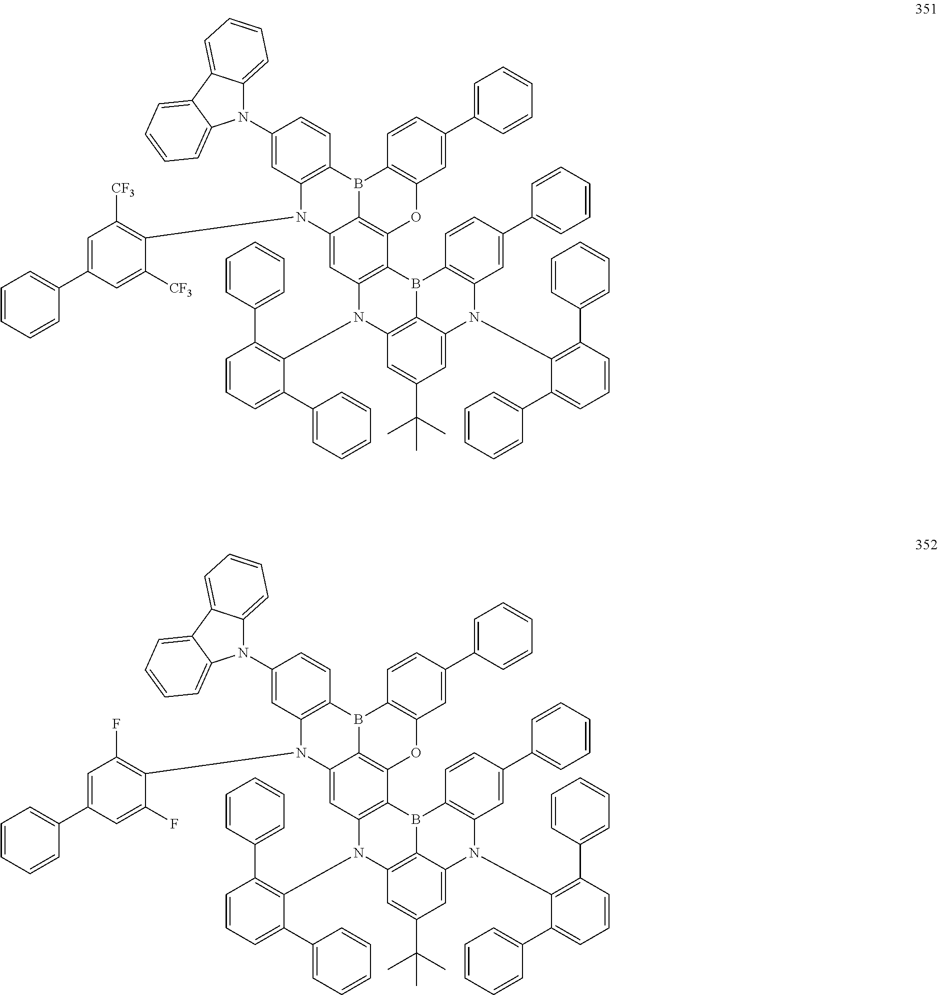 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(C(F)(F)F)cc(-c2ccccc2)cc1C(F)(F)F ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(F)cc(-c2ccccc2)cc1F]

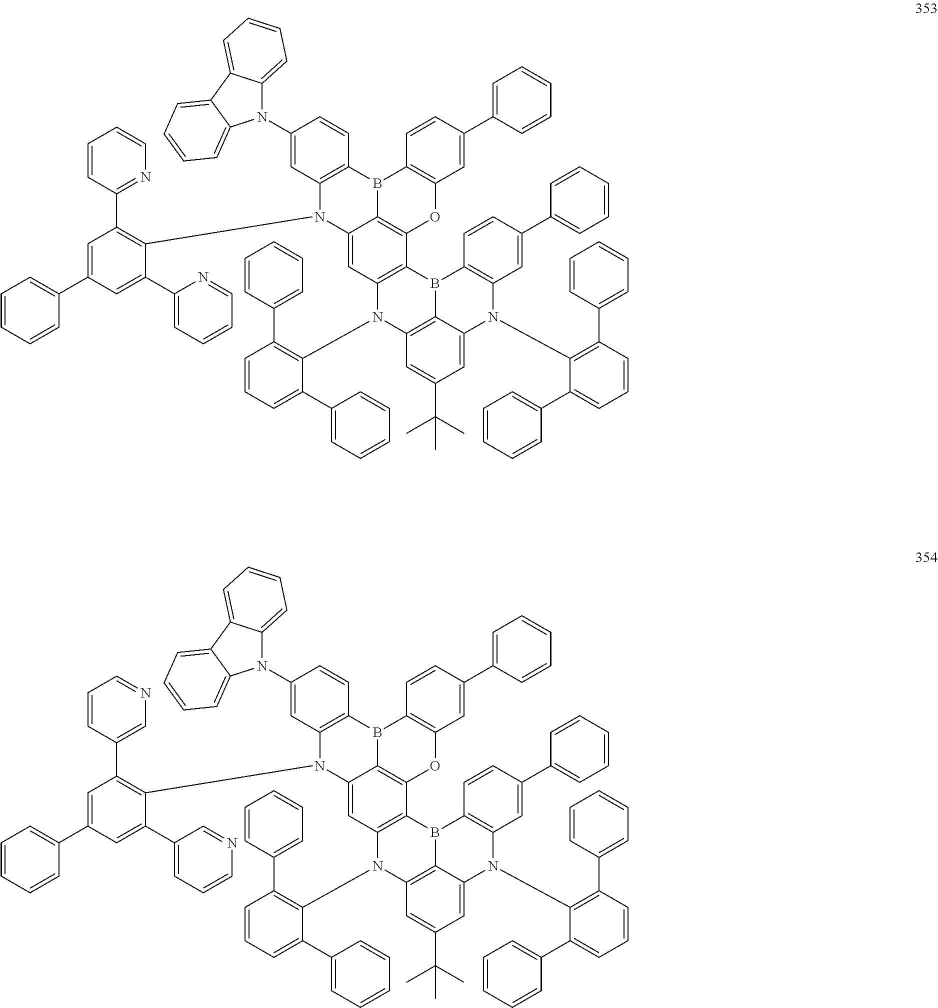 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccccn2)cc(-c2ccccc2)cc1-c1ccccn1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2cccnc2)cc(-c2ccccc2)cc1-c1cccnc1]

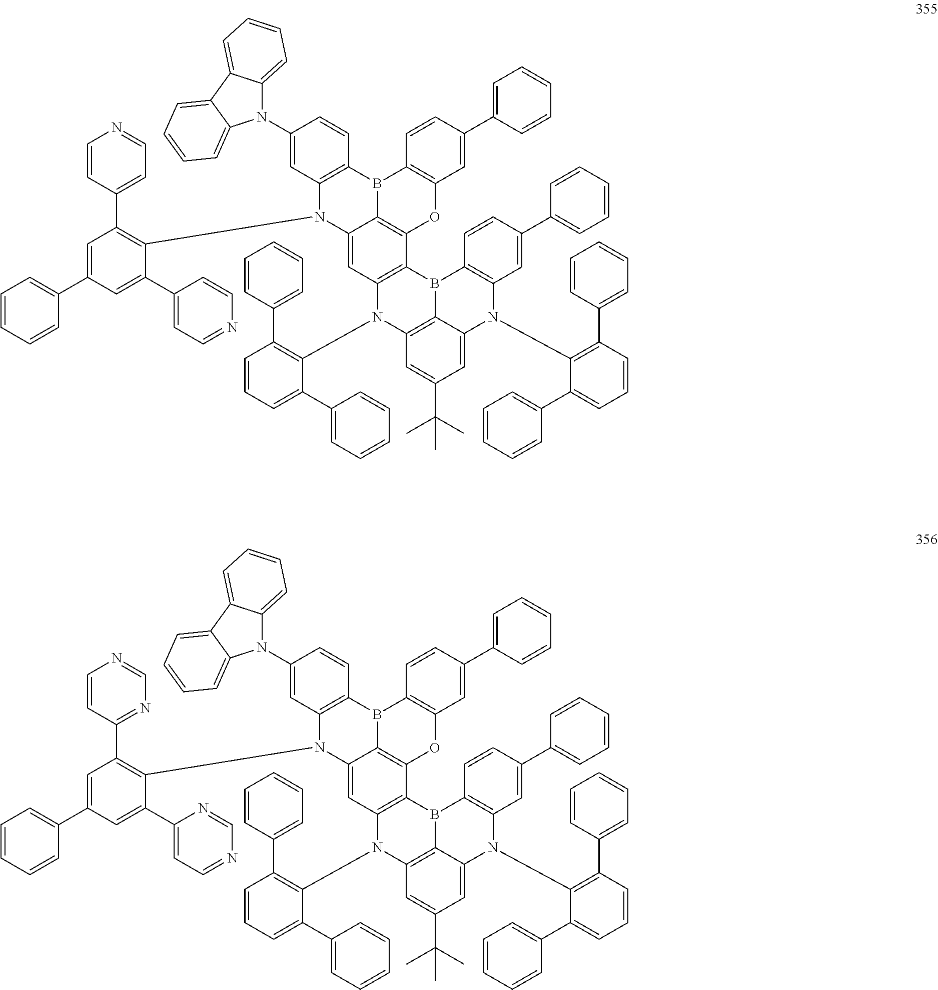 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccncc2)cc(-c2ccccc2)cc1-c1ccncc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccncn2)cc(-c2ccccc2)cc1-c1ccncn1]

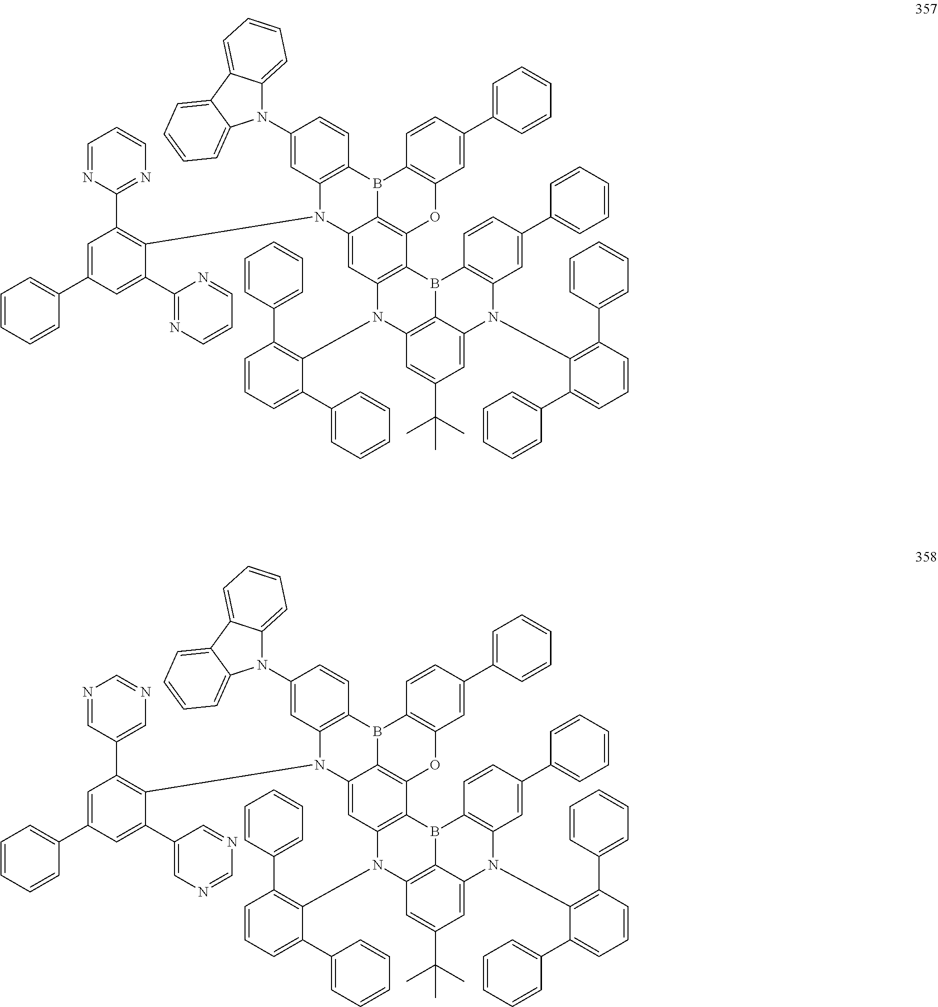 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2ncccn2)cc(-c2ccccc2)cc1-c1ncccn1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2cncnc2)cc(-c2ccccc2)cc1-c1cncnc1]

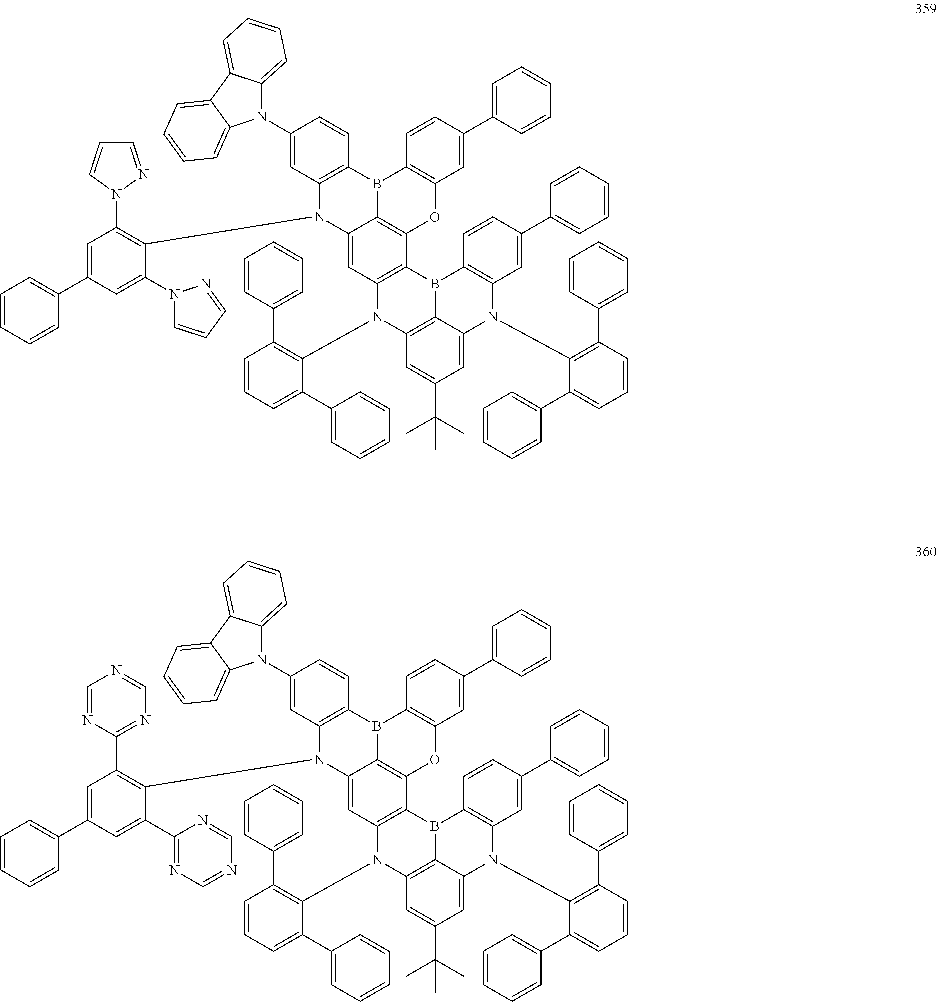 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-n2cccn2)cc(-c2ccccc2)cc1-n1cccn1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1c(-c2ncncn2)cc(-c2ccccc2)cc1-c1ncncn1]

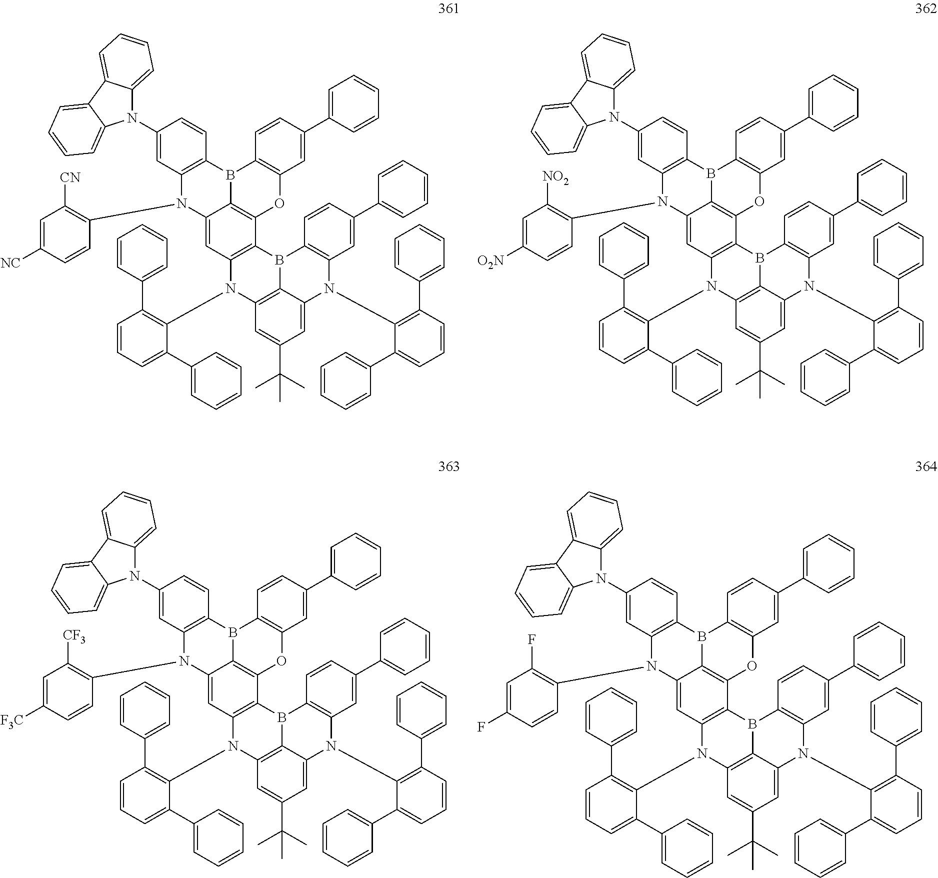

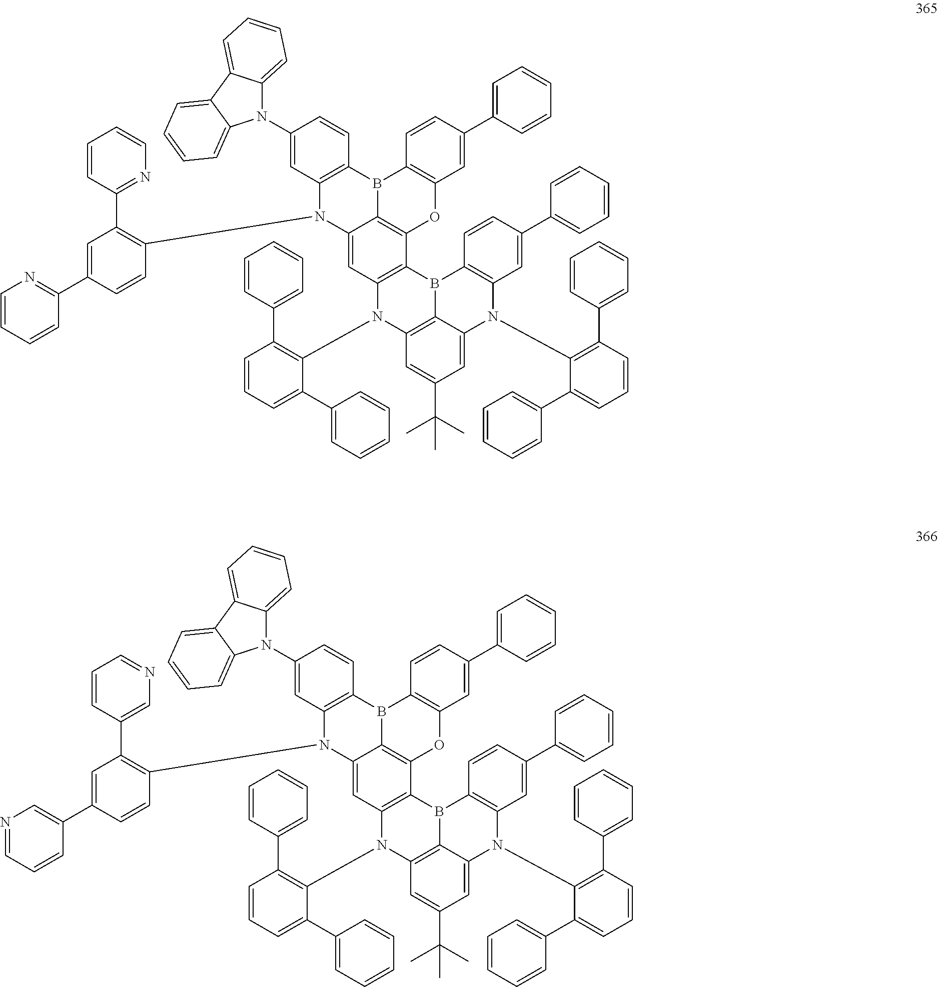 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ccccn2)cc1-c1ccccn1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2cccnc2)cc1-c1cccnc1]

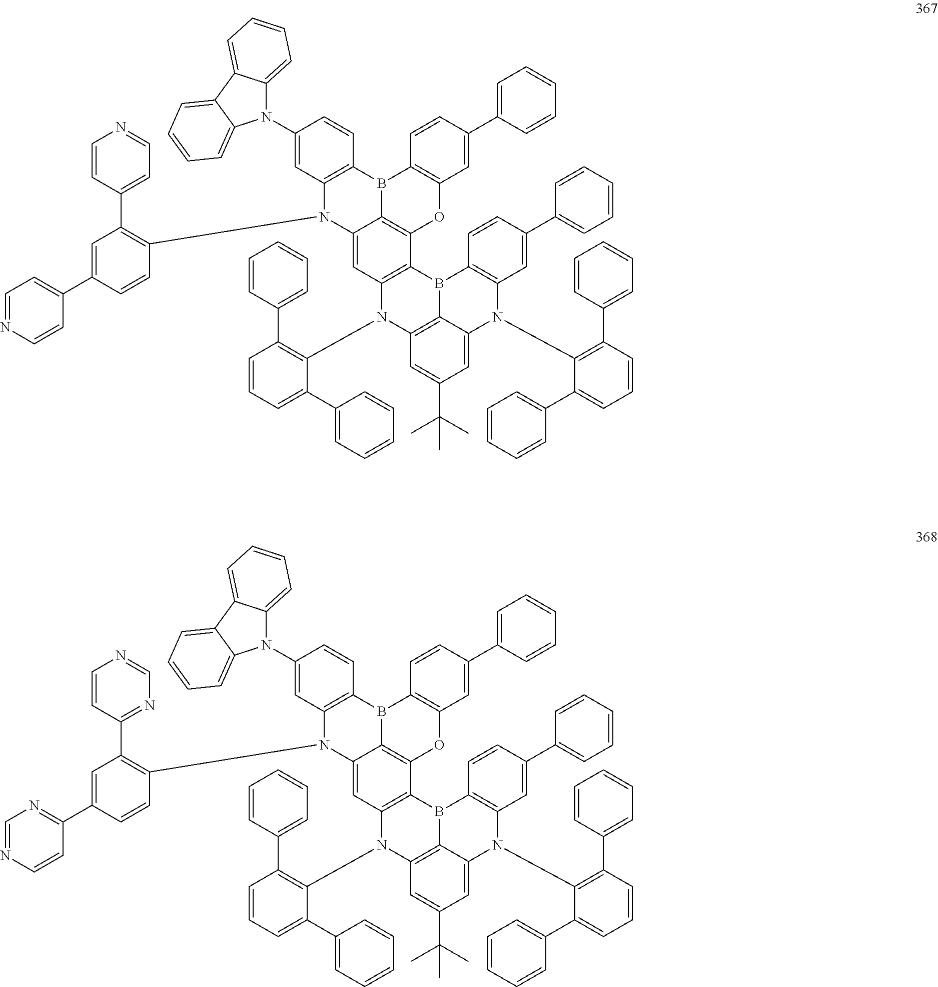 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ccncc2)cc1-c1ccncc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ccncn2)cc1-c1ccncn1]

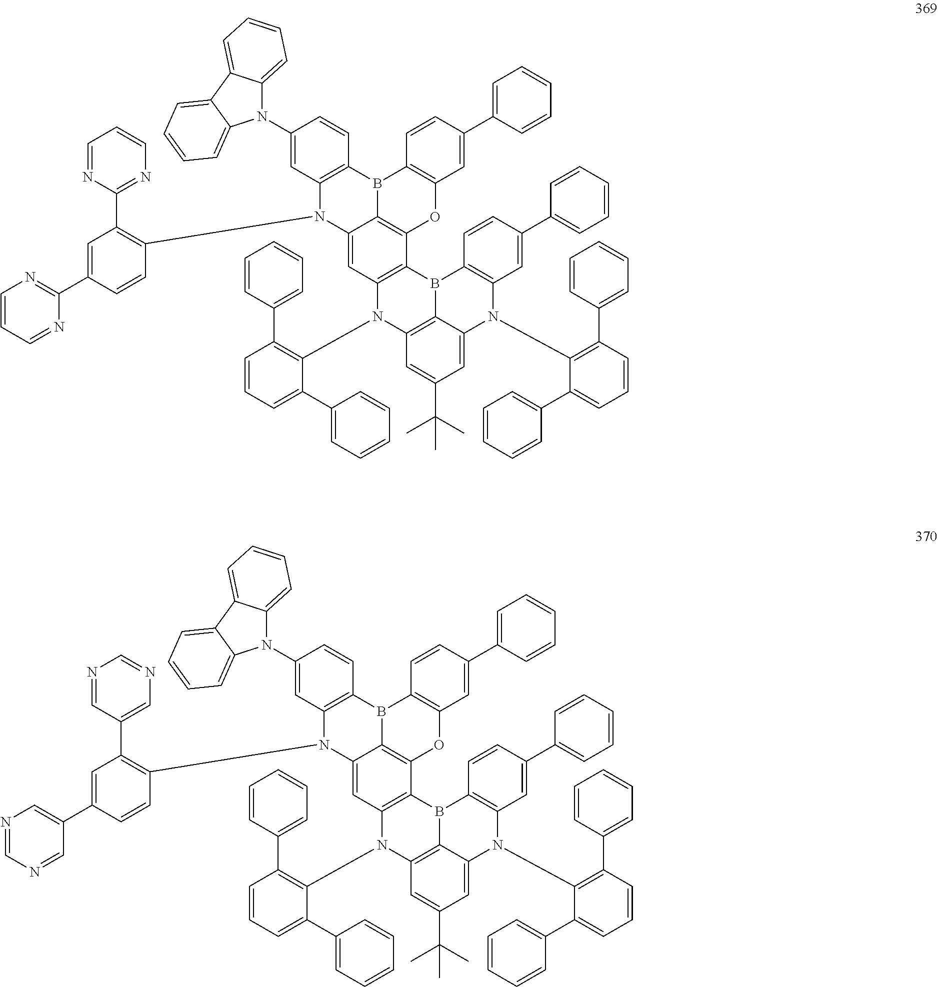 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ncccn2)cc1-c1ncccn1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2cncnc2)cc1-c1cncnc1]

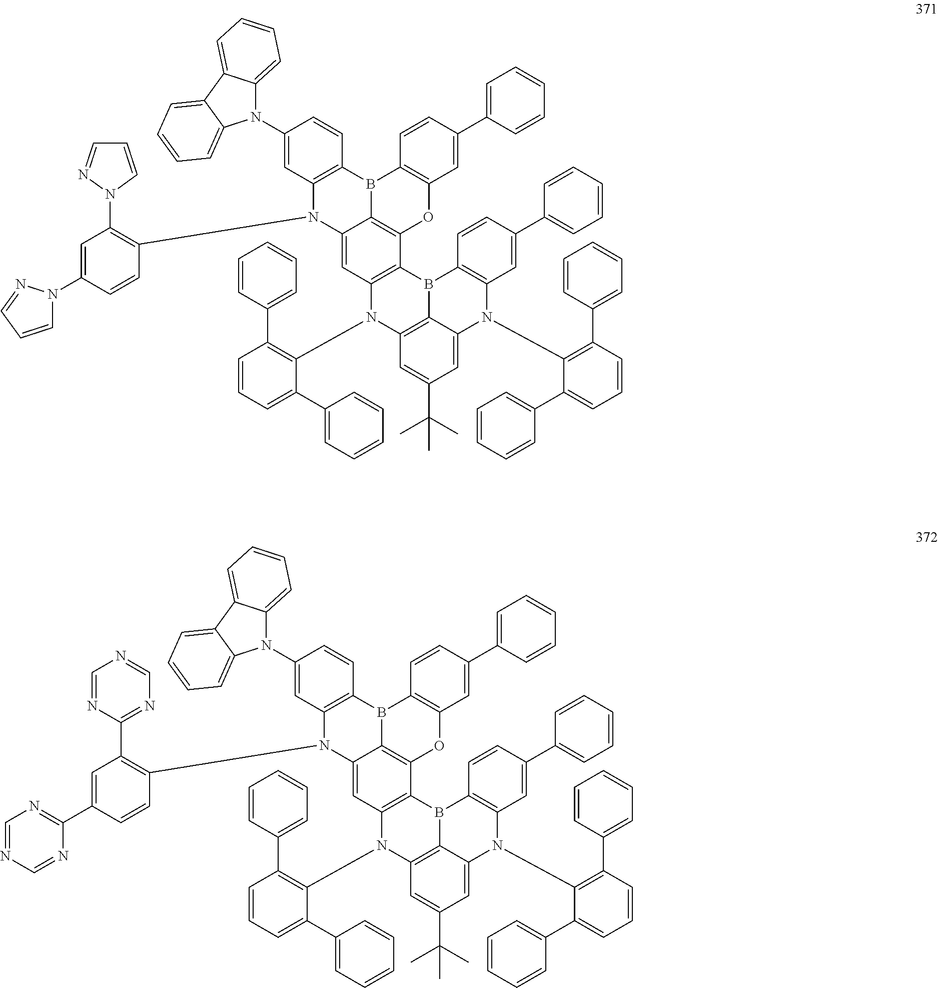 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-n2cccn2)cc1-n1cccn1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ncncn2)cc1-c1ncncn1]

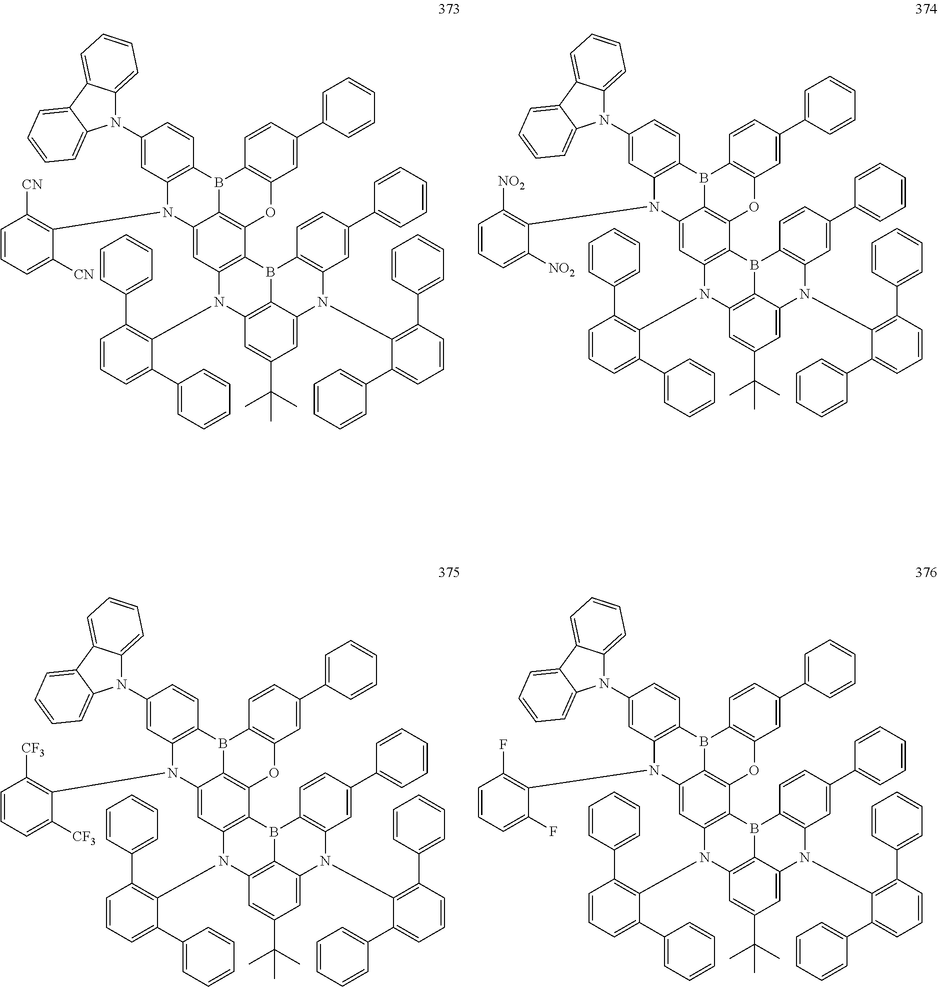

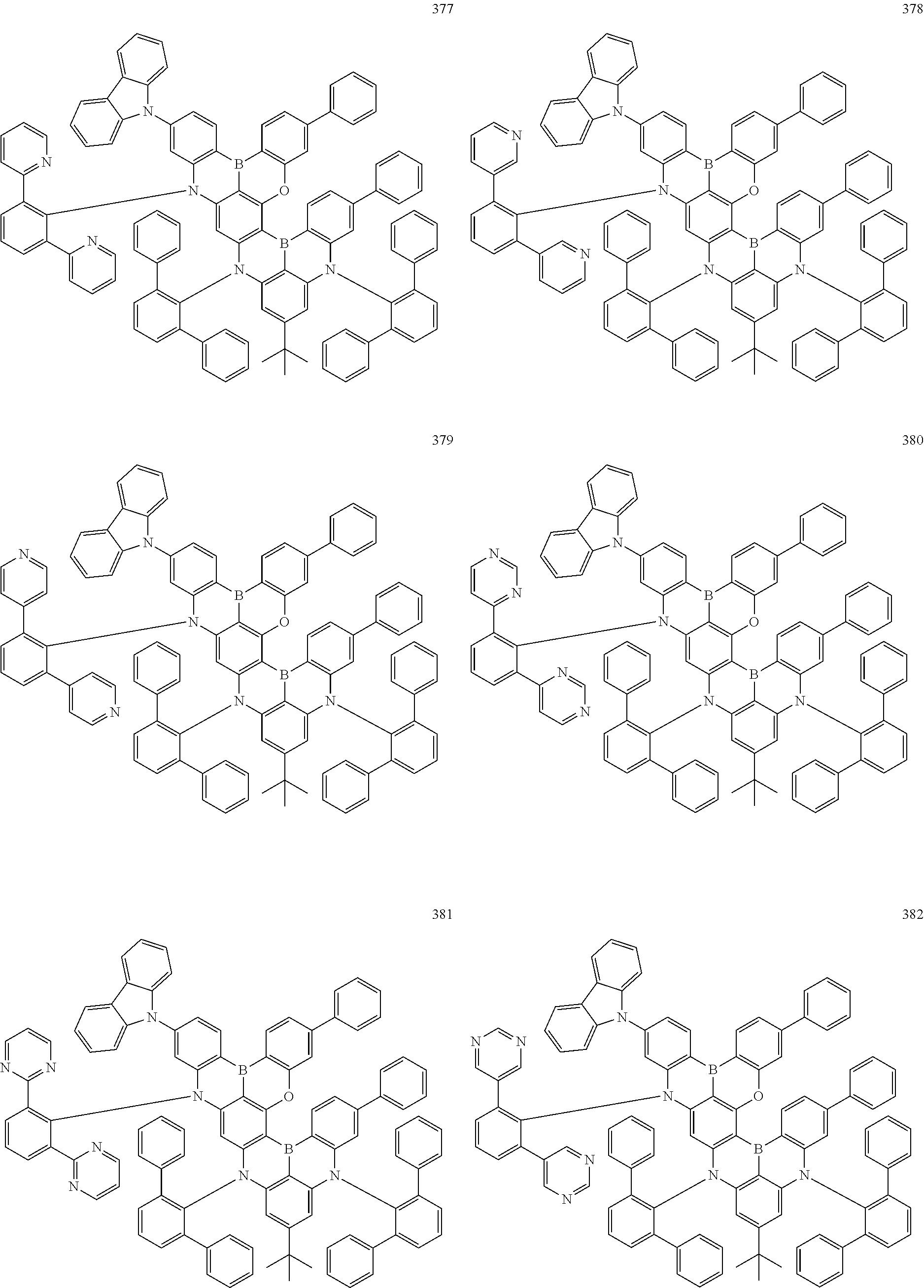

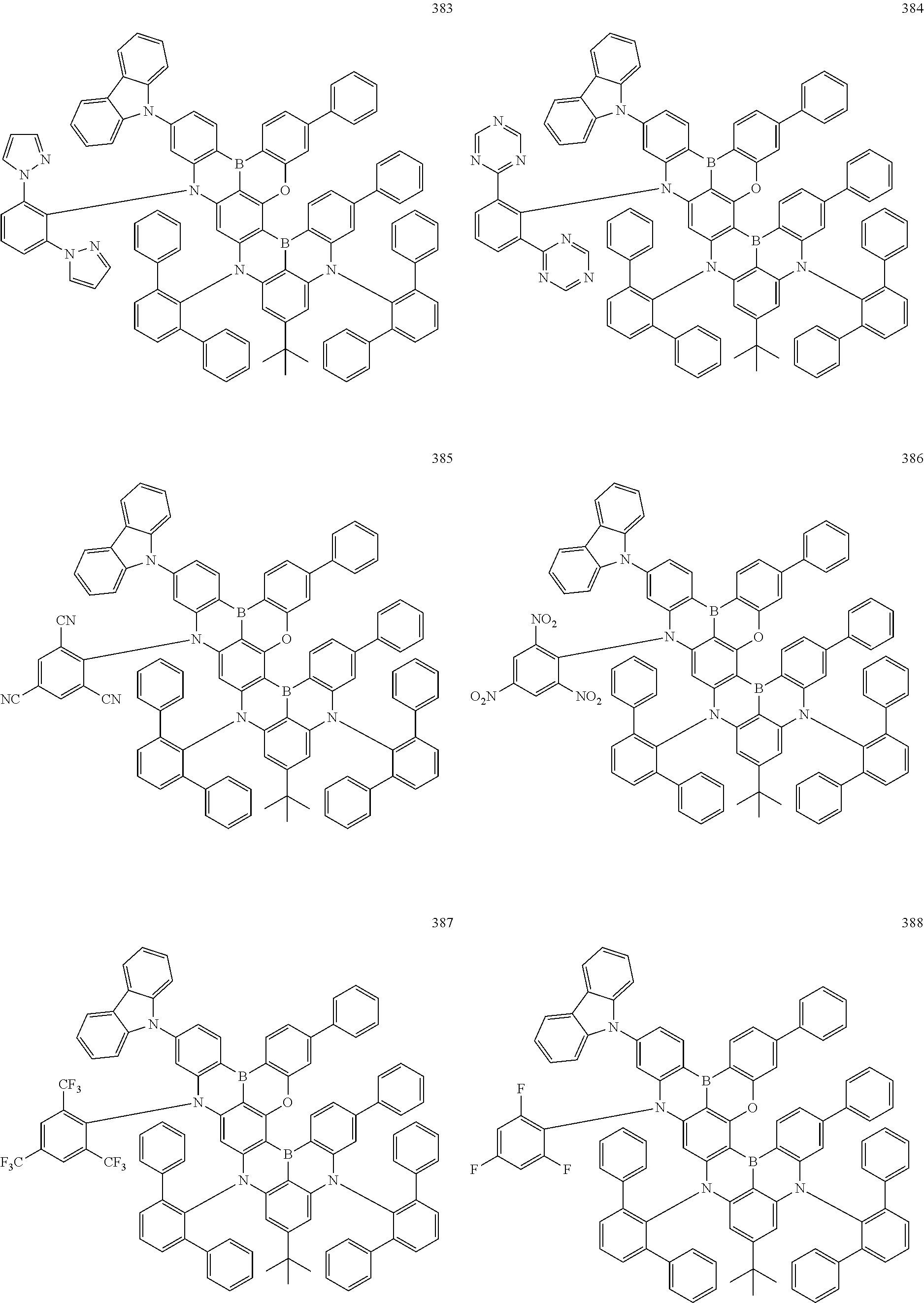

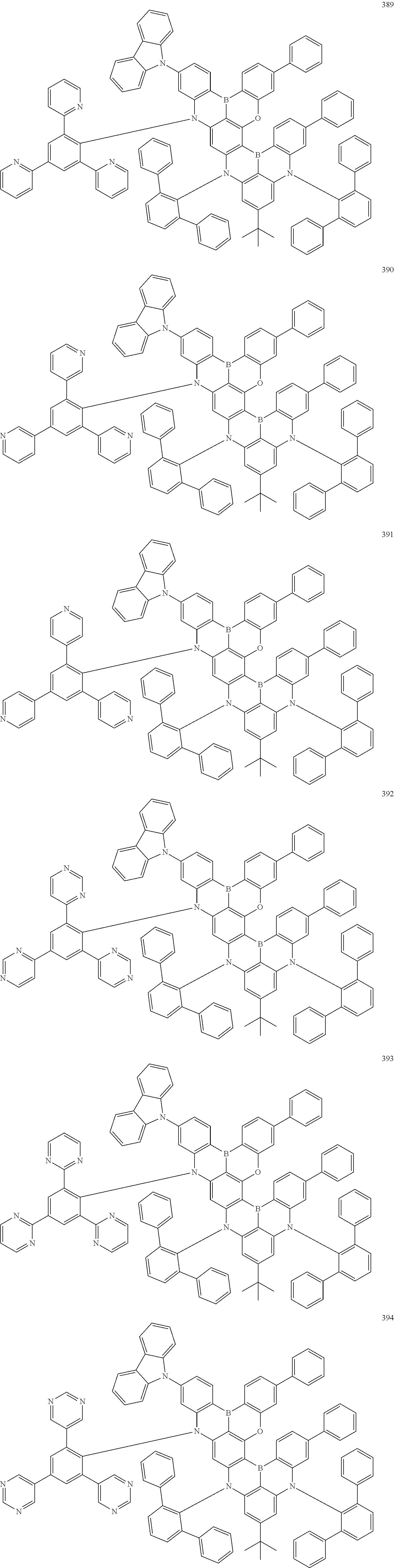

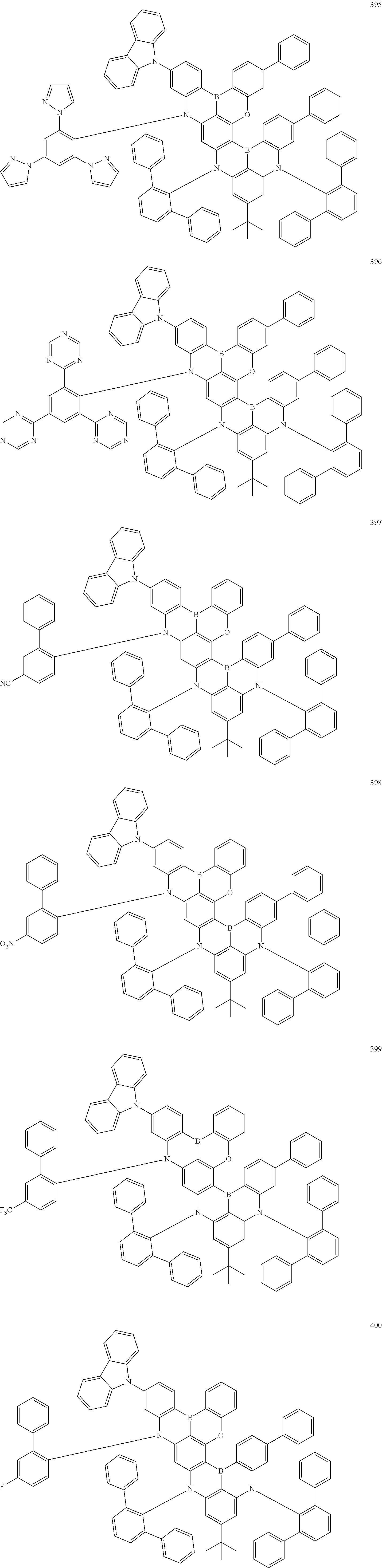

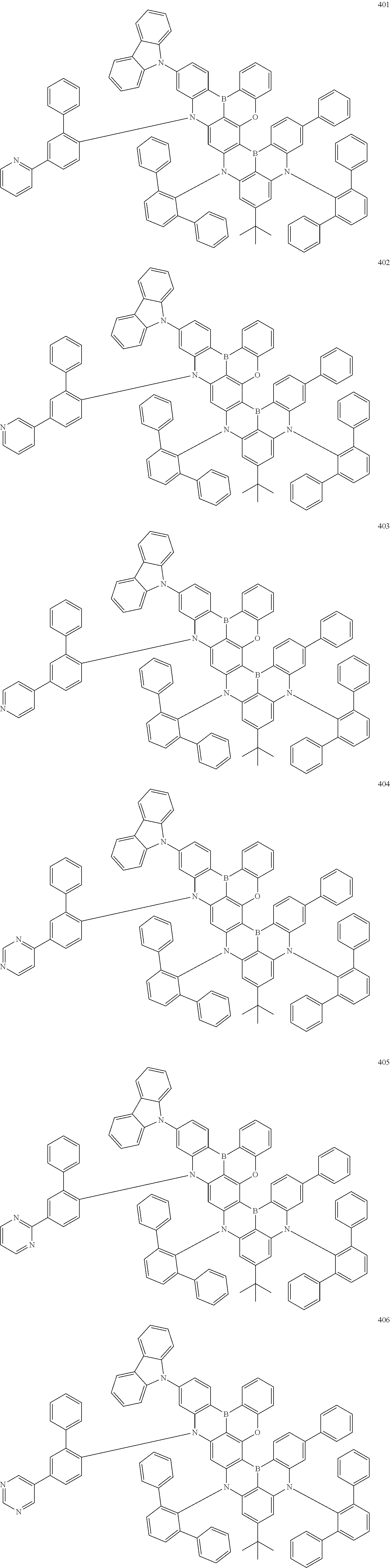

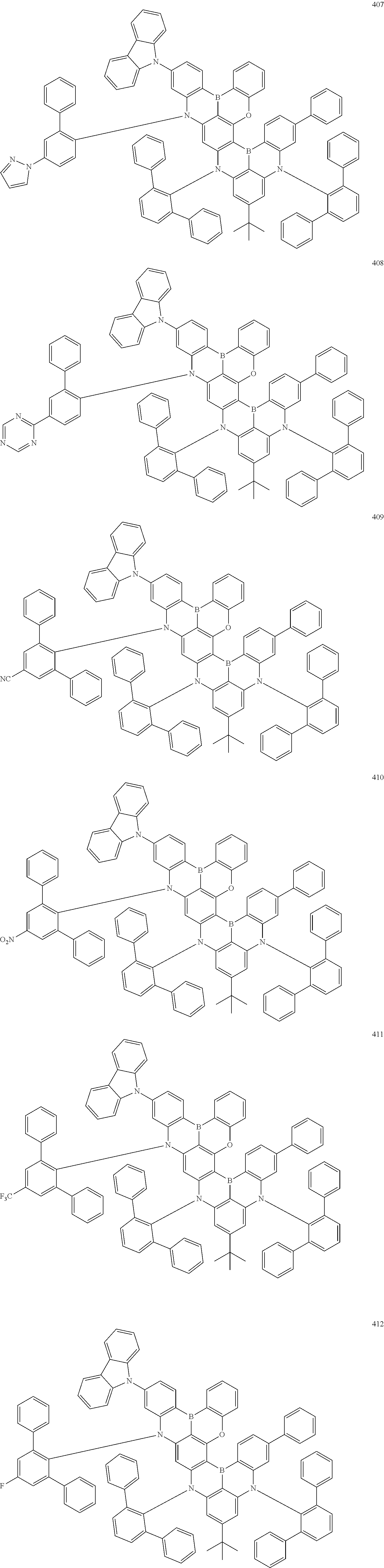

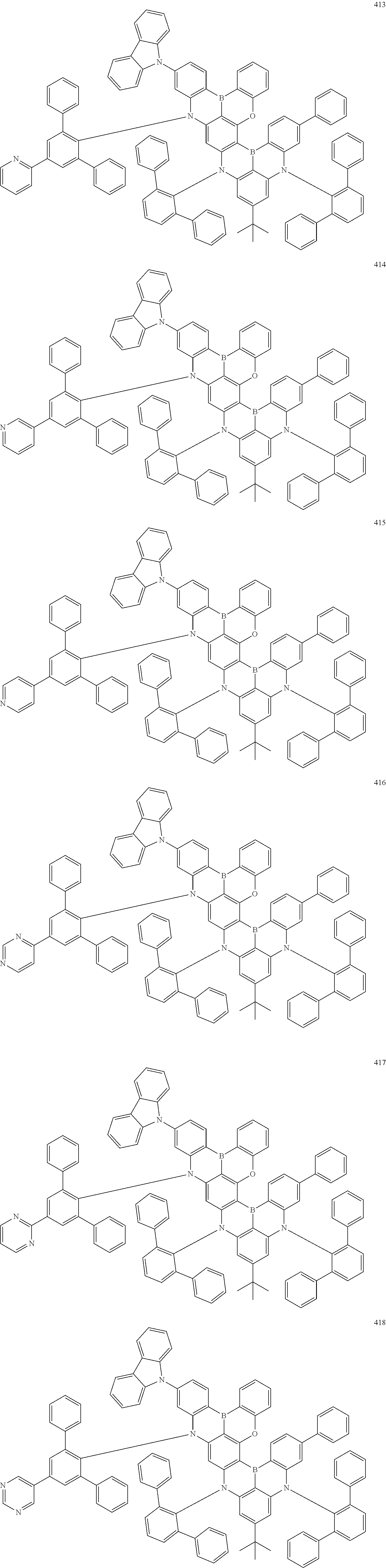

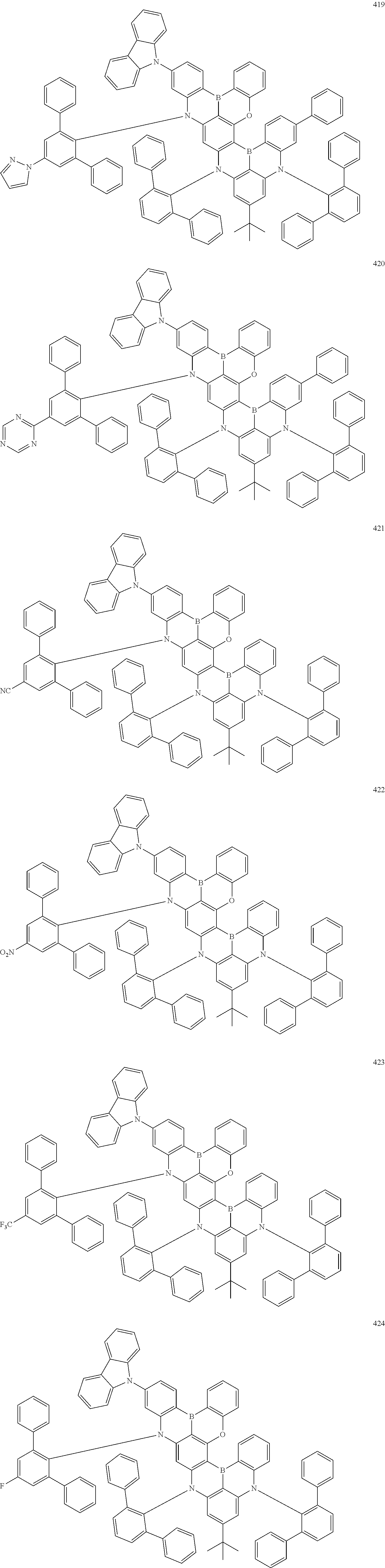

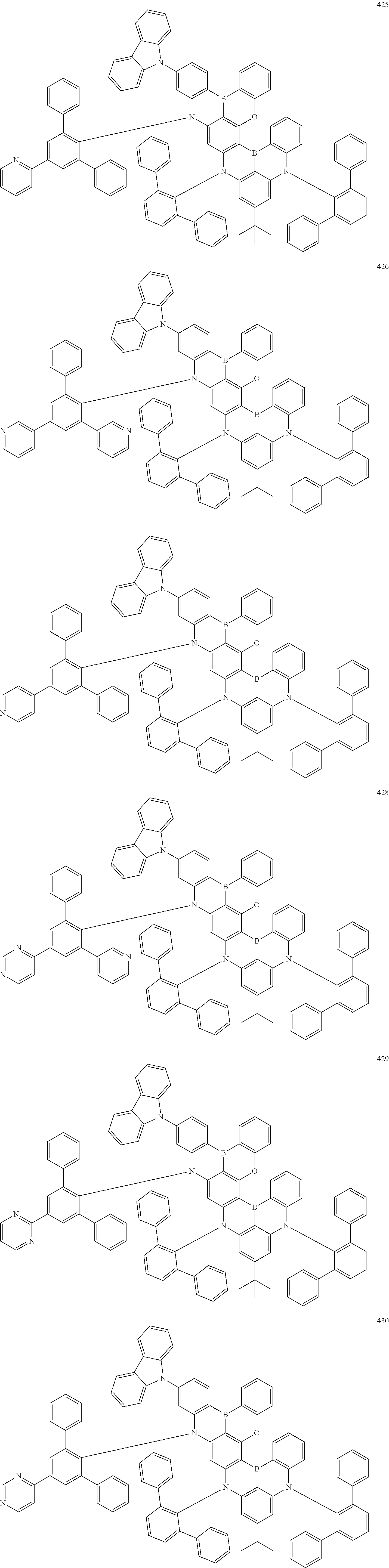

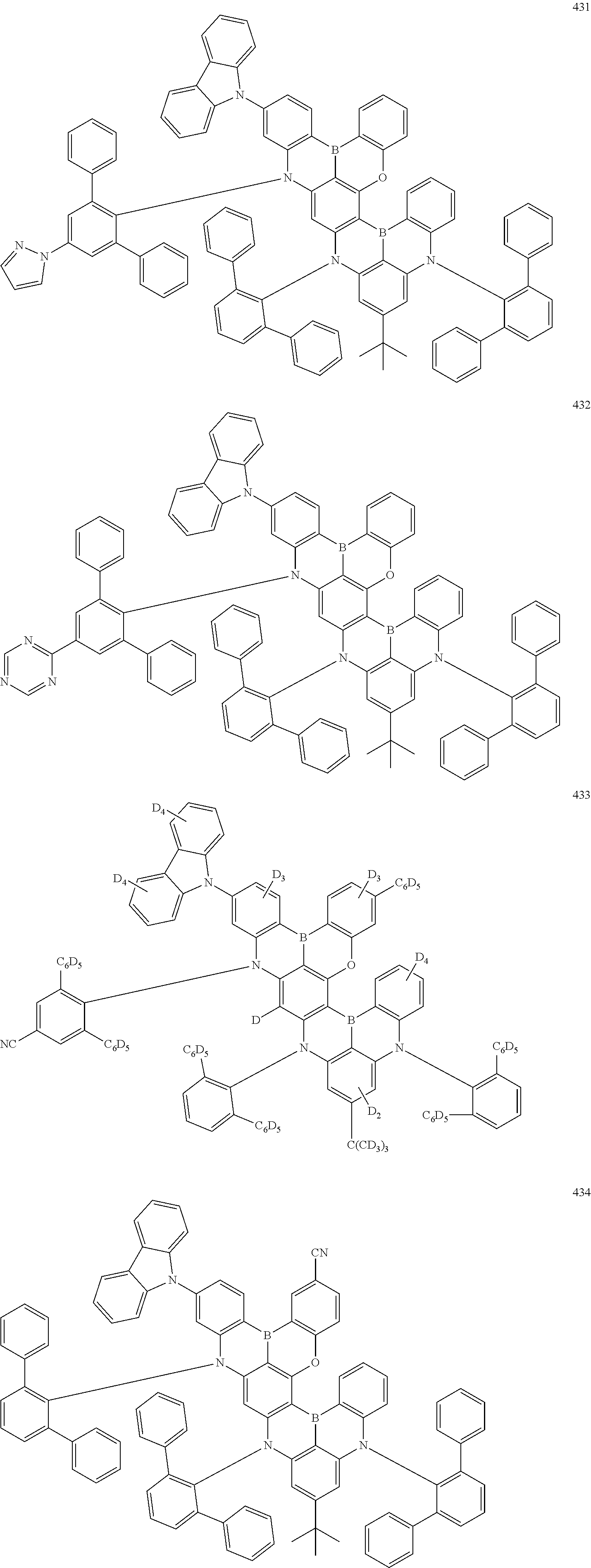

The light-emitting element ED including the fused polycyclic compound of Formula 1 according to an embodiment may have a peak emission wavelength in a wavelength region of about 450 nm to about 470 nm. The peak emission wavelength may refer to a wavelength at a position where an emission intensity in an emission spectrum is maximum. The light-emitting element ED including the fused polycyclic compound represented by Formula 1 according to an embodiment may emit a blue light. A third light-emitting element ED-3 (FIG. 2), emitting a blue light, may include the fused polycyclic compound represented by Formula 1 according to an embodiment.

The emission layer EML may include the fused polycyclic compound represented by Formula 1 according to an embodiment as a dopant. The fused polycyclic compound represented by Formula 1 according to an embodiment may be a delayed fluorescent material. The fused polycyclic compound represented by Formula 1 according to an embodiment may be a thermally activated delayed fluorescent (TADF) material. In the fused polycyclic compound represented by Formula 1 according to an embodiment, triplet excitons may be converted to singlet excitons by a reverse inter system crossing (RISC) mechanism, and thus light may be emitted.

The fused polycyclic compound represented by Formula 1 according to an embodiment may include, as a core structure, a fused ring system with nine rings, containing four heteroatoms and two boron atoms as ring-forming atoms. In addition, the fused polycyclic compound represented by Formula 1 includes a substituent E_{w} that is directly or indirectly bonded to the core structure. At least one of the four heteroatoms is N, and the others may be each independently N, O, or S. The substituent E_{w} is an electron withdrawing group. Each E_{w} is independently a fluorine atom, a cyano group, a nitro group, a trifluoromethyl group, a substituted or unsubstituted formyl group, a substituted or unsubstituted pyridine group, a substituted or unsubstituted pyrimidine group, a substituted or unsubstituted pyrazole group, or a substituted or unsubstituted triazine group. The fused ring system with nine rings may be represented by Formula Z1. The details described in Formula 1 may be similarly applied to X₁ to X₄ in Formula Z1.

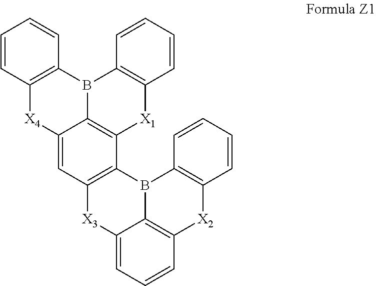

The fused ring system with nine rings, represented by Formula Z1, may be a charge transfer (CT)-type where distributions of HOMOs and LUMOs are separated. The fused polycyclic compound represented by Formula 1 according to an embodiment, where a substituent E_{w} (that is, an electron-withdrawing group) is introduced to a predetermined position in the fused ring with nine rings may have HOMO and LUMO distributions which are completely separated. The predetermined position to which the substituent E_{w} is introduced may be a position where the LUMO is distributed. The predetermined position to which the substituent E_{w} is introduced further satisfies at least one of the above-described Conditions 1 to 3. The fused polycyclic compound represented by Formula 1 according to an embodiment, including the fused ring with nine rings and the substituent E_{w}, have HOMO and LUMO distributions which are completely separated, and thus ΔE_{ST} may decrease. Therefore, the fused polycyclic compound represented by Formula 1 according to an embodiment may contribute to improvements in high emission efficiency and suppression of roll-off since the RISC is promoted. The roll-off refers to a phenomenon where emission efficiency sharply decreases at a high current density. When the RISC is promoted, long-lived triplet excitons may be rapidly converted to singlet excitons. ΔE_{ST} indicates an absolute value of a difference between a triplet state energy level and a singlet state energy level.

In an embodiment, the emission layer EML may include the fused polycyclic compound represented by Formula 1, and further include at least one among second to fourth compounds as described herein. In an embodiment, the emission layer EML may include a second compound represented by Formula HT-1. For example, the second compound may be used as a hole transporting host material in the emission layer EML.

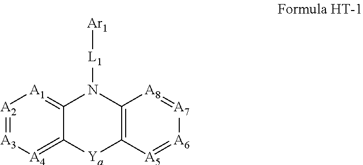

In Formula HT-1, A₁ to A₈ may be each independently N or CR₅₁. For example, all of A₁ to A₈ may be CR₅₁. Alternatively, any one among A₁ to A₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, CR₅₂R₅₃, or SiR₅₄R₅₅. That is, it may mean that the two benzene rings linked to the nitrogen atom in Formula HT-1 are linked via a direct linkage,

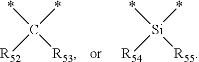

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT-1, R₅₁ to R₅₅ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. Alternatively, two or more of R₅₁ to R₅₅ may be bonded to an adjacent group to form a ring. For example, R₅₁ to R₅₅ may be each independently a hydrogen atom or a deuterium atom. In an embodiment, R₅₁ to R₅₅ may be each independently an unsubstituted methyl group or an unsubstituted phenyl group.

In an embodiment, the second compound represented by Formula HT-1 may be represented by one of the compounds represented by Compound Group 2. The emission layer EML may include at least one of the compounds represented by Compound Group 2 as a hole transporting host material.

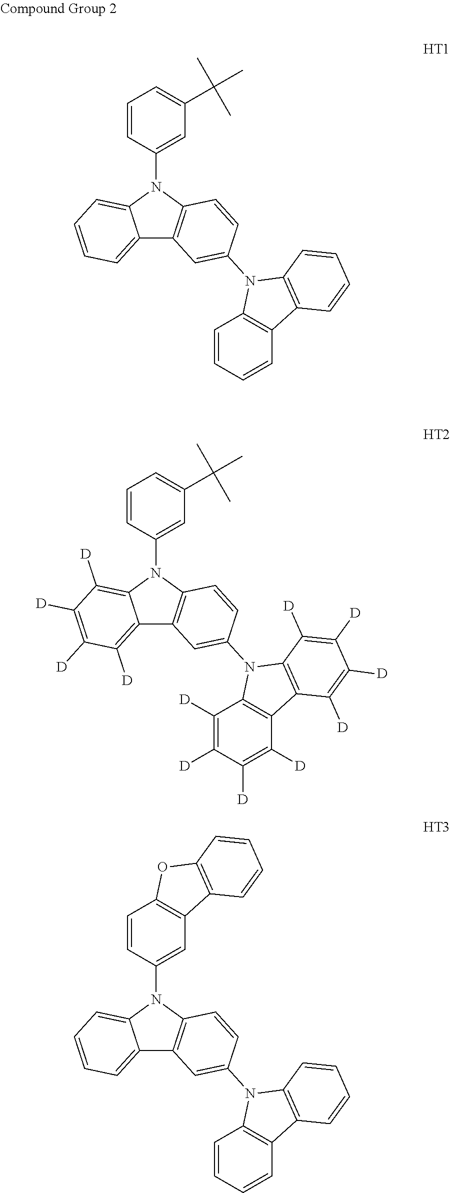

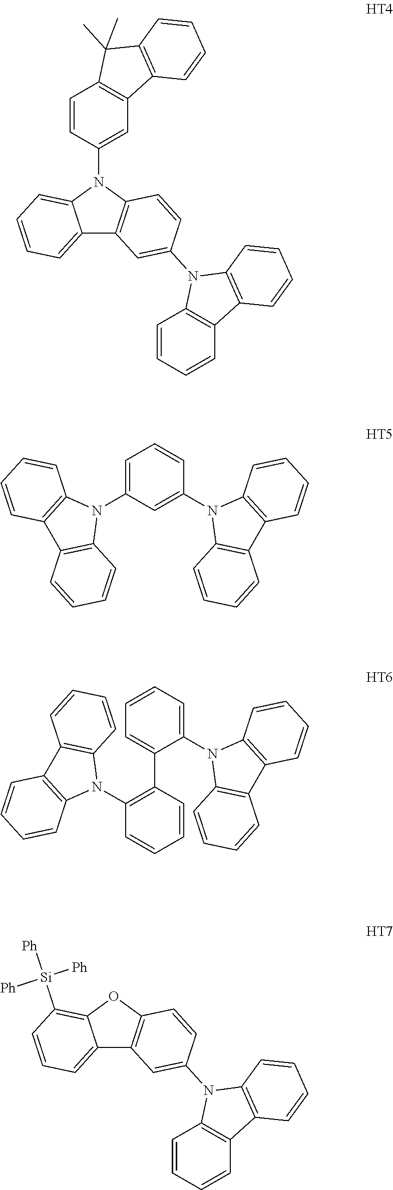 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

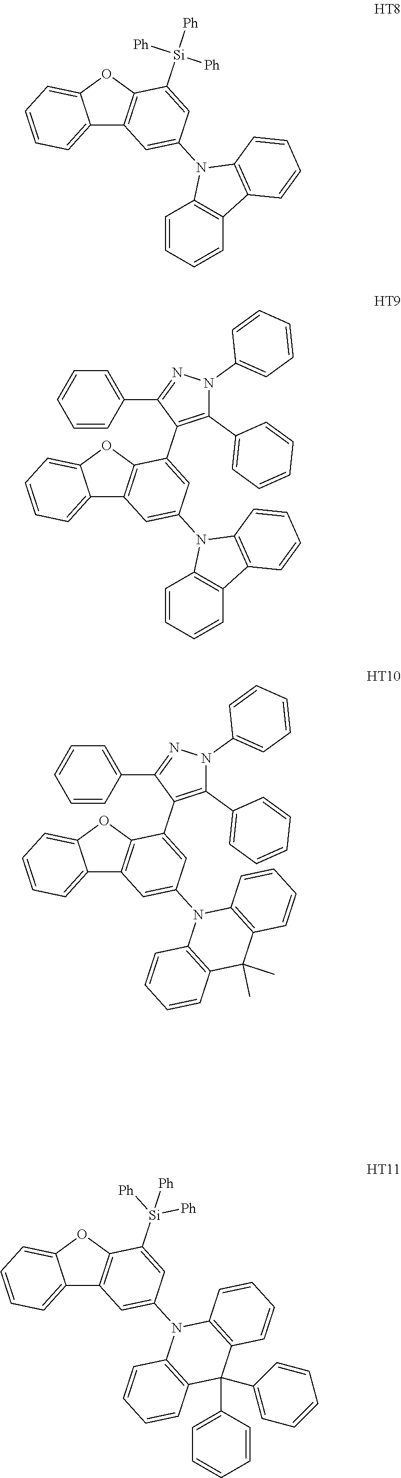 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

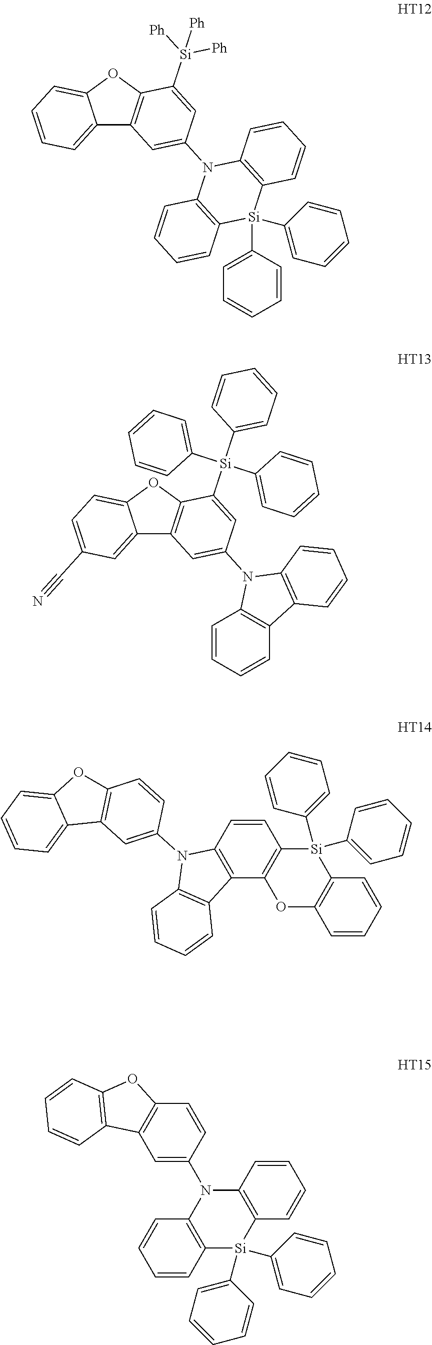 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

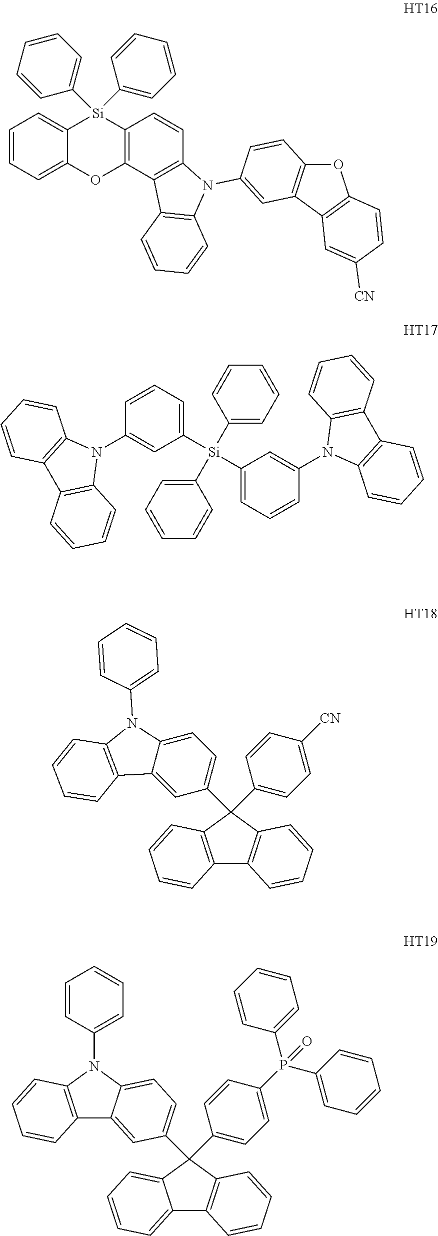 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

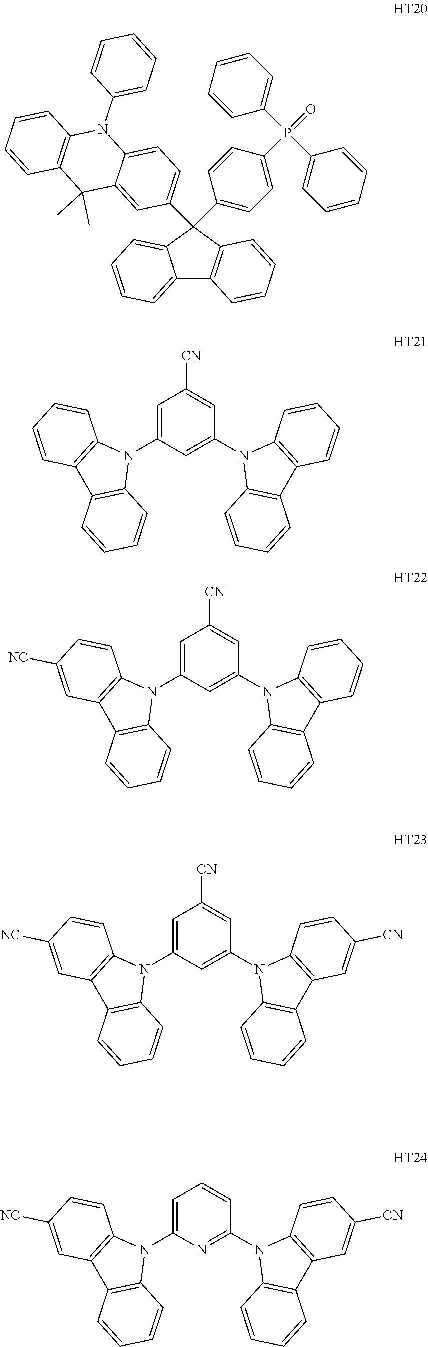 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

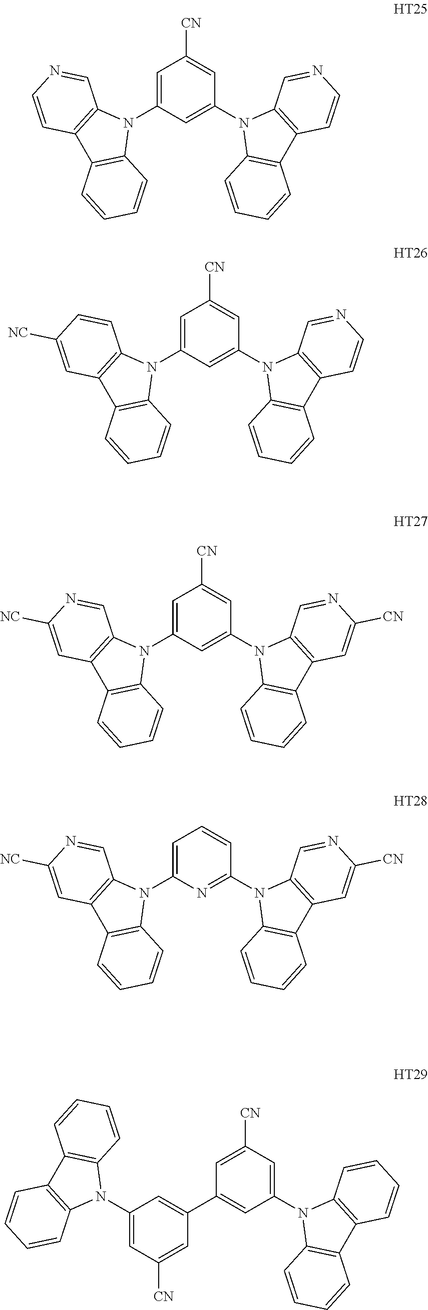 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

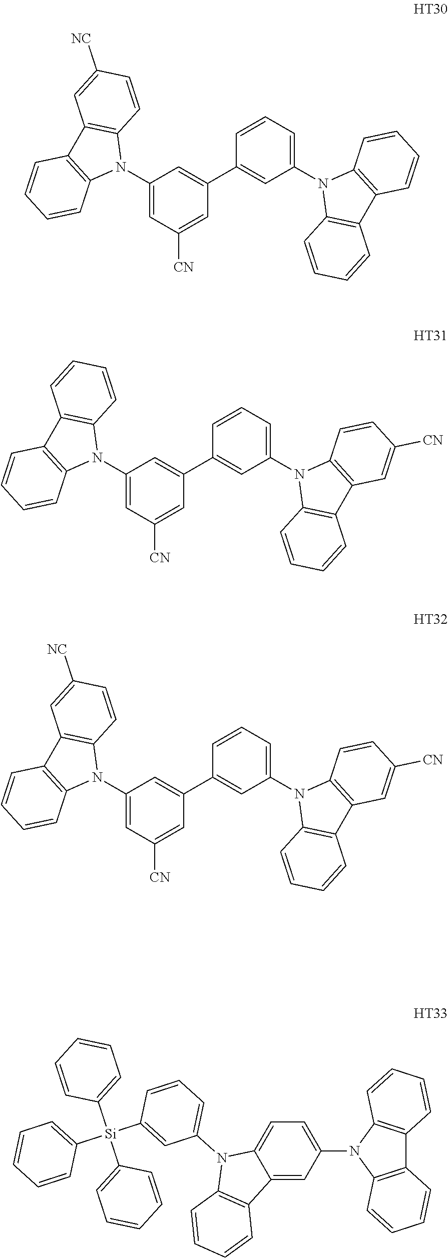 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

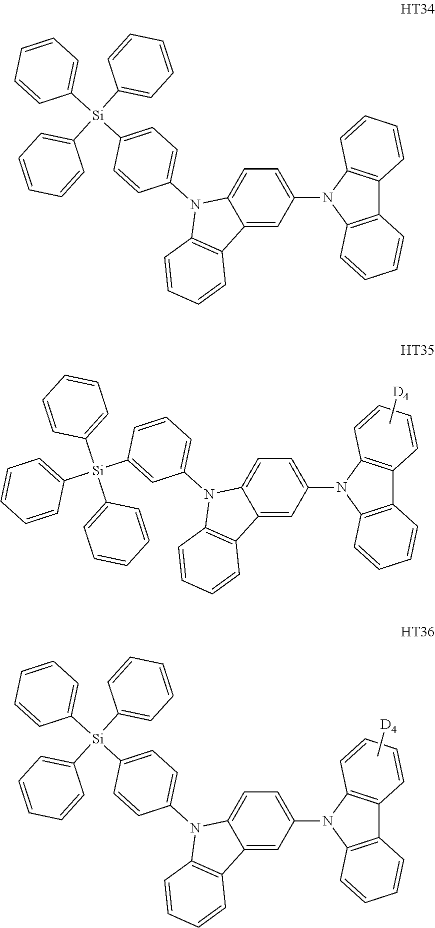

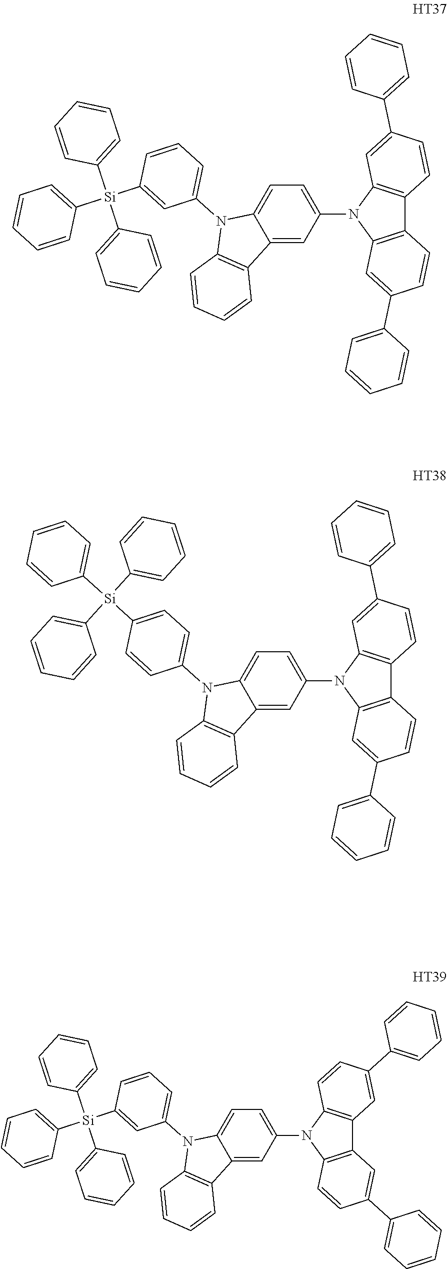 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1]

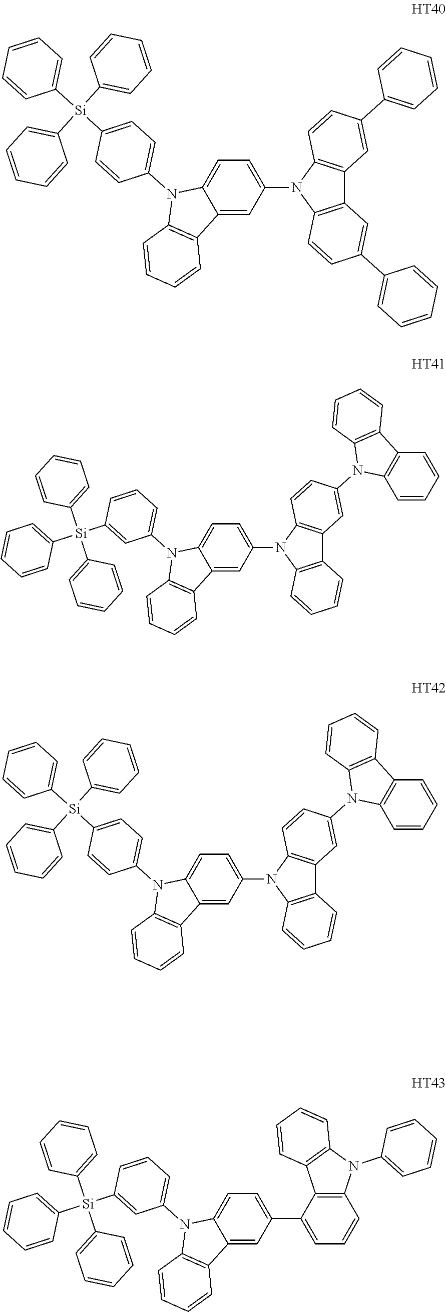 [SMILES: c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1]

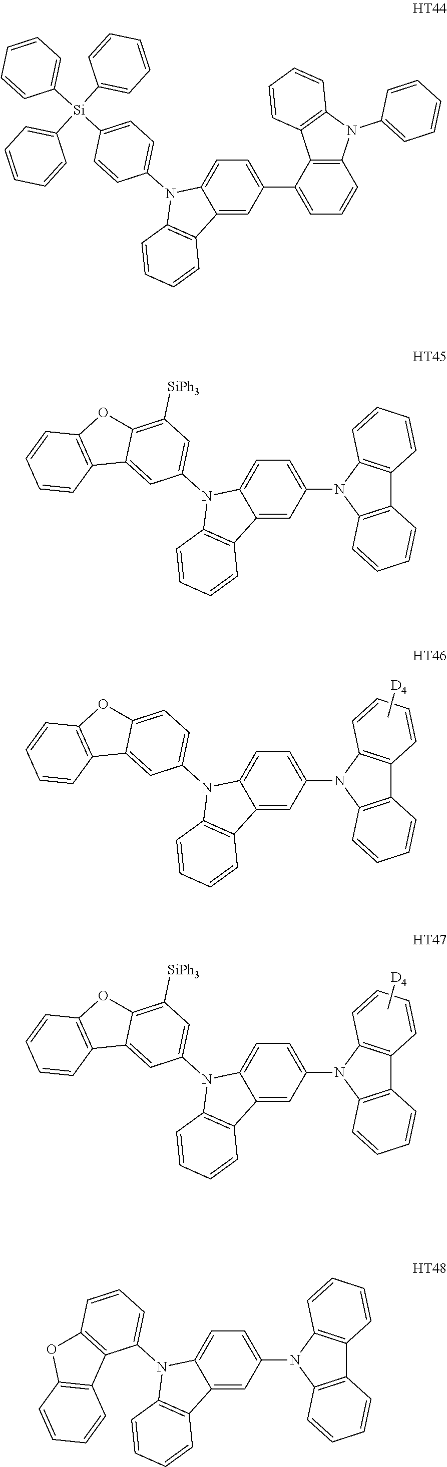

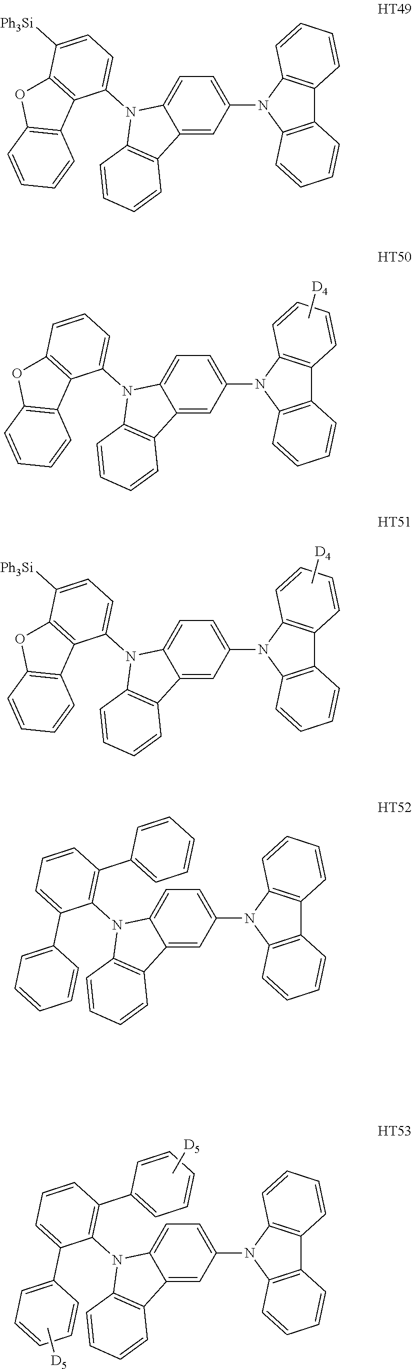

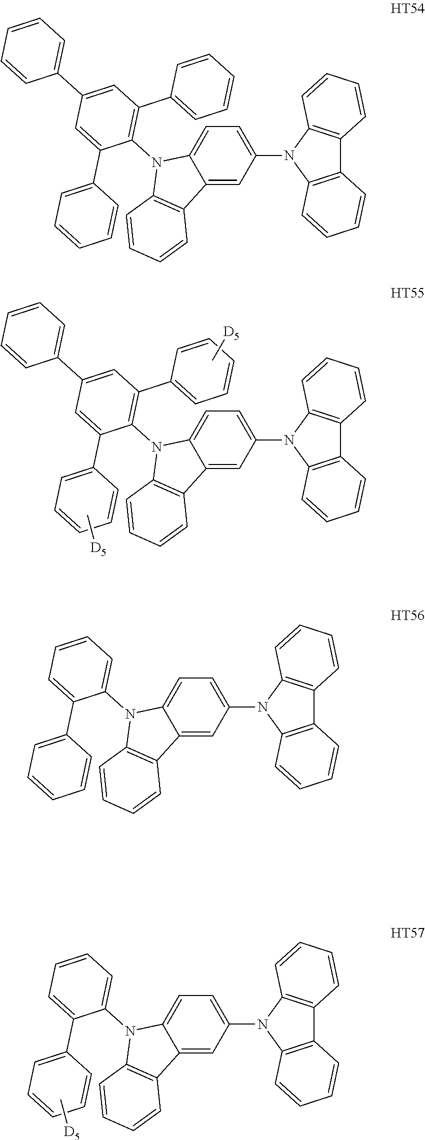

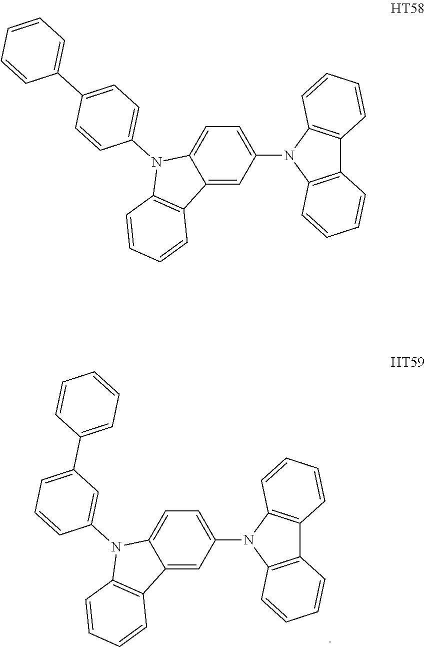 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In embodiment compounds presented in Compound Group 2, “D” may mean a deuterium atom, and “Ph” may mean a substituted or unsubstituted phenyl group. For example, in embodiment compounds presented in Compound Group 2, “Ph” may mean an unsubstituted phenyl group.

In an embodiment, the emission layer EML may include the third compound represented by Formula ET-1 below. For example, the third compound may be used as an electron transport host material for the emission layer EML.

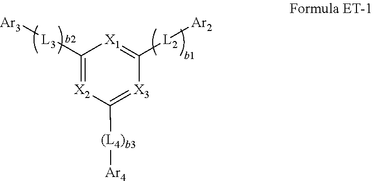

In Formula ET-1, X₁ to X₃ are each independently N or CR₅₆, wherein at least one of X₁ to X₃ is N. For example, any one among X₁ to X₃ may be N, and the rest may be each independently CR₅₆. In this case, the third compound represented by Formula ET-1 may include a pyridine moiety. Alternatively, two among X₁ to X₃ may be N, and the rest may be CR₅₆. In this case, the third compound represented by Formula ET-1 may include a pyrimidine moiety. Alternatively, X₁ to X₃ may all be N. In this case, the third compound represented by Formula ET-1 may include a triazine moiety.

In Formula ET-1, R₅₆ may be each independently be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may be each independently an integer of 0 to 10.

In Formula ET-1, Ar₂ to Ar₄ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may be each independently a substituted or unsubstituted phenyl group, or a substituted or unsubstituted carbazole group.

In Formula ET-1, L₂ to L₄ may be each independently a direct linkage, a substituted or unsubstituted arylene group having 6 to 30 ring-forming carbon atoms, or a substituted or unsubstituted heteroarylene group having 2 to 30 ring-forming carbon atoms. For example, when b1 to b3 are integers of 2 or greater, L₂ to L₄ may be each independently a substituted or unsubstituted arylene group having 6 to 30 ring-forming carbon atoms, or a substituted or unsubstituted heteroarylene group having 2 to 30 ring-forming carbon atoms.

In an embodiment, the third compound may be represented by one of compounds in Compound Group 3. The light-emitting element ED of an embodiment may include one of the compounds in Compound Group 3:

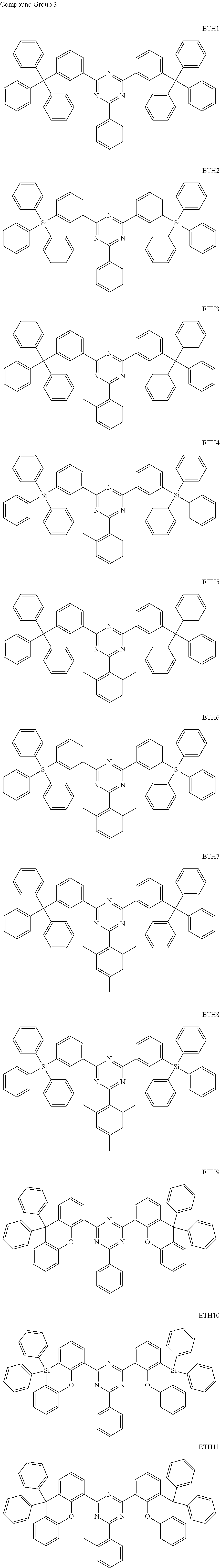

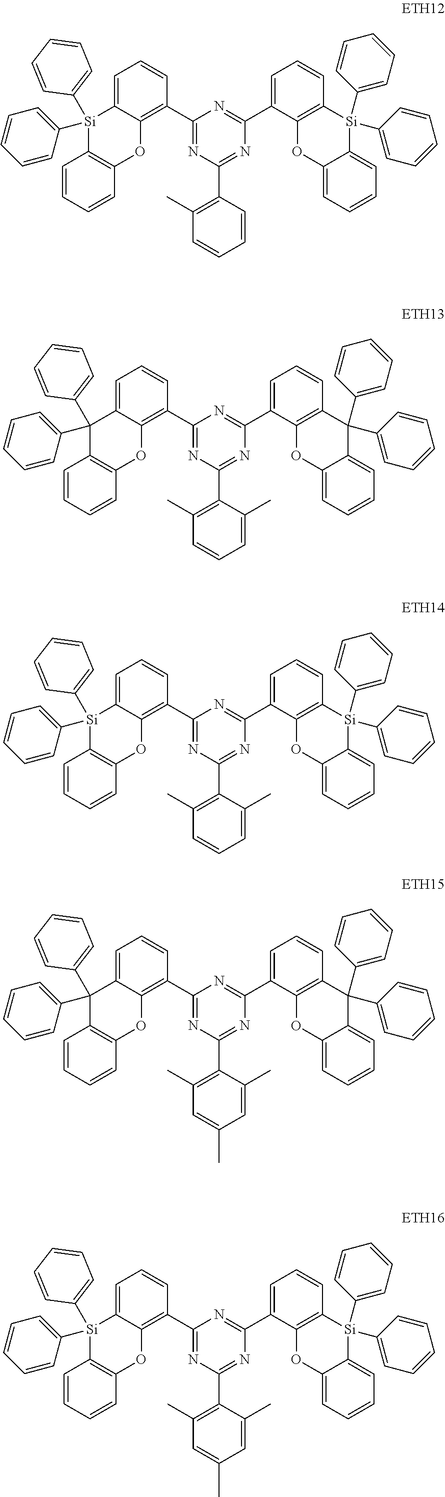

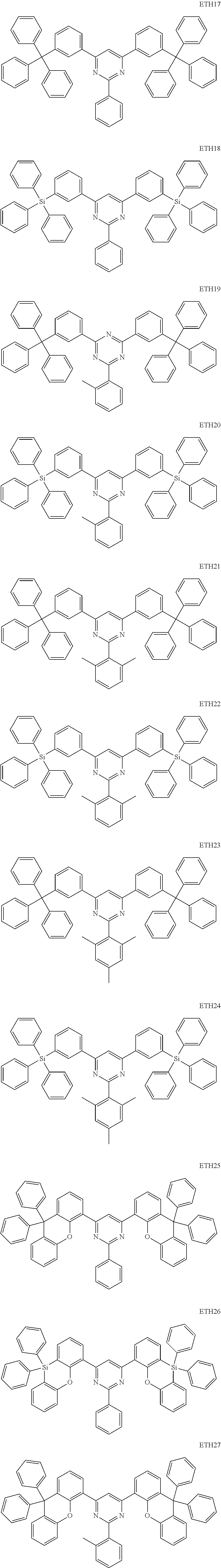

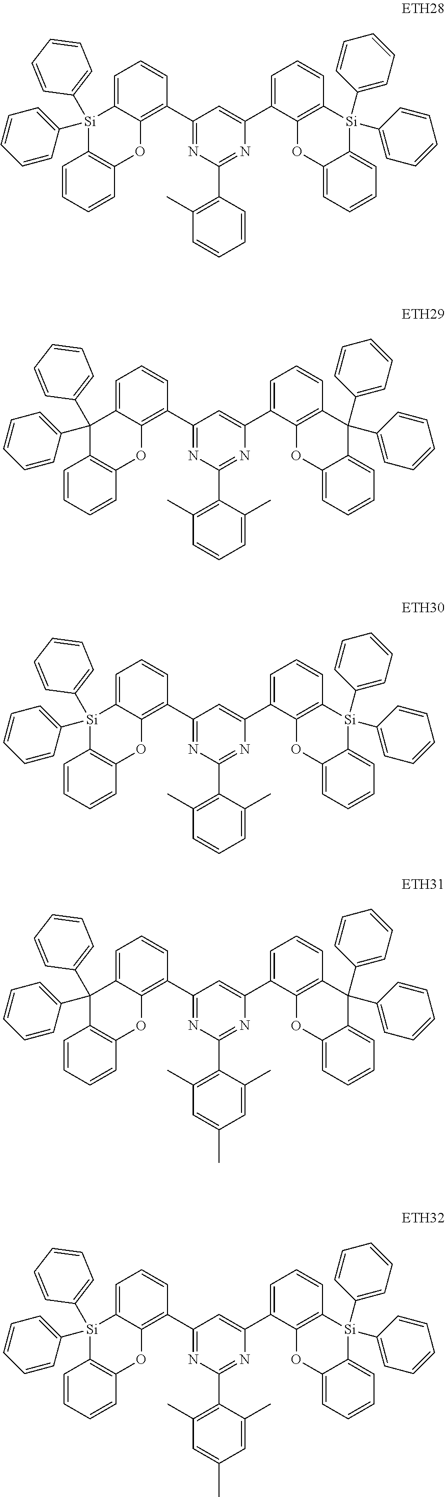

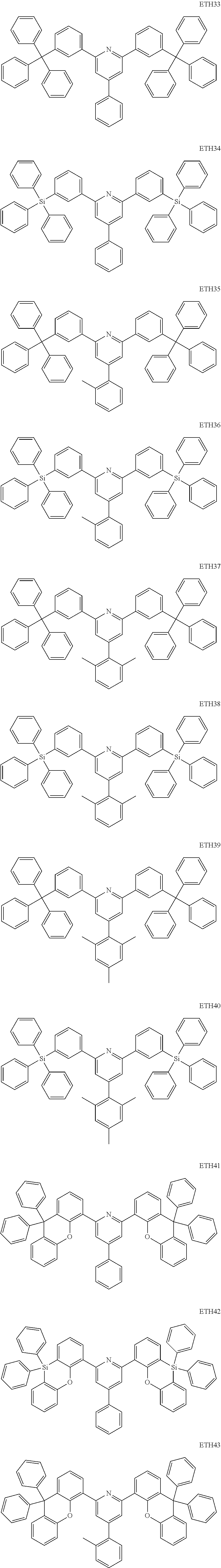

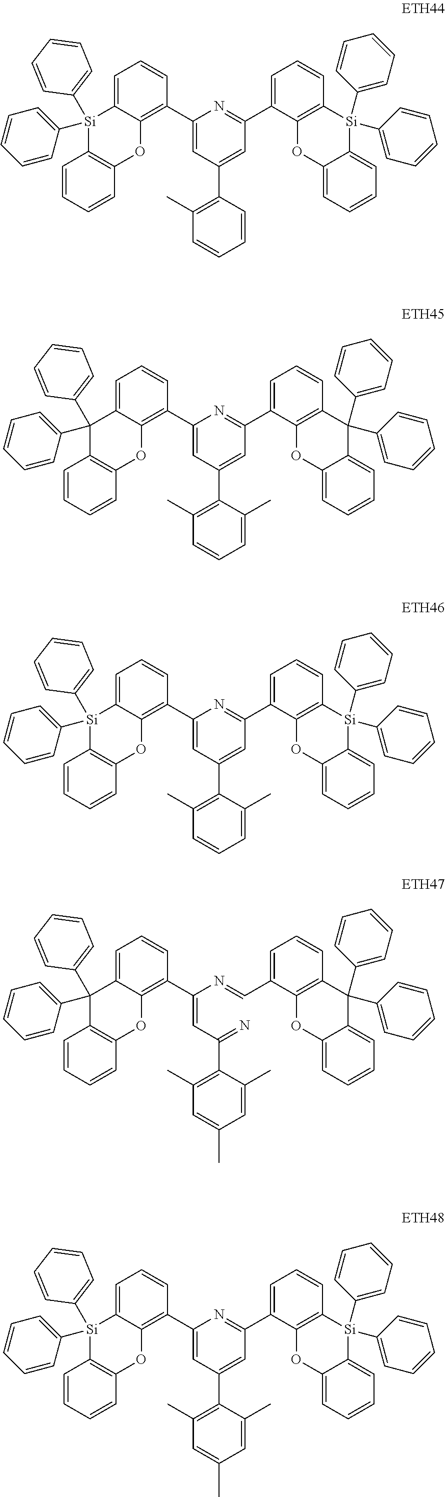

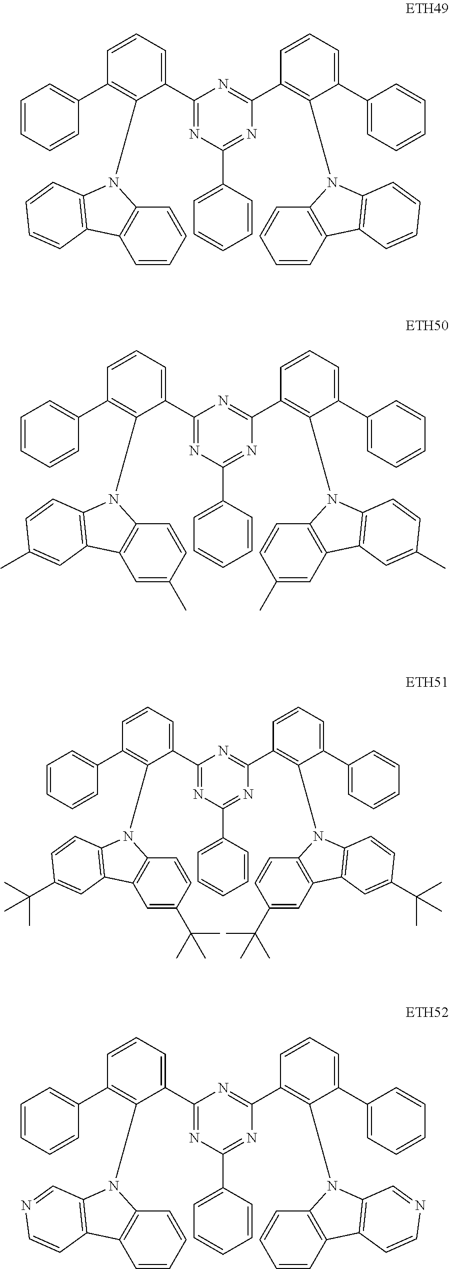

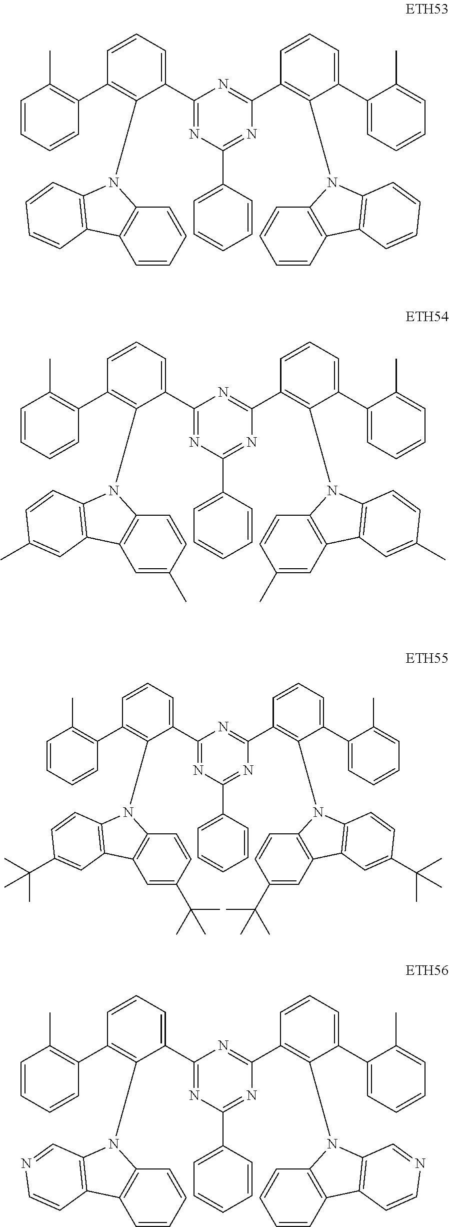

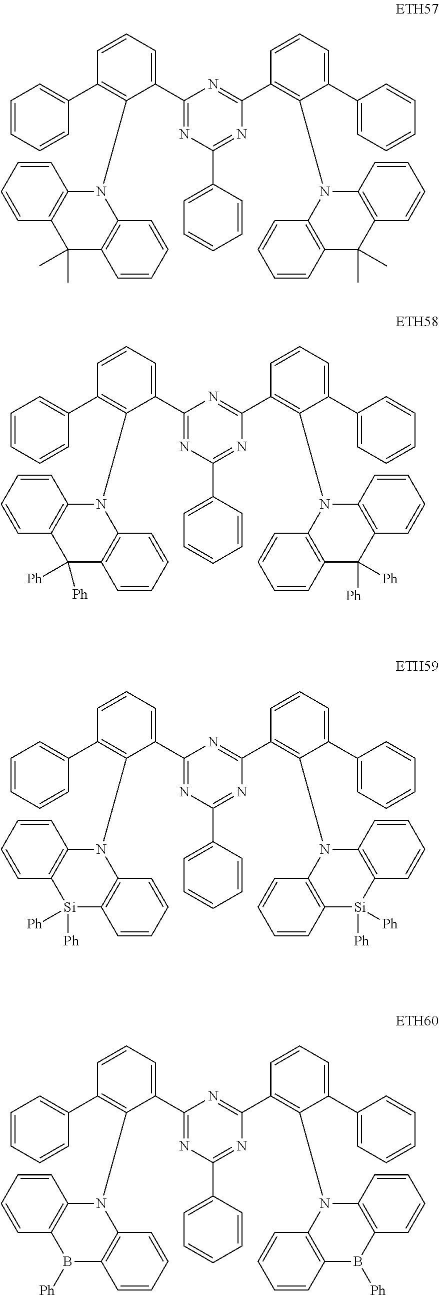

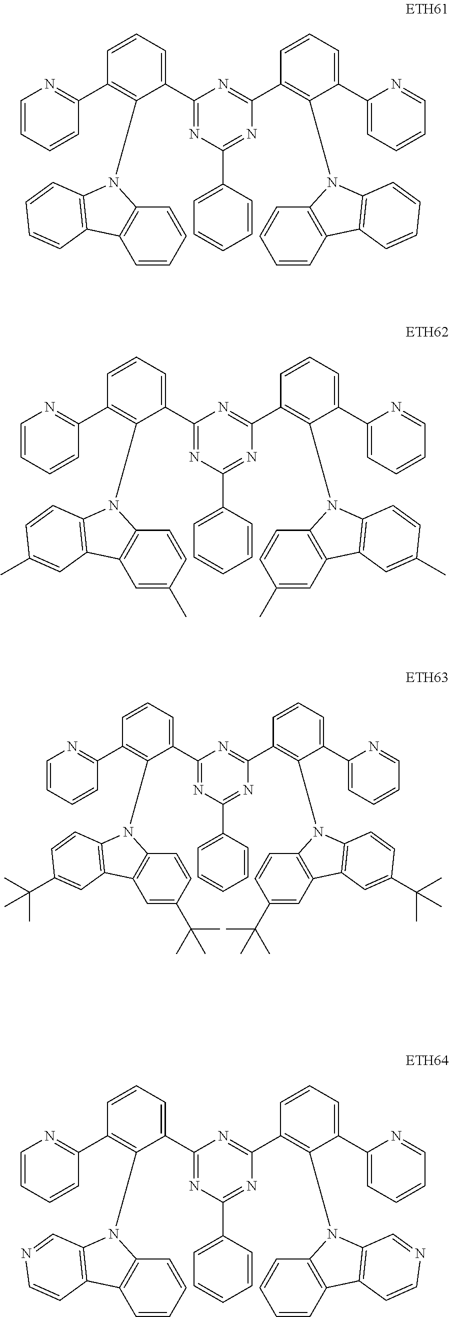

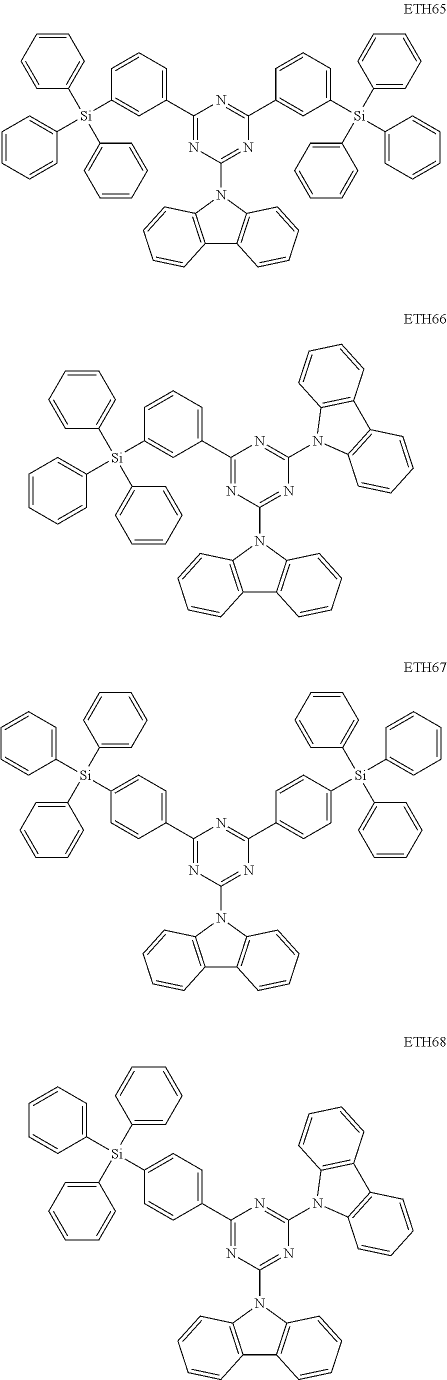 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

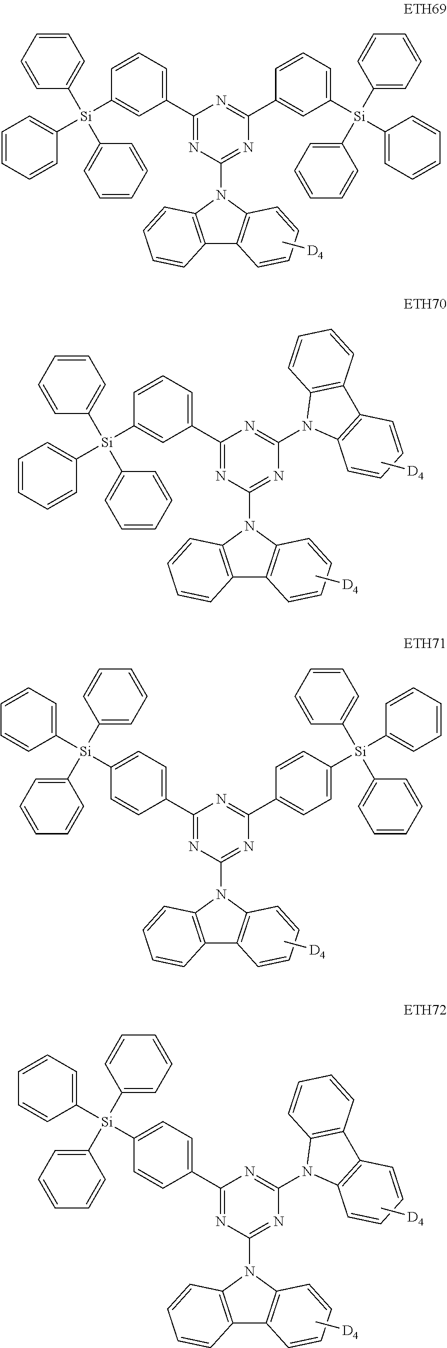

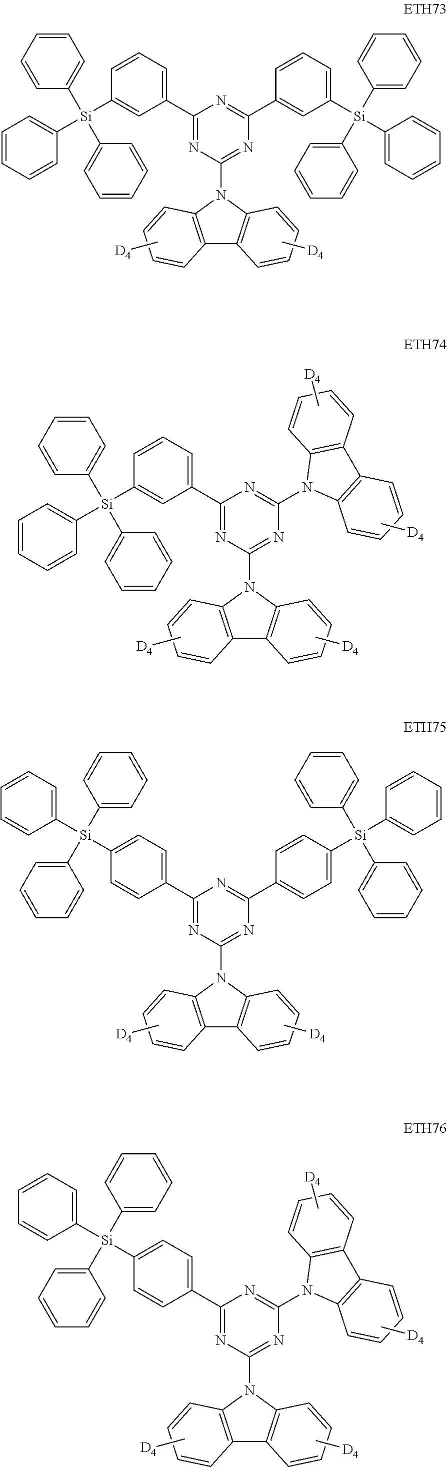

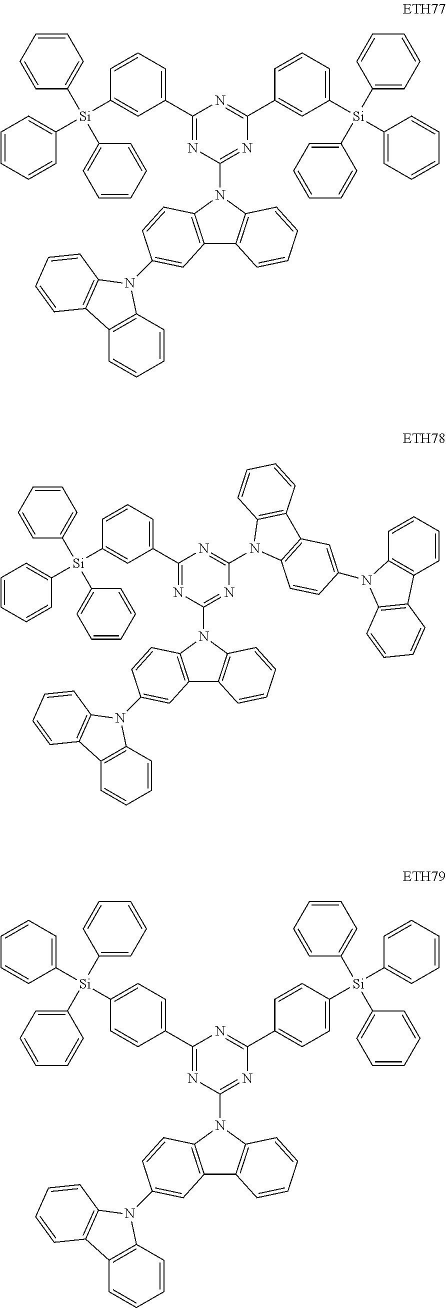 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

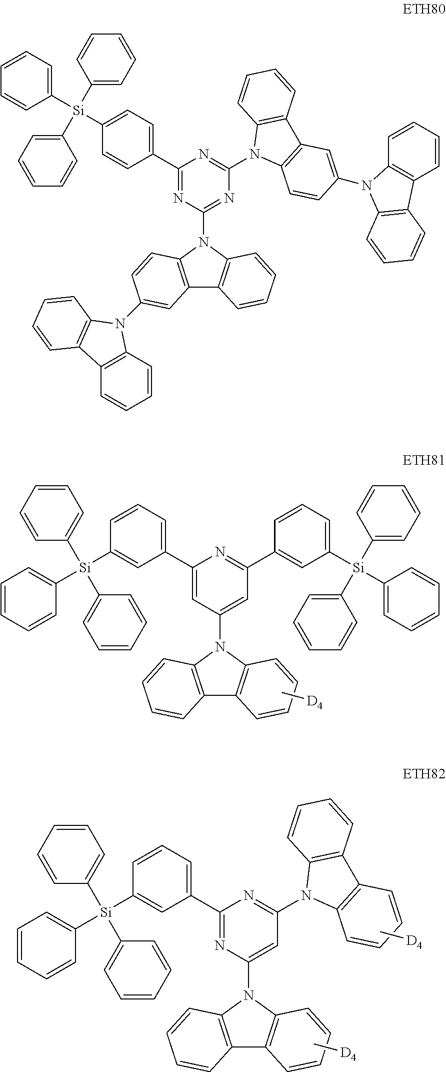

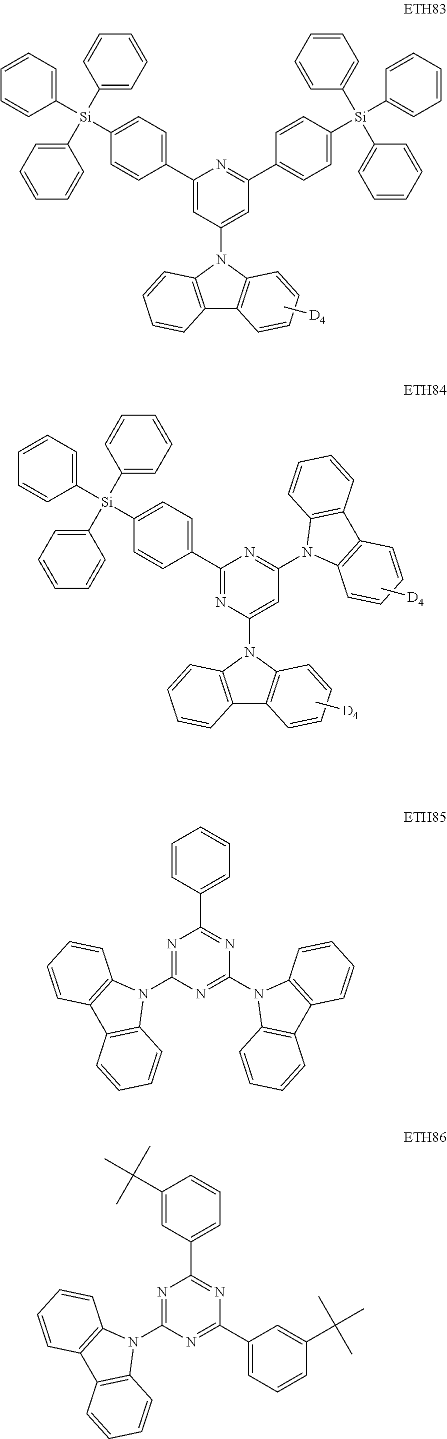

In the embodiment compounds presented in Compound Group 3, “D” refers to a deuterium atom and “Ph” refers to an unsubstituted phenyl group.

The emission layer EML may include the second compound and the third compound, and the second compound and the third compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 electron volts (eV) to about 3.0 eV. In addition, the triplet energy of the exciplex may be a value smaller than an energy gap of each host material. The exciplex may have a triplet energy of about 3.0 eV or less that is an energy gap between the hole transporting host and the electron transporting host.

In an embodiment, the emission layer EML may include a fourth compound in addition to the first compound to the third compound as described herein. The fourth compound may be used as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light-emitting element ED of an embodiment may include, as the fourth compound, a compound represented by Formula D-1:

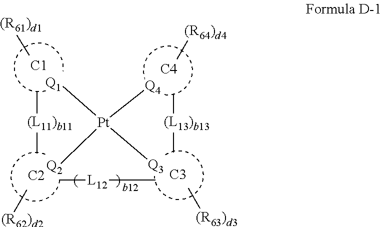

In Formula D-1, Q₁ to Q₄ may be each independently C or N.

In Formula D-1, ring C1 to ring C4 may be each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms.

In Formula D-1, L₁₁ to L₁₃ may be each independently a direct linkage, *—O—*, *—S—*,

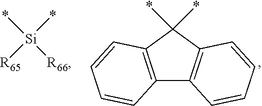

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “-*” means a part linked to C1 to C4.

In Formula D-1, b11 to b13 may be each independently 0 or 1. If b11 is 0, C1 and C2 may not be linked to each other. If b12 is 0, C2 and C3 may not be linked to each other. If b13 is 0, C3 and C4 may not be linked to each other.

In Formula D-1, R₆₁ to R₆₆ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. Alternatively, each of R₆₁ to R₆₆ may be bonded to an adjacent group to form a ring. R₆₁ to R₆₆ may be each independently a substituted or unsubstituted methyl group, or a substituted or unsubstituted t-butyl group.

In Formula D-1, d1 to d4 are each independently an integer of 0 to 4. In Formula D-1, if each of d1 to d4 is 0, the fourth compound may not be substituted with each of R₆₁ to R₆₄. The case where each of d1 to d4 is 4 and R₆₁'s to R₆₄'s are each hydrogen atoms may be the same as the case where each of d1 to d4 is 0. When each of d1 to d4 is an integer of 2 or more, a plurality of R₆₁'s to R₆₄'s may each be the same or at least one among the plurality of R₆₁'s to R₆₄'s may be different from the others.

In Formula D-1, ring C1 to ring C4 may be each independently a substituted or unsubstituted hydrocarbon ring or a substituted or unsubstituted heterocycle represented by one of C-1 to C-4:

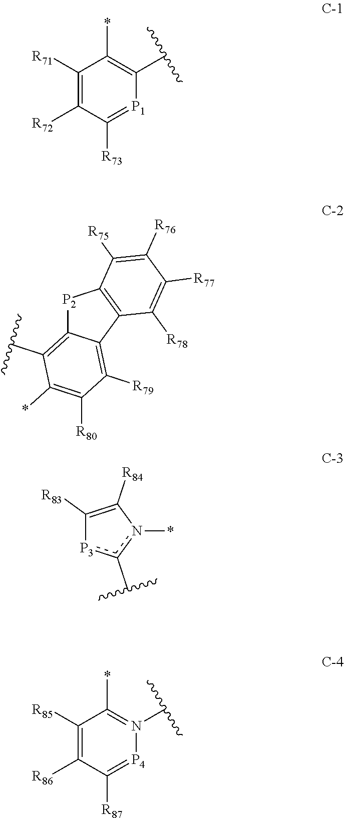

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may be each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In addition, in C-1 to C-4,

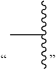

corresponds to a part linked to Pt that is a central metal atom, and “-*” corresponds to a part linked to a neighboring cyclic group (ring C1 to ring C4) or a linker (L₁₁ to L₁₃).

The emission layer EML of an embodiment may include the first compound, which is a fused polycyclic compound represented by Formula 1, and at least one of the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In addition, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In an embodiment, the fourth compound may be a sensitizer. The fourth compound included in the emission layer EML in the light-emitting element ED of an embodiment may serve as a sensitizer to deliver energy from the host to the first compound that is a light emitting dopant. That is, the fourth compound serving as an auxiliary dopant accelerates energy delivery to the first compound that is a light emitting dopant, thereby increasing the emission ratio of the first compound. Therefore, the emission layer EML of an embodiment may improve luminous efficiency. In addition, when the energy delivery to the first compound is increased, an exciton formed in the emission layer EML is not accumulated inside the emission layer EML and emits light rapidly, and thus deterioration of the device may be reduced. Therefore, the service life of the light-emitting element ED of an embodiment may increase.

The light-emitting element ED of an embodiment may include all of the first compound, the second compound, the third compound, and the fourth compound, and the emission layer EML may include the combination of two host materials and two dopant materials. In the light-emitting element ED of an embodiment, the emission layer EML may simultaneously include the second compound and the third compound, which are two different hosts, the first compound that emits a delayed fluorescence, and the fourth compound including an organometallic complex, thereby exhibiting excellent luminous efficiency characteristics.

In an embodiment, the fourth compound represented by Formula D-1 may be represented at least one of the compounds represented by Compound Group 4. The emission layer EML may include at least one among the compounds represented by Compound Group 4 as a sensitizer material.

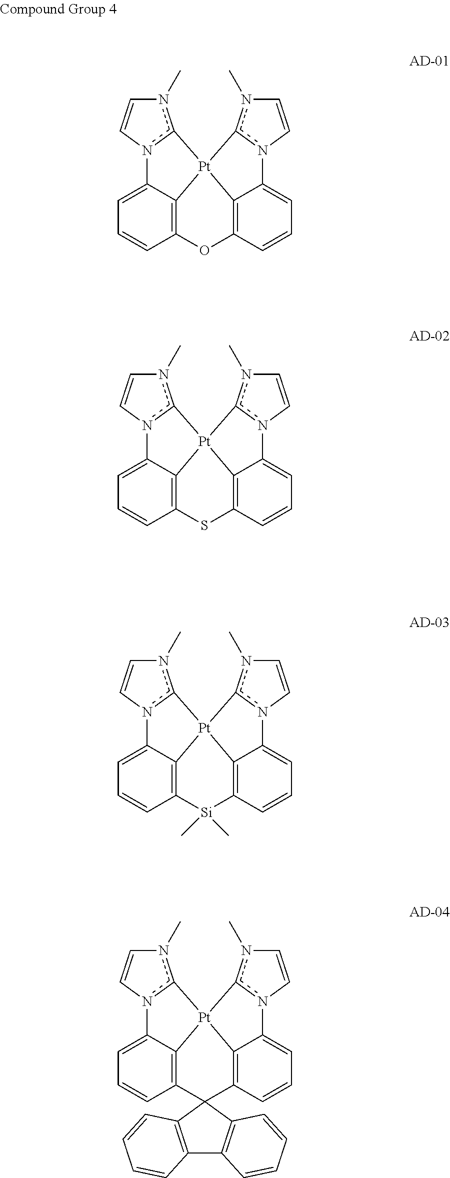

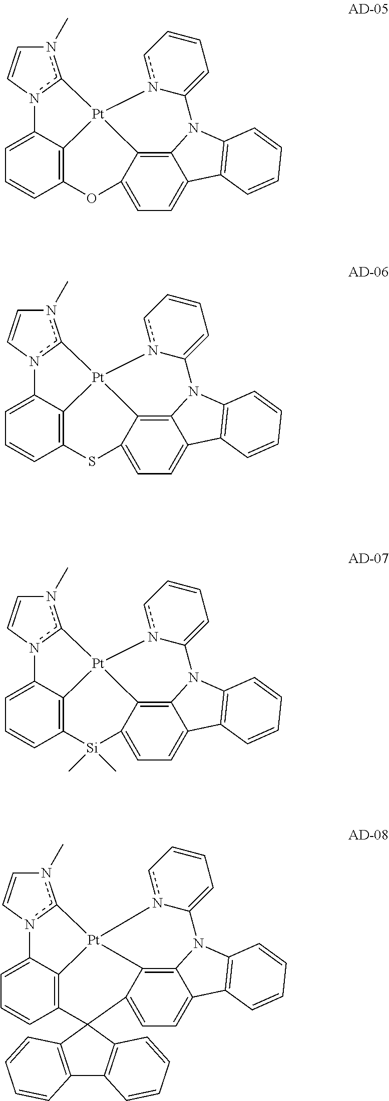

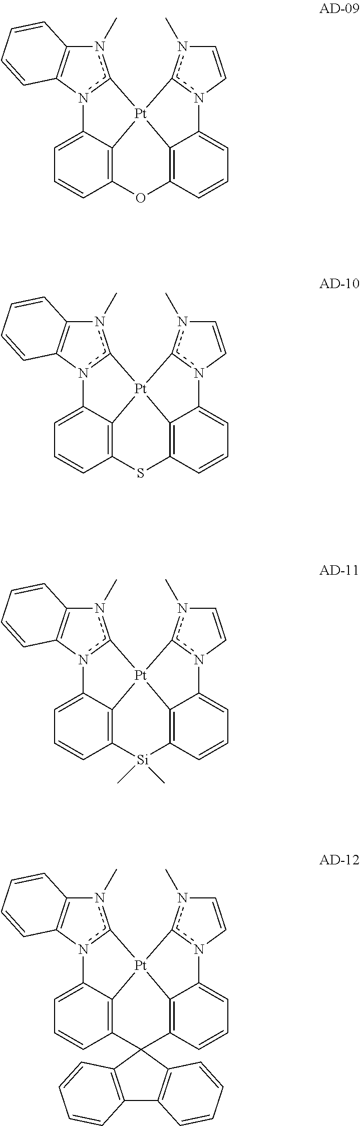

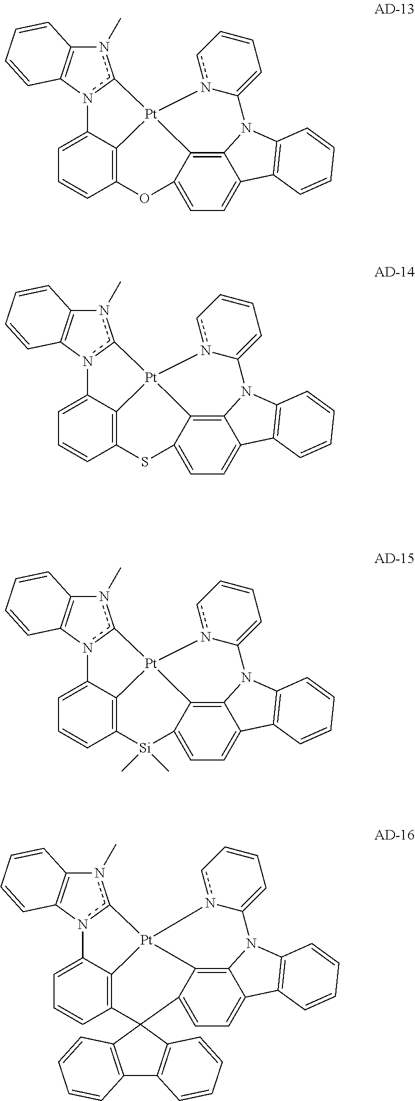

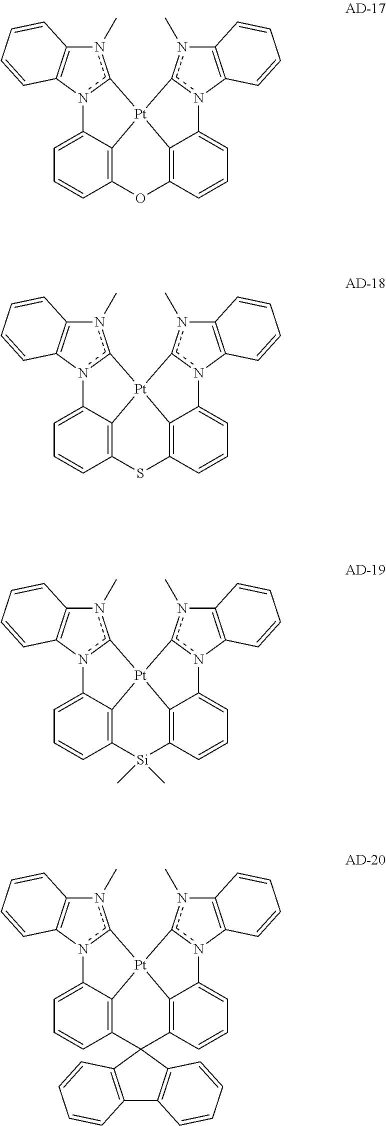

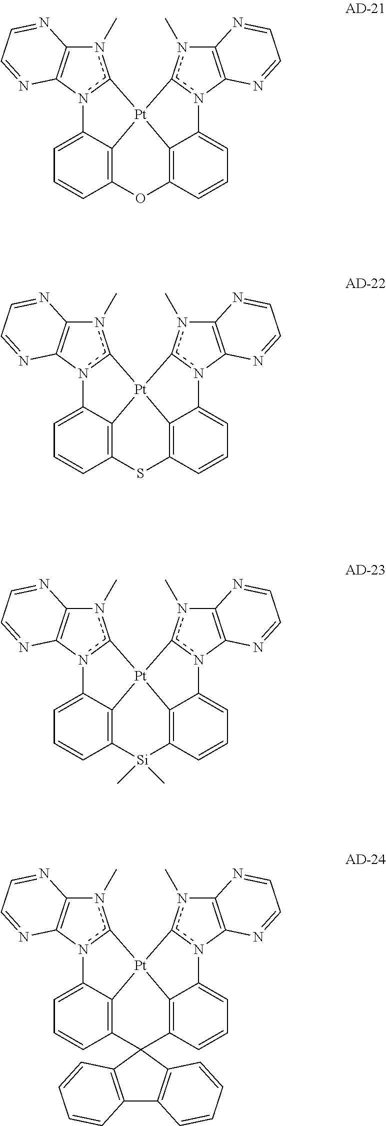

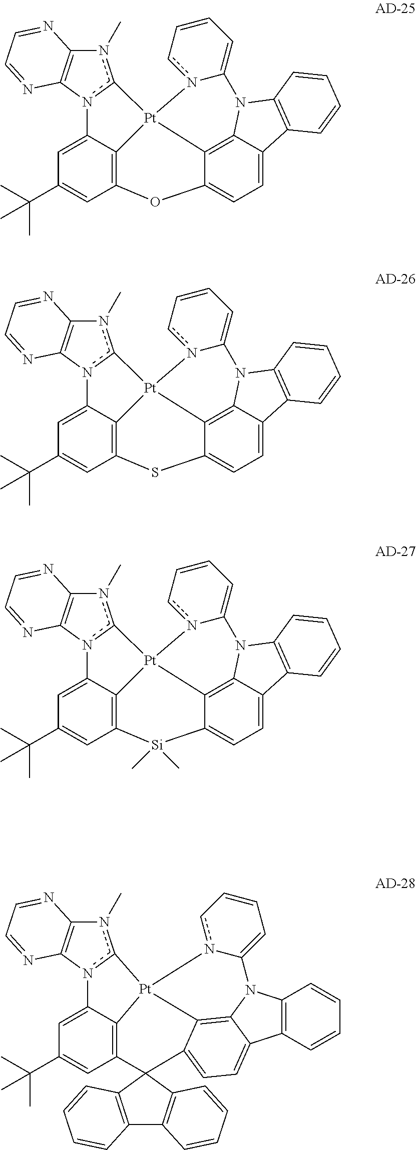

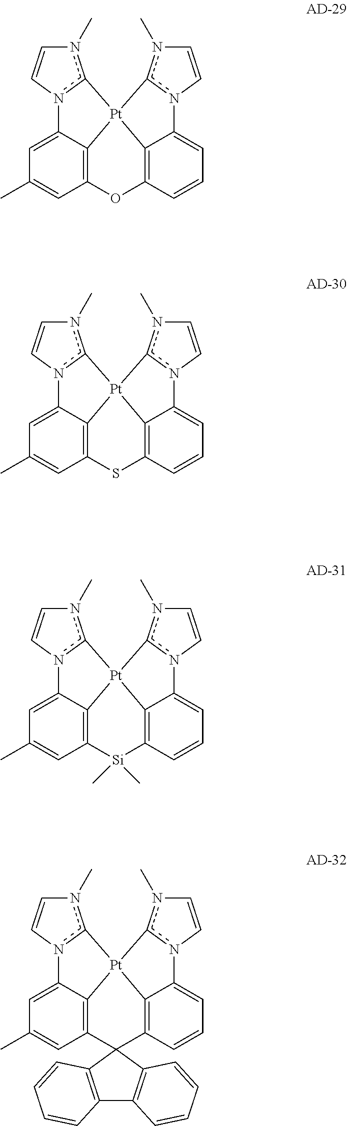

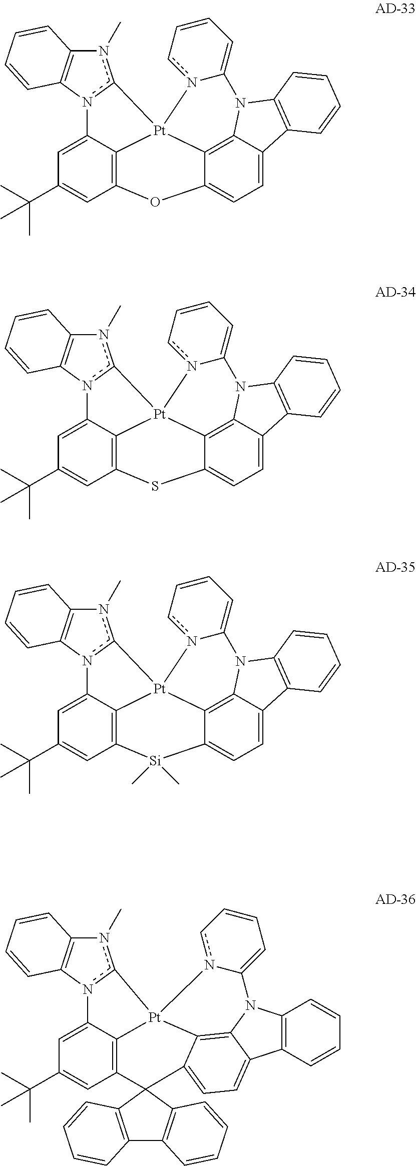

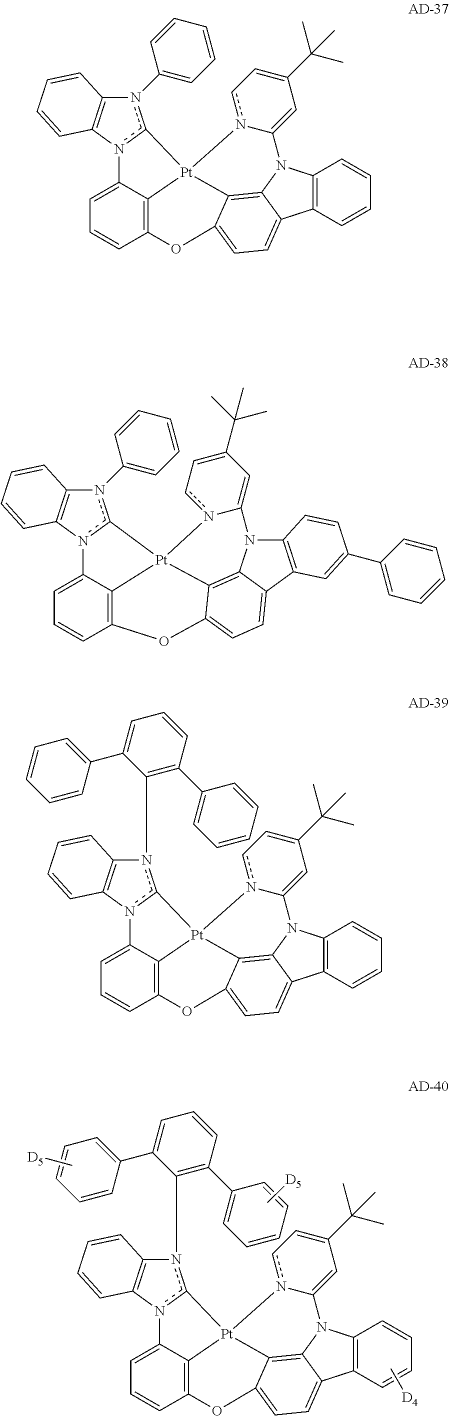

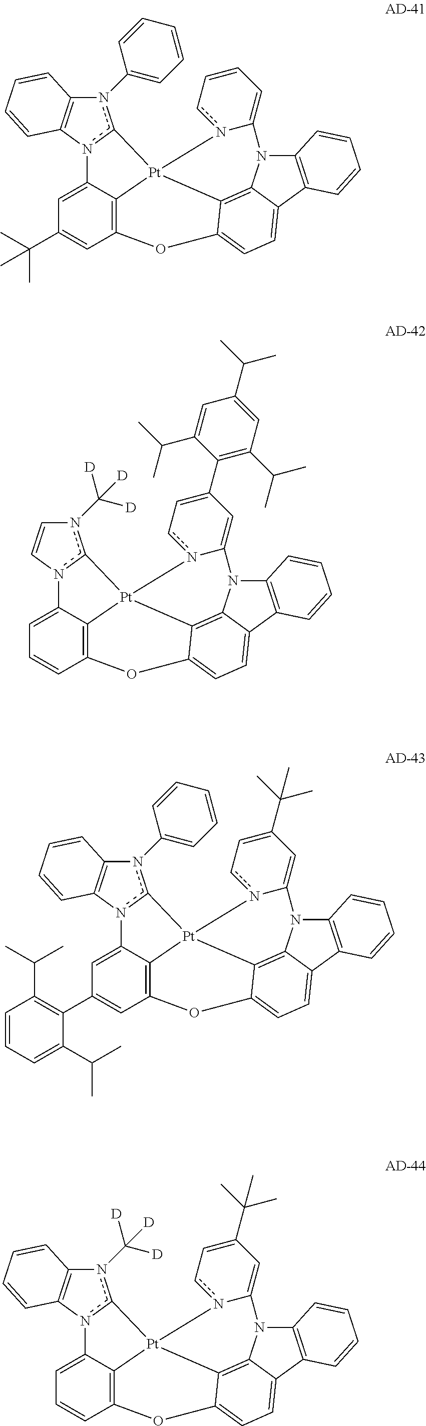

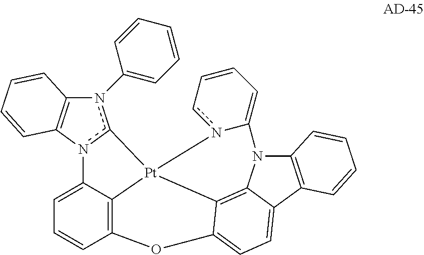

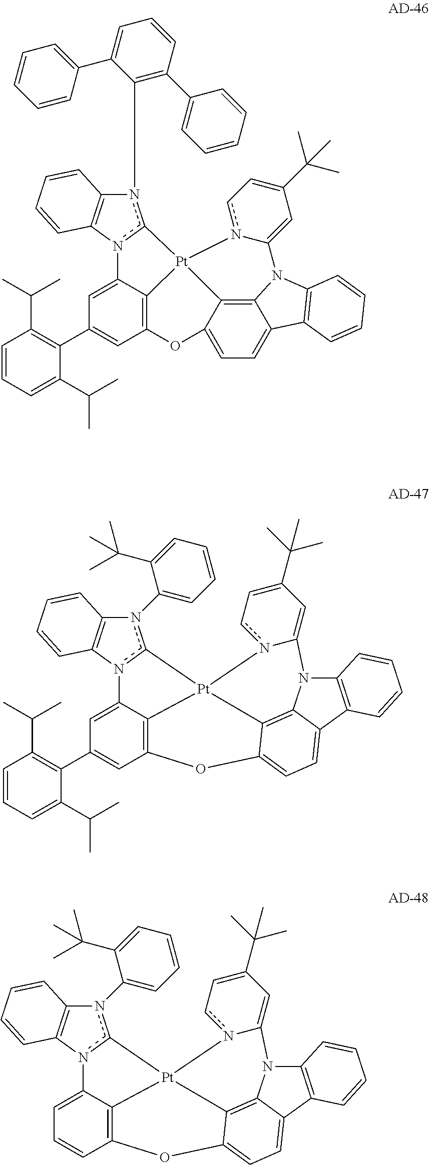

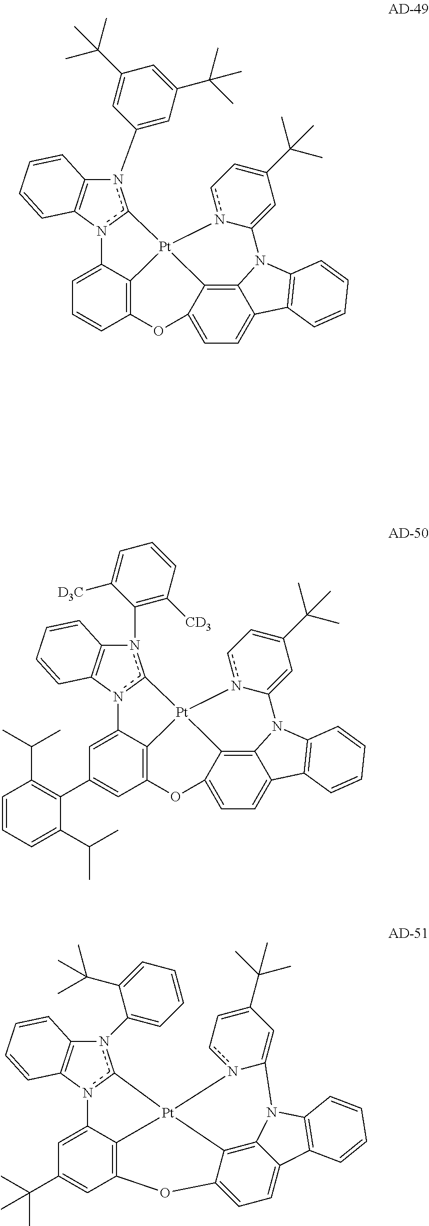

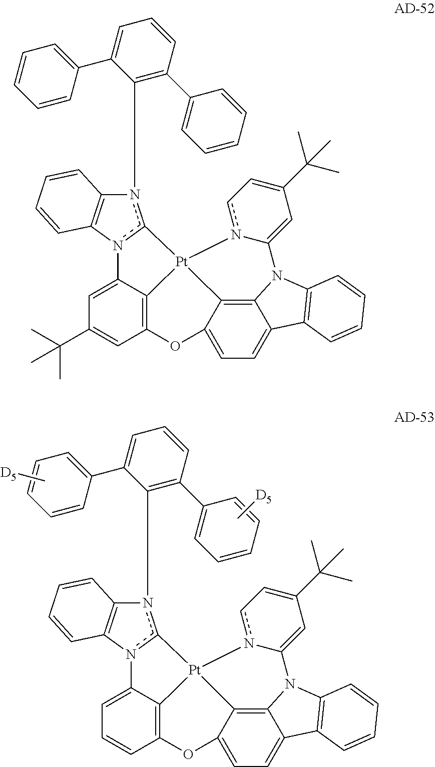

In the embodiment compounds presented in Compound Group 4, “D” means a deuterium atom.

When the emission layer EML in the light-emitting element ED of an embodiment includes all of the first compound, the second compound, and the third compound, with respect to the total weight of the first compound, the second compound, and the third compound, the content of the first compound may be about 0.1 wt % to about 5 wt %. However, embodiments are not limited thereto. When the content of the first compound satisfy the above-described proportion, the energy transfer from the second compound and the third compound to the first compound may increase, and thus the luminous efficiency and element service life may increase.

The contents of the second compound and the third compound in the emission layer EML may be the rest excluding the weight of the first compound. For example, the contents of the second compound and the third compound in the emission layer EML may be about 65 wt % to about 95 wt % with respect to the total weight of the first compound, the second compound, and the third compound.

In the total weight of the second compound and the third compound, the weight ratio of the second compound to the third compound may be about 3:7 to about 7:3.

When the contents of the second compound and the third compound satisfy the above-described ratio, a charge balance characteristic in the emission layer EML is improved, and thus the luminous efficiency and device service life may increase. When the contents of the second compound and the third compound deviate from the above-described ratio range, a charge balance in the emission layer EML is broken, and thus the luminous efficiency may be reduced and the device may be more easily deteriorated.

When the emission layer EML includes the fourth compound, the content of the fourth compound in the emission layer EML may be about 10 wt % to about 30 wt % with respect to the total weight of the first compound, the second compound, the third compound, and the fourth compound. However, embodiments are not limited thereto. When the content of the fourth compound satisfies the above-described content, the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the above-described content ratio range, excellent luminous efficiency and long service life may be achieved.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

The emission layer EML may further include a compound described below in addition to the fused polycyclic compound represented by Formula 1 of an embodiment.

In the light-emitting element ED of an embodiment, the emission layer EML may include an anthracene derivative, a pyrene derivative, a fluoranthene derivative, a chrysene derivative, a dihydrobenzanthracene derivative, or a triphenylene derivative. Specifically, the emission layer EML may include the anthracene derivative or the pyrene derivative.

In each light-emitting element ED of embodiments illustrated in FIGS. 3 to 6, the emission layer EML may further include a known host and dopant besides the above-described host and dopant, and for example the emission layer EML may include a compound represented by Formula E-1. The compound represented by Formula E-1 below may be used as a fluorescent host material.

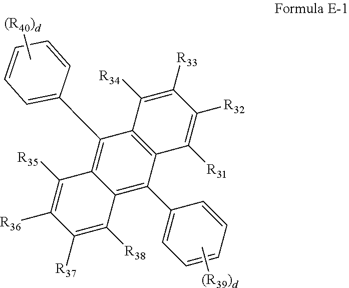

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may be each independently an integer of 0 to 5.

Formula E-1 may be represented by one of Compound E1 to Compound E21:

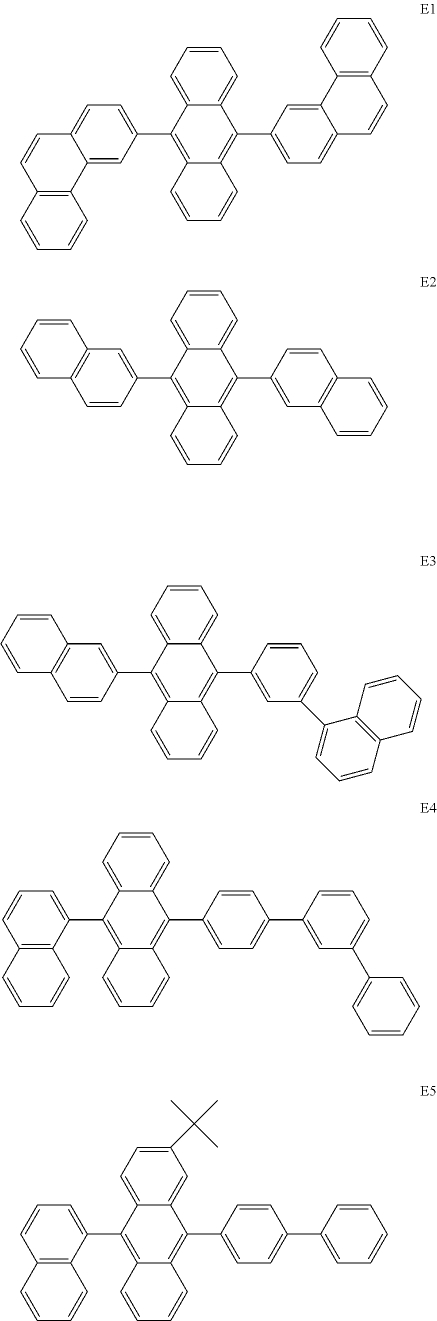

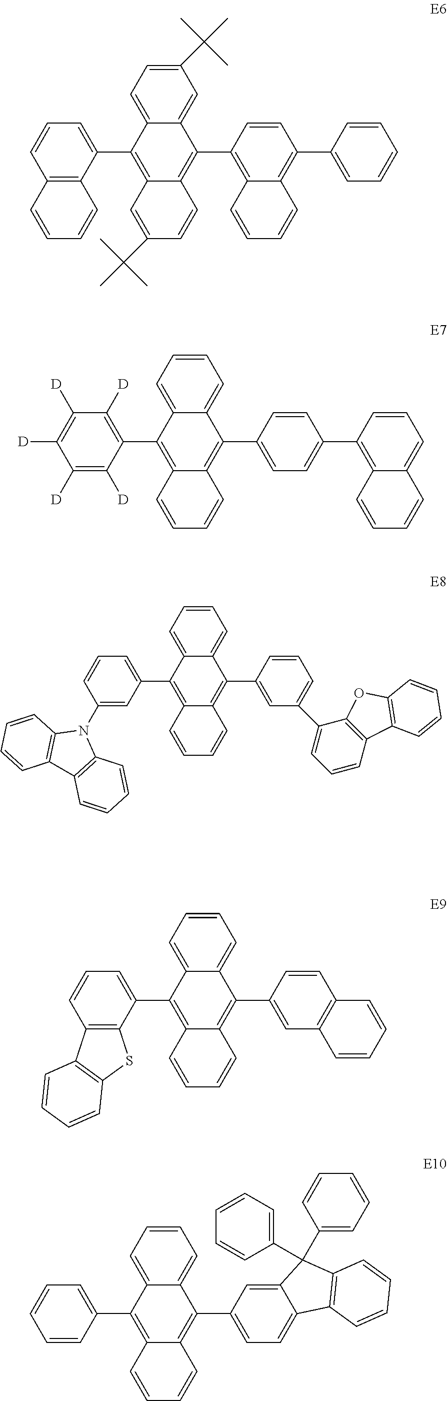

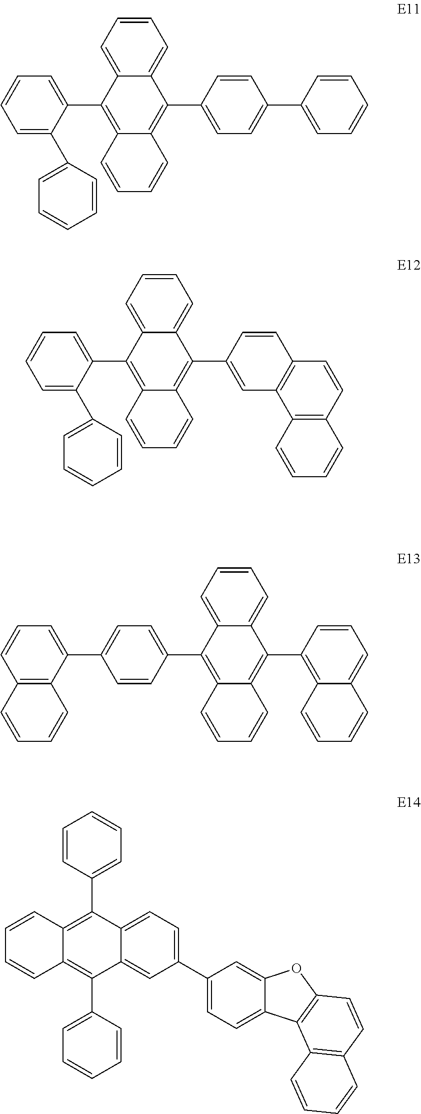

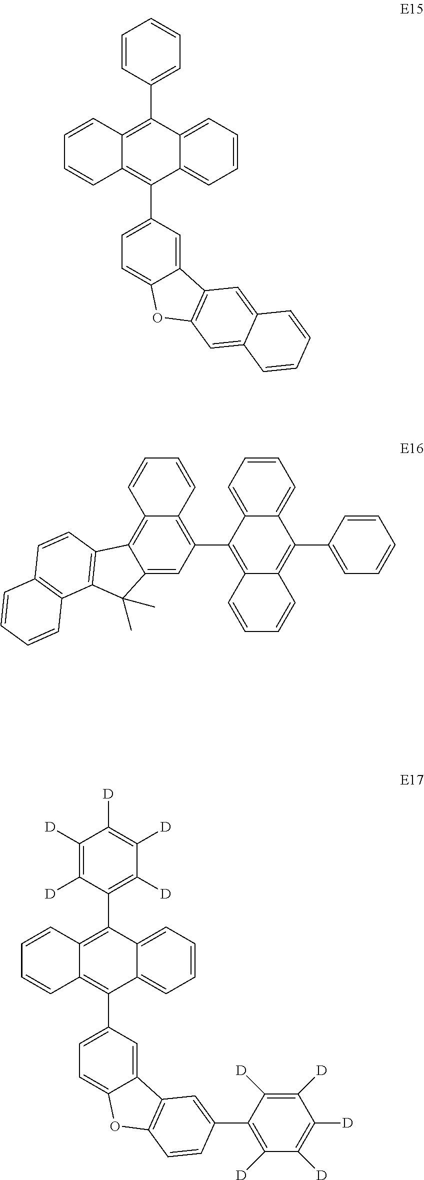

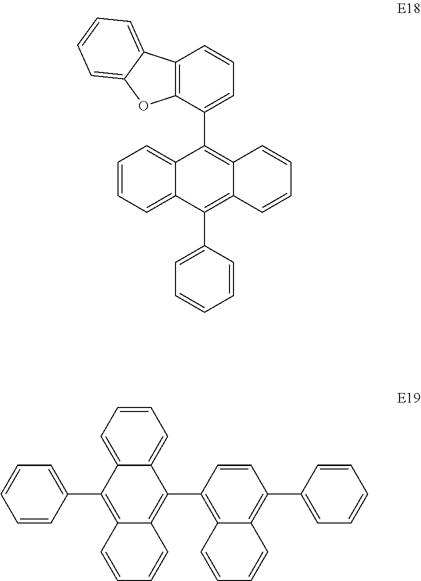

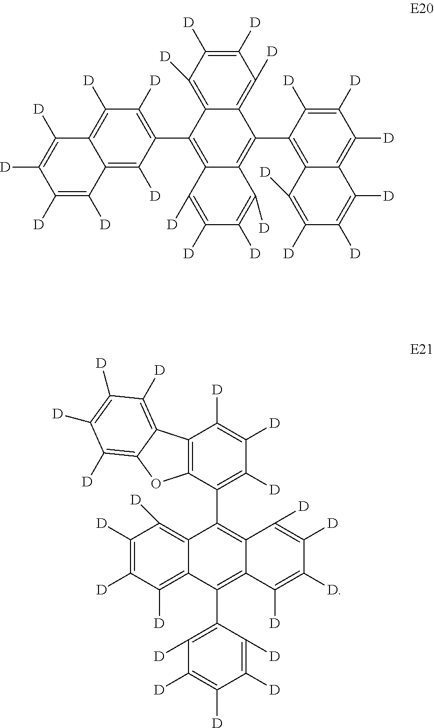

In an embodiment, the emission layer EML may include a compound represented by Formula E-2a or Formula E-2b. The compound represented by Formula E-2a or Formula E-2b may be used as a host material of a phosphorescent emission layer.

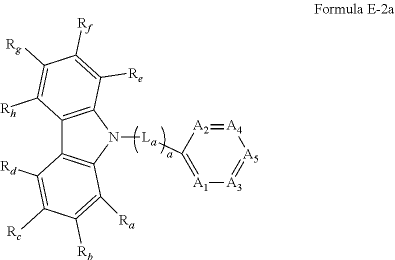

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is an integer of 2 or greater, a plurality of Lₐ's may be each independently a substituted or unsubstituted arylene group having 6 to 30 ring-forming carbon atoms, or a substituted or unsubstituted heteroarylene group having 2 to 30 ring-forming carbon atoms.

In addition, in Formula E-2a, A₁ to A₅ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, or the like, as a ring-forming atom.

In Formula E-2a, two or three selected from among A₁ to A₅ may be N, and the rest may be CRᵢ.

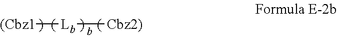

In Formula E-2b, Cbz1 and Cbz2 may be each independently an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b is an integer of 0 to 10, and when b is an integer of 2 or more, a plurality of L_{b}'s may be each independently a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by one of the compounds of Compound Group E-2. However, the compounds listed in Compound Group E-2 below are exemplary, and the compound represented by Formula E-2a or Formula E-2b is not limited to those represented in Compound Group E-2.

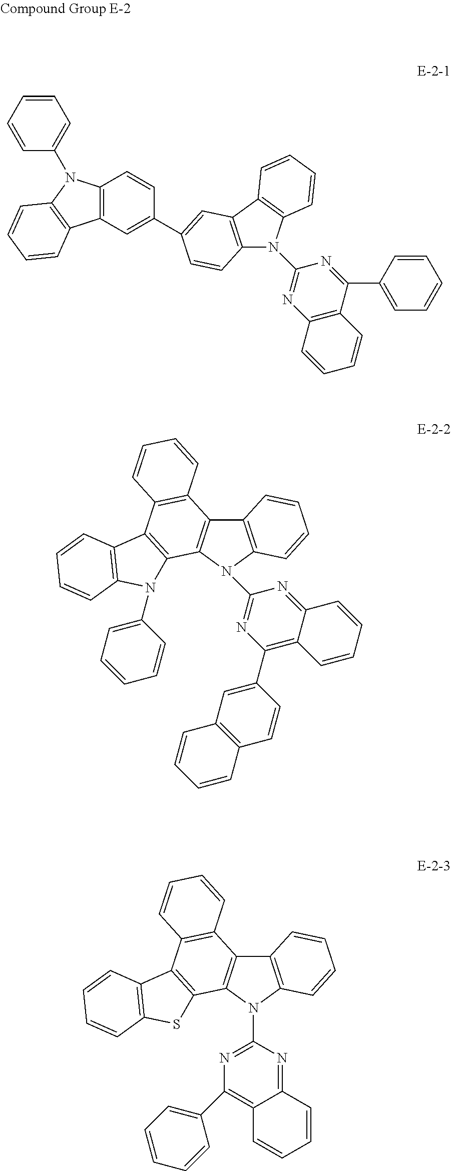 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

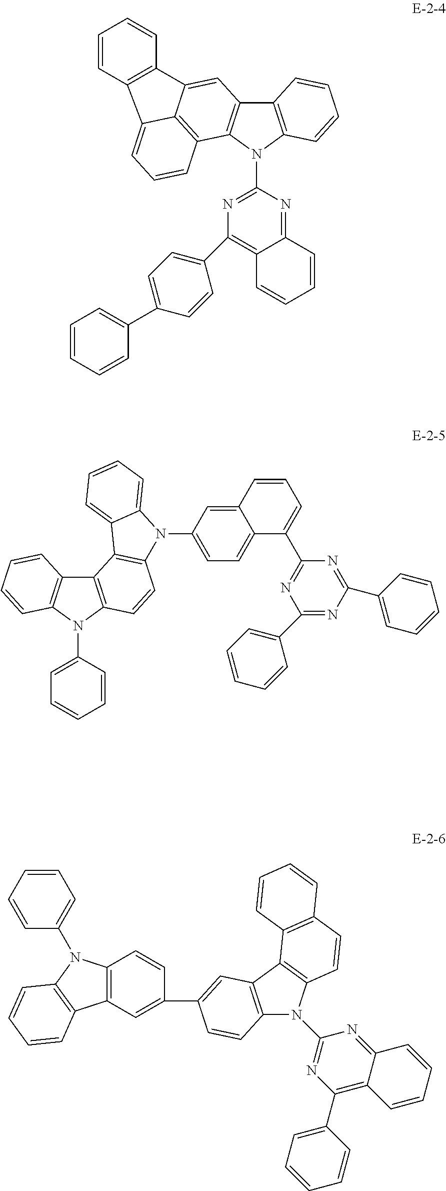 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

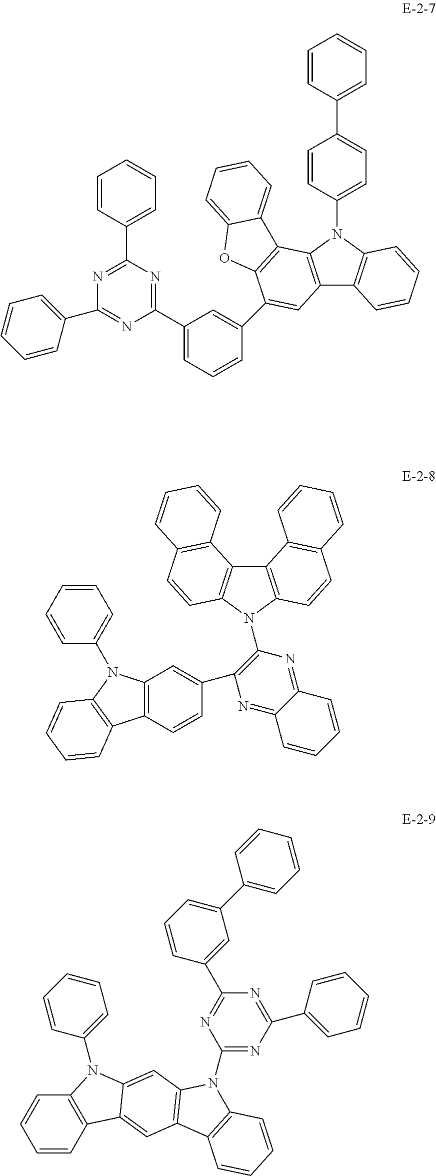 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

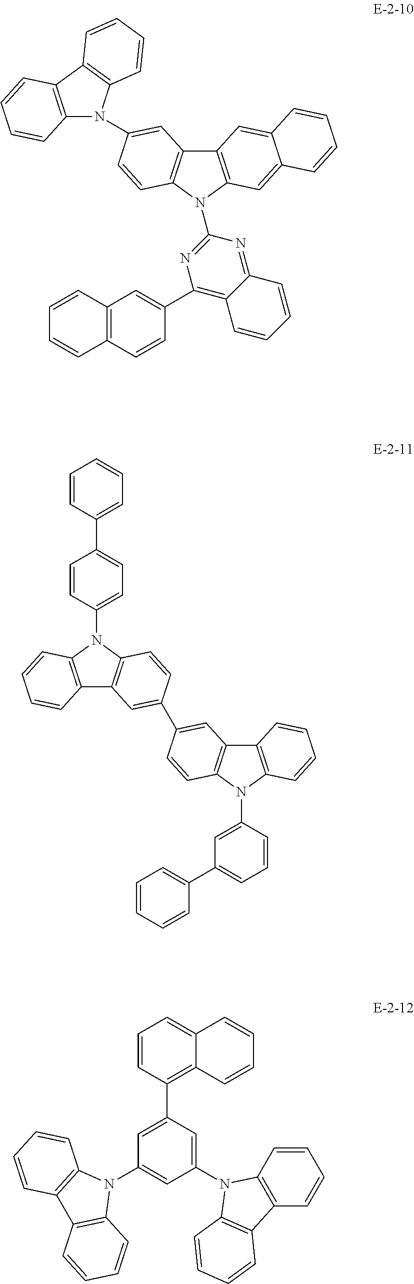 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

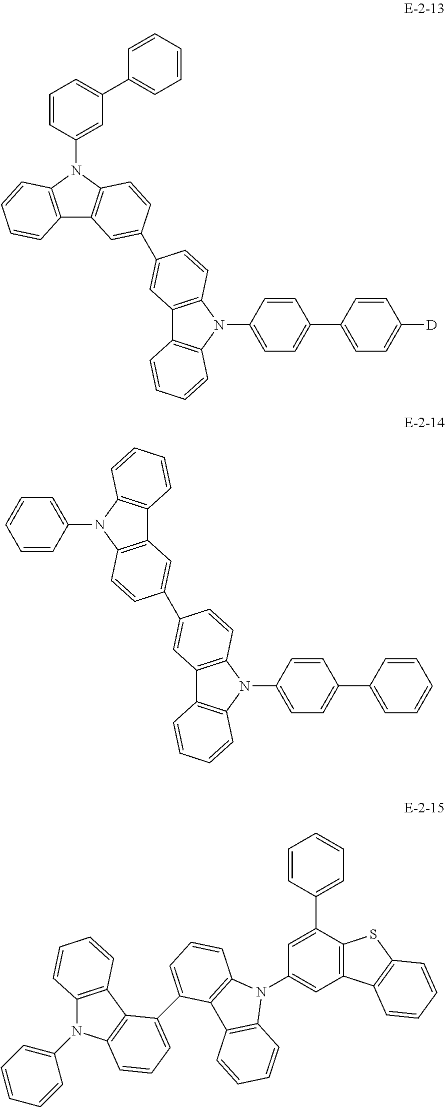 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

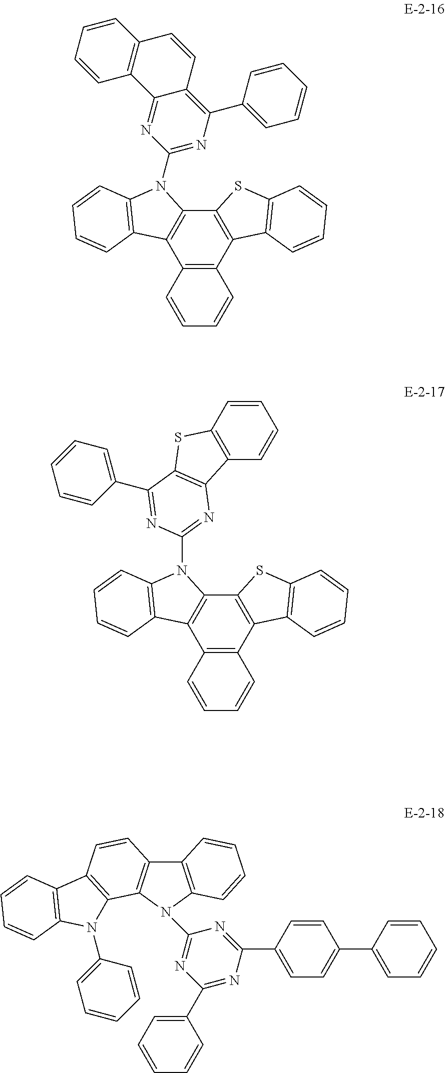 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

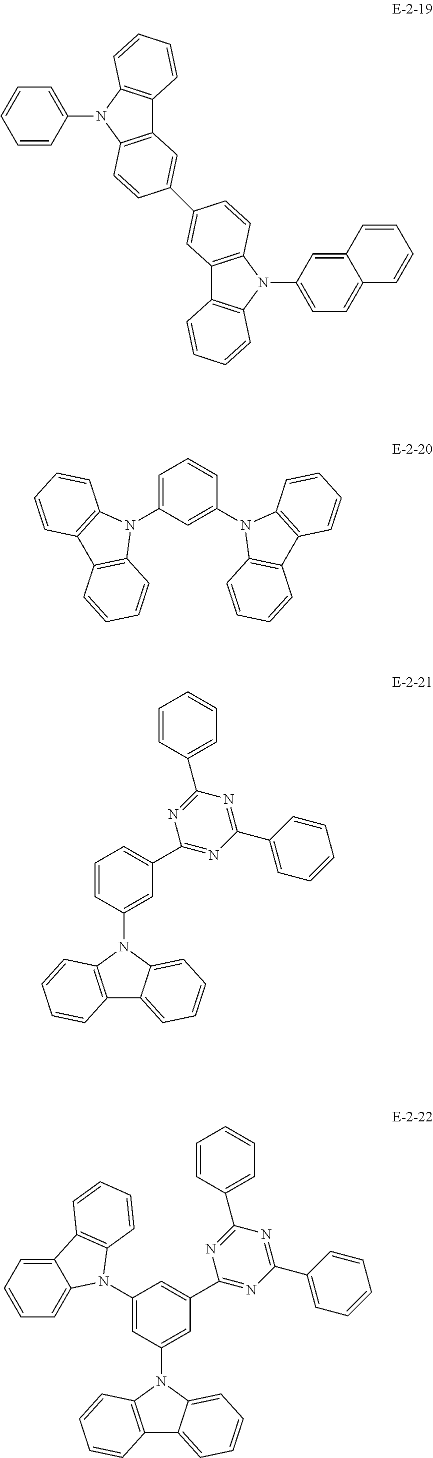 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

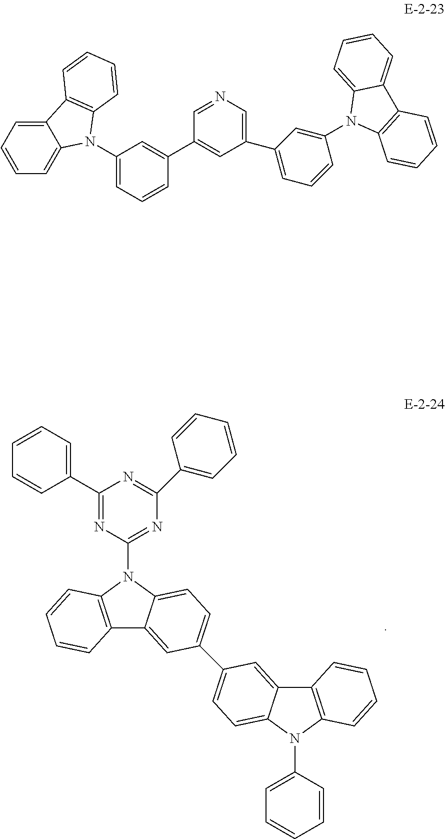 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material known in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi), tris(8-hydroxyquinolino)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), or the like, but embodiments are not limited thereto.

The emission layer EML may include the compound represented by Formula M-a. The compound represented by Formula M-a may be used as a phosphorescent dopant material.

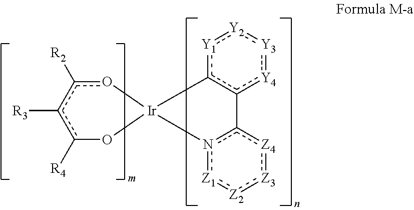

In Formula M-a, Y₁ to Y₄ and Z₁ to Z₄ may be each independently CR₁ or N, R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be represented by one of Compound M-a1 to Compound M-a25. However, Compounds M-a1 to M-a25 below are examples, and the compound represented by Formula M-a is not limited to those represented by Compounds M-a1 to M-a25:

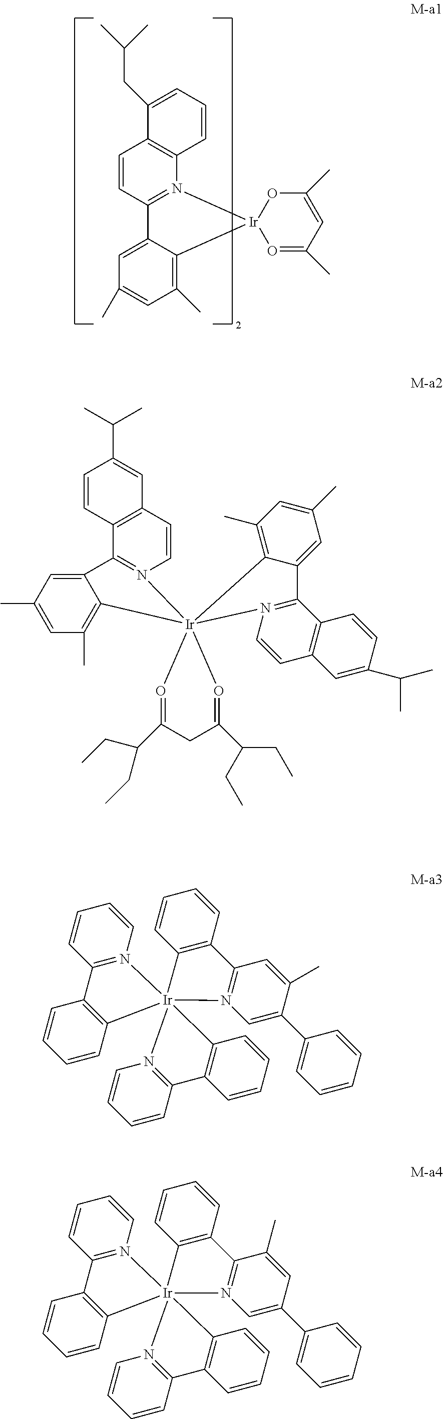

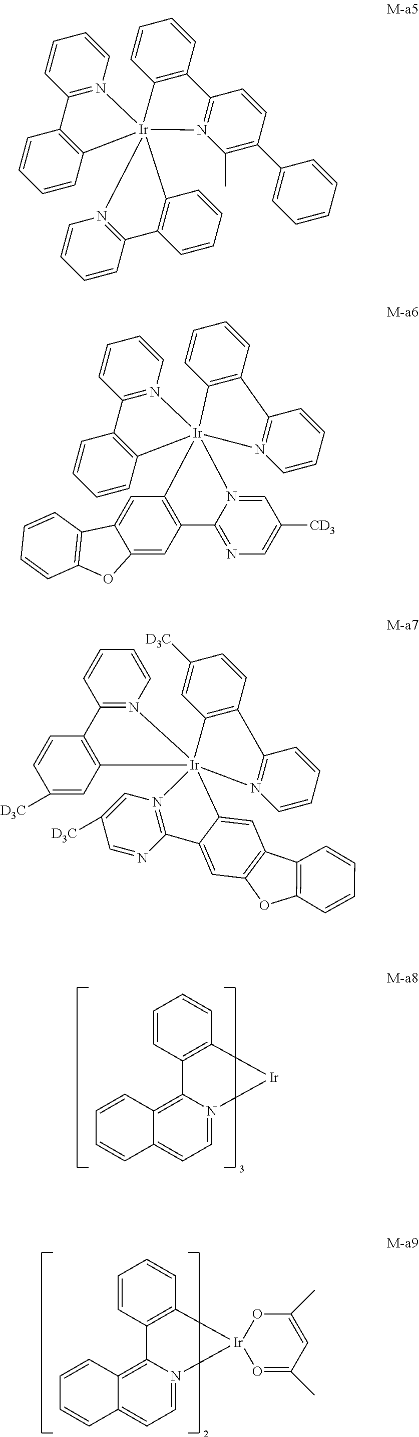

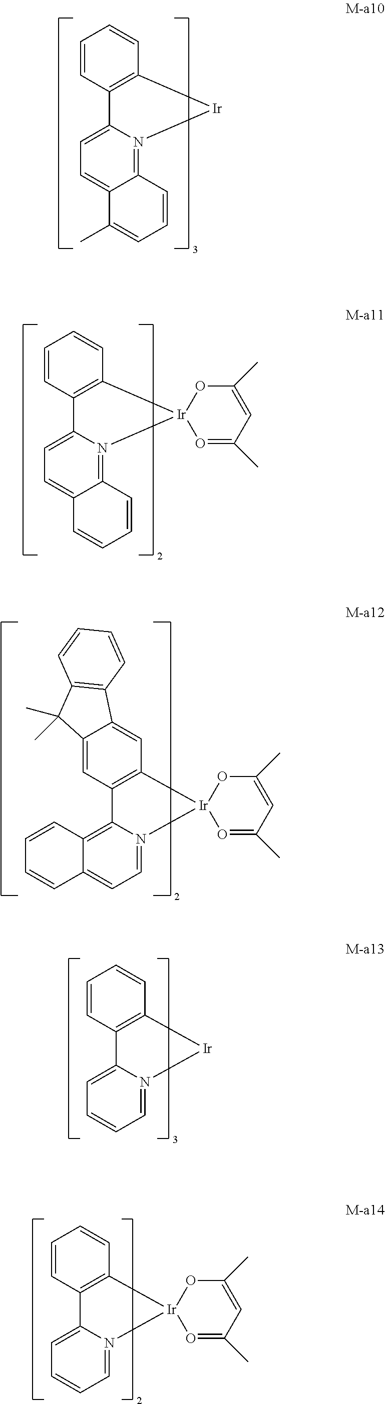

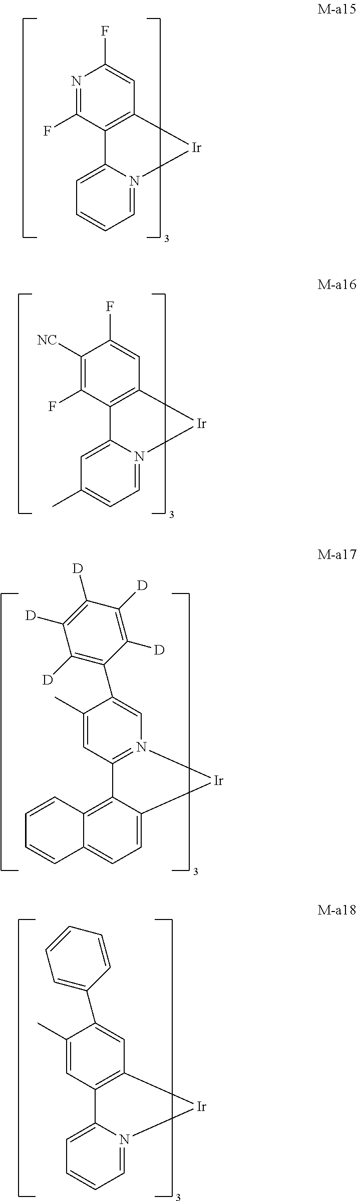

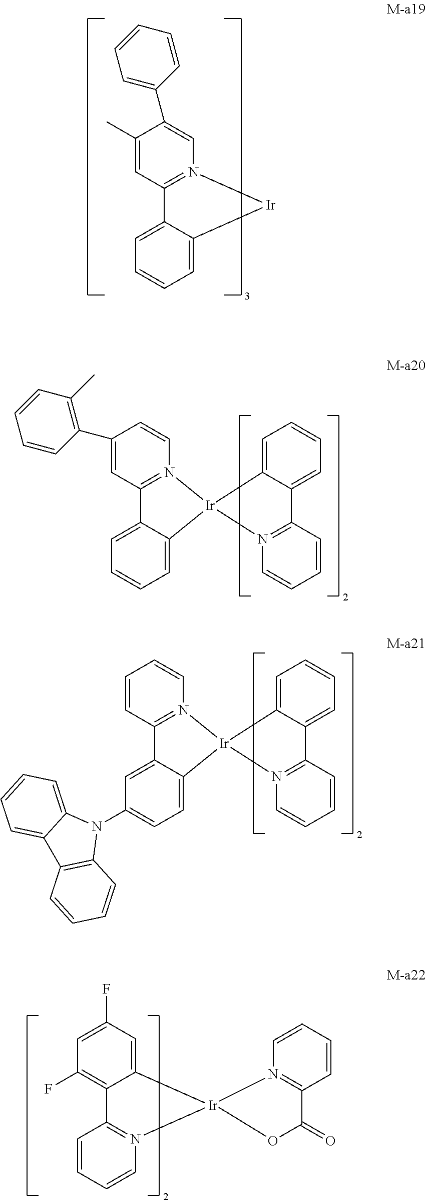

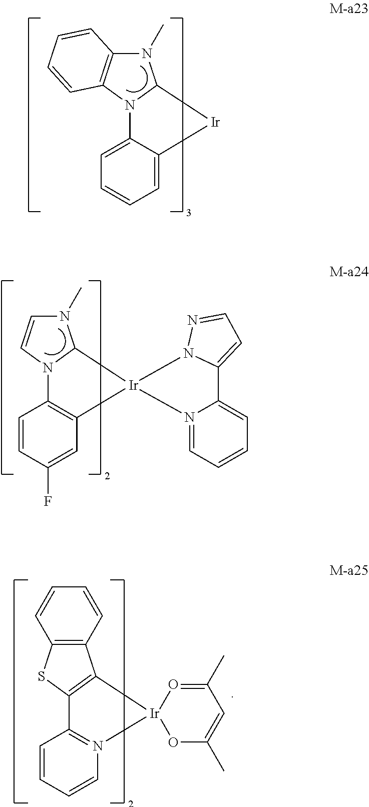

The emission layer EML may include a compound represented by one of Formula F-a to Formula F-c. The compound represented by Formula F-a to Formula F-c may be used as a fluorescence dopant material.

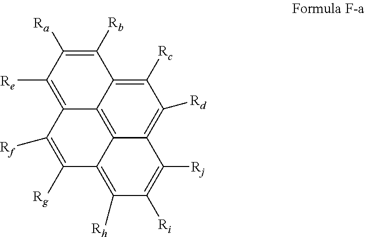

In Formula F-a, two selected from among Rₐ to Rⱼ may each independently be substituted with *—NAr₁Ar₂. The others, which are not substituted with *—NAr₁Ar₂, among Rₐ to Rⱼ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

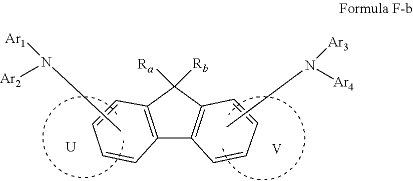

In Formula F-b, Rₐ and R_{b} may be each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Ar₁ to Ar₄ may be each independently a substituted or unsubstituted aryl group having 6 to 30 ring-forming carbon atoms, or a substituted or unsubstituted heteroaryl group having 2 to 30 ring-forming carbon atoms.

In Formula F-b, ring U and ring V may be each independently a substituted or unsubstituted hydrocarbon ring having 5 to 30 ring-forming carbon atoms, or a substituted or unsubstituted heterocycle having 2 to 30 ring-forming carbon atoms. At least one of Ar₁ to Ar₄ may be a heteroaryl group containing O or S as a ring-forming atom.

In Formula F-b, the number of rings represented by ring U and ring V may be each independently 0 or 1. For example, in Formula F-b, it means that when the number of ring U or ring V is 1, one ring constitutes a fused ring at a portion indicated by ring U or ring V, and when the number of ring U or ring V is 0, a ring indicated by ring U or ring V does not exist. Specifically, when the number of ring U is 0 and the number of ring V is 1, or when the number of ring U is 1 and the number of ring V is 0, the fused ring having a fluorene core in Formula F-b may be a cyclic compound having four rings. In addition, when each number of ring U and ring V is 0, the fused ring in Formula F-b may be a cyclic compound having three rings. In addition, when each number of ring U and ring V is 1, the fused ring having a fluorene core in Formula F-b may be a cyclic compound having five rings.

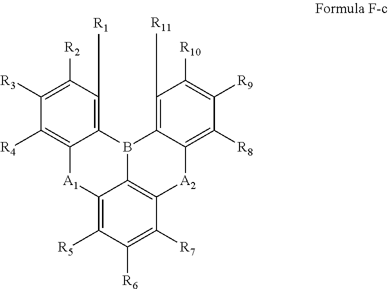

In Formula F-c, A₁ and A₂ may be each independently O, S, Se, or NRₘ, and each Rₘ may independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or R₁ to R₁₁ are independently bonded to an adjacent group to form a ring.

In Formula F-c, A₁ and A₂ may each independently be bonded to substituents of an adjacent ring to form a fused ring. For example, when A₁ and A₂ are each independently NRₘ, A₁ may be bonded to R₄ or R₅ to form a ring. In addition, A₂ may be bonded to R₇ or R₈ to form a ring.

In an embodiment, the emission layer EML may further include, as a dopant material, at least one of a styryl derivative (e.g., 1,4-bis[2-(3-N-ethylcarbazolyl) vinyl]benzene (BCzVB), 4-(di-p-tolylamino)-4′-[(di-p-tolylamino) styryl]stilbene (DPAVB), or N-(4-((E)-2-(6-((E)-4-(diphenylamino) styryl) naphthalen-2-yl) vinyl)phenyl)-N-phenylbenzenamine (N-BDAVBi), 4,4′-bis[2-(4-(N,N-diphenylamino)phenyl) vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), or the like, but embodiments are not limited thereto.

The emission layer EML may further include a known phosphorescence dopant material. For example, a metal complex containing iridium(Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. Specifically, iridium(III) bis(4,6-difluorophenylpyridinato-N, C2′)picolinate) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

The emission layer EML may include a quantum dot material. A core of the quantum dot may be a group II-VI compound, a group I-II-VI compound, a group II-IV-VI compound, a group I-II-IV-VI compound, a group II-IV-V compound, a group III-VI compound, a group I-III-VI compound, a group III-V compound, a group III-II-V compound, a group IV-VI compound, a group IV element, a group IV compound, or a combination thereof.

The group II-VI compound may be: a binary compound that is CdSe, CdTe, CdS, ZnS, ZnSe, ZnTe, ZnO, HgS, HgSe, HgTe, MgSe, MgS, or the like, or a combination thereof; a ternary compound that is CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or the like, or a combination thereof; a quaternary compound that is HgZnTeS, CdZnSeS, CdZnSeTe, CdZnSTe, CdHgSeS, CdHgSeTe, CdHgSTe, HgZnSeS, HgZnSeTe, or the like, or a combination thereof; or a combination thereof.

The group II-VI compound may further include a group I metal and/or a group IV element. The group I-II-VI compound may be CuSnS, or CuZnS, and ZnSnS or the like may be selected as the group II-IV-VI compound. The group I-II-IV-VI compound may be a quaternary compound that is Cu₂ZnSnS₂, Cu₂ZnSnS₄, Cu₂ZnSnSe₄, Ag₂ZnSnS₂, or the like, or a combination thereof.

The group II-IV-V compound may be a ternary compound that is ZnSnP, ZnSnP₂, ZnSnAs₂, ZnGeP₂, ZnGeAs₂, CdSnP₂, CdGeP₂, or the like, or a combination thereof.

The group III-VI compound may include: a binary compound such as GaS, Ga₂S₃, GaSe, Ga₂Se₃, GaTe, InTe, InS, InSe, In₂S₃, In₂Se₃, or the like, or a combination thereof; a ternary compound such as InGaS₃, InGaSe₃, or the like, or a combination thereof; or any combination thereof.

The group I-III-VI compound may be: a ternary compound that is AgInS, AgInS₂, CuInS, CuInS₂, AgGaS₂, CuGaS₂CuGaO₂, AgGaO₂, AgAlO₂, or the like, or a combination thereof; a quaternary compound such as AgInGaS₂, CuInGaS₂, or the like, or a combination thereof; or a combination thereof.

The group III-V compound may be: a binary compound that is GaN, GaP, GaAs, GaSb, AlN, AlP, AlAs, AlSb, InN, InP, InAs, InSb, or the like, or a combination thereof; a ternary compound that is GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, or the like, or a combination thereof; a quaternary compound that is GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or the like, or a combination thereof; or a combination thereof. The group III-V compound may further include a group II metal. For example, InZnP or the like may be selected as a group III-II-V compound.

The group IV-VI compound may be: a binary compound that is SnS, SnSe, SnTe, PbS, PbSe, PbTe, or the like, or a combination thereof; a ternary compound that is SnSeS, SnSeTe, SnSTe, PbSeS, PbSeTe, PbSTe, SnPbS, SnPbSe, SnPbTe, or the like, or a combination thereof; a quaternary compound that is SnPbSSe, SnPbSeTe, SnPbSTe, or the like, or a combination thereof; or a combination thereof. The group IV element may be Si, Ge, or a combination thereof. The group IV compound may be a binary compound that is SiC, SiGe, or the like, or a combination thereof.

Each element included in a multi-element compound such as the binary compound, the ternary compound, and the quaternary compound may be present in a particle at a uniform concentration or non-uniform concentration. That is, the formula above indicates the types of elements included in the compound, and element ratios in the compound may vary. For example, AgInGaS₂ may indicate AgInₓGa₁₋ₓS₂ (x is a real number of 0 to 1).

The quantum dot may have a core-shell dual structure or a single structure in which a concentration of each element included in the corresponding quantum dot is uniform. For example, a material included in the core may be different from a material included in the shell.

The shell of the quantum dot may serve as a protection layer for preventing the core from being chemically modified to maintain semiconductor properties and/or as a charging layer for imparting electrophoretic properties to the quantum dot. The shell may have a single layer or multilayer. An interface between the core and the shell may have a concentration gradient in which a concentration of an element present in the shell decreases toward the core.

In some embodiments, the quantum dot may have a core-shell structure which includes a core including the above-described nanoparticles, and a shell surrounding the core. Examples of the shell of the quantum dot may include an oxide of metal or non-metal, a semiconductor compound, a combination thereof, etc.

For example, the oxide of metal or non-metal may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or the like, or a combination thereof; a ternary compound such as MgAl₂O₄, CoFe₂O₄, NiFe₂O₄, CoMn₂O₄, or the like, or a combination thereof; or a combination thereof, but embodiments are not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, or a combination thereof, but embodiments are not limited thereto.

Each element included in a multi-element compound such as the binary compound and the ternary compound may be present in particle at a uniform concentration or non-uniform concentration. That is, the formula above indicates types of elements included in the compound, and element ratios in the compound may vary.

The quantum dot may have a full width of half maximum (FWHM) of about 45 nm or less, preferably about 40 nm or less, and more preferably about 30 nm or less in an emission wavelength spectrum, and color purity and color reproducibility may be improved in this range. In addition, light emitted through the quantum dot is emitted in all directions, and thus an optical viewing angle may be improved.

In addition, the shape of the quantum dot is commonly available in the art and is not particularly limited. However, more specifically, the quantum dot may adopt a spherical, pyramidal, multi-arm-shaped or cubic nanoparticle, a nanotube, a nanowire, a nanofiber, a nanoplate particle, or the like.

It is possible to control an energy band gap by adjusting the size of the quantum dot or by adjusting the element ratio in the quantum dot compound, and thus light with various wavelength bands may be emitted from the quantum dot emission layer. Therefore, by using the above-described quantum dot (using quantum dots having different sizes or different element ratios in the quantum dot compound), a light-emitting element that emits light with various wavelengths may be achieved. Specifically, the size of the quantum dot and the element ratio in the quantum dot compound may be selected such that red, green, and/or blue light is emitted. In addition, the quantum dots may be configured to emit white light by combining various colors of light.

In each of the light-emitting elements ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but embodiments are not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In addition, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in the stated order from the emission layer EML, but embodiments are not limited thereto. The electron transport region ETR may have a thickness, for example, from about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, a laser induced thermal imaging (LITI) method, or the like, but embodiments are not limited thereto.

The electron transport region ETR may include a compound represented by Formula ET-2:

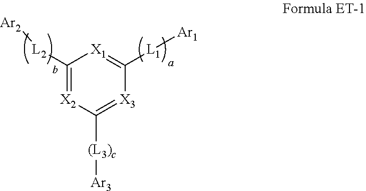

In Formula ET-2, at least one of X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may be each independently an integer of 0 to 10. In Formula ET-2, L₁ to L₃ may be each independently a direct linkage, a substituted or unsubstituted arylene group having 6 to 30 ring-forming carbon atoms, or a substituted or unsubstituted heteroarylene group having 2 to 30 ring-forming carbon atoms. When a to c are each independently an integer of 2 or more, L₁ to L₃ may be each independently a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-containing compound. However, embodiments are not limited thereto, and the electron transport region ETR may include, for example, at least one of tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalen-2-yl)anthracene (ADN), or 1,3-bis[3,5-di(pyridin-3-yl)phenyl]benzene (BmPyPhB).

The electron transport region ETR may include at least one from Compound ET1 to Compound ET36:

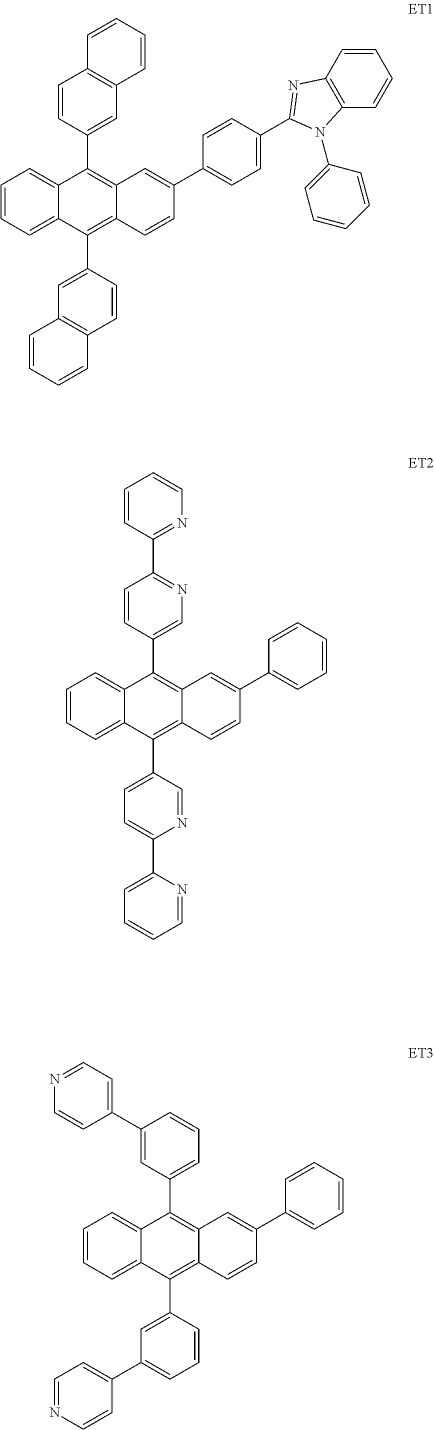 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

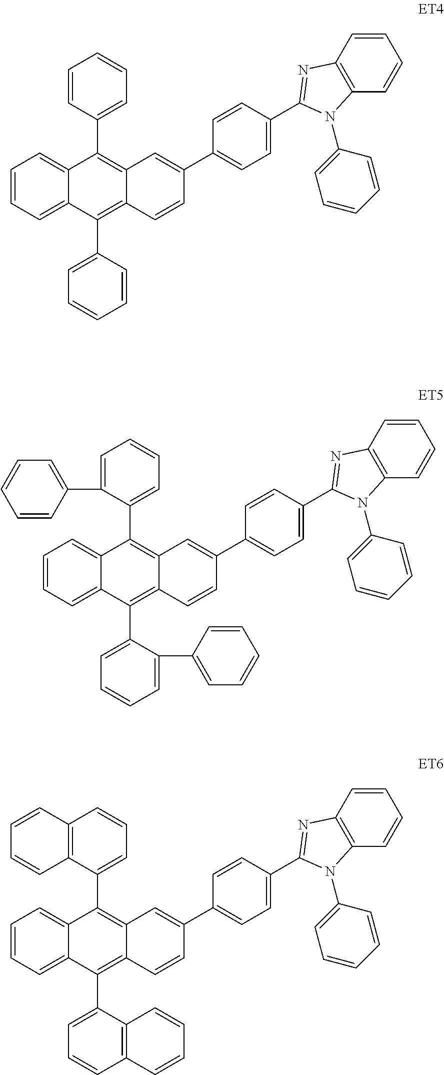 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

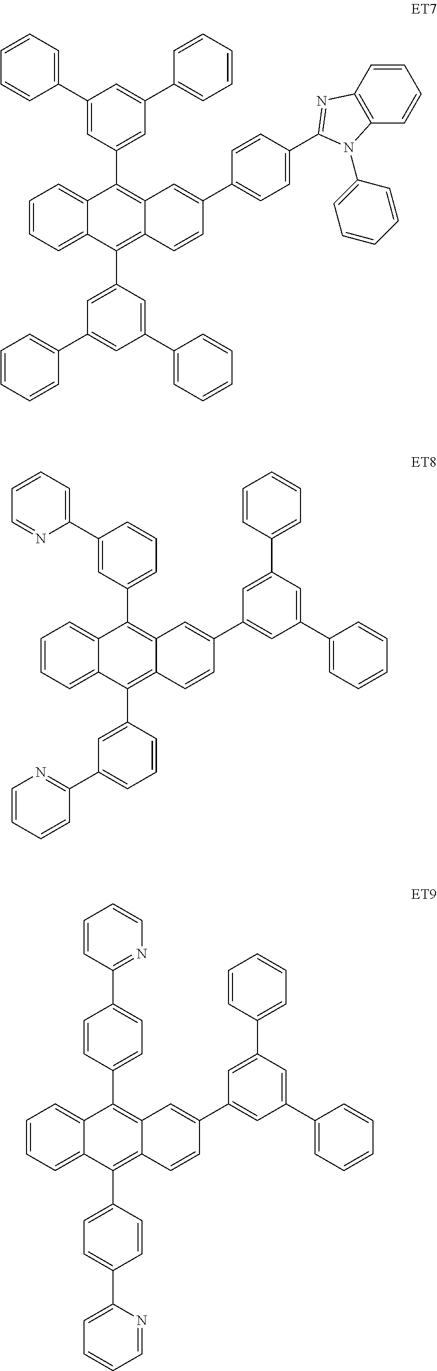 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

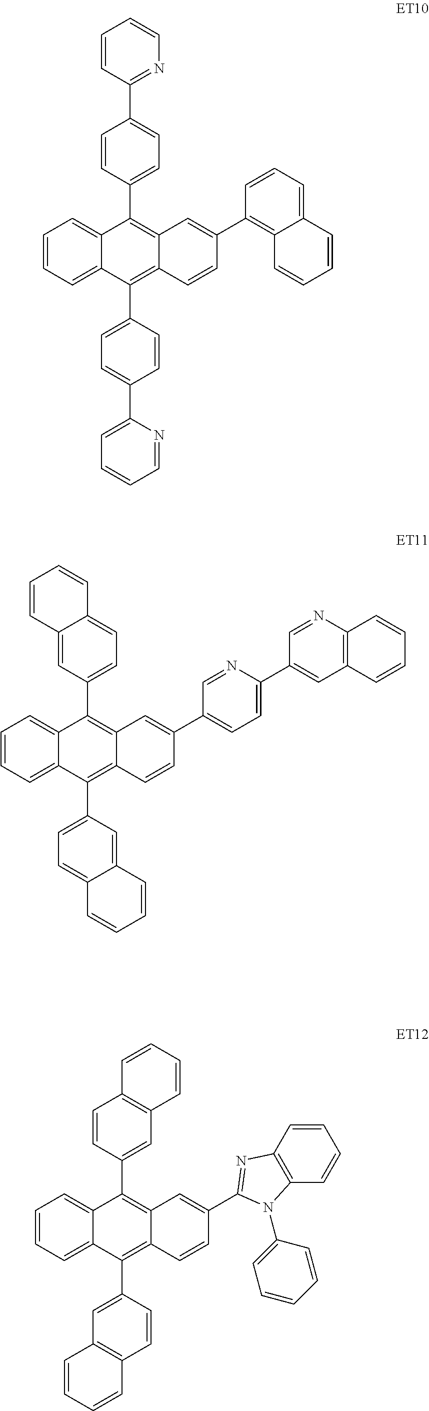 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

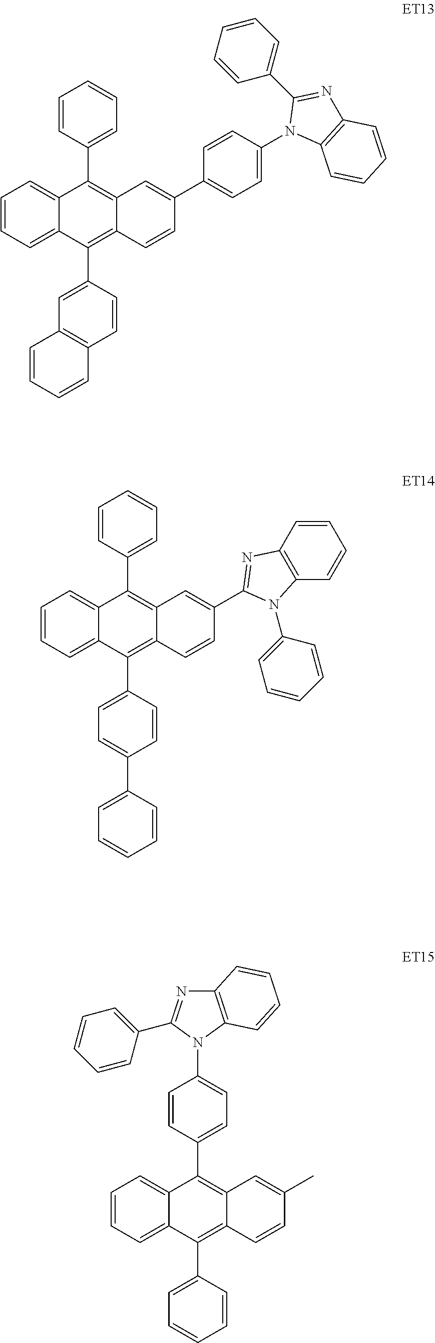 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

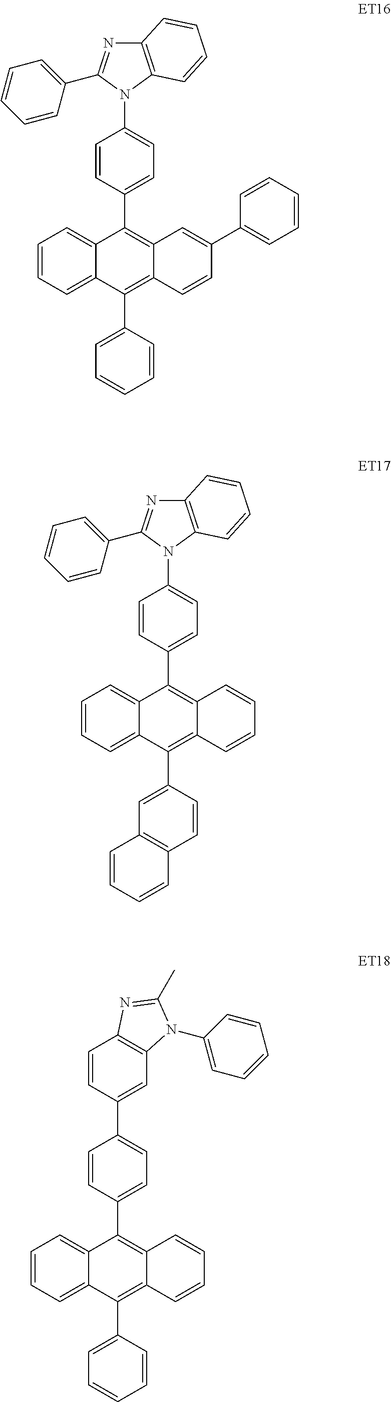 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

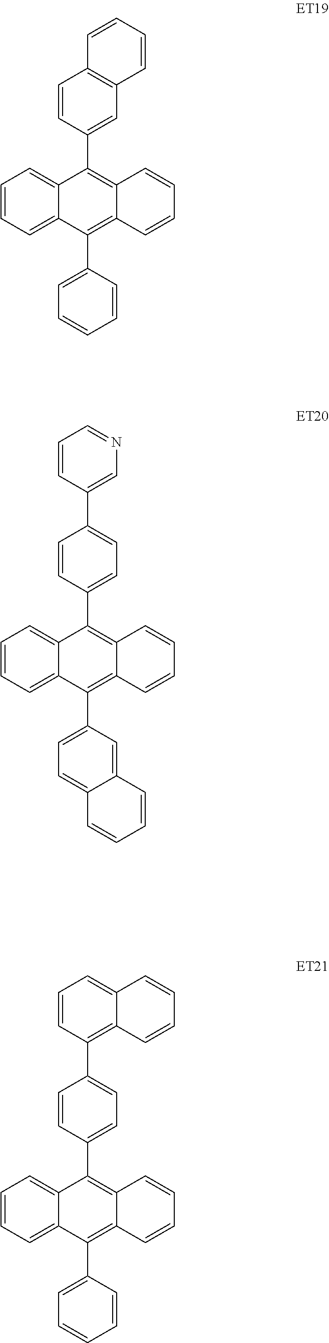

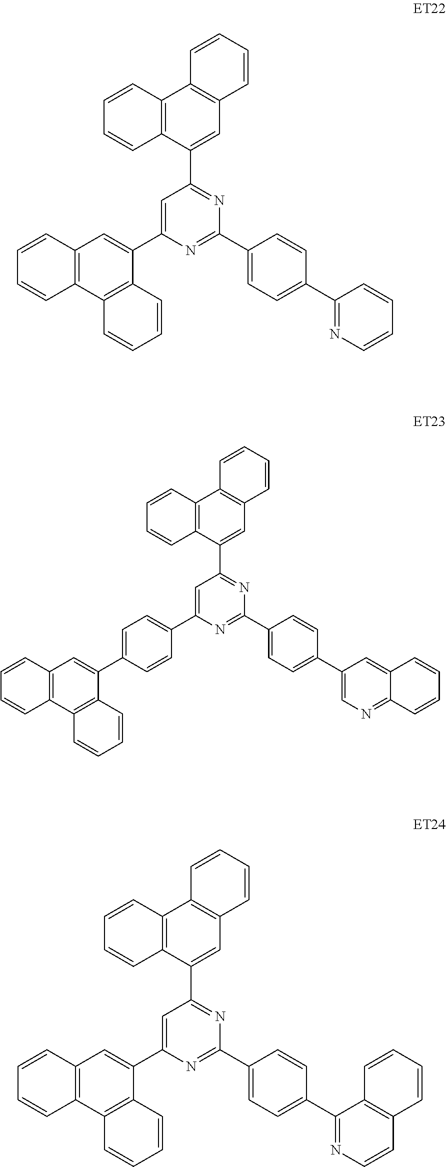 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

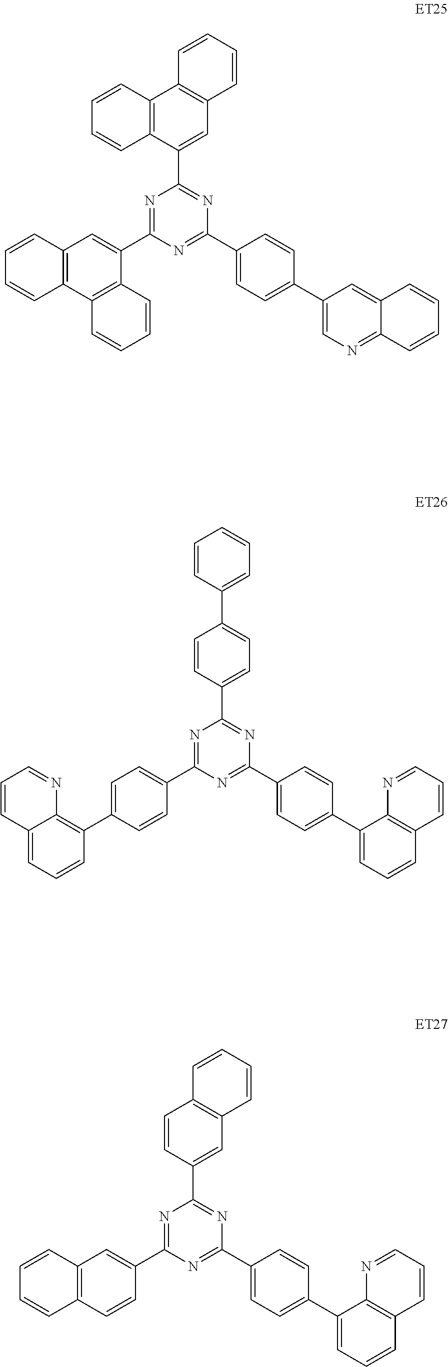 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

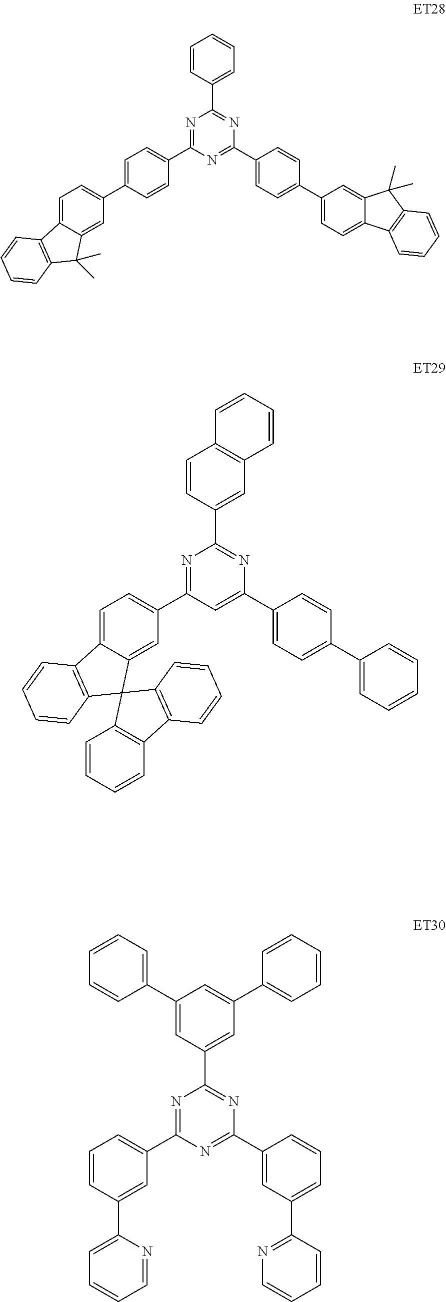 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

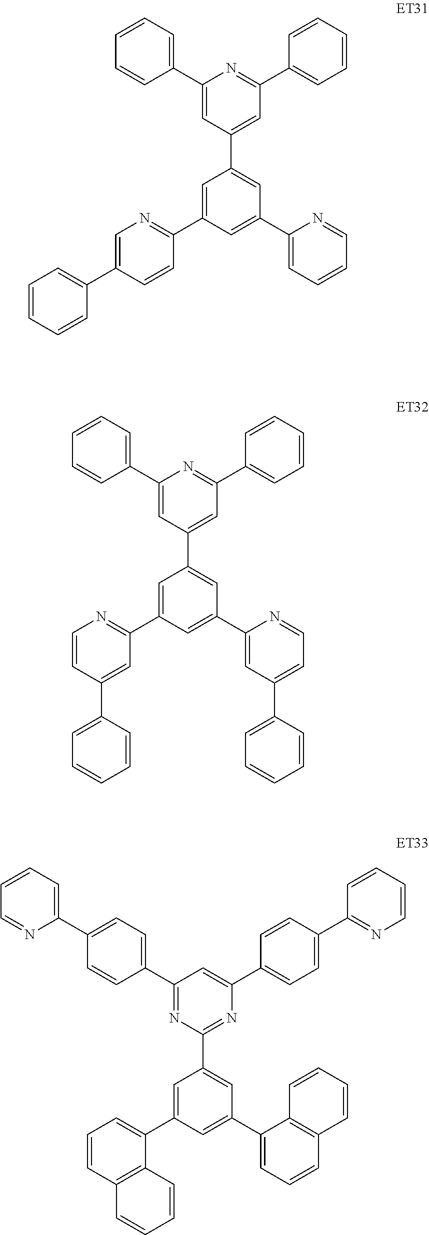 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

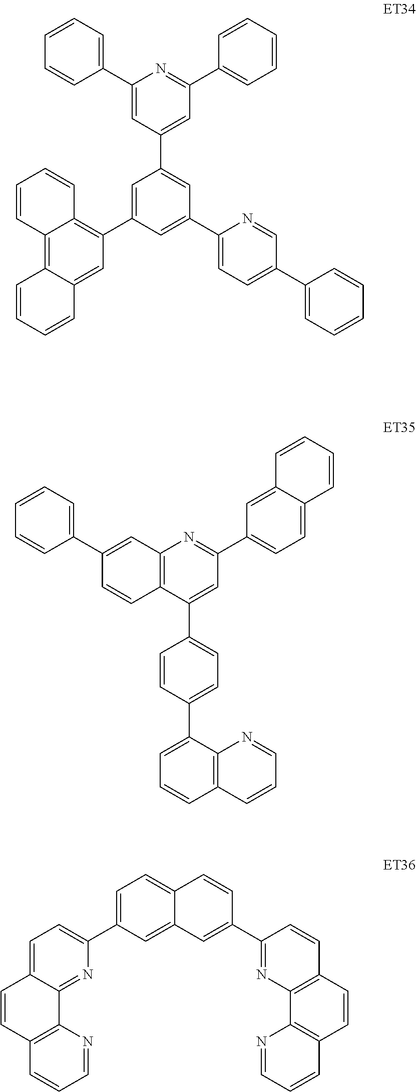 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In addition, the electron transport region ETR may include a metal halide such as LiF, NaCl, CsF, RbCl, RbI, CuI, KI, or the like, or a combination thereof, a lanthanide metal such as Yb, or a co-deposited material of the metal halide and the lanthanide metal. For example, the electron transport region ETR may include KI:Yb, RbI:Yb, LiF:Yb, or the like, as a co-deposited material. The electron transport region ETR may be formed using a metal oxide such as Li₂O or BaO, or 8-hydroxyl-lithium quinolate (Liq), or the like, but embodiments are not limited thereto. The electron transport region ETR may also be formed of a mixture material of an electron transport material and an insulating organometallic salt. The organometallic salt may be a material having an energy band gap of about 4 eV or more. Specifically, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. If the thickness of the electron transport layer ETL satisfies the aforementioned range, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. If the thickness of the electron injection layer EIL satisfies the above-described range, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), or the like, or a combination thereof.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, Na, or a compound or mixture thereof (e.g., AgMg, AgYb, MgYb, AgNa, or AgLi). Alternatively, the second electrode EL2 may have a multi-layer structure including a reflective film or a transflective film formed of the above-described materials, and a transparent conductive film formed of ITO, IZO, ZnO, ITZO, or the like, or a combination thereof. For example, the second electrode EL2 may include the above-described metal materials, combinations of at least two metal materials of the above-described metal materials, oxides of the above-described metal materials, or the like.

Although not shown, the second electrode EL2 may be connected with an auxiliary electrode. If the second electrode EL2 is connected with the auxiliary electrode, the resistance of the second electrode EL2 may be decreased.

A capping layer CPL may further be disposed on the second electrode EL2 of the light-emitting element ED of an embodiment. The capping layer CPL may include a multilayer or a single layer.

In an embodiment, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, or the like.

For example, when the capping layer CPL includes an organic material, the organic material may include at least one of α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), an epoxy resin, or acrylate such as methacrylate. However, embodiments are not limited thereto, and the capping layer CPL may include at least one among Compounds P1 to P5:

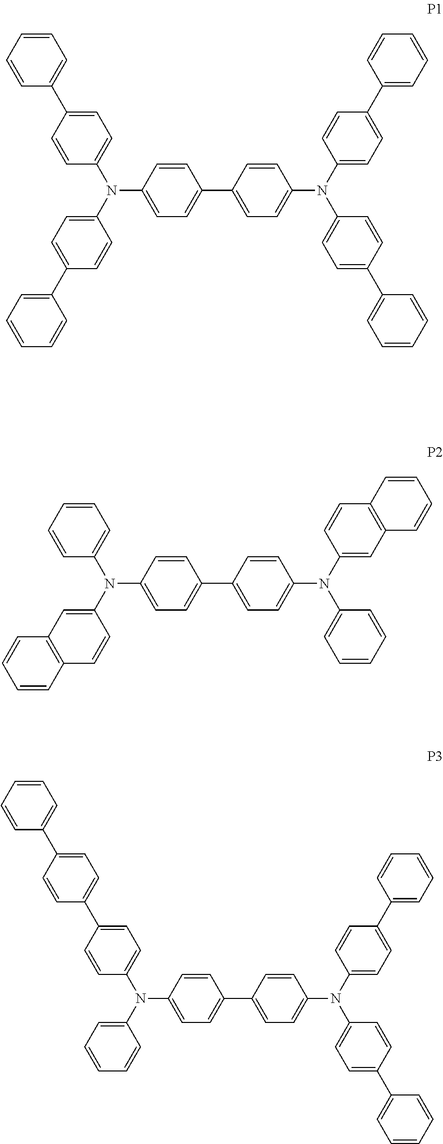 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

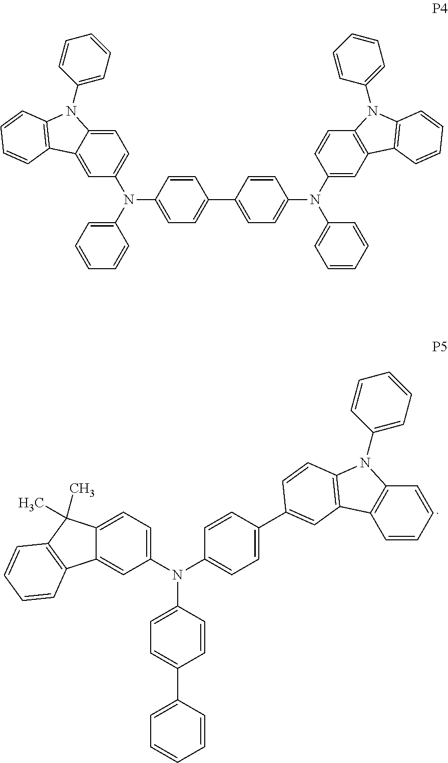 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be about 1.6 or more. Specifically, the refractive index of the capping layer CPL may be about 1.6 or more with respect to light in a wavelength range of about 550 nm to about 660 nm.

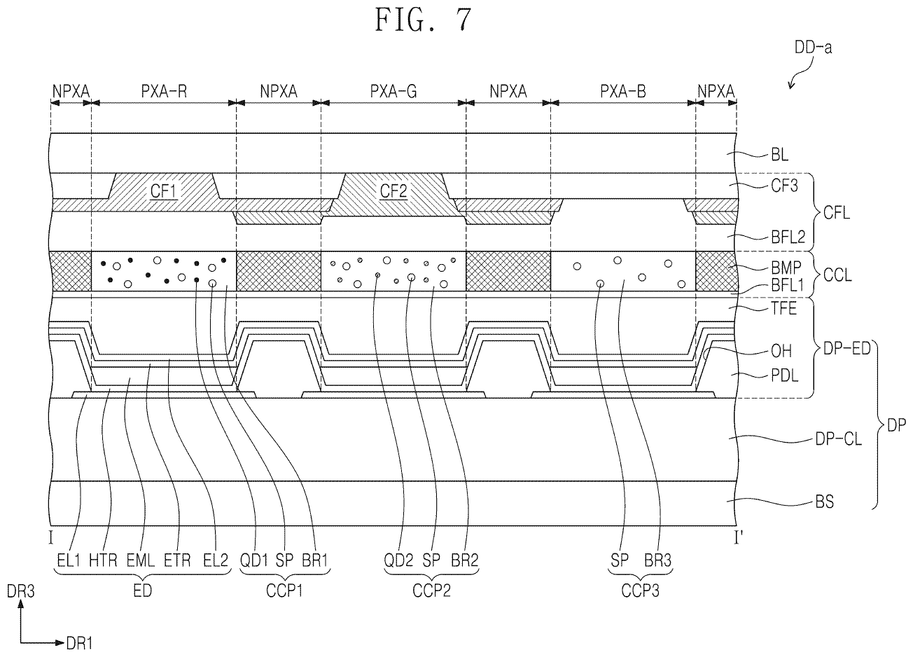

FIG. 7 to FIG. 10 are cross-sectional views of display devices according to embodiments. Hereinafter, in the explanation on the display devices according to embodiments, referring to FIG. 7 to FIG. 10, the overlapping contents with those explained in FIG. 1 to FIG. 6 will not be explained again, and different points will be explained mainly.

Referring to FIG. 7, a display device DD-a according to an embodiment may include a display panel DP including a display element layer DP-ED, a light control layer CCL disposed on the display panel DP and a color filter layer CFL. In an embodiment shown in FIG. 7, the display panel DP may include a base layer BS, a circuit layer DP-CL provided on the base layer BS and a display element layer DP-ED, and the display element layer DP-ED may include a light-emitting element ED.

The light-emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. The same structure as the light-emitting elements ED of FIG. 3 to FIG. 6 may be applied to the structure of the light-emitting element ED, shown in FIG. 7. The light-emitting element ED shown in FIG. 7 may include the fused polycyclic compound of an embodiment. The light-emitting element ED including the fused polycyclic compound of an embodiment may exhibit high emission efficiency.

Referring to FIG. 7, the emission layer EML may be disposed in an opening OH defined in a pixel defining film PDL. For example, the emission layer EML which is divided by the pixel defining film PDL and provided corresponding to each light emitting regions PXA-R, PXA-G, and PXA-B may emit light in the same wavelength range. In the display device DD-a of an embodiment, the emission layer EML may emit a blue light. Unlike the configuration illustrated, in an embodiment, the emission layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may emit provided light by converting the wavelength thereof. That is, the light control layer CCL may be a layer containing the quantum dot or a layer containing the phosphor.

The light control layer CCL may include a plurality of light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3 which are spaced apart from each other, but embodiments are not limited thereto. FIG. 7 illustrates that the divided patterns BMP do not overlap the light control parts CCP1, CCP2, and CCP3, but at least a portion of the edges of the light control parts CCP1, CCP2, and CCP3 may overlap the divided patterns BMP.

The light-emitting element ED may emit a first color light. The light control layer CCL may include a first light control part CCP1 containing a first quantum dot QD1 which converts the first color light provided from the light-emitting element ED into a second color light, a second light control part CCP2 containing a second quantum dot QD2 which converts the first color light into a third color light, and a third light control part CCP3 which transmits the first color light.

In an embodiment, the first light control part CCP1 may provide a red light that is the second color light, and the second light control part CCP2 may provide a green light that is the third color light. The third light control part CCP3 may provide a blue light by transmitting the blue light that is the first color light provided from the light-emitting element ED. For example, the first quantum dot QD1 may be a red quantum dot, and the second quantum dot QD2 may be a green quantum dot. The same as described above may be applied with respect to the quantum dots QD1 and QD2.

In addition, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but include the scatterer SP.

The scatterer SP may include inorganic particles. For example, the scatterer SP may include at least one of TiO₂, ZnO, Al₂O₃, SiO₂, or hollow sphere silica. The scatterer SP may include at least one of TiO₂, ZnO, Al₂O₃, SiO₂, or hollow sphere silica, or may be a mixture of at least two materials that include TiO₂, ZnO, Al₂O₃, SiO₂, or hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-containing resins, urethane-containing resins, silicone-containing resins, epoxy-containing resins, or the like, or a combination thereof. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent the penetration of moisture and/or oxygen (hereinafter, referred to as ‘moisture/oxygen’). The barrier layer BFL1 may block the light control parts CCP1, CCP2 and CCP3 from being exposed to moisture/oxygen. The barrier layer BFL1 may cover the light control parts CCP1, CCP2, and CCP3. In addition, the barrier layer BFL2 may be provided between the light control parts CCP1, CCP2, and CCP3 and the color filter layer CFL.

The barrier layers BFL1 and BFL2 may include at least one inorganic layer. That is, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, or the like. The barrier layers BFL1 and BFL2 may further include an organic film. The barrier layers BFL1 and BFL2 may be formed of a single layer or a plurality of layers.

In the display device DD-a of an embodiment, the color filter layer CFL may be disposed on the light control layer CCL. For example, the color filter layer CFL may be directly disposed on the light control layer CCL. In this case, the barrier layer BFL2 may be omitted.

The color filter layer CFL may include color filters CF1, CF2, and CF₃. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or a dye. The first filter CF1 may include a red pigment or dye, the second filter CF2 may include a green pigment or dye, and the third filter CF3 may include a blue pigment or dye.

Embodiments are not limited thereto, and the third filter CF3 may not include a pigment or a dye. The third filter CF3 may include a polymeric photosensitive resin and may not include a pigment or a dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated but may be provided as one filter.

Although not illustrated, the color filter layer CFL may further include a light shielding part (not shown). The light shielding part may be a black matrix. The light shielding part may include an organic light shielding material or an inorganic light shielding material containing a black pigment or dye. The light shielding part may prevent light leakage, and may separate boundaries between the adjacent filters CF1, CF2, and CF3. In an embodiment, the light shielding part may be formed of a blue filter.

The first to third filters CF1, CF2, and CF3 may be disposed corresponding to the red light emitting region PXA-R, the green light emitting region PXA-G, and the blue light emitting region PXA-B, respectively.

A base substrate BL may be disposed on the color filter layer CFL. The base substrate BL may be a member which provides a base surface in which the color filter layer CFL, the light control layer CCL, and the like are disposed. The base substrate BL may be a glass substrate, a metal substrate, a plastic substrate, or the like. However, embodiments are not limited thereto, and the base substrate BL may be an inorganic layer, an organic layer, or a composite material layer. In addition, unlike the configuration illustrated, in an embodiment, the base substrate BL may be omitted.

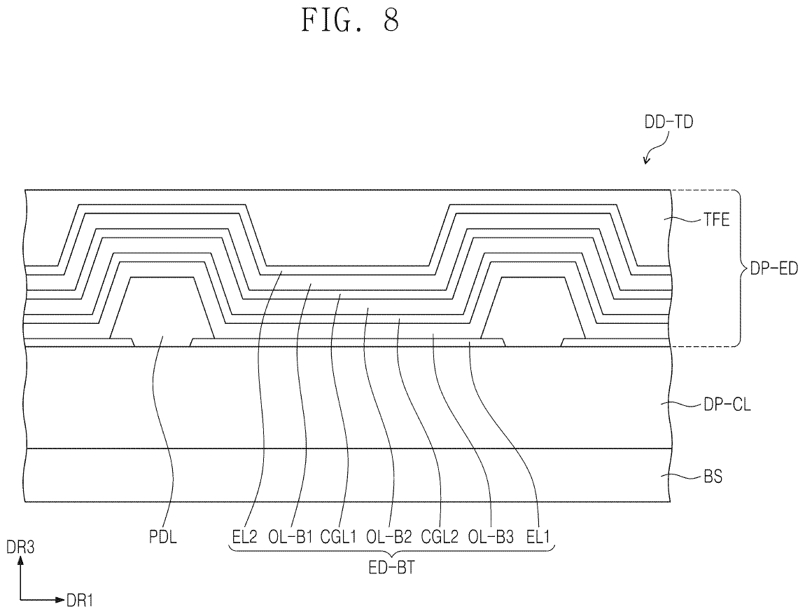

FIG. 8 is a cross-sectional view showing a portion of a display device DD-TD according to an embodiment. In the display device DD-TD of an embodiment, a light-emitting element ED-BT may include multiple light emitting structures OL-B1, OL-B2, and OL-B3. The light-emitting element ED-BT may include oppositely disposed first electrode EL1 and second electrode EL2, and multiple light emitting structures OL-B1, OL-B2, and OL-B3, which are stacked in order in a thickness direction and provided between the first electrode EL1 and the second electrode EL2. Each of the light emitting structures OL-B1, OL-B2, and OL-B3 may include an emission layer EML (FIG. 7), and a hole transport region HTR and an electron transport region ETR, disposed with the emission layer EML (FIG. 7) therebetween. That is, the light-emitting element ED-BT included in the display device DD-TD of an embodiment may be a light-emitting element with a tandem structure, including multiple emission layers.

At least one among the light emitting structures OL-B1, OL-B2, and OL-B3 may include the fused polycyclic compound represented by Formula 1 of an embodiment. The light-emitting element ED-BT including the fused polycyclic compound represented by Formula 1 of an embodiment may exhibit high emission efficiency.

In an embodiment illustrated in FIG. 8, all light beams respectively emitted from the light emitting structures OL-B1, OL-B2, and OL-B3 may be a blue light. However, embodiments are not limited thereto, and the light beams respectively emitted from the light emitting structures OL-B1, OL-B2, and OL-B3 may have wavelength ranges different from each other. For example, the light-emitting element ED-BT including the plurality of light emitting structures OL-B1, OL-B2, and OL-B3 which emit light beams having wavelength ranges different from each other may emit white light.

Charge generation layers CGL1 and CGL2 may be respectively disposed between two of the neighboring light emitting structures OL-B1, OL-B2, and OL-B3. The charge generation layers CGL1 and CGL2 may include a p-type charge generation layer and/or an n-type charge generation layer.

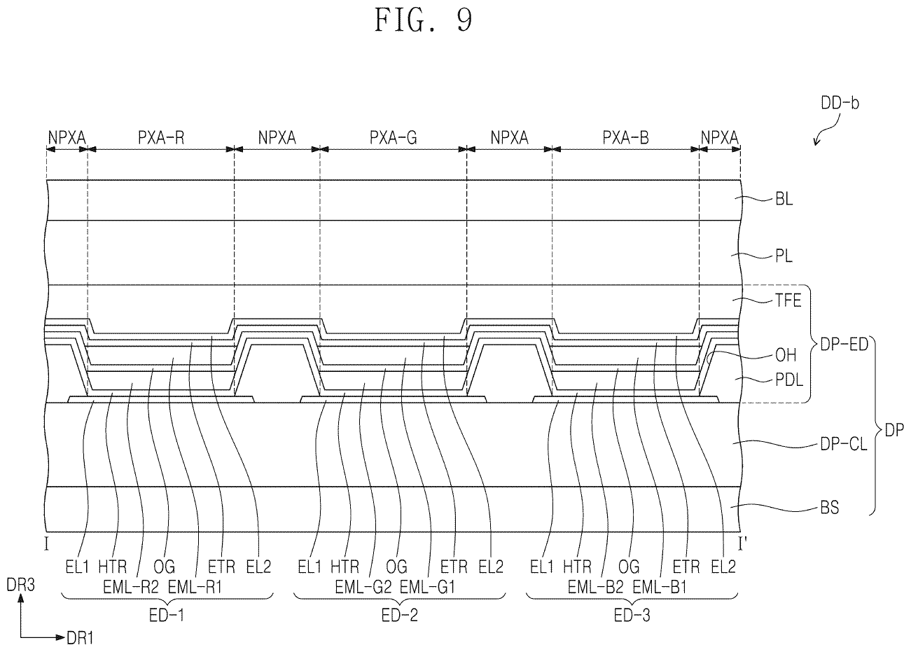

Referring to FIG. 9, a display device DD-b according to an embodiment may include light-emitting elements ED-1, ED-2, and ED-3, in which two emission layers are stacked. Compared to the display device DD of an embodiment, shown in FIG. 2, an embodiment shown in FIG. 9 differs in that each of the first to third light-emitting elements ED-1, ED-2, and ED-3 includes two emission layers stacked in a thickness direction. Two emission layers in each of the first to third light-emitting elements ED-1, ED-2, and ED-3 may emit light having the same wavelength range.

At least one among the light-emitting elements ED-1, ED-2, and ED-3 may include the fused polycyclic compound represented by Formula 1 of an embodiment. At least one among the light-emitting elements ED-1, ED-2, and ED-3, including the fused polycyclic compound represented by Formula 1 of an embodiment may exhibit high emission efficiency.

The first light-emitting element ED-1 may include a first red emission layer EML-R1 and a second red emission layer EML-R2. The second light-emitting element ED-2 may include a first green emission layer EML-G1 and a second green emission layer EML-G2. In addition, the third light-emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light-emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be disposed between the emission auxiliary part OG and the electron transport region ETR. The second red emission layer EML-R2, the second green emission layer EML-G2, and the second blue emission layer EML-B2 may be disposed between the hole transport region HTR and the emission auxiliary part OG.

That is, the first light-emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light-emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light-emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

An optical auxiliary layer PL may be disposed on the display element layer DP-ED. The optical auxiliary layer PL may include a polarizing layer. The optical auxiliary layer PL may be disposed on the display panel DP and control reflected light in the display panel DP due to external light. Unlike the configuration illustrated, the optical auxiliary layer PL in the display device according to an embodiment may be omitted.

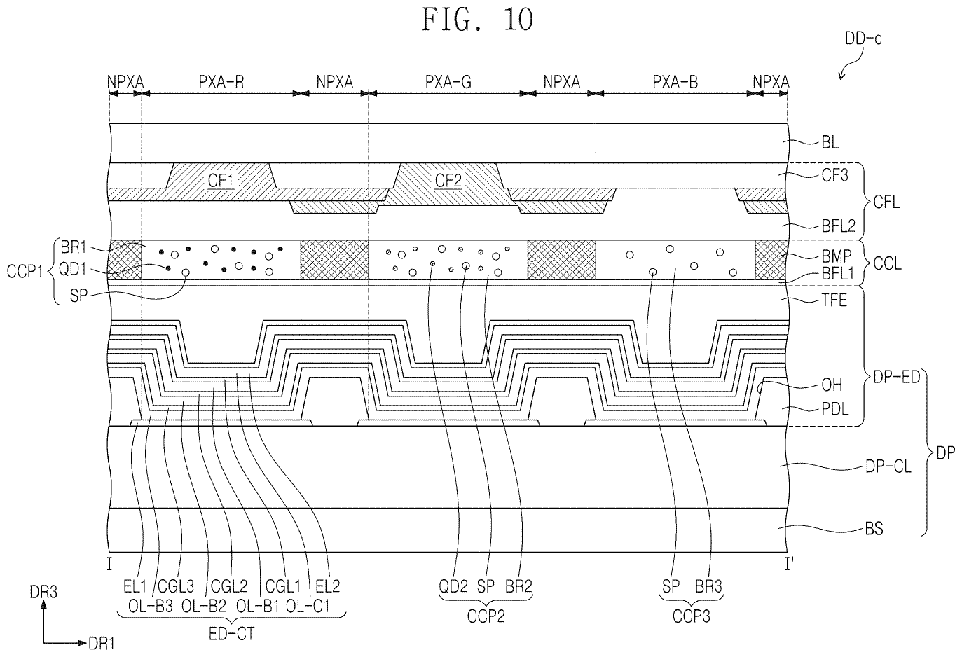

Different from FIG. 8 and FIG. 9, a display device DD-c in FIG. 10 is shown to include four light emitting structures OL-B1, OL-B2, OL-B3, and OL-C1. A light-emitting element ED-CT may include oppositely disposed first electrode EL1 and second electrode EL2, and first to fourth light emitting structures OL-B1, OL-B2, OL-B3, and OL-C1 stacked in order in a thickness direction between the first electrode EL1 and the second electrode EL2. At least one among the first to fourth light emitting structures OL-B1, OL-B2, OL-B3, and OL-C1 may include the fused polycyclic compound represented by Formula 1 of an embodiment. The light-emitting element ED-CT including the fused polycyclic compound represented by Formula 1 of an embodiment may exhibit high emission efficiency.

Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may emit a blue light, and the fourth light emitting structure OL-C1 may emit a green light. However, embodiments are not limited thereto, and the first to fourth light emitting structures OL-B1, OL-B2, OL-B3, and OL-C1 may emit light beams in different wavelength regions.

The charge generation layers CGL1, CGL2, and CGL3 disposed between adjacent light emitting structures OL-B1, OL-B2, OL-B3, and OL-C1 may include a p-type charge generation layer and/or an n-type charge generation layer.

In an embodiment, an electronic device may include a display device including multiple light-emitting elements and a control part controlling the display device. The electronic device of an embodiment may be a device activated according to electrical signals. The electronic device may include display devices of various embodiments. For example, the electronic devices may include large-size display devices such as televisions, monitors, and outside billboards, and medium- and small-size display devices such as personal computers, laptop computers, personal digital terminals, display apparatuses for automobiles, game consoles, portable electronic devices, and cameras.

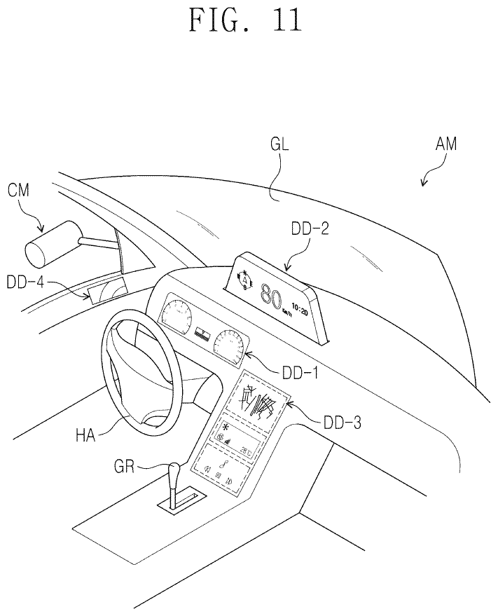

FIG. 11 is a diagram showing an automobile AM in which first to fourth display devices DD-1, DD-2, DD-3, and DD-4 are disposed. At least one among the first to fourth display devices DD-1, DD-2, DD-3, and DD-4 may include the same configurations as those of the display devices DD, DD-TD, DD-a, DD-b, and DD-c of embodiments, explained referring to FIGS. 1, 2, and 7 to 10.

In FIG. 11, a vehicle is shown as an automobile AM, but this is an illustration, and the first to fourth display devices DD-1, DD-2, DD-3, and DD-4 may be disposed on other transport means such as bicycles, motorcycles, trains, ships, and airplanes. In addition, at least one among the first to fourth display devices DD-1, DD-2, DD-3, and DD-4 including the same configurations as those of the display devices DD, DD-TD, DD-a, DD-b, and DD-c may be introduced in personal computers, laptop computers, personal digital terminals, game consoles, portable electronic devices, televisions, monitors, external billboards, or the like. In addition, these are suggested as examples, and the display device may be introduced in other electronic devices.

At least one among the first to fourth display devices DD-1, DD-2, DD-3, or DD-4 may include the light-emitting element ED, explained by referring to FIG. 3 to FIG. 6. At least one among the first to fourth display devices DD-1, DD-2, DD-3, or DD-4 may include the fused polycyclic compound represented by Formula 1 of an embodiment. A display device including the fused polycyclic compound represented by Formula 1 of an embodiment (at least one among the first to fourth display devices DD-1, DD-2, DD-3, and DD-4) may show excellent display quality.

Referring to FIG. 11, the vehicle AM may include a steering wheel HA and a gear GR for driving the vehicle AM. In addition, the vehicle AM may include a front window GL disposed so as to face the driver.

The first display device DD-1 may be disposed in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, or the like. A first scale and a second scale may be indicated as a digital image.

The second display device DD-2 may be disposed in a second region facing the driver's seat and overlapping the front window GL. The driver's seat may be a seat in which the steering wheel HA is disposed. For example, the second display device DD-2 may be a head up display (HUD) which displays second information of the vehicle AM. The second display device DD-2 may be optically transparent. The second information may include digital numbers which indicate a driving speed, and may further include information such as the current time. Unlike the configuration illustrated, the second information of the second display device DD-2 may be projected to the front window GL to be displayed.

The third display device DD-3 may be disposed in a third region adjacent to the gear GR. For example, the third display device DD-3 may be disposed between the driver's seat and the passenger seat and may be a center information display (CID) for a vehicle for displaying third information. The passenger seat may be a seat spaced apart from the driver's seat with the gear GR disposed therebetween. The third information may include information about traffic (e.g., navigation information), playing music or radio or a video (or an image), temperatures inside the vehicle AM, or the like.

The fourth display device DD-4 may be spaced apart from the steering wheel HA and the gear GR, and may be disposed in a fourth region adjacent to the side of the vehicle AM. For example, the fourth display device DD-4 may be a digital side-view mirror which displays fourth information. The fourth display device DD-4 may display an image outside the vehicle AM taken by a camera module CM disposed outside the vehicle AM. The fourth information may include an image outside the vehicle AM.

The above-described first to fourth information may be examples, and the first to fourth display devices DD-1, DD-2, DD-3, and DD-4 may further display information about the inside and outside of the vehicle AM. The first to fourth information may include different information. However, embodiments are not limited thereto, and a part of the first to fourth information may include the same information as one another.

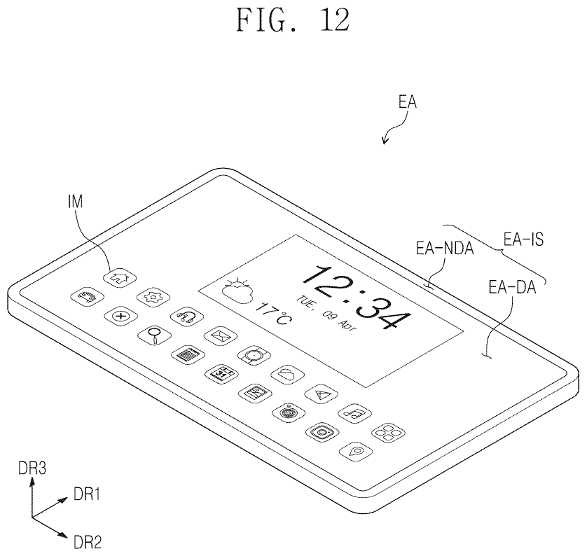

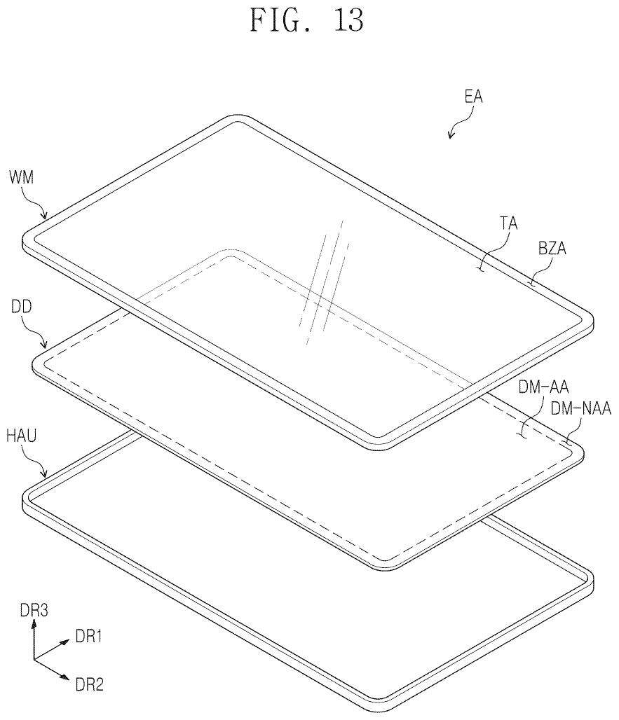

FIG. 12 is a perspective view illustrating an electronic apparatus according to an embodiment. FIG. 13 is an exploded perspective view illustrating an electronic apparatus according to an embodiment.

FIG. 12 illustrates a portable electronic apparatus as an example of an electronic apparatus EA. The electronic apparatus EA may display an image IM through a display surface EA-IS. The image IM may include a still image as well as a dynamic image. The display surface EA-IS may be parallel to a plane defined by a first direction axis DR1 and a second direction axis DR2. FIG. 12 illustrates the electronic apparatus EA equipped with a flat display surface EA-IS, but embodiments are not limited thereto. For example, the electronic apparatus EA may include a curved display surface or three-dimensional display surface. The three-dimensional display surface may include a plurality of display regions indicating different directions.

The display surface EA-IS may include a display region EA-DA and a non-display region EA-NDA. The electronic apparatus EA may display an image IM through the display region EA-DA.

The non-display region EA-NDA may not be an optically transparent and may have a color. The non-display region EA-NDA may be adjacent to the display region EA-DA. The non-display region EA-NDA may surround the display region EA-DA. Therefore, the shape of the display region EA-DA may be defined substantially by the non-display region EA-NDA. However, FIG. 12 illustrates an example, and thus the non-display region EA-NDA may be disposed adjacent to only one side of the display region EA-DA and may be omitted.

Referring to FIG. 13, the electronic apparatus EA may include a display device DD. In addition, the electronic apparatus EA may further include a window member WM and a housing HAU.

The window member WM may cover an entire exterior of the electronic apparatus EA. The window member WM may include a transmission region TA, and a bezel region BZA. A front surface of the window member WM including the transmission region TA and the bezel region BZA may correspond to a front surface of the electronic apparatus EA. The transmission region TA may correspond to the display region EA-DA of the electronic apparatus EA illustrated in FIG. 12, and the bezel region BZA may correspond to the non-display region EA-NDA of the electronic apparatus EA illustrated in FIG. 12.

The transmission region TA may be an optically transparent region. The bezel region BZA may be a region having a relatively lower light transmittance than the transmission region TA. The bezel region BZA may not be an optically transparent and may have a predetermined color. The bezel region BZA may be adjacent to the transmission region TA and surround the transmission region TA. The bezel region BZA may define the shape of the transmission region TA. However, embodiments are not limited to what is illustrated in the drawings, and the bezel region BZA may be disposed adjacent to only one side of the transmission region TA, or a portion thereof may be omitted.

The housing HAU may include a material having a relatively high rigidity. For example, the housing HAU may include a frame and/or plate composed of glass, plastic, or metal. The frame and/or plate may be provided in plurality. The housing HAU may provide an accommodation space. The display device DD may be accommodated in the accommodation space to be protected from an external impact.

The display device DD includes the same configuration as at least one among the display devices DD, DD-TD, DD-a, DD-b, and DD-c, according to embodiments, described with reference to FIGS. 1, 2, and 7 to 10. The display device DD may include the light-emitting element ED described with reference to FIG. 3 to FIG. 6. Therefore, the electronic apparatus EA including the display device DD according to an embodiment may exhibit excellent reliability.

The display device DD may be activated in response to an electrical signal and may provide an image IM (FIG. 12). The display device DD may be activated and display an image IM (FIG. 12) in the display region EA-DA (FIG. 12) of the electronic apparatus EA. An active region DM-AA and a peripheral region DM-NAA may be defined in the display device DD. The active region DM-AA may overlap the display region EA-DA illustrated in FIG. 12, and the peripheral region DM-NAA may overlap the non-display region EA-NDA illustrated in FIG. 12.

The active region DM-AA may be a region activated in response to an electrical signal. The peripheral region DM-NAA may be a region disposed adjacent to at least one side of the active region DM-AA. The active region DM-AA may include a non-emission region NPXA and emission regions PXA-R, PXA-G, and PXA-B, illustrated in FIG. 1. The peripheral region DM-NAA may be disposed to surround the active region DM-AA. However, embodiments are not limited thereto, and unlike what is illustrated, a portion of the peripheral region DM-NAA may be omitted. In the peripheral region DM-NAA, a driving circuit, a driving line, or the like for driving the active region DM-AA may be disposed.

The display devices DD, DD-TD, DD-a, DD-b, and DD-c, according to embodiments (FIGS. 1, 2, and 7 to 10) may be applied to various electronic apparatuses. The electronic apparatus EA according to an embodiment may include the above-described display devices DD, DD-TD, DD-a, DD-b, and DD-c (FIGS. 1, 2, and 7 to 10) and further include a module or device having an additional function in addition to the display devices DD, DD-TD, DD-a, DD-b, and DD-c (FIGS. 1, 2, and 7 to 10).

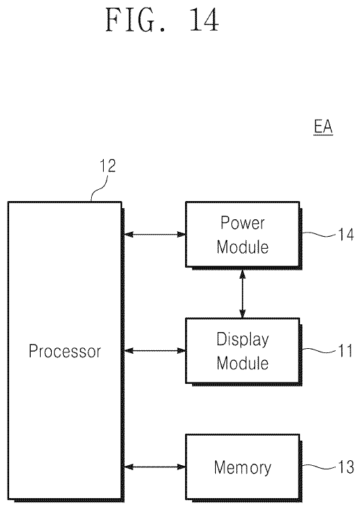

FIG. 14 is a block diagram of an electronic apparatus according to an embodiment. Referring to FIG. 14, the electronic apparatus EA according to an embodiment may include a display module 11, a processor 12, a memory 13, and a power module 14.

The processor 12 may include at least one among a central processing unit (CPU), an application processor (AP), a graphic processing unit (GPU), a communication processor (CP), an image signal processor (ISP), and a controller.

The memory 13 may store data information needed for the operation of the processor 12 or the display module 11. When the processor 12 executes an application stored in the memory 13, an image data signal and/or an input control signal are/is transmitted to the display module 11, and the display module 11 may process the received signal and output image information through a display screen.

The power module 14 may include a power supply module such as a power adaptor or a battery device, and a power conversion module that converts power supplied by the power supply module to generate power needed for the operation of the electronic apparatus EA.

At least one of the above-described components of the electronic apparatus EA may be included in the above-described display device according to embodiments. In addition, some of individual modules functionally included in one module may be included in the display device, and some others may be provided separately from the display device. For example, the display device may include the display module 11, and the processor 12, the memory 13 and the power module 14 may be provided in the form of other devices within the electronic apparatus EA, not the display device.

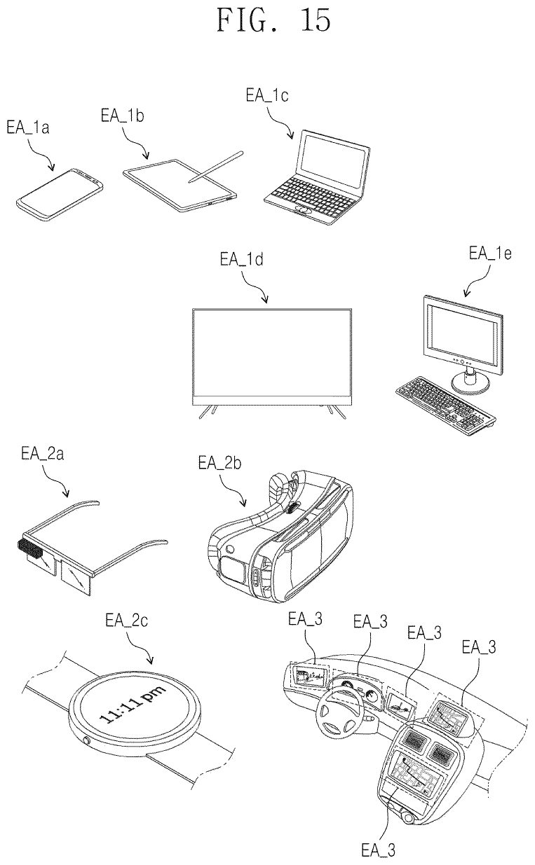

FIG. 15 illustrates schematic views of electronic apparatuses according to various embodiments. Referring to FIG. 15, various electronic apparatuses including the display device according to an embodiment may include not only an image-displaying electronic apparatus such as a smart phone EA_1a, a tablet PC EA_1b, a laptop computer EA_1c, a TV EA_1d, and a desktop monitor EA_1e, but also a wearable electronic apparatus such as smart glasses EA_2a, a head mounted display EA_2b, or a smart watch EA_2c, and a vehicular electronic apparatus EA_3 such as a car dashboard, a center fascia, a center information display (CID) disposed in a dashboard, or a room mirror display, or the like.

Hereinafter, with reference to Examples and Comparative Examples, the fused polycyclic compound represented by Formula 1 according to an embodiment of the inventive concept and the light-emitting element according to an embodiment will be described in further detail. In addition, Examples provided below are exemplified only for helping the understanding of the subject matter, and the scope of the subject matter is not limited thereto.

### EXAMPLES

### 1. Synthesis of Fused Polycyclic Compound According to Examples

Synthetic methods of the fused polycyclic compounds according to the present embodiments will be described in detail by exemplifying the synthetic methods of Fused Polycyclic Compounds 399, 109, 434, 217, 325, 397, 110, 112, 295, 296, 407, and 408. In addition, the synthetic methods of the fused polycyclic compounds described hereinbelow are examples, and a synthetic method of the compound according to embodiments are not limited to the examples below.

### (1) Synthesis of Fused Polycyclic Compound 399

Fused polycyclic compound 399 was synthesized according to Reaction Scheme 1.

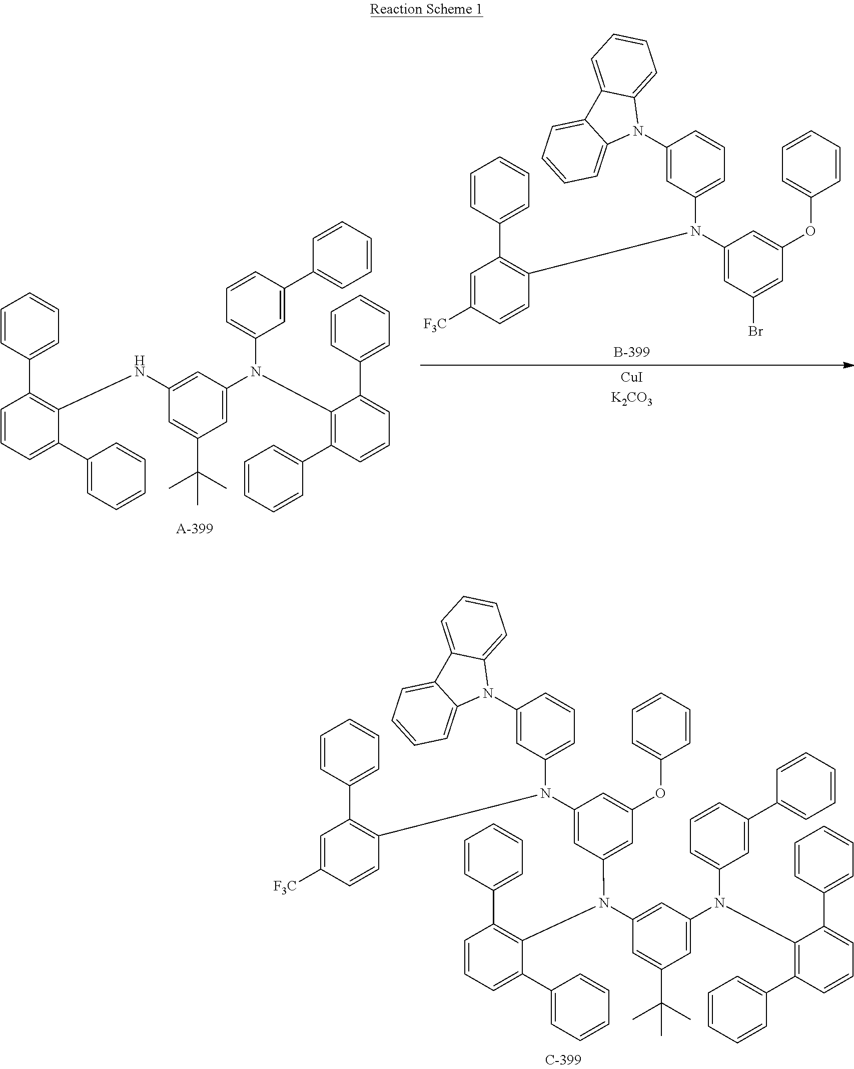

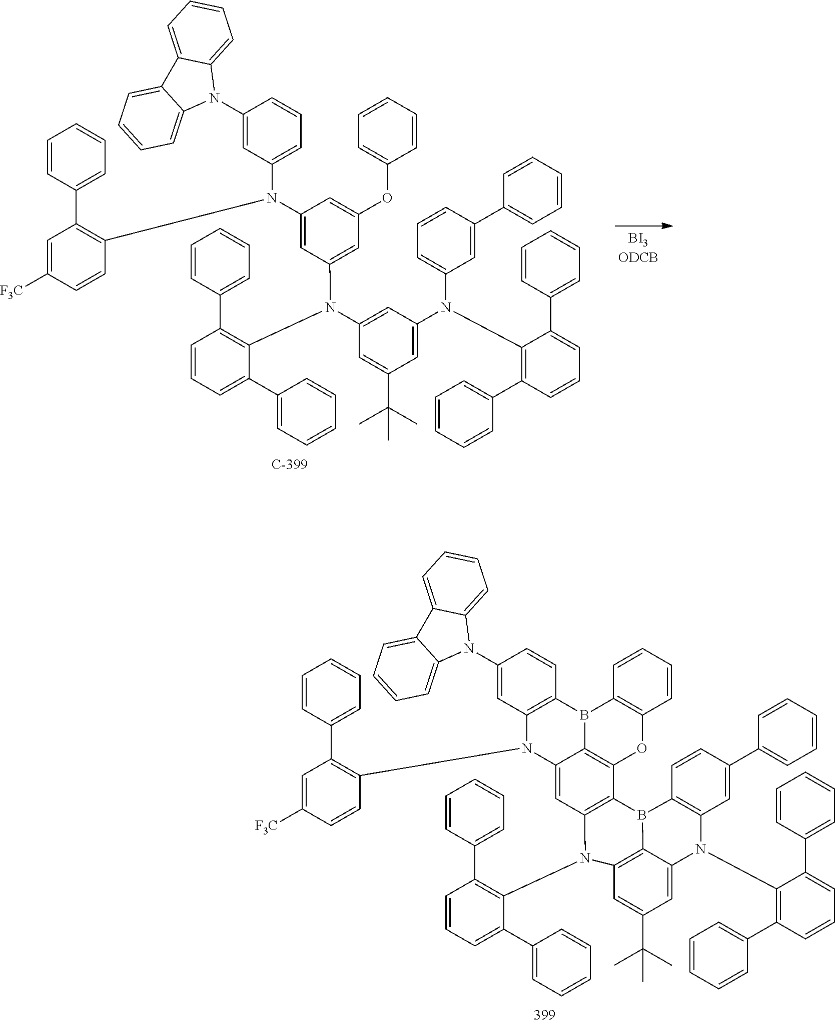 [SMILES: CC(C)(C)c1cc(N(c2cccc(-c3ccccc3)c2)c2c(-c3ccccc3)cccc2-c2ccccc2)cc(N(c2cc(Oc3ccccc3)cc(N(c3cccc(-n4c5ccccc5c5ccccc54)c3)c3ccc(C(F)(F)F)cc3-c3ccccc3)c2)c2c(-c3ccccc3)cccc2-c2ccccc2)c1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1ccc(-n2c3ccccc3c3ccccc32)cc1N4c1ccc(C(F)(F)F)cc1-c1ccccc1]

Compound A-399 (21.4 millimoles (mmol)), Compound B-399 (21.4 mmol), K₂CO₃ (128 mmol), and CuI (85.5 mmol) were added to a three-necked flask, the flask was purged with Ar, and then the mixture was stirred at about 230° C. for about 72 hours. Toluene was added to the reaction system to extract an organic material. The extracted organic material was filtered, and a solvent was removed under reduced pressure. The obtained crude product was purified through silica gel chromatography (hexane/CH₂Cl₂) to obtain Compound C-399 (10.7 mmol, yield of 50%).

Compound C-399 (10.7 mmol) was added to a three-necked flask, the flask was purged with Ar, then ortho-dichlorobenzene (ODCB) (70 mL) was added and dissolved, then BI₃ (42.5 mmol) was added, and the mixture was stirred at 120° C. for about 4 hours. The reaction solution was returned to room temperature, diisopropylethylamine (30 mL) was added to quench the reaction, the reaction solution was filtered through silica gel, and the solvent was removed under reduced pressure. The obtained crude product was purified through silica gel chromatography (hexane/CH₂Cl₂) to obtain Fused Polycyclic Compound 399 (4.40 mmol, yield of 43%). Fast atom bombardment-mass spectrometry (FAB-MASS) m/z: 1432.56.

### (2) Synthesis of Fused Polycyclic Compound 109

Fused polycyclic compound 109 was synthesized according to Reaction Scheme 2.

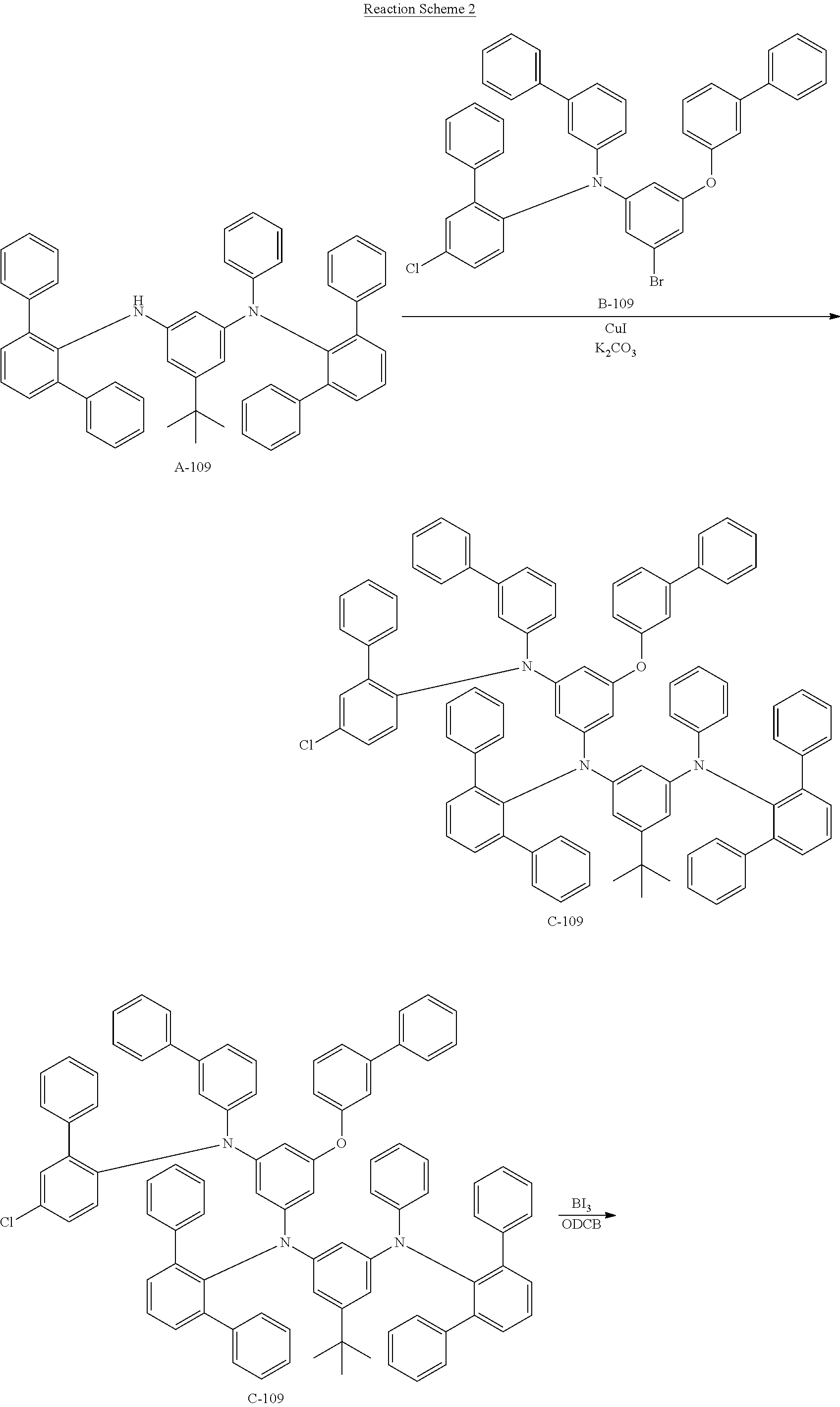

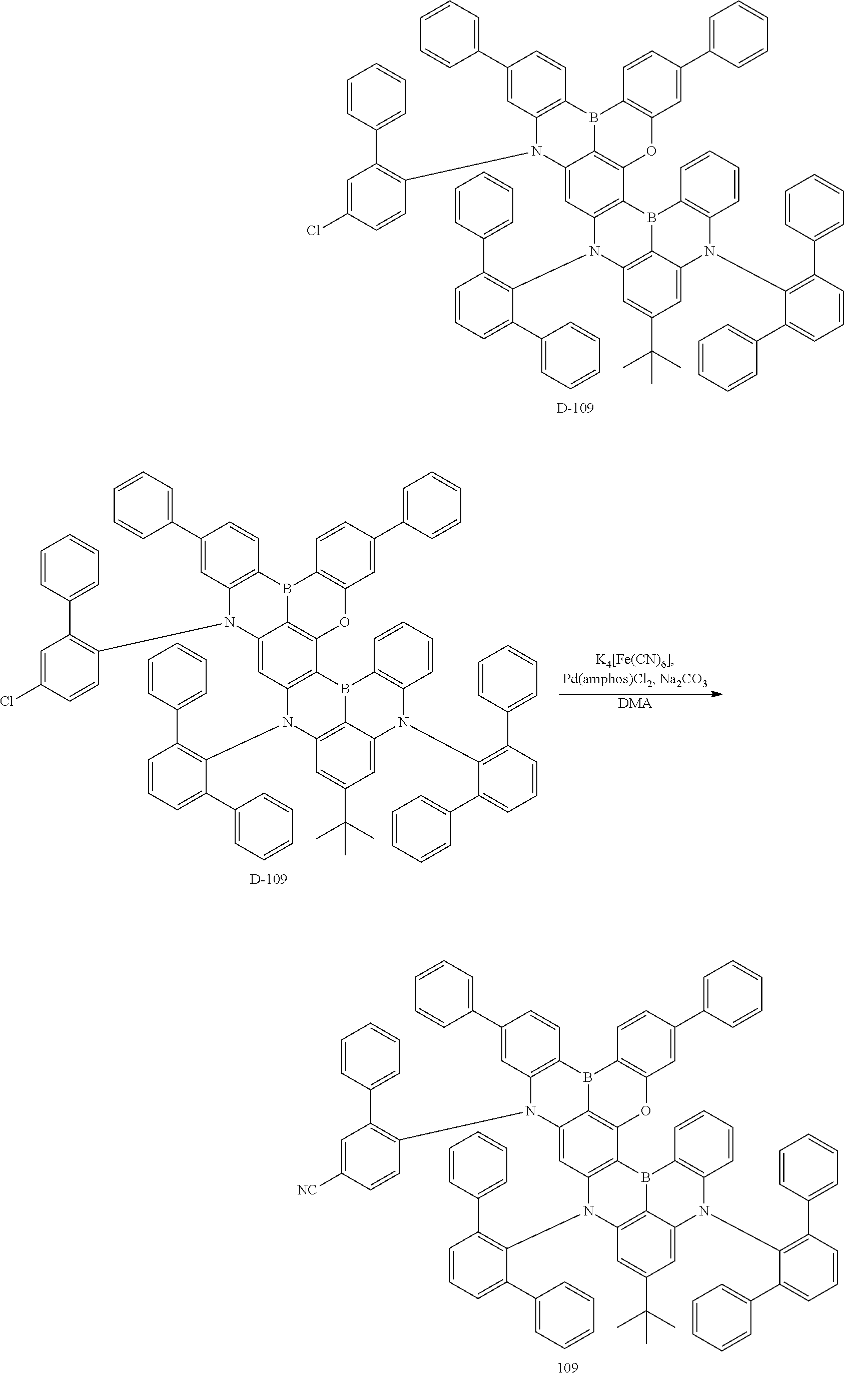

Compound A-109 (12.4 mmol), Compound B-109 (12.4 mmol), K₂CO₃ (74.3 mmol), and CuI (49.5 mmol) were added to a three-necked flask, the flask was purged with Ar, and then the mixture was stirred at about 230° C. for about 72 hours. Toluene was added to the reaction system to extract an organic material. The extracted organic material was filtered, and the solvent was removed under reduced pressure. The obtained crude product was purified through silica gel chromatography (hexane/CH₂Cl₂) to obtain Compound C-109 (5.69 mmol, yield of 46%).

Compound C-109 (5.69 mmol) was added to a three-necked flask, the flask was purged with Ar, then ODCB (40 mL) was added and dissolved, then BI₃ (22.8 mmol) was added, and the mixture was stirred at 120° C. for about 4 hours. The reaction solution was returned to room temperature, diisopropylethylamine (16 mL) was added to quench the reaction, the reaction solution was filtered through silica gel, and a solvent was removed under reduced pressure. The obtained crude product was purified through silica gel chromatography (hexane/CH₂Cl₂) to obtain Compound D-109 (2.39 mmol, yield of 42%).

Compound D-109 (2.39 mmol), K₄[Fe(CN)₆] (4.78 mmol), Pd(amphos)Cl₂ (0.240 mmol), and Na₂CO₃ (9.56 mmol) were added to a three-necked flask, the flask was purged with Ar, then dimethylacetamide (DMA, 24 mL) was added, and then the mixture was stirred at about 130° C. for about 4 hours. Water was added to the reaction solution, and an organic layer was extracted by using toluene. The extracted organic layer was dried over MgSO₄, the product was filtered, and the solvent was removed under reduced pressure. The obtained crude product was purified through silica gel chromatography (hexane/CH₂Cl₂) to obtain Fused Polycyclic Compound 109 (0.790 mmol, yield of 33%). FAB-MASS m/z: 1300.54.

### (3) Synthesis of Fused Polycyclic Compound 434

Fused polycyclic compound 434 was synthesized according to Reaction Scheme 3.

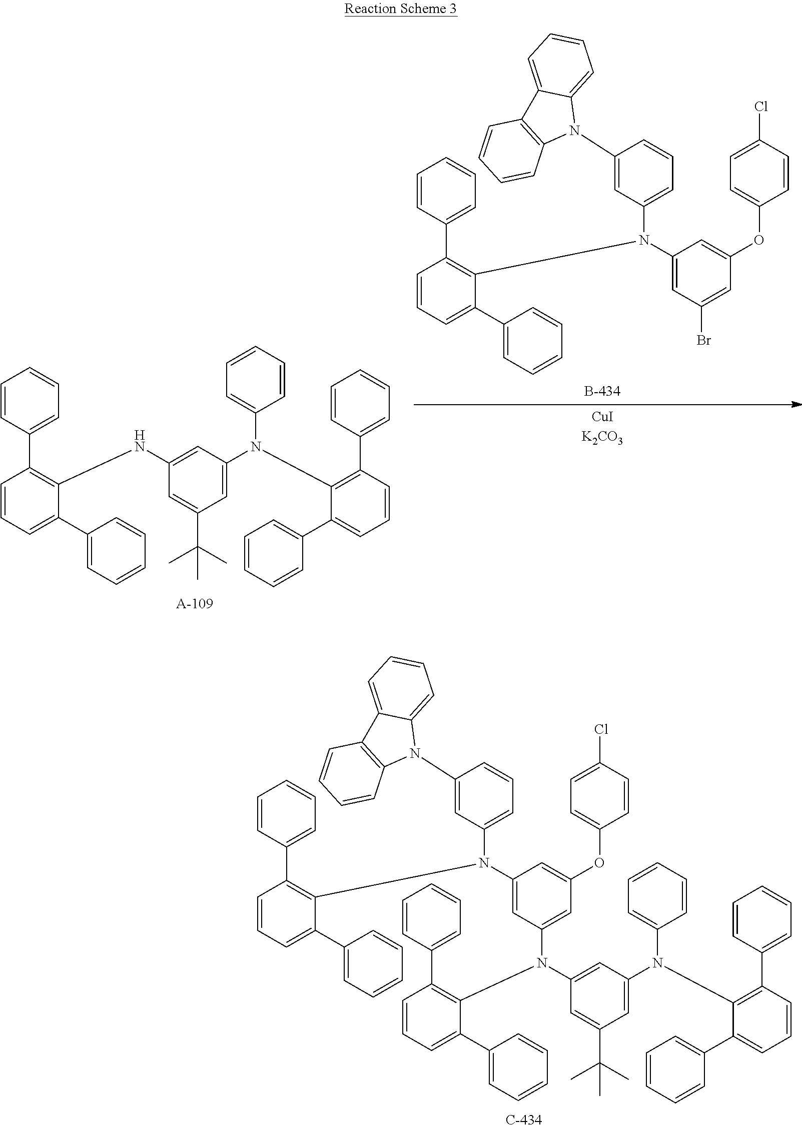

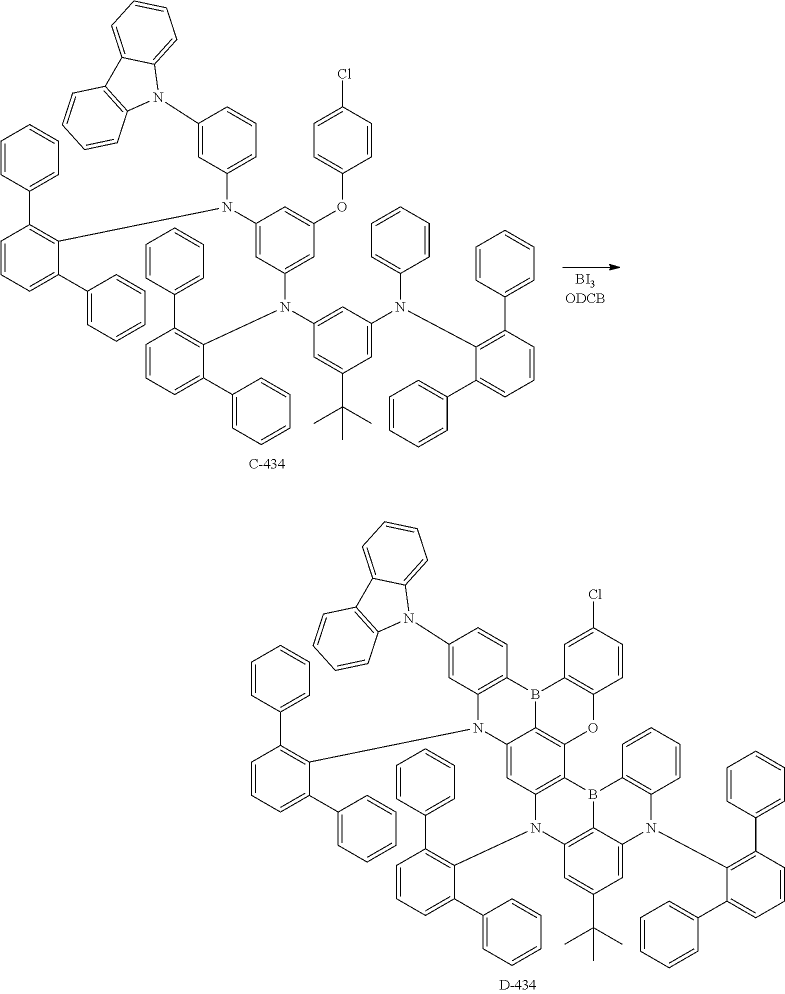 [SMILES: CC(C)(C)c1cc(N(c2ccccc2)c2c(-c3ccccc3)cccc2-c2ccccc2)cc(N(c2cc(Oc3ccc(Cl)cc3)cc(N(c3cccc(-n4c5ccccc5c5ccccc54)c3)c3c(-c4ccccc4)cccc3-c3ccccc3)c2)c2c(-c3ccccc3)cccc2-c2ccccc2)c1 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1ccc(Cl)cc1B5c1ccc(-n2c3ccccc3c3ccccc32)cc1N4c1c(-c2ccccc2)cccc1-c1ccccc1]

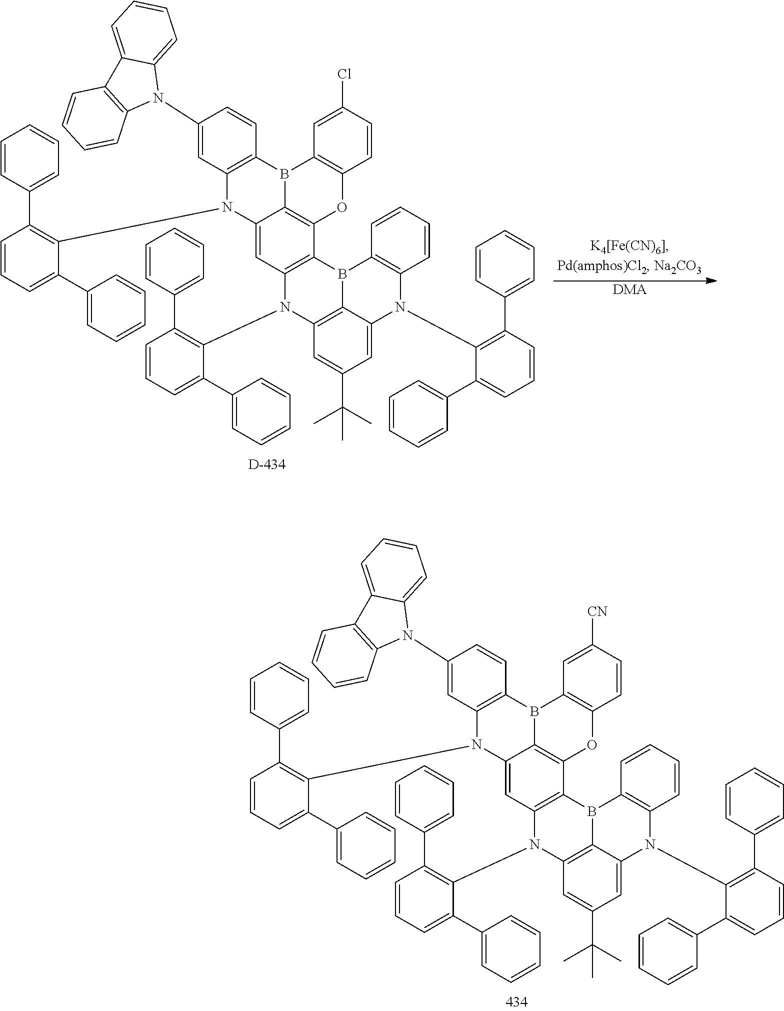

Compound A-109 (51.0 mmol), Compound B-434 (60.8 mmol), K₂CO₃ (307 mmol), and CuI (205 mmol) were added to a three-necked flask, the flask was purged with Ar, and then the mixture was stirred at about 230° C. for about 120 hours. Toluene was added to the reaction system to extract an organic material. Then, the extracted organic material was filtered, and the solvent was removed under reduced pressure. The obtained crude product was purified through silica gel chromatography (hexane/CH₂Cl₂) to obtain Compound C-434 (12.8 mmol, yield of 25%).

Compound C-434 (12.8 mmol) was added to a three-necked flask, the flask was purged with Ar, then ODCB (85 mL) was added and dissolved, then BI₃ (51.0 mmol) was added, and the mixture was stirred at 120° C. for about 5 hours. The reaction solution was returned to room temperature, diisopropylethylamine (35 mL) was added to quench the reaction, the reaction solution was filtered through silica gel, and the solvent was removed under reduced pressure. The obtained crude product was purified through silica gel chromatography (hexane/CH₂Cl₂) to obtain Compound D-434 (5.12 mmol, yield of 40%).

Compound D-434 (5.12 mmol), K₄[Fe(CN)₆] (10.2 mmol), Pd(amphos)Cl₂ (0.512 mmol), and Na₂CO₃ (20.4 mmol) were added to a three-necked flask, the flask was purged with Ar, then dimethylacetamide (DMA, 50 mL) was added, and then the mixture was stirred at about 130° C. for about 4 hours. Water was added to the reaction solution, and an organic layer was extracted by using toluene. The extracted organic layer was dried over MgSO₄ and the solvent was removed under reduced pressure. The obtained crude product was purified through silica gel chromatography (hexane/CH₂Cl₂) to obtain Fused Polycyclic Compound 434 (1.43 mmol, yield of 28%). FAB-MASS m/z: 1389.57.

### (4) Synthesis of Fused Polycyclic Compound 217

Fused polycyclic compound 217 was synthesized according to Reaction Scheme 4.

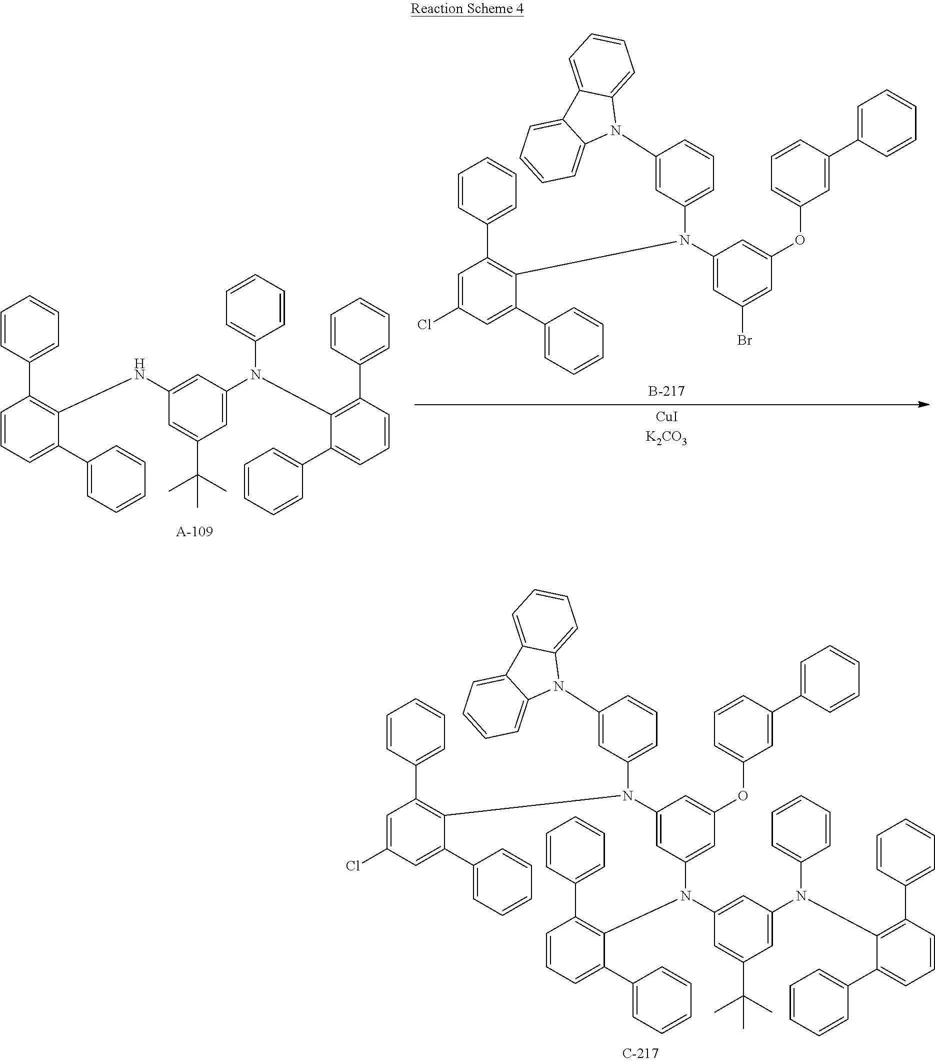

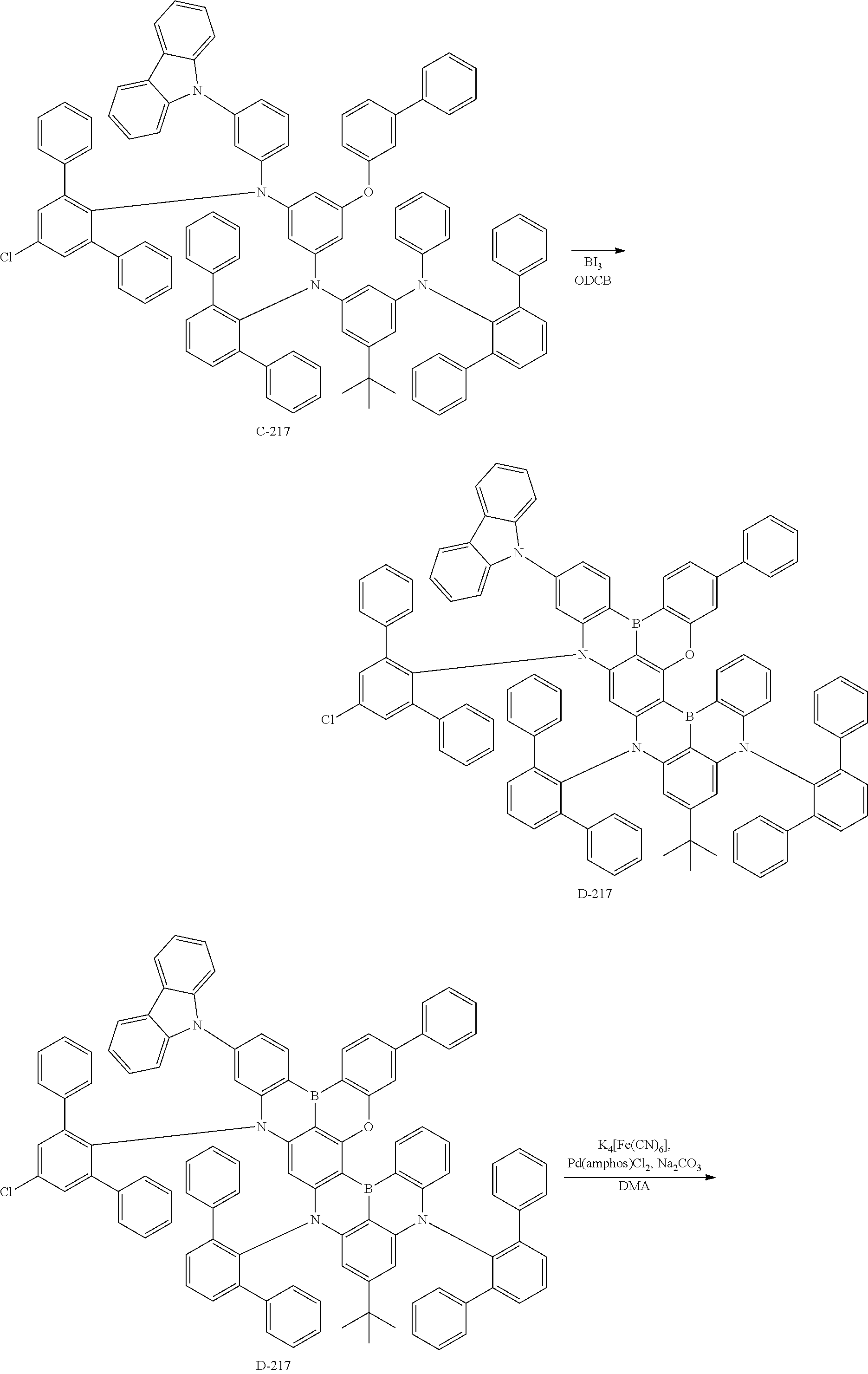

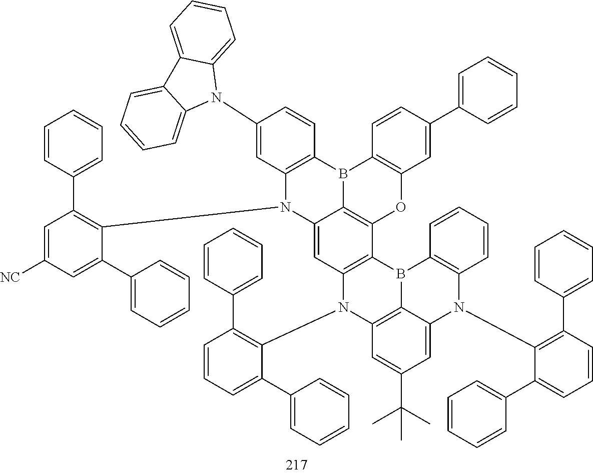 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-n2c3ccccc3c3ccccc32)cc1N4c1c(-c2ccccc2)cc(C#N)cc1-c1ccccc1]

Compound A-109 (20.4 mmol), Compound B-217 (20.4 mmol), K₂CO₃ (204 mmol), and CuI (102 mmol) were added to a three-necked flask, the flask was purged with Ar, and then the mixture was stirred at about 230° C. for about 120 hours. Toluene was added to the reaction system to extract an organic material. The extracted organic material was filtered, and the solvent was removed under reduced pressure. The obtained crude product was purified through silica gel chromatography (hexane/CH₂Cl₂) to obtain Compound C-217 (5.09 mmol, yield of 25%).

Compound C-217 (5.09 mmol) was added to a three-necked flask, the flask was purged with Ar, then ODCB (40 mL) was added and dissolved, then BI₃ (20.4 mmol) was added, and the mixture was stirred at 120° C. for about 3 hours. The reaction solution was returned to room temperature, diisopropylethylamine (14 mL) was added to quench the reaction, the reaction solution was filtered through silica gel, and the solvent was removed under reduced pressure. The obtained crude product was purified through silica gel chromatography (hexane/CH₂Cl₂) to obtain Compound D-217 (2.29 mmol, yield of 45%).

Compound D-217 (2.29 mmol), K₄[Fe(CN)₆] (4.58 mmol), Pd(amphos)Cl₂ (0.230 mmol), and Na₂CO₃ (9.16 mmol) were added to a three-necked flask, the flask was purged with Ar, then dimethylacetamide (DMA, 23 mL) was added, and the mixture was stirred at about 130° C. for about 3 hours. Water was added to the reaction solution, and an organic layer was extracted by using toluene. The extracted organic layer was dried over MgSO₄ and the solvent was removed under reduced pressure. The obtained crude product was purified through silica gel chromatography (hexane/CH₂Cl₂) to obtain Fused Polycyclic Compound 217 (0.687 mmol, yield of 30%). FAB-MASS m/z: 1465.60.

### (5) Synthesis of Fused Polycyclic Compound 325

Fused polycyclic compound 325 was synthesized according to Reaction Scheme 5.

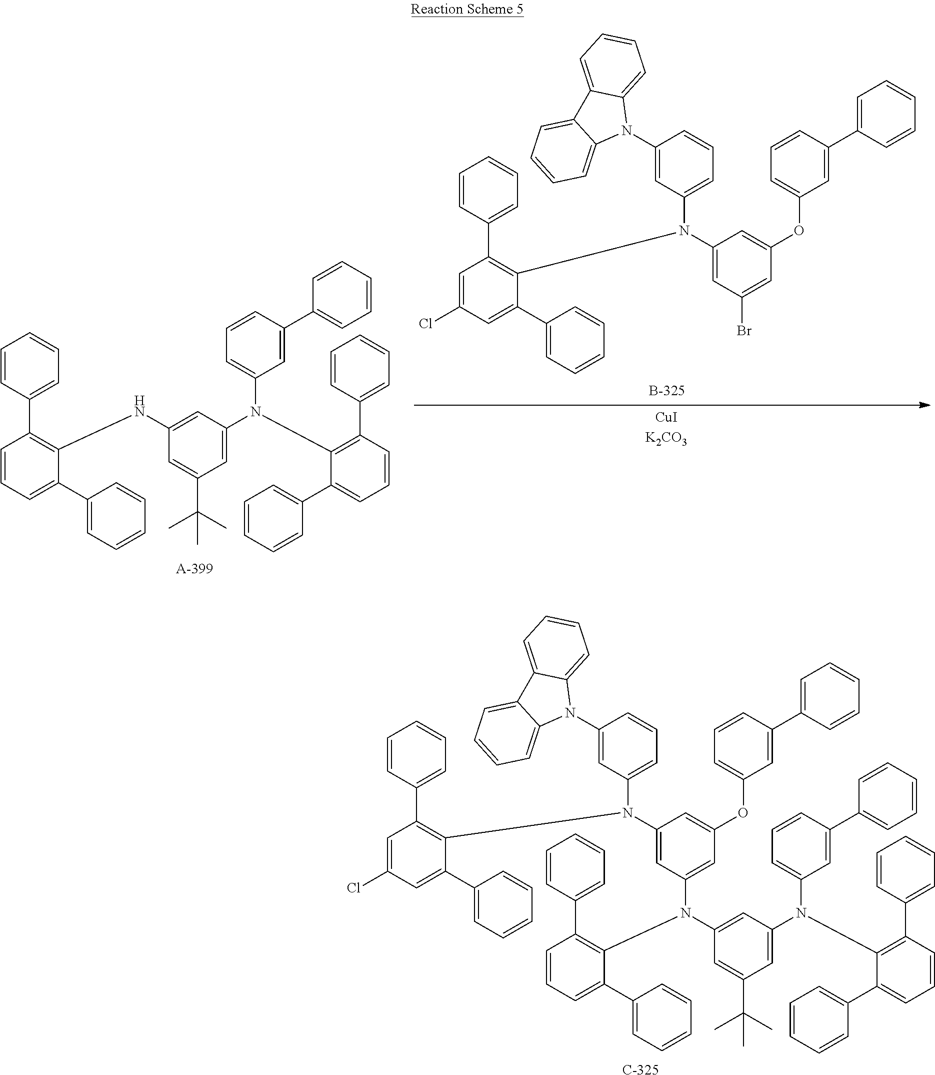

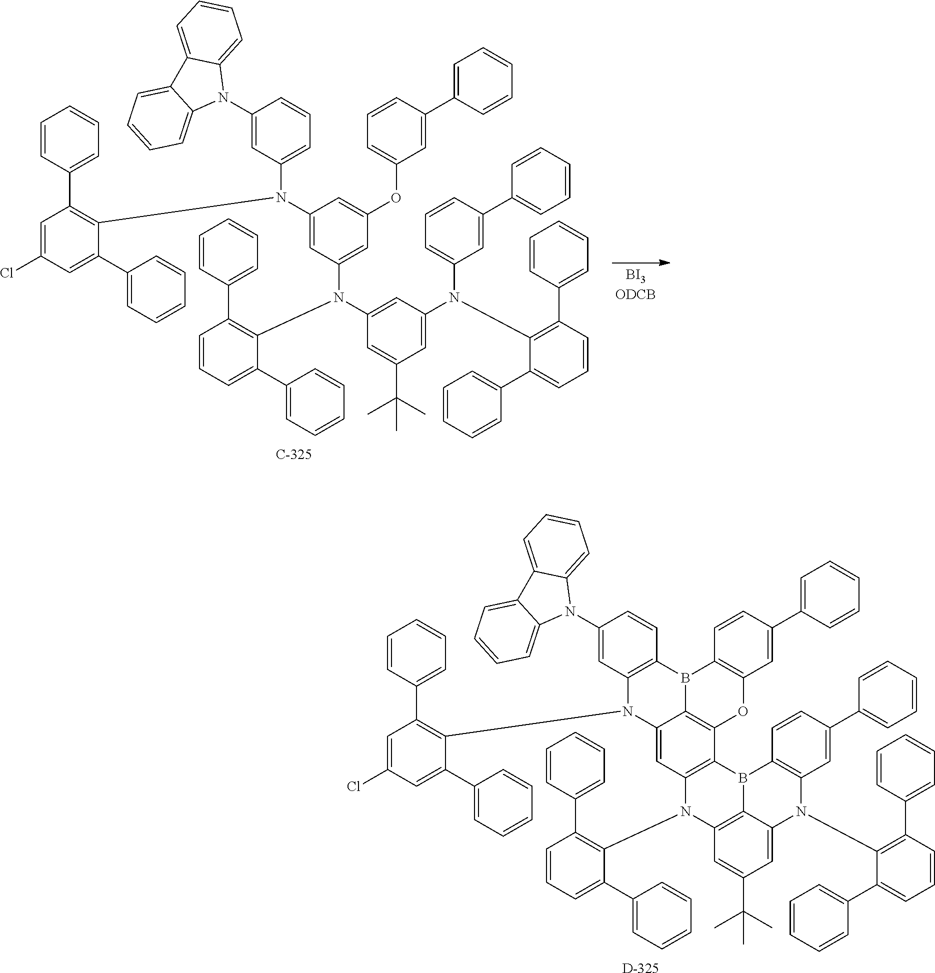

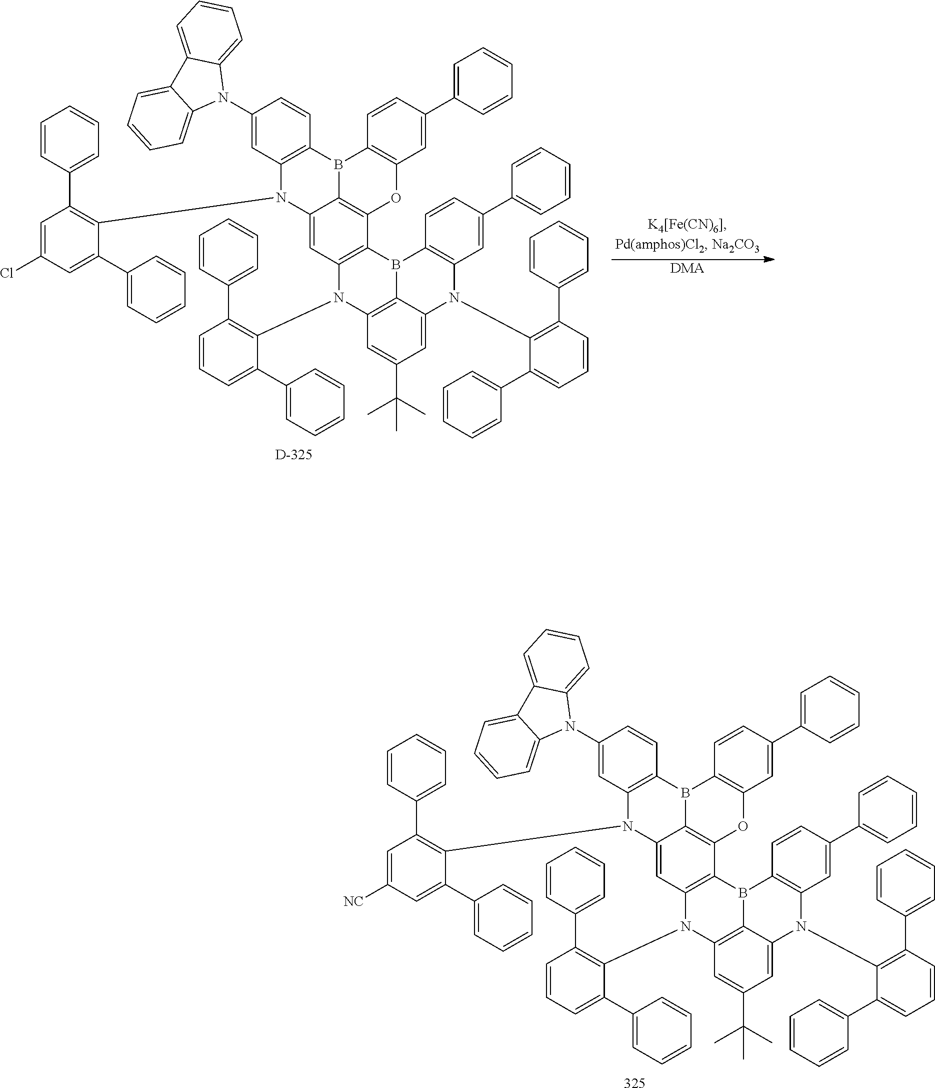

Compound A-399 (23.2 mmol), Compound B-325 (25.8 mmol), K₂CO₃ (232 mmol), and CuI (92.8 mmol) were added to a three-necked flask, the flask was purged with Ar, and then the mixture was stirred at about 230° C. for about 72 hours. Toluene was added to the reaction system to extract an organic material. The extracted organic layer was filtered, and the solvent was removed under reduced pressure. The obtained crude product was purified through silica gel chromatography (hexane/CH₂Cl₂) to obtain Compound C-325 (7.42 mmol, yield of 32%).

Compound C-325 (7.42 mmol) was added to a three-necked flask, the flask was purged with Ar, then ODCB (60 mL) was added and dissolved, then BI₃ (29.68 mmol) was added, and the mixture was stirred at 120° C. for about 4 hours. The reaction solution was returned to room temperature, diisopropylethylamine (45 mL) was added to quench the reaction, the reaction solution was filtered through silica gel, and the solvent was removed under reduced pressure. The obtained crude product was purified through silica gel chromatography (hexane/CH₂Cl₂) to obtain Compound D-325 (3.12 mmol, yield of 42%).

Compound D-325 (3.12 mmol), K₄[Fe(CN)₆] (6.24 mmol), Pd(amphos)Cl₂ (0.312 mmol), and Na₂CO₃ (12.5 mmol) were added to a three-necked flask, the flask was purged with Ar, then dimethylacetamide (DMA, 32 mL) was added, and then the mixture was stirred at about 130° C. for about 4 hours. Water was added to the reaction solution, and an organic layer was extracted by using toluene. The extracted organic layer was dried over MgSO₄ and the solvent was removed under reduced pressure. The obtained crude product was purified through silica gel chromatography (hexane/CH₂Cl₂) to obtain Fused Polycyclic Compound 325 (1.06 mmol, yield of 34%). FAB-MASS m/z: 1541.63.

### (6) Synthesis of Fused Polycyclic Compound 397

Fused polycyclic compound 397 was synthesized according to Reaction Scheme 6.

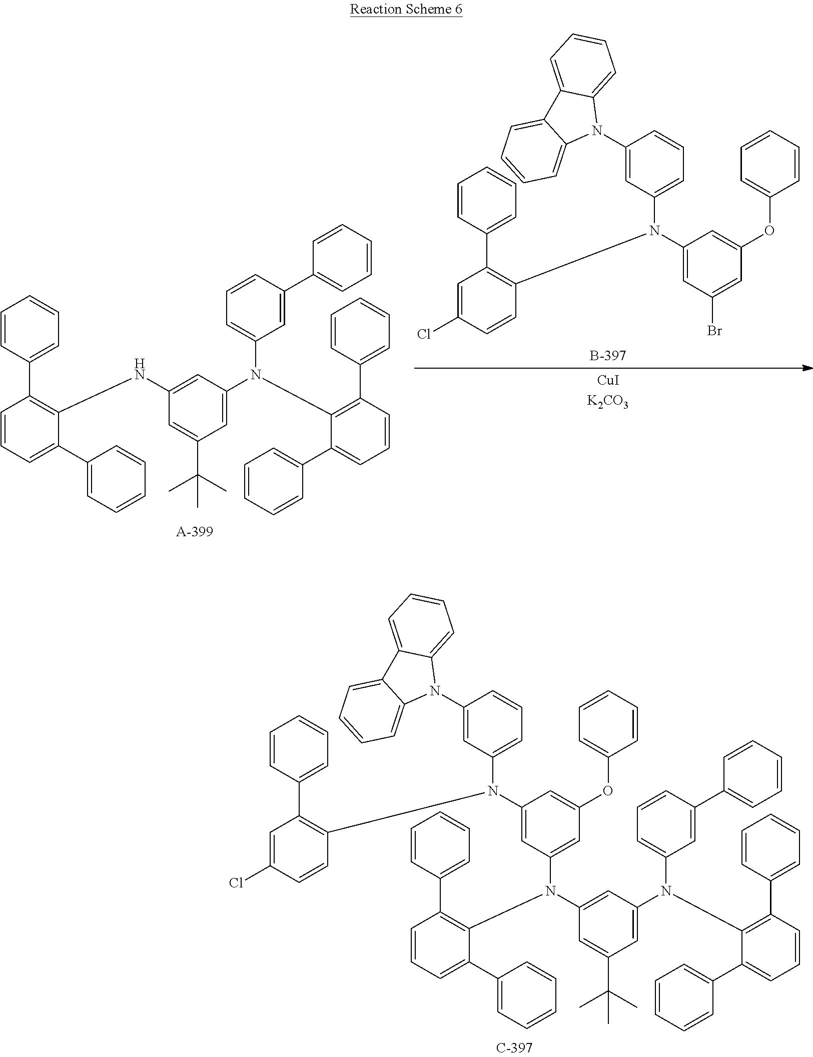

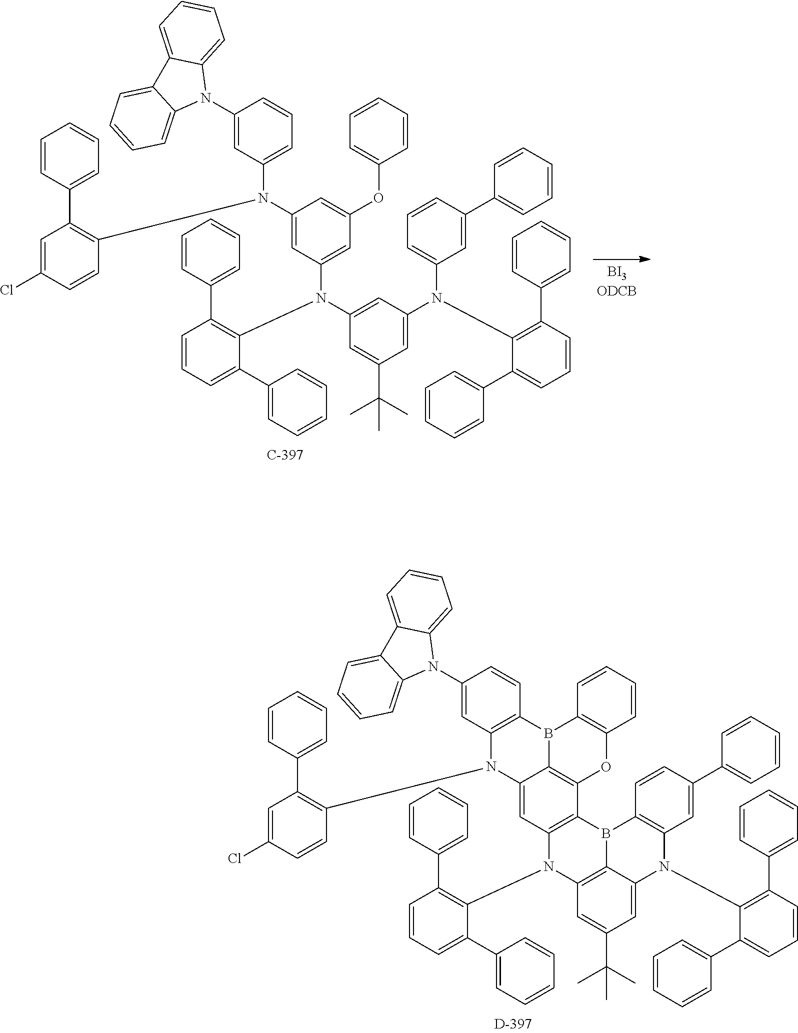 [SMILES: CC(C)(C)c1cc(N(c2cccc(-c3ccccc3)c2)c2c(-c3ccccc3)cccc2-c2ccccc2)cc(N(c2cc(Oc3ccccc3)cc(N(c3cccc(-n4c5ccccc5c5ccccc54)c3)c3ccc(Cl)cc3-c3ccccc3)c2)c2c(-c3ccccc3)cccc2-c2ccccc2)c1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1ccc(-n2c3ccccc3c3ccccc32)cc1N4c1ccc(Cl)cc1-c1ccccc1]

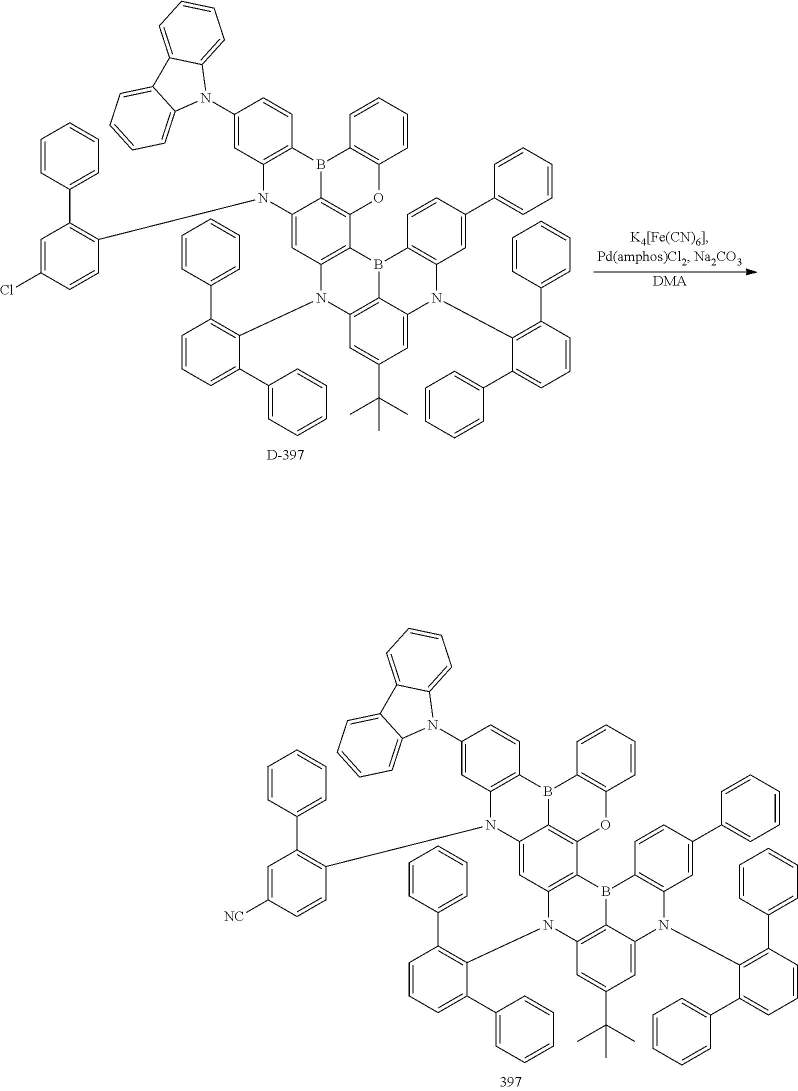

Compound A-399 (50.2 mmol), Compound B-397 (50.2 mmol), K₂CO₃ (100 mmol), and CuI (20.8 mmol) were added to a three-necked flask, the flask was purged with Ar, and then the mixture was stirred at about 230° C. for about 105 hours. Toluene was added to the reaction system to extract an organic material. The extracted organic material was filtered, and the solvent was removed under reduced pressure. The obtained crude product was purified through silica gel chromatography (hexane/CH₂Cl₂) to obtain Compound C-397 (14.1 mmol, yield of 28%).

Compound C-397 (14.1 mmol) was added to a three-necked flask, the flask was purged with Ar, then ODCB (100 mL) was added and dissolved, then BI₃ (56.4 mmol) was added, and the mixture was stirred at 120° C. for about 5 hours. The reaction solution was returned to room temperature, diisopropylethylamine (80 mL) was added to quench a reaction, the reaction solution was filtered through silica gel, and the solvent was removed under reduced pressure. The obtained crude product was purified through silica gel chromatography (hexane/CH₂Cl₂) to obtain Compound D-397 (5.64 mmol, yield of 40%).

Compound D-397 (5.64 mmol), K₄[Fe(CN)₆] (11.3 mmol), Pd(amphos)Cl₂ (0.564 mmol), and Na₂CO₃ (22.6 mmol) were added to a three-necked flask, the flask was purged with Ar, then dimethylacetamide (DMA, 55 mL) was added, and then the mixture was stirred at about 130° C. for about 3 hours. Water was added to a reaction solution, and an organic layer was extracted by using toluene. The extracted organic layer was dried over MgSO₄ to remove a solvent by distillation. The obtained crude product was purified through silica gel chromatography (hexane/CH₂Cl₂) to obtain Fused Polycyclic Compound 397 (1.63 mmol, yield of 29%). FAB-MASS m/z: 1541.63 FAB-MASS m/z: 1389.57.

### (7) Synthesis of Fused Polycyclic Compound 110

Fused poly cyclic compound 110 was synthesized according to Reaction Scheme 7.

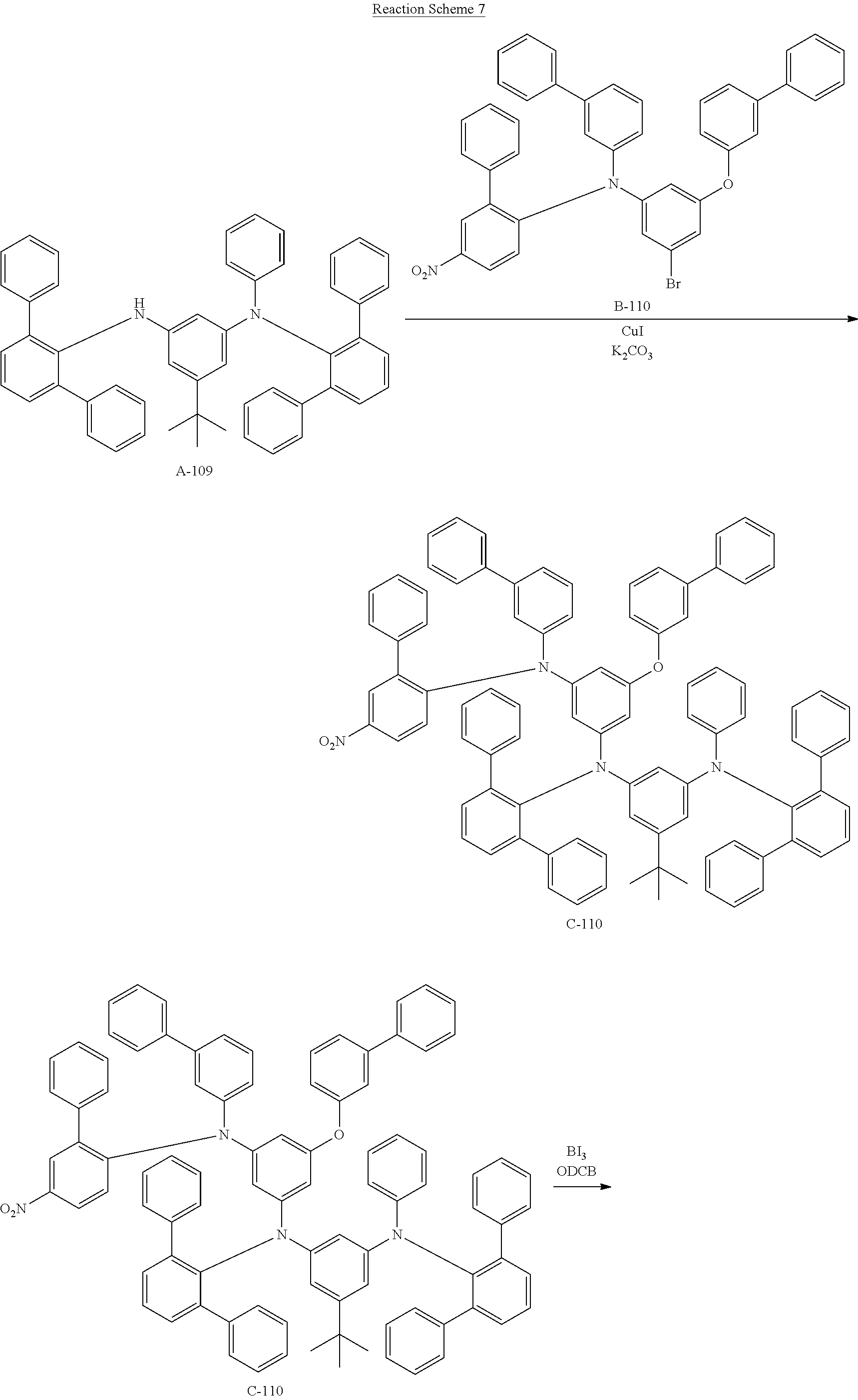

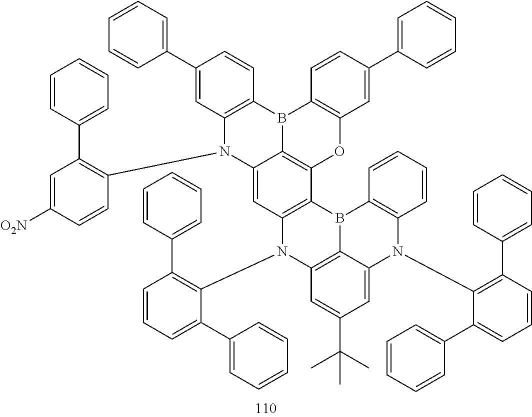 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-c2ccccc2)cc1N4c1ccc([N+](=O)[O-])cc1-c1ccccc1]

Compound A-109 (20.0 mmol), Compound B-110 (25 mmol), K₂CO₃ (200 mmol), CuI (80.0 mmol) were added to a three-necked flask, the flask was purged with Ar, and then the mixture was stirred at about 230° C. for about 80 hours. Toluene was added to the reaction system to extract an organic layer. The extracted organic layer was filtered, and the solvent was removed under reduced pressure. The obtained crude product was purified through silica gel chromatography (hexane/CH₂Cl₂) to obtain Compound C-110 (7.02 mmol, yield of 35%).

Compound C-110 (7.02 mmol) was added to a three-necked flask, the flask was purged with Ar, then ODCB (45 mL) was added and dissolved, then BI₃ (28.1 mmol) was added, and the mixture was stirred at 120° C. for about 4 hours. The reaction solution was returned to room temperature, diisopropylethylamine (40 mL) was added to quench the reaction, the reaction solution was filtered through silica gel, and the solvent was removed under reduced pressure. The obtained crude product was purified through silica gel chromatography (hexane/CH₂Cl₂) to obtain Fused Polycyclic Compound 110 (0.772 mmol, yield of 11%). FAB-MASS m/z: 1320.53.

### (8) Synthesis of Fused Polycyclic Compound 112

Fused polycyclic compound 112 was synthesized according to Reaction Scheme 8.

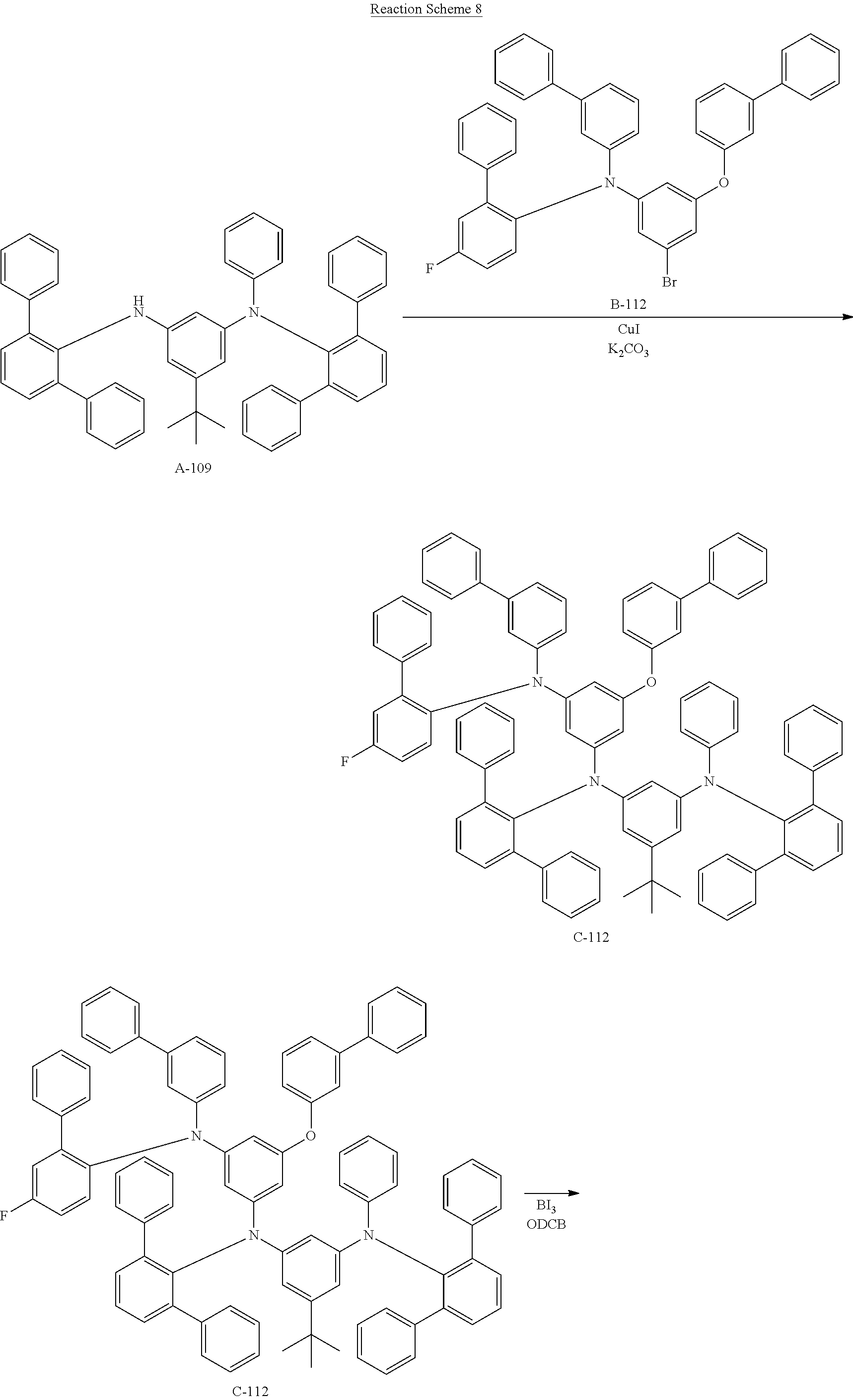

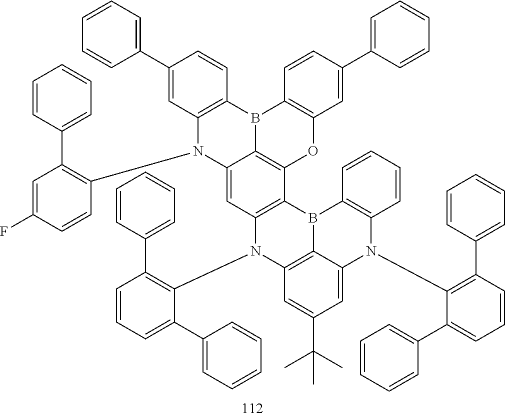 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1ccc(-c2ccccc2)cc1N4c1ccc(F)cc1-c1ccccc1]

Compound A-109 (25.3 mmol), Compound B-112 (25.3 mmol), K₂CO₃ (253 mmol), and CuI (101 mmol) were added to a three-necked flask, the flask was purged with Ar, and then the mixture was stirred at about 230° C. for about 100 hours. Toluene was added to the reaction system to extract an organic material. The extracted organic material was filtered, and the solvent was removed under reduced pressure. The obtained crude product was purified through silica gel chromatography (hexane/CH₂Cl₂) to obtain Compound C-112 (10.4 mmol, yield of 41%).

Compound C-112 (10.4 mmol) was added to a three-necked flask, the flask was purged with Ar, then ODCB (70 mL) was added and dissolved, then BI₃ (41.6 mmol) was added, and the mixture was stirred at 120° C. for about 4 hours. The reaction solution was returned to room temperature, diisopropylethylamine (50 mL) was added to quench the reaction, the reaction solution was filtered through silica gel, and the solvent was removed under reduced pressure. The obtained crude product was purified through silica gel chromatography (hexane/CH₂Cl₂) to obtain Fused Polycyclic Compound 112 (5.30 mmol, yield of 51%). FAB-MASS m/z: 1293.54.

### (9) Synthesis of Fused Polycyclic Compound 295

Fused polycyclic compound 295 was synthesized according to Reaction Scheme 9.

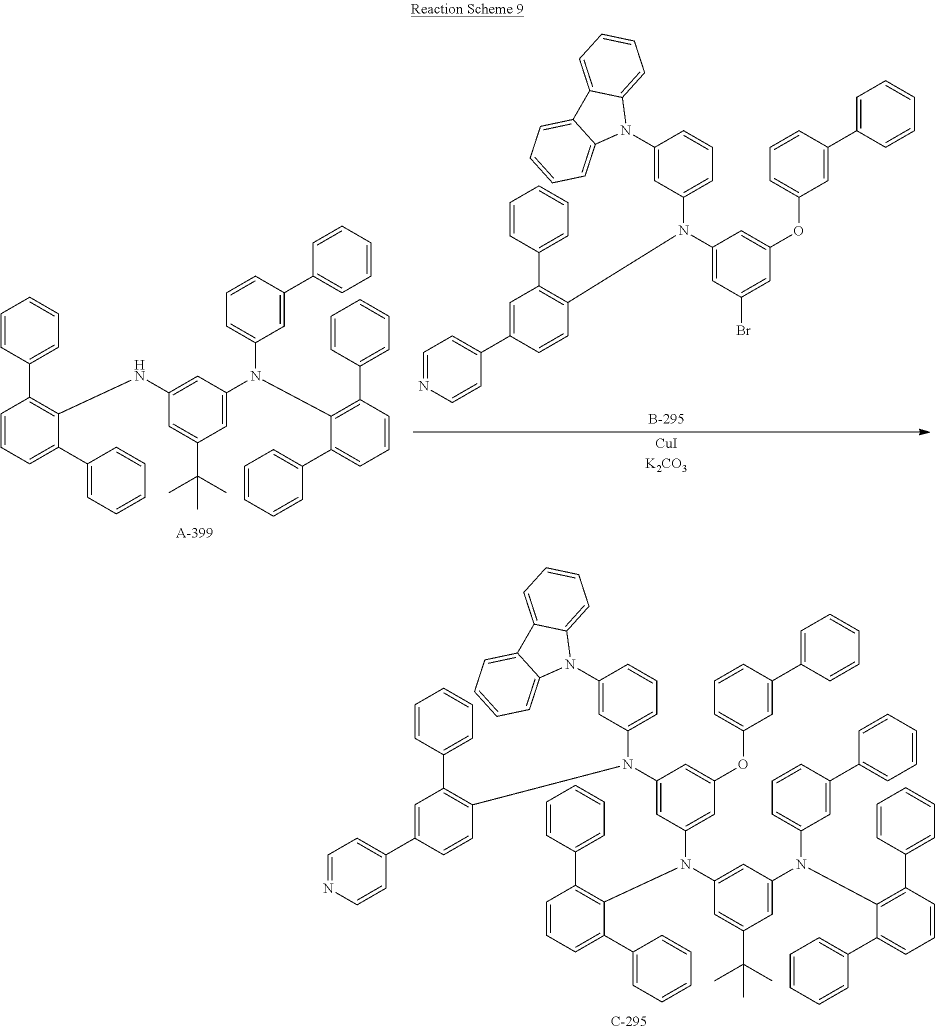

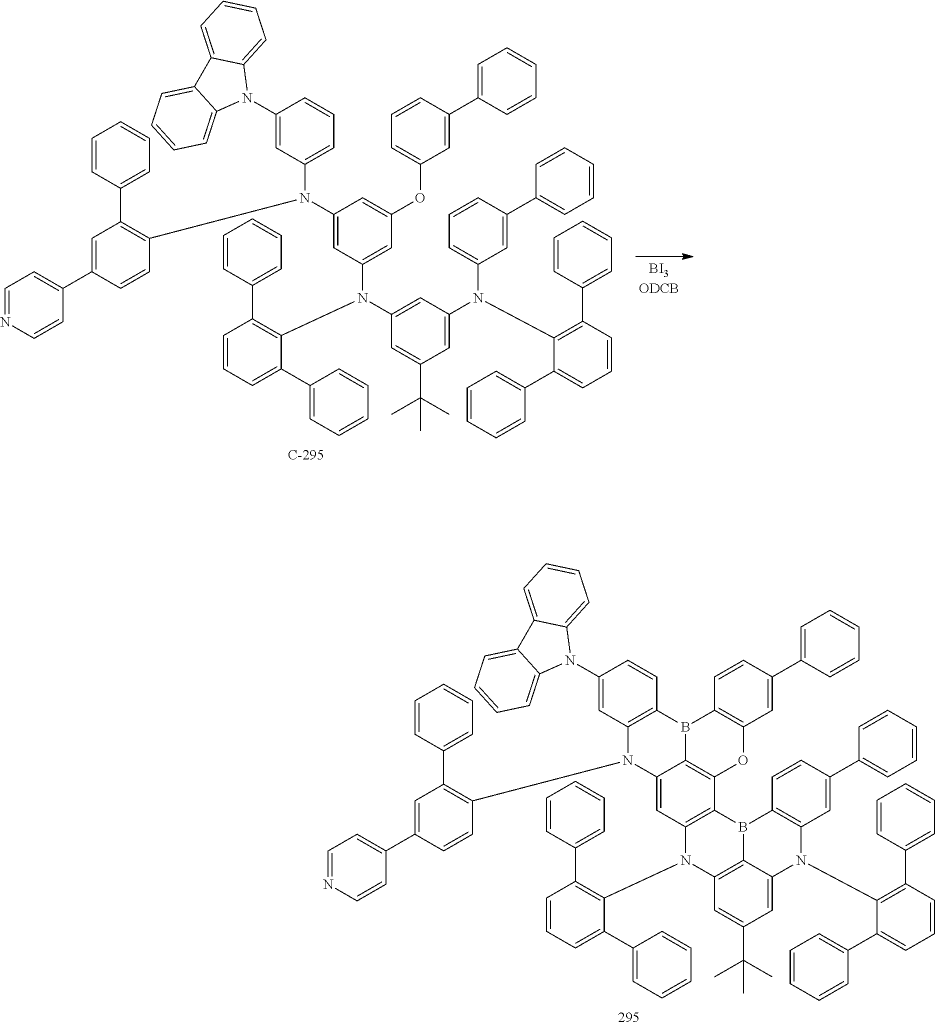 [SMILES: CC(C)(C)c1cc(N(c2cccc(-c3ccccc3)c2)c2c(-c3ccccc3)cccc2-c2ccccc2)cc(N(c2cc(Oc3cccc(-c4ccccc4)c3)cc(N(c3cccc(-n4c5ccccc5c5ccccc54)c3)c3ccc(-c4ccncc4)cc3-c3ccccc3)c2)c2c(-c3ccccc3)cccc2-c2ccccc2)c1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ccncc2)cc1-c1ccccc1]

Compound A-399 (10.5 mmol), Compound B-295 (22.0 mmol), K₂CO₃ (105 mmol), and CuI (42.0 mmol) were added to a three-necked flask, the flask was purged with Ar, and then the mixture was stirred at about 230° C. for about 80 hours. Toluene was added to the reaction system to extract an organic layer. The extracted organic layer was filtered, and the solvent was removed under reduced pressure. The obtained crude product was purified through silica gel chromatography (hexane/CH₂Cl₂) to obtain Compound C-295 (5.25 mmol, yield of 50%).

Compound C-295 (5.25 mmol) was added to a three-necked flask, the flask was purged with Ar, then ODCB (35 mL) was added and dissolved, then BI₃ (21.0 mmol) was added, and the mixture was stirred at 120° C. for about 4 hours. The reaction solution was returned to room temperature, diisopropylethylamine (30 mL) was added to quench the reaction, the reaction solution was filtered through silica gel, and the solvent was removed under reduced pressure. The obtained crude product was purified through silica gel chromatography (hexane/CH₂Cl₂) to obtain Compound D-295 (1.16 mmol, yield of 22%). FAB-MASS m/z: 1517.63.

### (10) Synthesis of Fused Polycyclic Compound 296

Fused polycyclic compound 296 was synthesized according to Reaction Scheme 10.

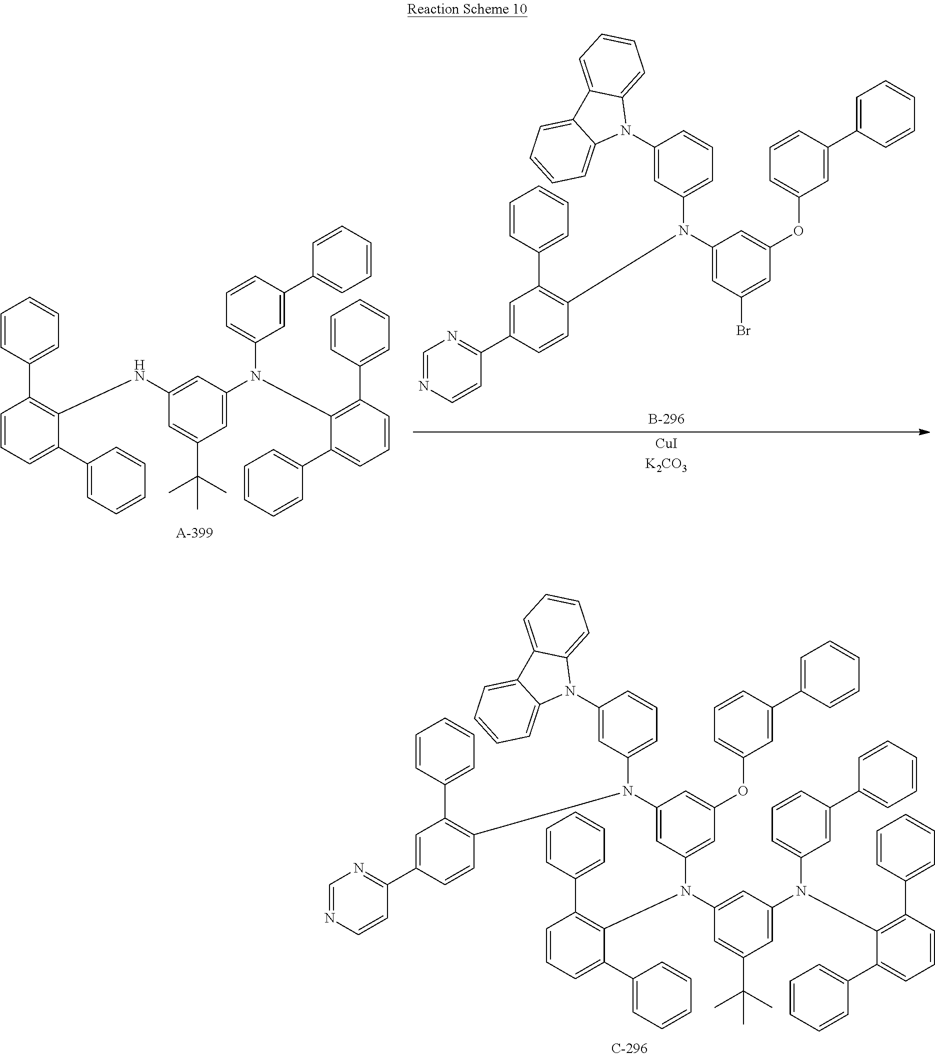

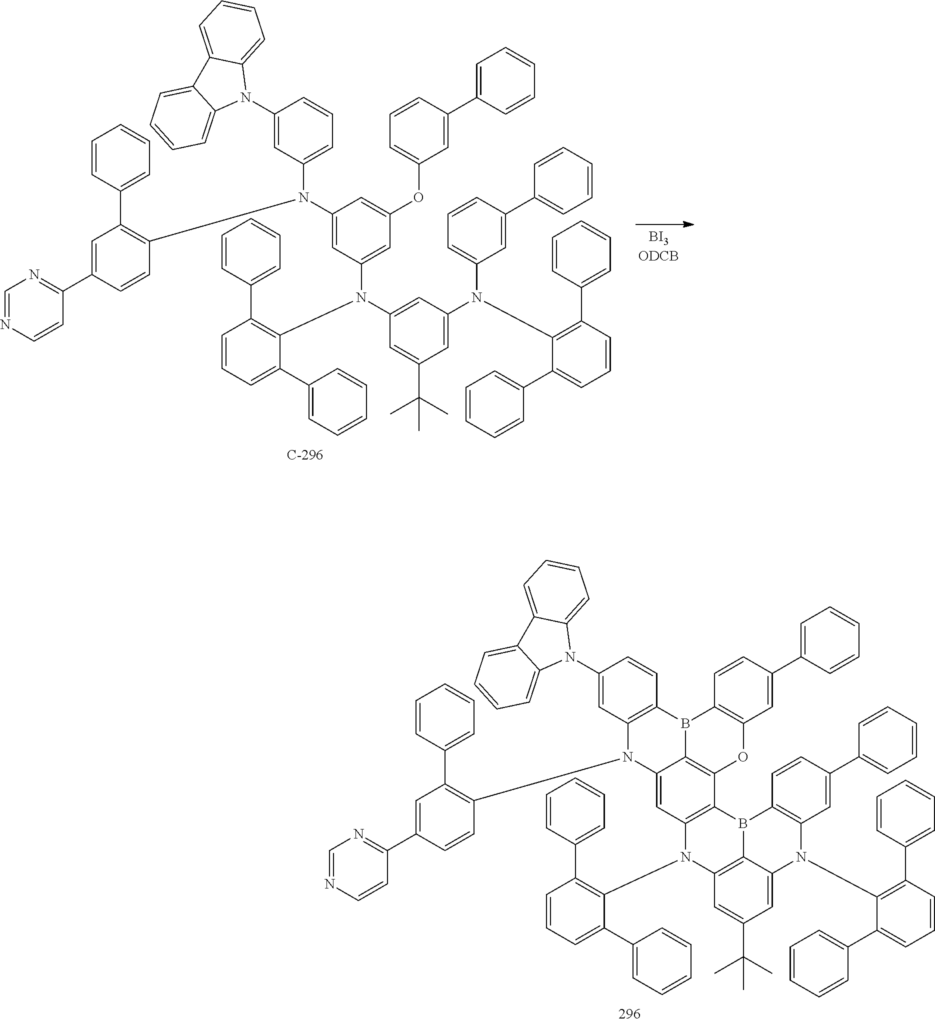 [SMILES: CC(C)(C)c1cc(N(c2cccc(-c3ccccc3)c2)c2c(-c3ccccc3)cccc2-c2ccccc2)cc(N(c2cc(Oc3cccc(-c4ccccc4)c3)cc(N(c3cccc(-n4c5ccccc5c5ccccc54)c3)c3ccc(-c4ccncn4)cc3-c3ccccc3)c2)c2c(-c3ccccc3)cccc2-c2ccccc2)c1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-n2c3ccccc3c3ccccc32)cc1N4c1ccc(-c2ccncn2)cc1-c1ccccc1]

Compound A-399 (12.8 mmol), Compound B-296 (20.5 mmol), K₂CO₃ (128 mmol), and CuI (51.2 mmol) were added to a three-necked flask, the flask was purged with Ar, and then the mixture was stirred at about 230° C. for about 75 hours. Toluene was added to the reaction system to extract an organic layer. The extracted organic layer was filtered, and the solvent was removed under reduced pressure. The obtained crude product was purified through silica gel chromatography (hexane/CH₂Cl₂) to obtain Compound C-296 (4.86 mmol, yield of 38%).

Compound C-296 (4.86 mmol) was added to a three-necked flask, the flask was purged with Ar, then ODCB (30 mL) was added and dissolved, then BI₃ (19.4 mmol) was added, and the mixture was stirred at 120° C. for about 4 hours. The reaction solution was returned to room temperature, diisopropylethylamine (25 mL) was added to quench the reaction, the reaction solution was filtered through silica gel, and the solvent was removed under reduced pressure. The obtained crude product was purified through silica gel chromatography (hexane/CH₂Cl₂) to obtain Fused Polycyclic Compound 296 (0.874 mmol, yield of 18%). FAB-MASS m/z: 1518.63.

### (11) Synthesis of Fused Polycyclic Compound 407

Fused polycyclic compound 407 was synthesized according to Reaction Scheme 11.

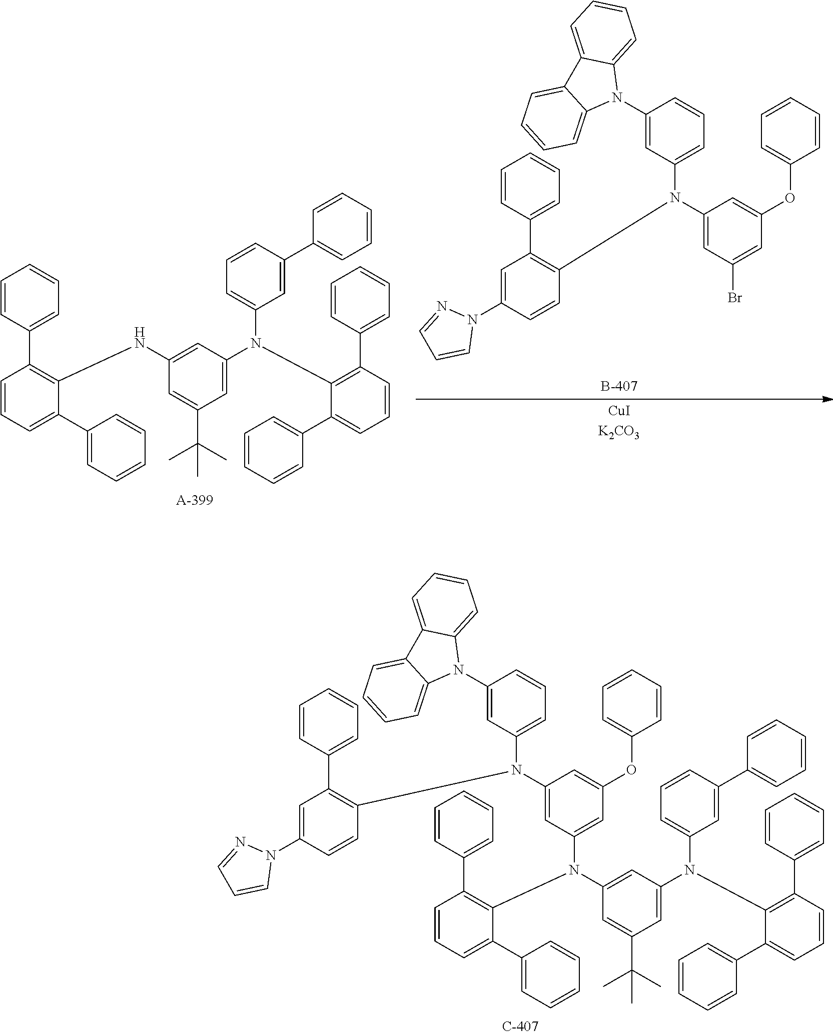

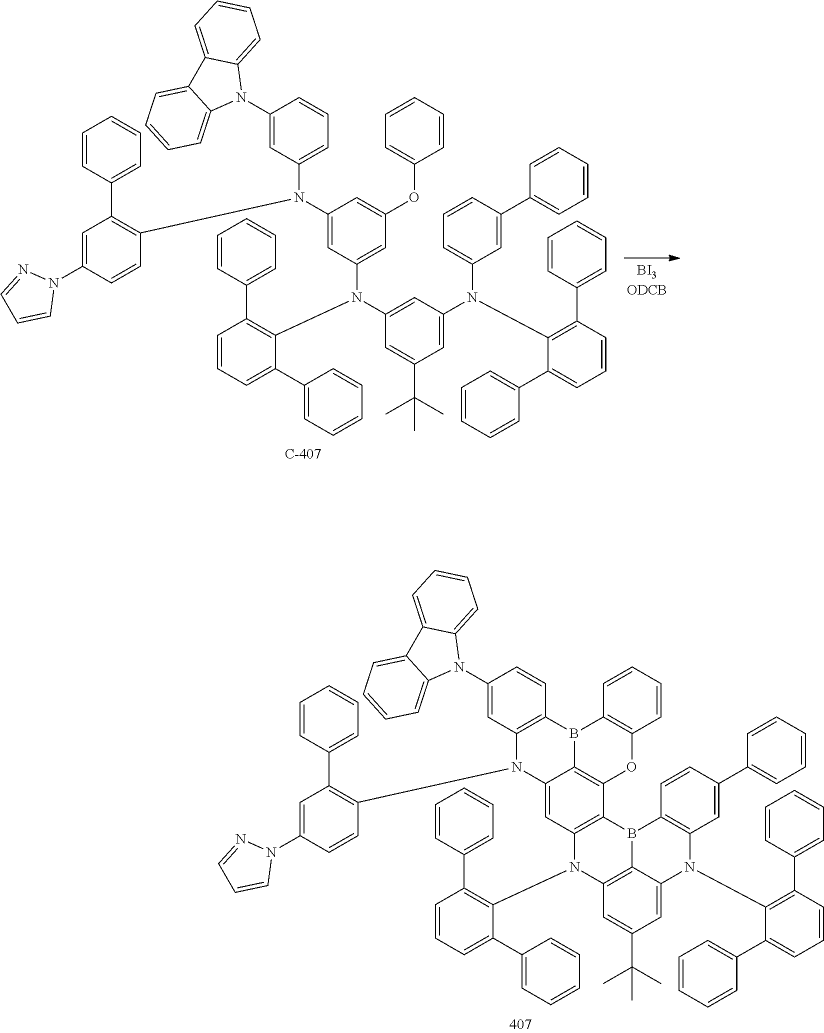 [SMILES: CC(C)(C)c1cc(N(c2cccc(-c3ccccc3)c2)c2c(-c3ccccc3)cccc2-c2ccccc2)cc(N(c2cc(Oc3ccccc3)cc(N(c3cccc(-n4c5ccccc5c5ccccc54)c3)c3ccc(-n4cccn4)cc3-c3ccccc3)c2)c2c(-c3ccccc3)cccc2-c2ccccc2)c1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1ccc(-n2c3ccccc3c3ccccc32)cc1N4c1ccc(-n2cccn2)cc1-c1ccccc1]

Compound A-399 (14.5 mmol), Compound B-407 (16 mmol), K₂CO₃ (145 mmol), CuI (58.0 mmol) were added to a three-necked flask, the flask was purged with Ar, and then the mixture was stirred at about 230° C. for about 70 hours. Toluene was added to the reaction system to extract an organic material. The extracted organic material was filtered, and the solvent was removed under reduced pressure. The obtained crude product was purified through silica gel chromatography (hexane/CH₂Cl₂) to obtain Compound C-407 (5.51 mmol, yield of 38%).

Compound C-407 (5.51 mmol) was added to a three-necked flask, the flask was purged with Ar, then ODCB (35 mL) was added and dissolved, then BI₃ (22.0 mmol) was added, and the mixture was stirred at 120° C. for about 4 hours. The reaction solution was returned to room temperature, diisopropylethylamine (30 mL) was added to quench the reaction, the reaction solution was filtered through silica gel, and the solvent was removed under reduced pressure. The obtained crude product was purified through silica gel chromatography (hexane/CH₂Cl₂) to obtain Fused Polycyclic Compound 407 (0.725 mmol, yield of 5%). FAB-MASS m/z: 1430.60.

### (12) Synthesis of Fused Polycyclic Compound 408

Fused polycyclic compound 408 was synthesized according to Reaction Scheme 12.

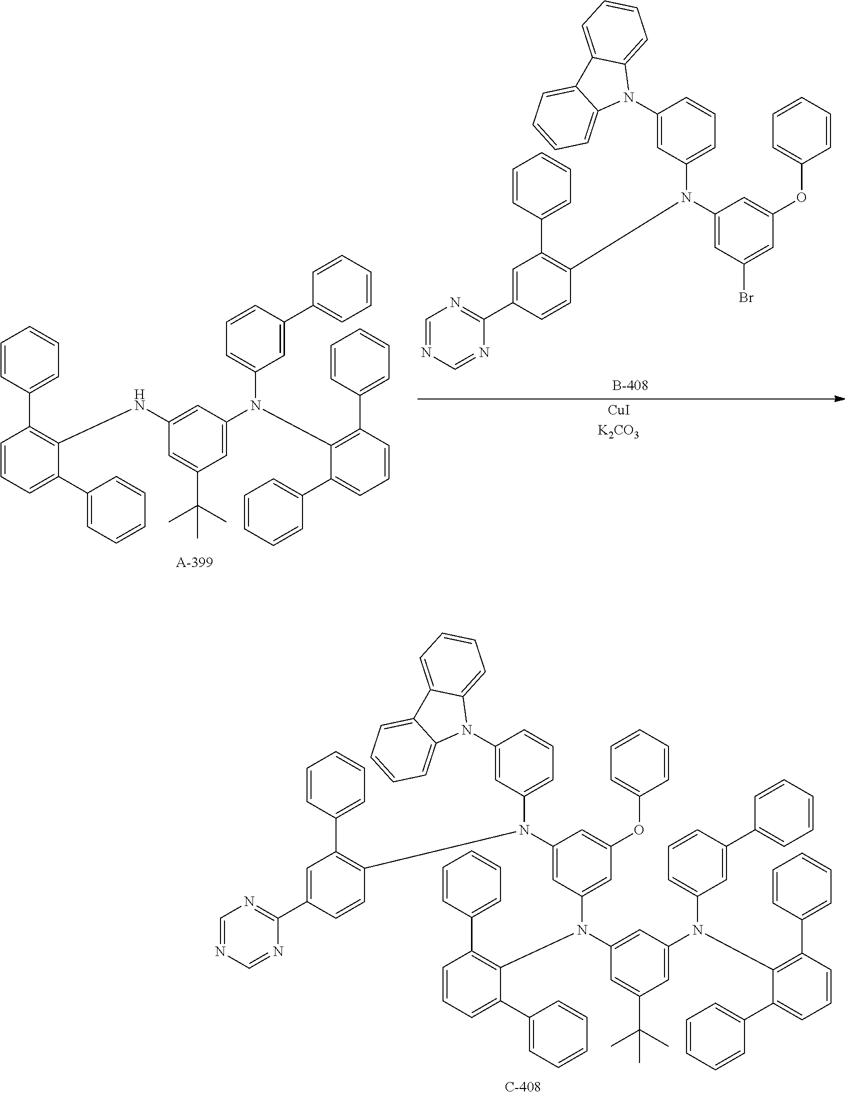

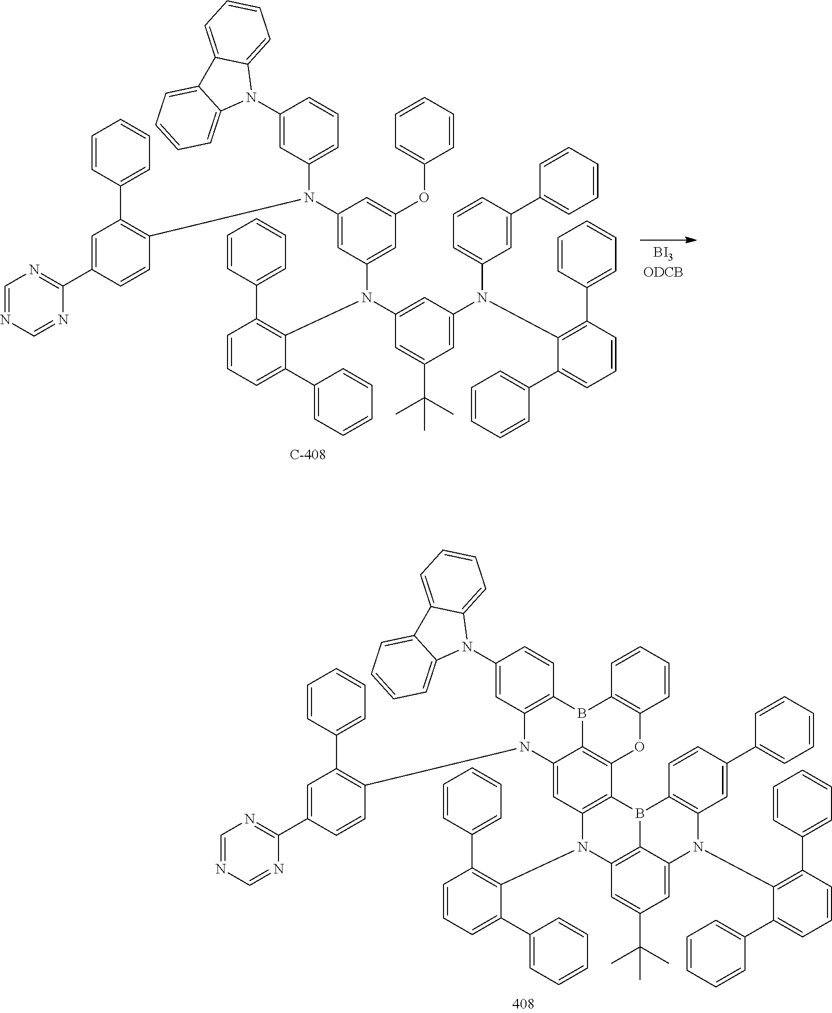 [SMILES: CC(C)(C)c1cc(N(c2cccc(-c3ccccc3)c2)c2c(-c3ccccc3)cccc2-c2ccccc2)cc(N(c2cc(Oc3ccccc3)cc(N(c3cccc(-n4c5ccccc5c5ccccc54)c3)c3ccc(-c4ncncn4)cc3-c3ccccc3)c2)c2c(-c3ccccc3)cccc2-c2ccccc2)c1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1ccc(-n2c3ccccc3c3ccccc32)cc1N4c1ccc(-c2ncncn2)cc1-c1ccccc1]

Compound A-399 (16.8 mmol), Compound B-408 (17.5 mmol), K₂CO₃ (168 mmol), and CuI (67.2 mmol) were added to a three-necked flask, the flask was purged with Ar, and then the mixture was stirred at about 230° C. for about 70 hours. Toluene was added to the reaction system to extract an organic material. The extracted organic material was filtered, and the solvent was removed under reduced pressure. The obtained crude product was purified through silica gel chromatography (hexane/CH₂Cl₂) to obtain Compound C-408 (5.04 mmol, yield of 30%). Compound C-408 (5.04 mmol) was added to a three-necked flask, the flask was purged with Ar, then ODCB (35 mL) was added and dissolved, then BI₃ (20.2 mmol) was added, and the mixture was stirred at 120° C. for about 4 hours. The reaction solution was returned to room temperature, diisopropylethylamine (30 mL) was added to quench the reaction, the reaction solution was filtered through silica gel, and the solvent was removed under reduced pressure. The obtained crude product was purified through silica gel chromatography (hexane/CH₂Cl₂) to obtain Fused Polycyclic Compound 408 (1.16 mmol, yield of 23%). FAB-MASS m/z: 1443.59.

### 2. Manufacture and Evaluation of Light-Emitting Elements

### (1) Manufacture of Light-Emitting Elements

Light-emitting elements, including the fused polycyclic compounds represented by Formula 1 according to Examples or Comparative Example Compounds in an emission layer were manufactured through methods below. Light emitting elements according to Examples 1 to 12 were respectively manufactured using, as a dopant material of the emission layer, Compounds 399, 109, 434, 217, 325, 397, 110, 112, 295, 296, 407, and 408, which were the fused polycyclic compounds represented by Formula 1 according to Examples. Light-emitting elements according to Comparative Examples 1 to 10 were respectively manufactured using Comparative Example Compounds X-1 to X-10 as a dopant material of the emission layer.

A first electrode was prepared by patterning an ITO with a thickness of about 150 nm on a glass substrate, and then the resultant glass substrate was cleansed using deionized (DI) water and UV-ozone treatment for about 10 minutes. Thereafter, a hole injection layer having a thickness of about 10 nm was formed using HAT-CN, and a hole transport layer having a thickness of about 80 nm was formed using α-NPD.

Next, an electron blocking layer having a thickness of about 5 nm was formed using mCP, and the respective Example Compound or Comparative Example Compound, and mCBP were provided at a weight ratio of about 1:99 to form an emission layer. The emission layer was formed to a thickness of about 20 nm. An electron transport layer having a thickness of about 30 nm was formed on the emission layer using TPBi, and an electron injection layer having a thickness of about 0.5 nm was formed using LiF. Then, a second electrode having a thickness of about 100 nm was formed using aluminum (Al). The hole injection layer, the hole transport layer, the electron blocking layer, the emission layer, the electron transport layer, the electron injection layer, and the second electrode were formed by using a vacuum deposition device.

### Example Compounds

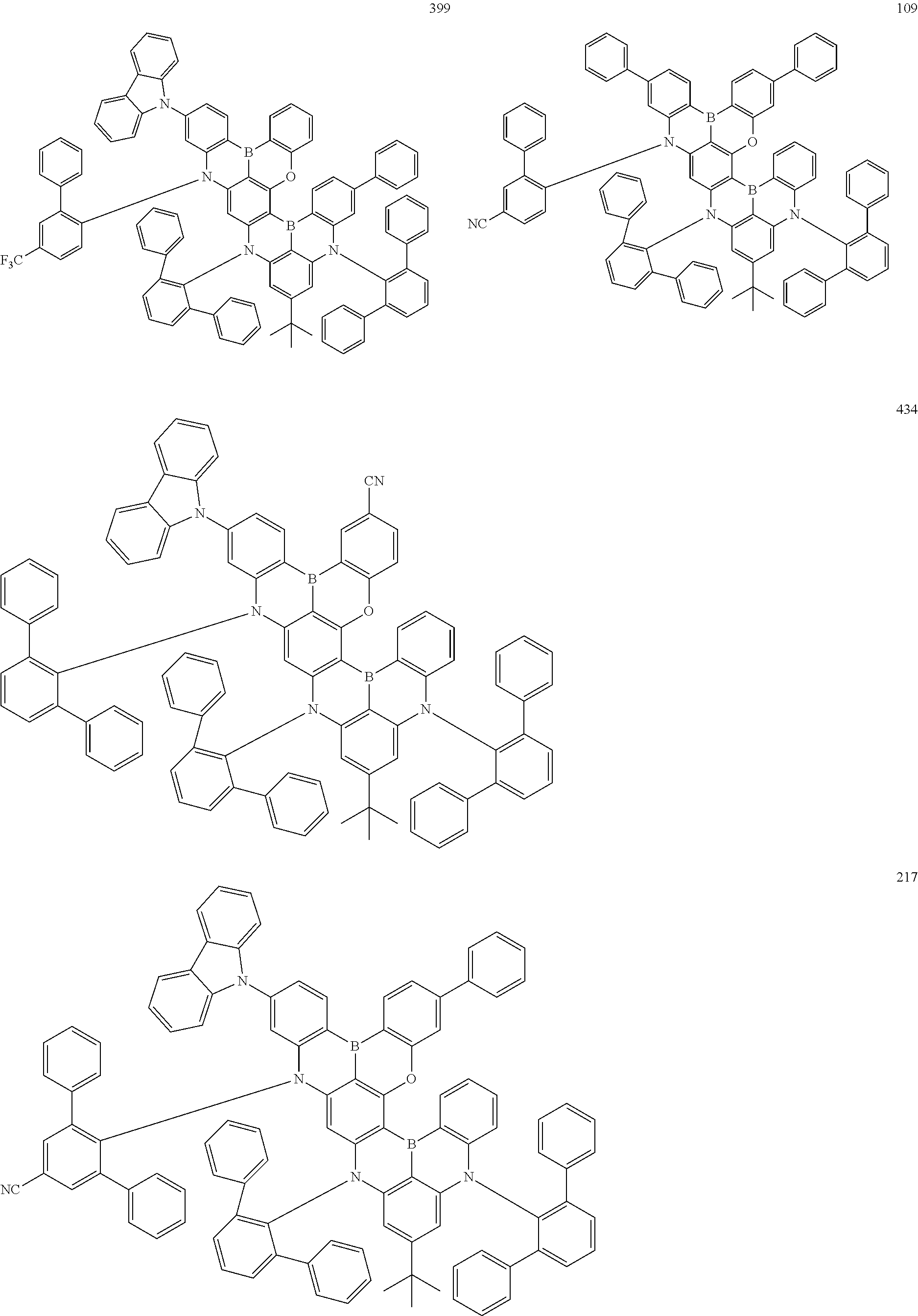

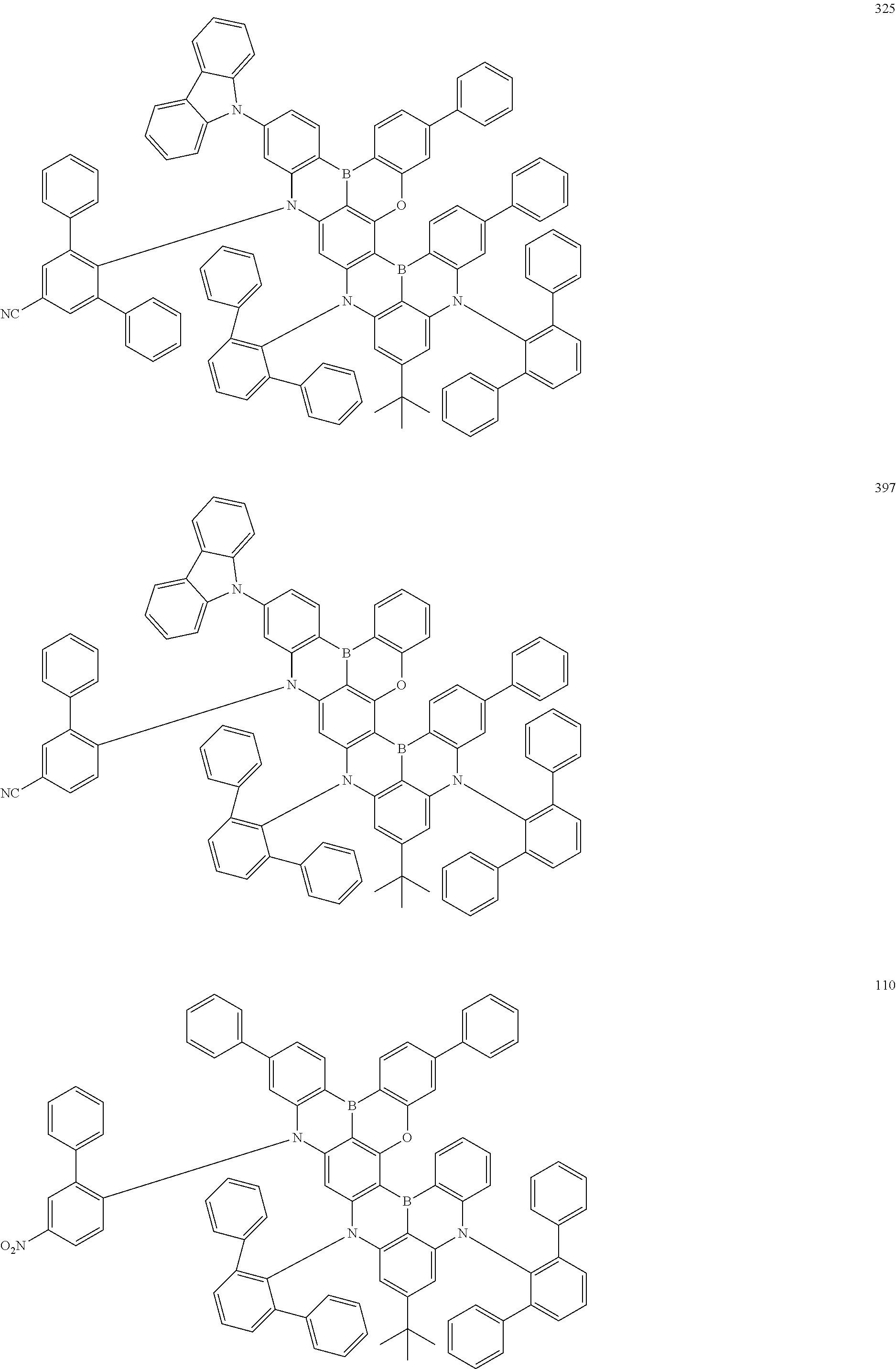

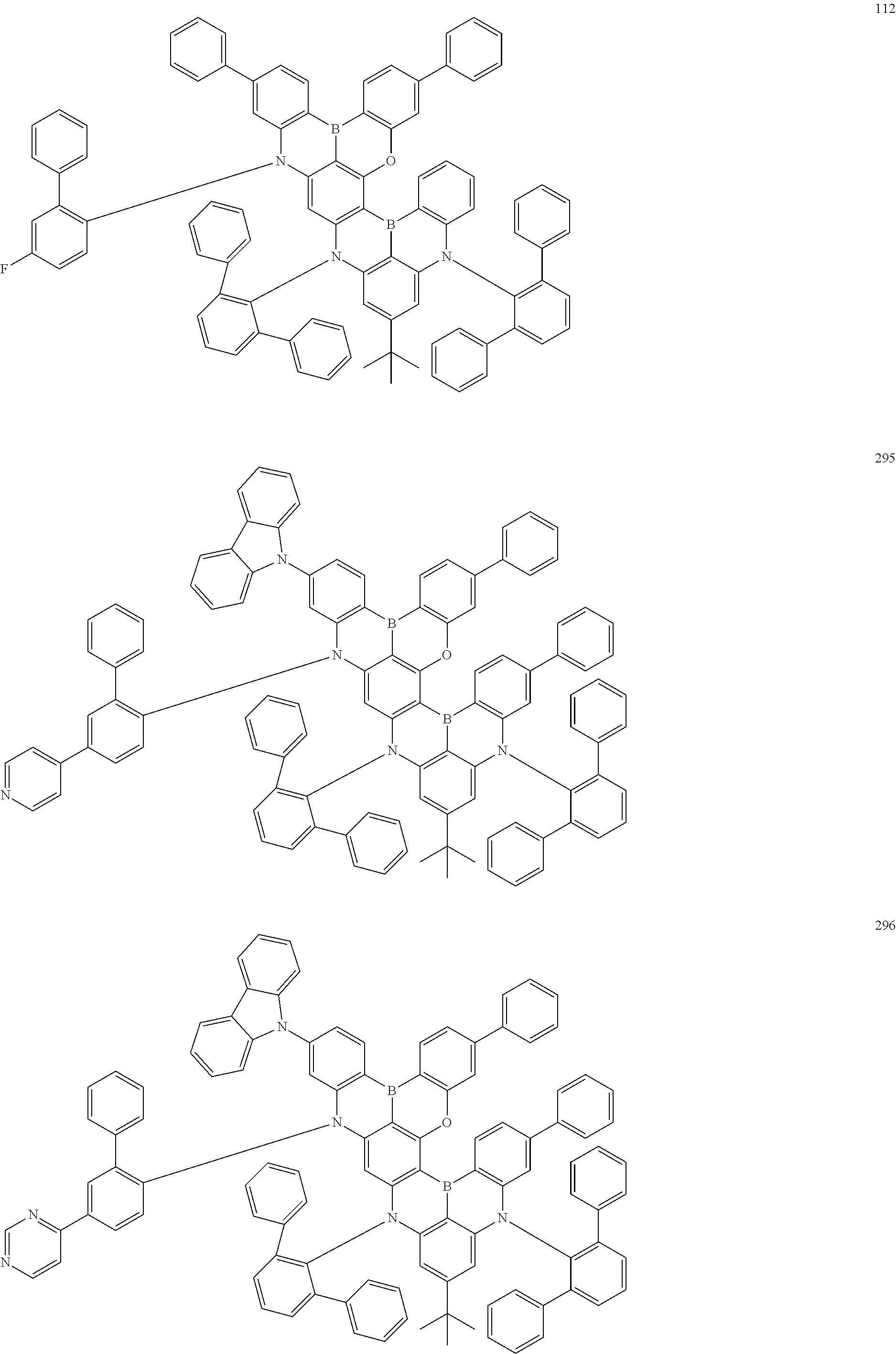

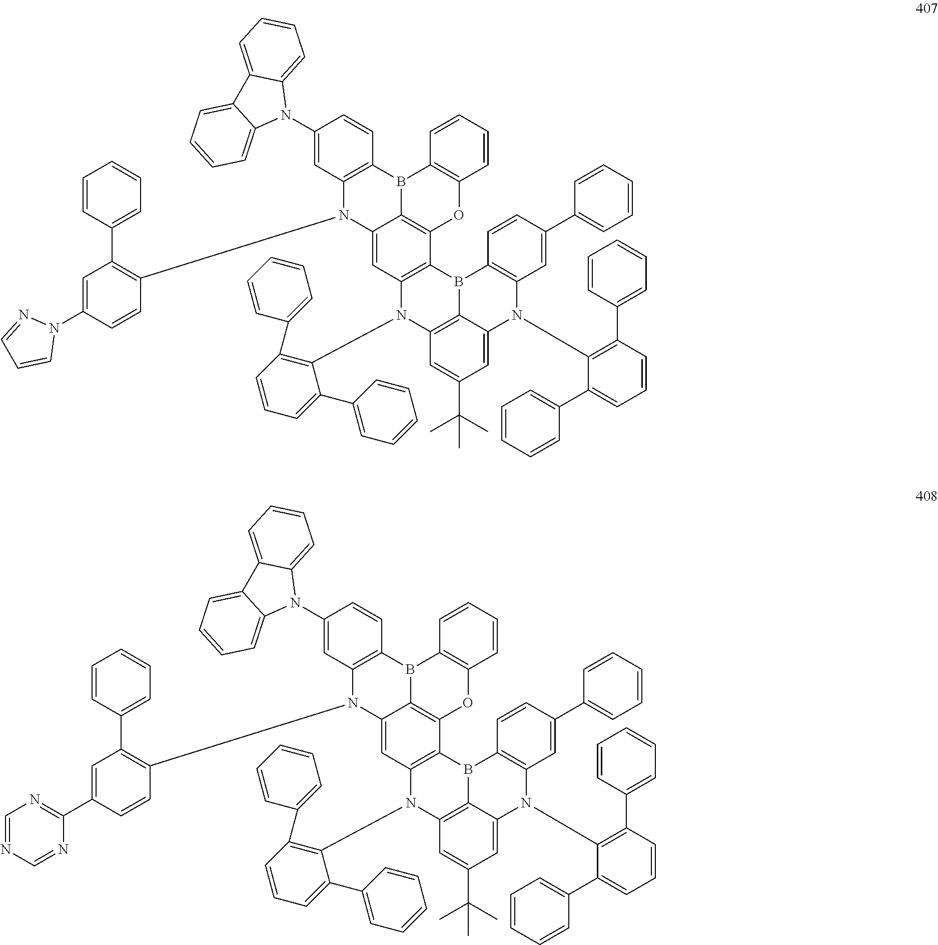 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1ccc(-n2c3ccccc3c3ccccc32)cc1N4c1ccc(-n2cccn2)cc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1ccc(-n2c3ccccc3c3ccccc32)cc1N4c1ccc(-c2ncncn2)cc1-c1ccccc1]

### Comparative Example Compounds

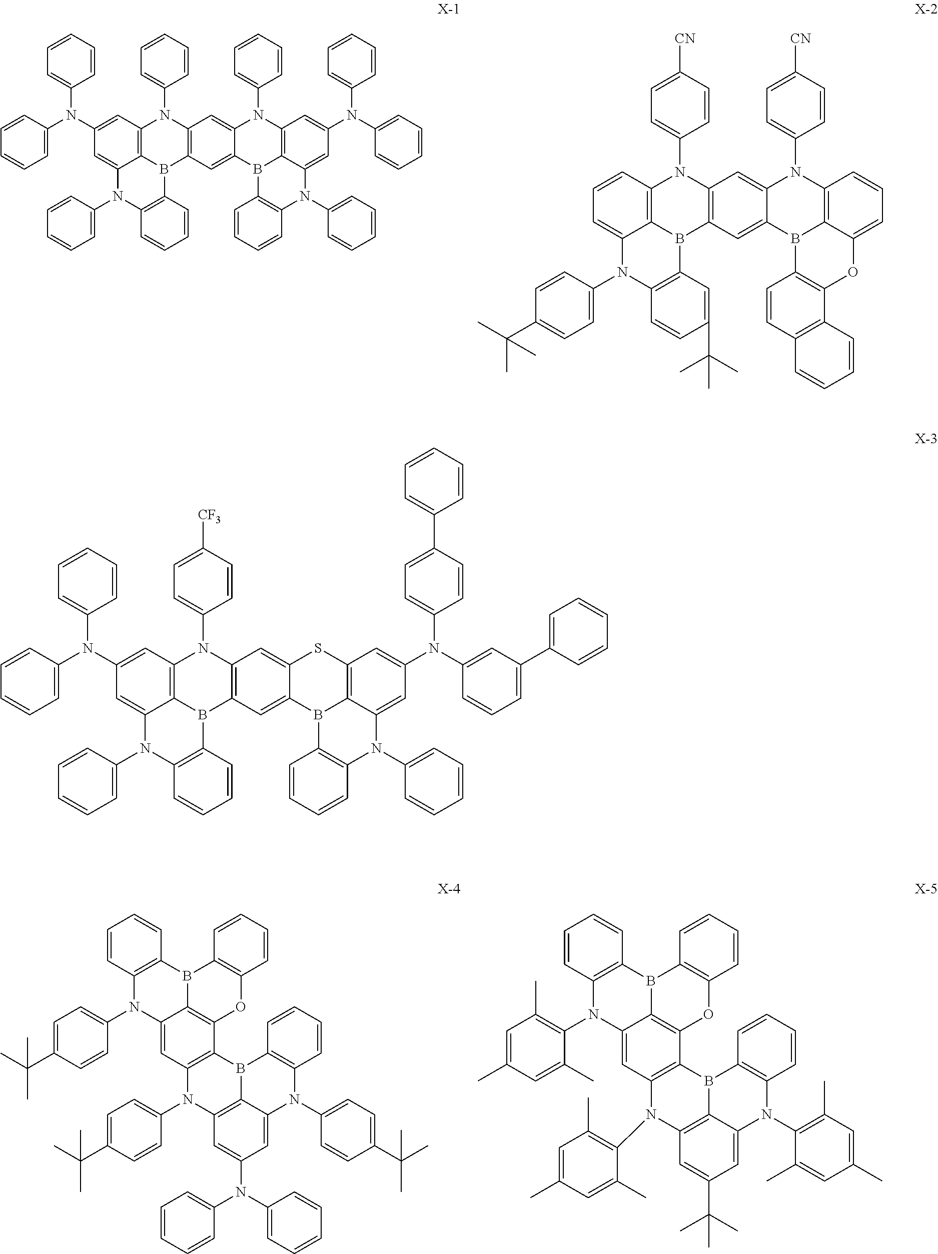

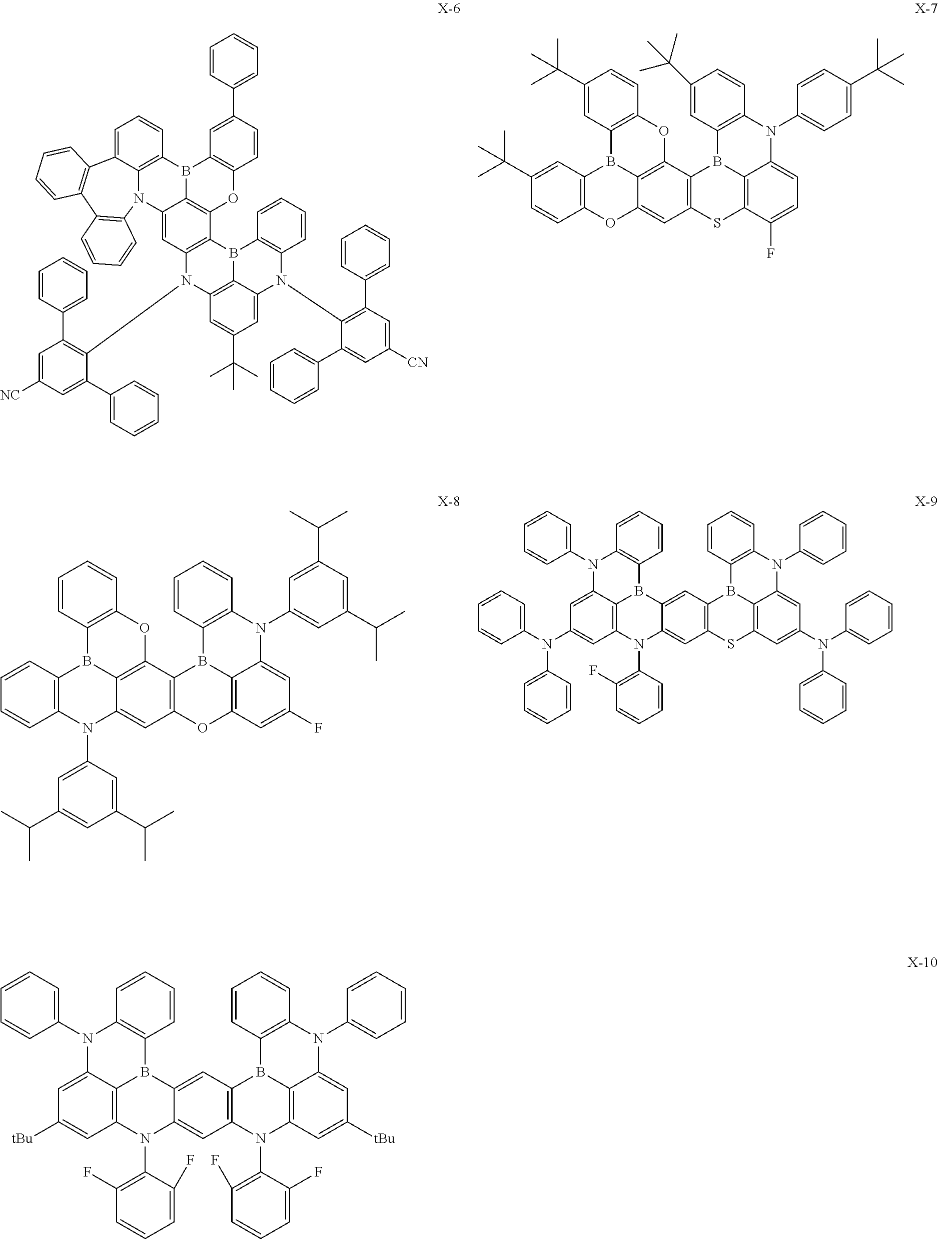

### (2) Evaluation of Light-Emitting Element

Table 1 shows the evaluation results of light-emitting elements according to Examples and Comparative Examples. The peak emission wavelengths (λₘₐₓ, nm), external quantum efficiency (EQE₁₀₀₀ₙᵢₜ, %), and roll-off ratio (%) of the light-emitting elements according to Examples and Comparative Examples were evaluated. The peak emission wavelengths (λₘₐₓ), the external quantum efficiency (EQE₁₀₀₀ₙᵢₜ), and the roll-off ratio were evaluated using a spectroradiometer (SR-3AR made by TOPCON TECHNOHOUSE CORPORATION). The peak emission wavelength (λₘₐₓ) indicates a wavelength at which a maximum value appears in the emission spectrum. The external quantum efficiency (EQE₁₀₀₀ₙᵢₜ) was measured at a luminance of about 1000 cd/m², and expressed as a relative value with respect to the measured external quantum efficiency of the light-emitting element according to Comparative Example 1. The roll-off ratio represents a decrease rate in efficiency at high luminance, which was evaluated based on a luminance at about 1 cd/m² and a luminance at about 1000 cd/m². More specifically, the roll-off was calculated from Equation 1 below.

$${R}_{0} = [ ( {E}_{1} - {E}_{2} ) / {E}_{1} ] \times 100 \% \qquad Equation 1$$

In Equation 1, E₁ is an external quantum efficiency at a luminance of 1 cd/m², E₂ is an external quantum efficiency at a luminance of 1000 cd/m², and R₀ is a roll-off value.

TABLE 1

| Element | | | | |
|---|---|---|---|---|
| manufacture | | λₘₐₓ | EQE_{1000 nit} | Roll- |
| examples | Dopant | (nm) | (%) | off (%) |
| Example 1 | Example Compound 399 | 458 | 1.17 | 23.0 |
| Example 2 | Example Compound 109 | 460 | 1.21 | 20.3 |
| Example 3 | Example Compound 434 | 457 | 1.25 | 20.8 |
| Example 4 | Example Compound 217 | 457 | 1.23 | 20.8 |
| Example 5 | Example Compound 325 | 463 | 1.25 | 20.6 |
| Example 6 | Example Compound 397 | 459 | 1.23 | 21.1 |
| Example 7 | Example Compound 110 | 461 | 1.20 | 20.7 |
| Example 8 | Example Compound 112 | 461 | 1.15 | 22.7 |
| Example 9 | Example Compound 295 | 460 | 1.22 | 21.2 |
| Example 10 | Example Compound 296 | 460 | 1.22 | 21.2 |
| Example 11 | Example Compound 407 | 460 | 1.23 | 20.3 |
| Example 12 | Example Compound 408 | 461 | 1.22 | 21.4 |
| Comparative | Comparative Example | 472 | 1 | 34.7 |
| Example 1 | Compound X-1 | | | |
| Comparative | Comparative Example | 466 | 1.14 | 27.4 |
| Example 2 | Compound X-2 | | | |
| Comparative | Comparative Example | 465 | 1.09 | 31.7 |
| Example 3 | Compound X-3 | | | |
| Comparative | Comparative Example | 455 | 1.02 | 29.4 |
| Example 4 | Compound X-4 | | | |
| Comparative | Comparative Example | 460 | 1.04 | 29.6 |
| Example 5 | Compound X-5 | | | |
| Comparative | Comparative Example | 458 | 1.06 | 26.3 |
| Example 6 | Compound X-6 | | | |
| Comparative | Comparative Example | 461 | 1.09 | 24.6 |
| Example 7 | Compound X-7 | | | |
| Comparative | Comparative Example | 459 | 1.09 | 24.0 |
| Example 8 | Compound X-8 | | | |
| Comparative | Comparative Example | 470 | 1.14 | 25.7 |
| Example 9 | Compound X-9 | | | |
| Comparative | Comparative Example | 479 | 1.14 | 28.8 |
| Example 10 | Compound X-10 | | | |

Referring to Table 1, it can be confirmed that peak emission wavelengths of the light-emitting elements according to Examples 1 to 12 are about 460 nm, and the light-emitting elements according to Examples 1 to 12 emit near-pure blue light. It can be seen that the light-emitting elements according to Examples 1 to 12 emit pure blue light with high color purity.

It can be seen that the light-emitting elements according to Examples 1 to 12 exhibit higher external quantum efficiency and lower roll-off ratio than the light-emitting elements according to Comparative Examples 1 to 10. The light-emitting elements according to Examples 1 to 12 include Example Compounds 399, 109, 434, 217, 325, 397, 110, 112, 295, 296, 407, and 408, respectively, and Example Compounds 399, 109, 434, 217, 325, 397, 110, 112, 295, 296, 407, and 408 are the fused polycyclic compounds represented by Formula 1 according to one or more embodiments. Compounds 399, 109, 434, 217, 325, 397, 110, 112, 295, 296, 407, and 408 each include the fused ring with nine rings and the substituent E_{w}, and include a trifluoromethyl group, a cyano group, a nitro group, a fluorine atom, a pyridine group, a pyrimidine group, a pyrazole group, or a triazine group as the substituent E_{w}.

Molecular orbitals of Compounds 399, 109, 434, 217, 325, 397, 110, 112, 295, 296, 407, and 408 were calculated with Gaussian16, and B3LYP/6-31G (d) was used as basis set. It can be seen that Compounds 399, 109, 434, 217, 325, 397, 110, 112, 295, 296, 407, and 408 are each a charge transfer (CT) type, in which HOMO and LUMO distributions are separated, from the calculated results. In addition, it can be confirmed that the HOMO and the LUMO are completely separated by introducing the substituent E_{w} (that is, a trifluoromethyl group, a cyano group, a nitro group, a fluorine atom, a pyridine group, a pyrimidine group, a pyrazole group, or a triazine group) at a position where the LUMO is distributed. Additionally, ΔE_{ST} of each of Compounds 399, 109, 434, 217, 325, 397, 110, 112, 295, 296, 407, a 408 is lower than those of Comparative Example Compounds X-1 to X-6. ΔE_{ST} indicates an absolute value of a difference between a triplet state energy level and a singlet state energy level. It is considered that, since Compounds 399, 109, 434, 217, 325, 397, 110, 112, 295, 296, 407, and 408 each have a small ΔE_{ST}, reverse intersystem crossing from the triple state to the singlet state is promoted, and thus triplet excitons having long lifespan are rapidly converted to singlet excitons, resulted in improvements in emission efficiency and suppression of the roll-off. Therefore, it can be seen that the fused polycyclic compound represented by Formula 1 according to an embodiment may contribute to improvements in the emission efficiency and suppression of the roll-off.

The light-emitting element according to Comparative Example 1 includes Comparative Example Compound X-1. The core structure of Comparative Example Compound X-1 is a fused ring with nine rings but differs from the fused ring with nine rings included in the fused polycyclic compound represented by Formula 1 according to an embodiment. In the fused ring with nine rings included in Comparative Example Compound X-1, a HOMO and a LUMO are not separated but are mixed. Therefore, the light-emitting element according to Comparative Example 1 including Comparative Example Compound X-1 exhibits relatively low emission efficiency and a high roll-off value.

The light-emitting elements according to Comparative Examples 2 and 3 include Comparative Example Compounds X-2 and X-3, respectively. Comparative Example Compounds X-2 and X-3 include a cyano group, a trifluoromethyl group, which are electron withdrawing groups, and also include a fused ring with nine rings as a core structure. However, the fused rings with nine rings included in Comparative Example Compounds X-2 and X-3 differ from the fused ring with nine rings included in the fused polycyclic compound represented by Formula 1 according to an embodiment. It can be seen that the fused rings with nine rings included in Comparative Example Compounds X-2 and X-3 each have a locally excited (LE) type, where a HOMO and a LUMO are not distinctly separated, and thus be an incomplete CT type fused rings. Even when an electron withdrawing group is introduced in such a molecule, the HOMO and the LUMO slightly overlap to lead to an increase in a ΔE_{ST} values. Therefore, the light-emitting elements according to Comparative Examples 2 and 3 exhibit relatively low emission efficiency and high roll-off value.

The light-emitting elements according to Comparative Examples 4 and 5 include Comparative Example Compounds X-4 and X-5, respectively. Comparative Example Compounds X-4 and X-5 each include a fused ring with nine rings, and the fused ring with nine rings has an orbital distribution where a HOMO and a LUMO are separated. However, Comparative Example Compounds X-4 and X-5 do not include an electron withdrawing group, and thus ΔE_{ST} increases. Therefore, the light-emitting elements according to Comparative Examples 4 and 5 exhibit relatively low emission efficiency and high roll-off value.

The light-emitting element according to Comparative Example 6 includes Comparative Example Compound X-6, and Comparative Example Compound X-6 includes a cyano group, which is an electron withdrawing group. However, it can be seen that in Comparative Example Compound X-6, a cyano group is introduced to a site where HOMOs are likely to be distributed, and thus HOMOs and LUMOs are not separated distinctly to result in an increase in ΔE_{ST}. Therefore, the light-emitting element according to Comparative Example 6 exhibits relatively low emission efficiency and high roll-off value.

The light-emitting elements according to Comparative Examples 7 and 8 include Comparative Example Compounds X-7 and X-8, respectively, and Comparative Example Compounds X-7 and X-8 each include a fluorine atom as an electron withdrawing group. However, it can be seen that in Comparative Example Compounds X-7 and X-8, a fluorine atom is introduced to a site where HOMOs are likely to be distributed, and thus HOMOs and LUMOs are not separated distinctly to result in an increase in ΔE_{ST}. Therefore, the light-emitting elements according to Comparative Examples 7 and 8 exhibit relatively low emission efficiency and high roll-off value.

The light-emitting elements according to Comparative Examples 9 and 10 respectively include Comparative Example Compounds X-9 and X-10, respectively. Comparative Example Compounds X-9 and X-10 include a fluorine atom as an electron withdrawing group and includes a fused ring with nine rings as a core structure. However, the fused rings with nine rings included in Comparative Example Compounds X-9 and X-10 differ from the fused ring with nine rings included in the fused polycyclic compound represented by Formula 1 according to an embodiment. It can be seen that the fused rings with nine rings included in Comparative Example Compounds X-9 and X-10 are each a locally excited (LE) type in which HOMOs and LUMOs are not distinctly separated, and are each an incomplete CT type. Even when an electron withdrawing group is introduced to such a molecule, the HOMOs and the LUMOs still slightly overlap to result in an increase in ΔE_{ST}. Therefore, the light-emitting elements according to Comparative Examples 9 and 10 exhibit relatively low emission efficiency and high roll-off value.

In an embodiment, an electronic apparatus may include a light-emitting element, and the light-emitting element may include a fused polycyclic compound represented by Formula 1. The fused polycyclic compound represented by Formula 1 according to an embodiment includes a fused ring with nine rings and a substituent E_{w}. The fused ring with nine rings is a core structure and includes four heteroatoms and two boron atoms as ring-forming atoms. The substituent E_{w} is an electron withdrawing group. The substituent E_{w} may be directly bonded to the core structure or indirectly bonded to the core structure in such a way that the substituent is included in at least one of the four heteroatoms. Therefore, RISC in the fused polycyclic compound represented by Formula 1 according to an embodiment may be promoted, and the light-emitting element including the fused polycyclic compound represented by Formula 1 according to an embodiment may exhibit high emission efficiency. In an embodiment, the electronic apparatus including the light-emitting element may exhibit excellent reliability.

The light-emitting element according to an embodiment and the electronic apparatus including the same may exhibit high emission efficiency by including the fused polycyclic compound represented by Formula 1 according to an embodiment.

The fused polycyclic compound represented by Formula 1 according to an embodiment may contribute to improvements in emission efficiency of the light-emitting element.

In the above, the detailed description has been made with reference to embodiments and the drawings, but those skilled or of ordinary skill in the art may understand that various modifications and changes may be made insofar as such modifications and changes do not depart from the spirit and technical scope of the subject matter set forth in the claims.

Therefore, the technical scope is not to be limited to the contents stated in the detailed description of the specification, but should be determined by the claims.

1. A light-emitting element comprising:
a first electrode;
a second electrode disposed on the first electrode; and
an emission layer disposed between the first electrode and the second electrode, wherein the emission layer includes a first compound represented by Formula 1: 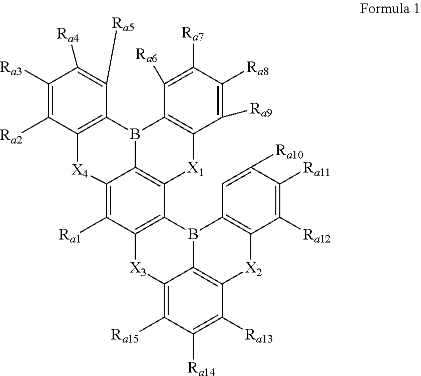
wherein, in Formula 1 above,
X₁ to X₄ are each independently O, S, or NRₙ, wherein at least one of X₁ to X₄ is NRₙ,
each Rₙ is independently a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, E_{w}, or a group represented by Formula 2,
each E_{w} is independently a fluorine atom, a cyano group, a nitro group, a trifluoromethyl group, a substituted or unsubstituted formyl group, a substituted or unsubstituted pyridine group, a substituted or unsubstituted pyrimidine group, a substituted or unsubstituted pyrazole group, or a substituted or unsubstituted triazine group,
Rₐ₁ to Rₐ₉ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w},
adjacent two or more of Rₐ₂ to Rₐ₉ are optionally bonded together to form a ring, and
Rₐ₁₀ to Rₐ₁₅ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms: 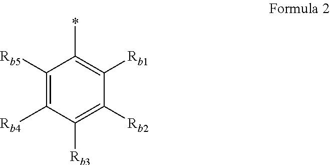
wherein, in Formula 2,
R_{b1} to R_{b5} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w},
wherein the first compound optionally comprises a deuterium atom, and
wherein, the first compound satisfies at least one among Conditions 1 to 3:
Condition 1
at least one of Rₙ is E_{w},
Condition 2
at least one of Rₙ is represented by Formula 2, and
at least one among R_{b1} to R_{b5} in Formula 2 is E_{w},
Condition 3
at least one of Rₐ₁ to Rₐ₉ is E_{w}.

2. The light-emitting element of claim 1, wherein the emission layer further comprises at least one of a second compound represented by Formula HT-1, a third compound represented by Formula ET-1, or a fourth compound represented by Formula D-1: 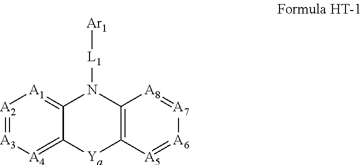
wherein, in Formula HT-1,
A₁ to A₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms, or a substituted or unsubstituted heteroaryl group having 2 to 30 ring-forming carbon atoms,
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms,
R₅₁ to R₅₅ are optionally bonded to an adjacent group to form a ring: 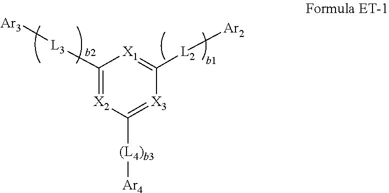
wherein, in Formula ET-1,
X₁ to X₃ are each independently N or CR₅₆, wherein at least one of X₁ to X₃ is N,
R₅₆ is each independently a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms: 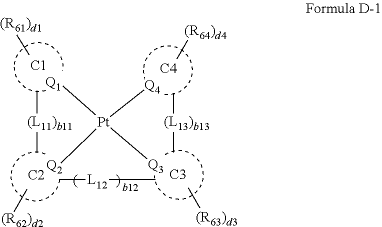
wherein, in Formula D-1,
Q₁ to Q₄ are each independently C or N,
ring C1 to ring C4 are each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms,
L₁₁ to L₁₃ are each independently a direct linkage, *—O—*, *—S—*, 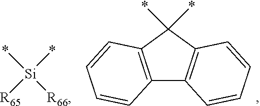
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer of 0 to 4.

3. The light-emitting element of claim 1, wherein Formula 1 is represented by one of Formula 1-A1 to Formula 1-A5: 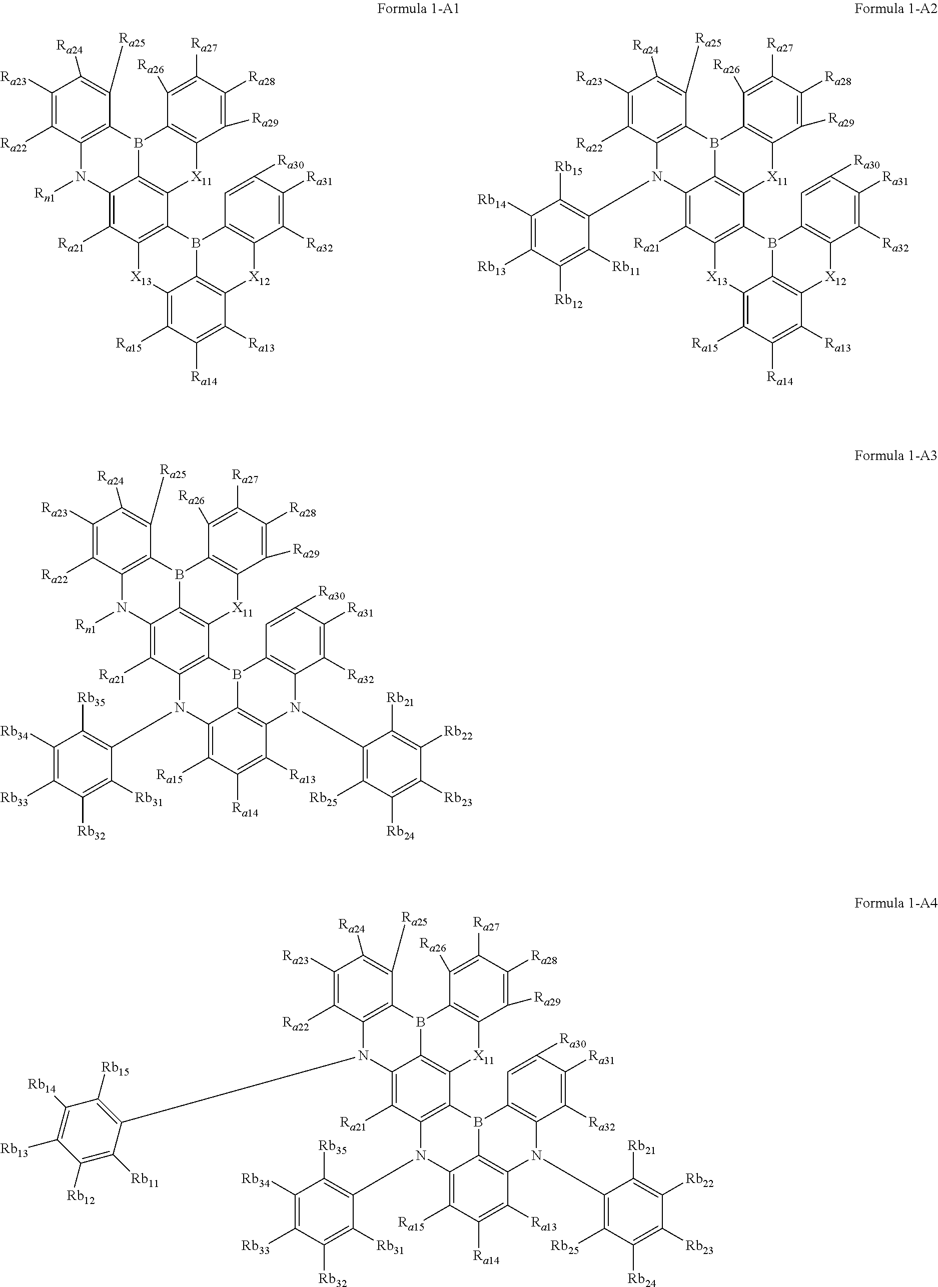 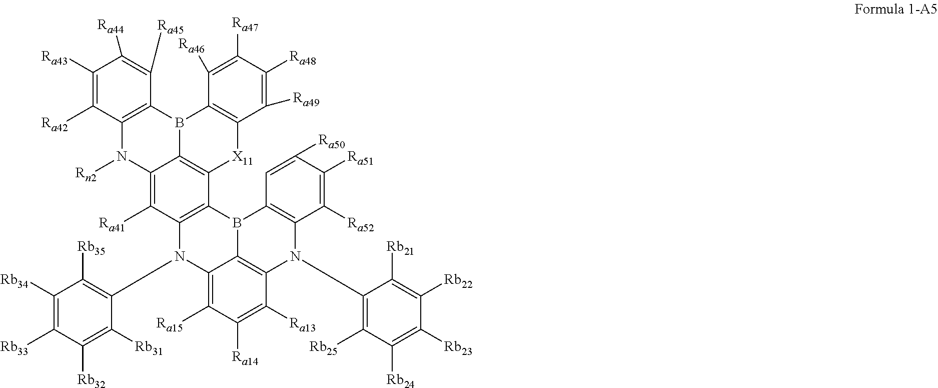
wherein, in Formula 1-A1 and Formula 1-A3,
Rₙ₁ is E_{w},
in Formula 1-A2 and Formula 1-A4,
at least one among R_{b11} to R_{b15} is E_{w}, and the others are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
in Formula 1-A5,
Rₙ₂ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one among Rₐ₄₁ to Rₐ₄₉ is E_{w}, and the others are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Rₐ₅₀ to Rₐ₅₂ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
in Formula 1-A1 to Formula 1-A5,
X₁₁ to X₁₃ are each independently O or S,
Rₐ₂₁ to Rₐ₃₂ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{b21} to R_{b25}, and R_{b31} to R_{b35} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
Rₐ₁₃ to Rₐ₁₅ are the same as defined in Formula 1.

4. The light-emitting element of claim 3, wherein Formula 1-A4 is represented by one of Formula 1-A41 to Formula 1-A43: 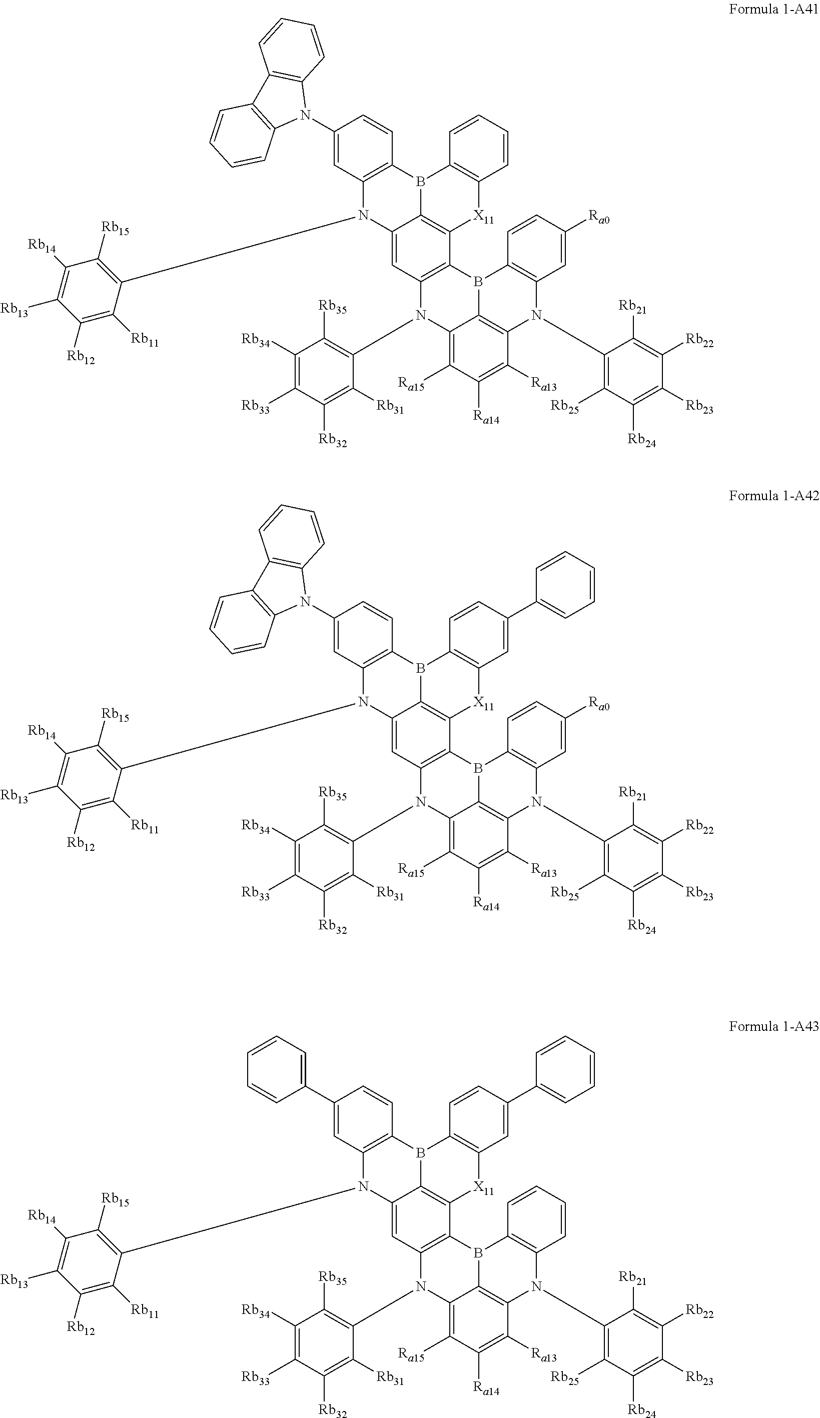
wherein, in Formula 1-A41 to Formula 1-A43,
Rₐ₀ is a hydrogen atom, a deuterium atom, or a substituted or unsubstituted phenyl group, and
Rₐ₁₃ to Rₐ₁₅, R_{b11} to R_{b15}, R_{b21} to R_{b25}, R_{b31} to R_{b35}, and X₁₁ are the same as defined in Formula 1-A4.

5. The light-emitting element of claim 3, wherein, in Formula 1-A₂ and Formula 1-A4, a first cyclic group comprising R_{b11} to R_{b15} is represented by one of R1-B1 to R1-B144: 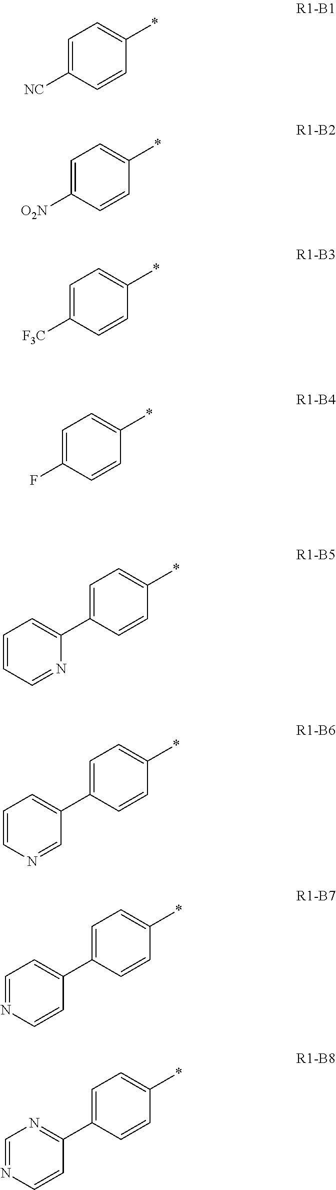 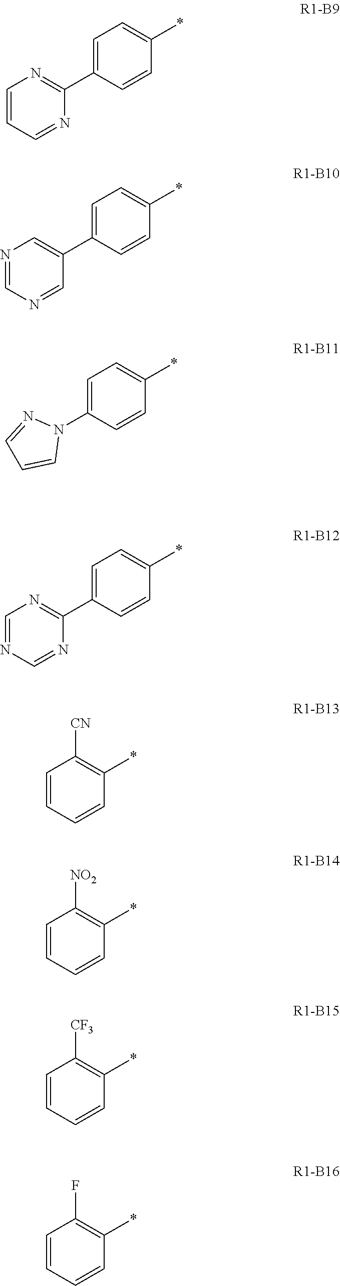 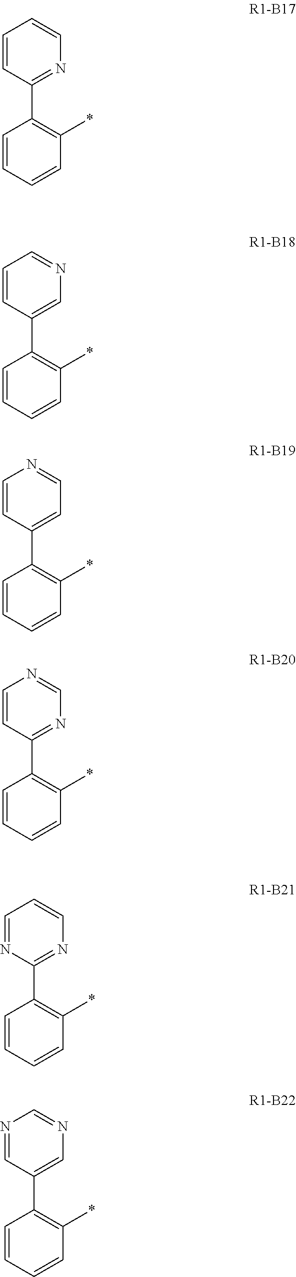 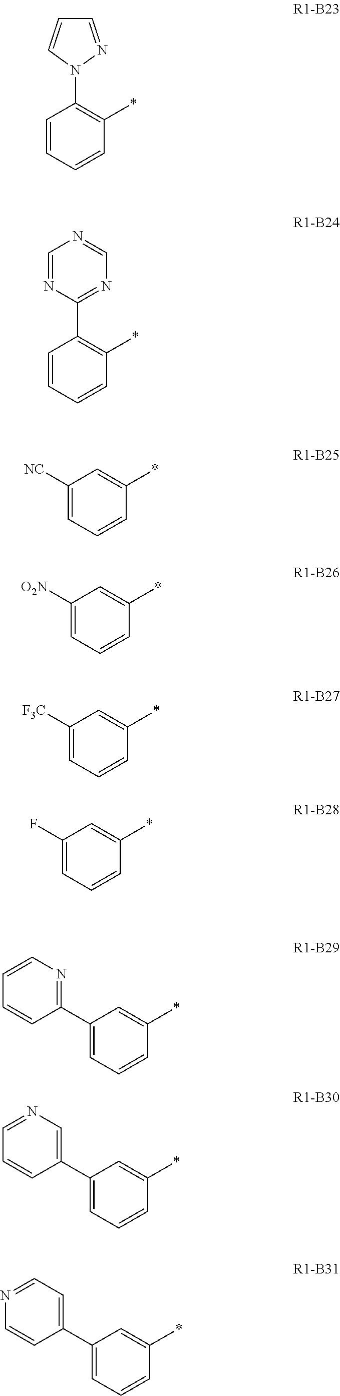 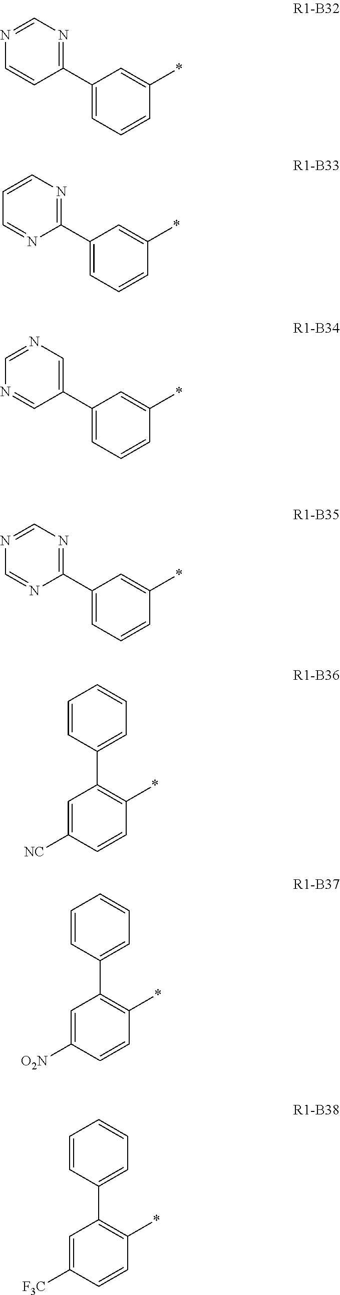 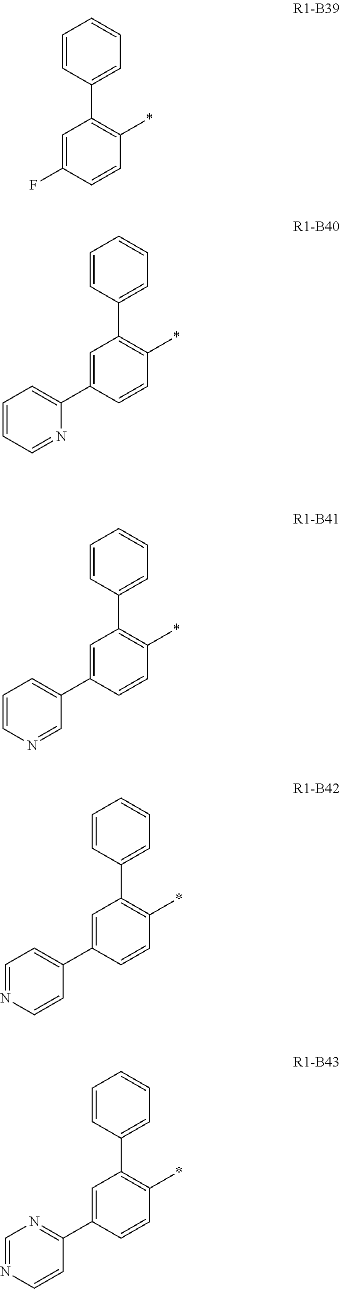 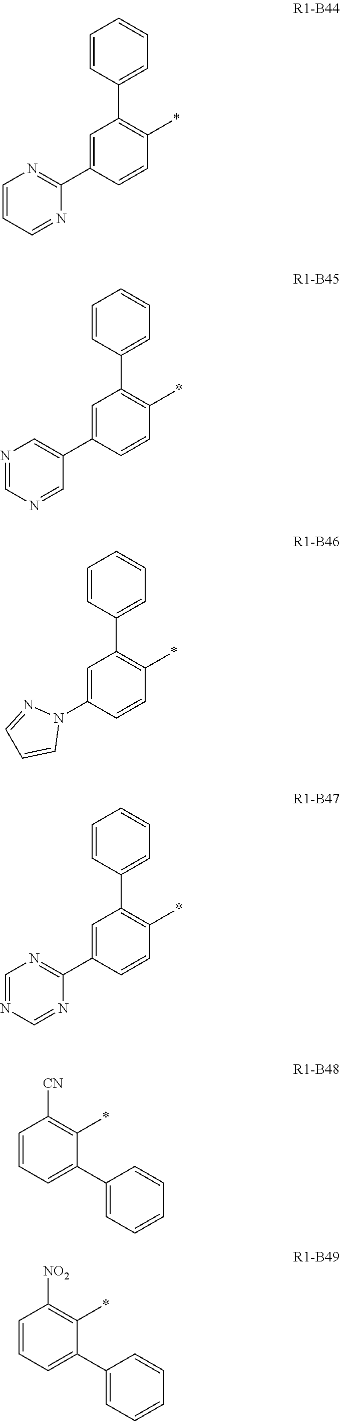 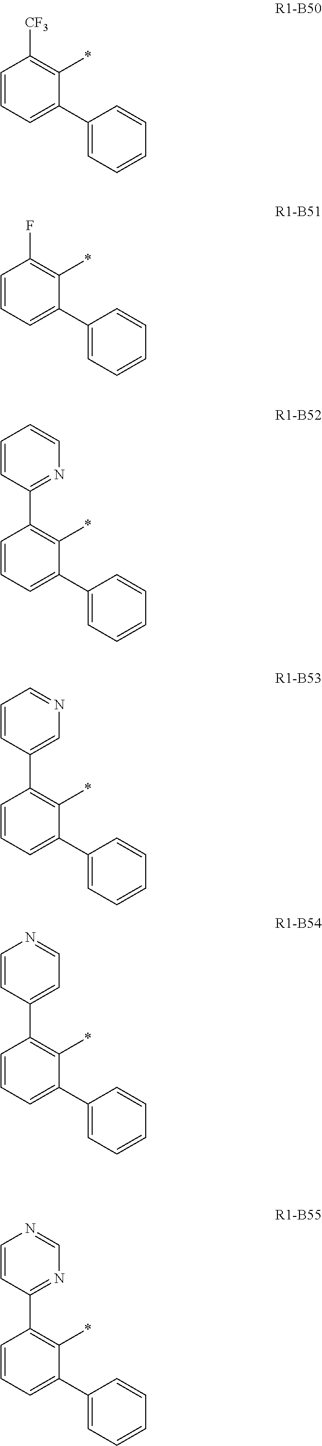 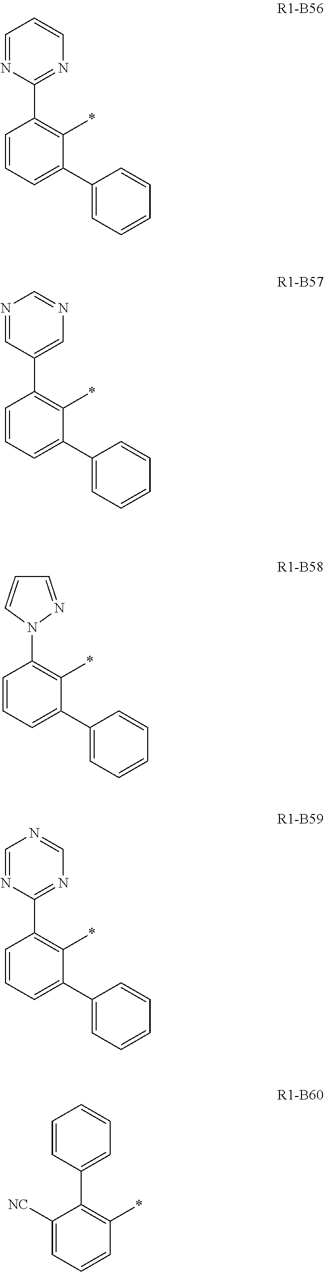 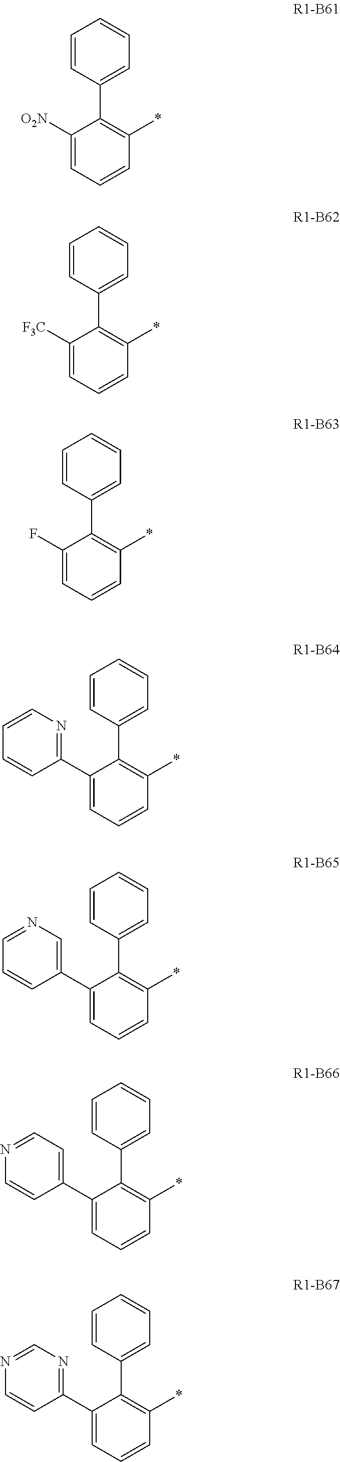 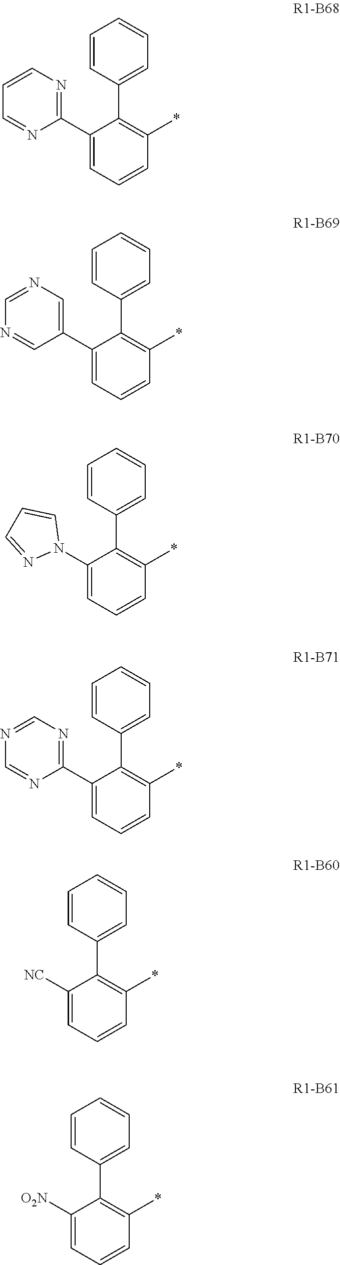 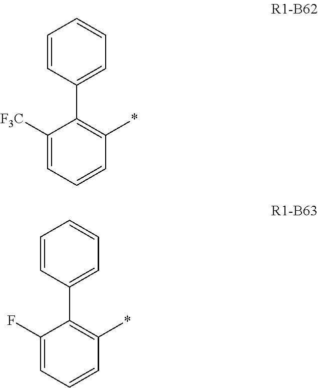 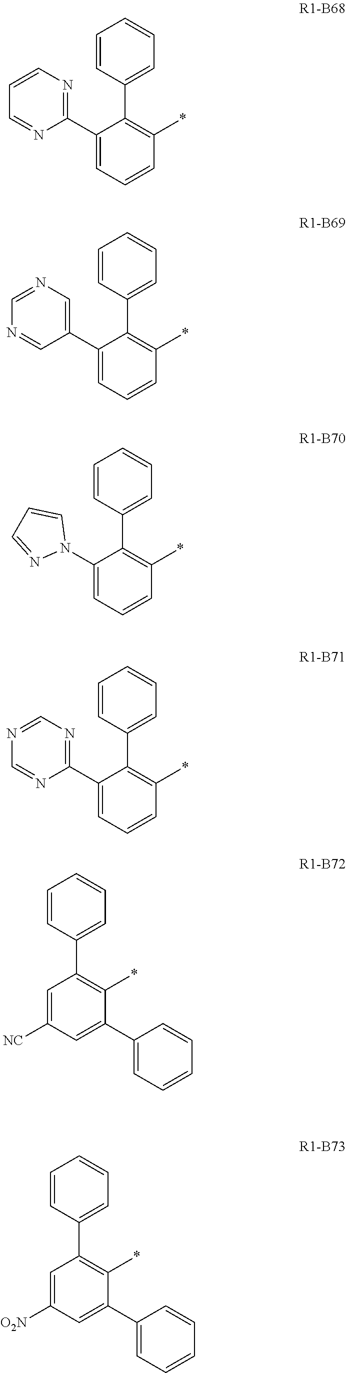 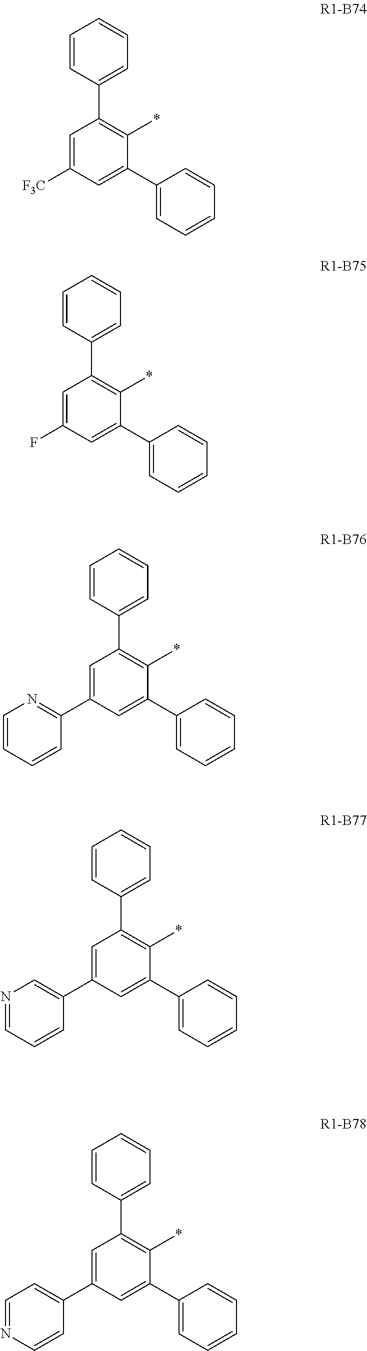 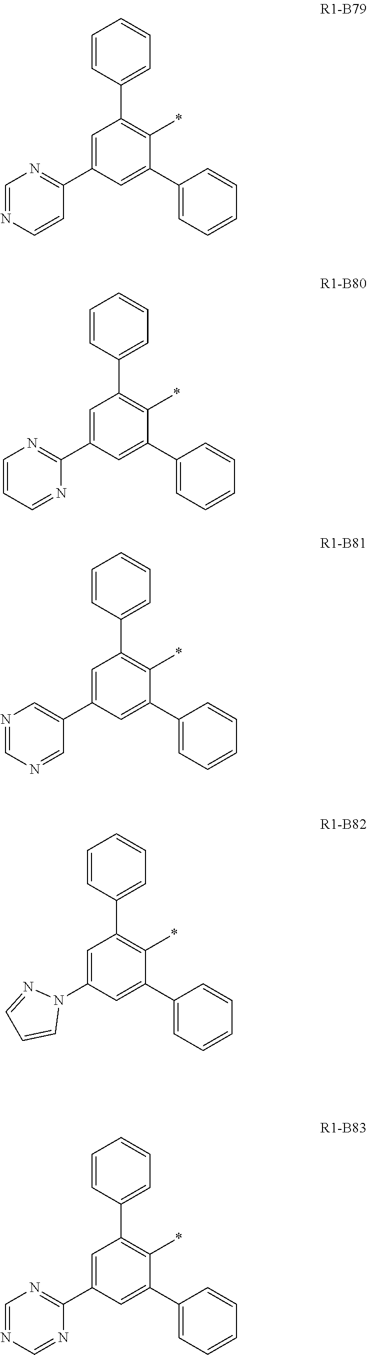 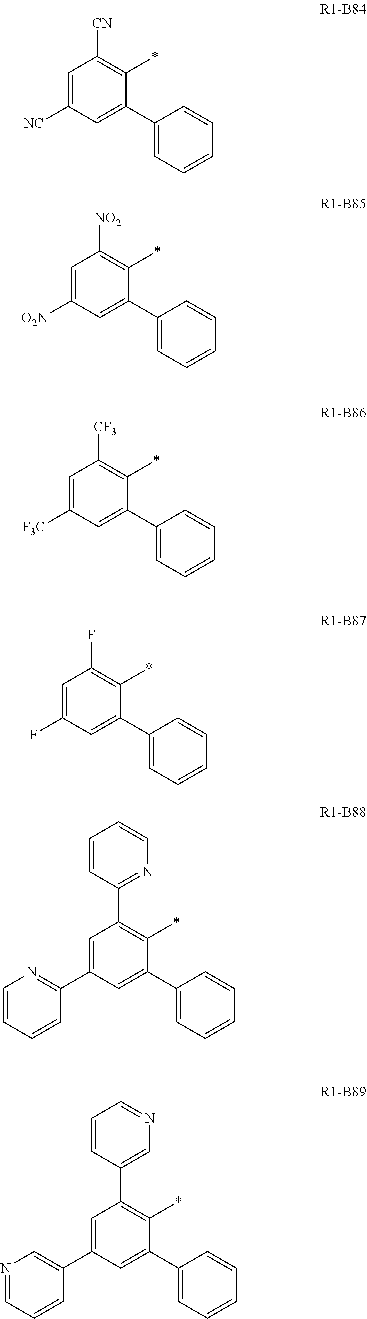 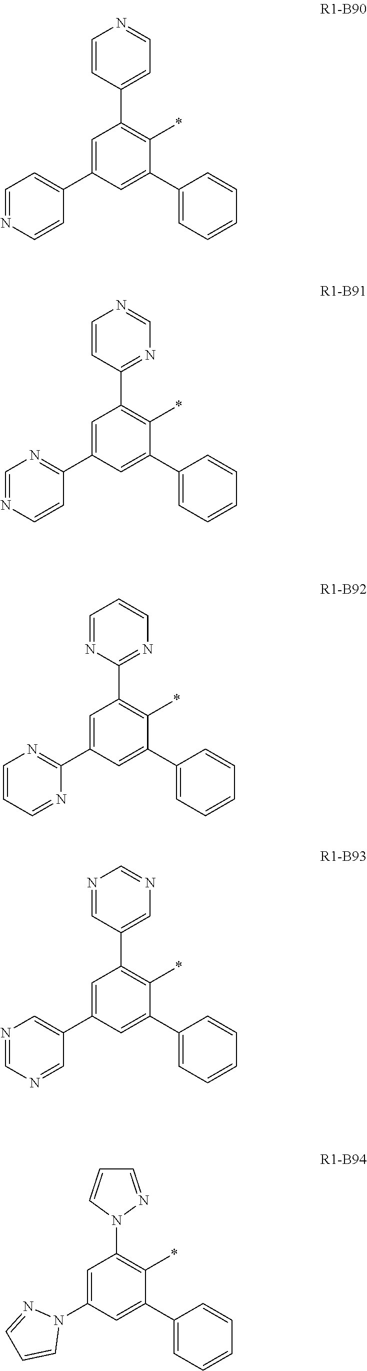 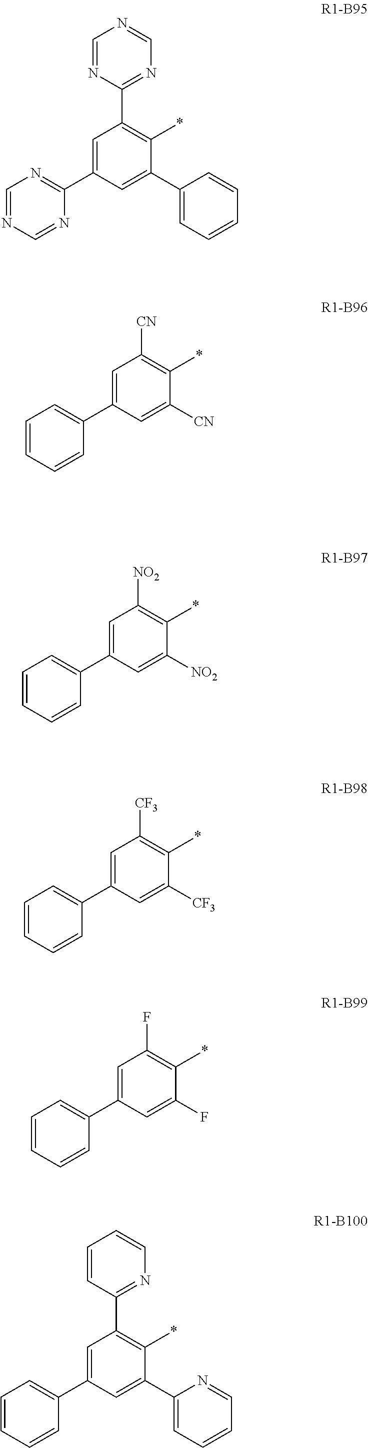 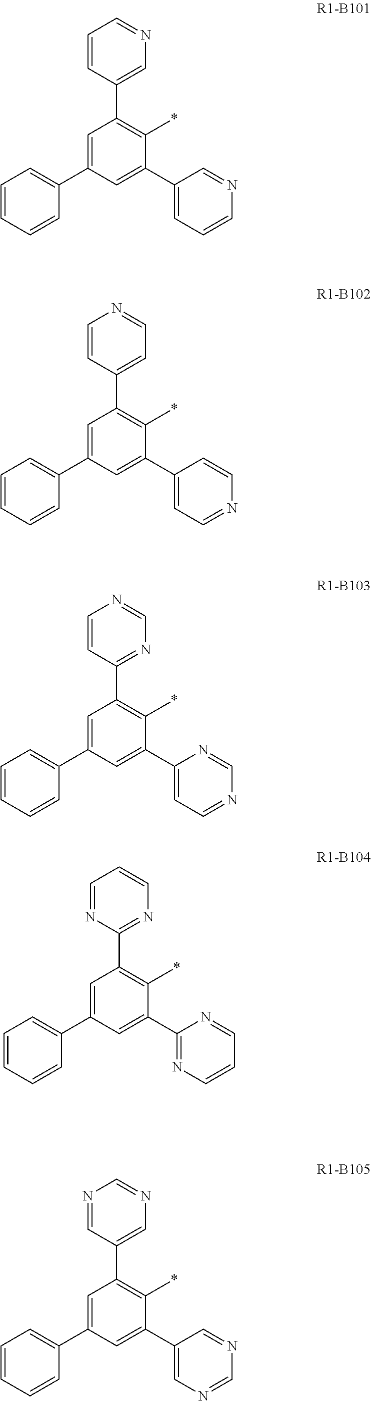 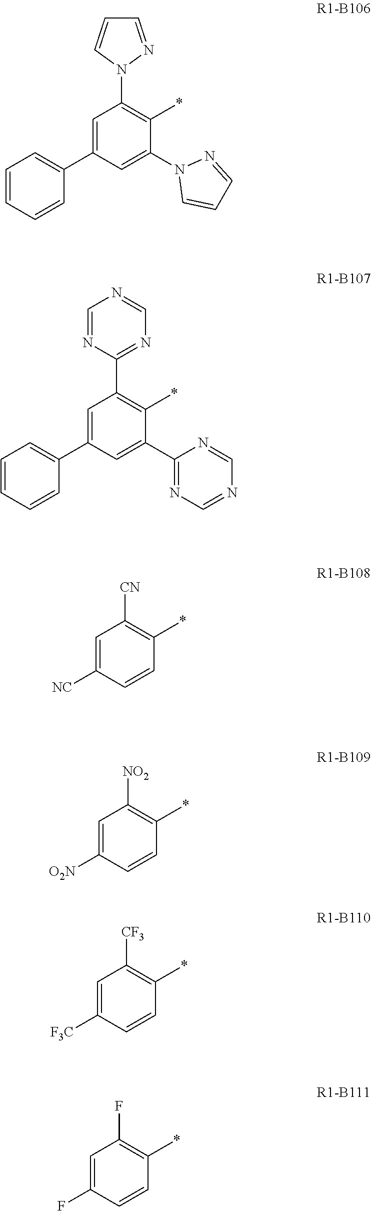 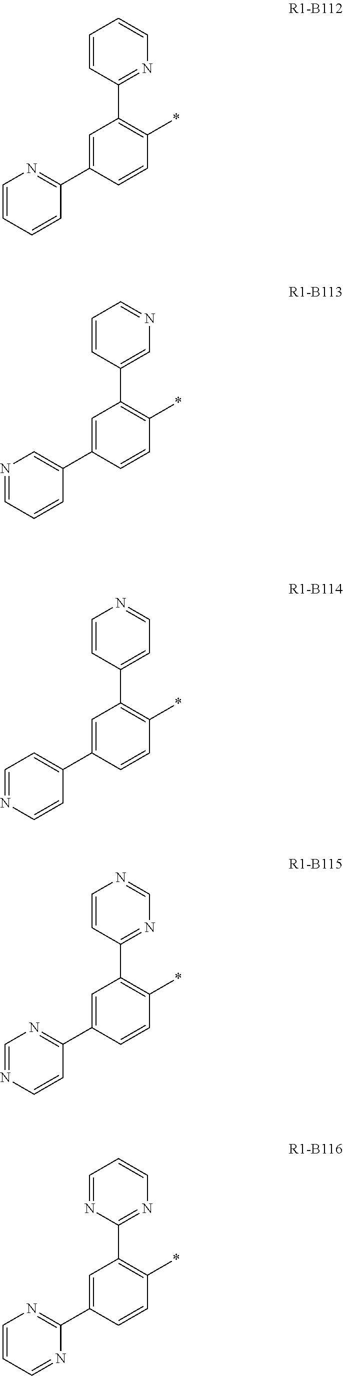 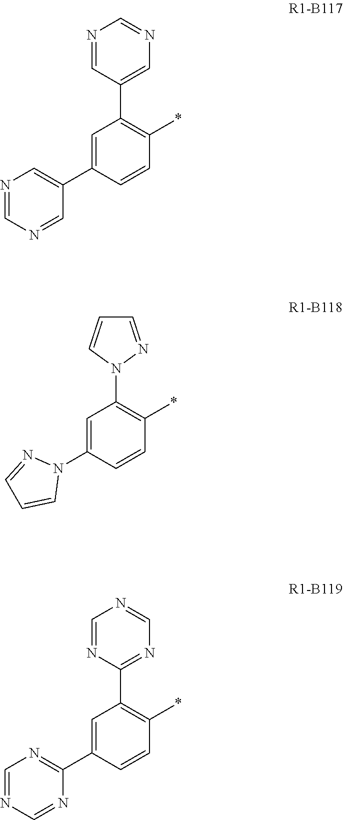 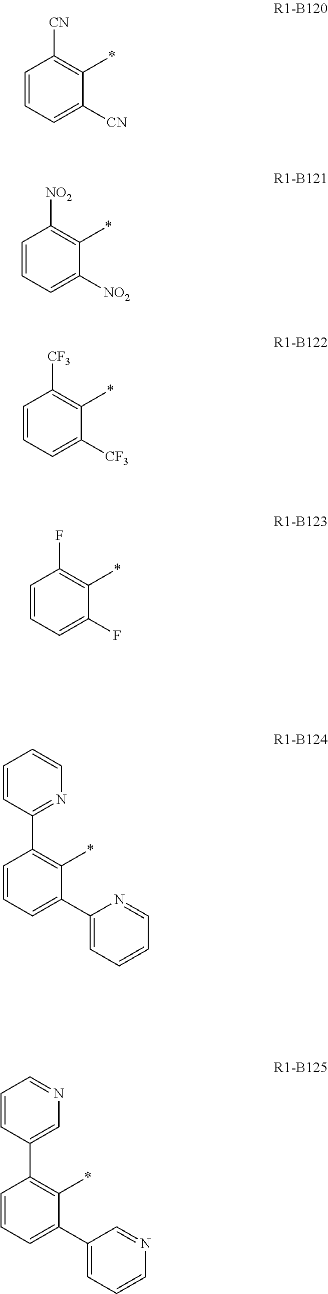 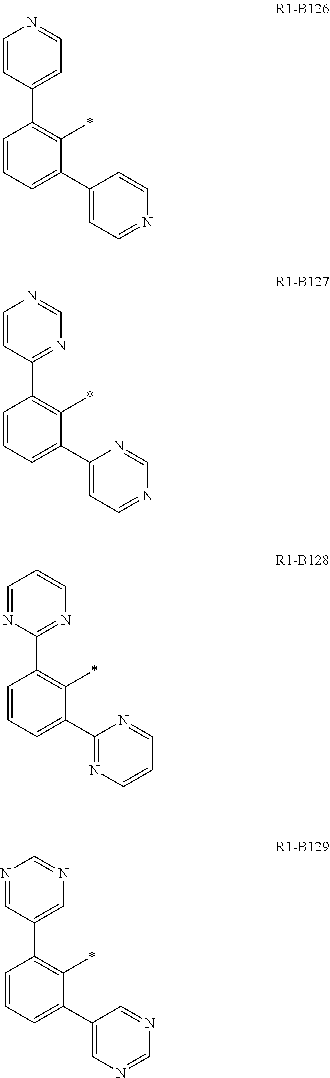 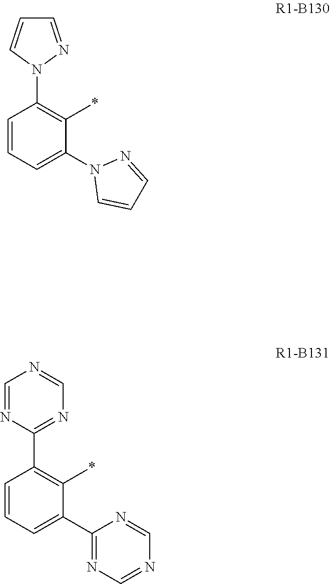 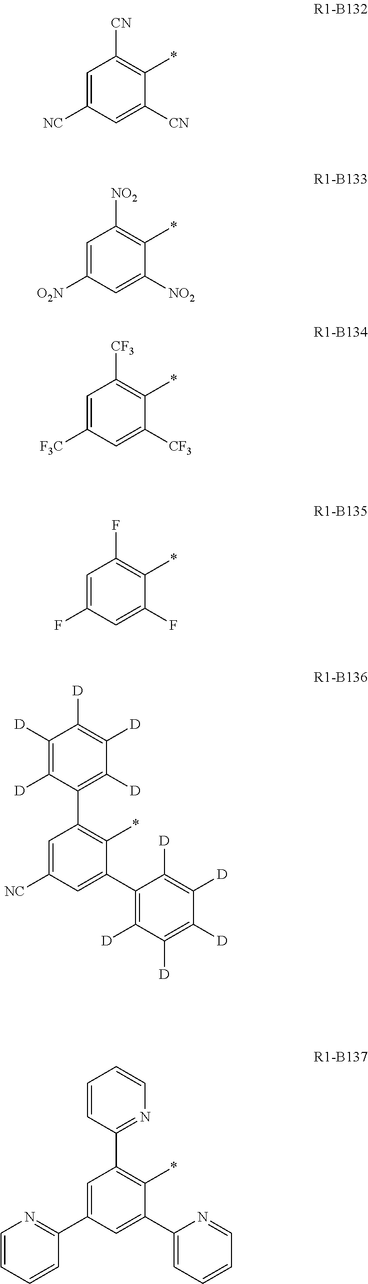 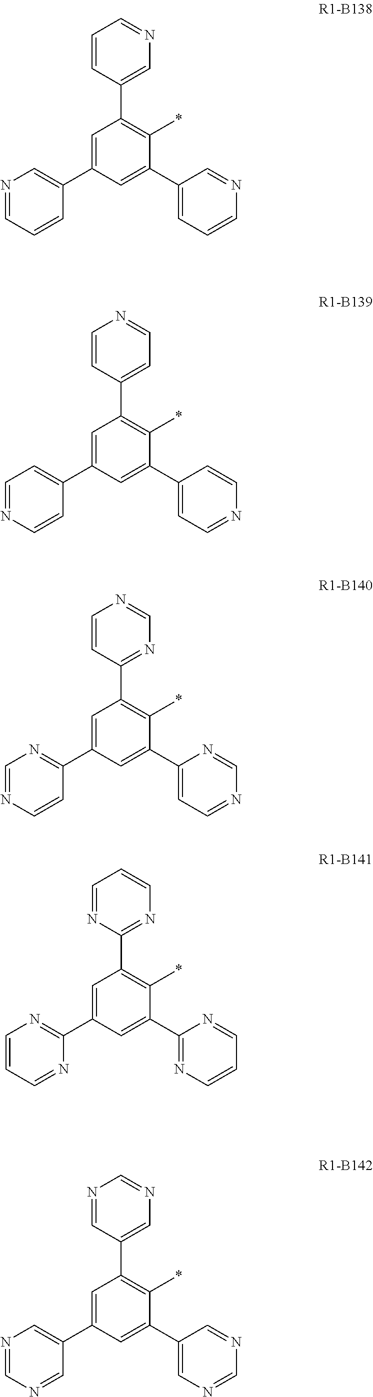 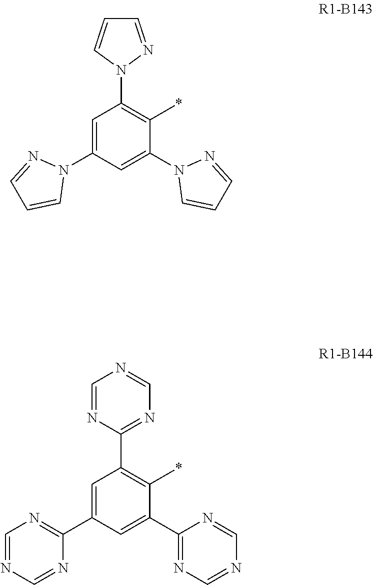
wherein, in R1-B136 above, D is a deuterium atom.

6. The light-emitting element of claim 3, wherein, in Formula 1-A3 to Formula 1-A5, a second cyclic group comprising R_{b21} to R_{b25}, and a third cyclic group comprising R_{b31} to R_{b35} are each independently represented by one of R2-B1 to R2-B4: 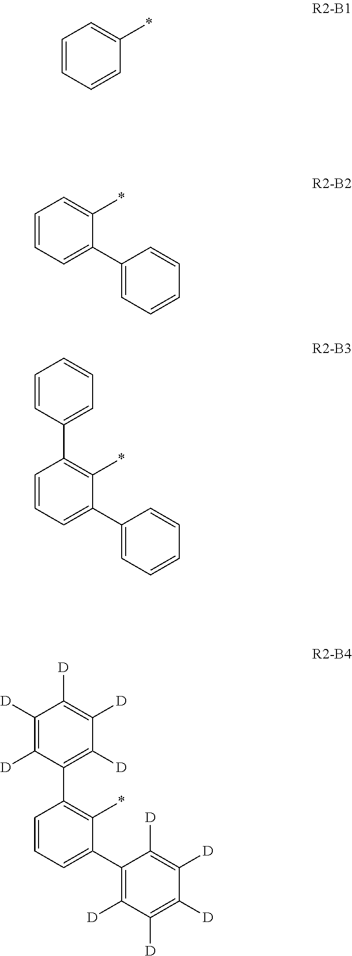
wherein, in R2-B4, D is a deuterium atom.

7. The light-emitting element of claim 1, wherein Formula 1 is represented by Formula 1-B: 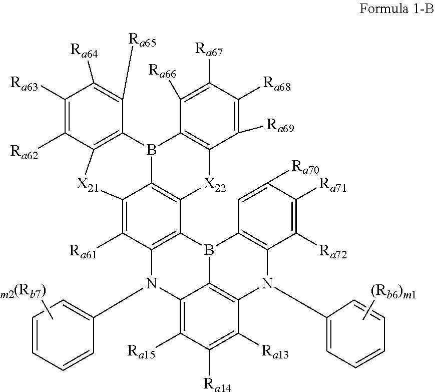
wherein, in Formula 1-B,
X₂₁ and X₂₂ are each independently O, S, or NRₙ₃, wherein at least one of X₂₁ or X₂₂ is NRₙ₃,
each Rₙ₃ is independently a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, E_{w}, or a group represented by Formula 2,
m1 and m2 are each independently an integer of 0 to 5,
R_{b6} and R_{b7} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w},
Rₐ₆₁ to Rₐ₆₉ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w},
Rₐ₇₀ to Rₐ₇₂ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
provided that at least one of Rₙ₃, R_{b6}, R_{b7}, or Rₐ₆₁ to Rₐ₆₉ comprises E_{w}, and
Rₐ₁₃ to Rₐ₁₅ are the same as defined in Formula 1.

8. The light-emitting element of claim 1, wherein, in Formula 1, Rₐ₁₃ to Rₐ₁₅ are each independently a hydrogen atom, a deuterium atom, a halogen atom, or a substituted or unsubstituted t-butyl group.

9. The light-emitting element of claim 1, wherein the first compound is represented by a compound from Compound Group 1: 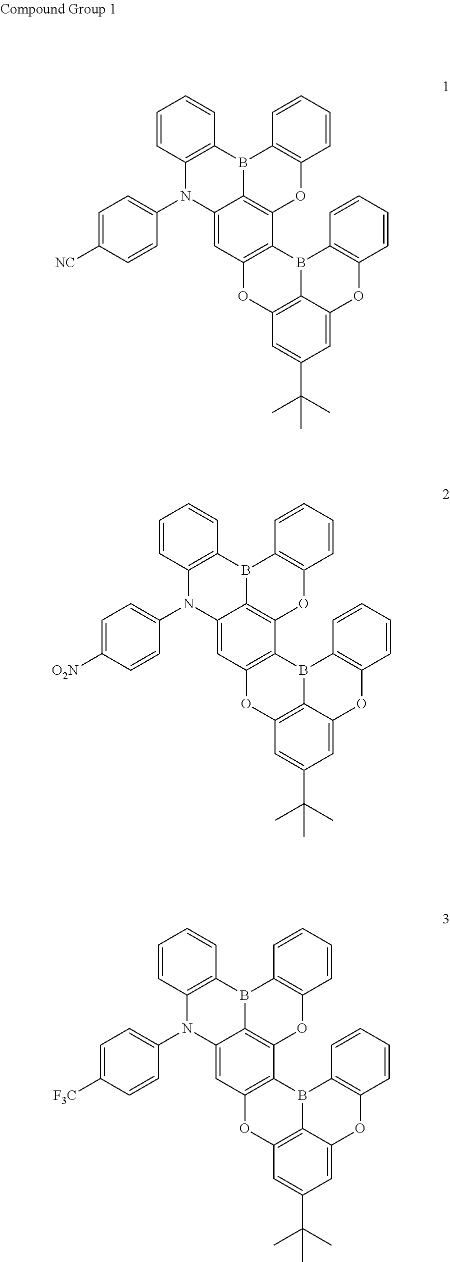 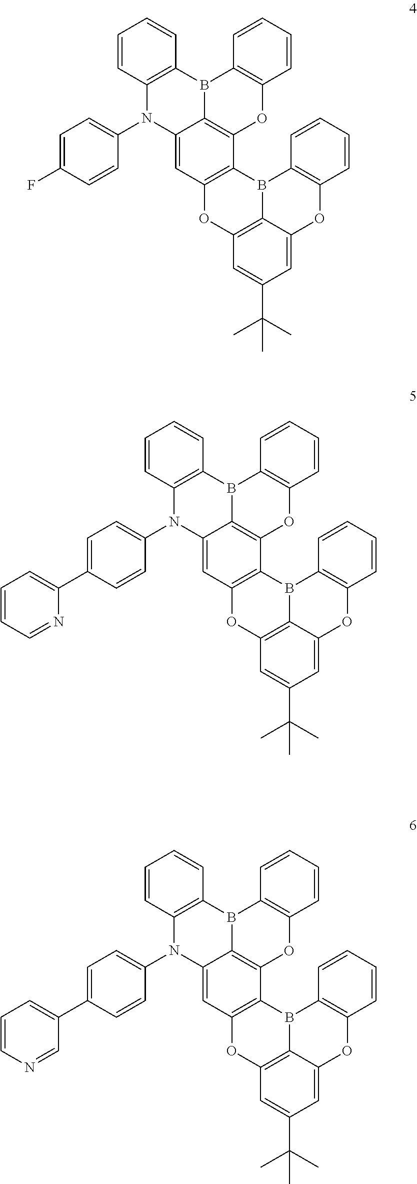 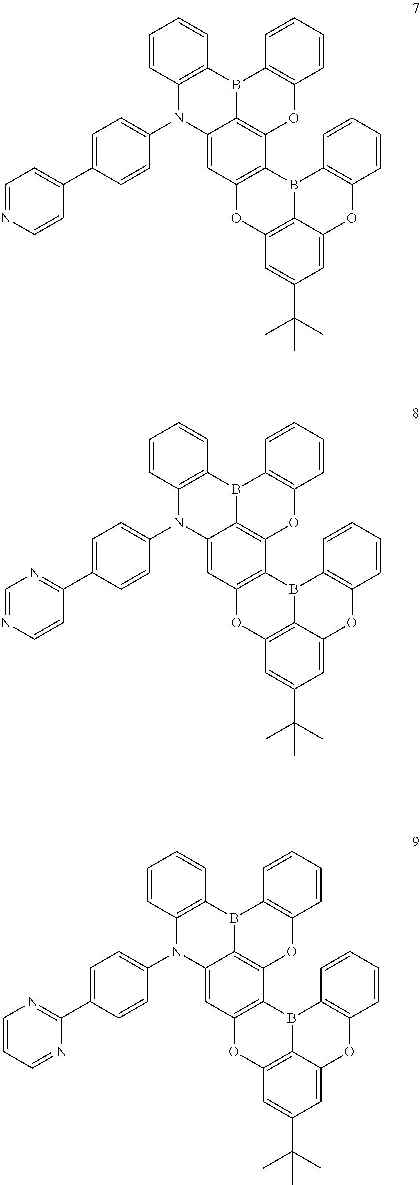 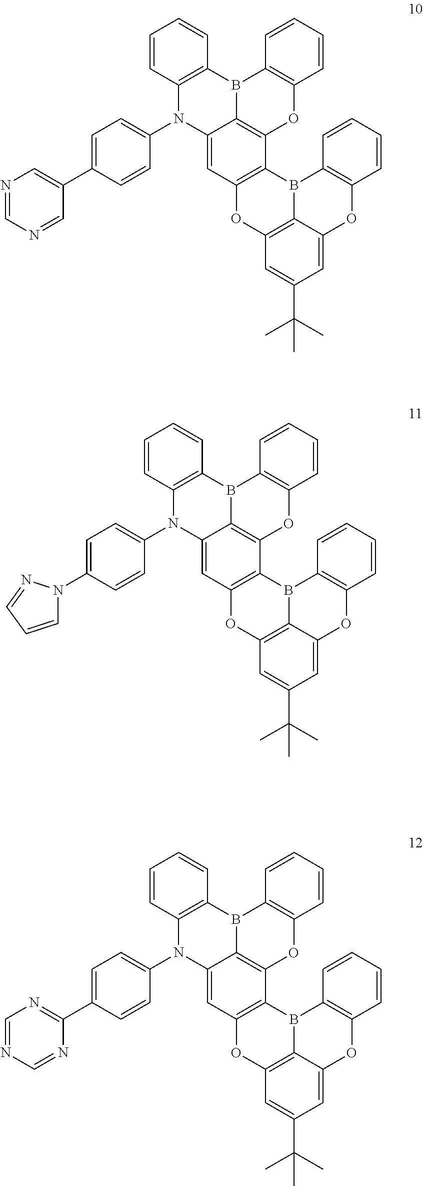 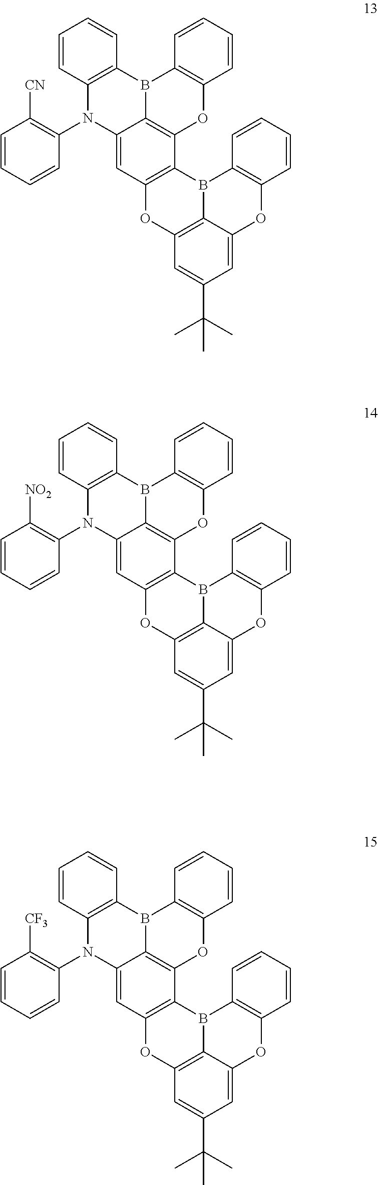 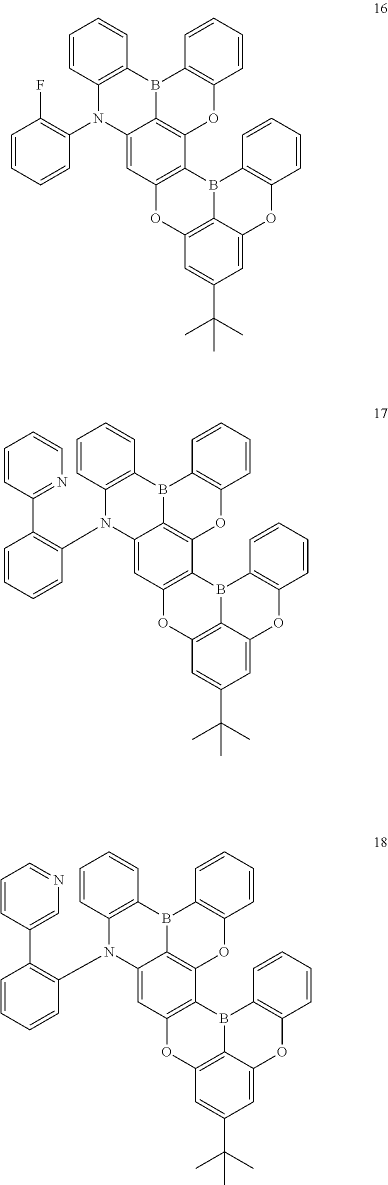 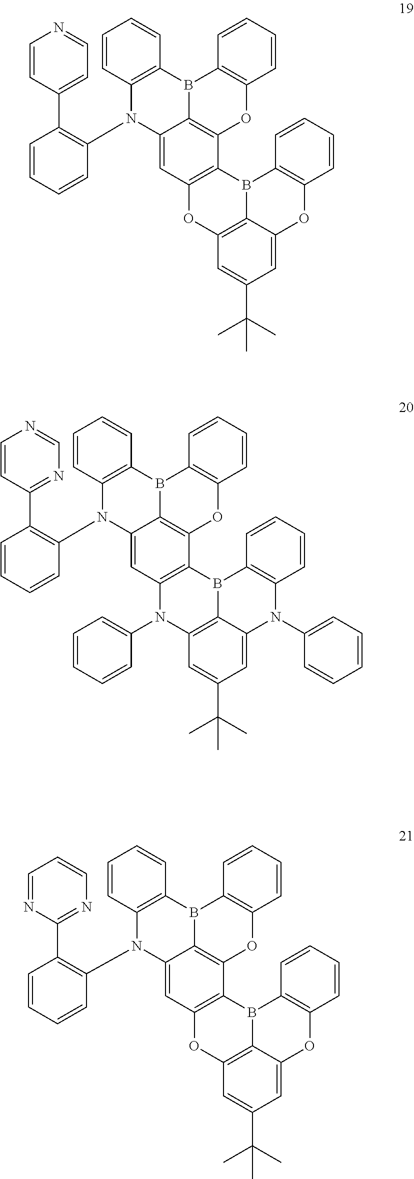 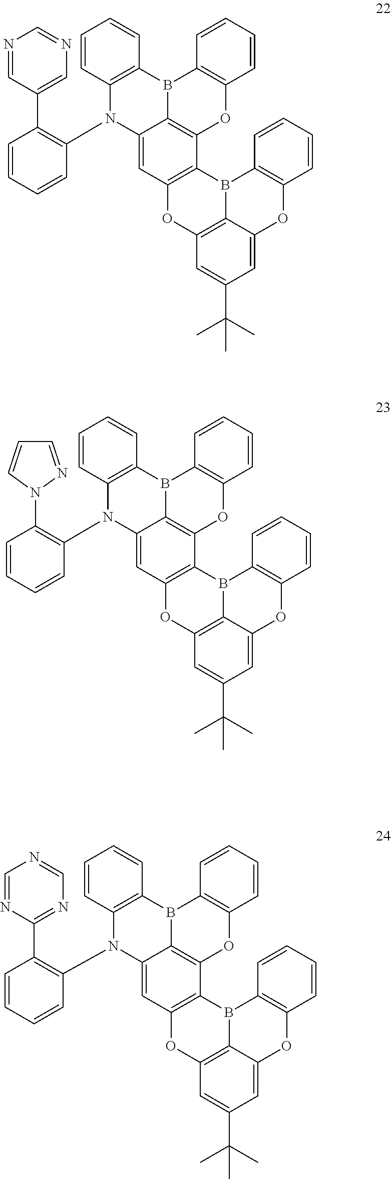 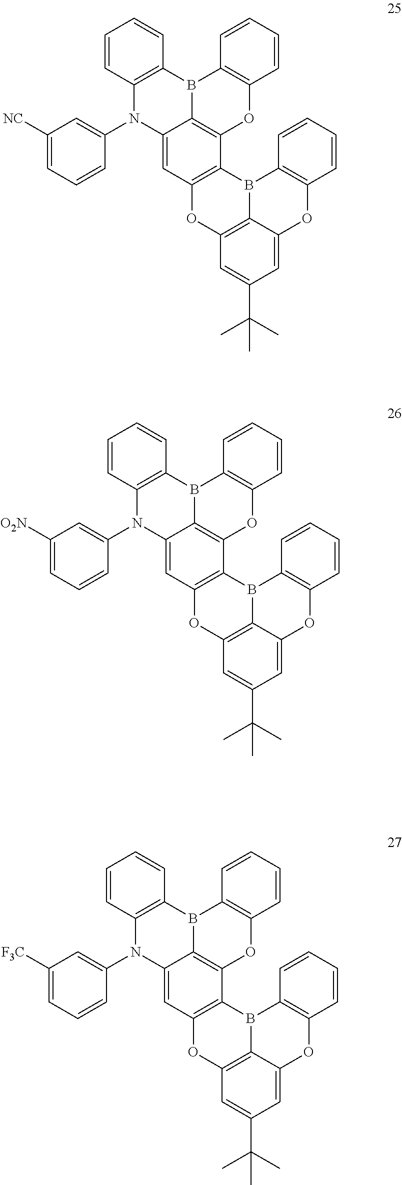 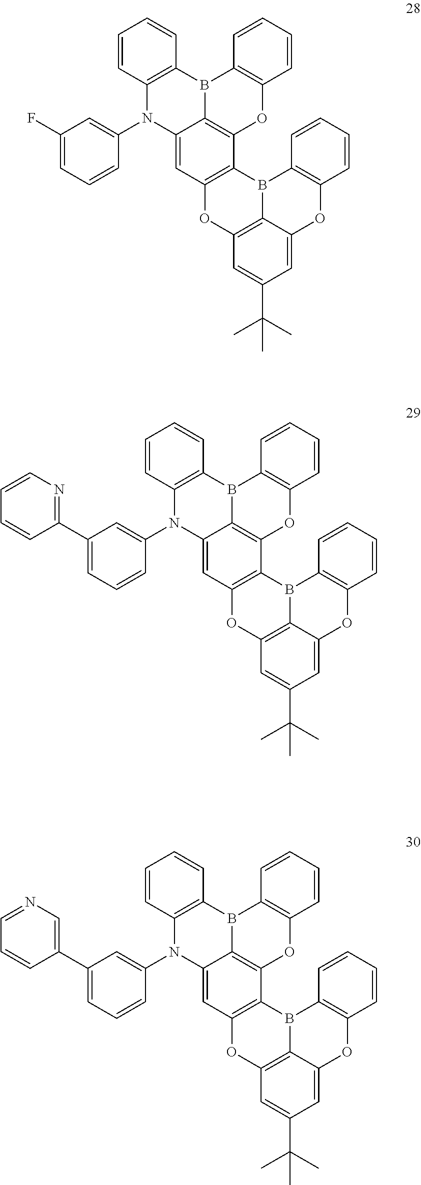 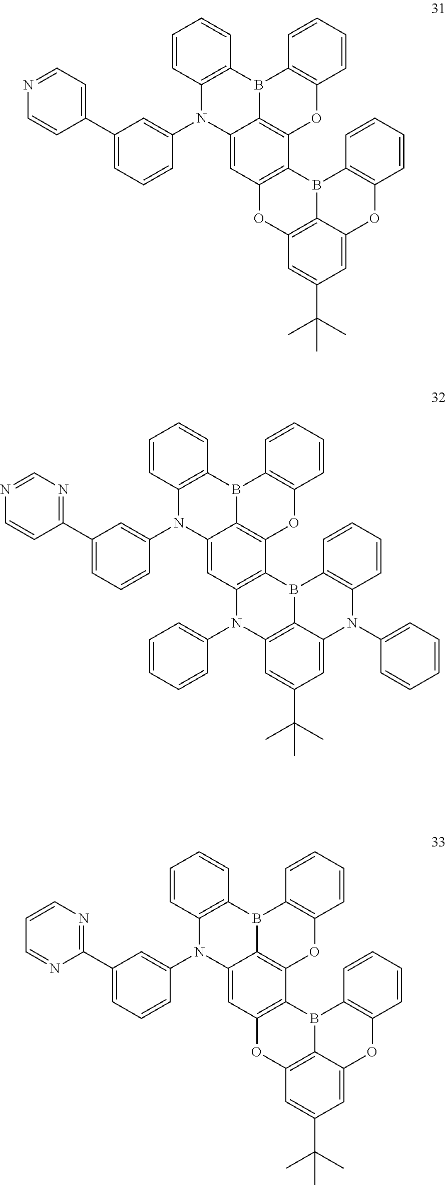 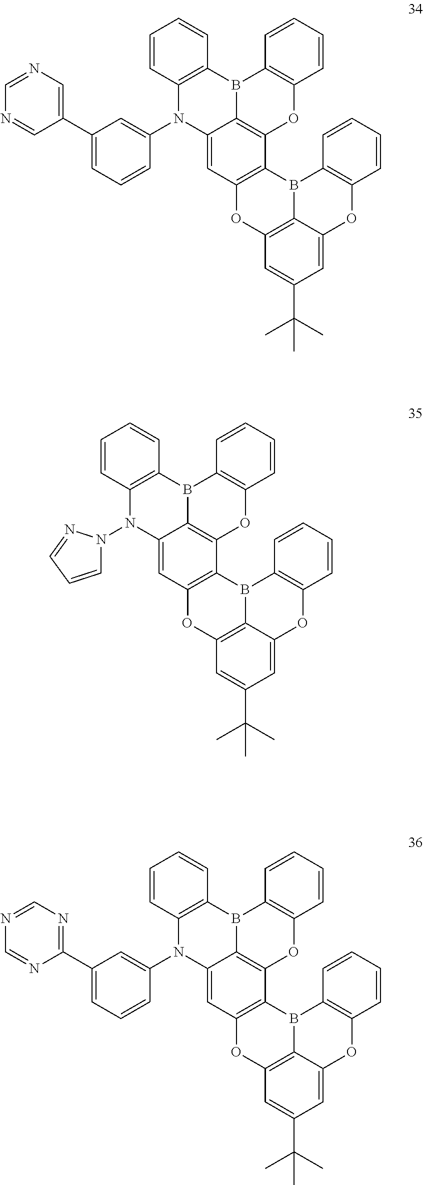 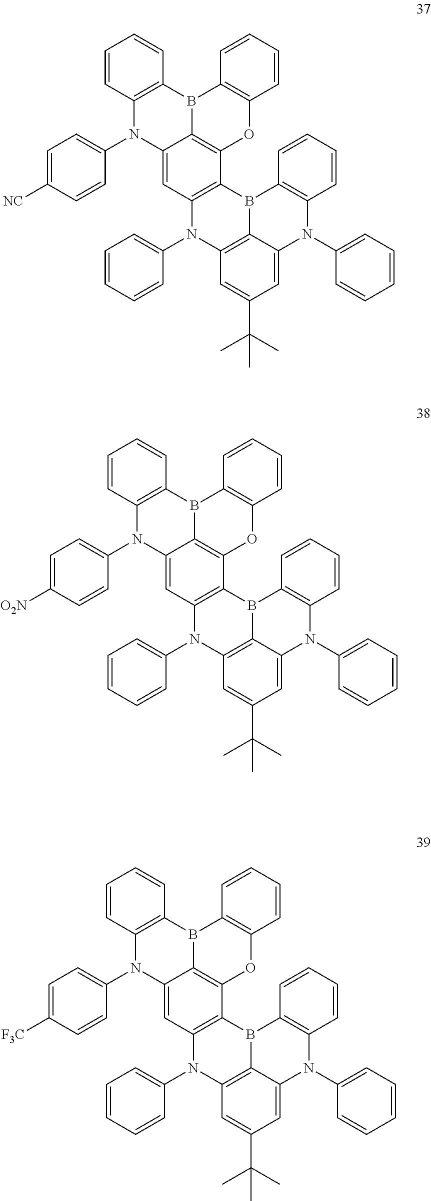 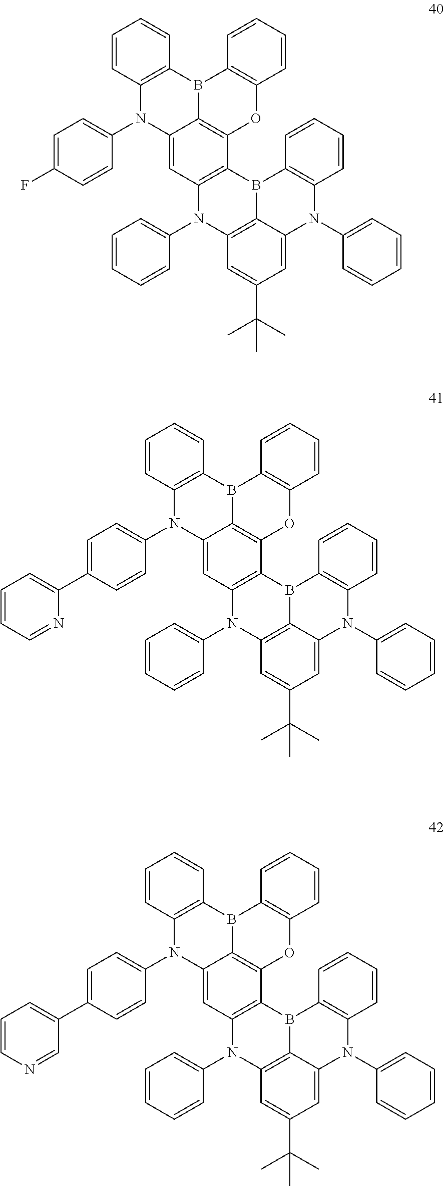 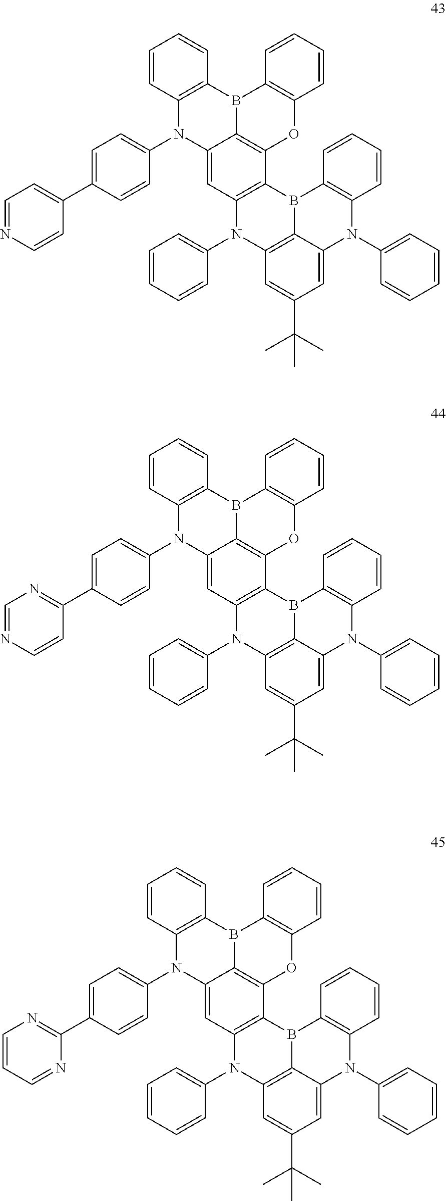 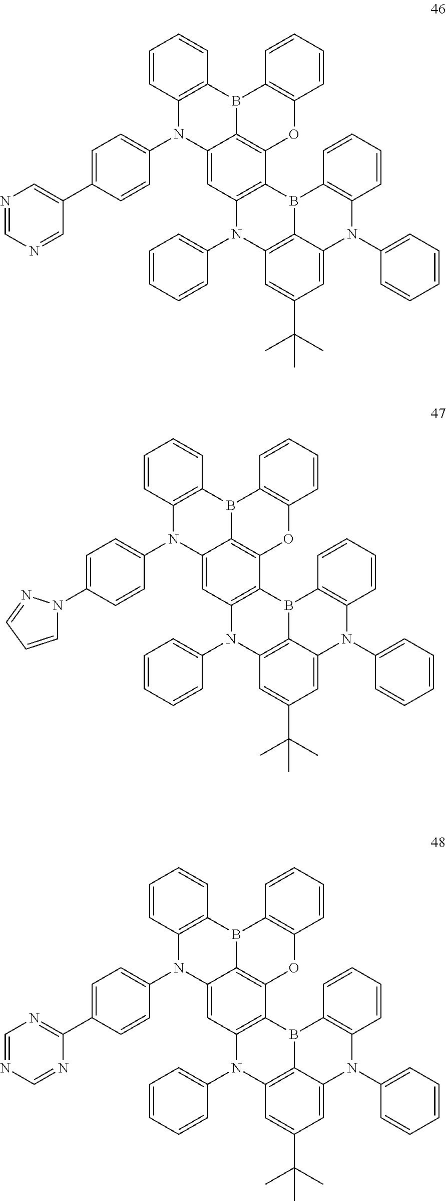 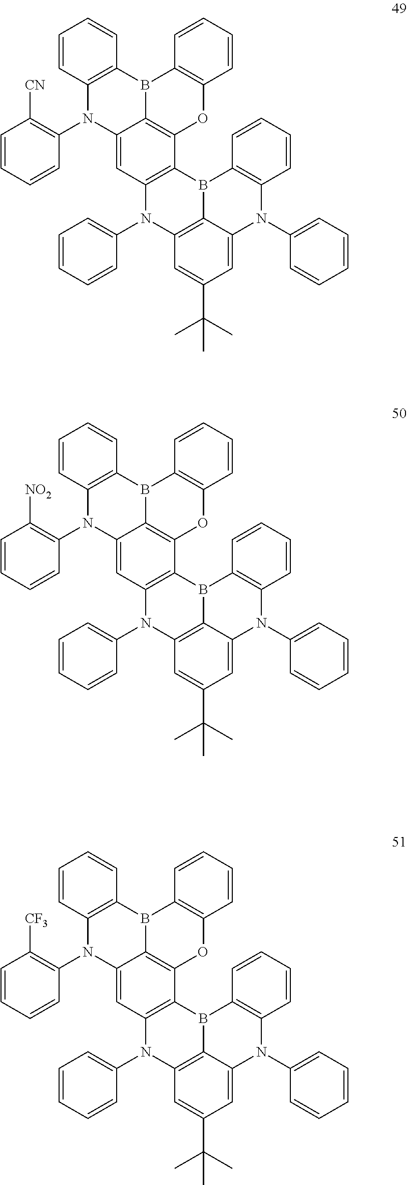 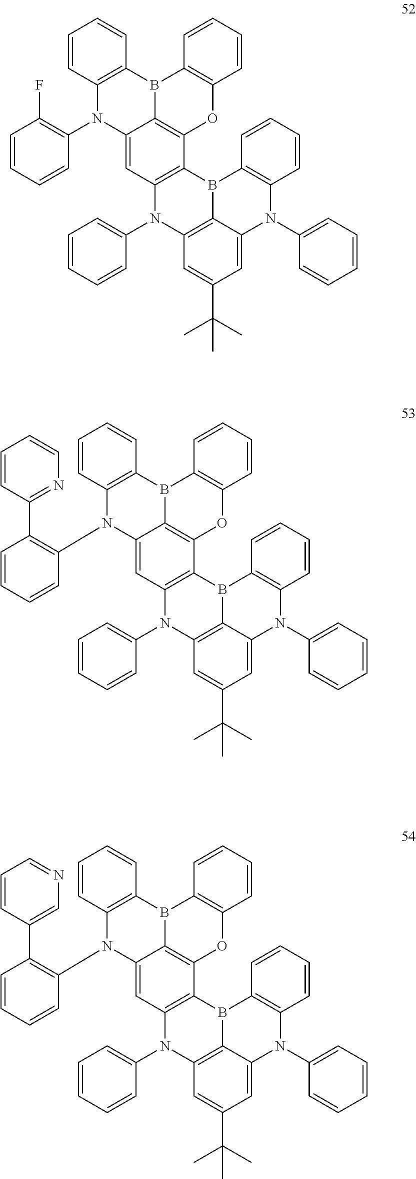 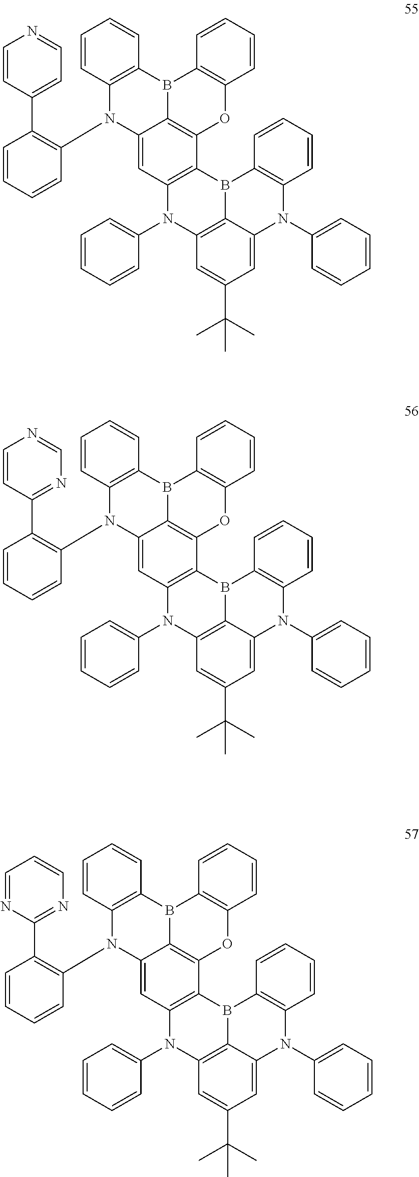 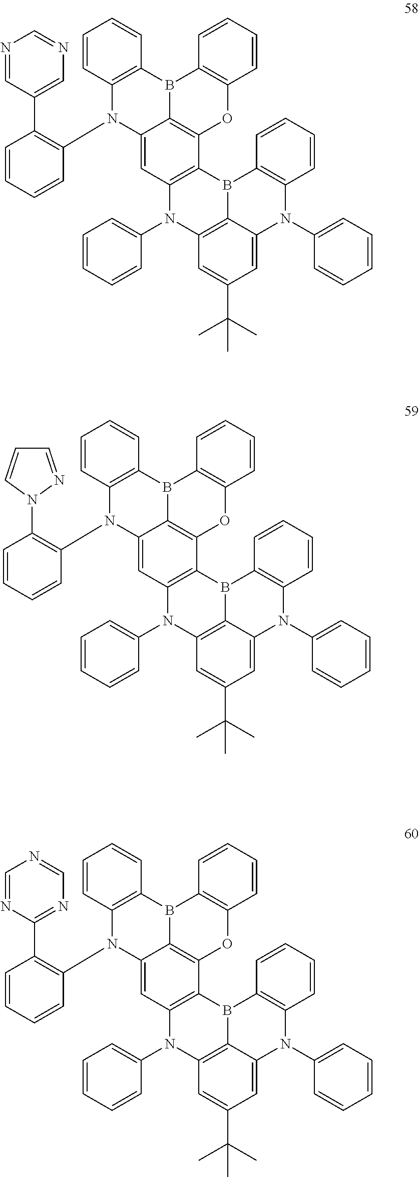 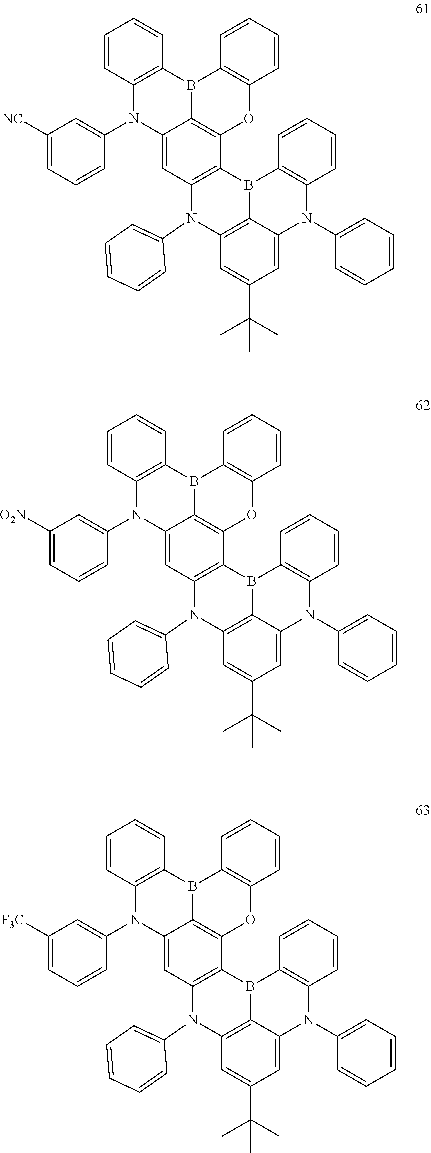 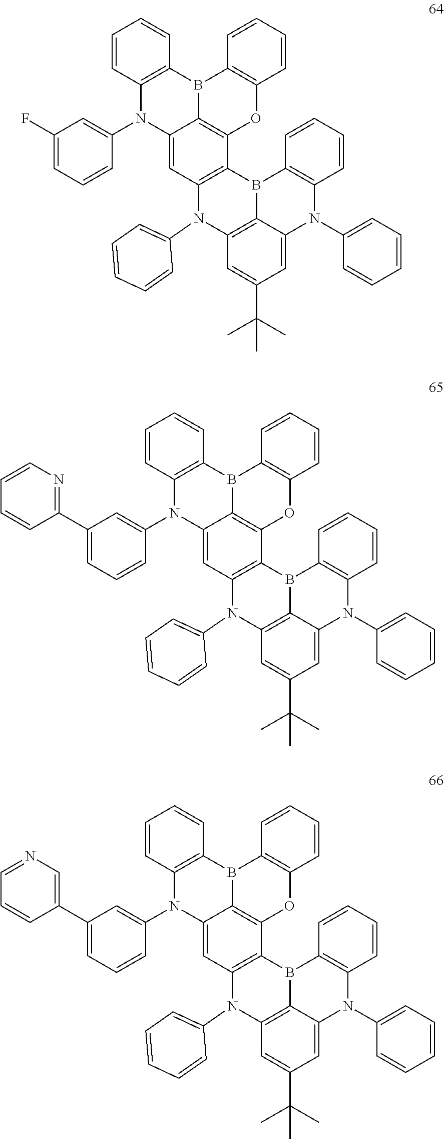 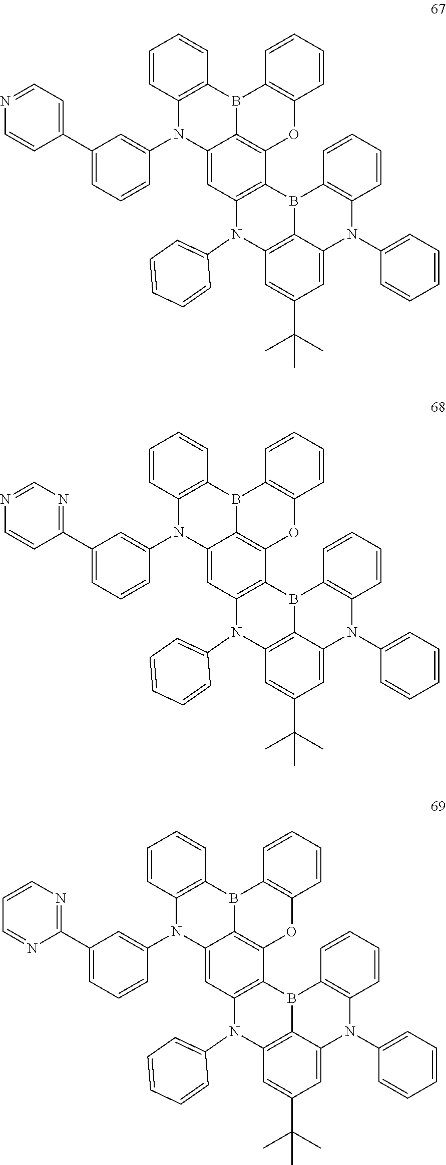 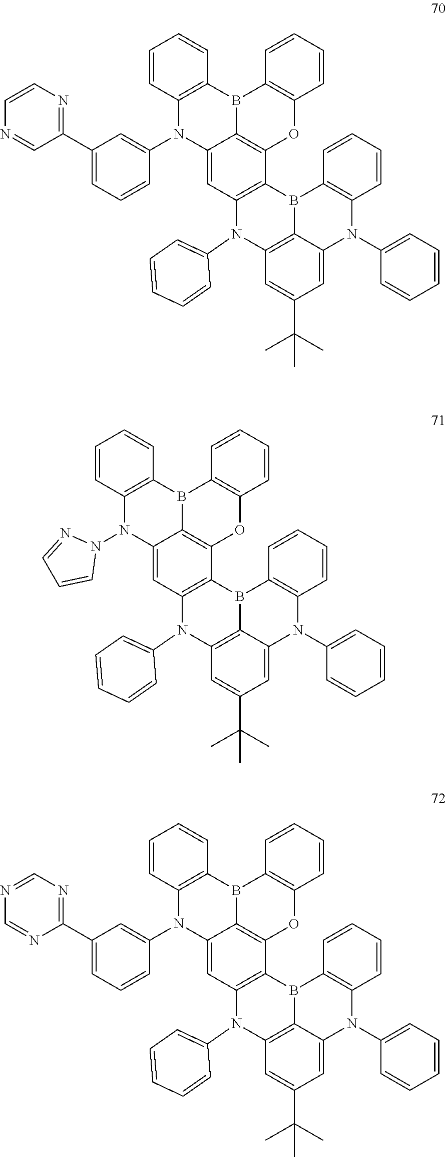 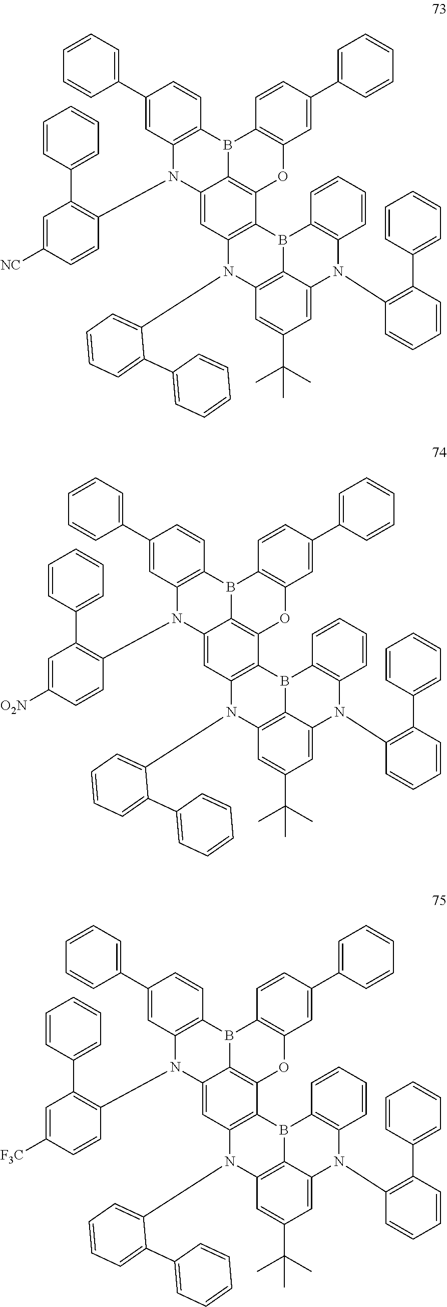 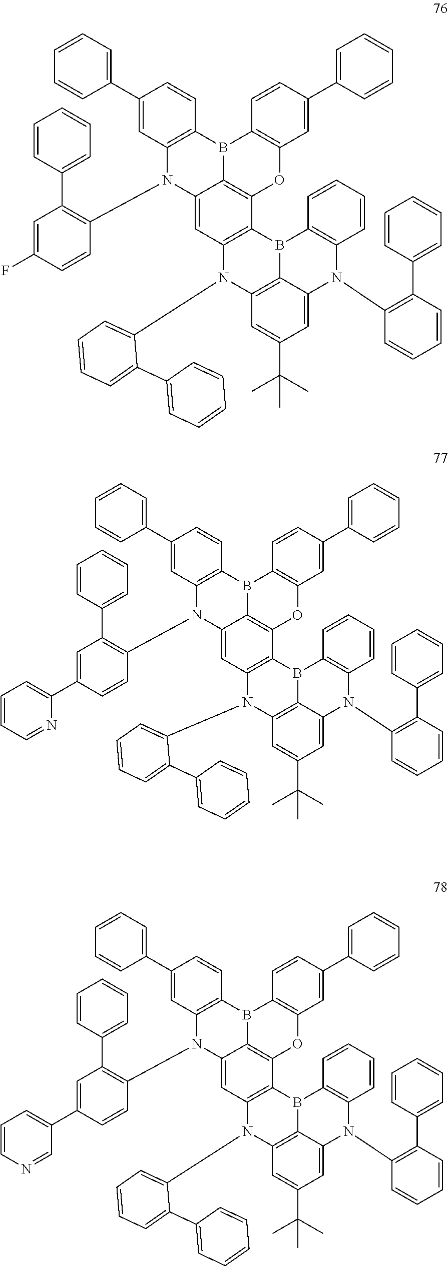 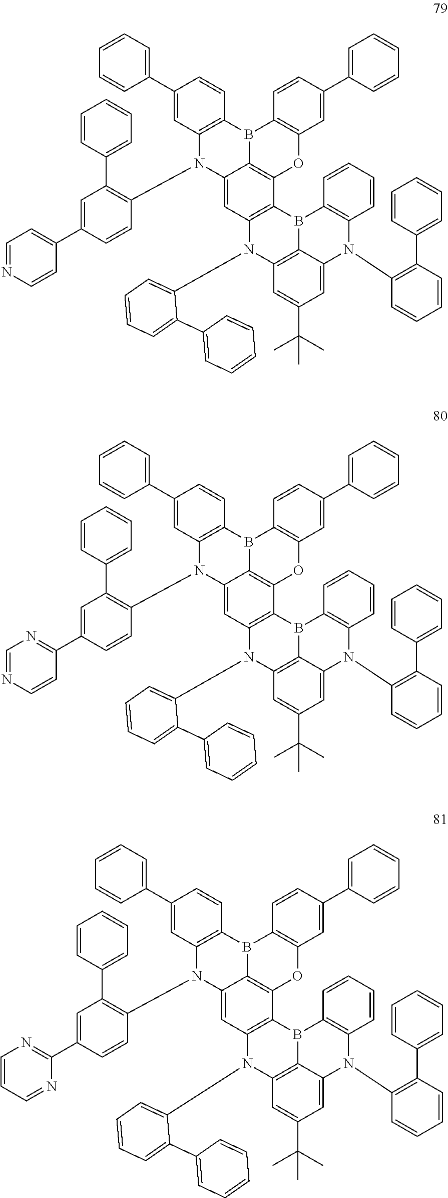 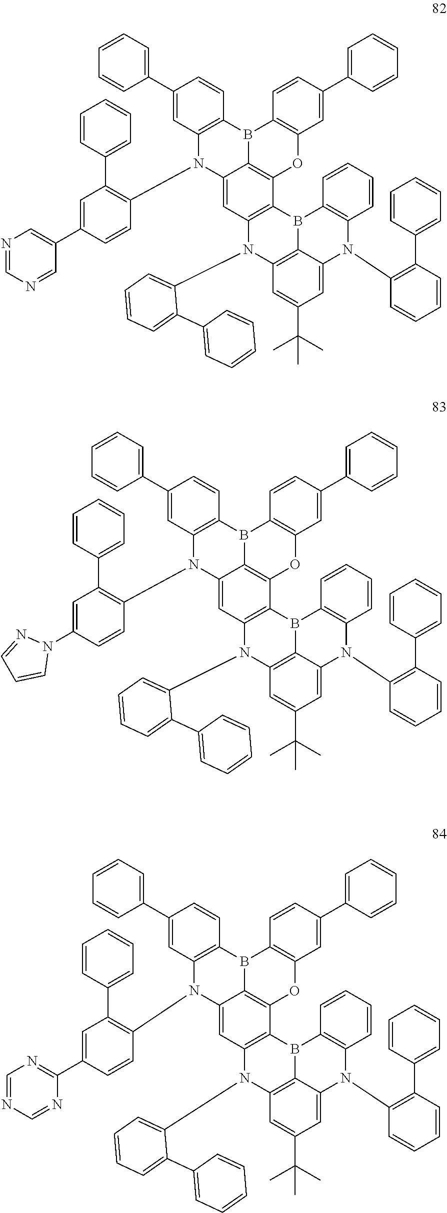 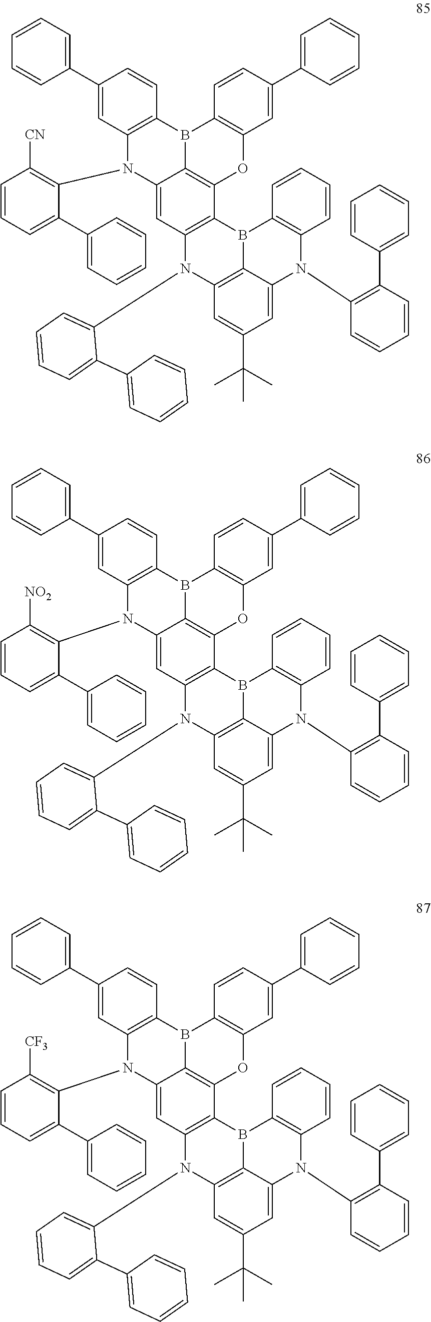 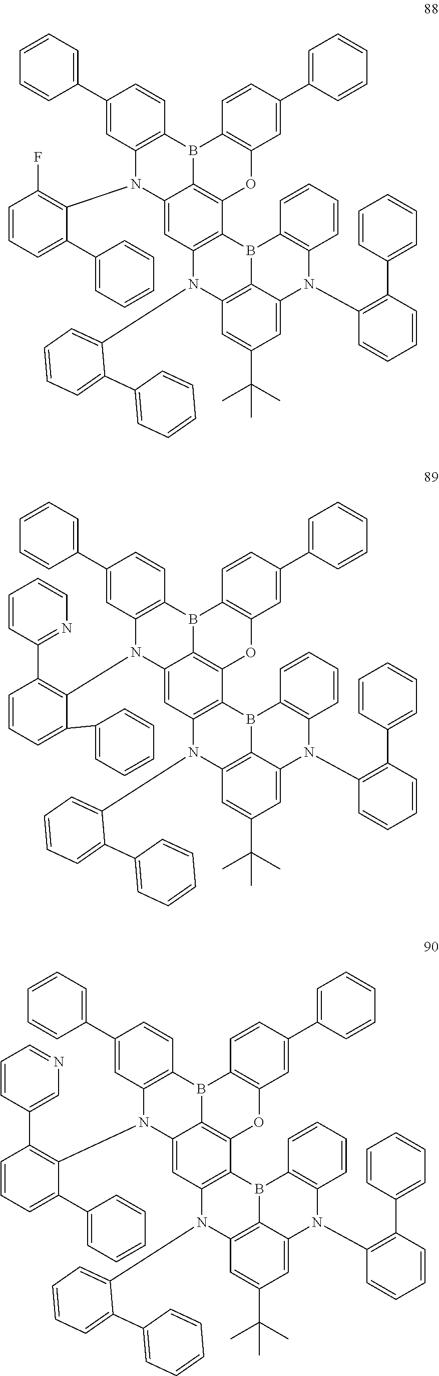 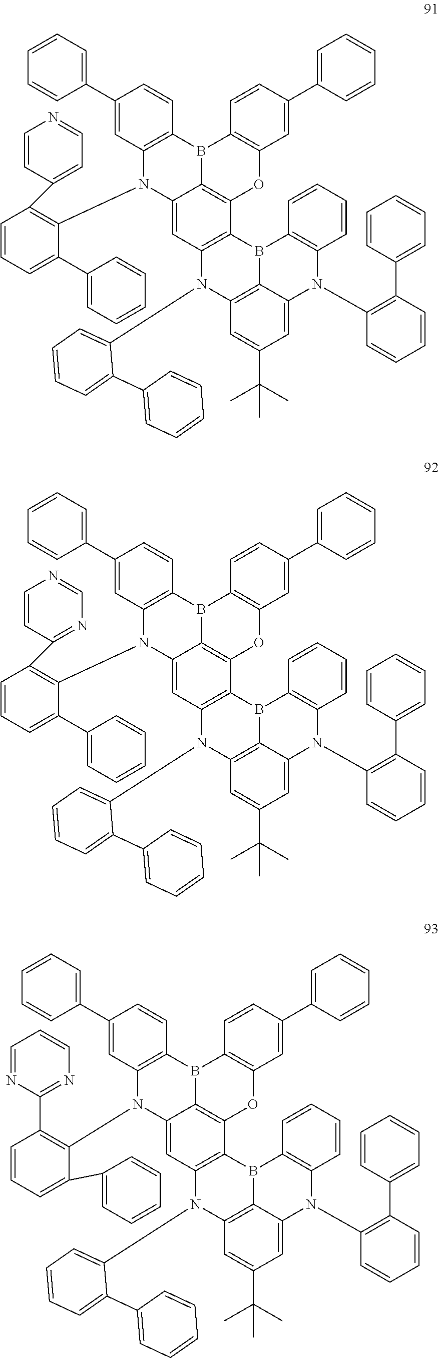 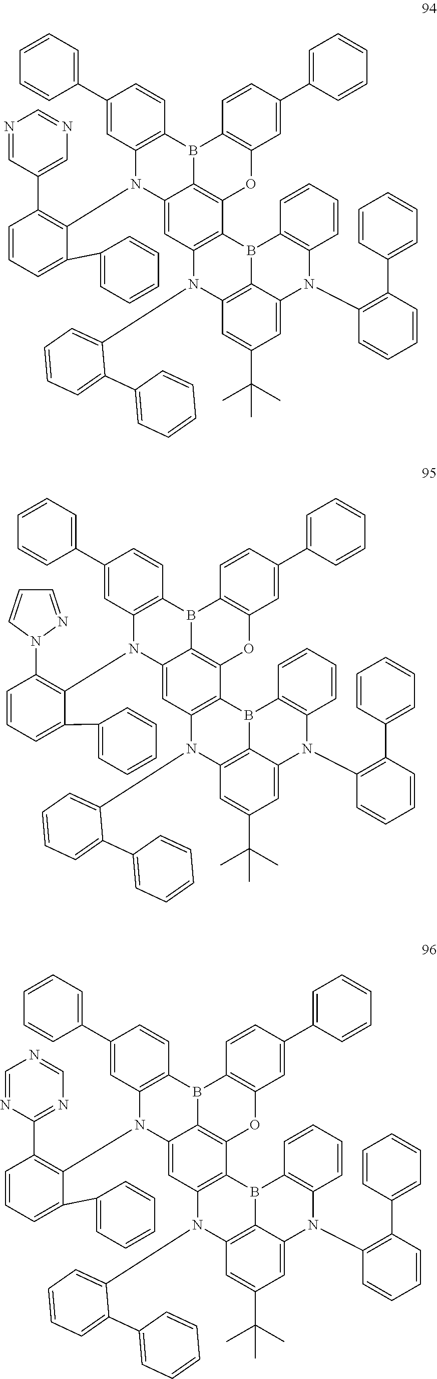 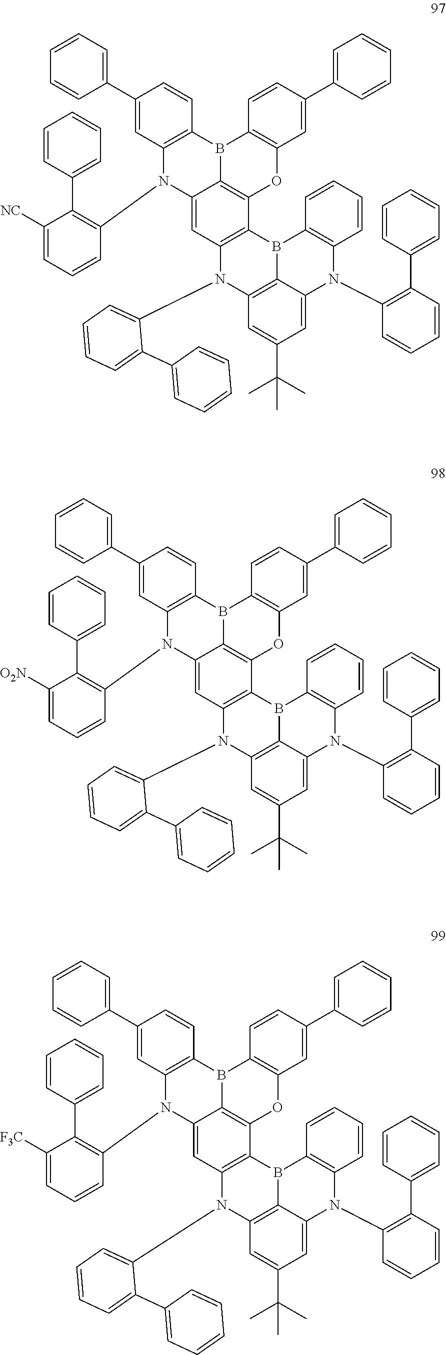 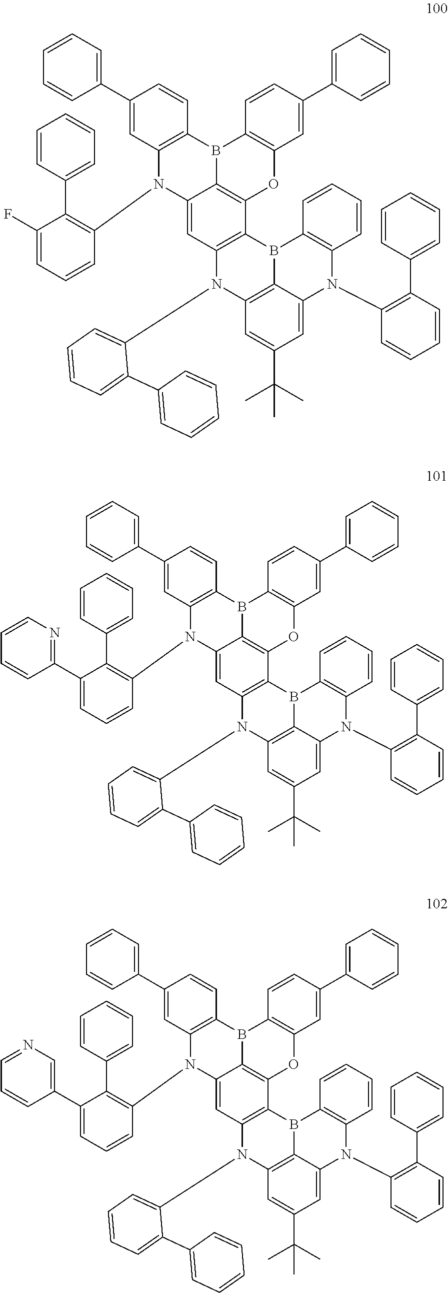 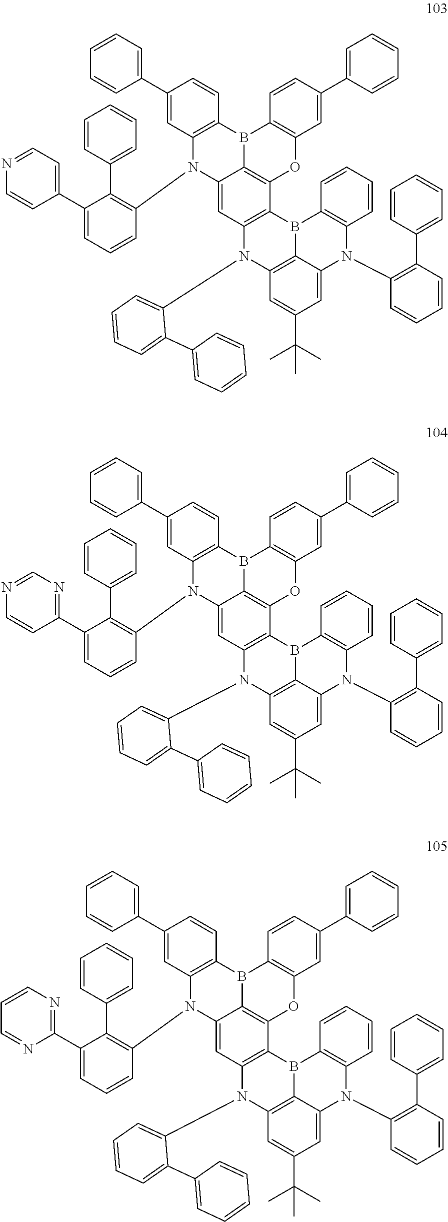 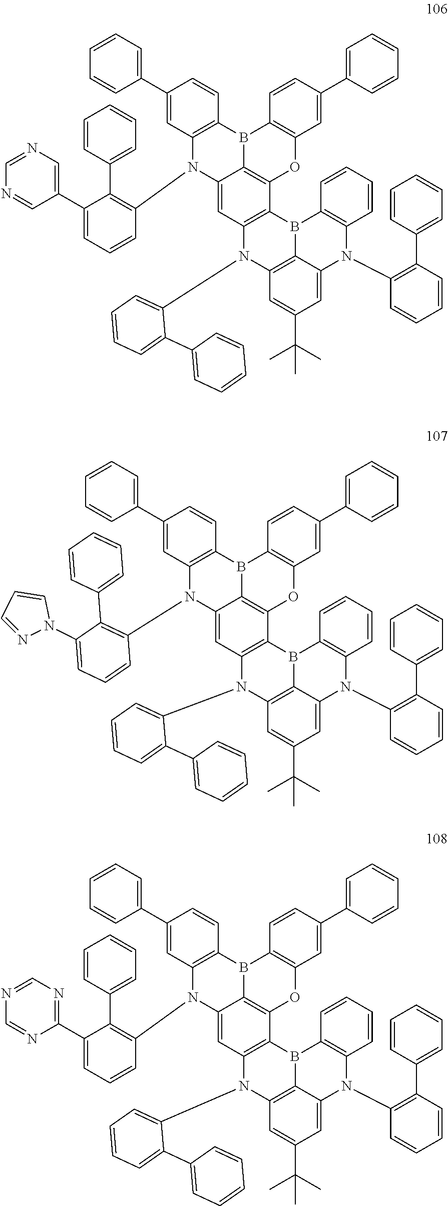 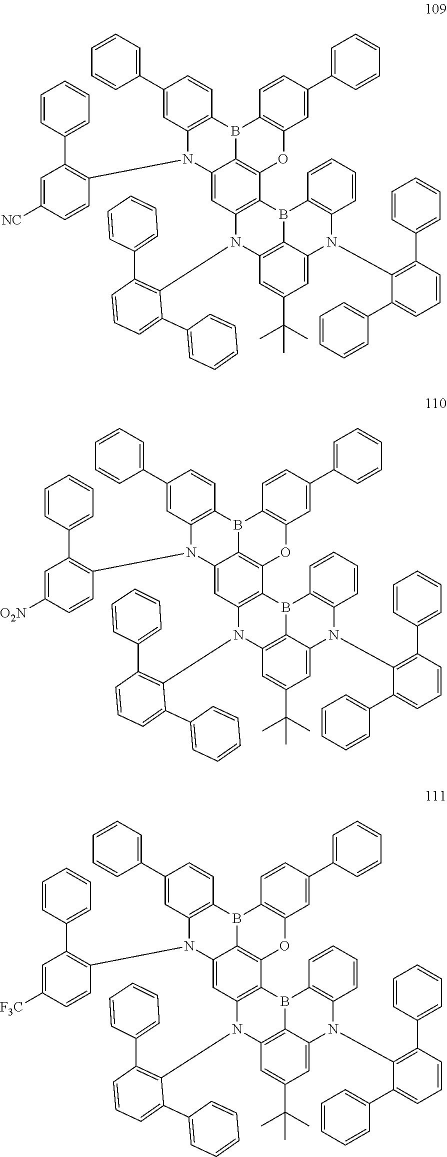 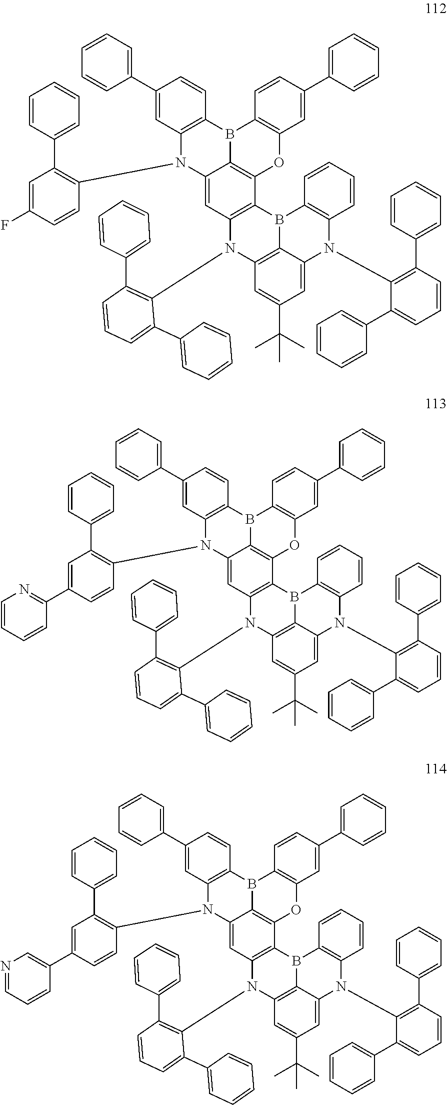 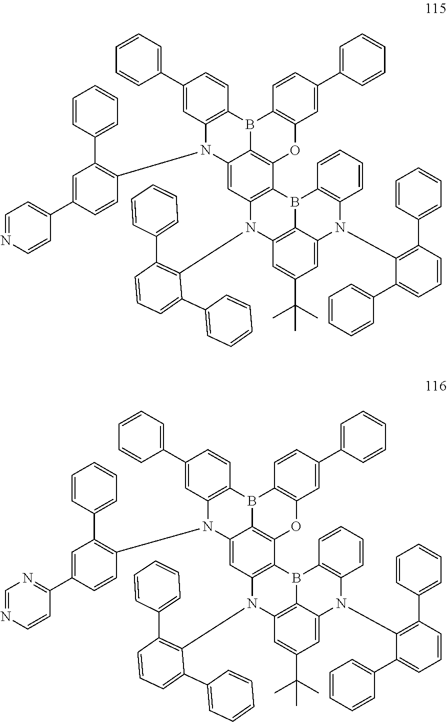 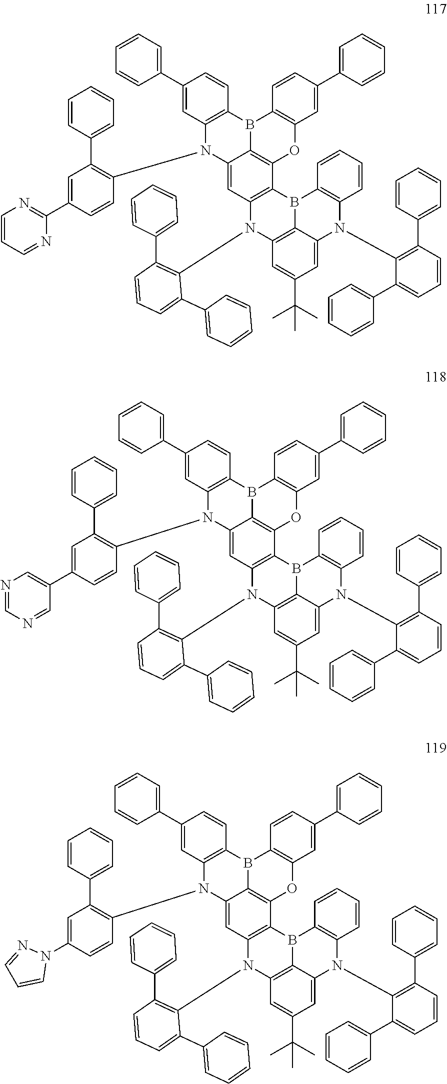 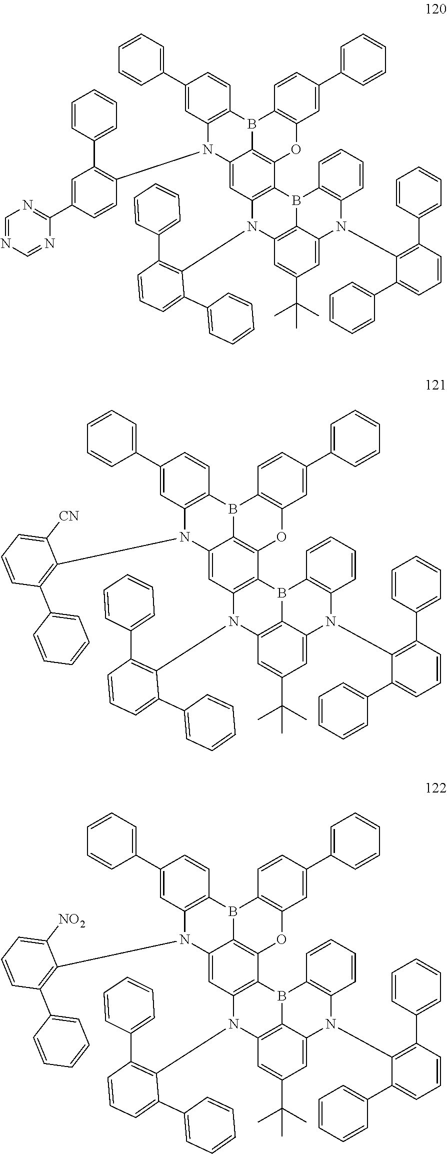 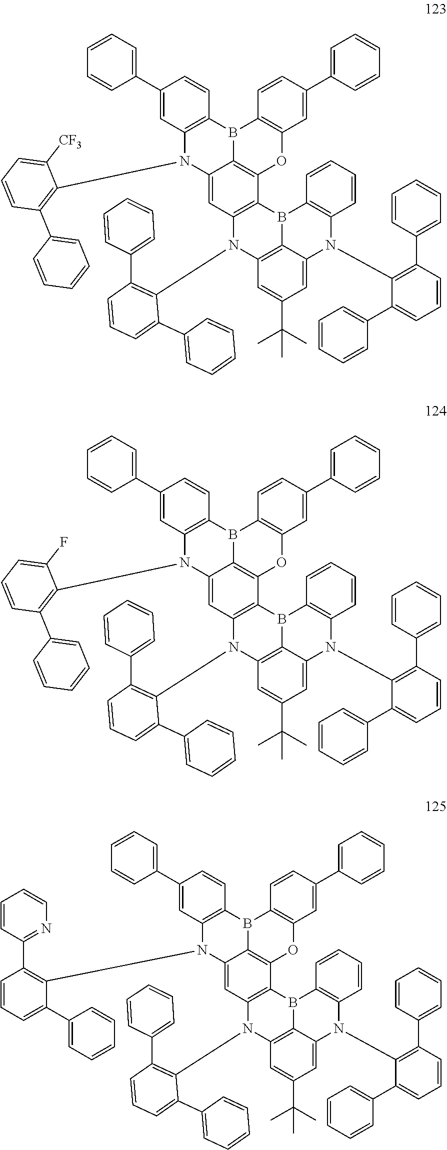 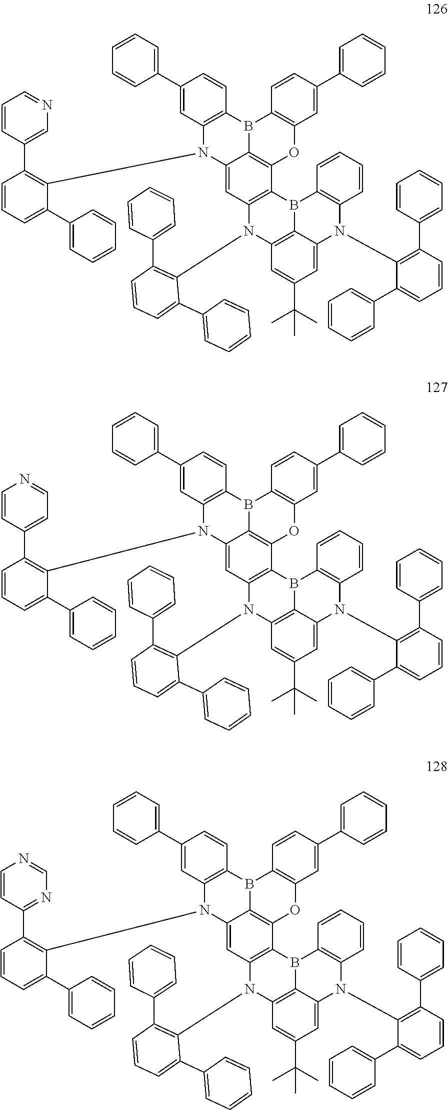 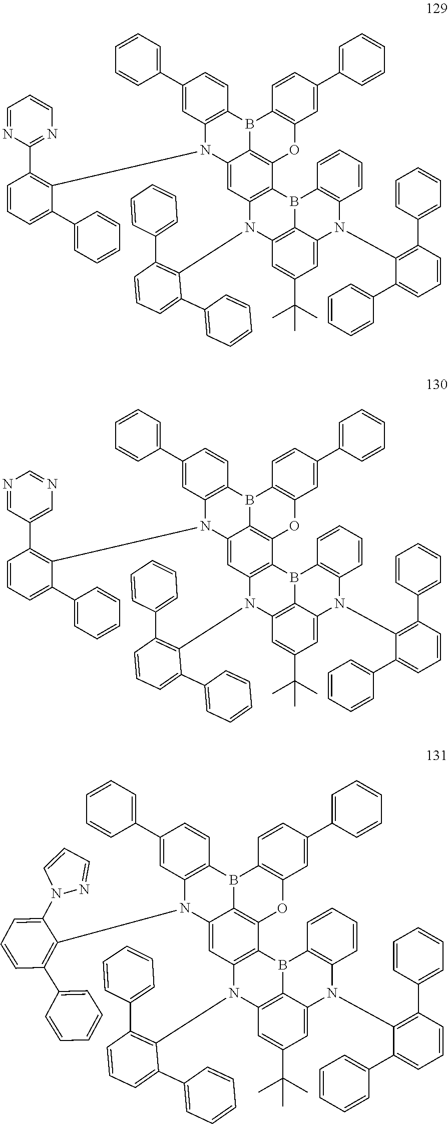 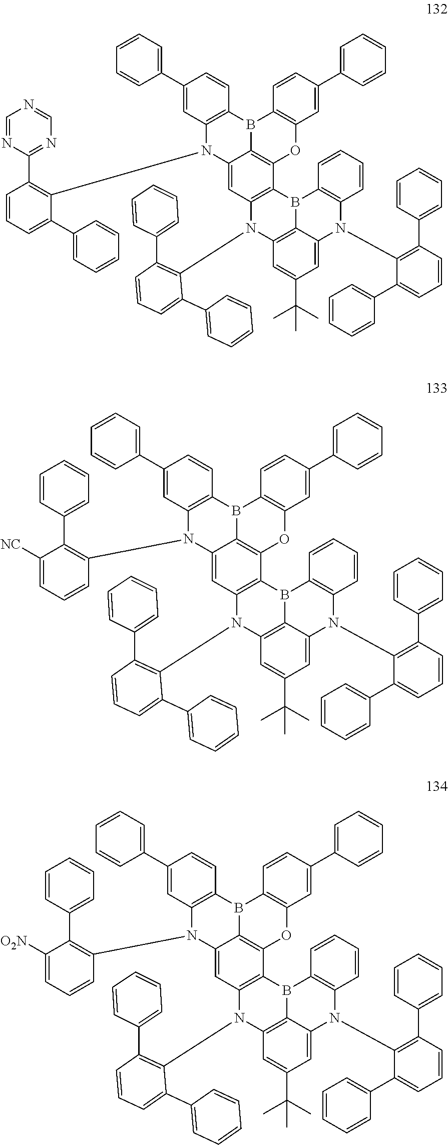 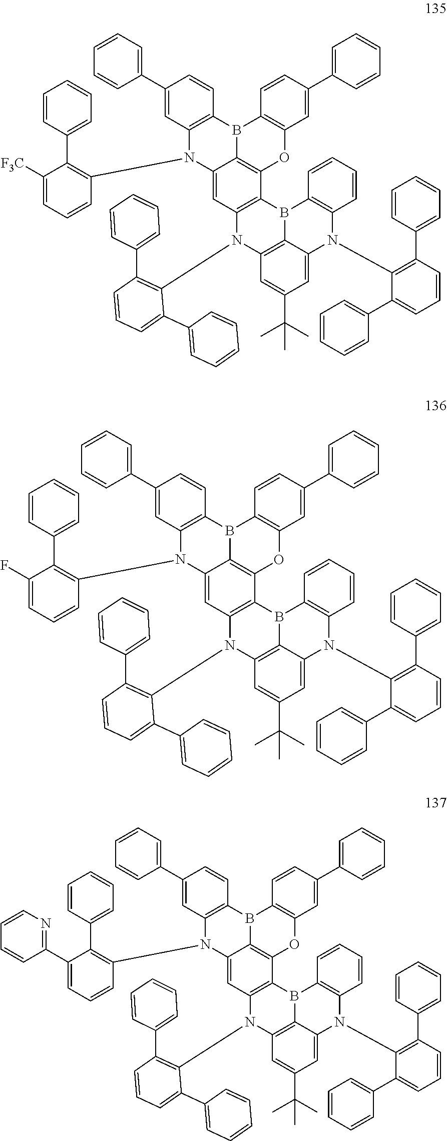 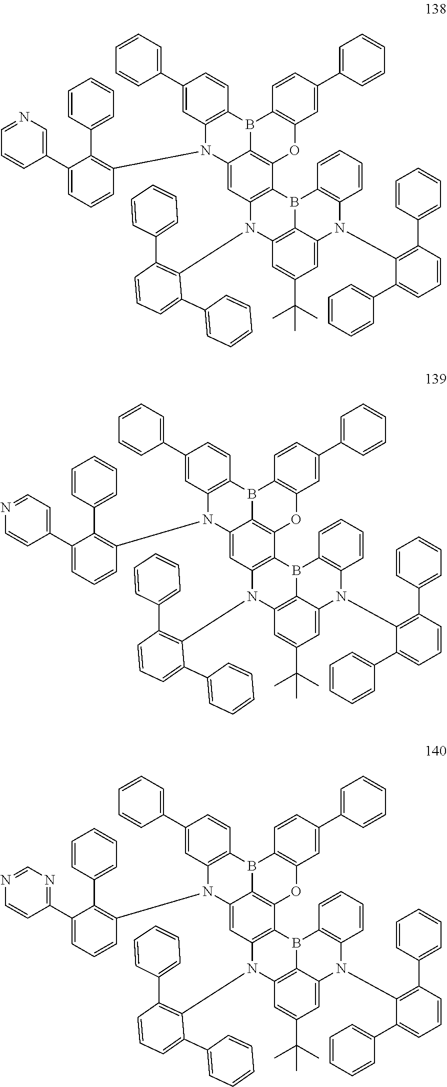 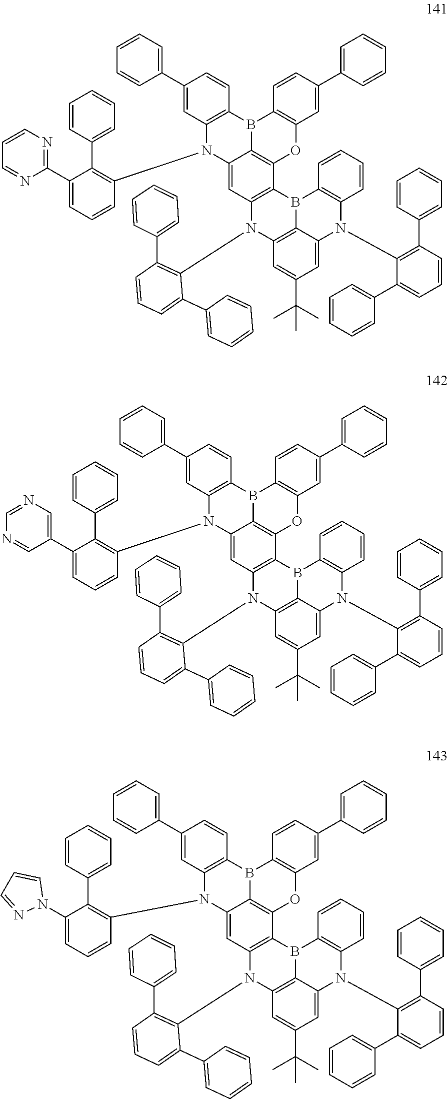 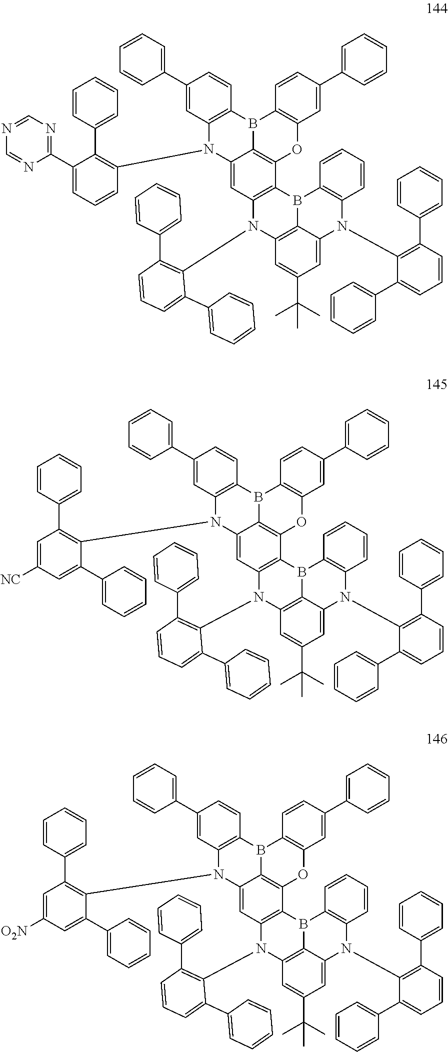 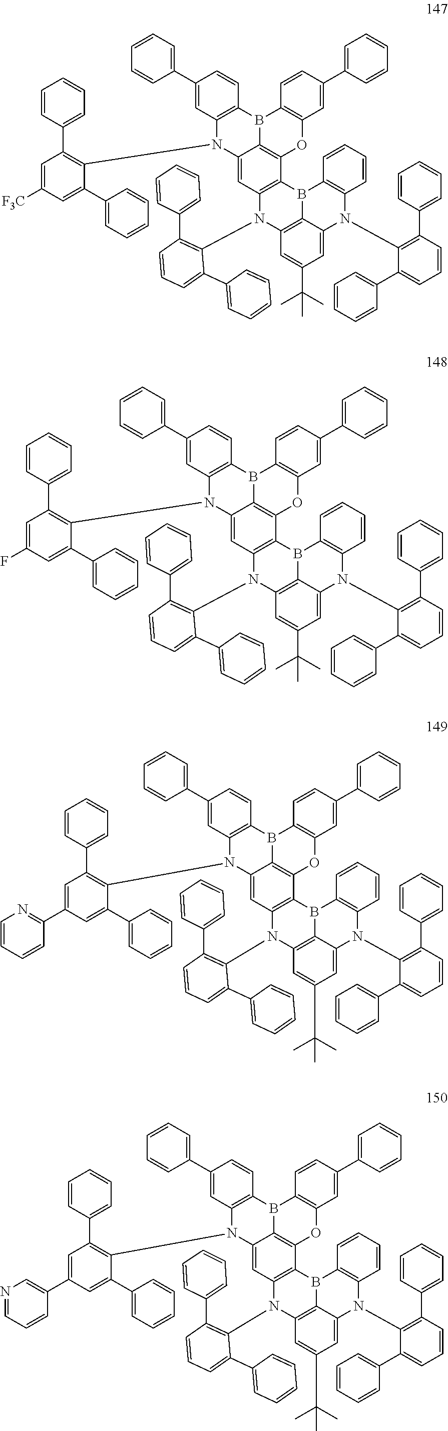 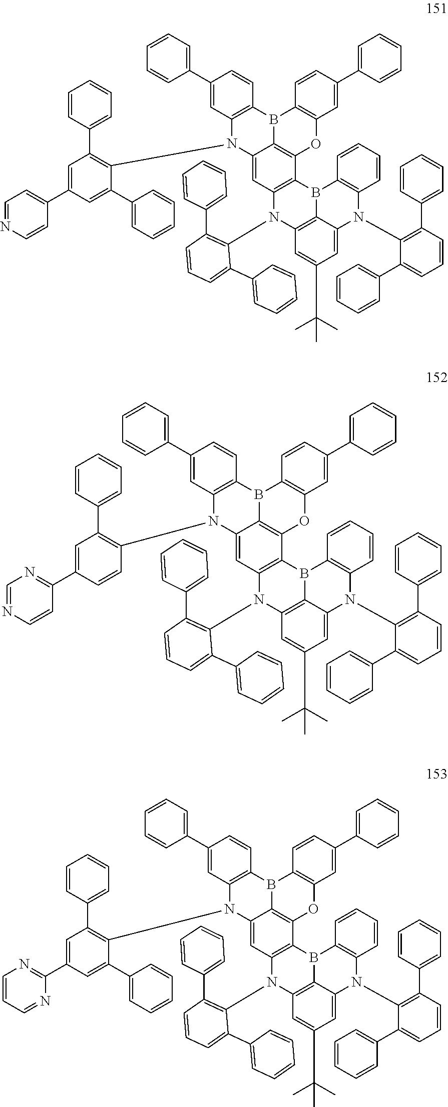 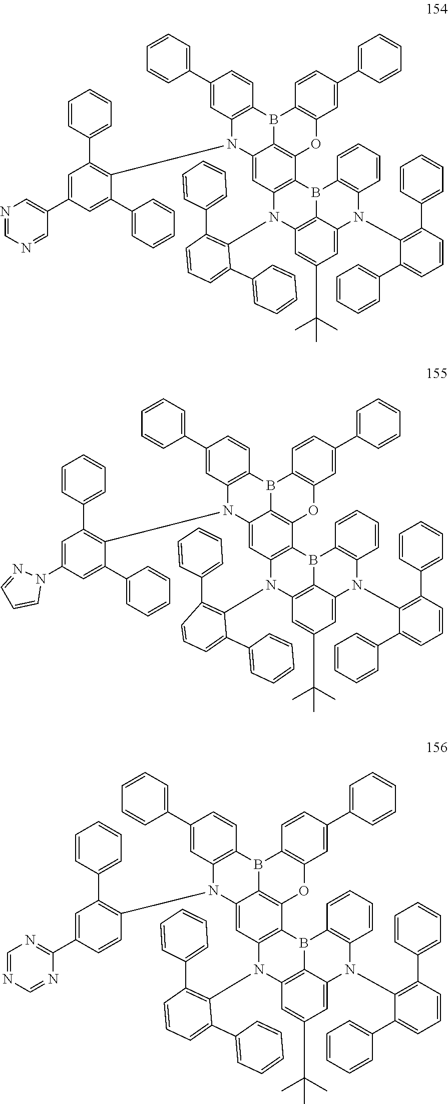 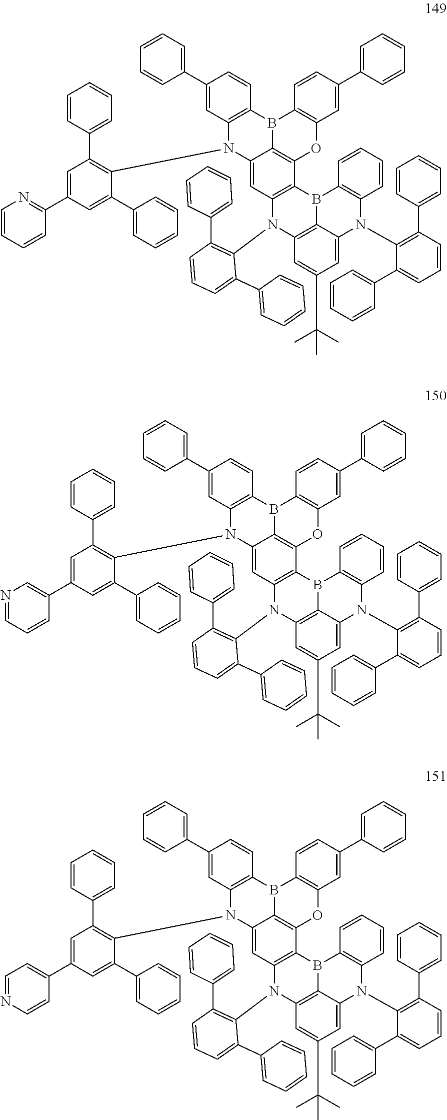 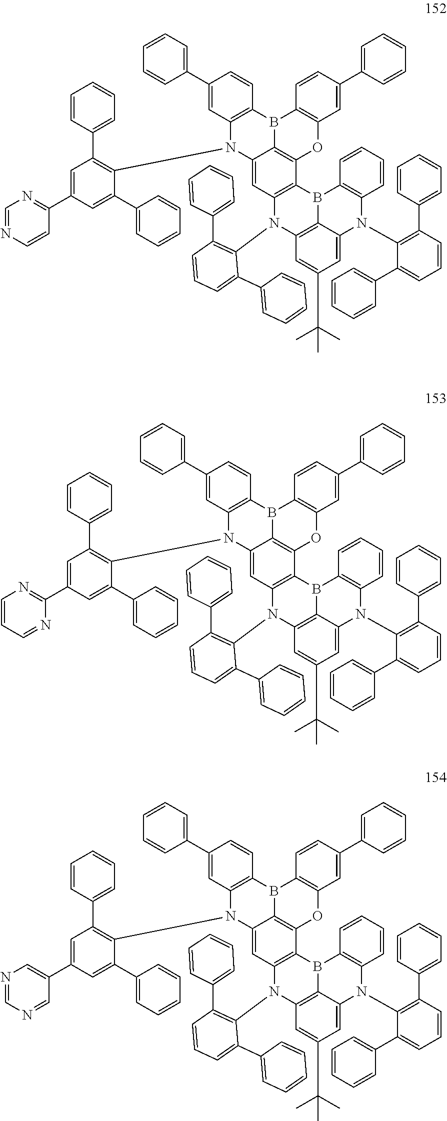 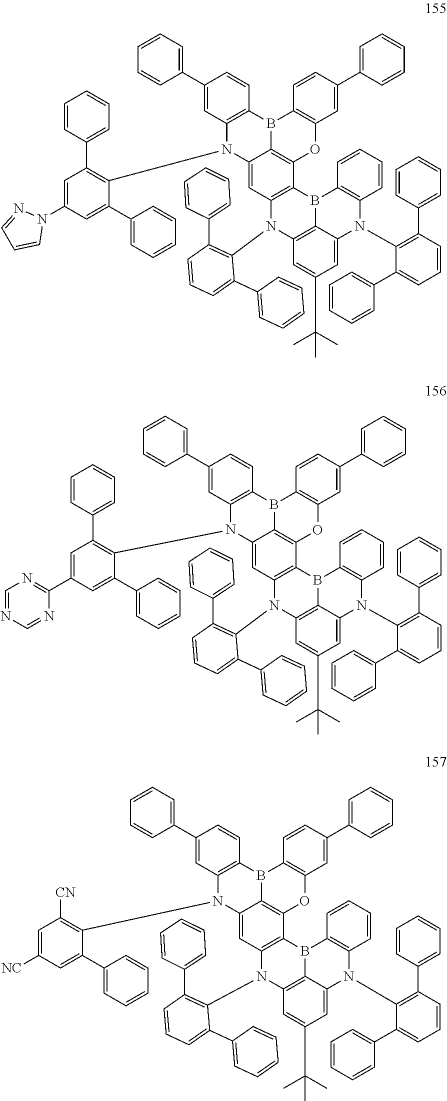 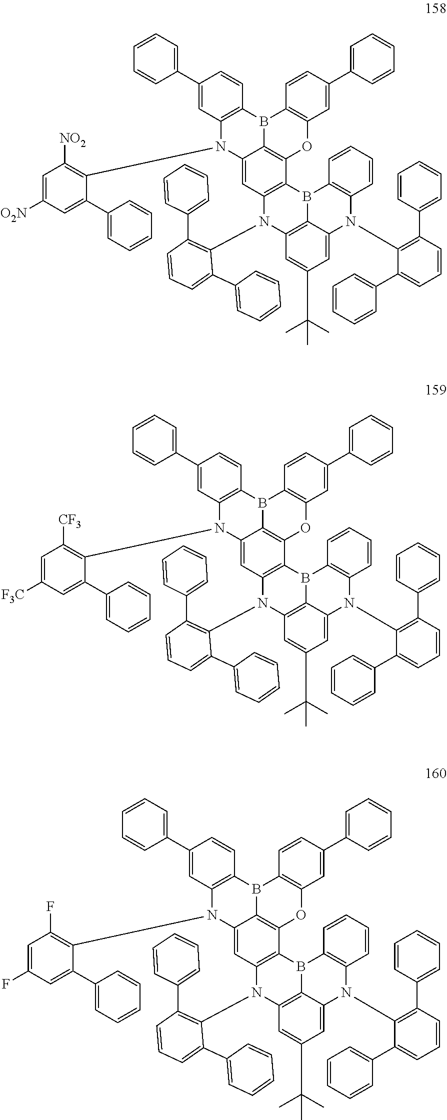 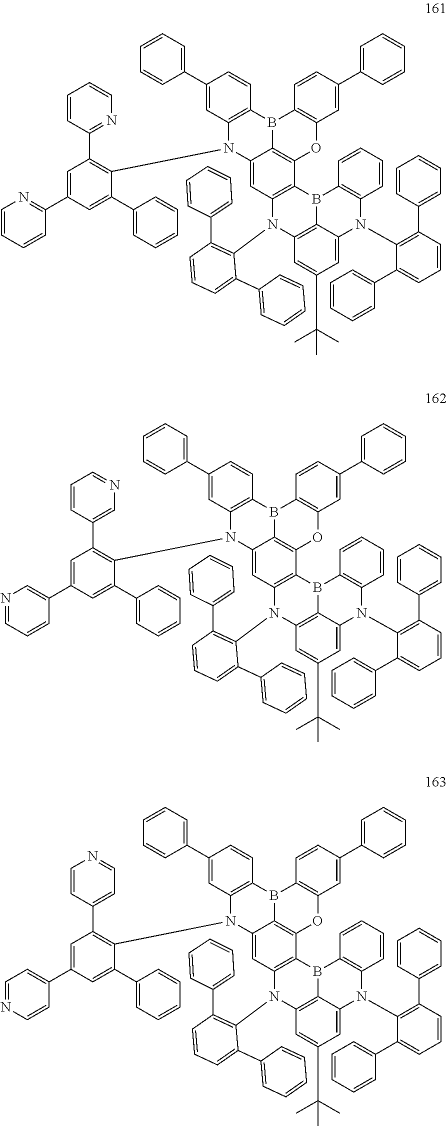 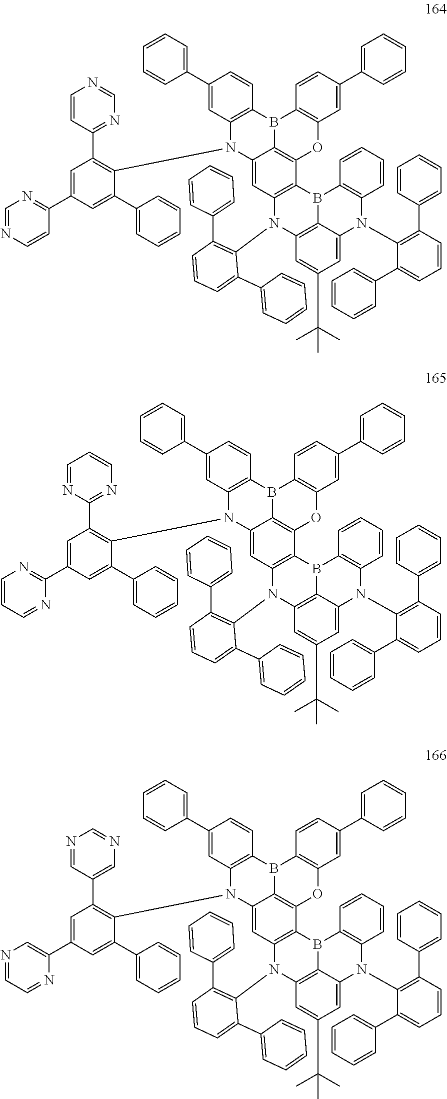 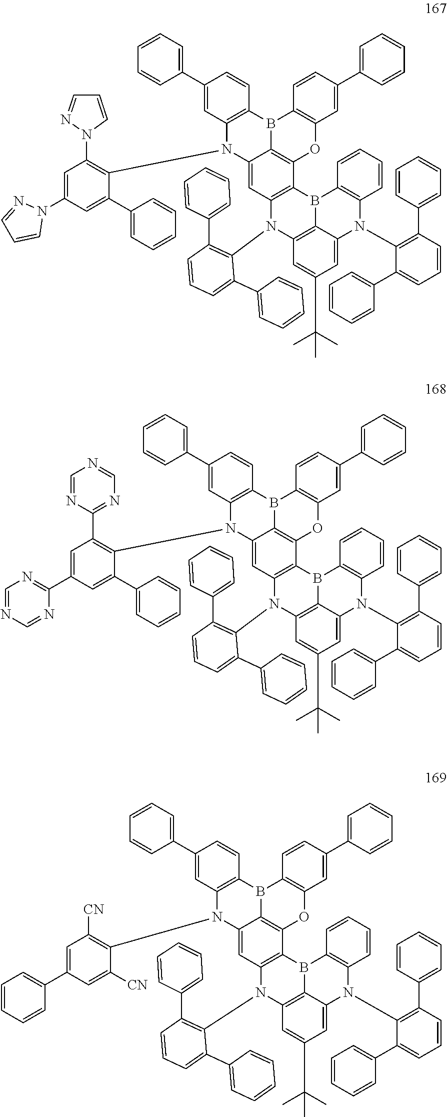 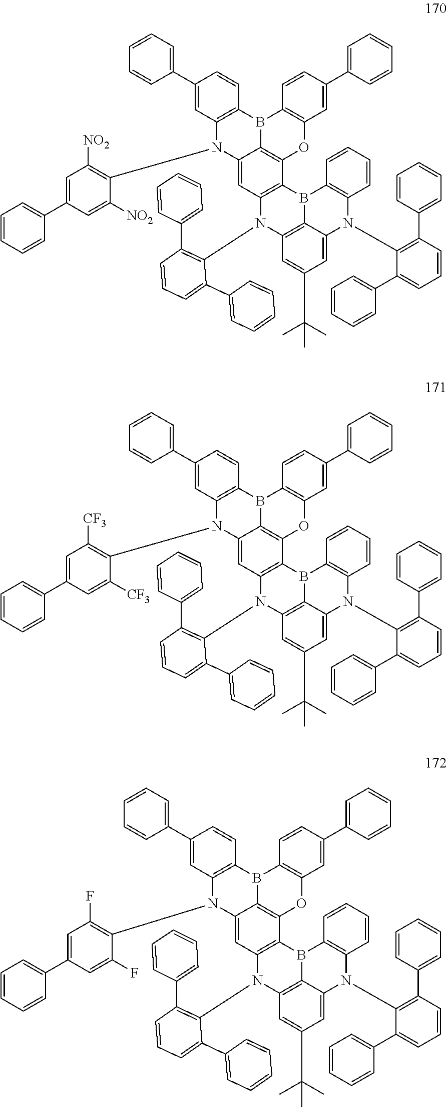 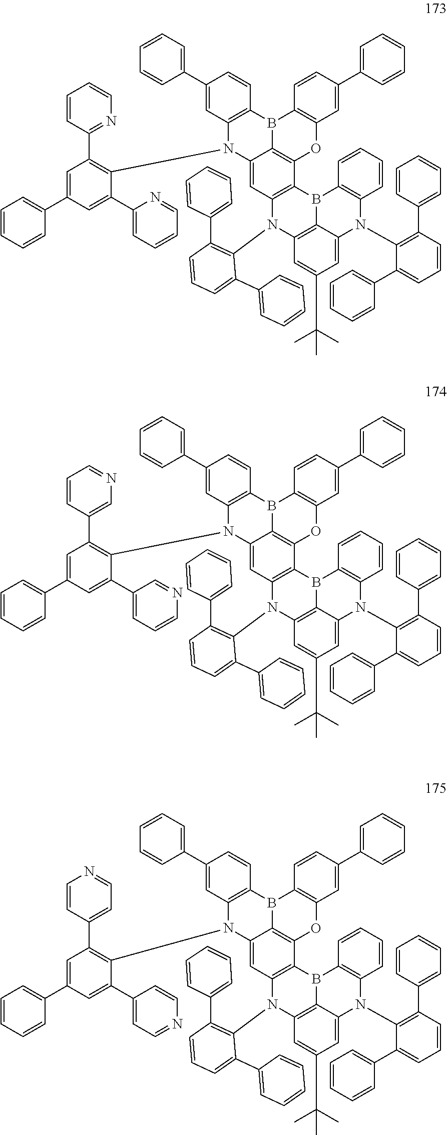 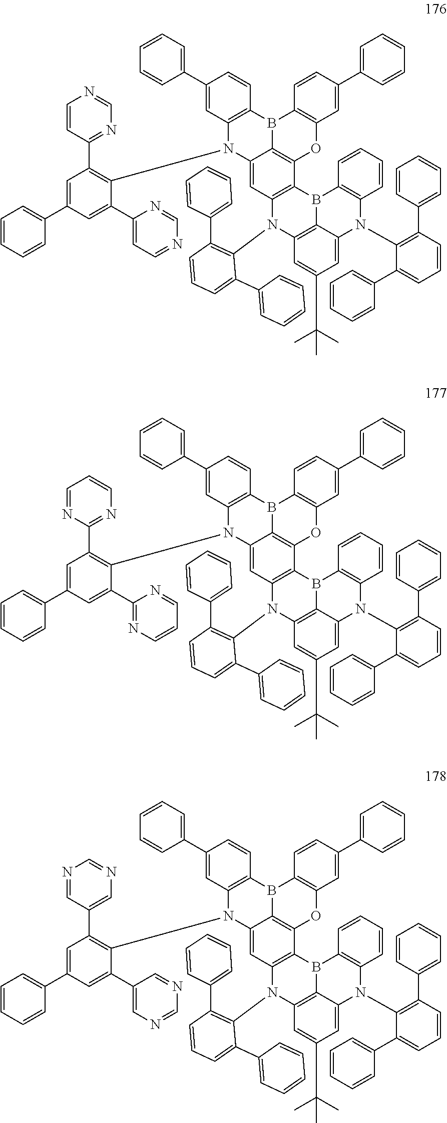 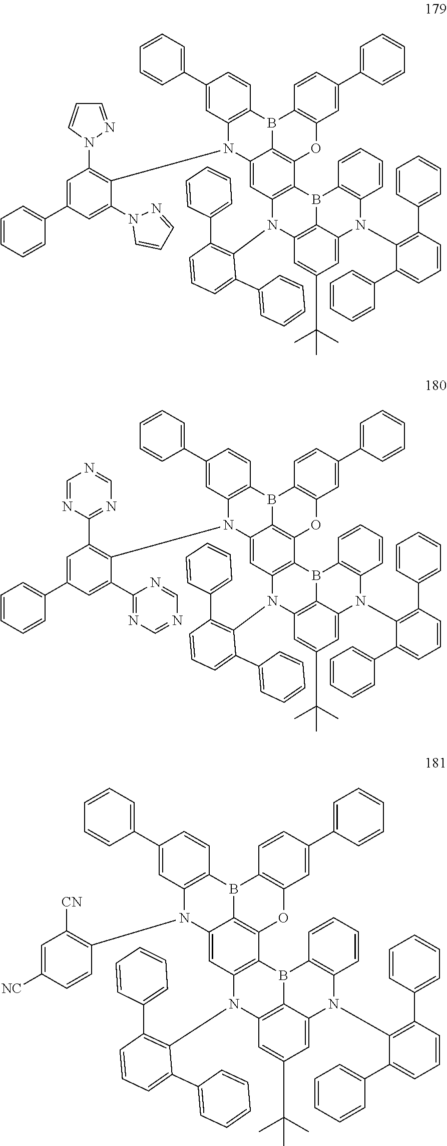 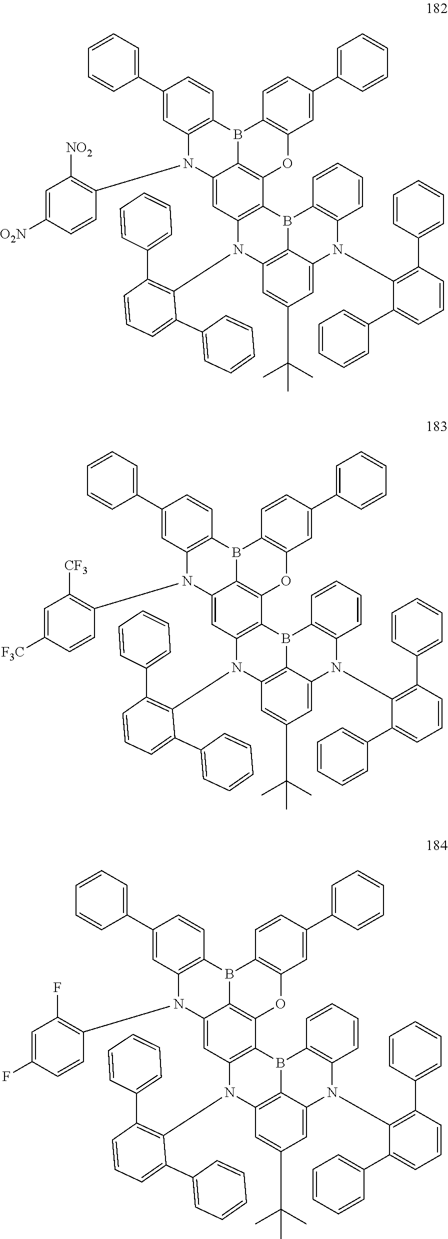 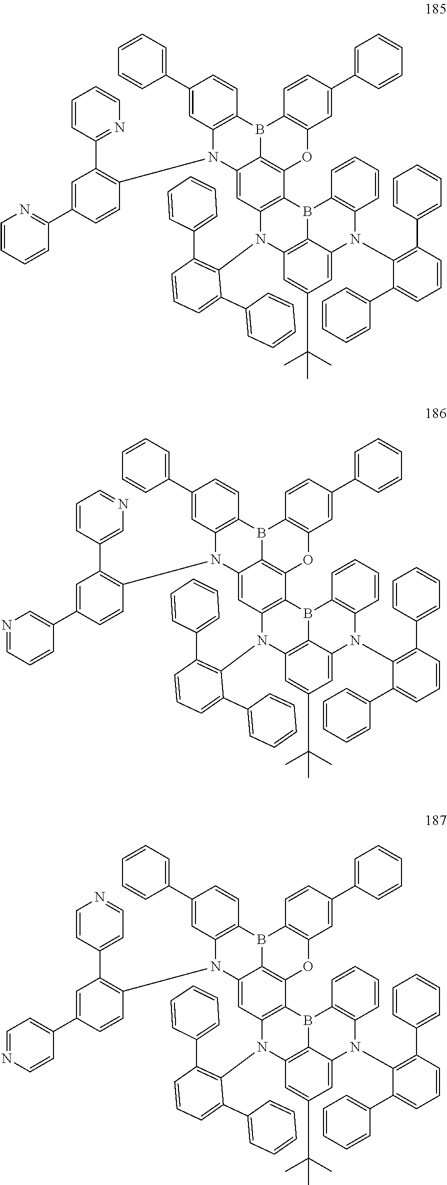 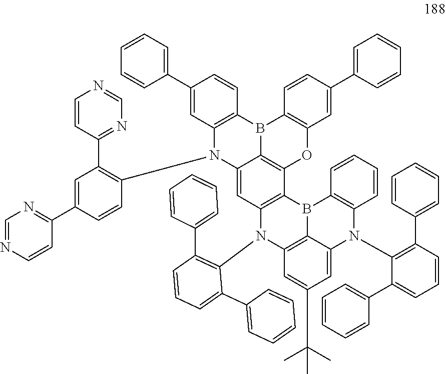 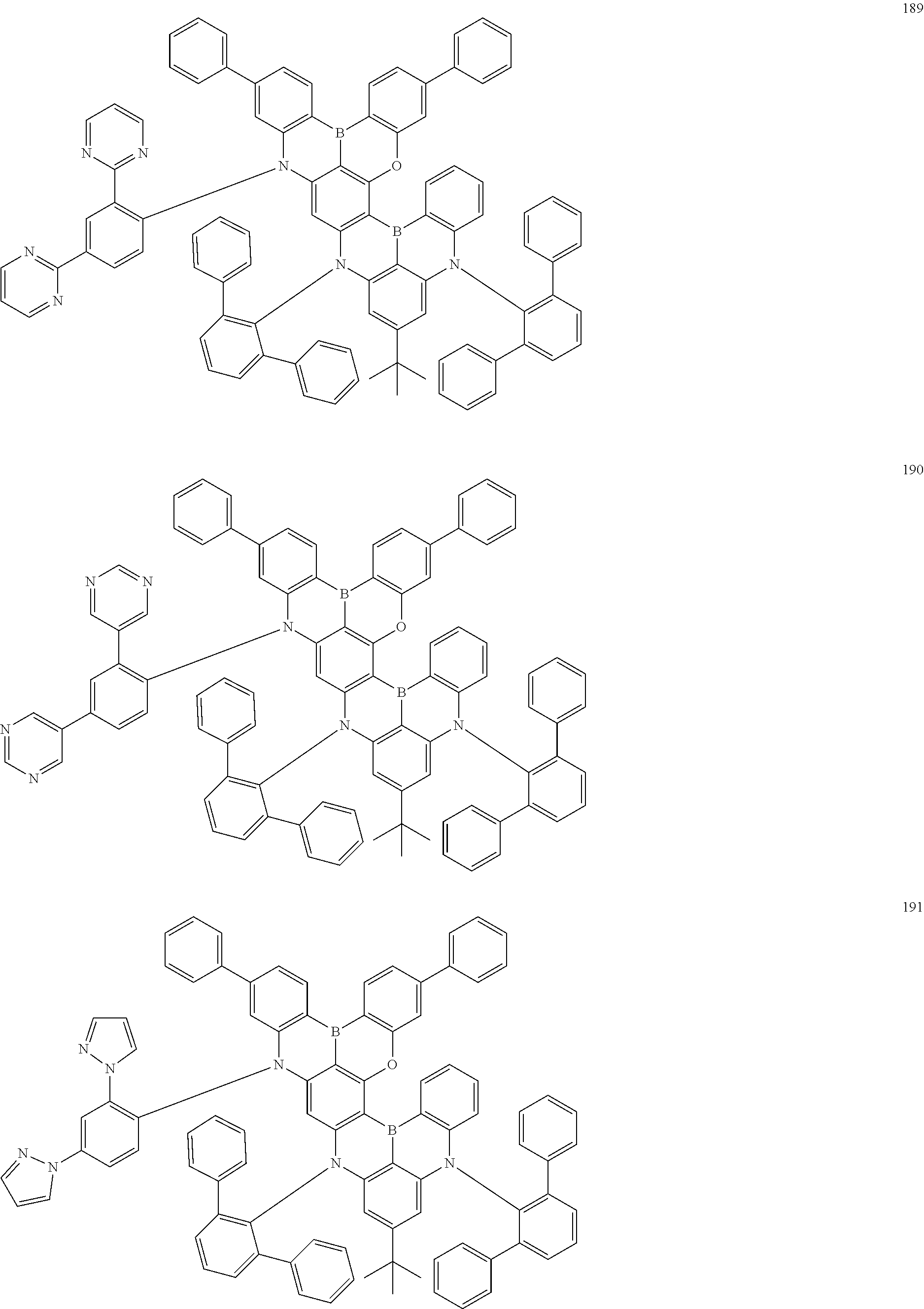 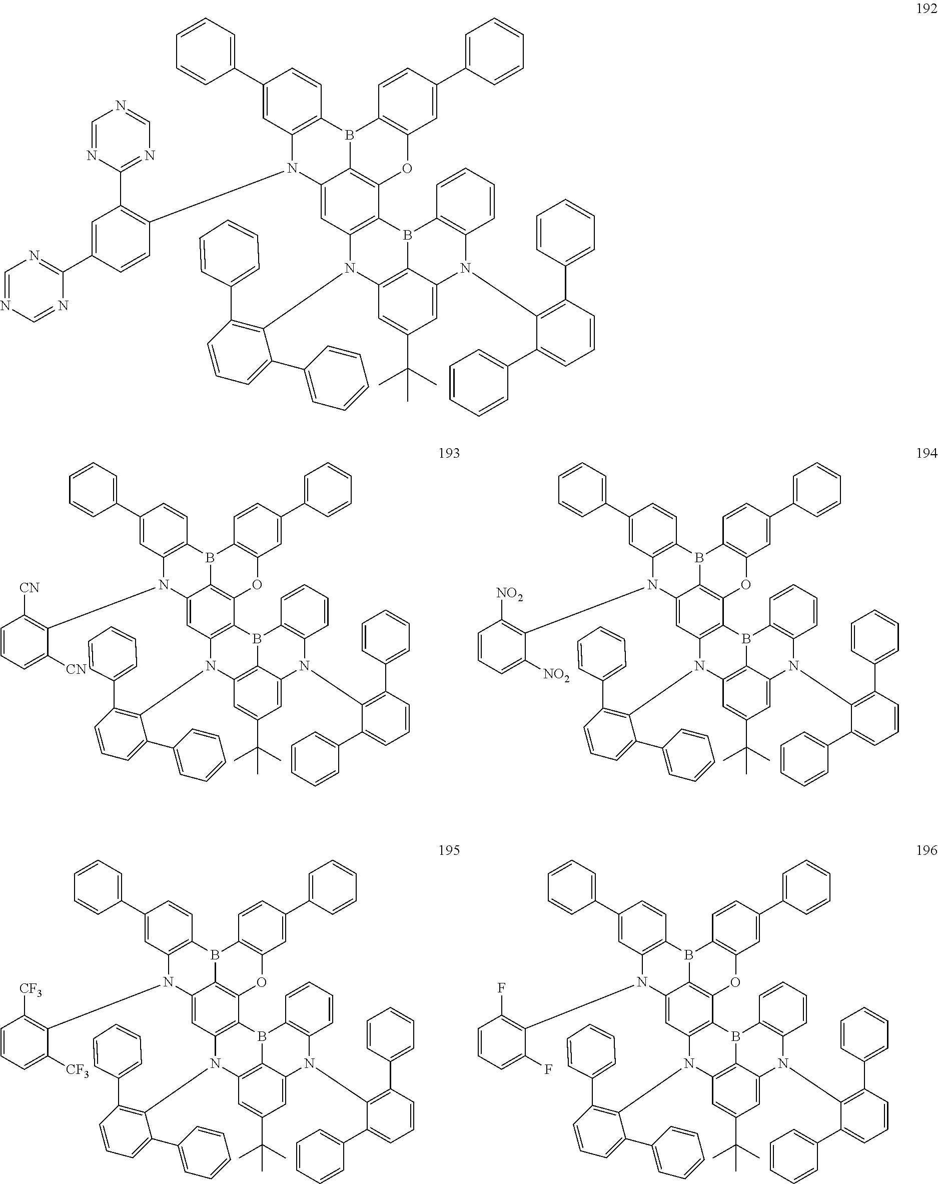 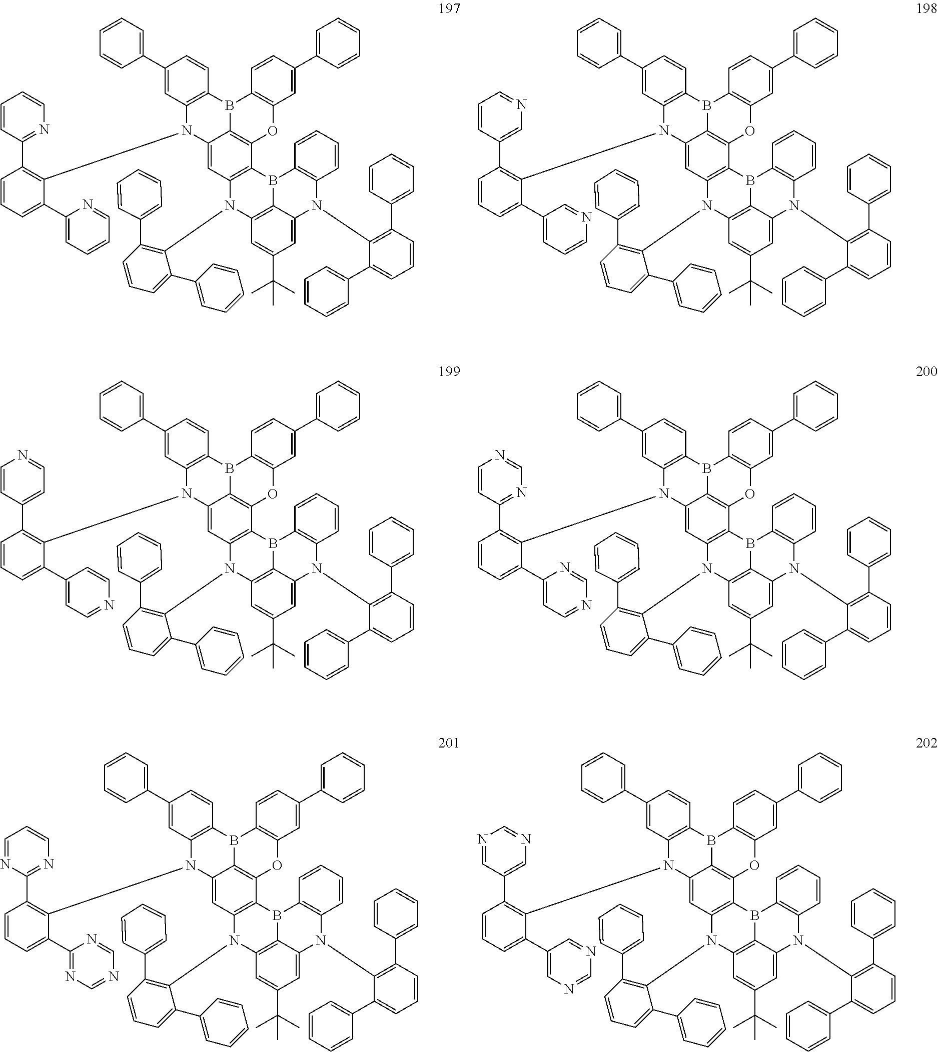 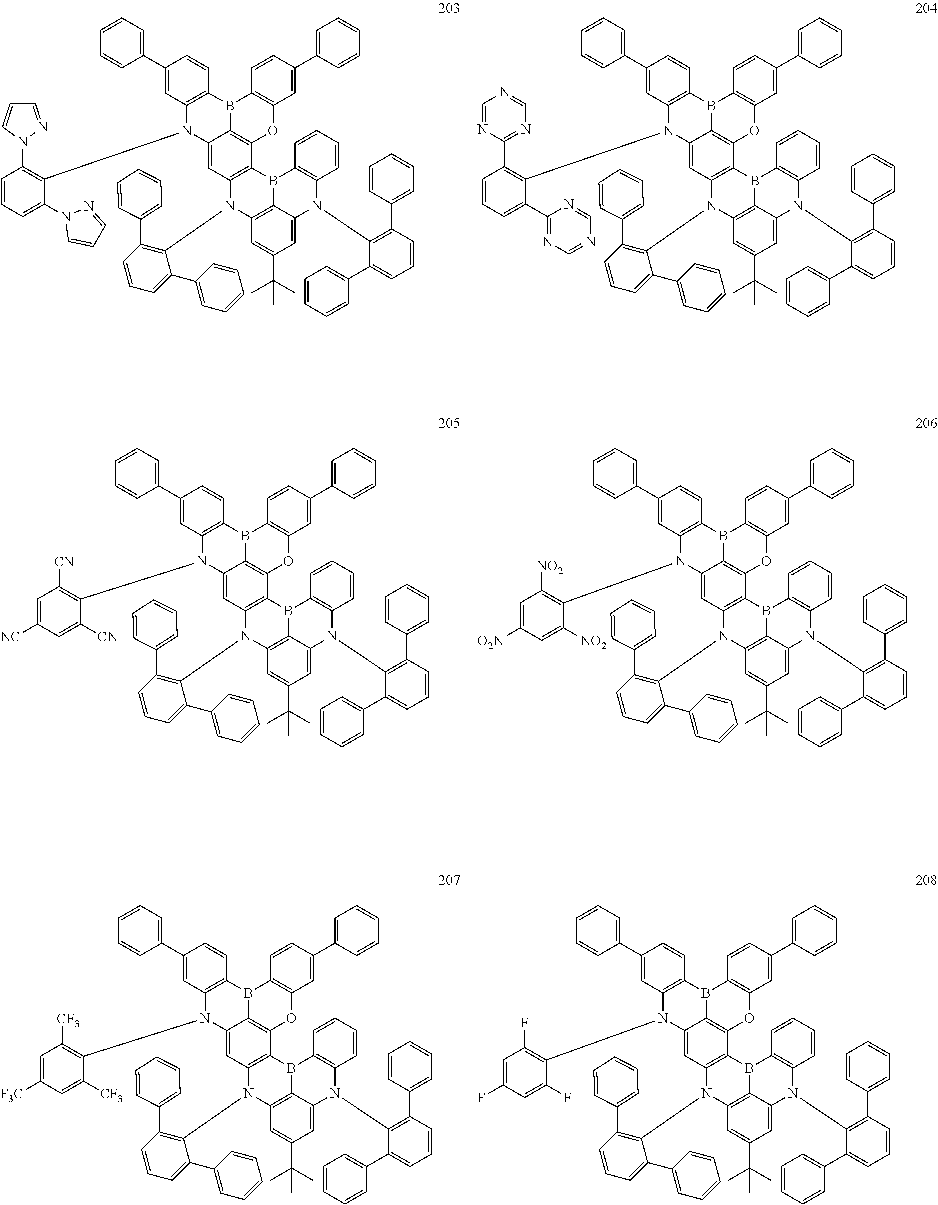 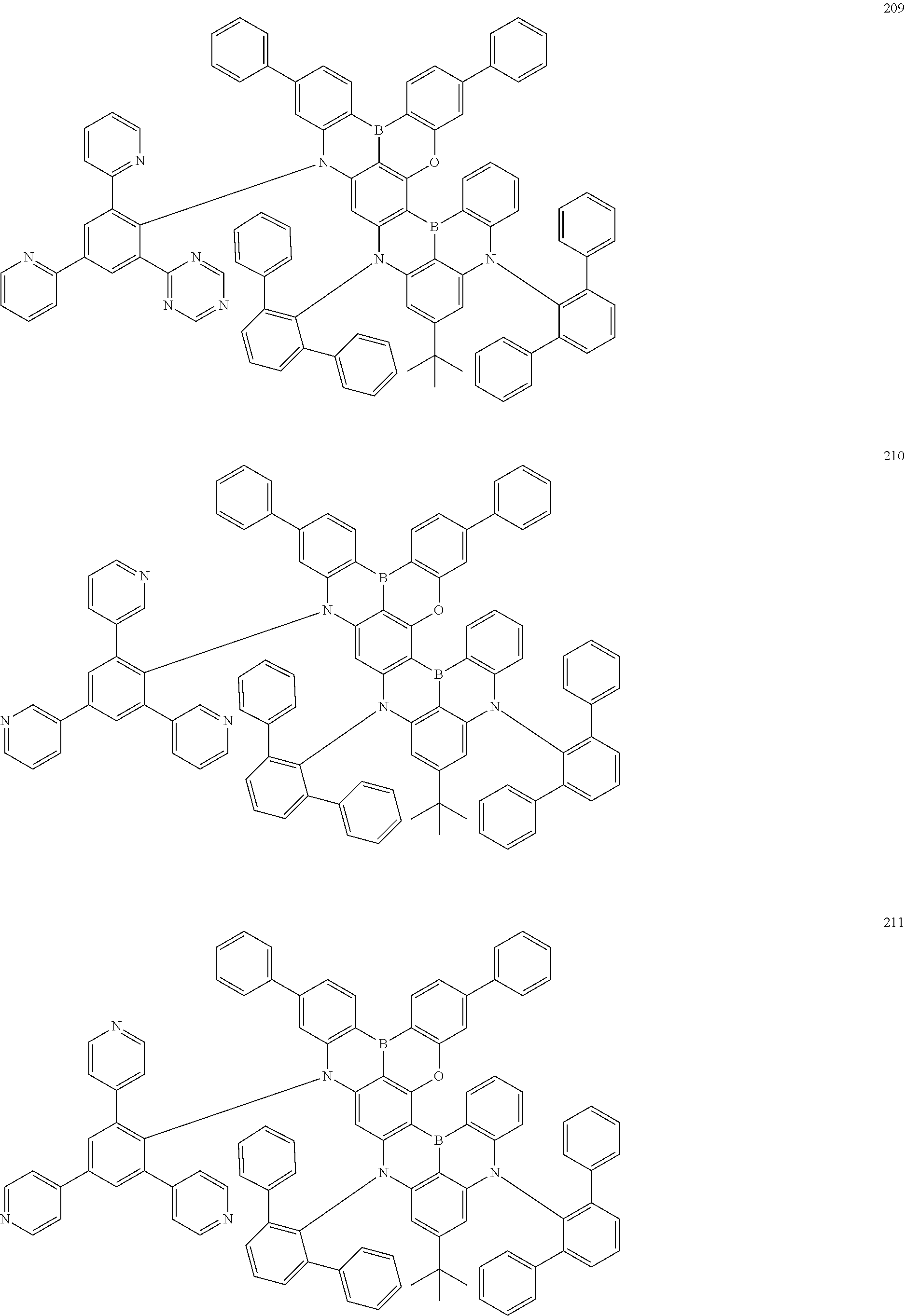 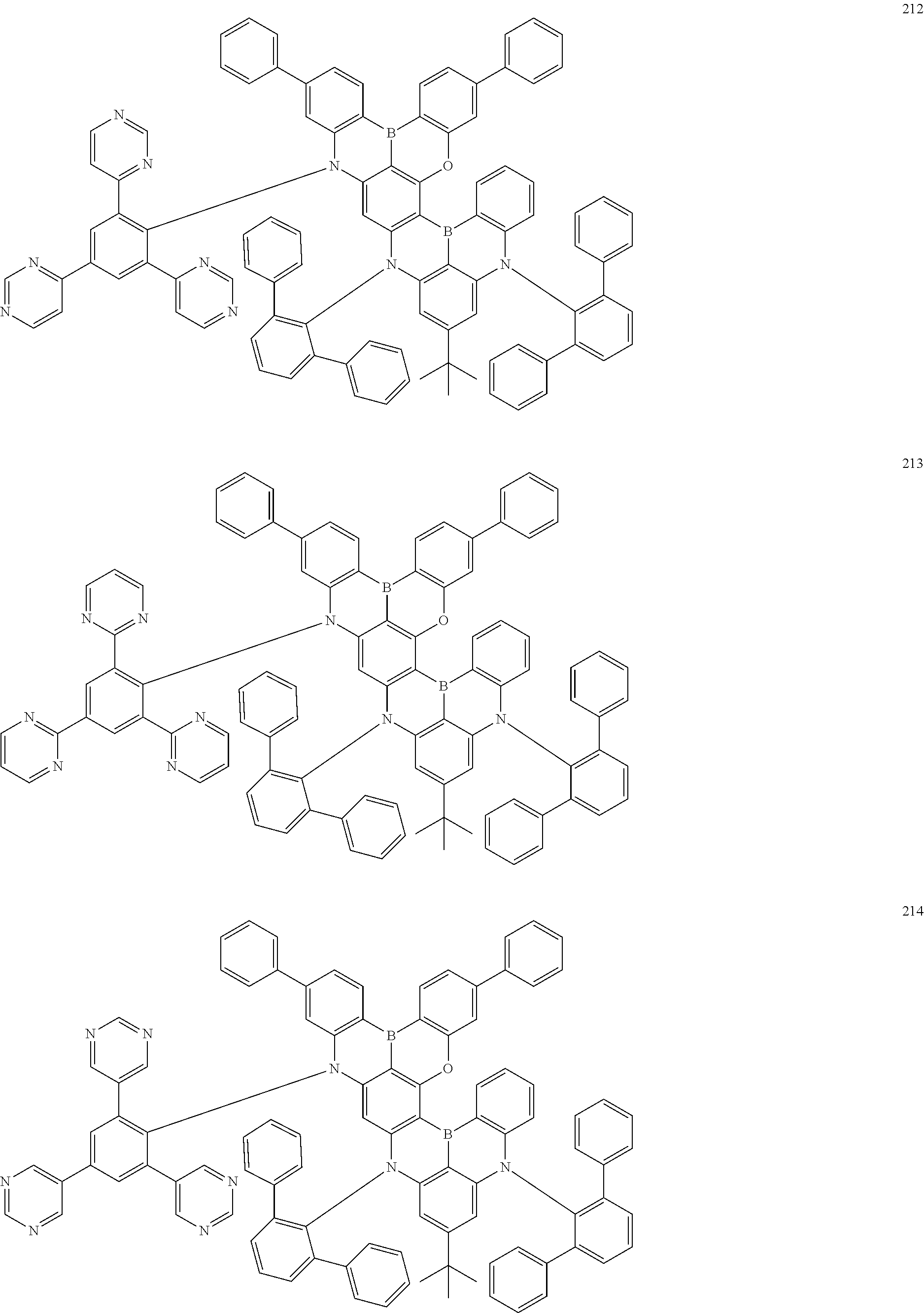 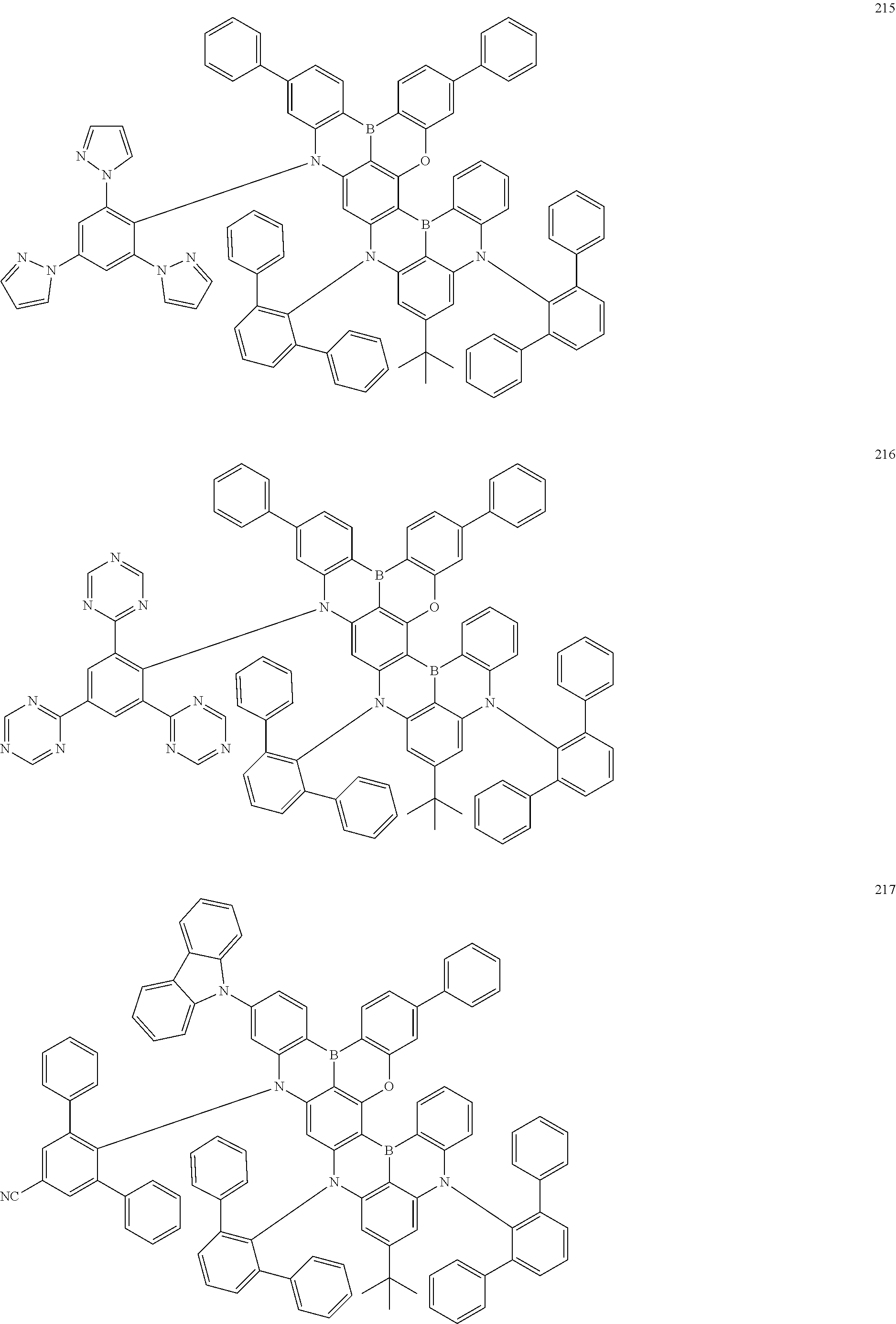 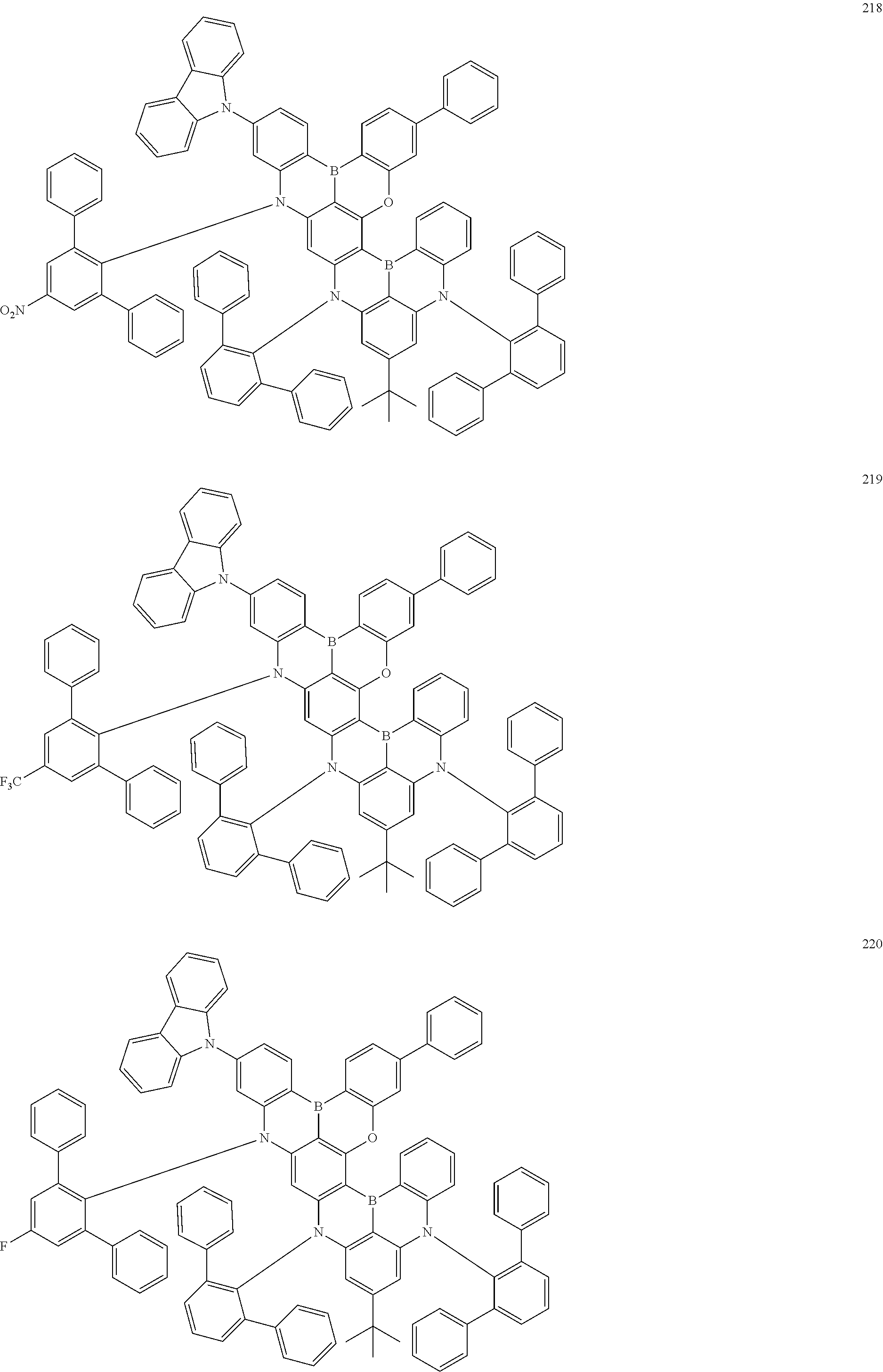 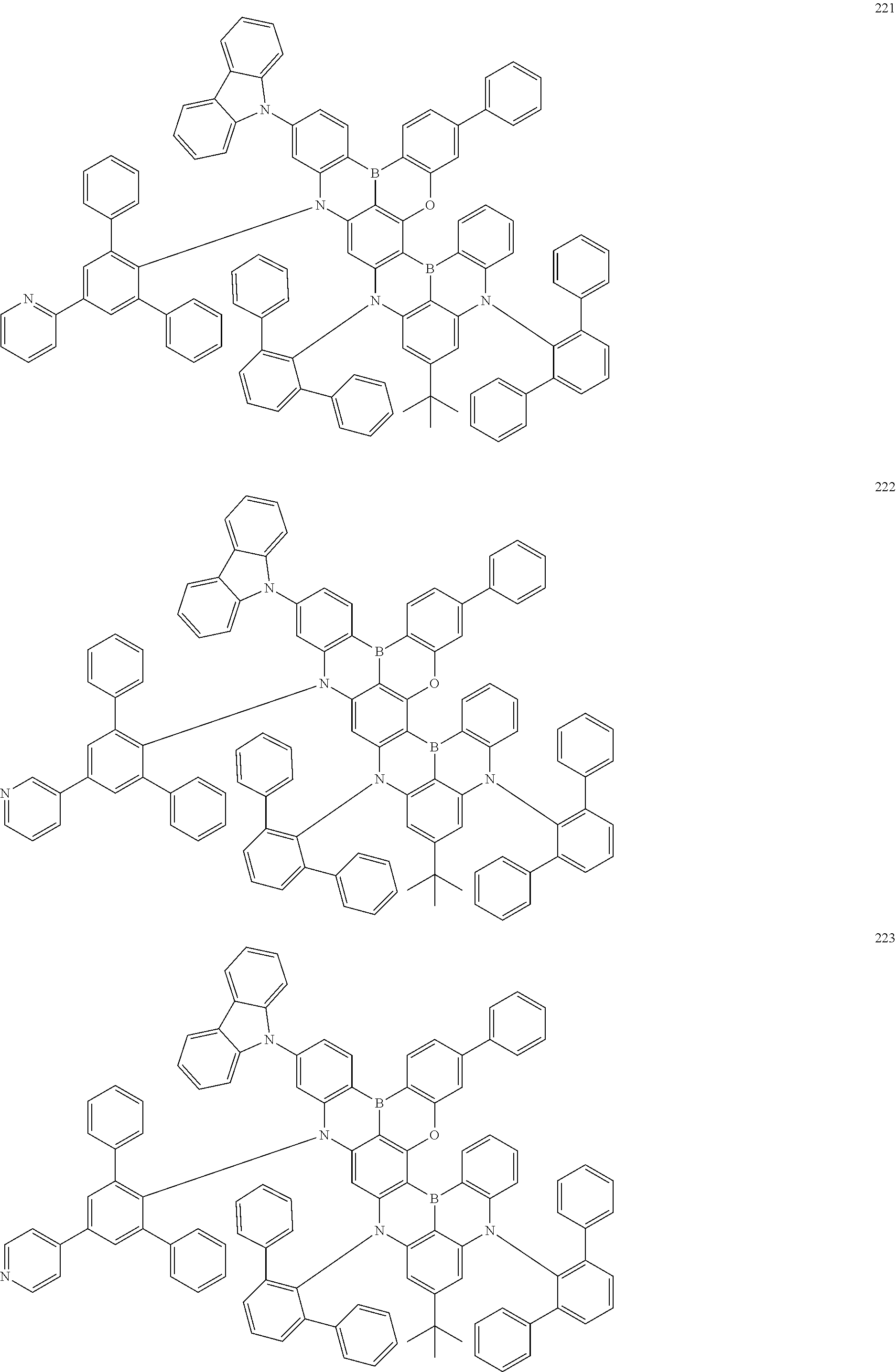 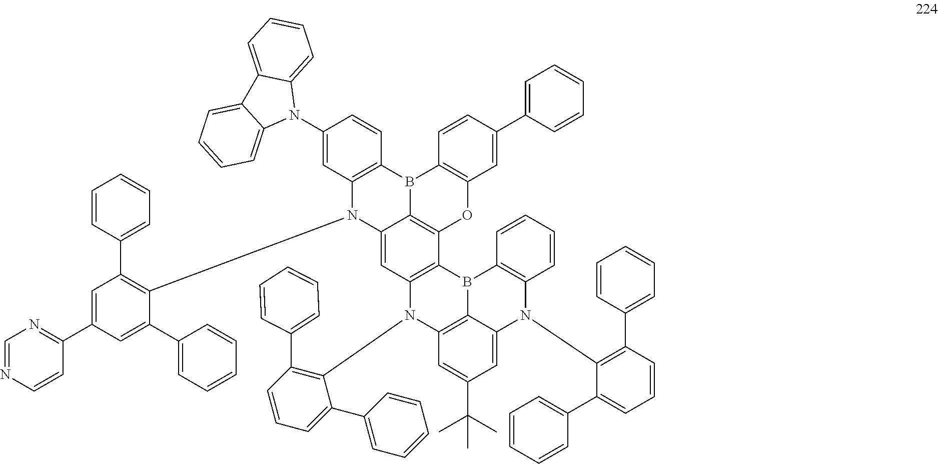 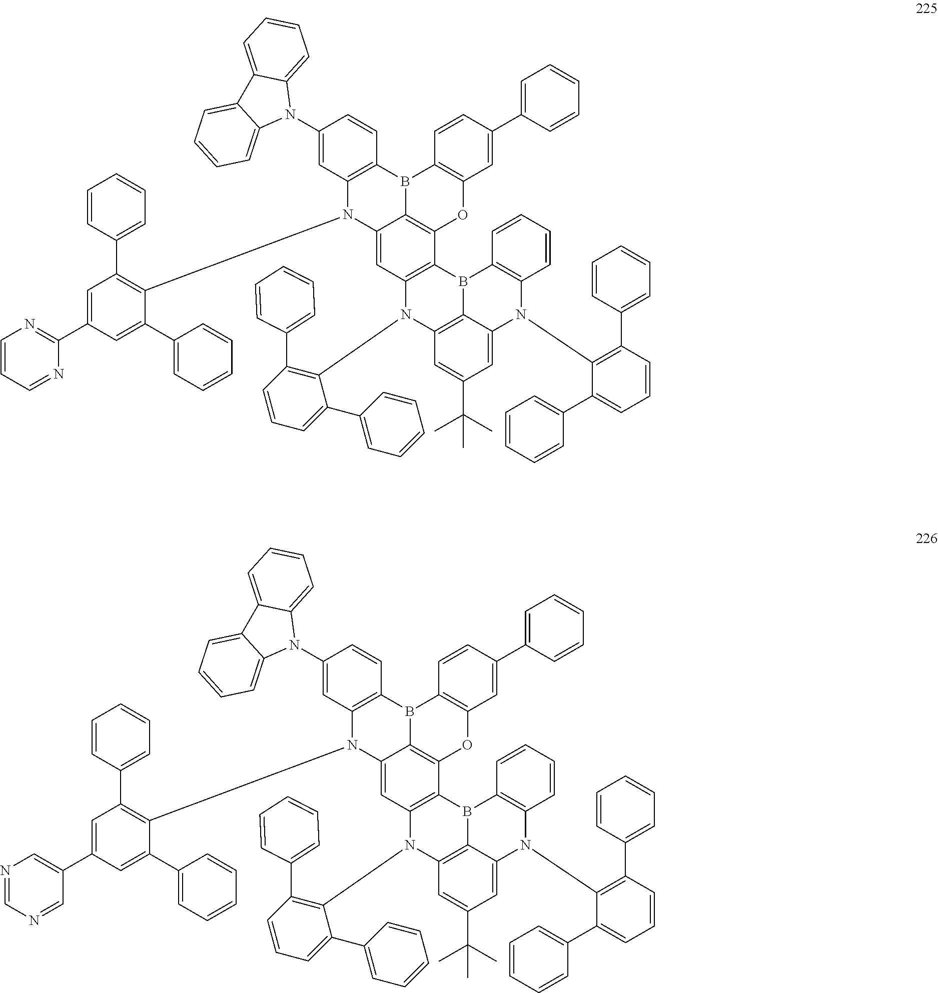 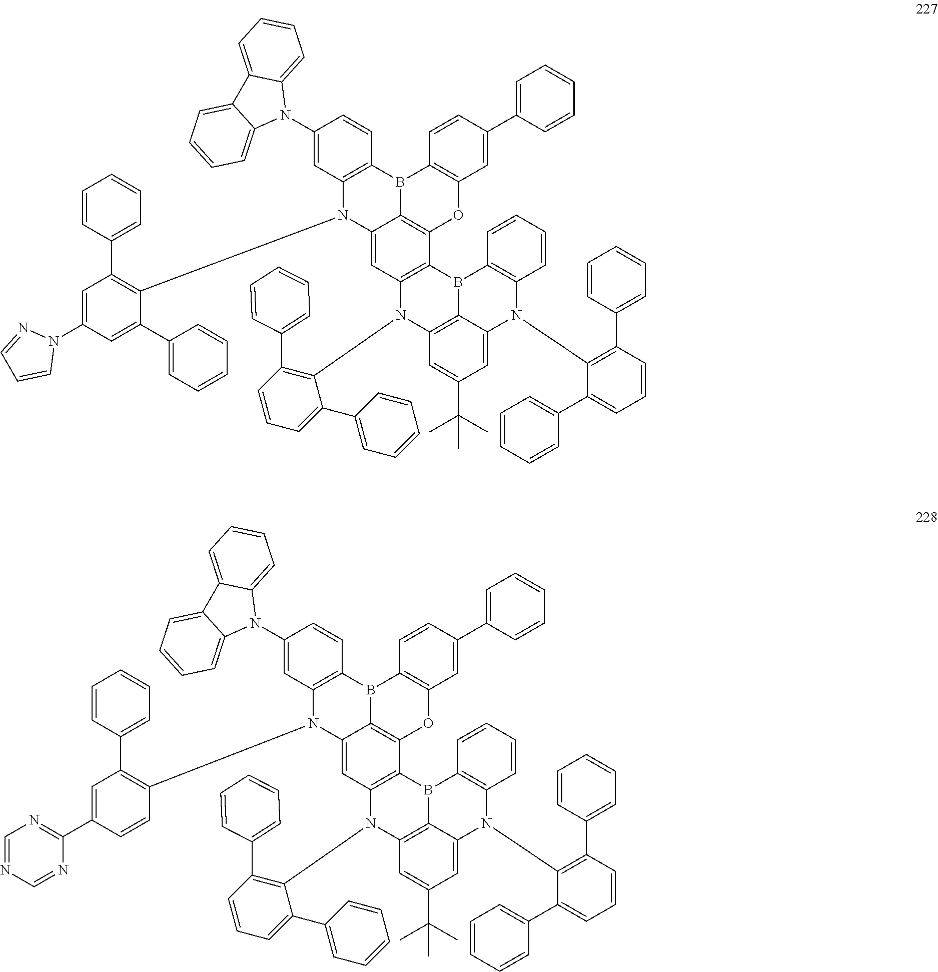 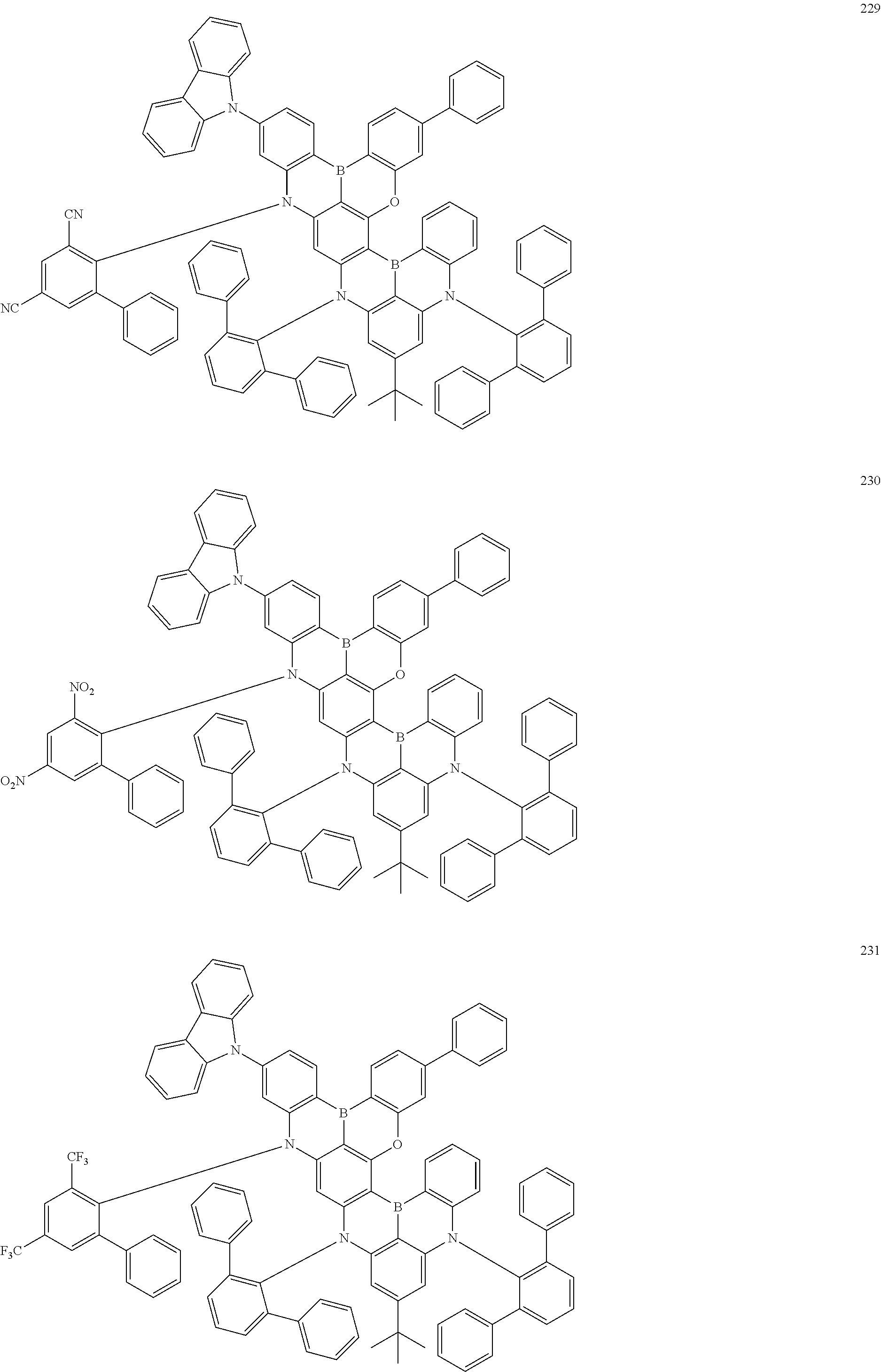 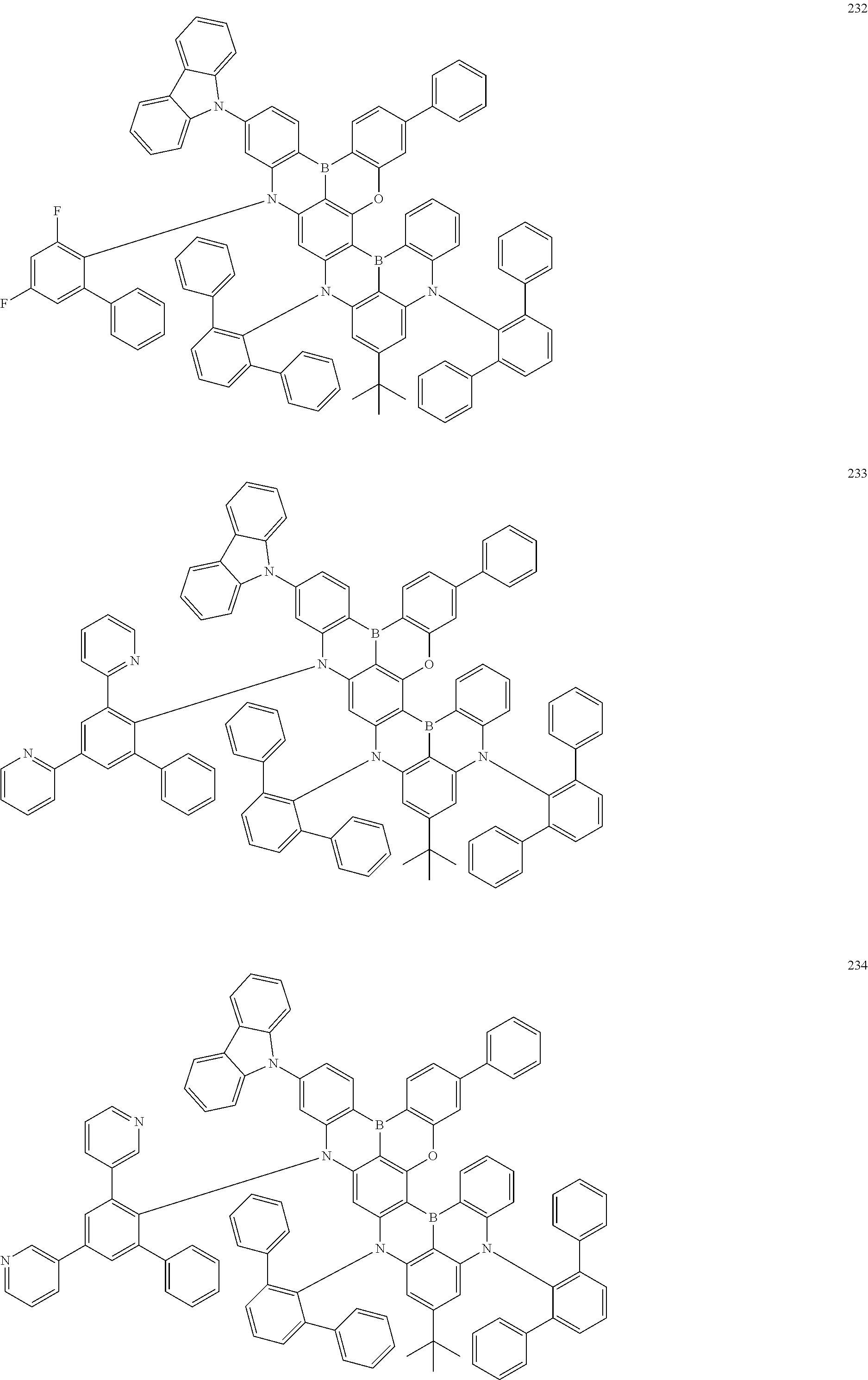 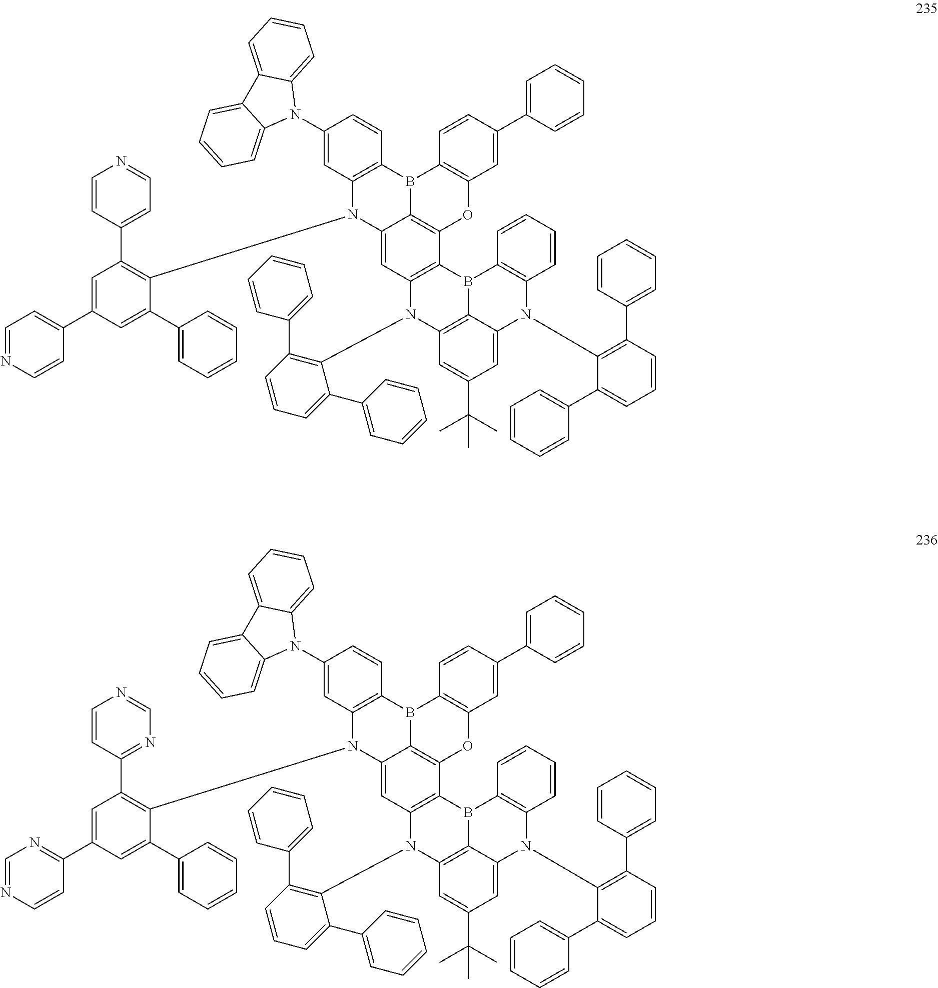 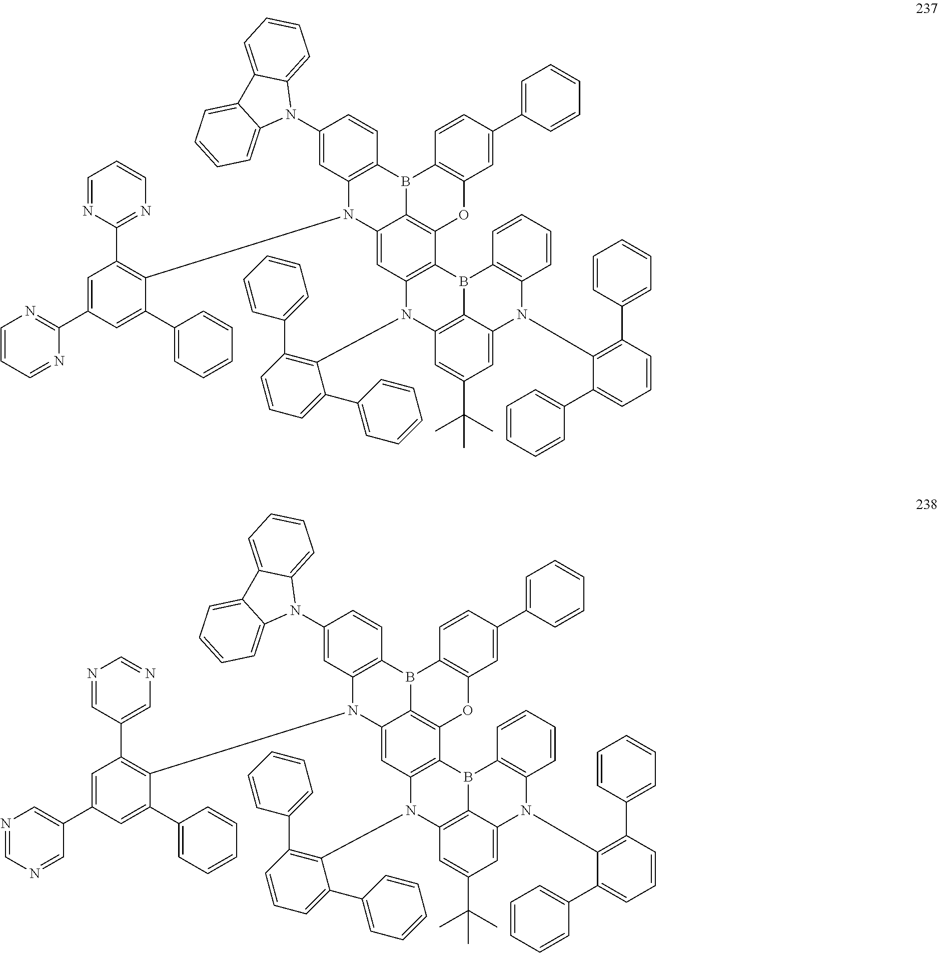 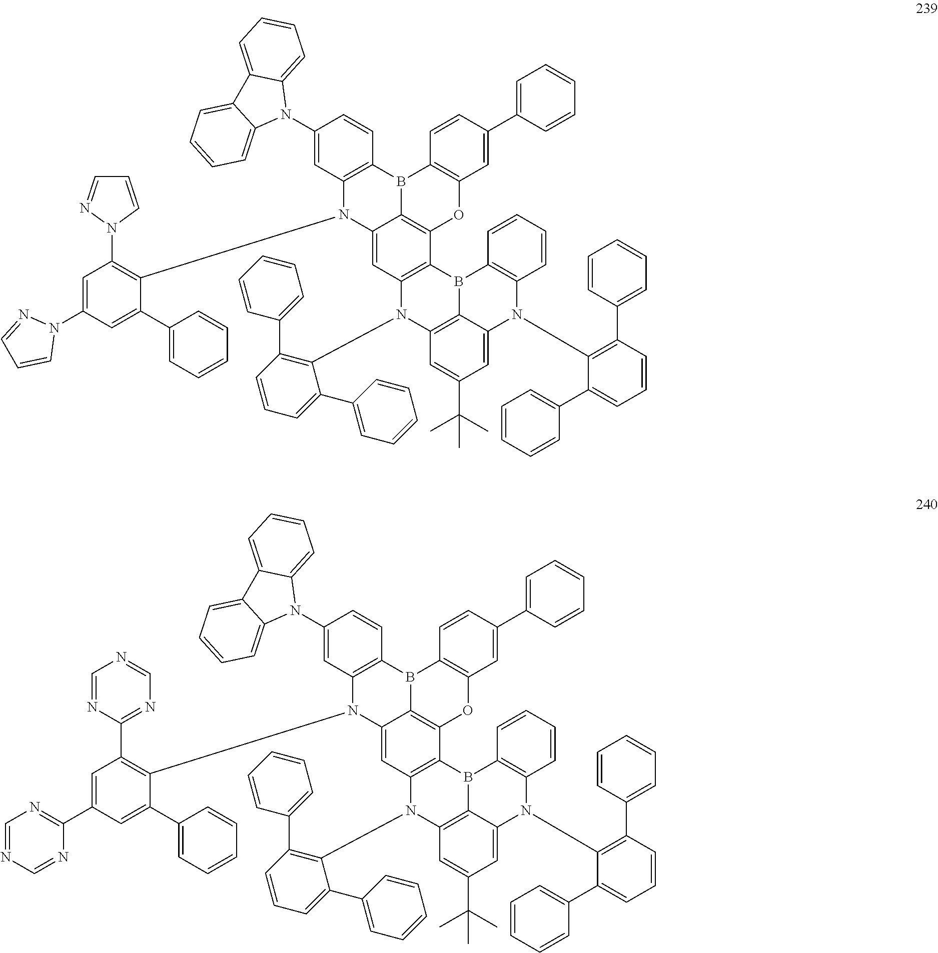 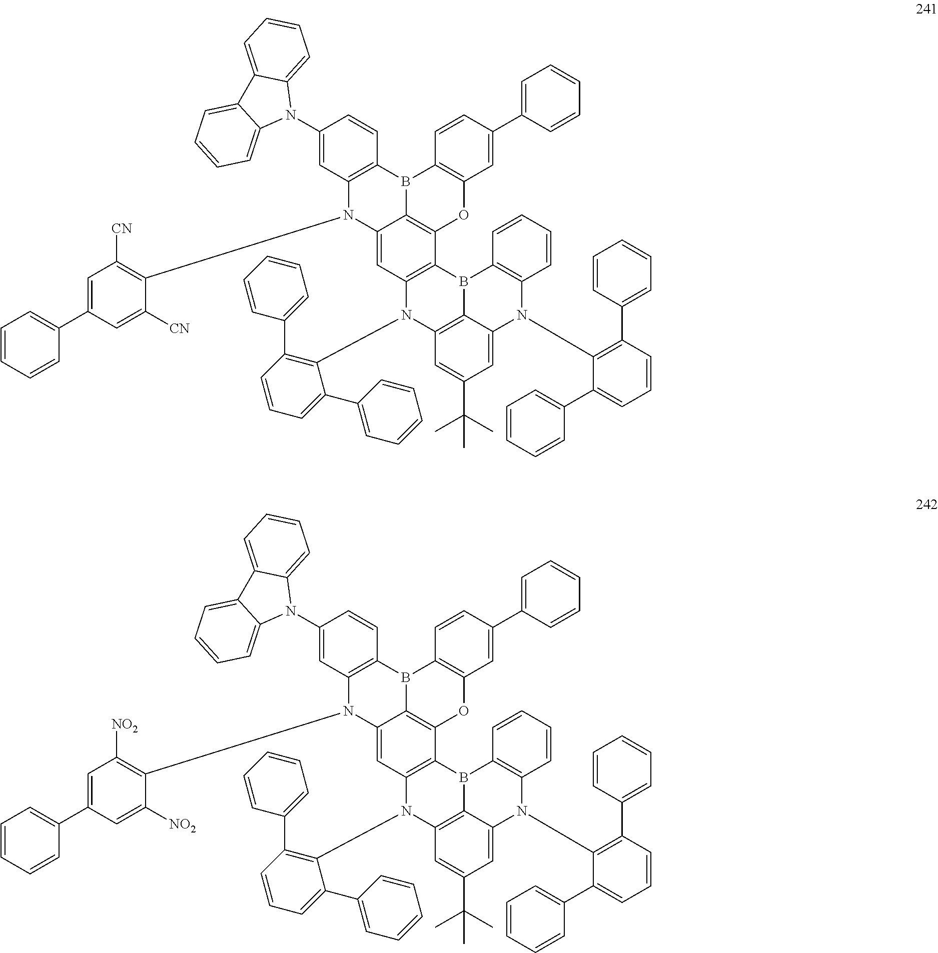 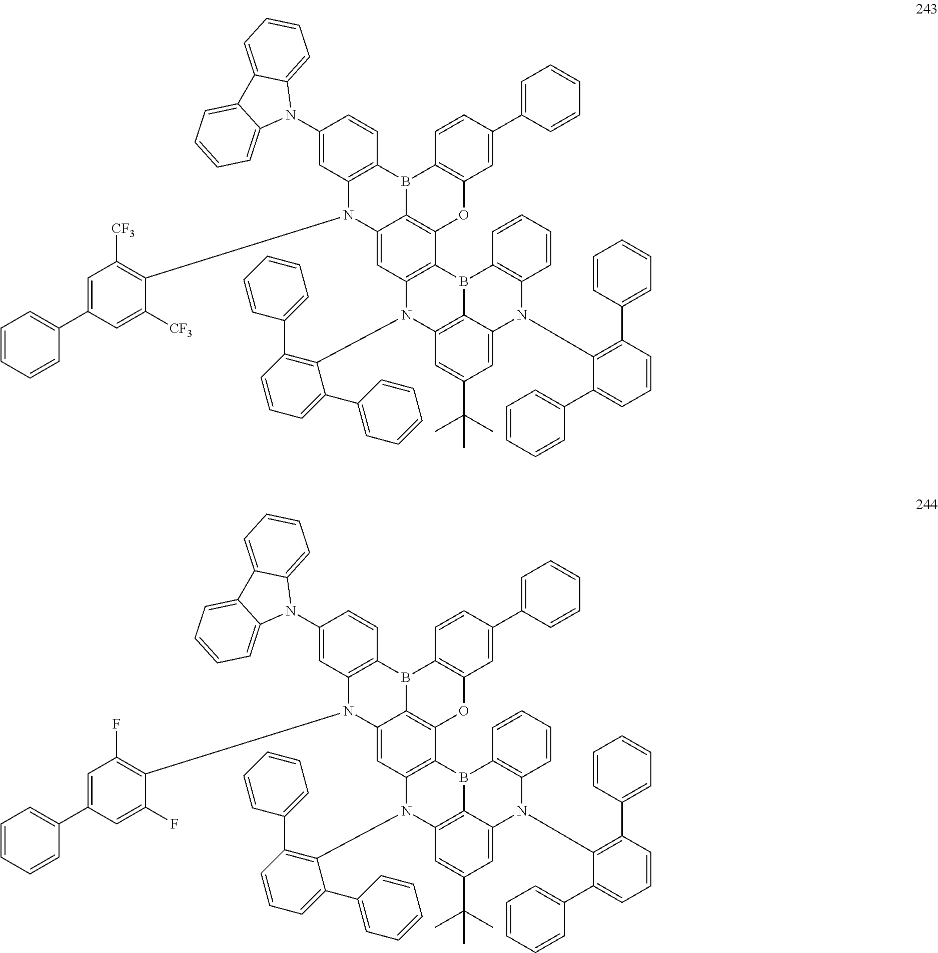 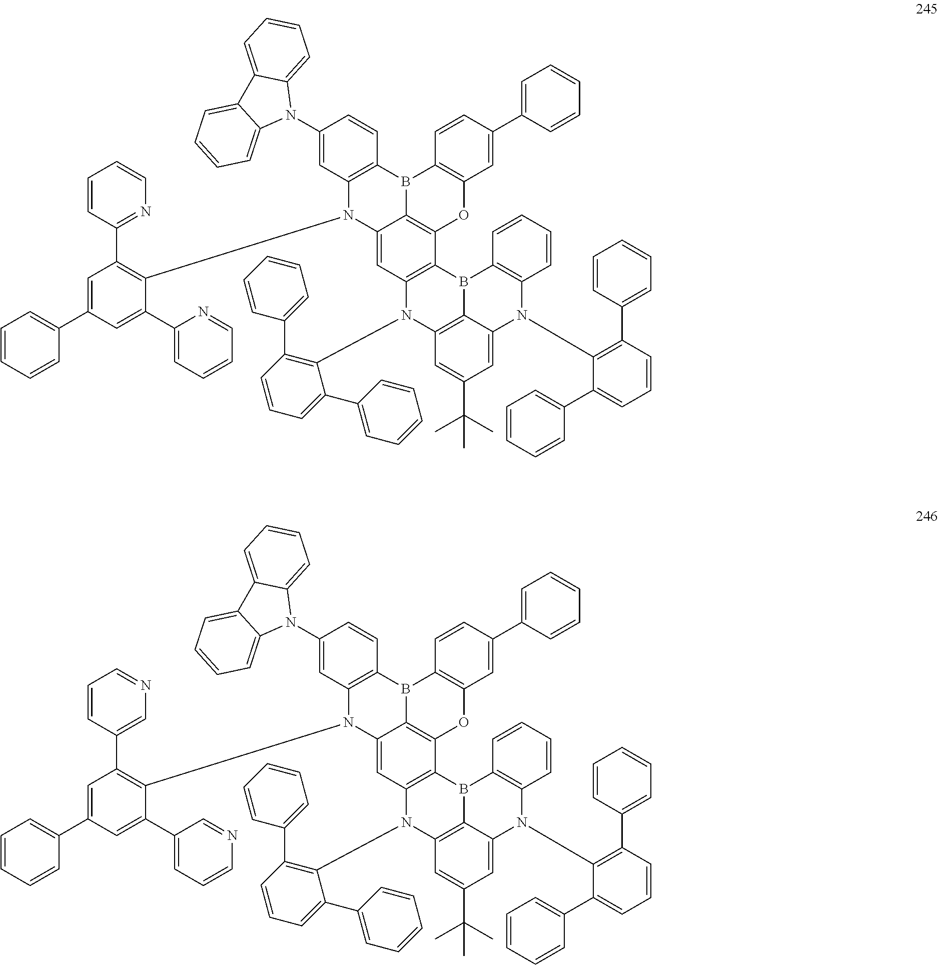 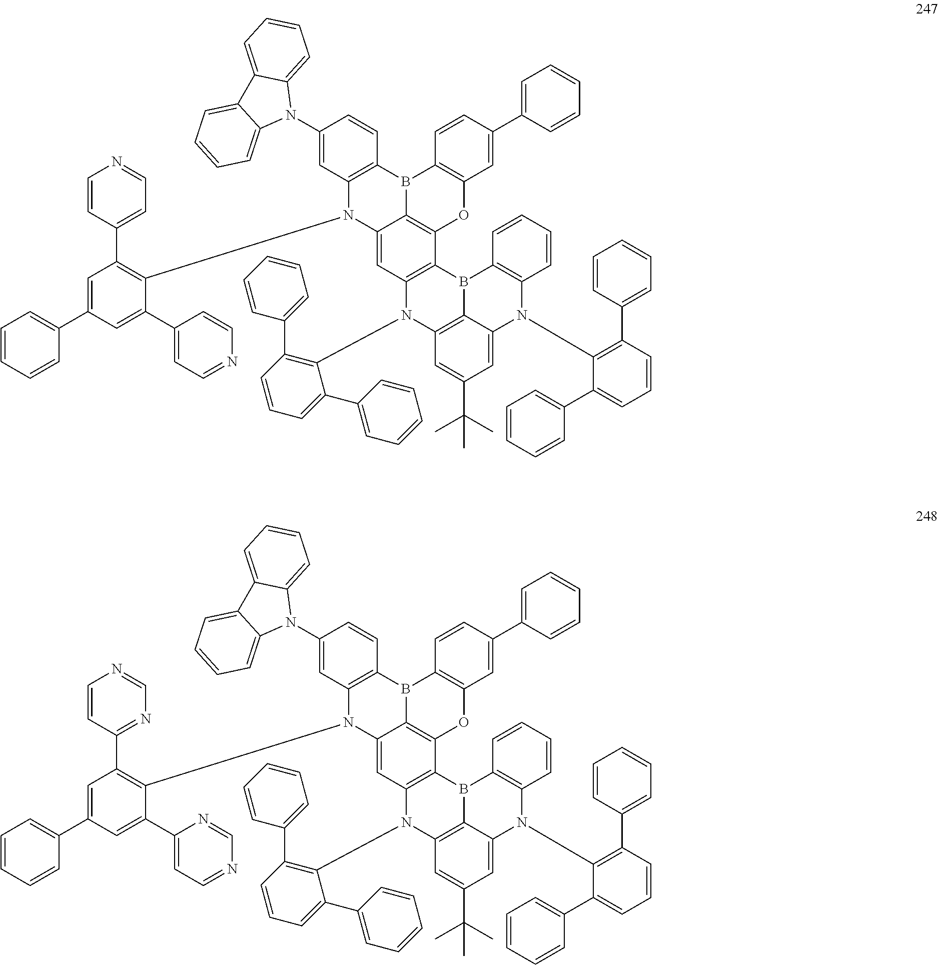 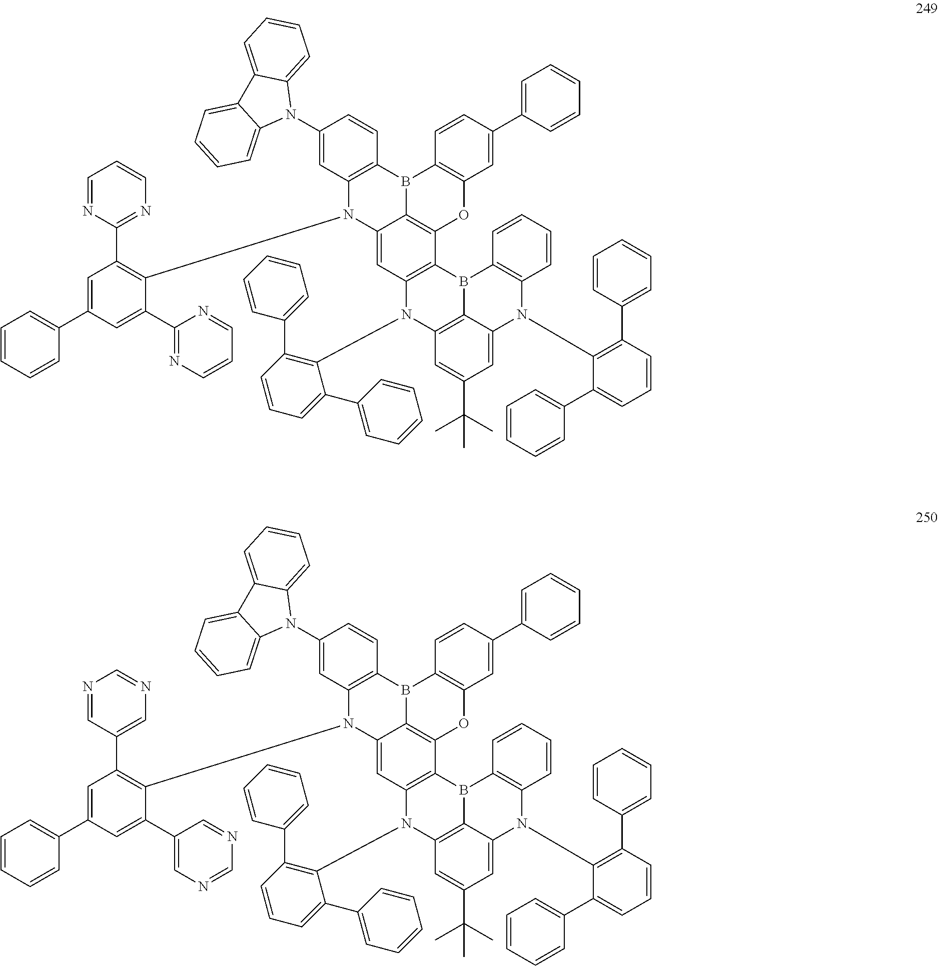 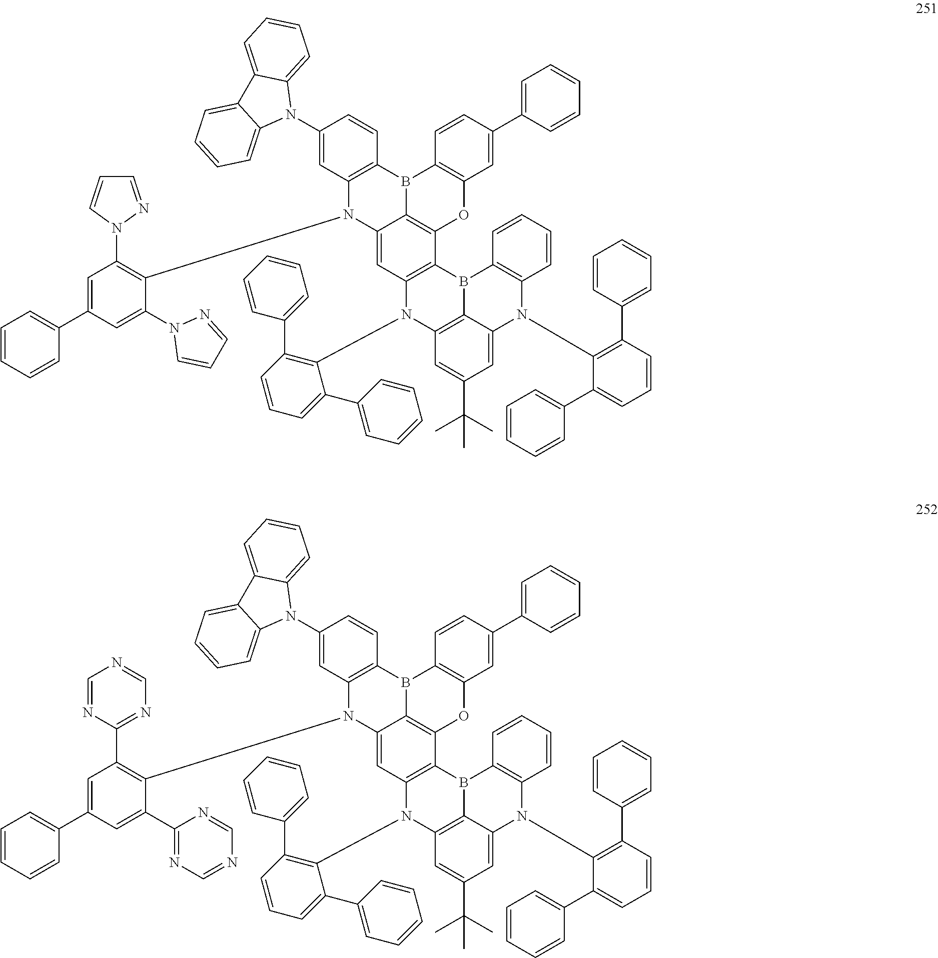 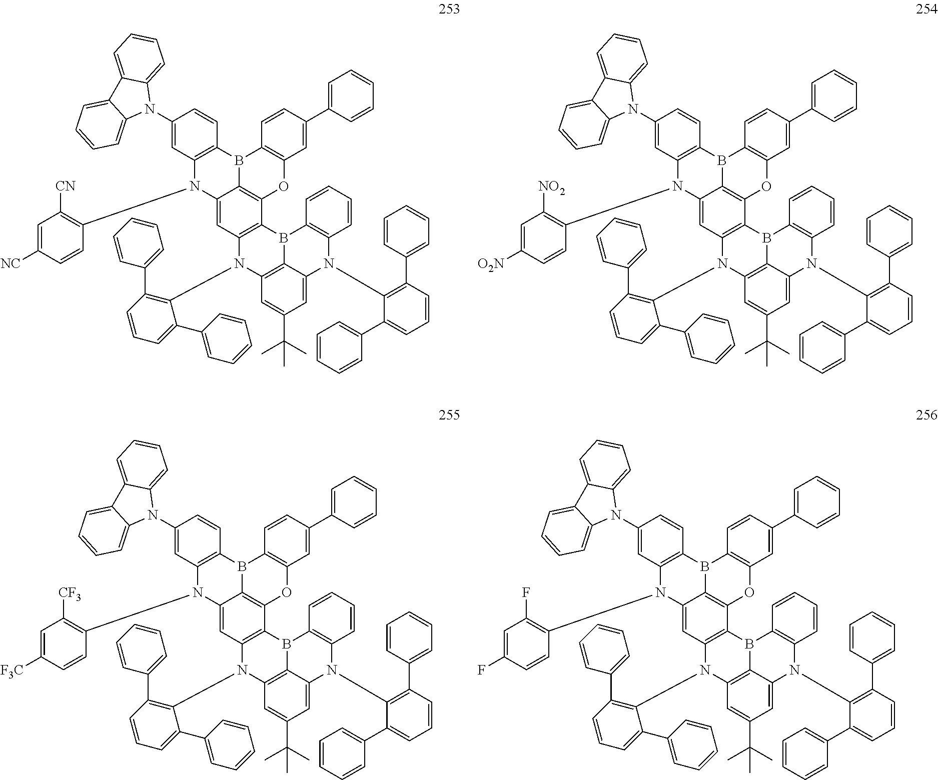 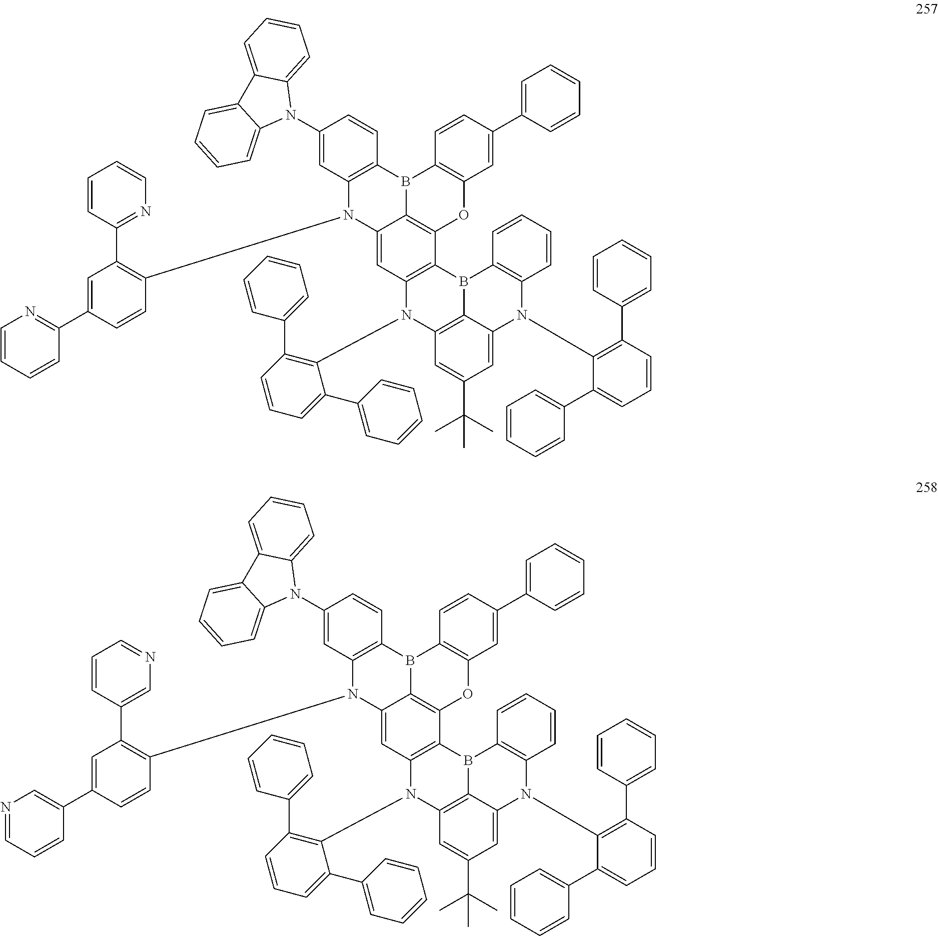 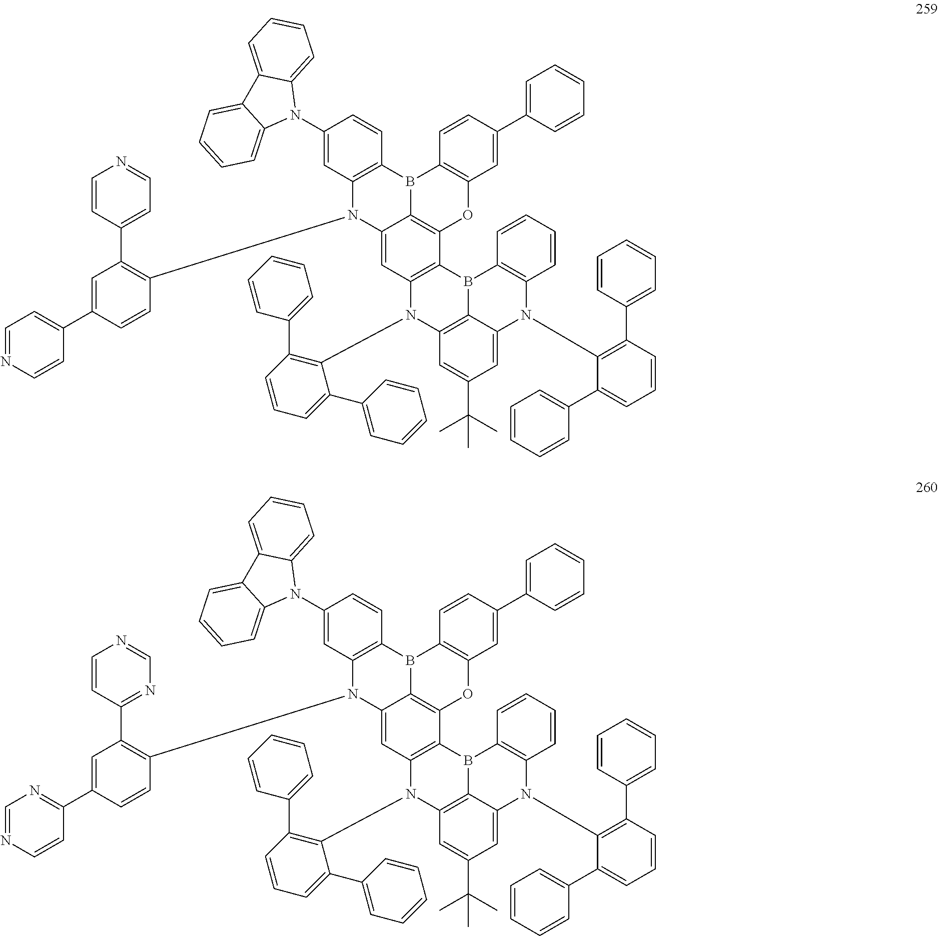 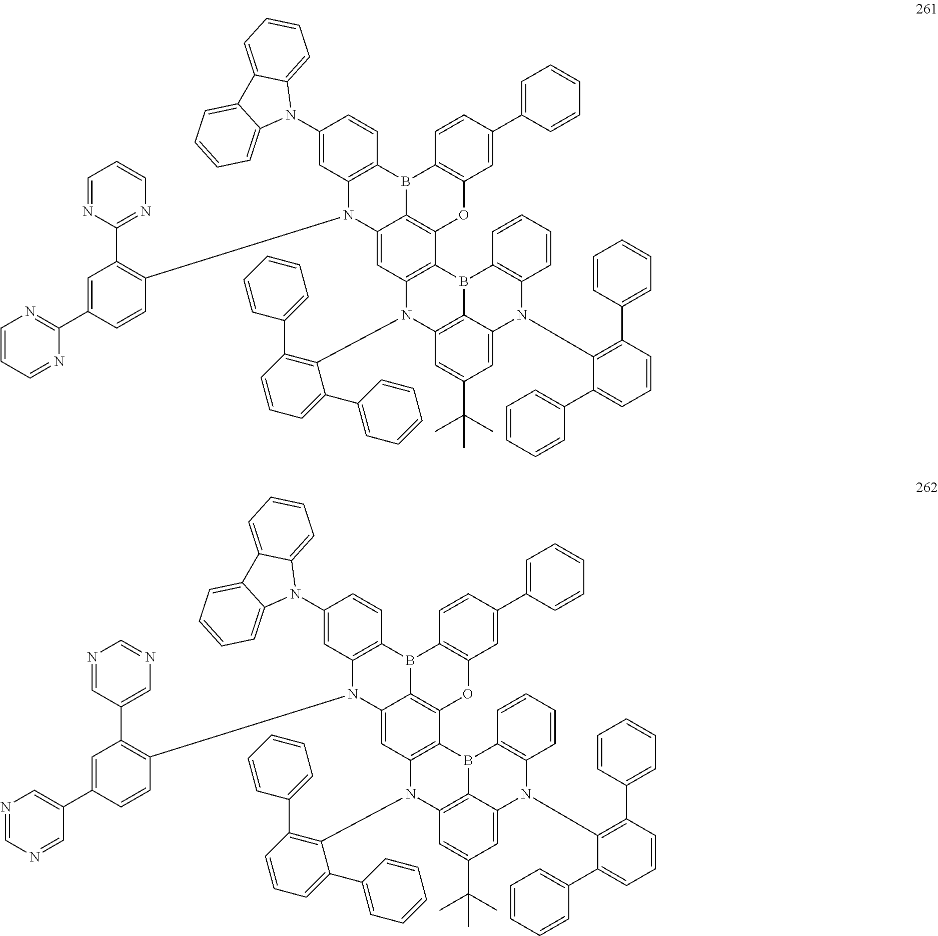 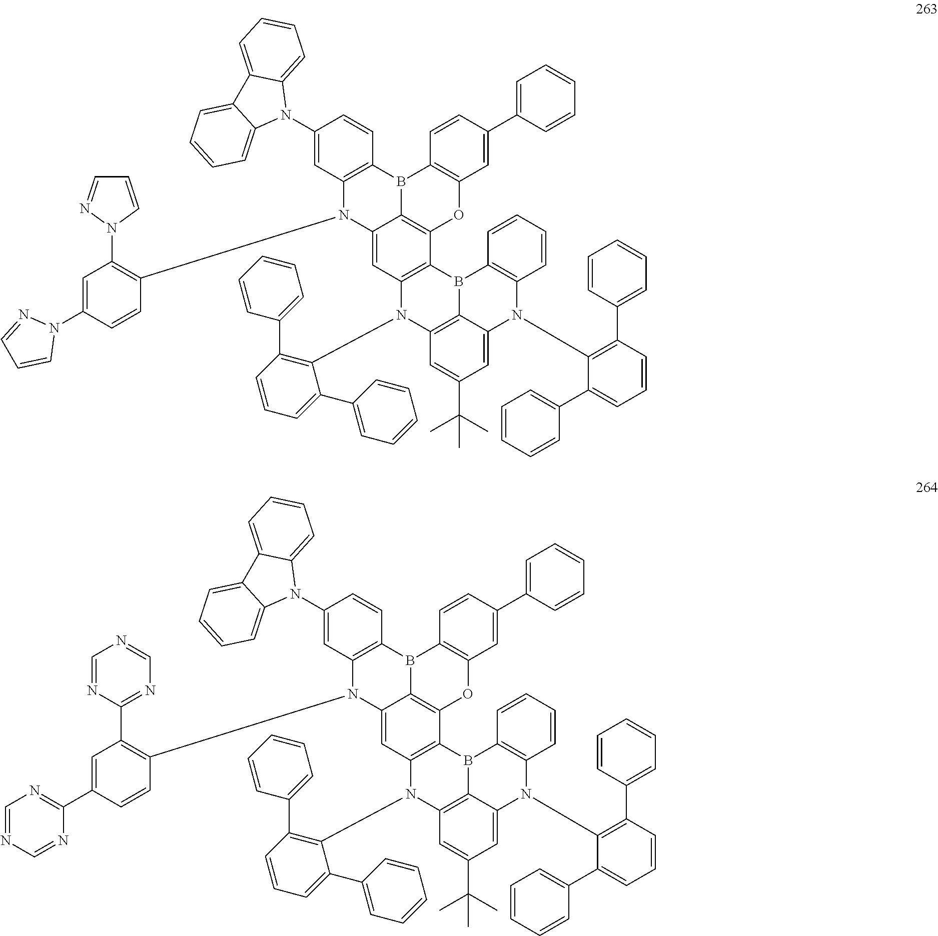 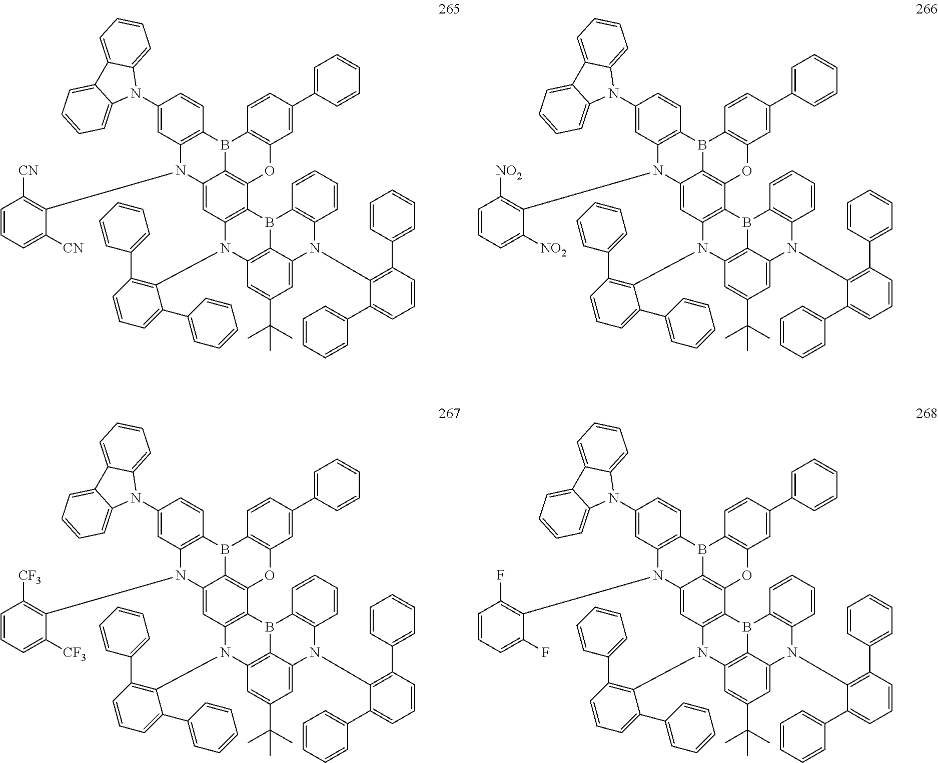 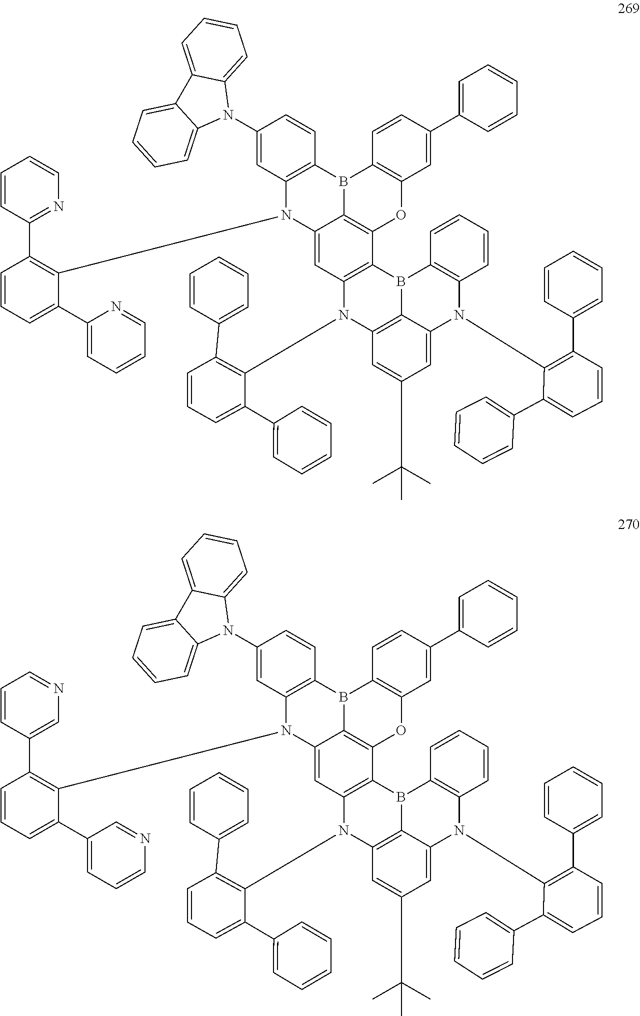 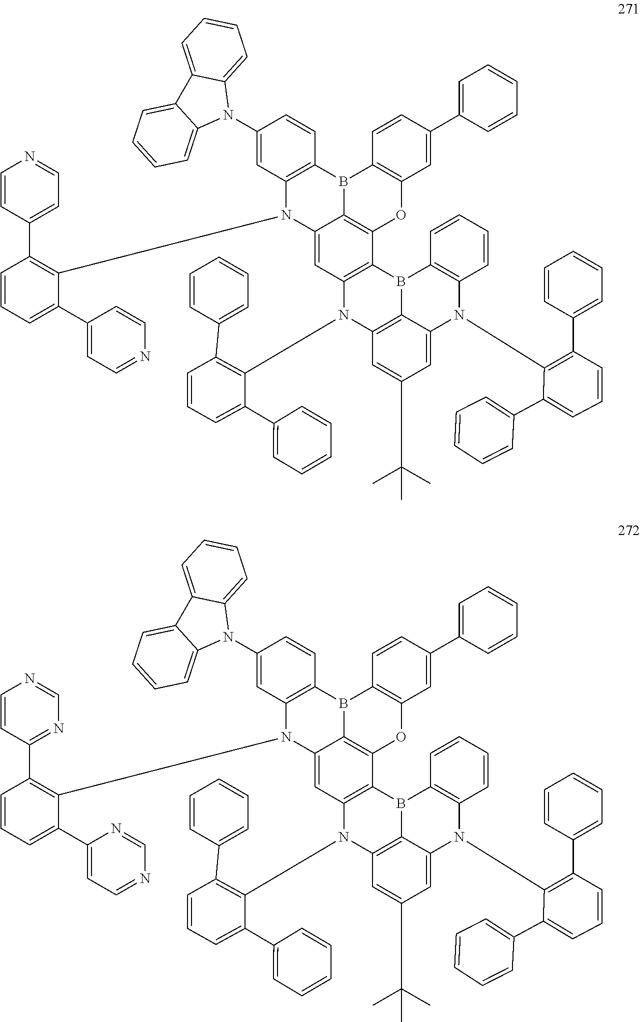 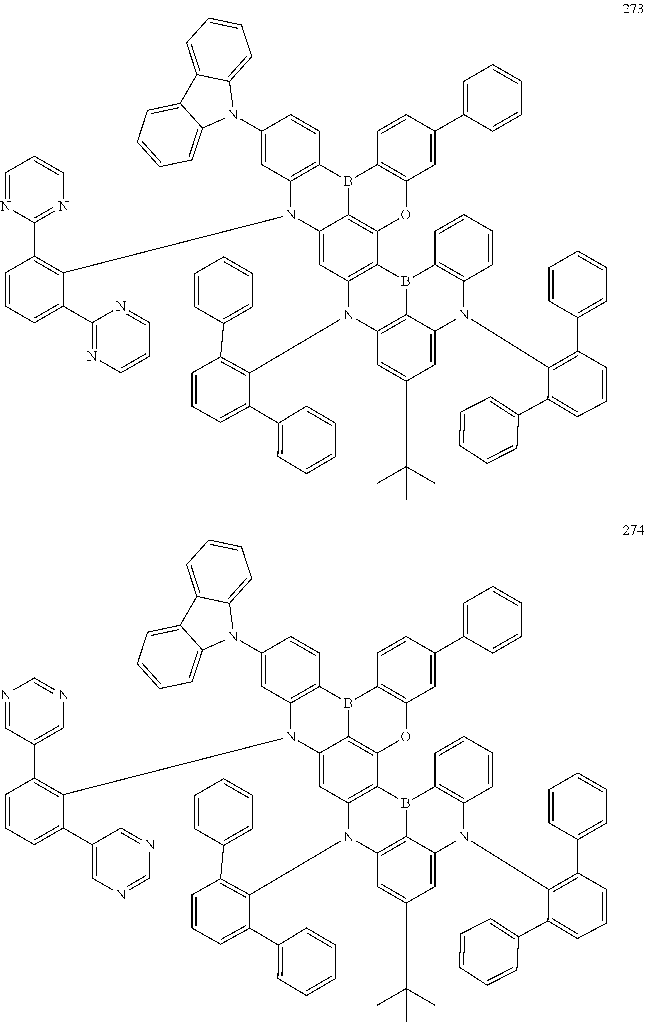 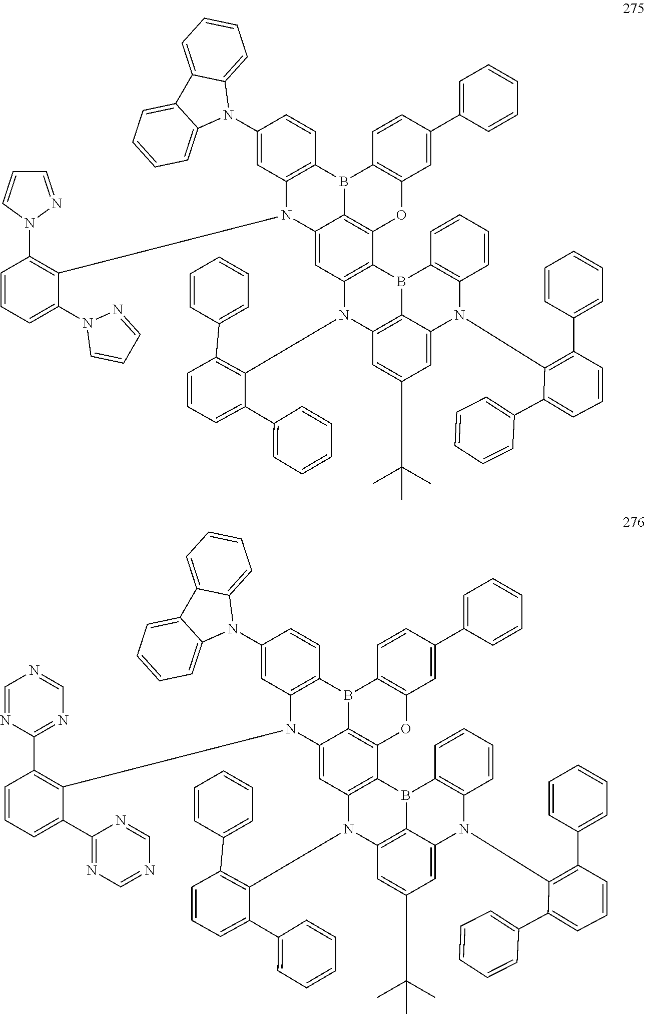 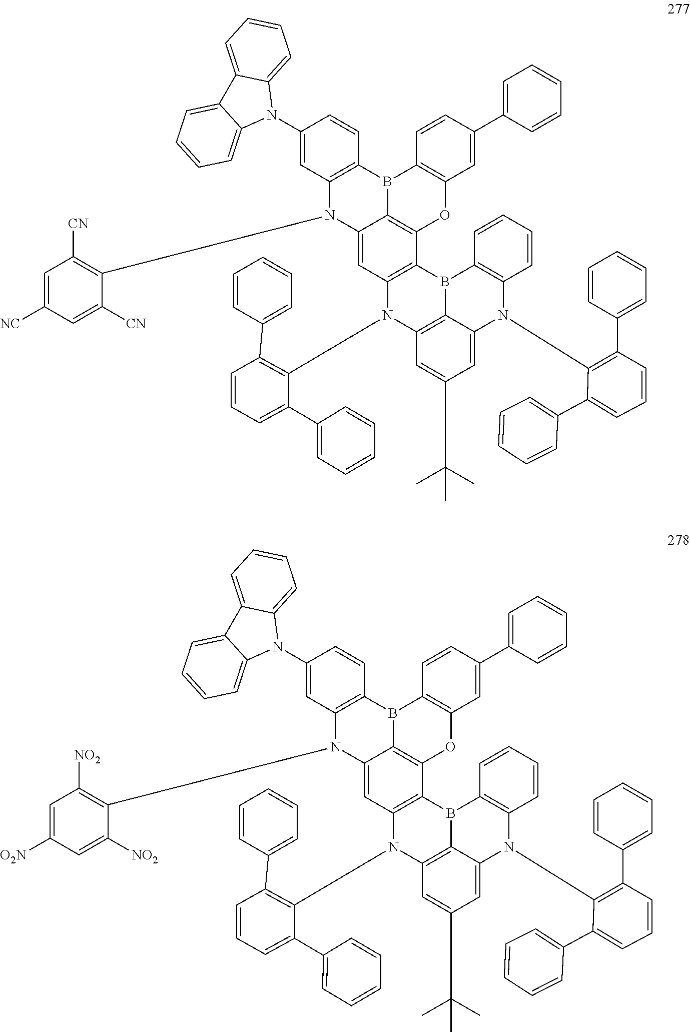 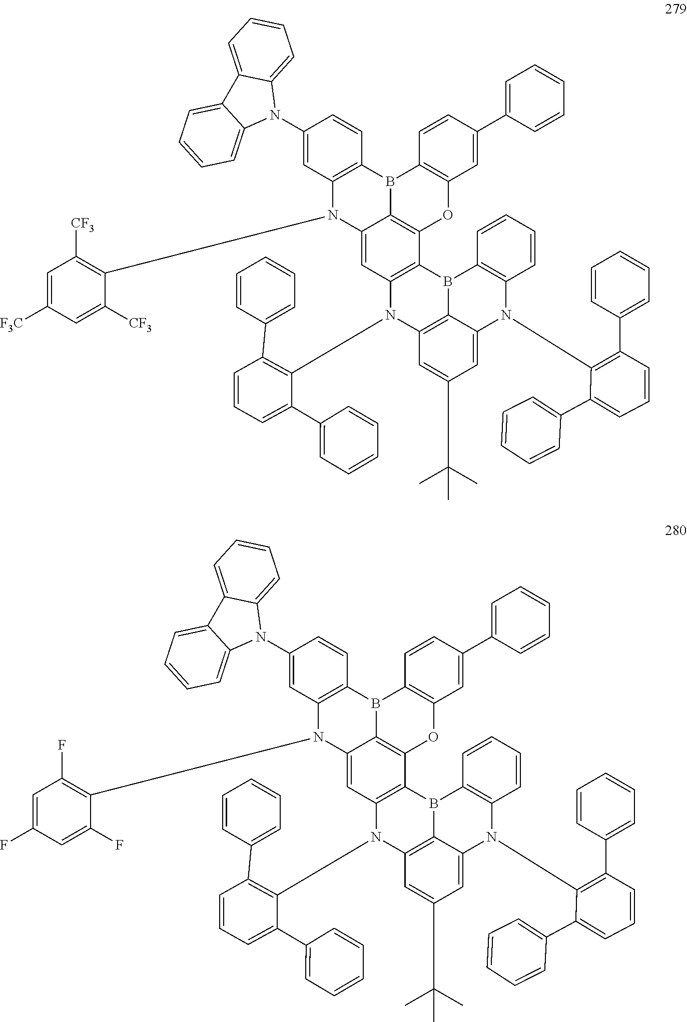 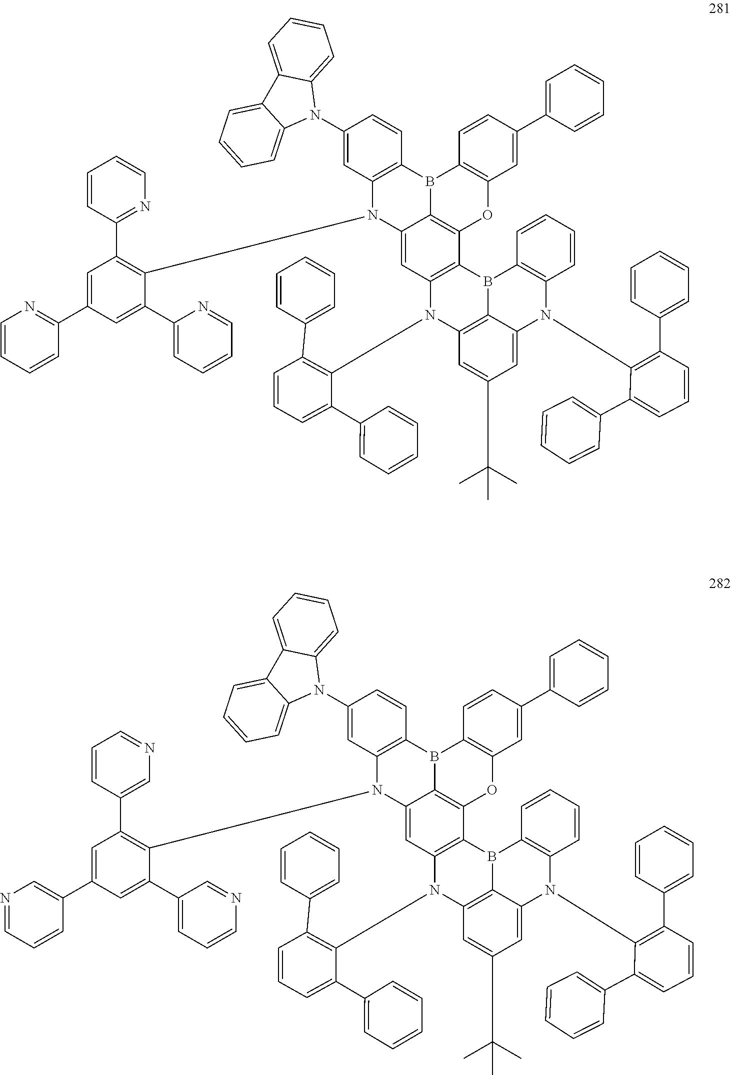 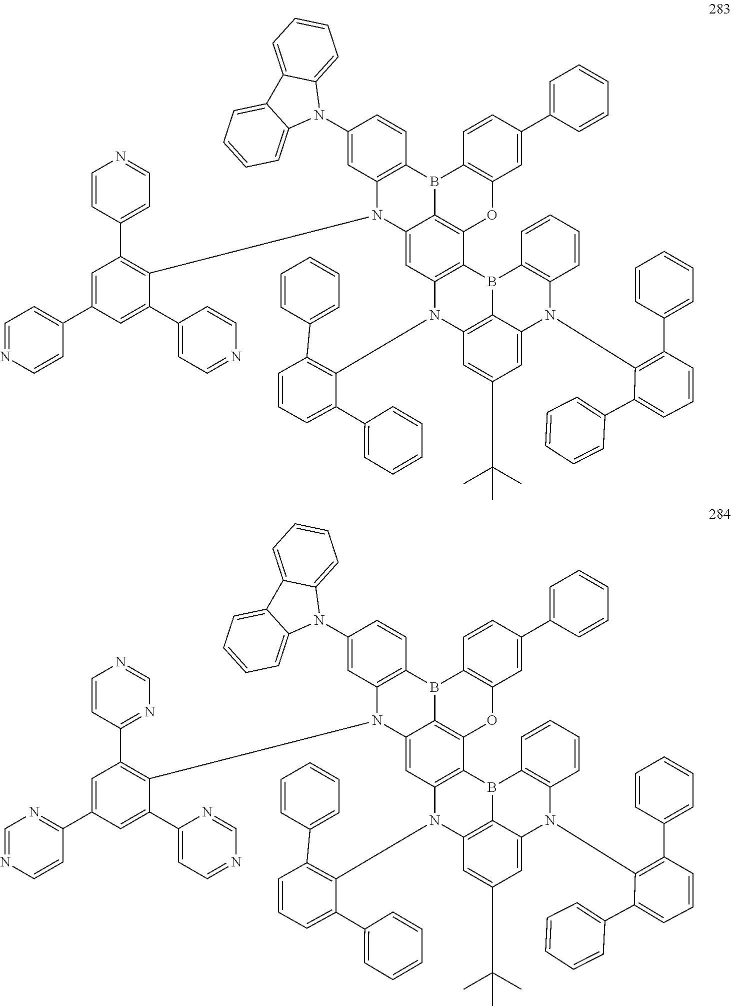 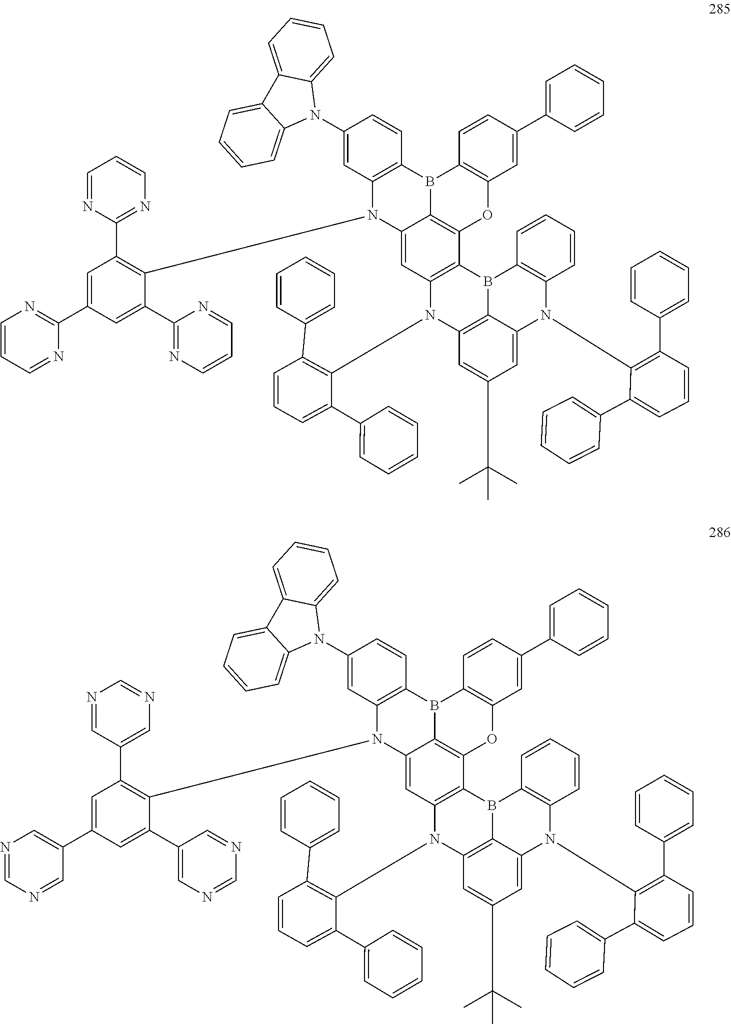 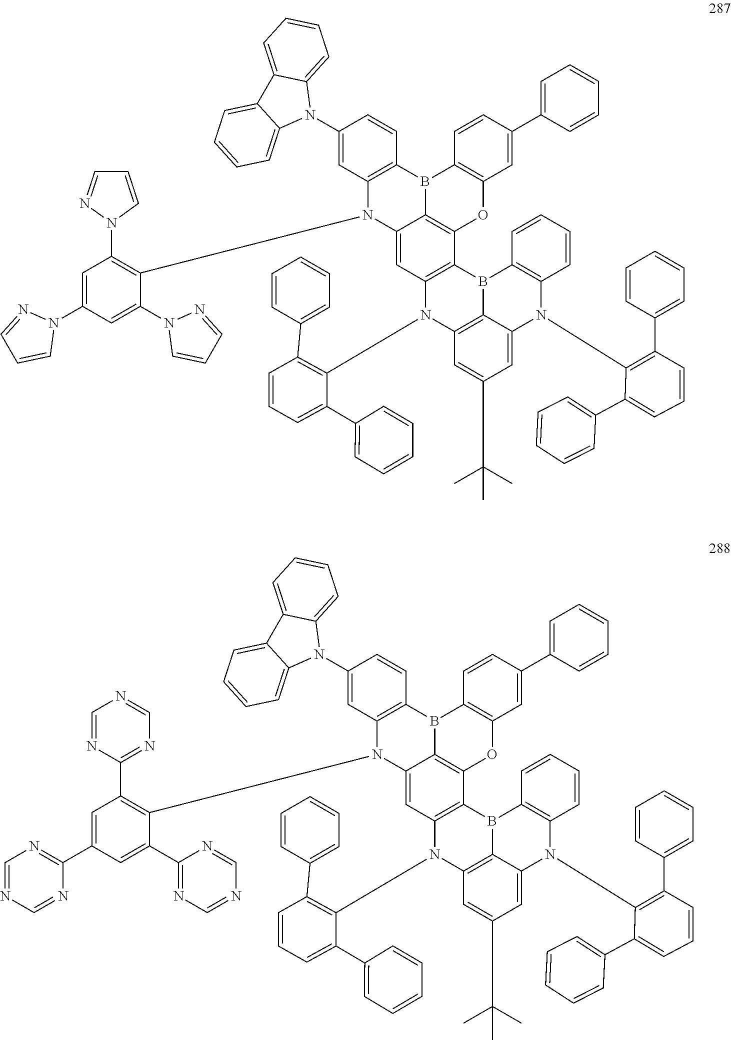 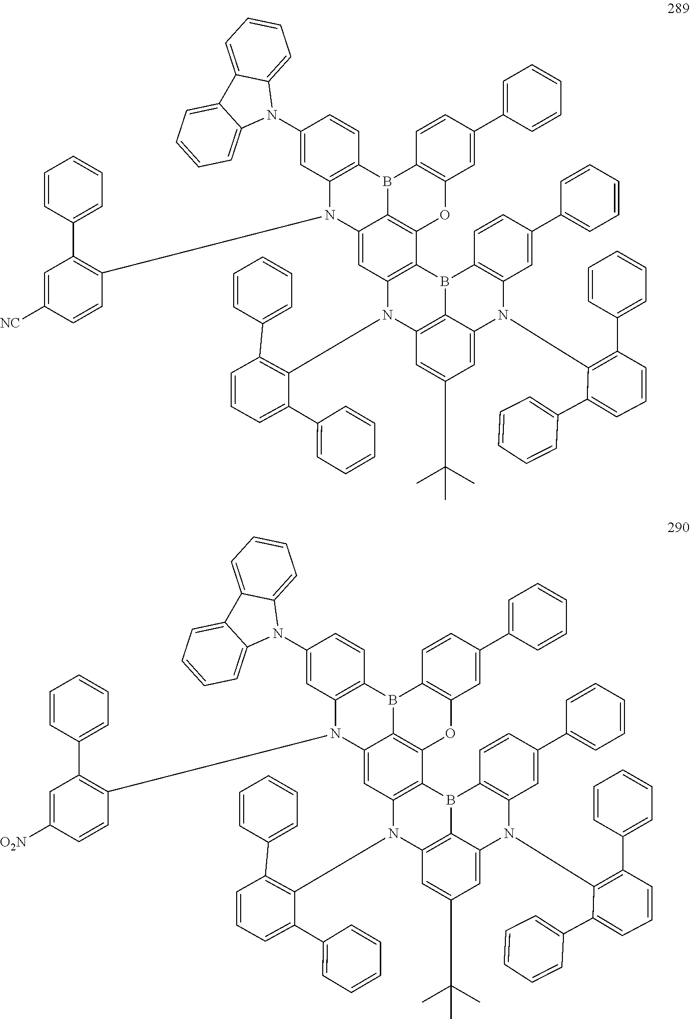 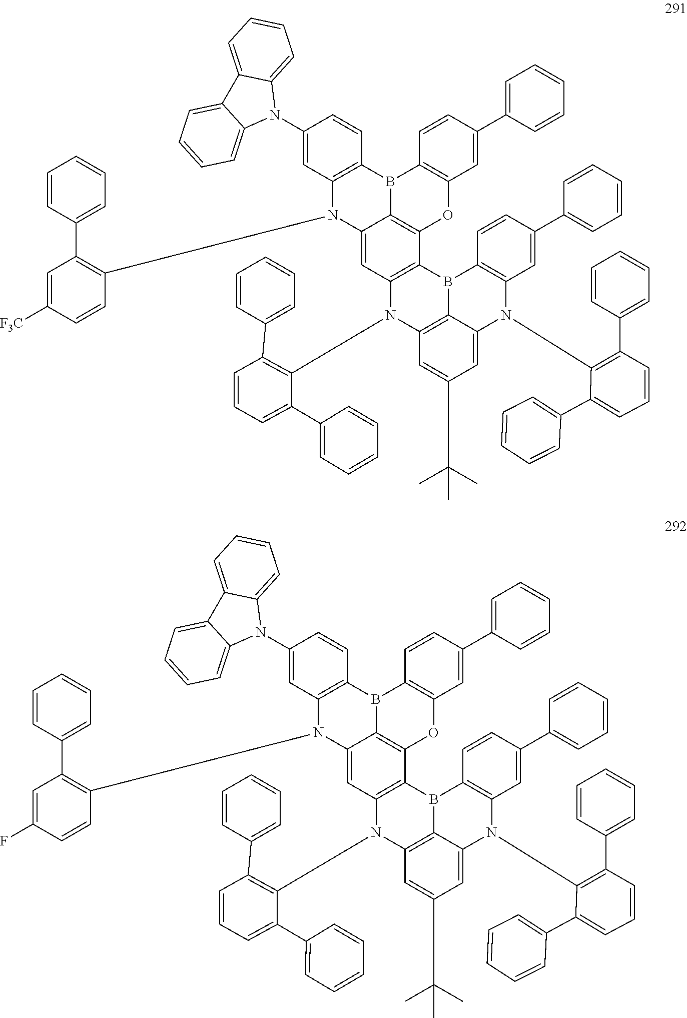 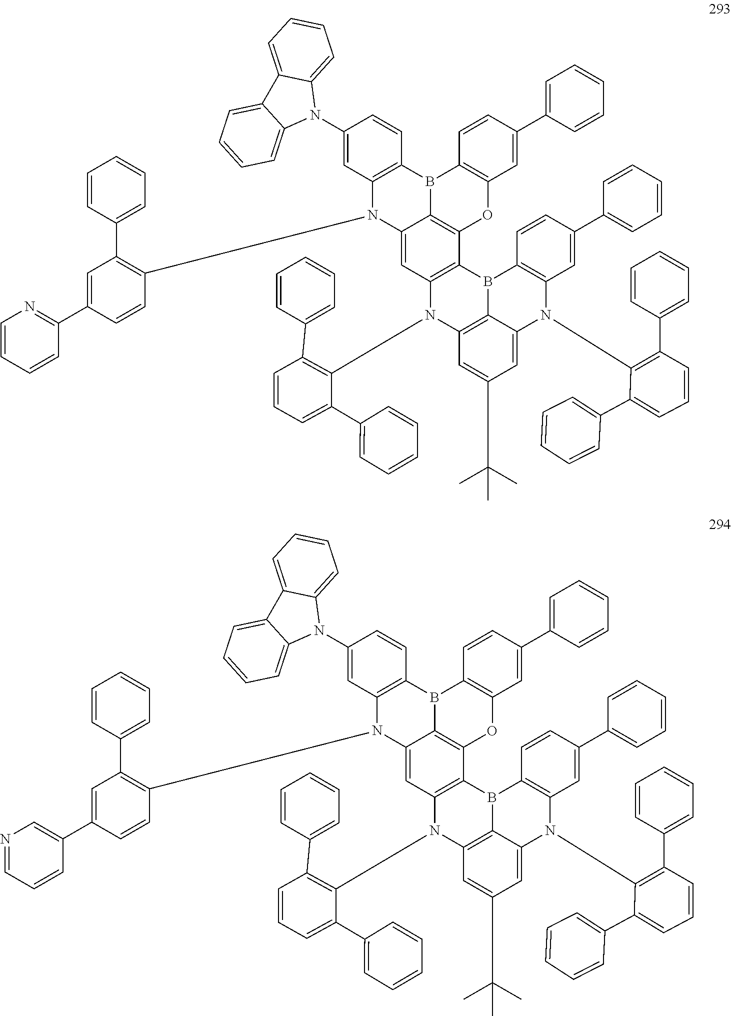 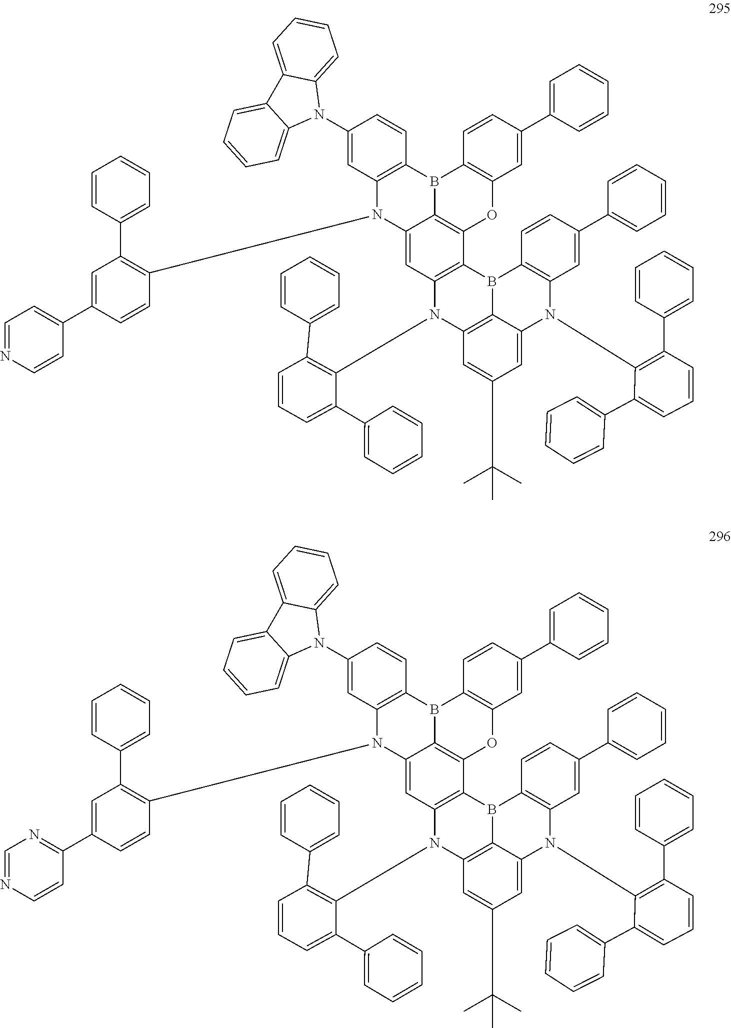 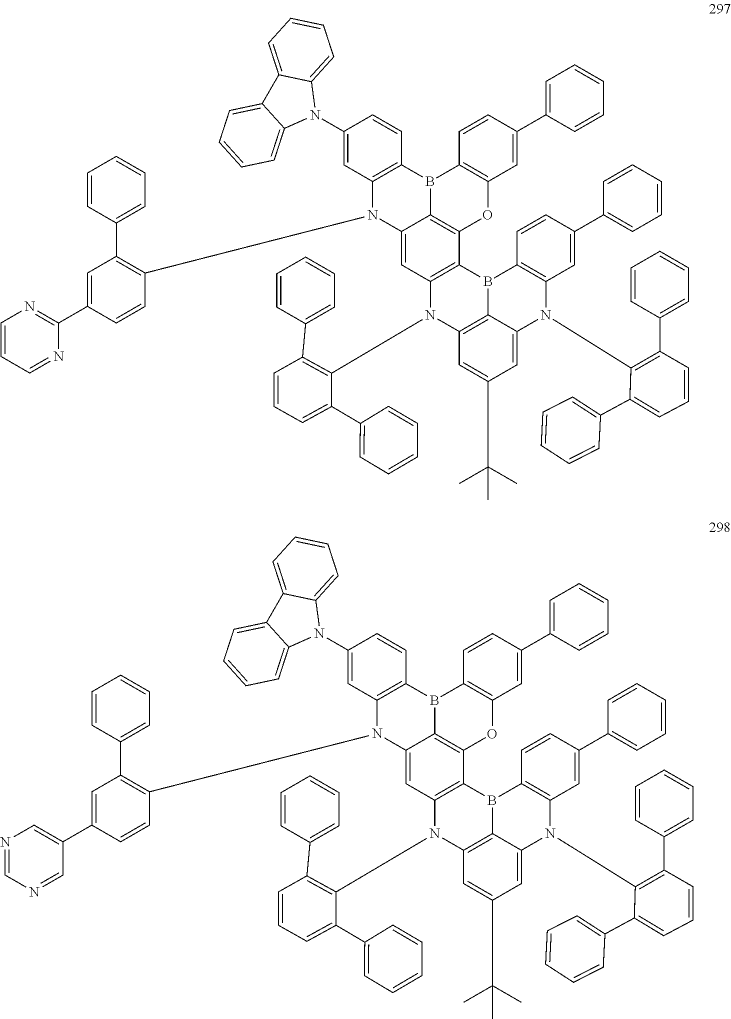 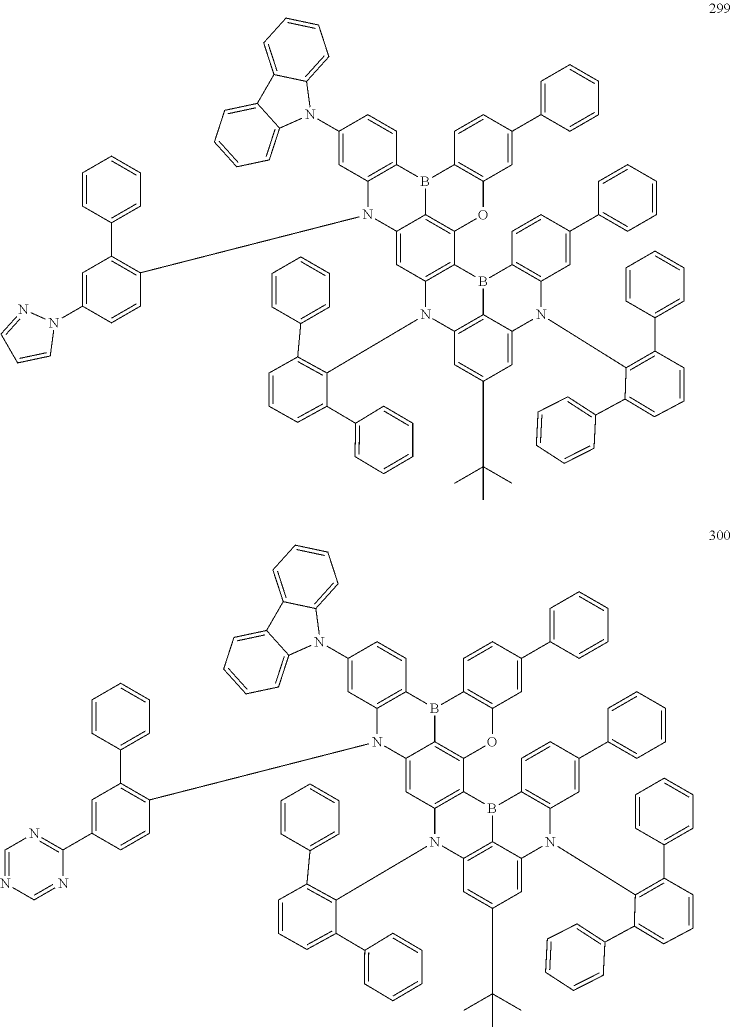 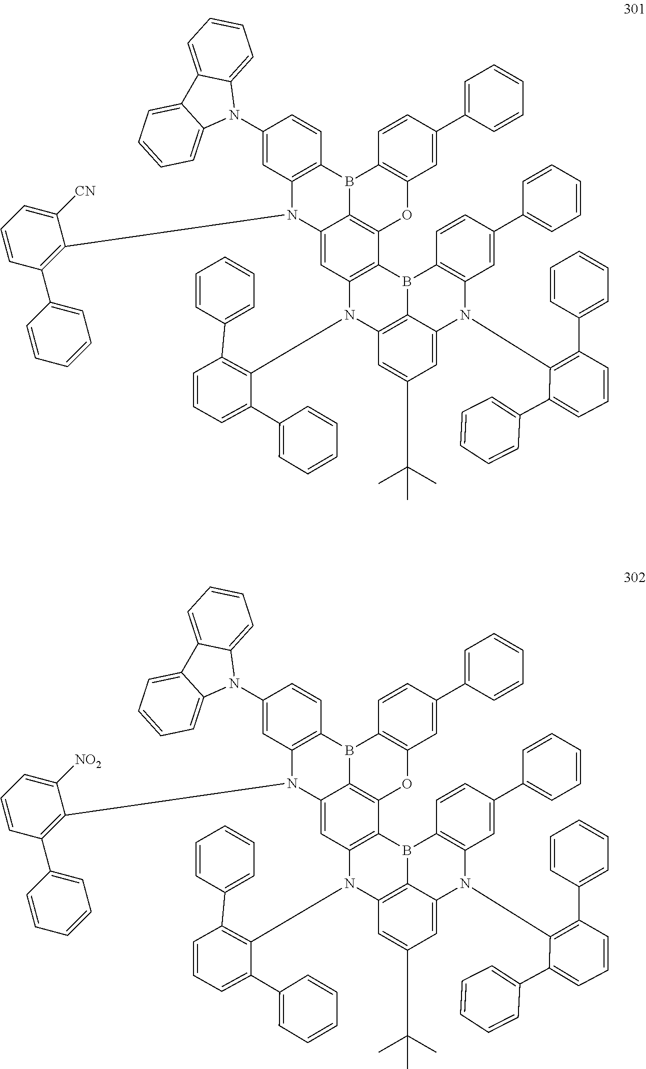 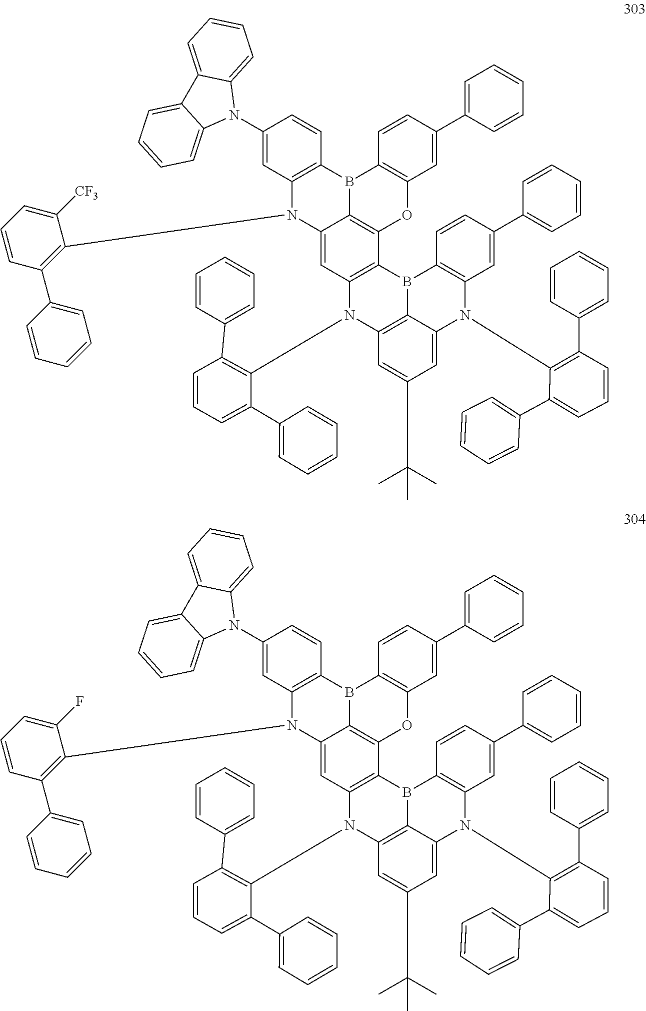 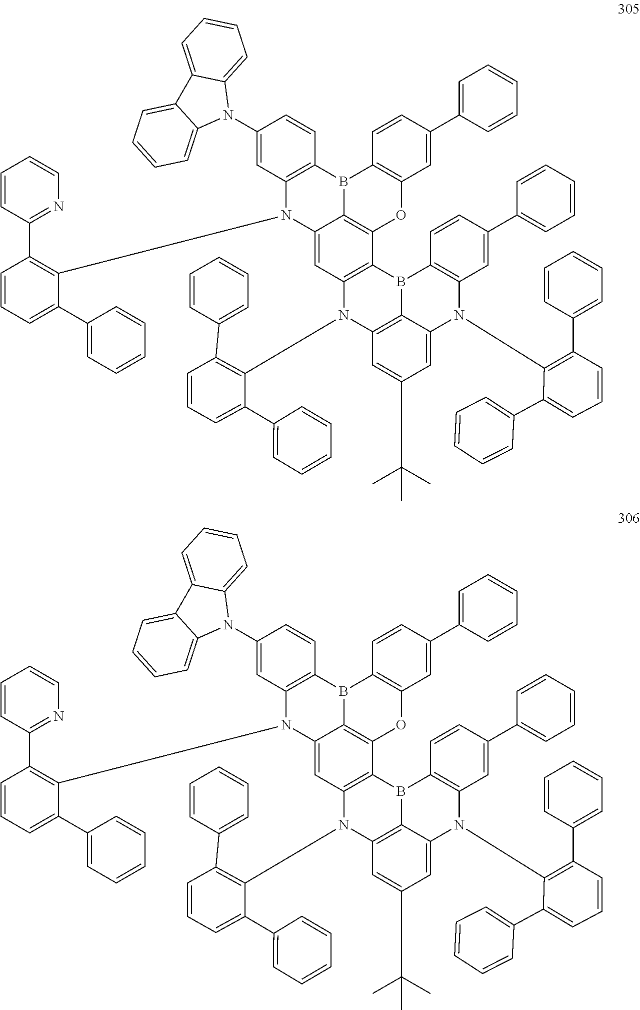 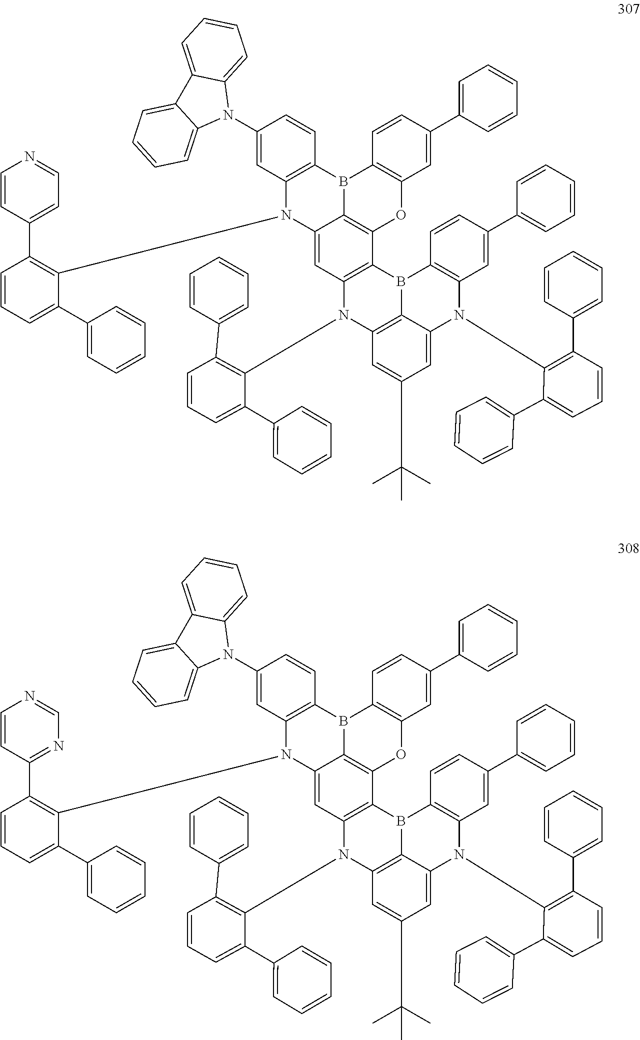 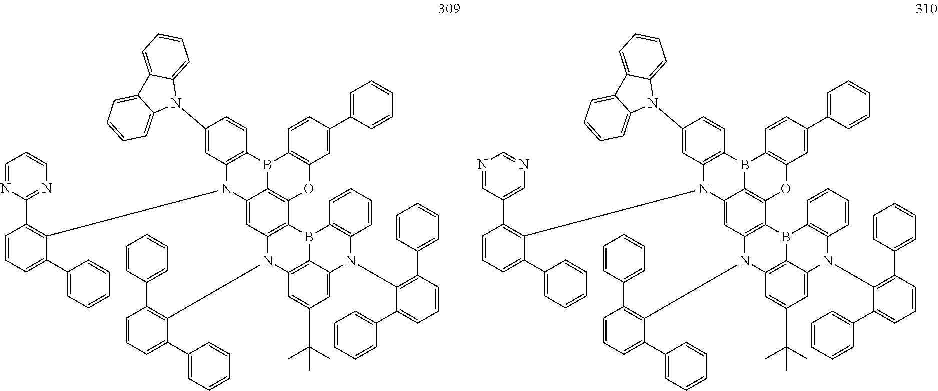 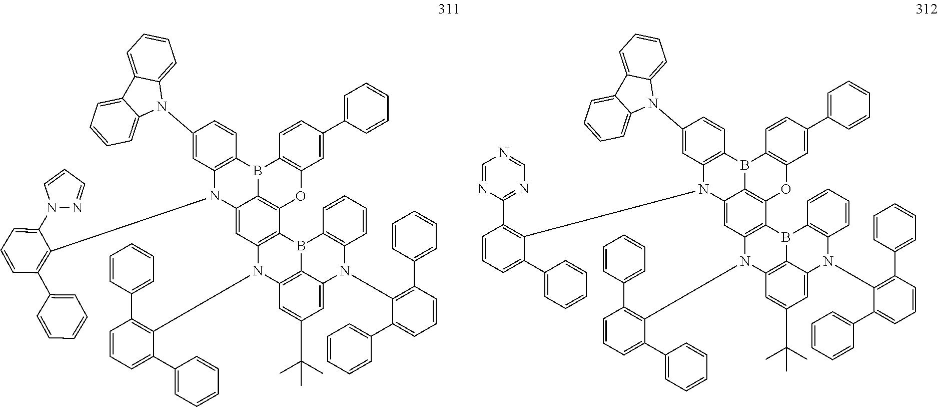 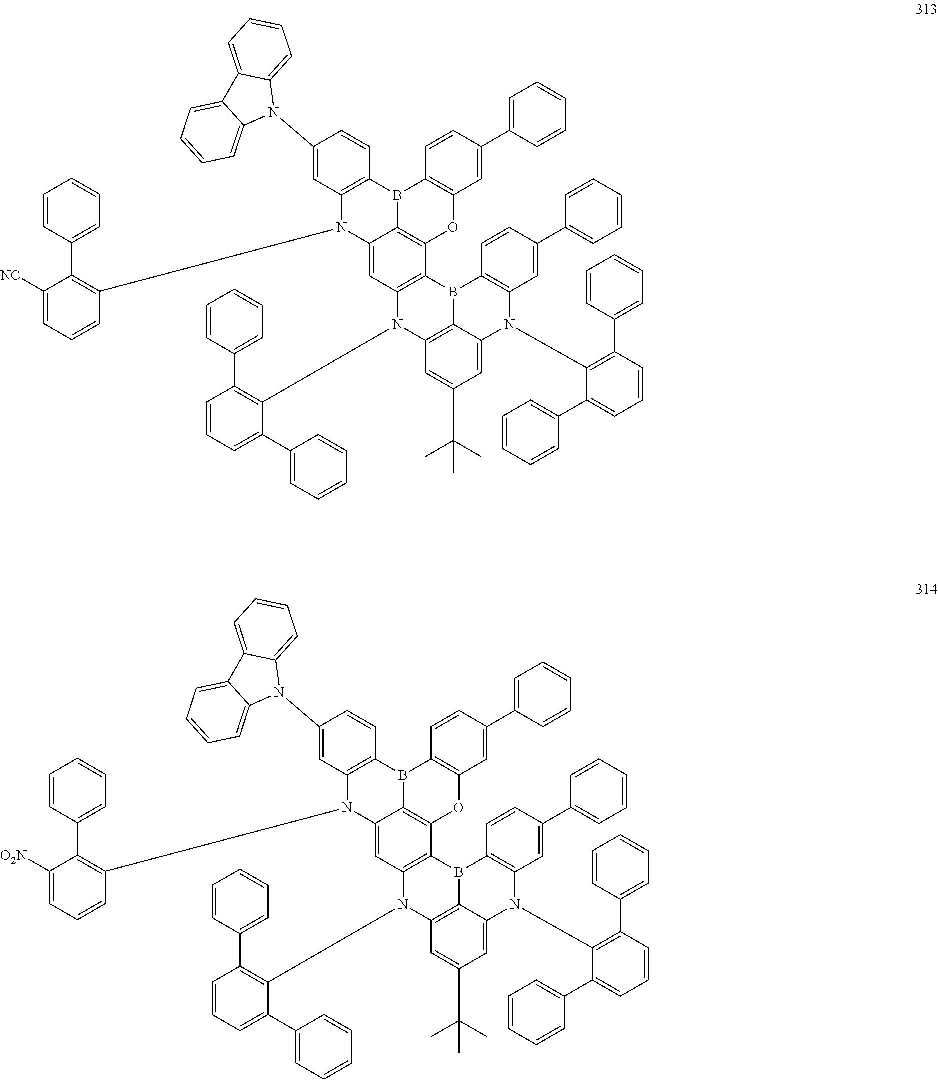 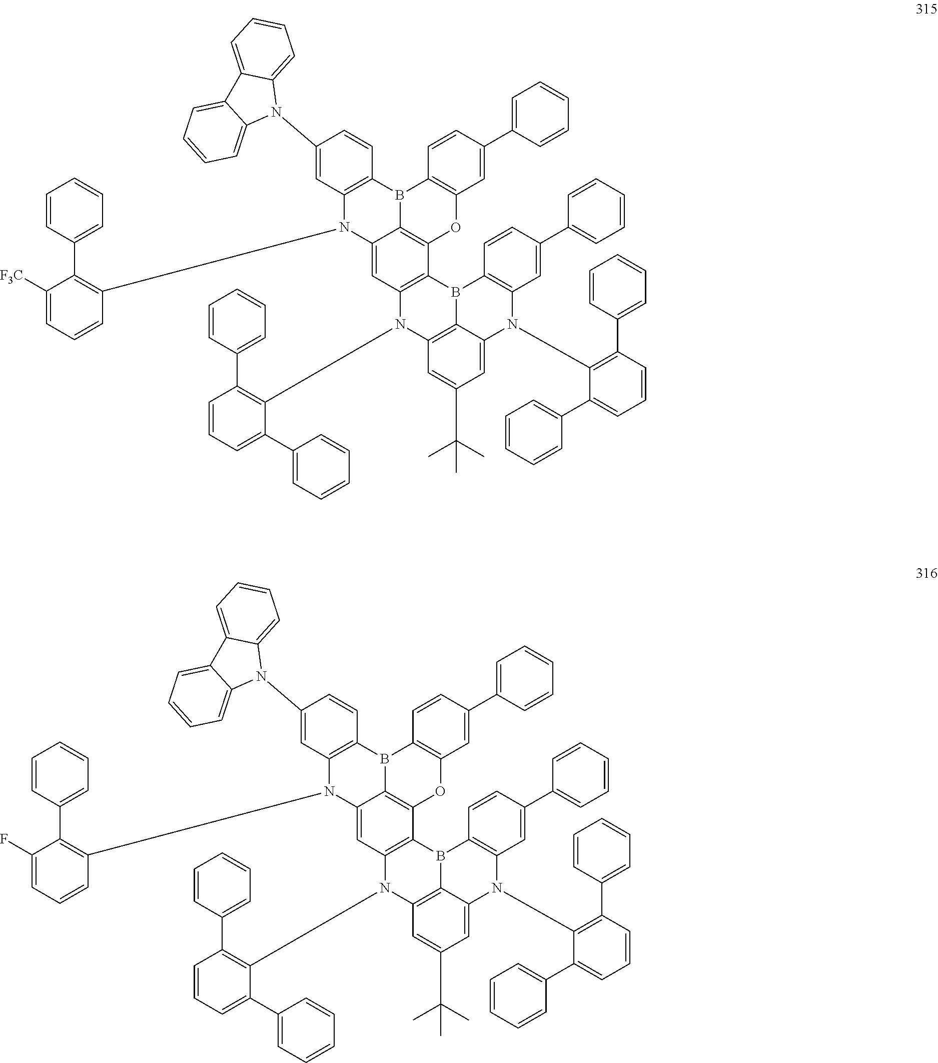 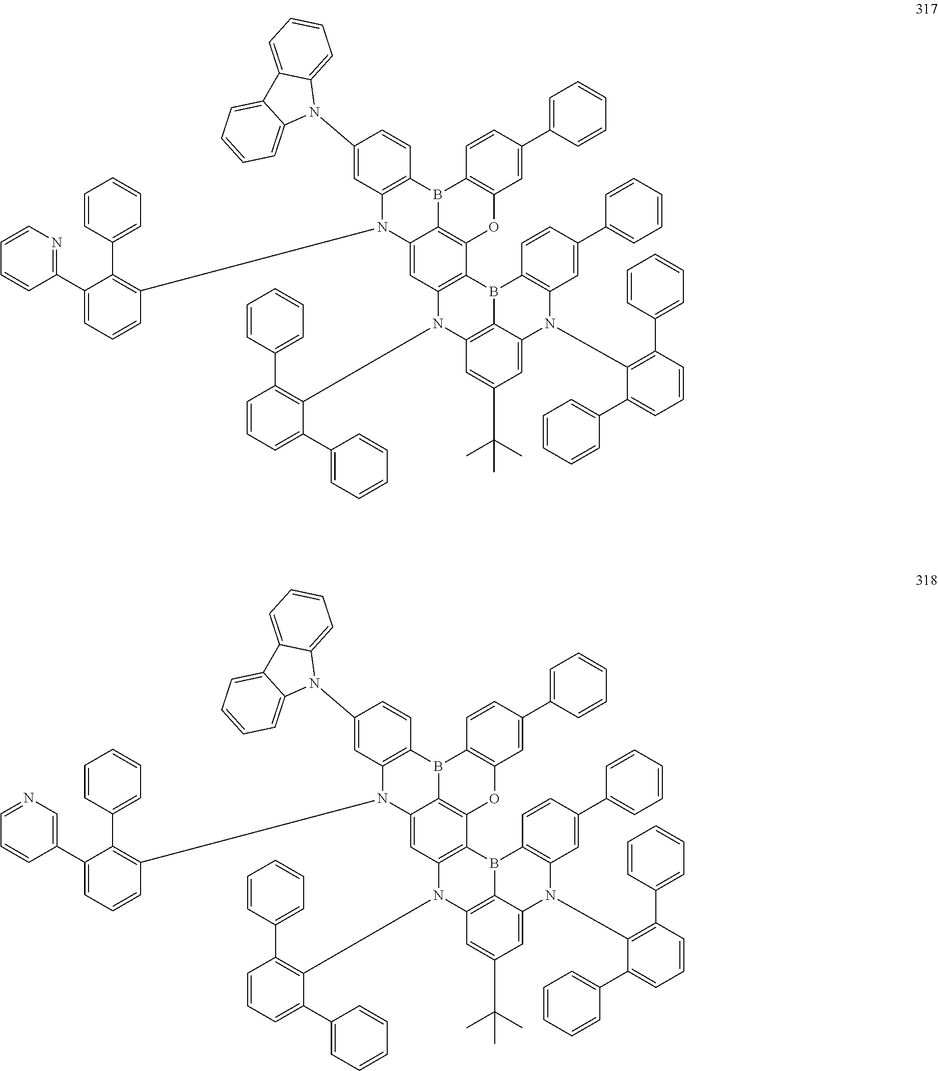 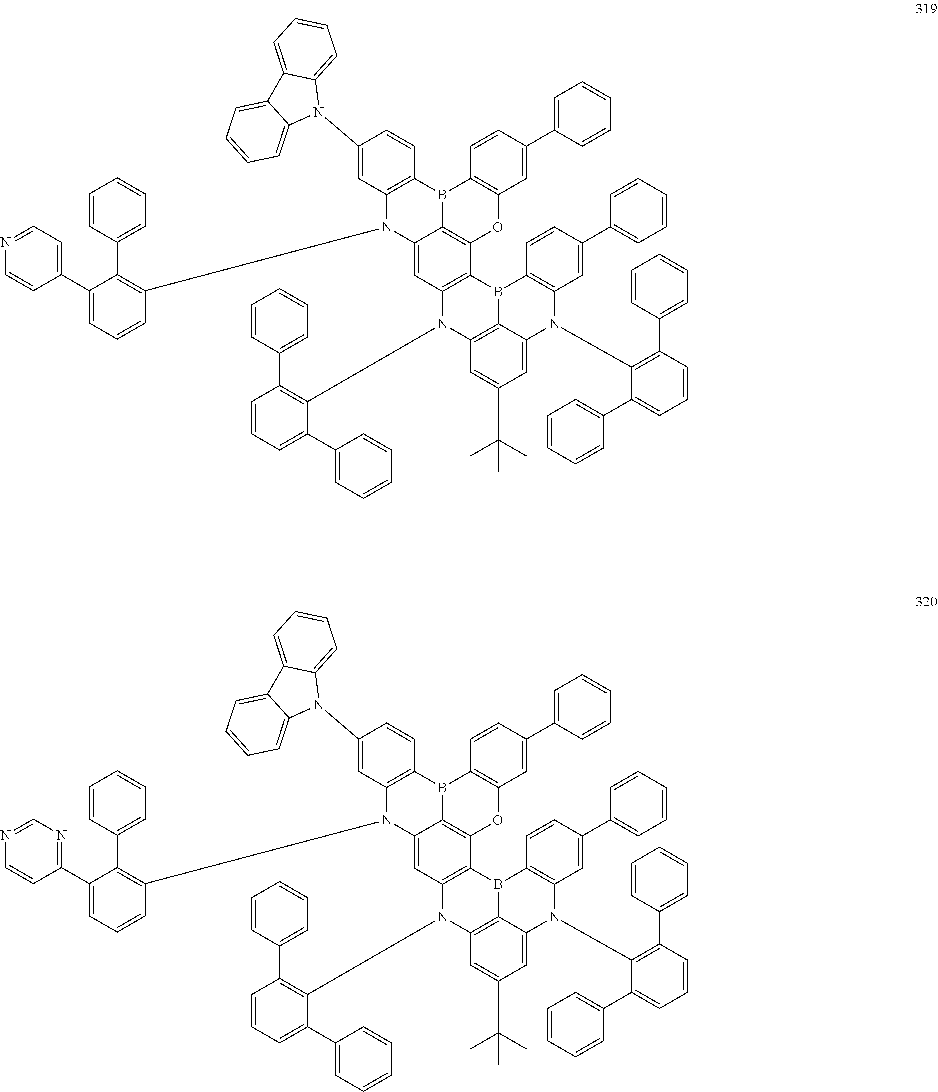 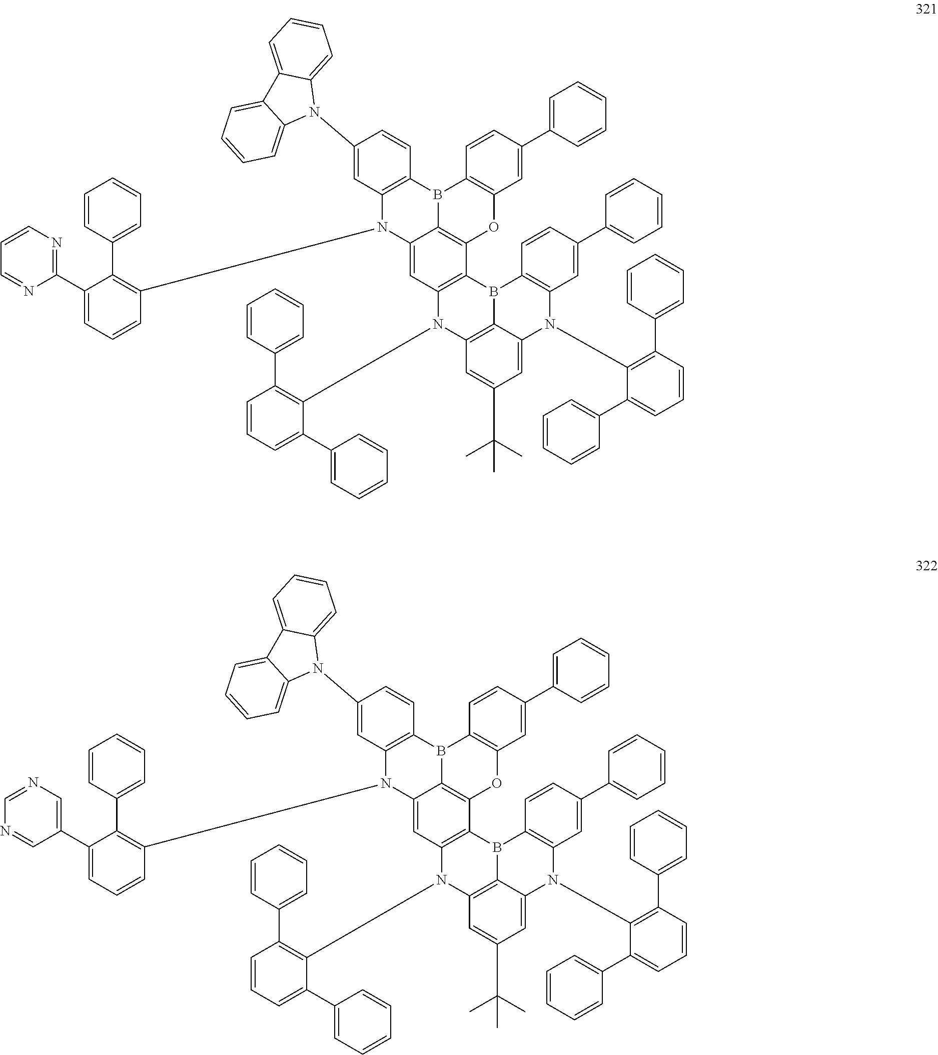 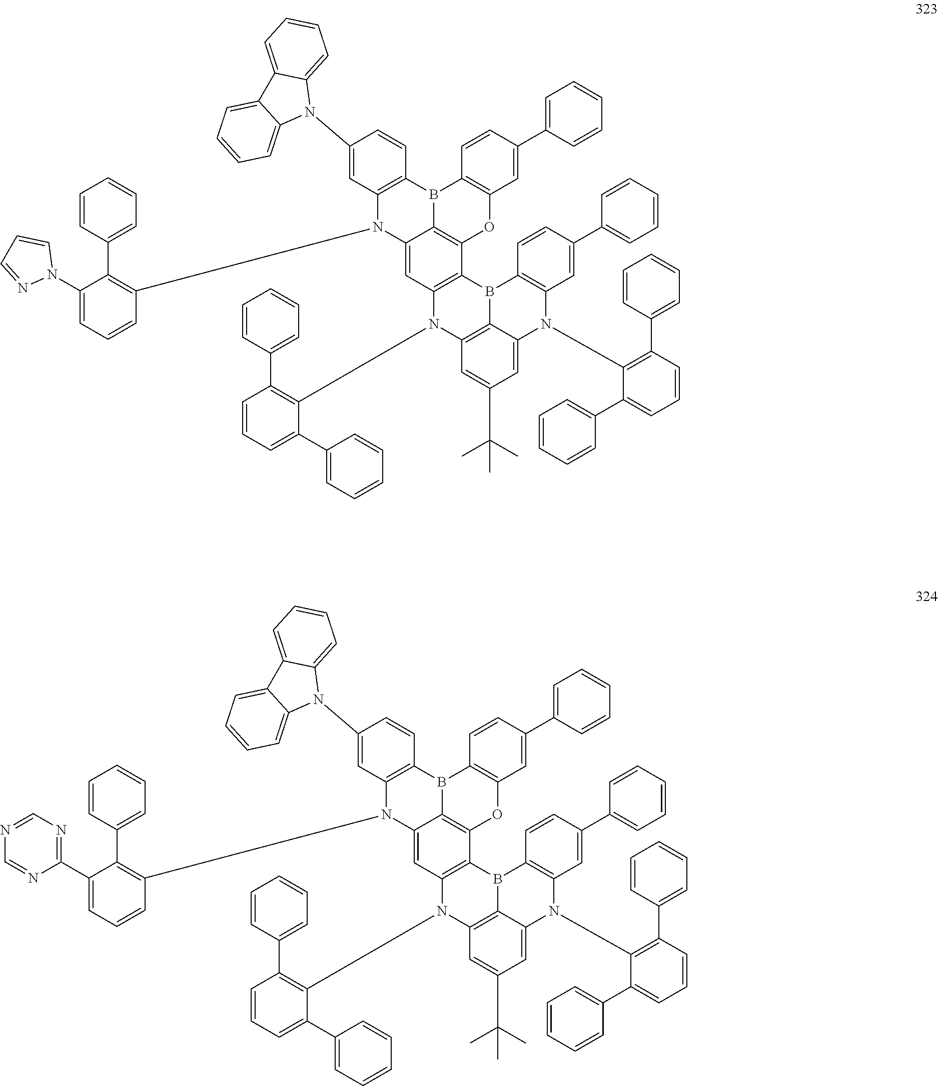 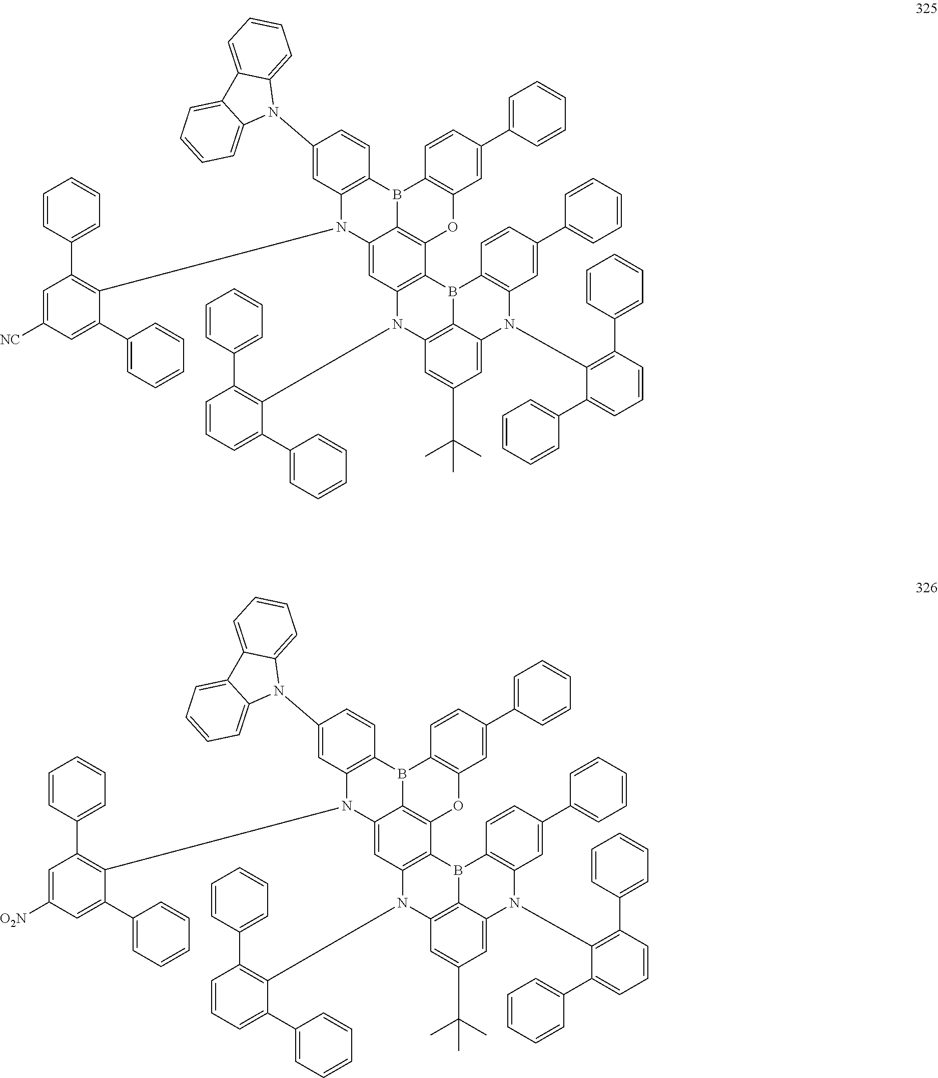 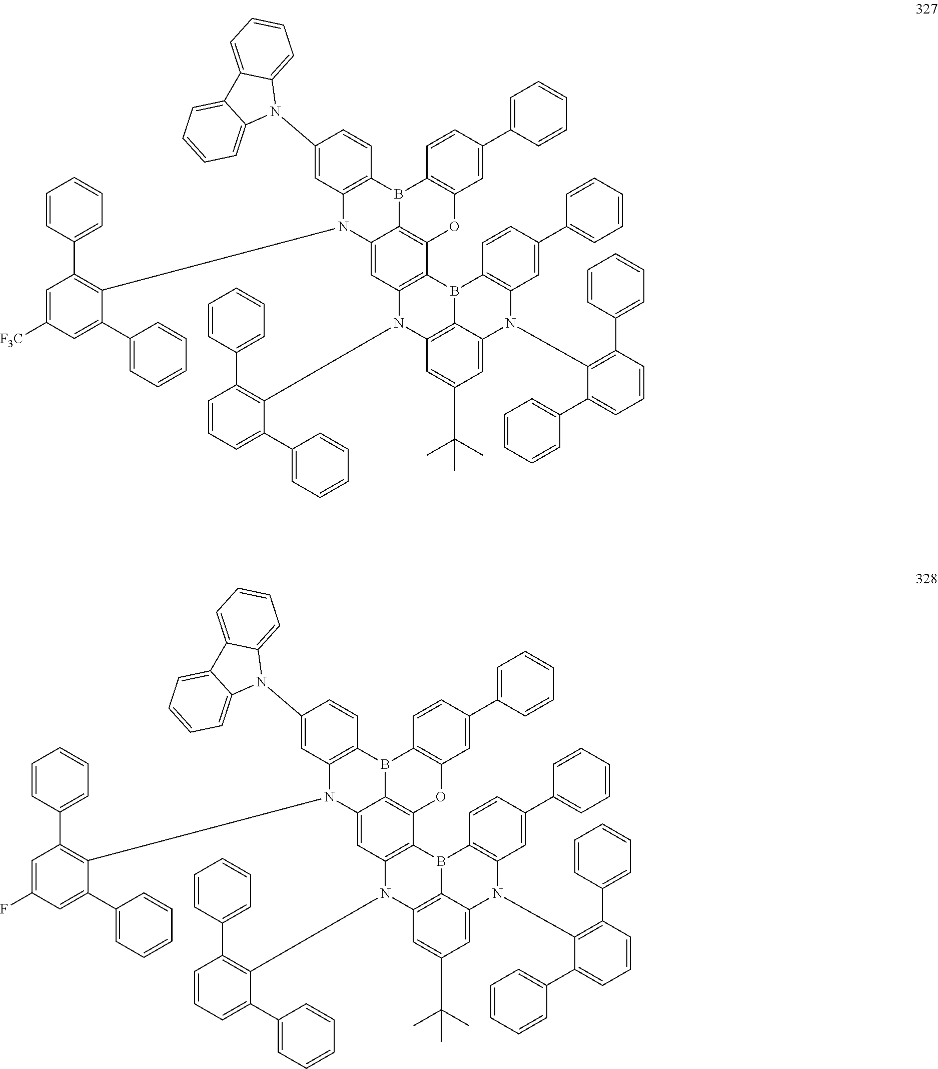 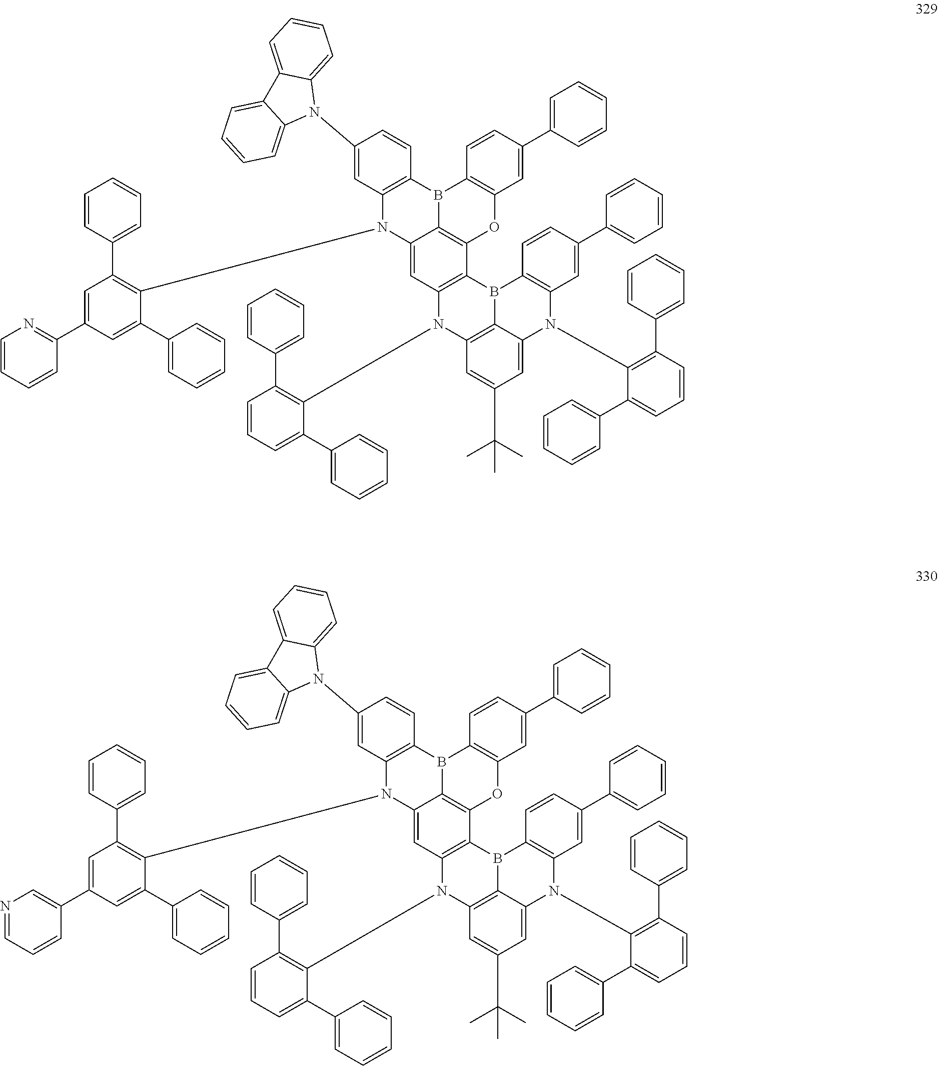 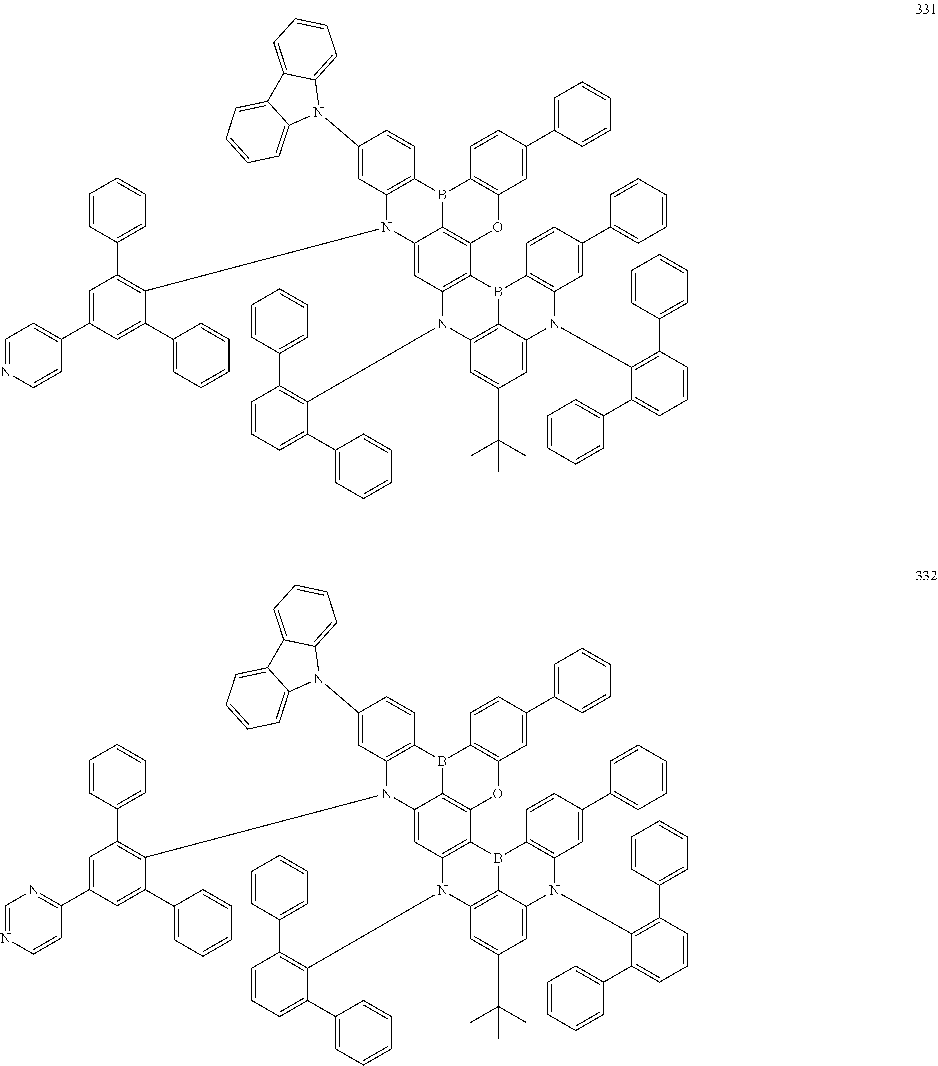 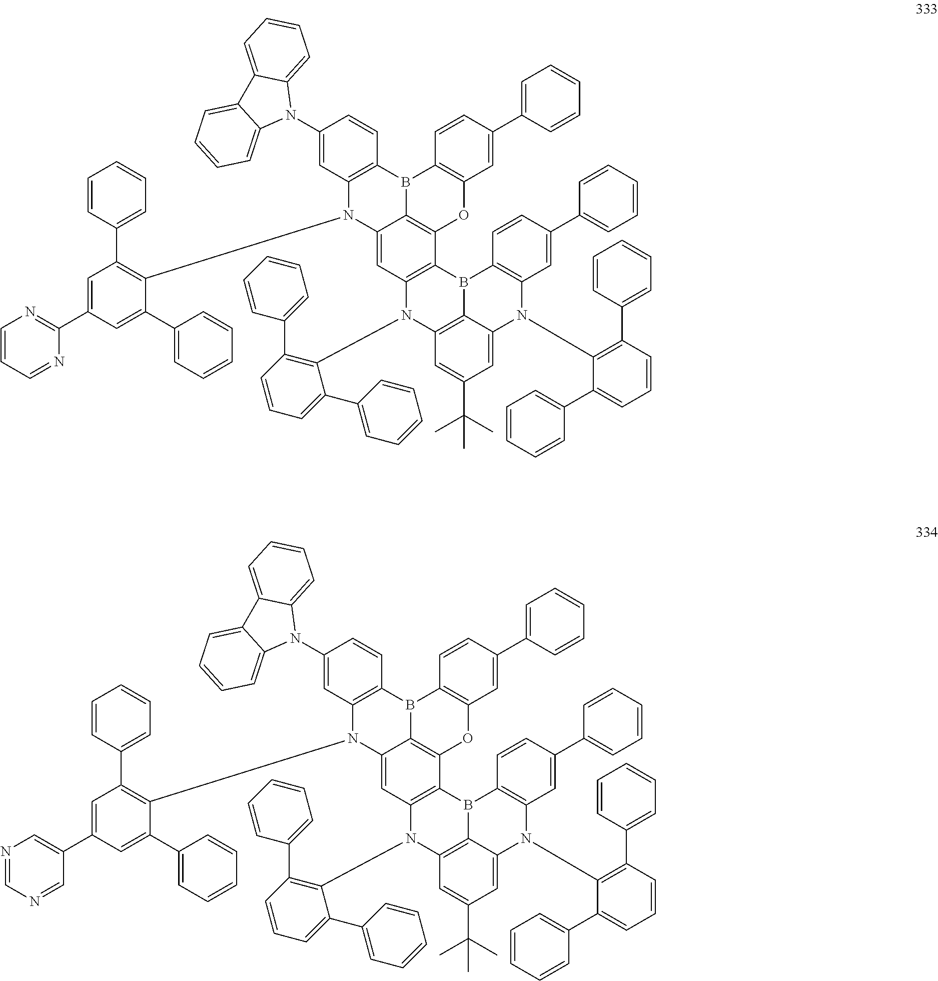 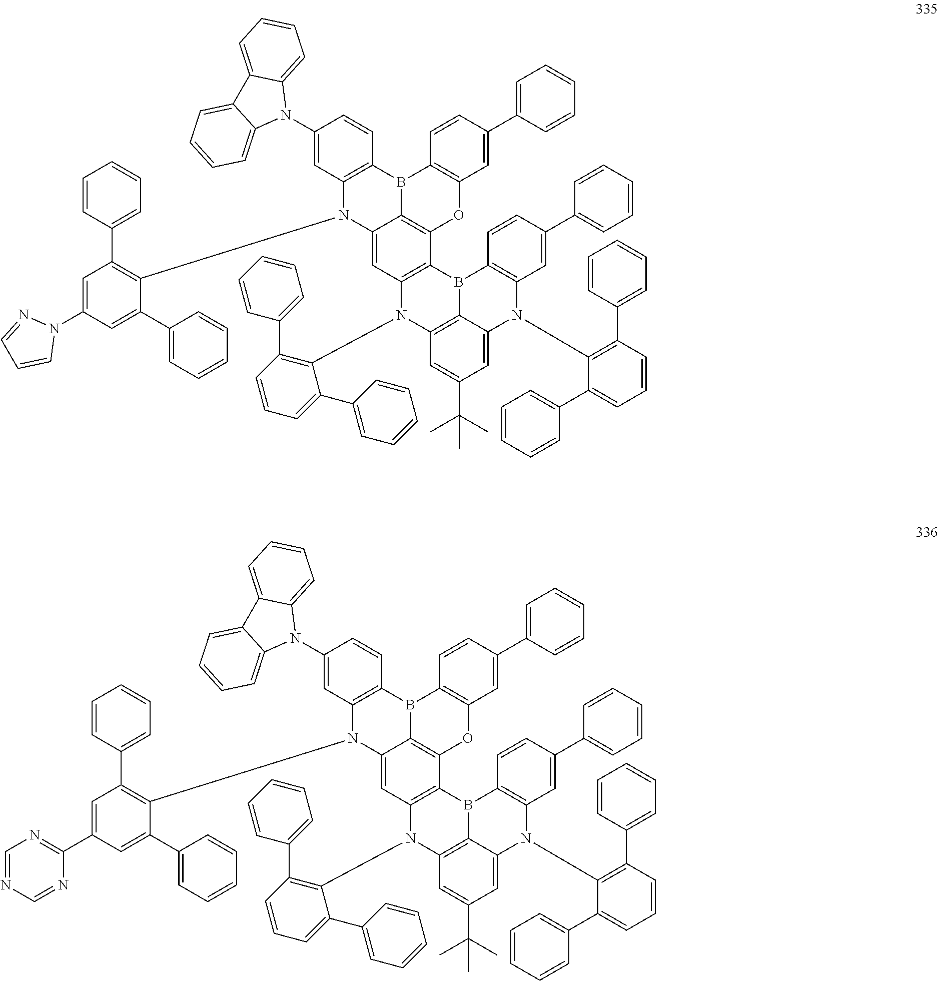 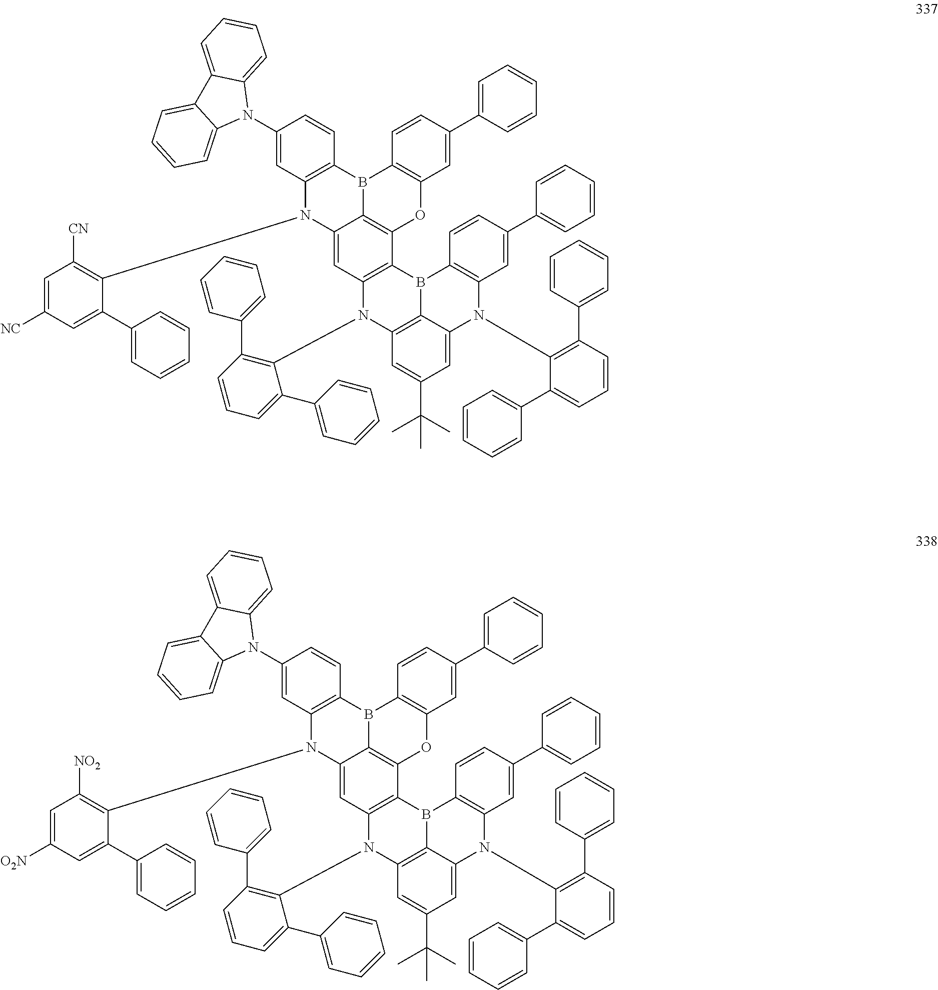 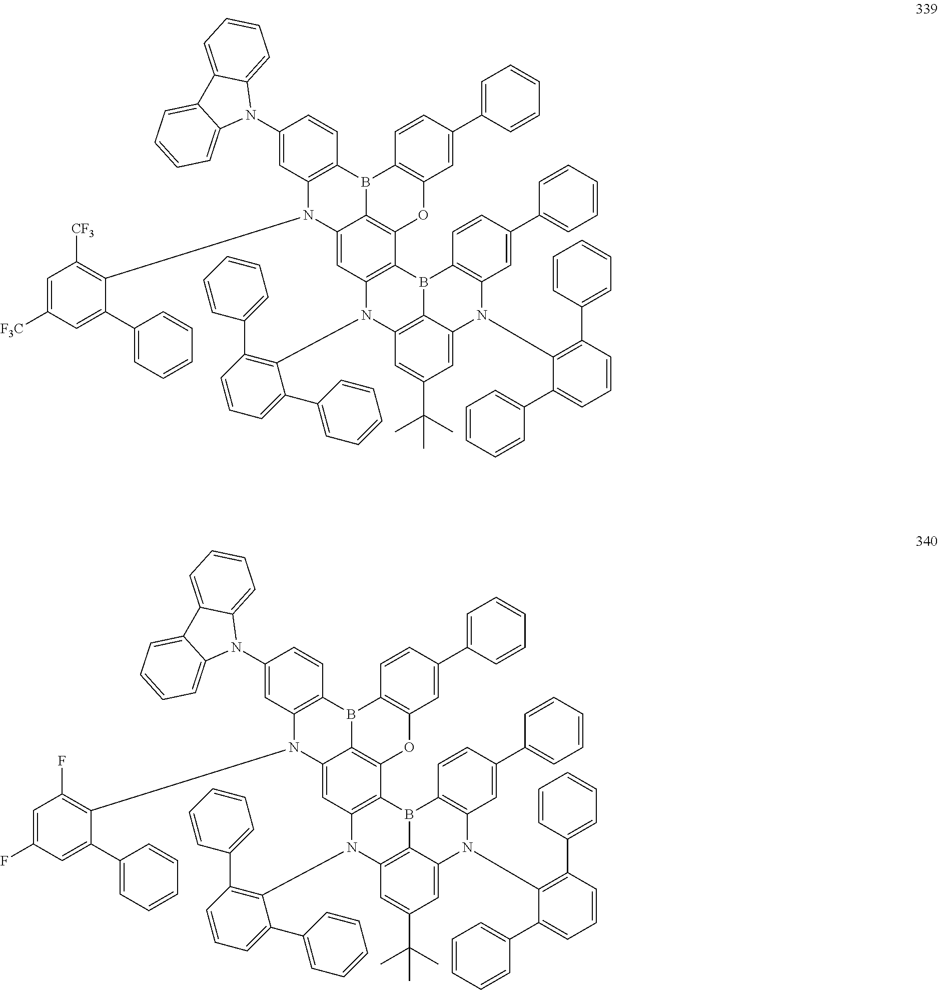 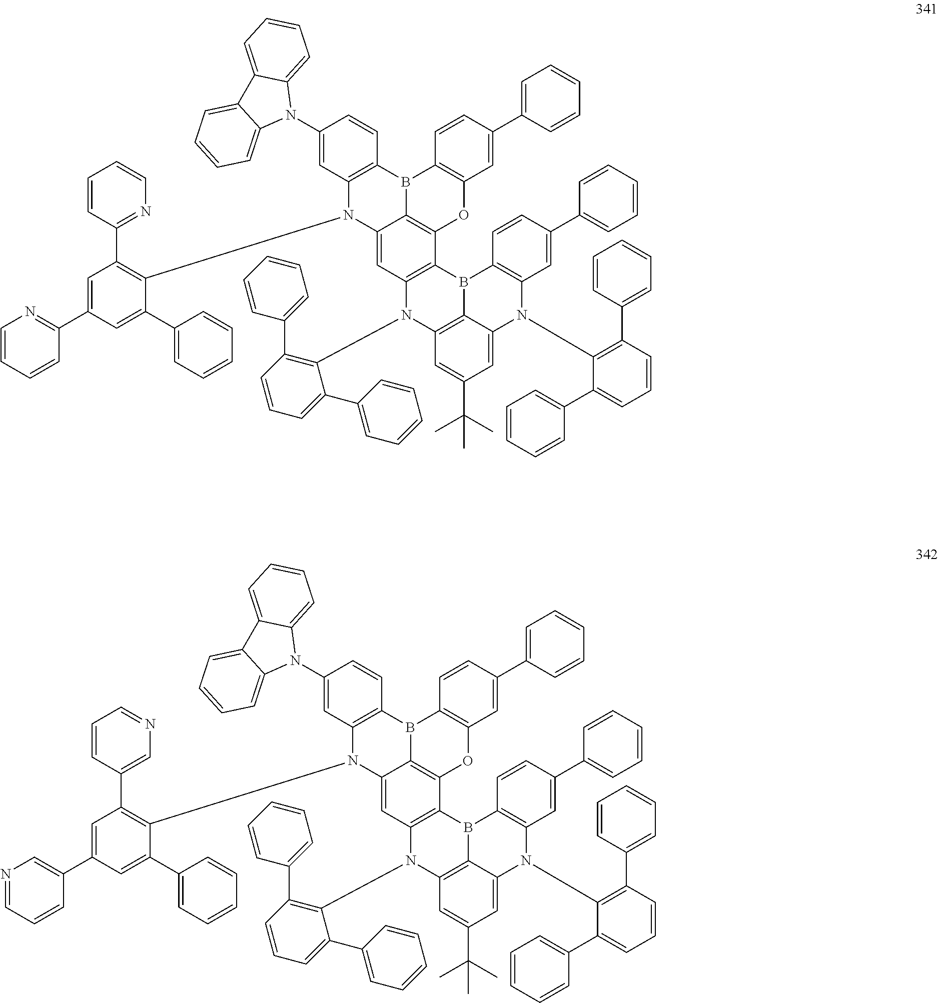 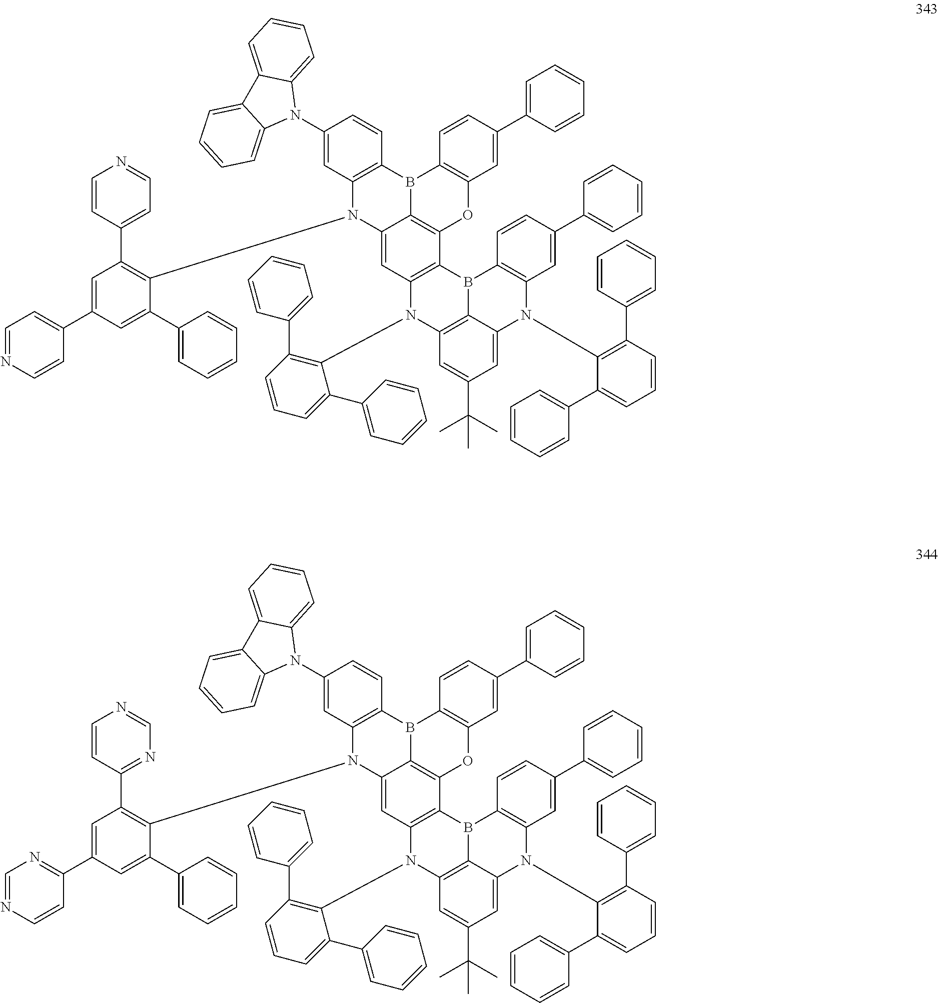 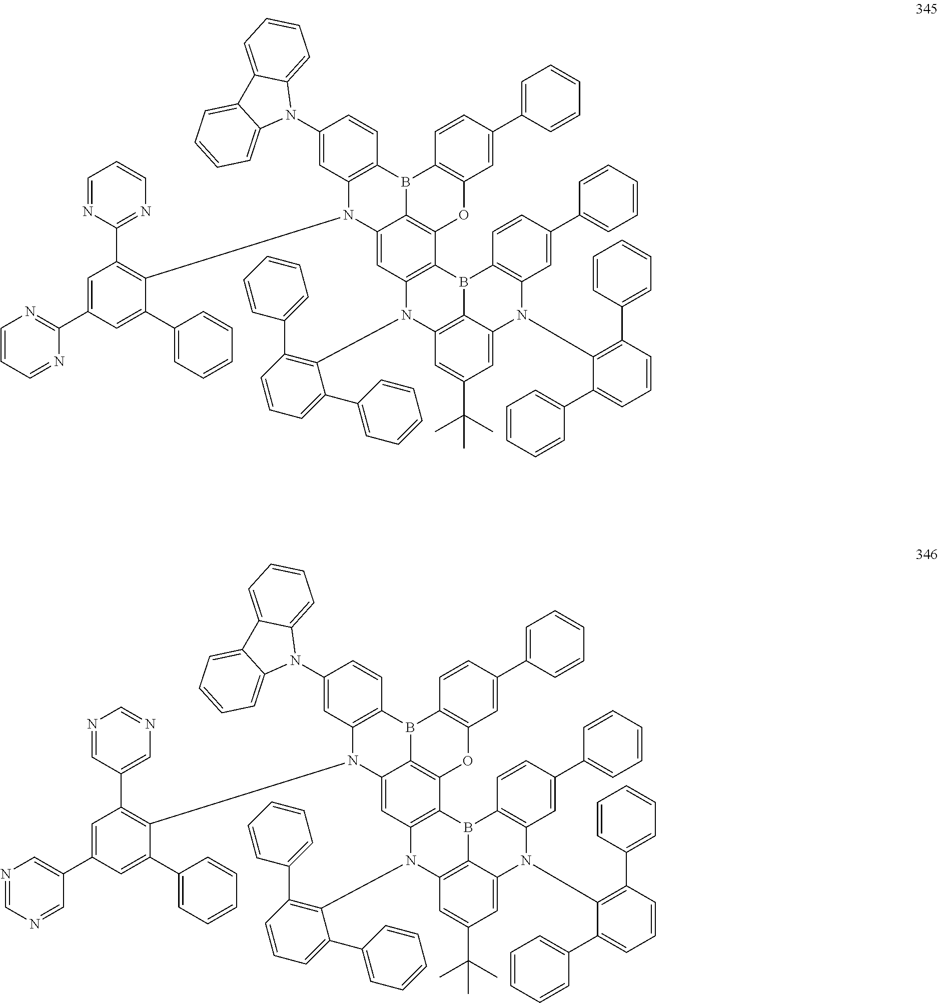 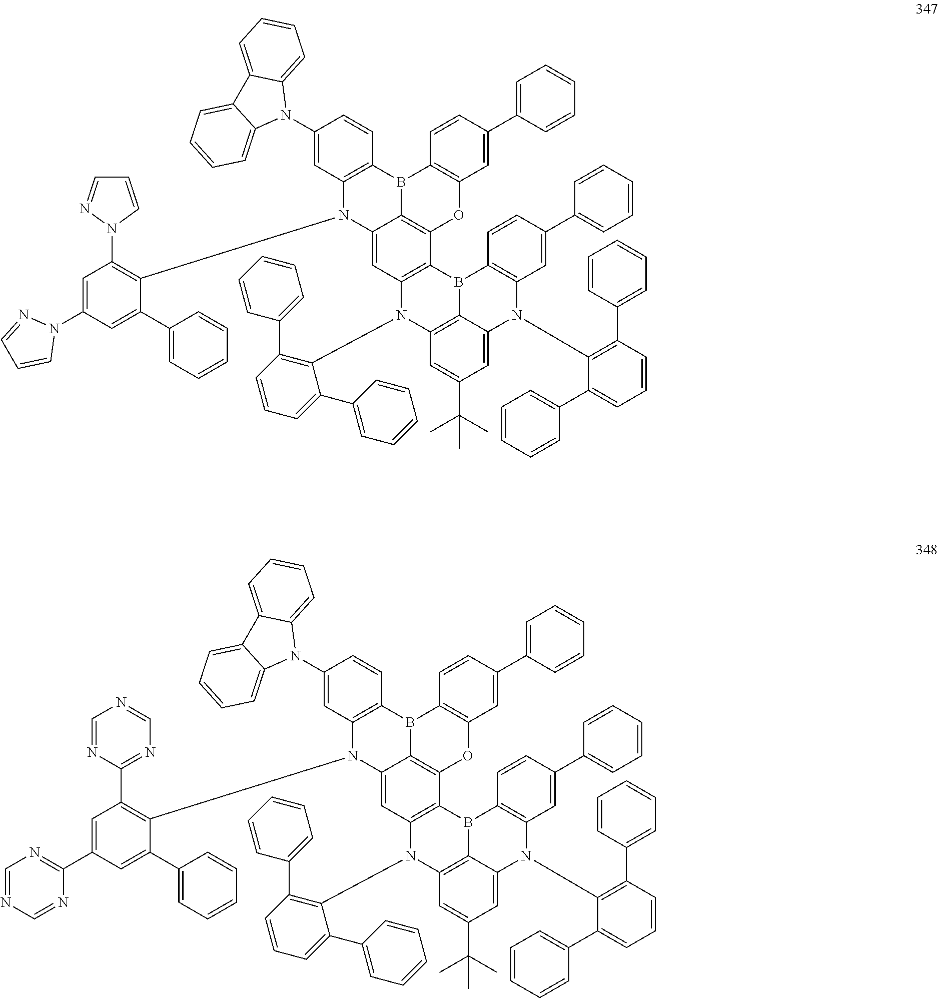 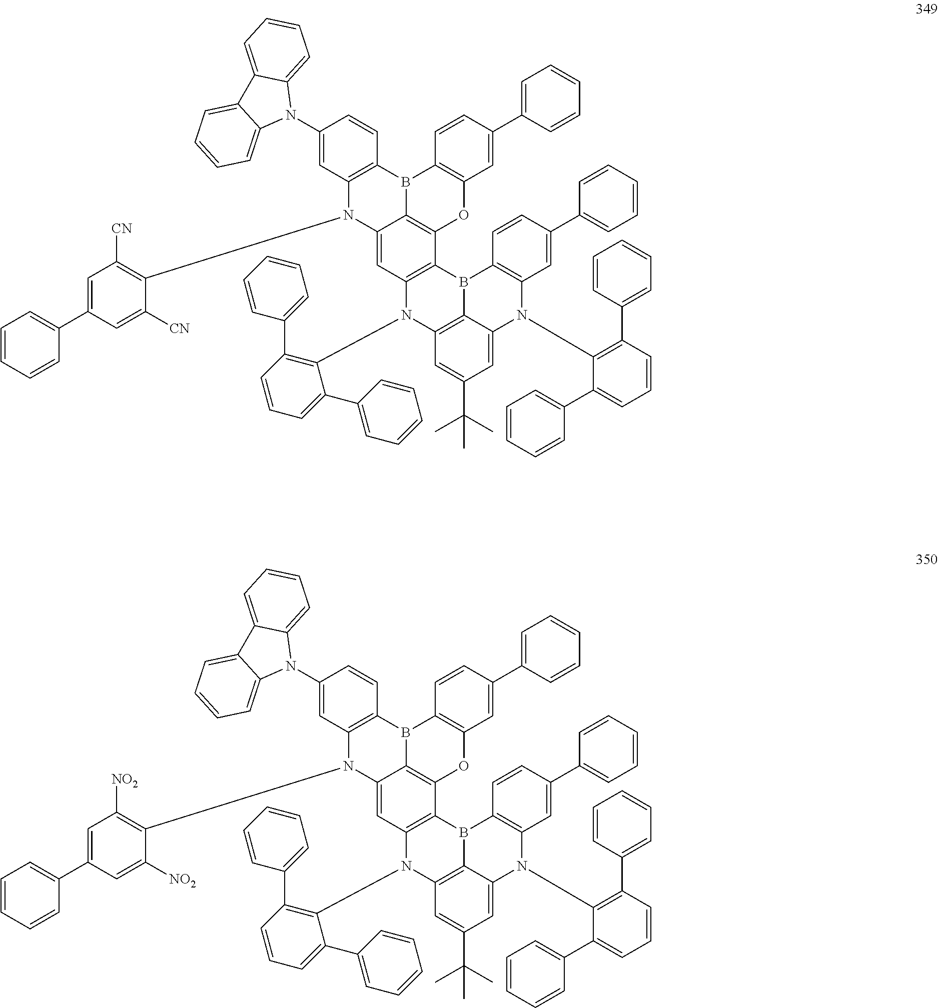 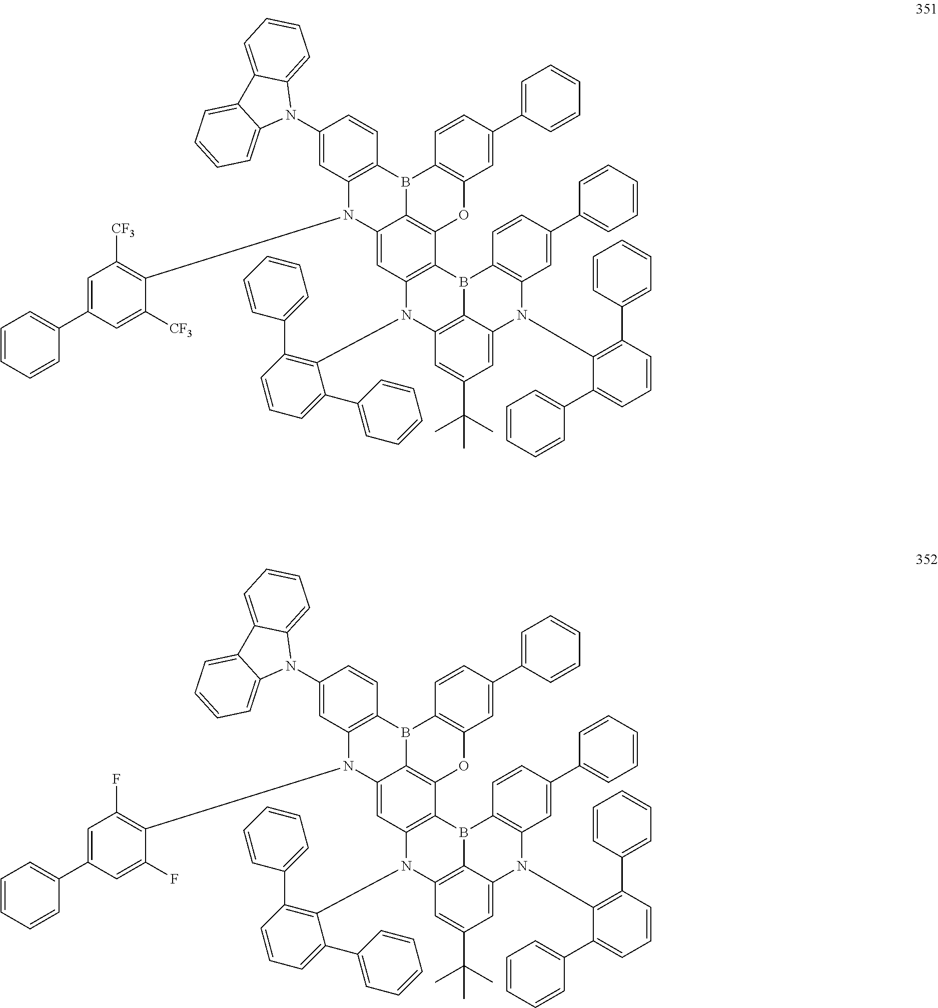 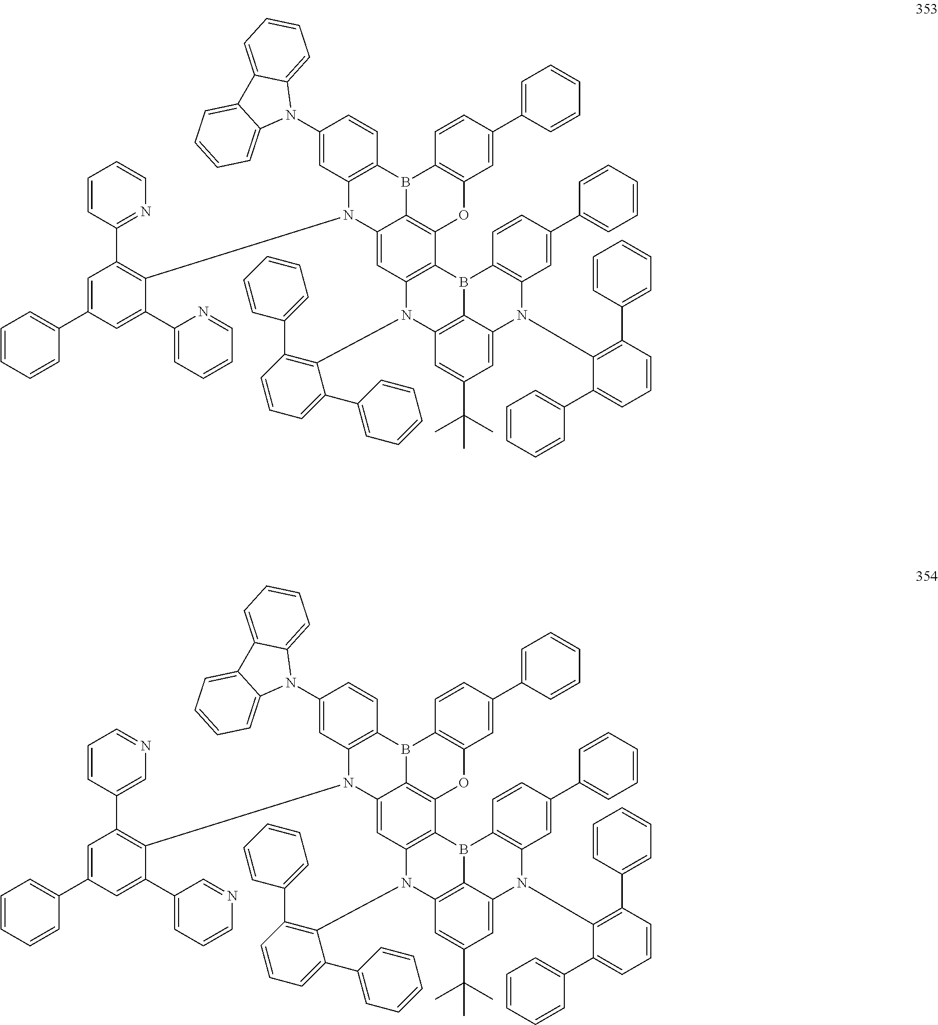 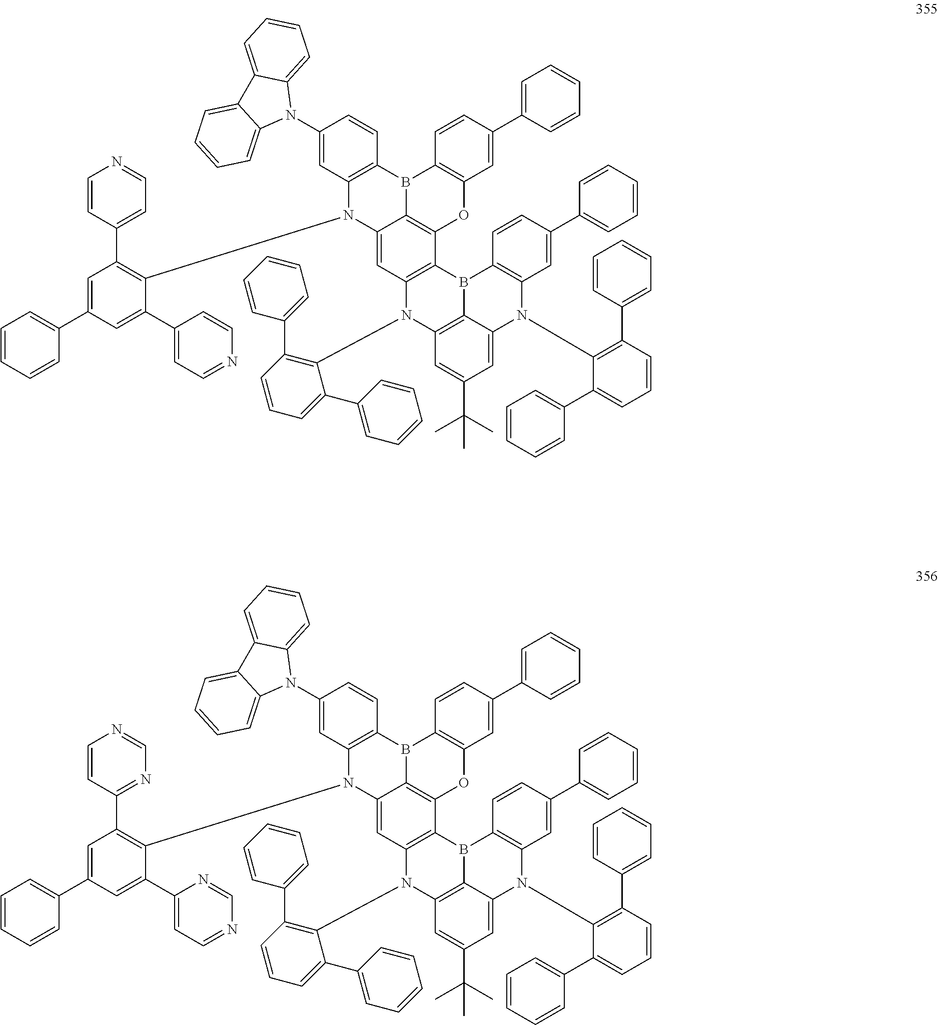 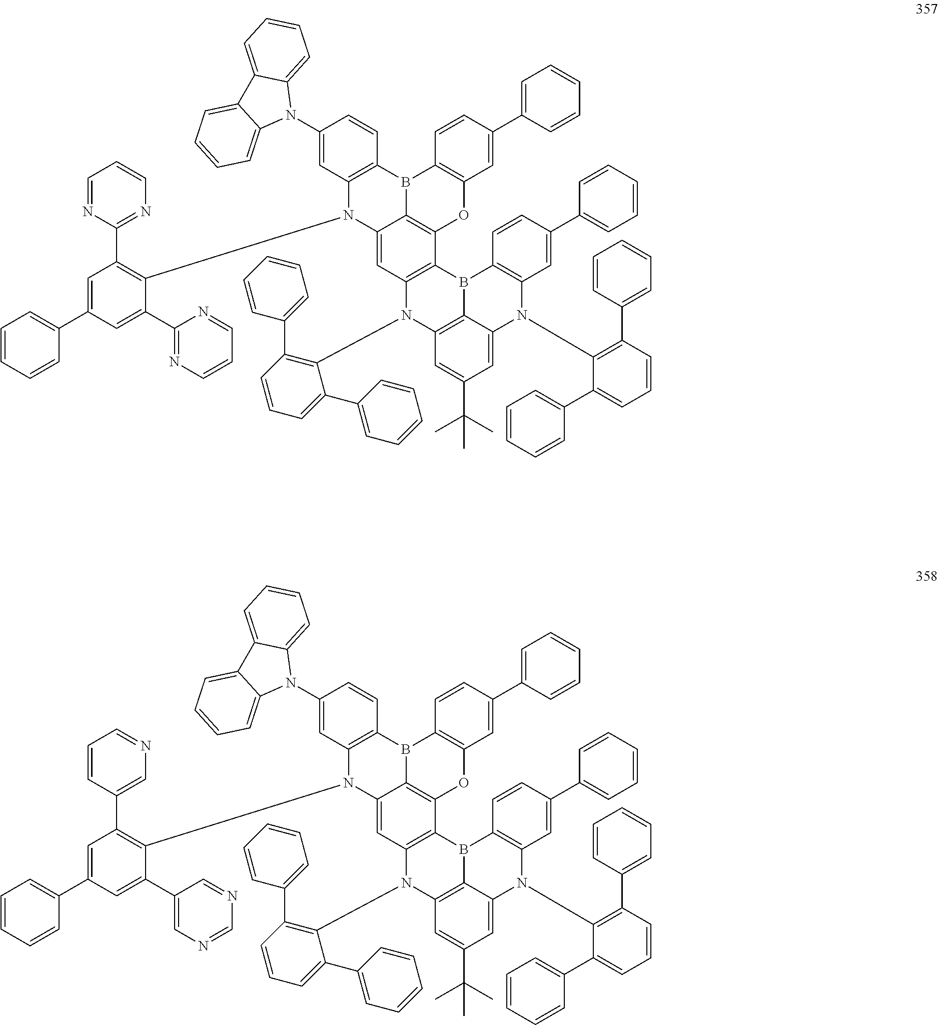 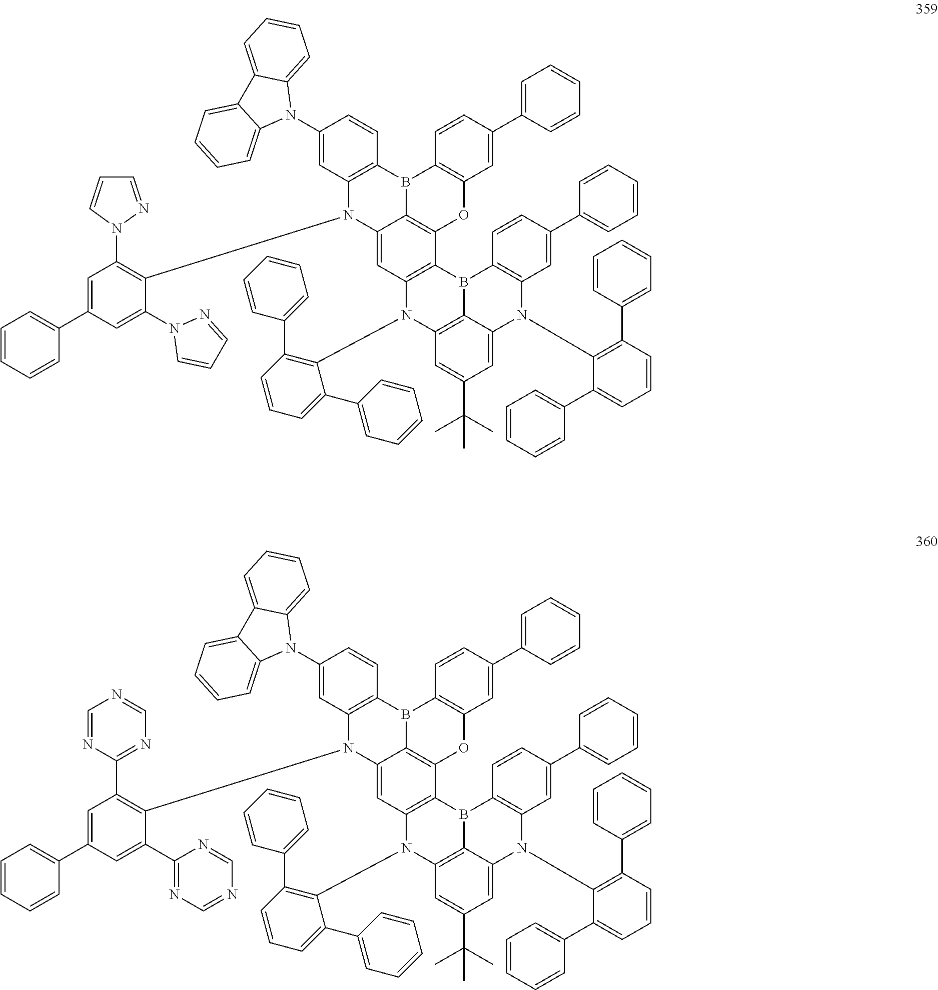 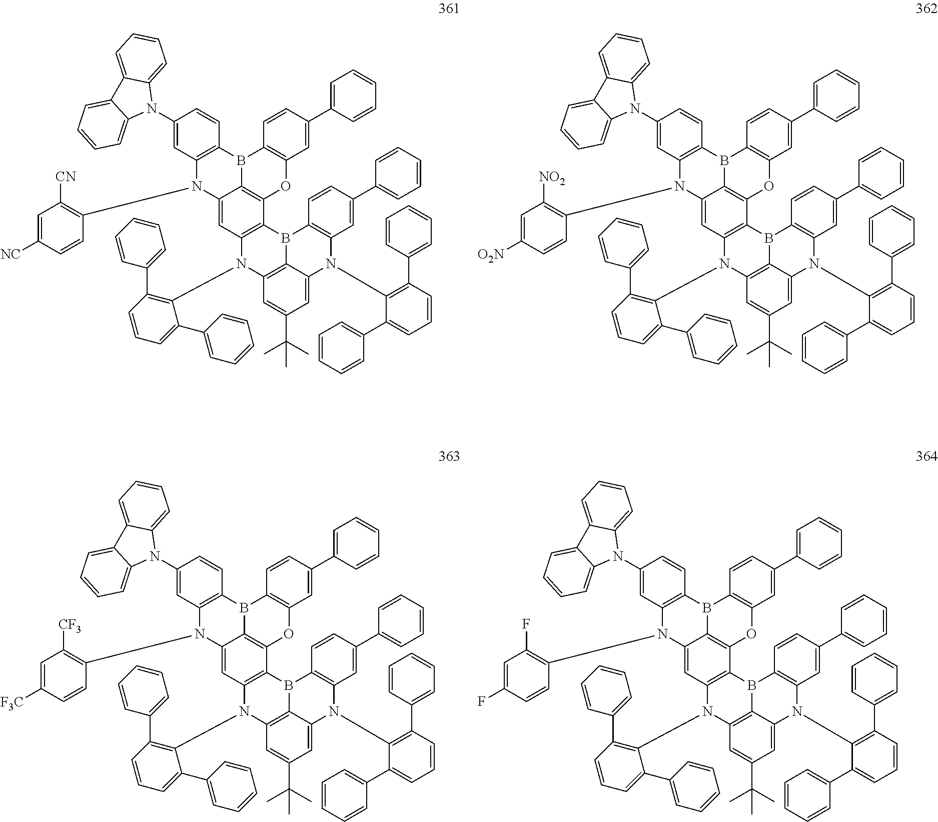 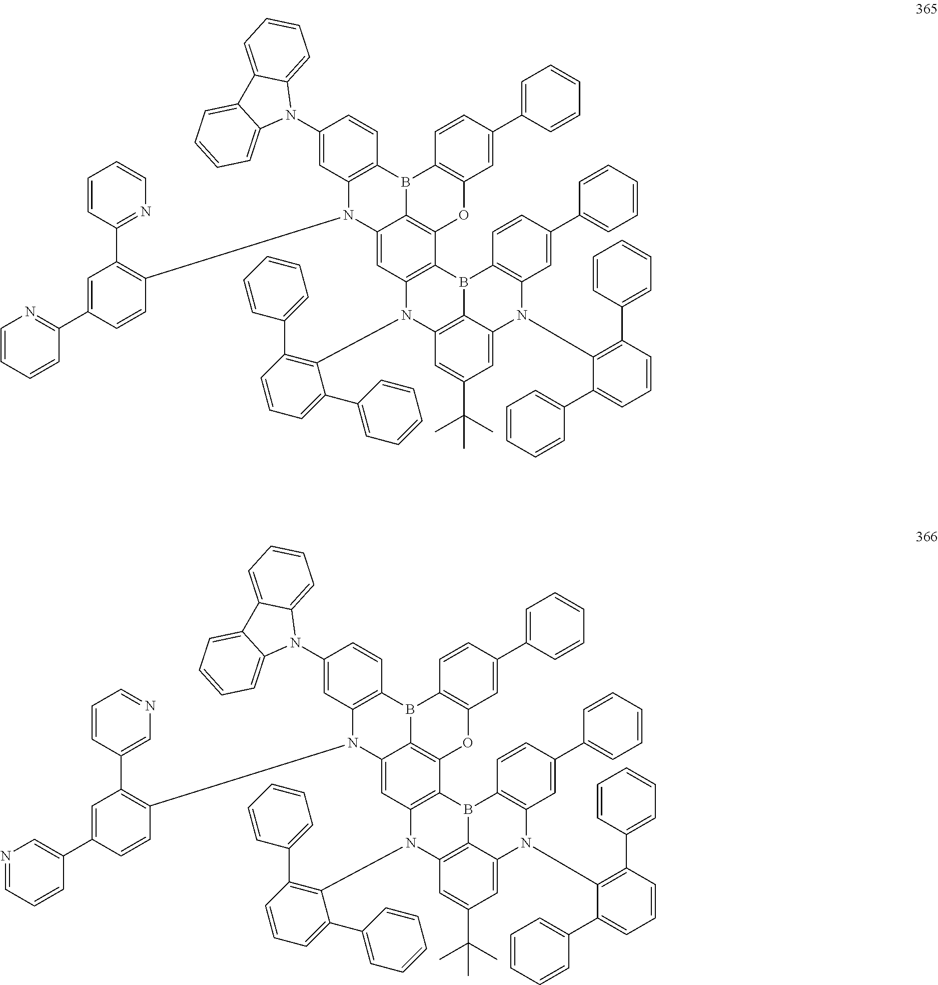 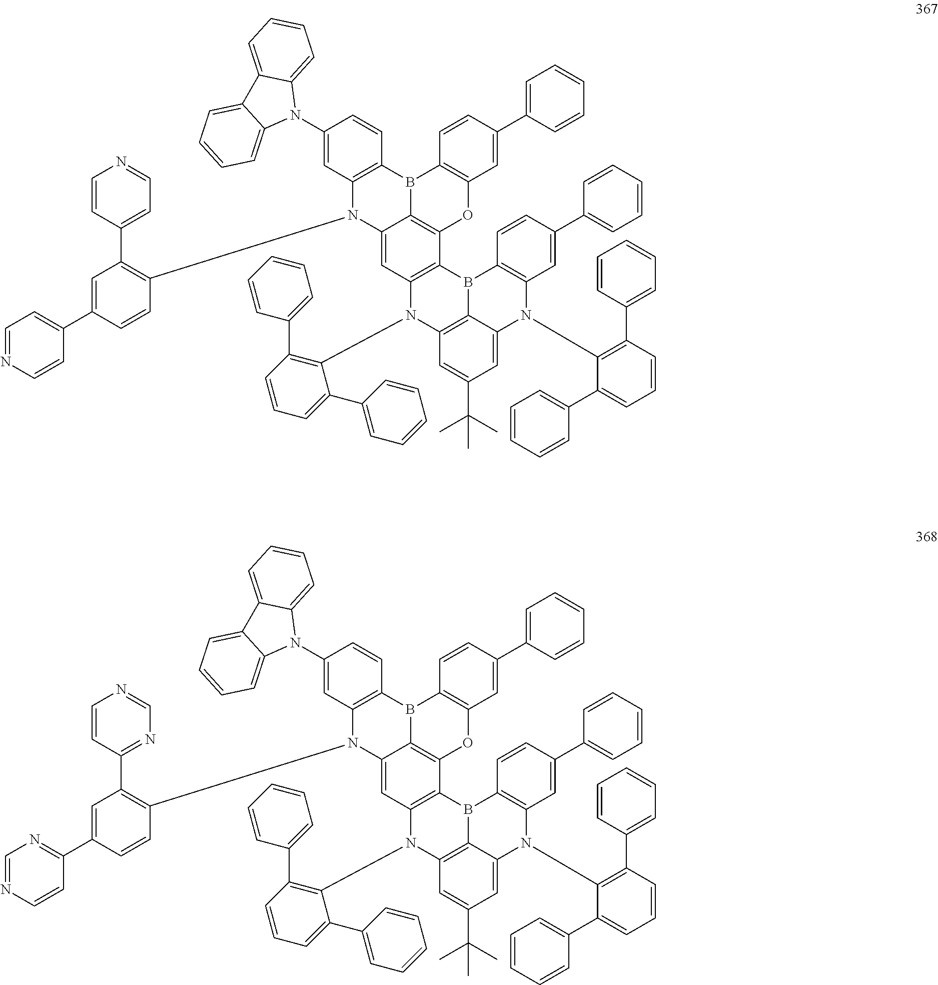 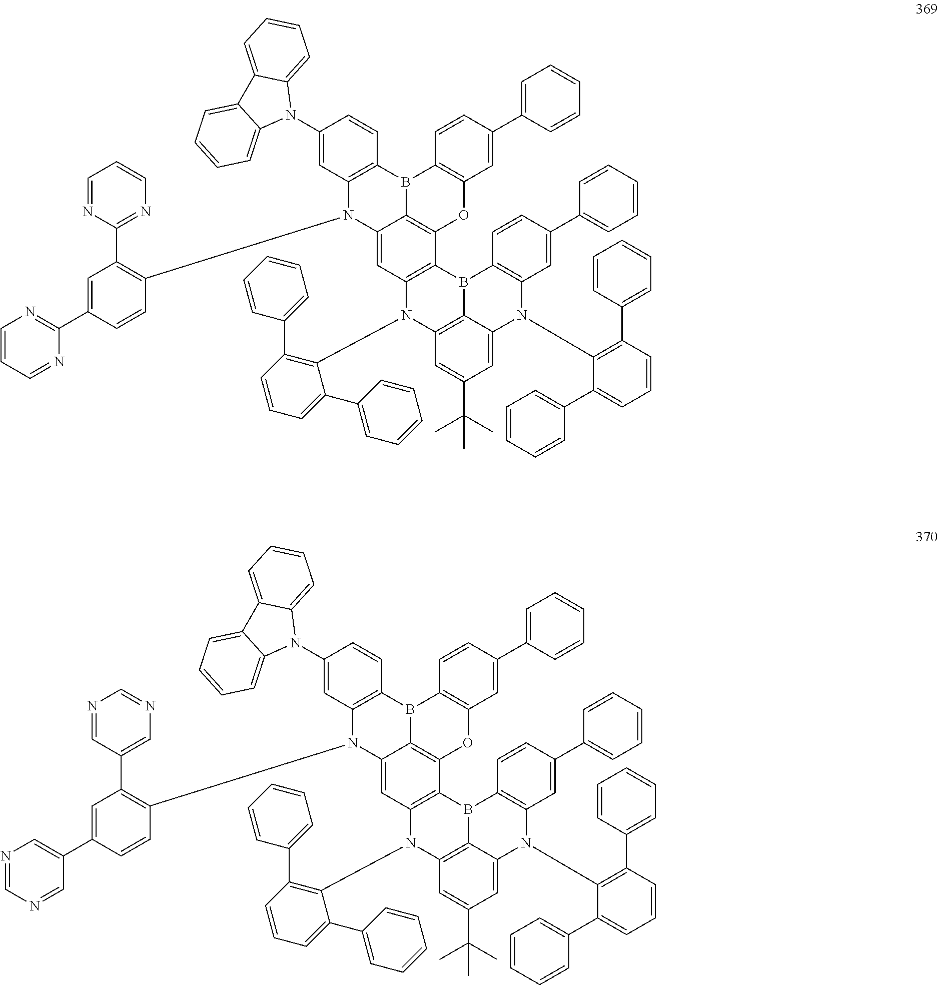 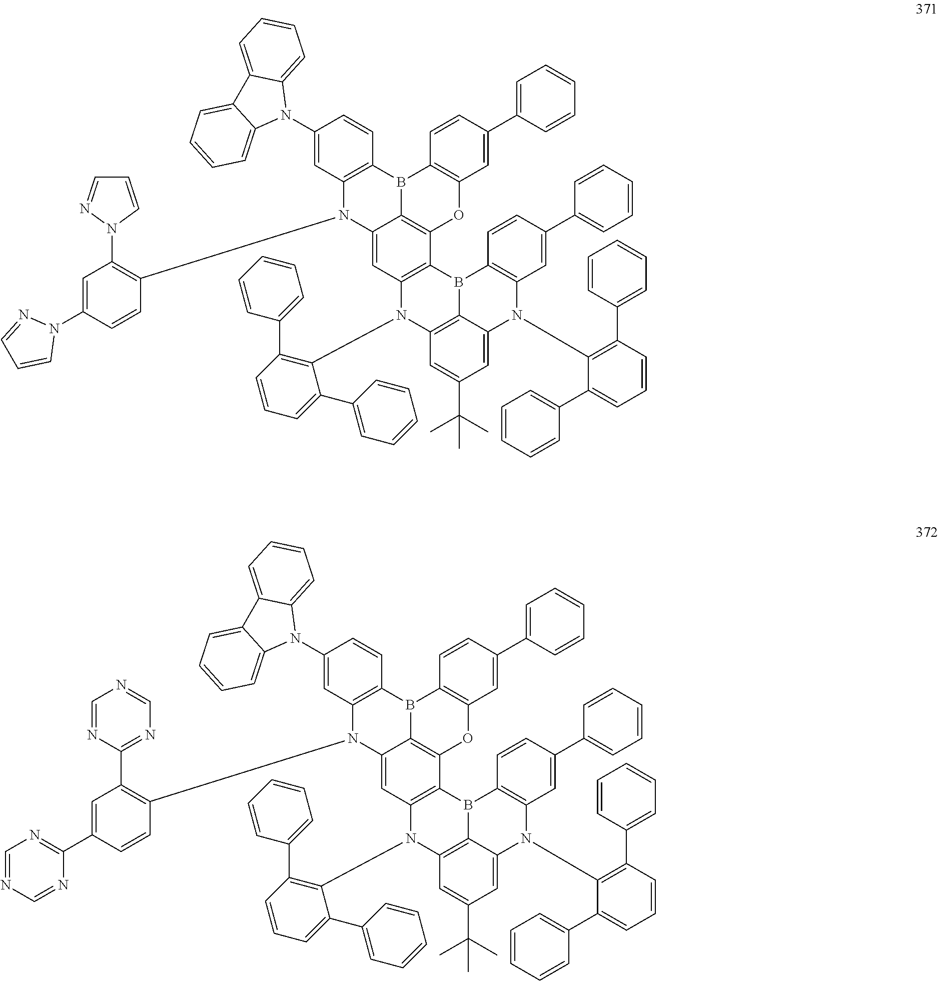 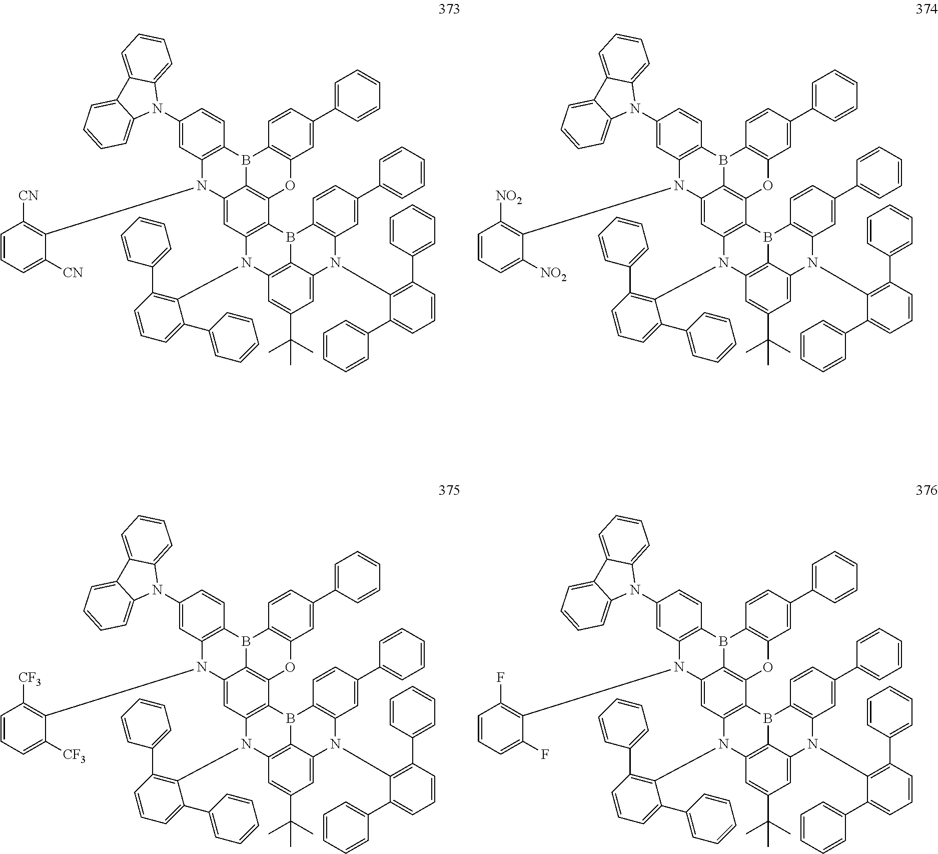 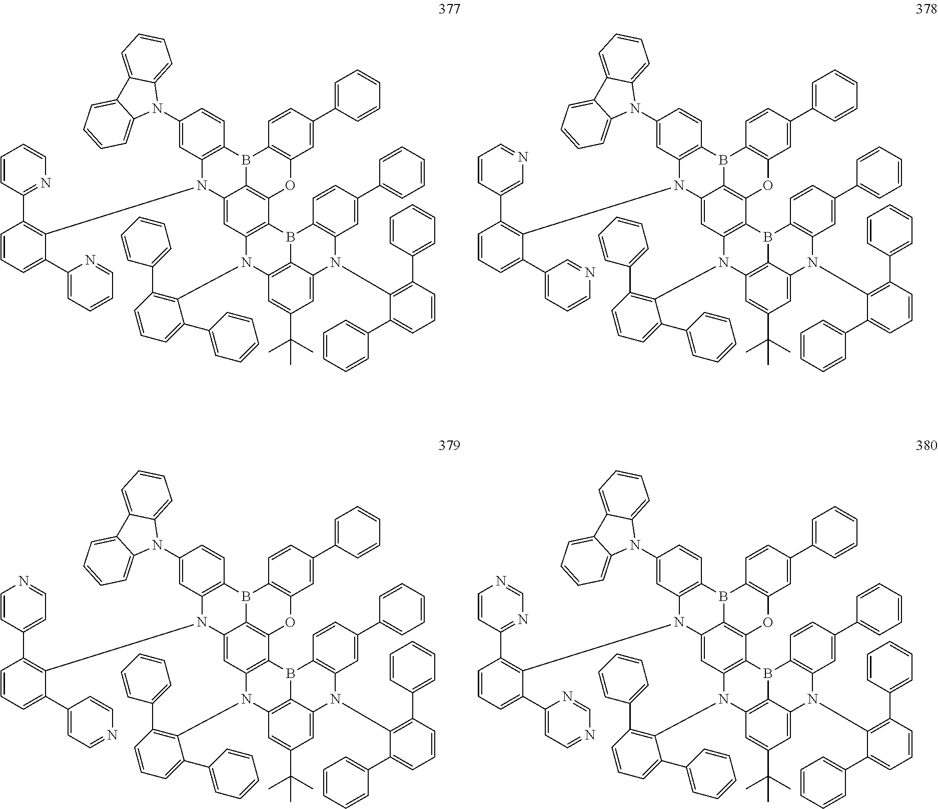 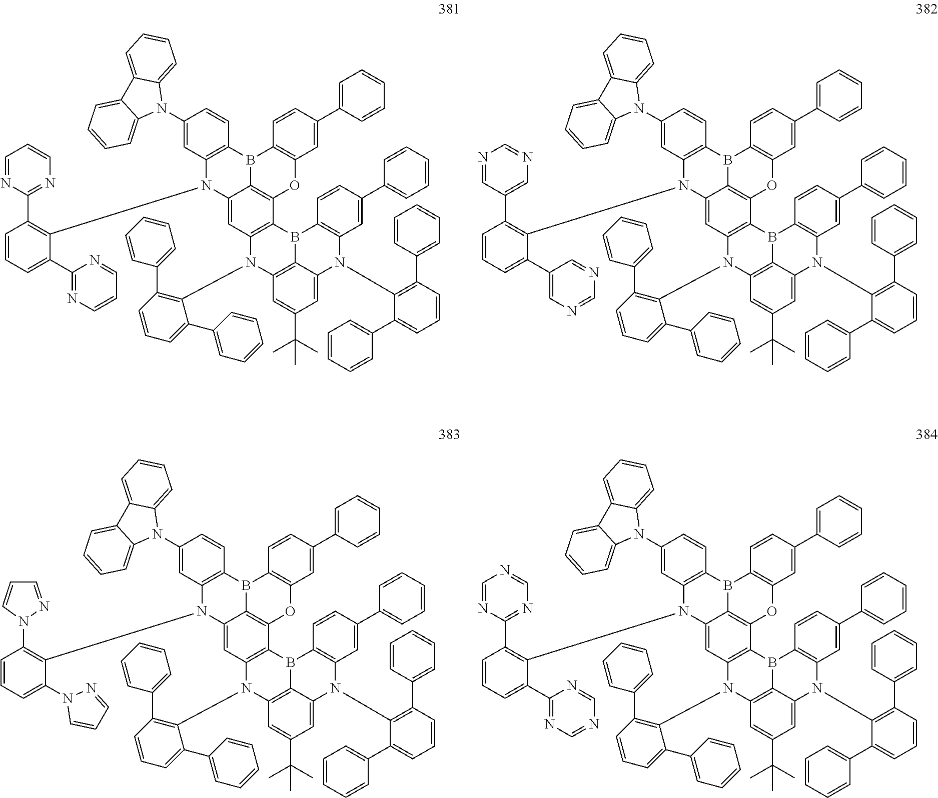 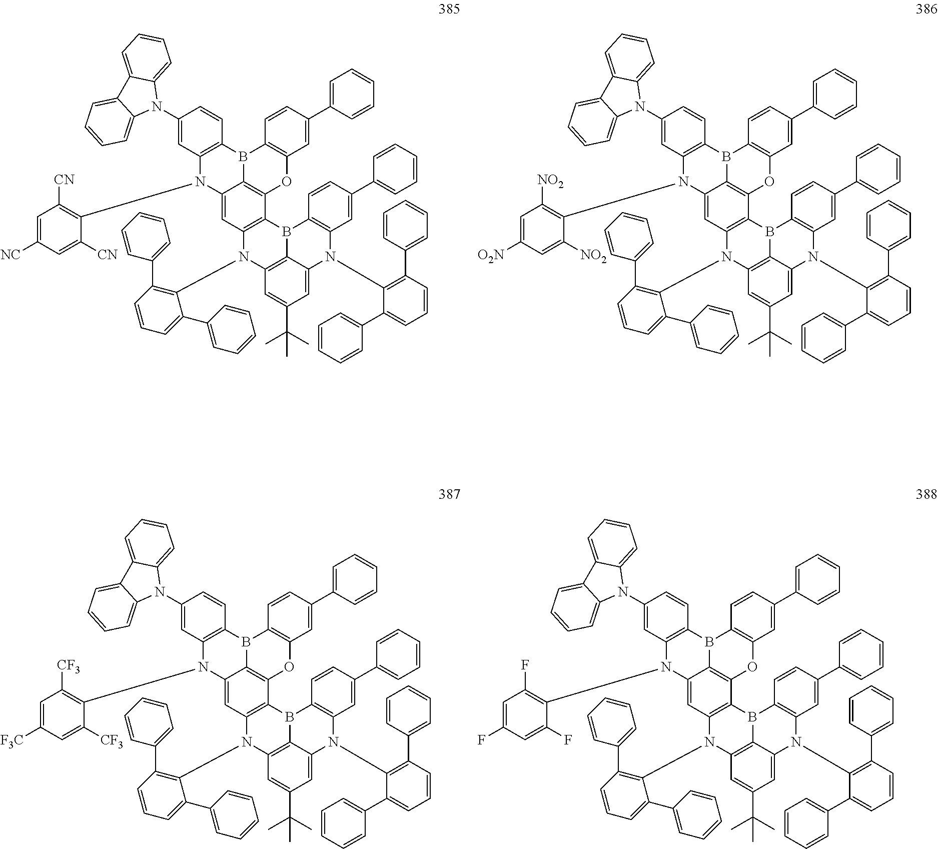 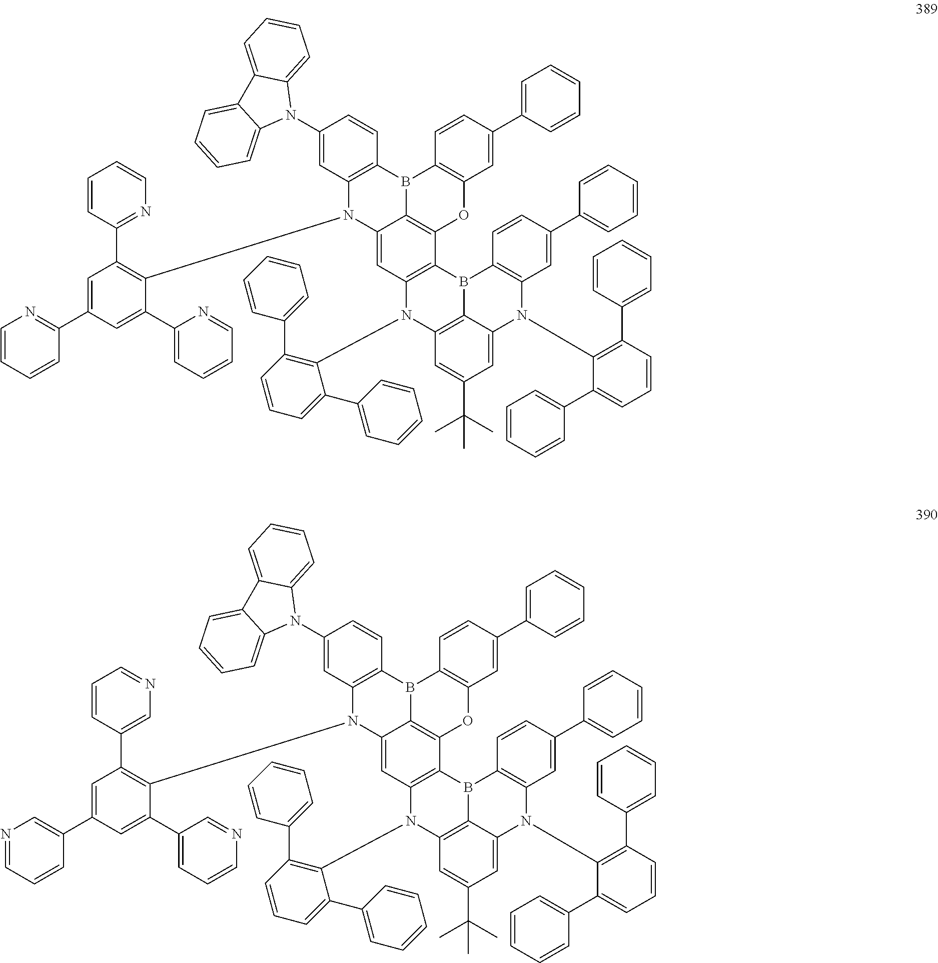 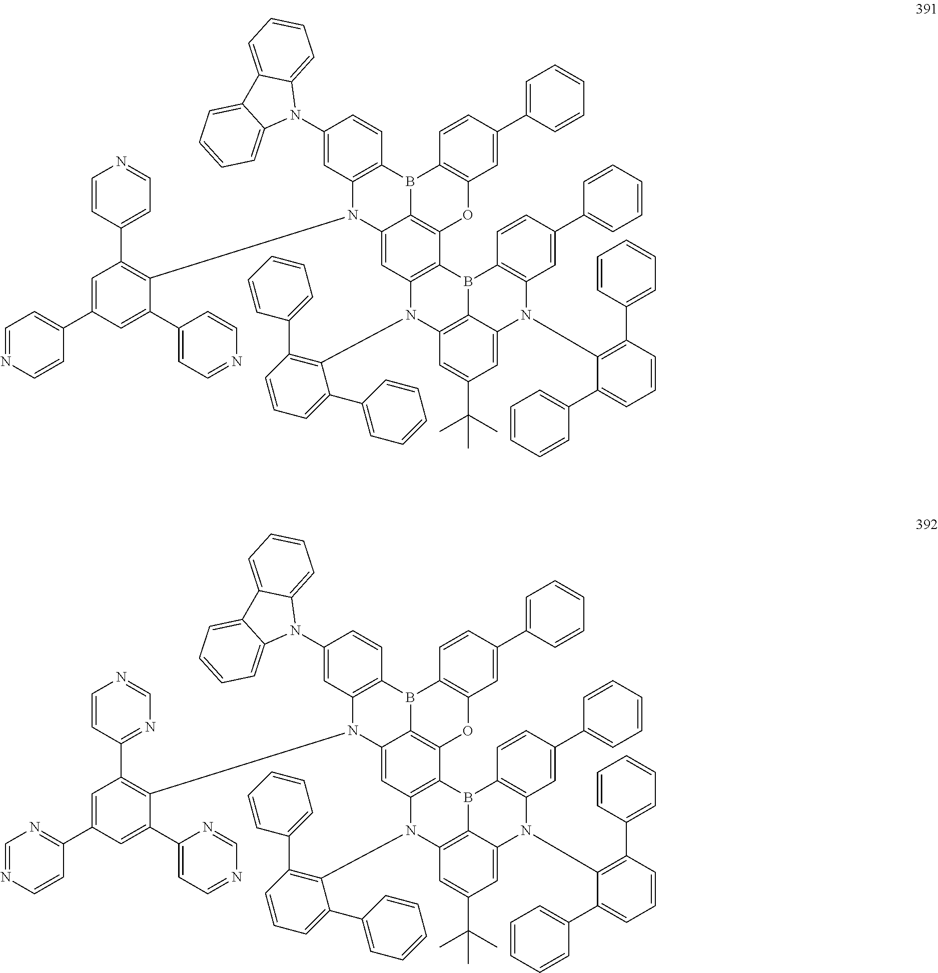 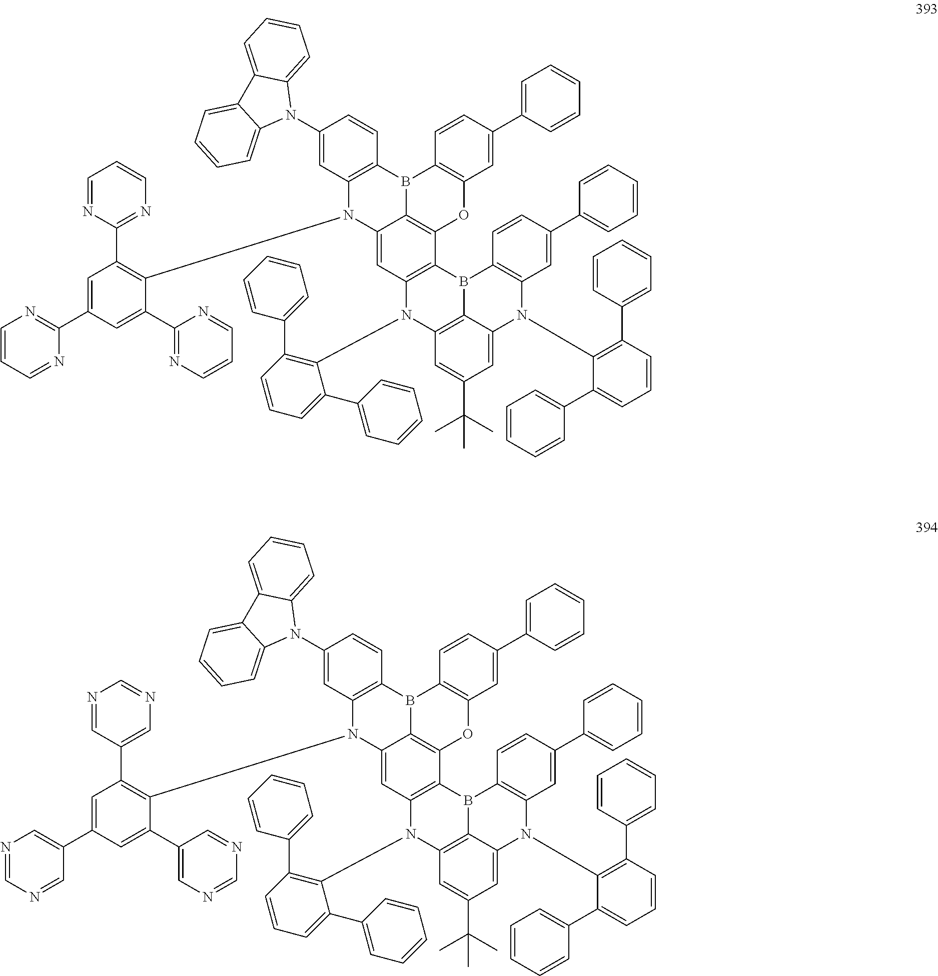 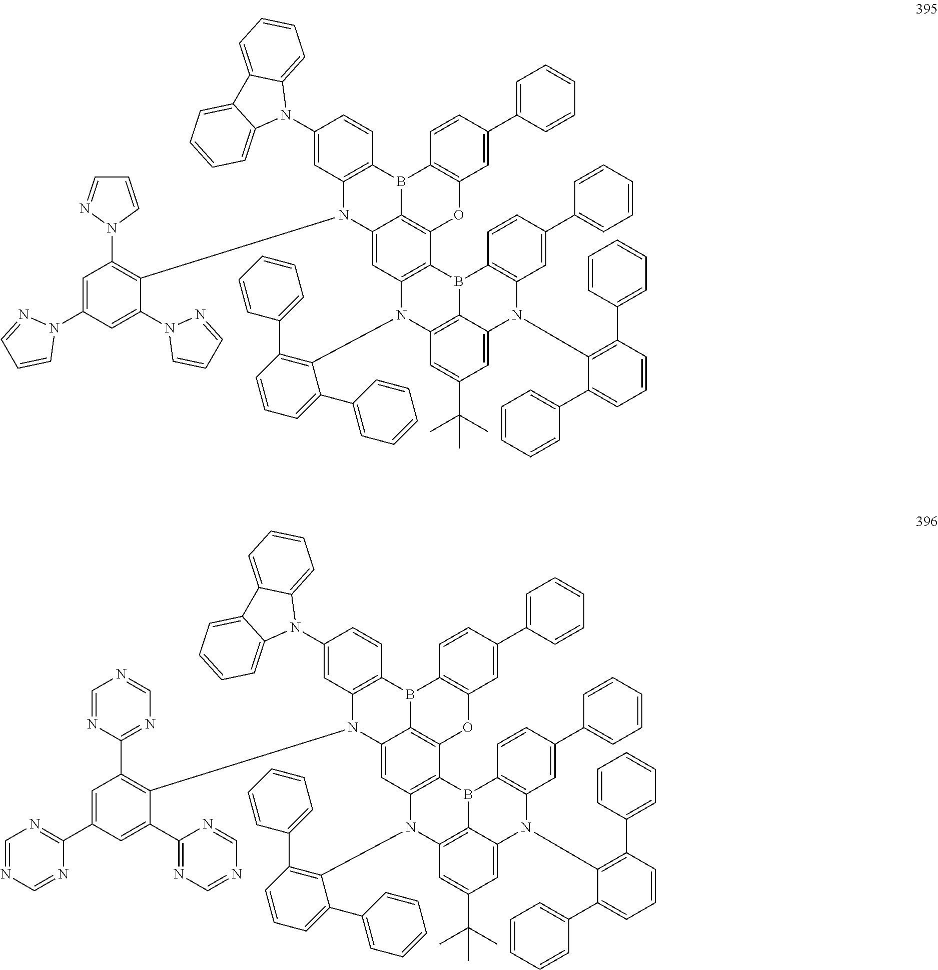 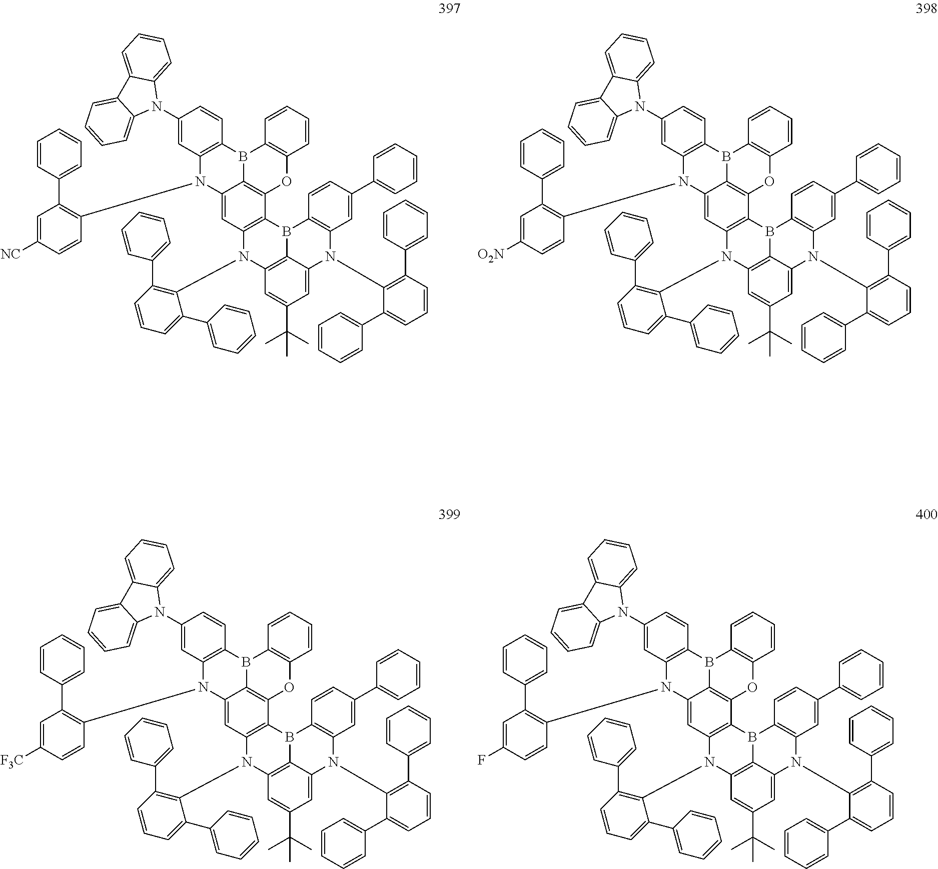 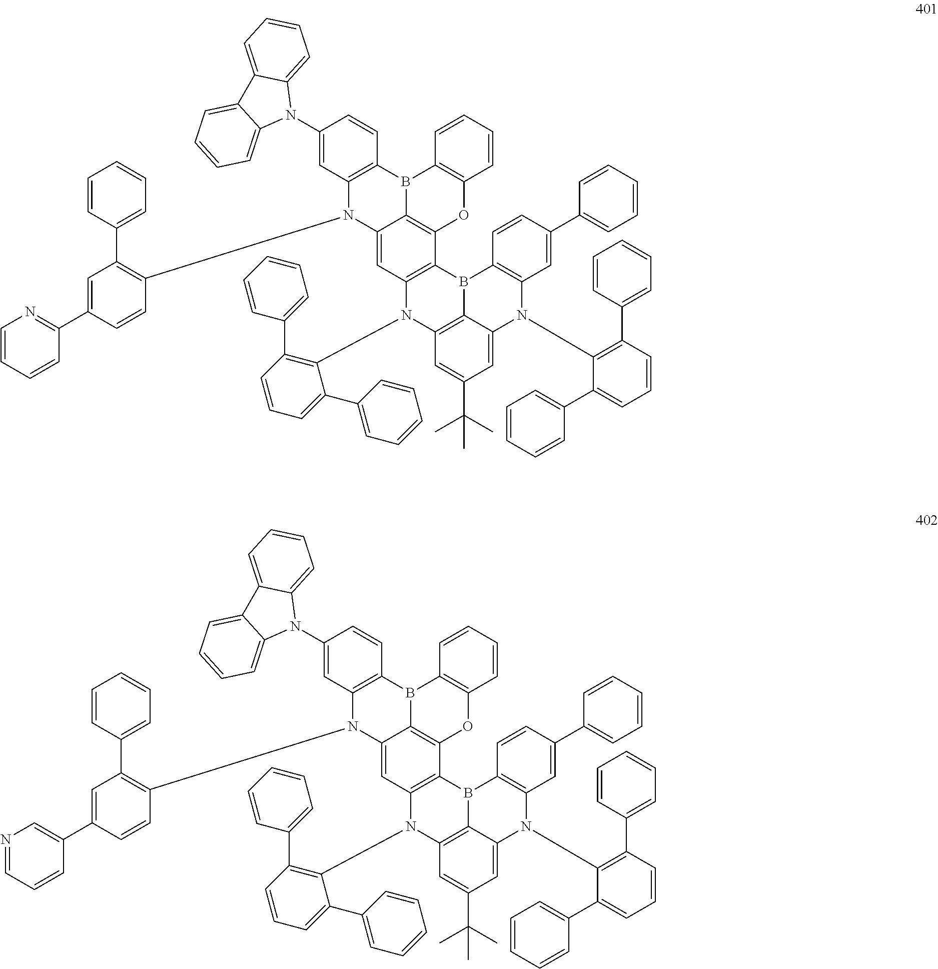 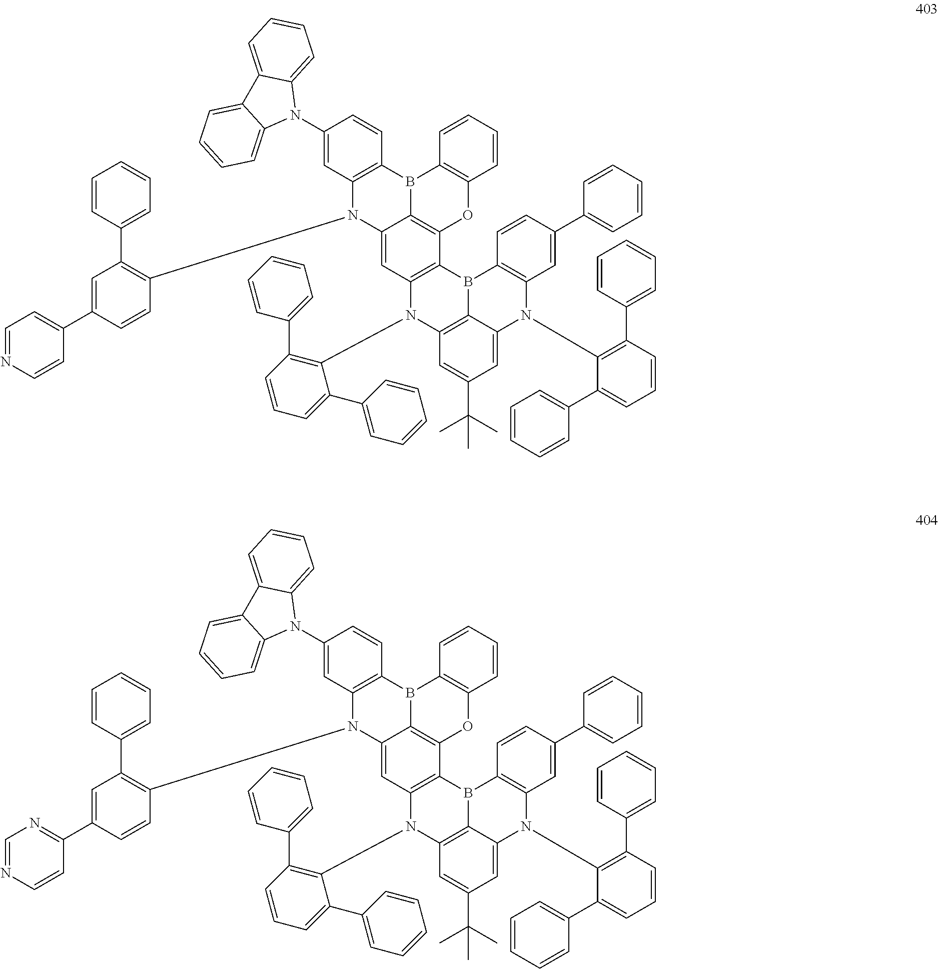 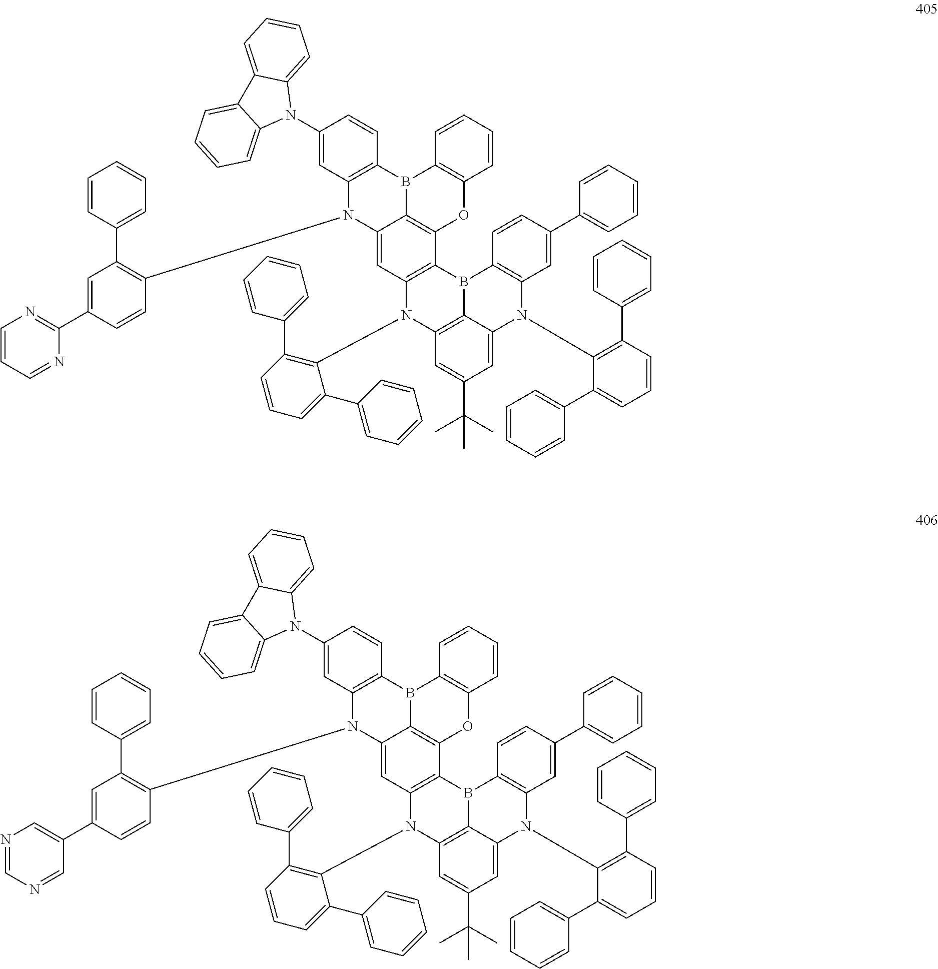 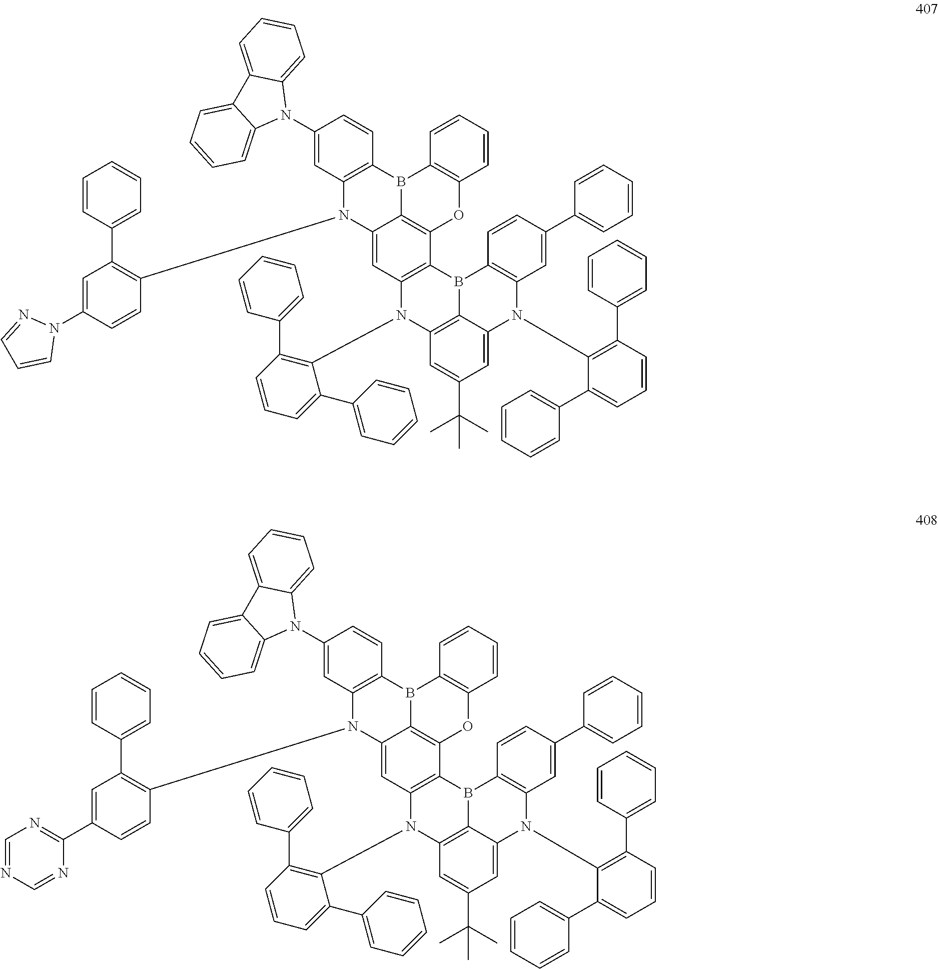 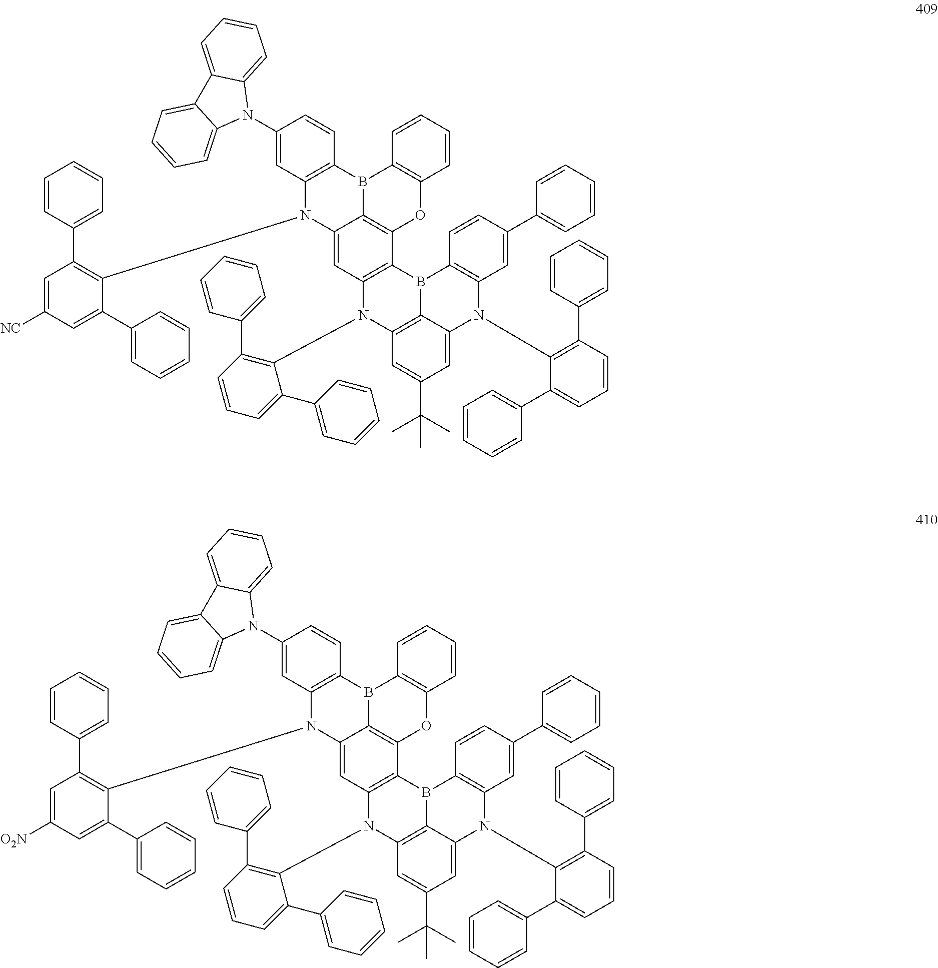 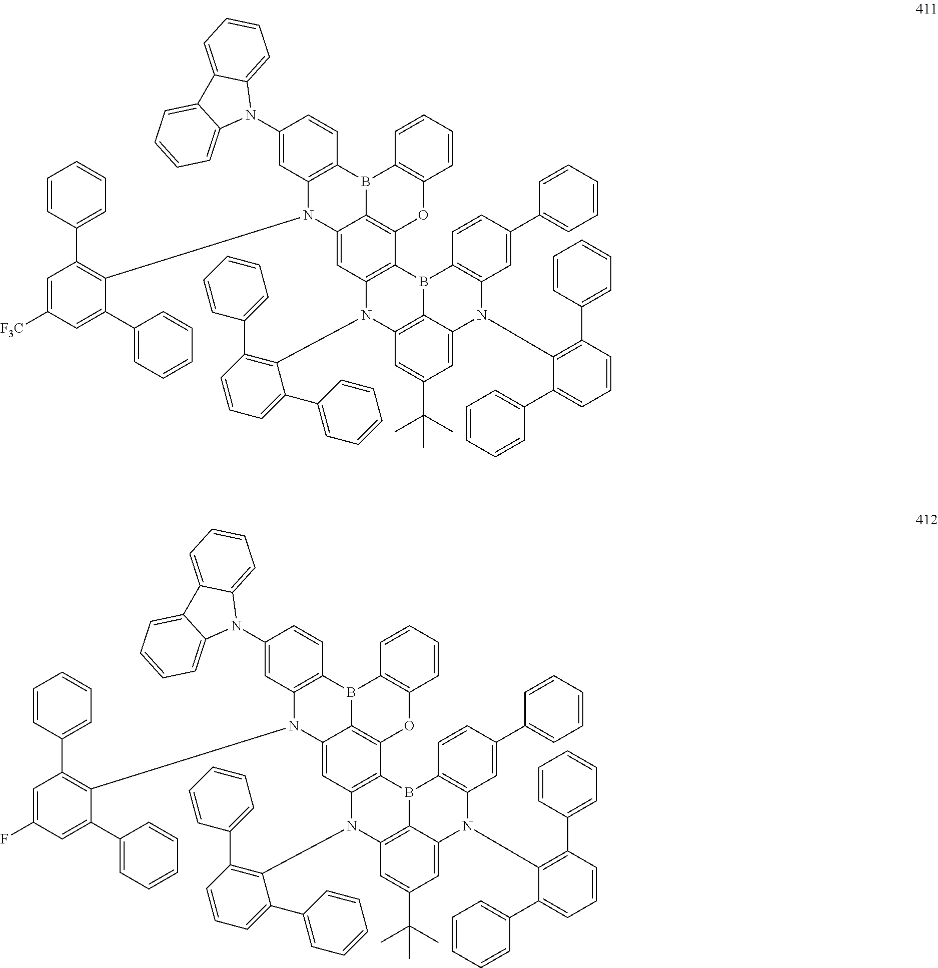 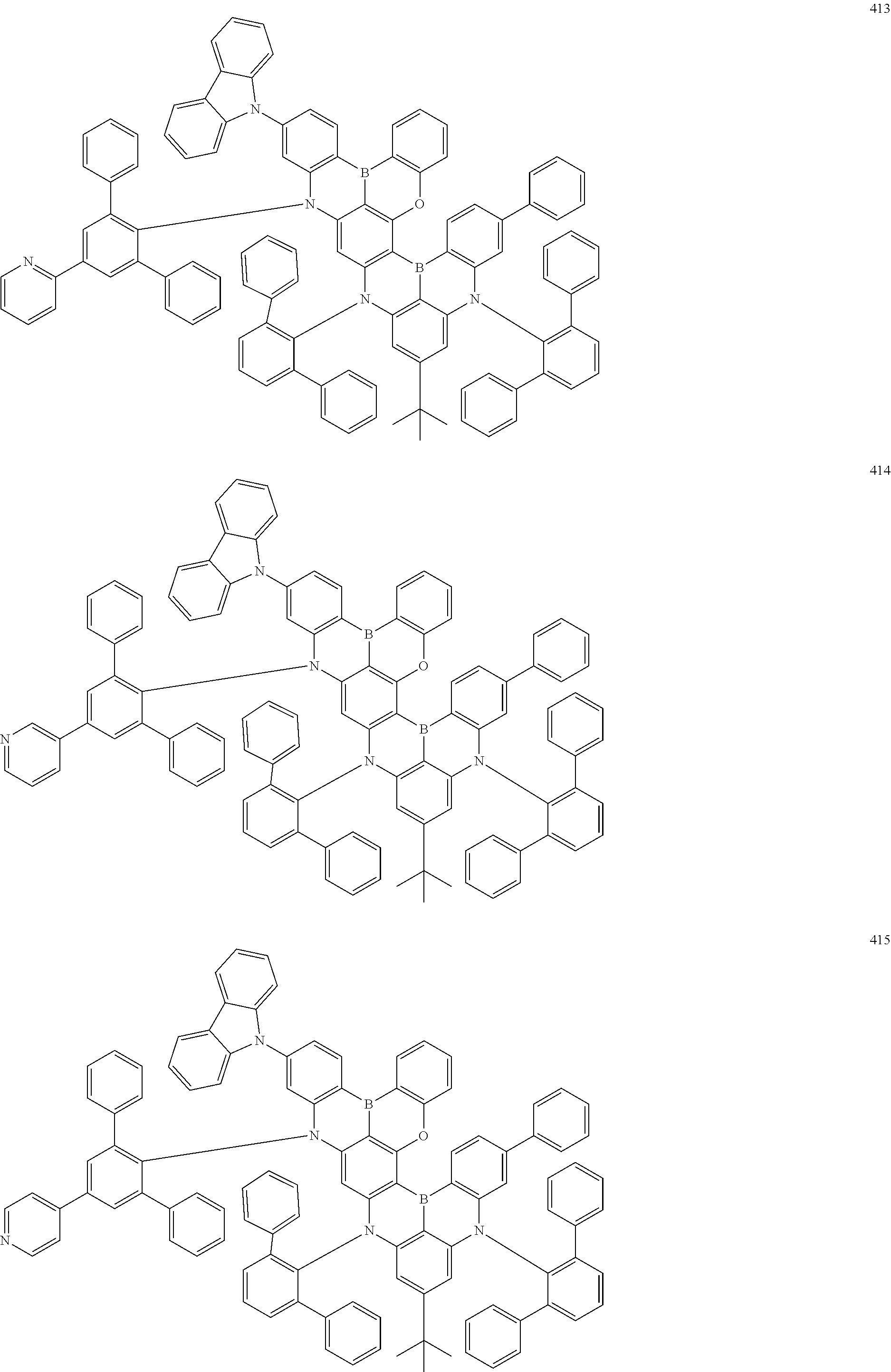 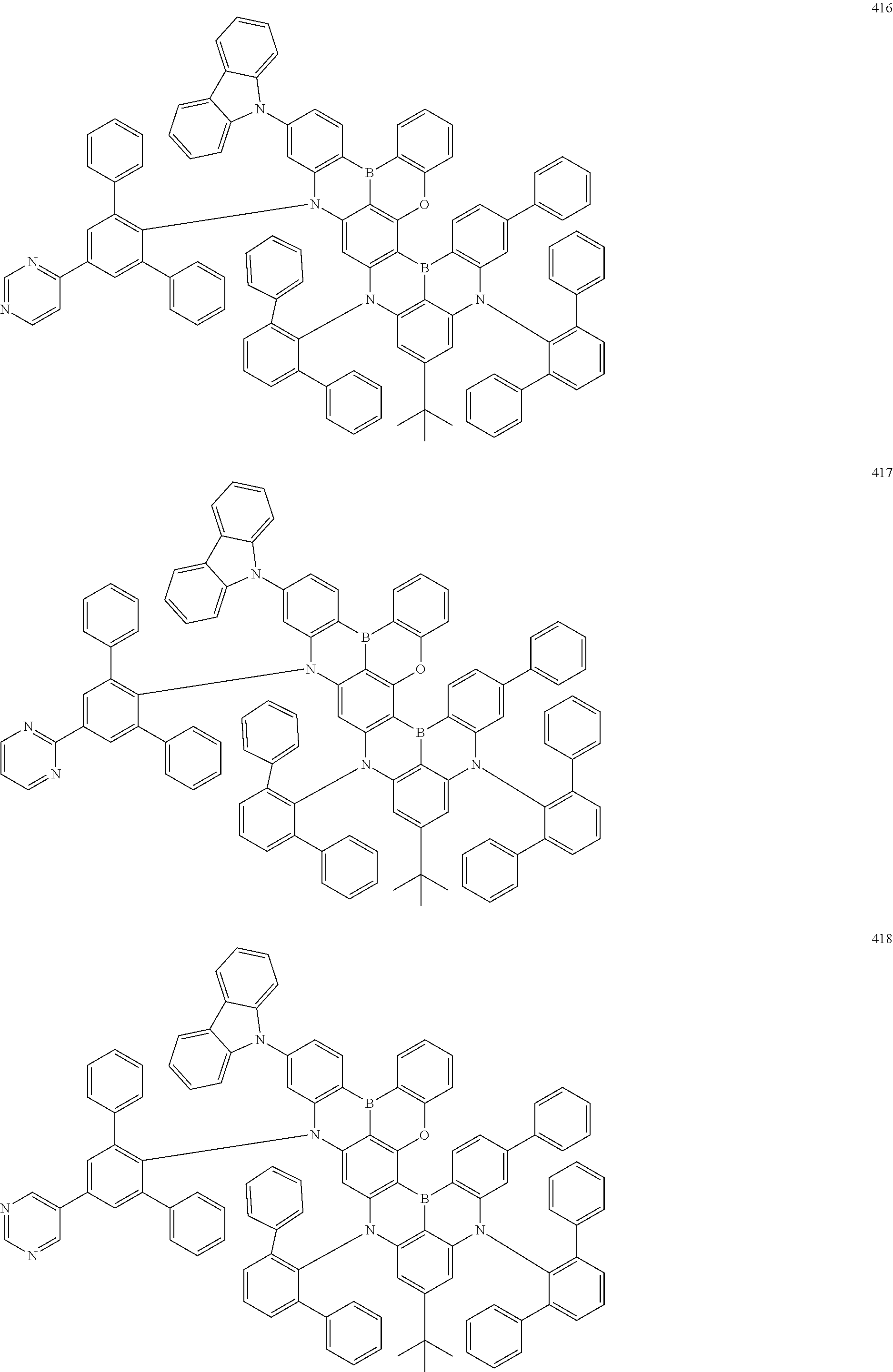 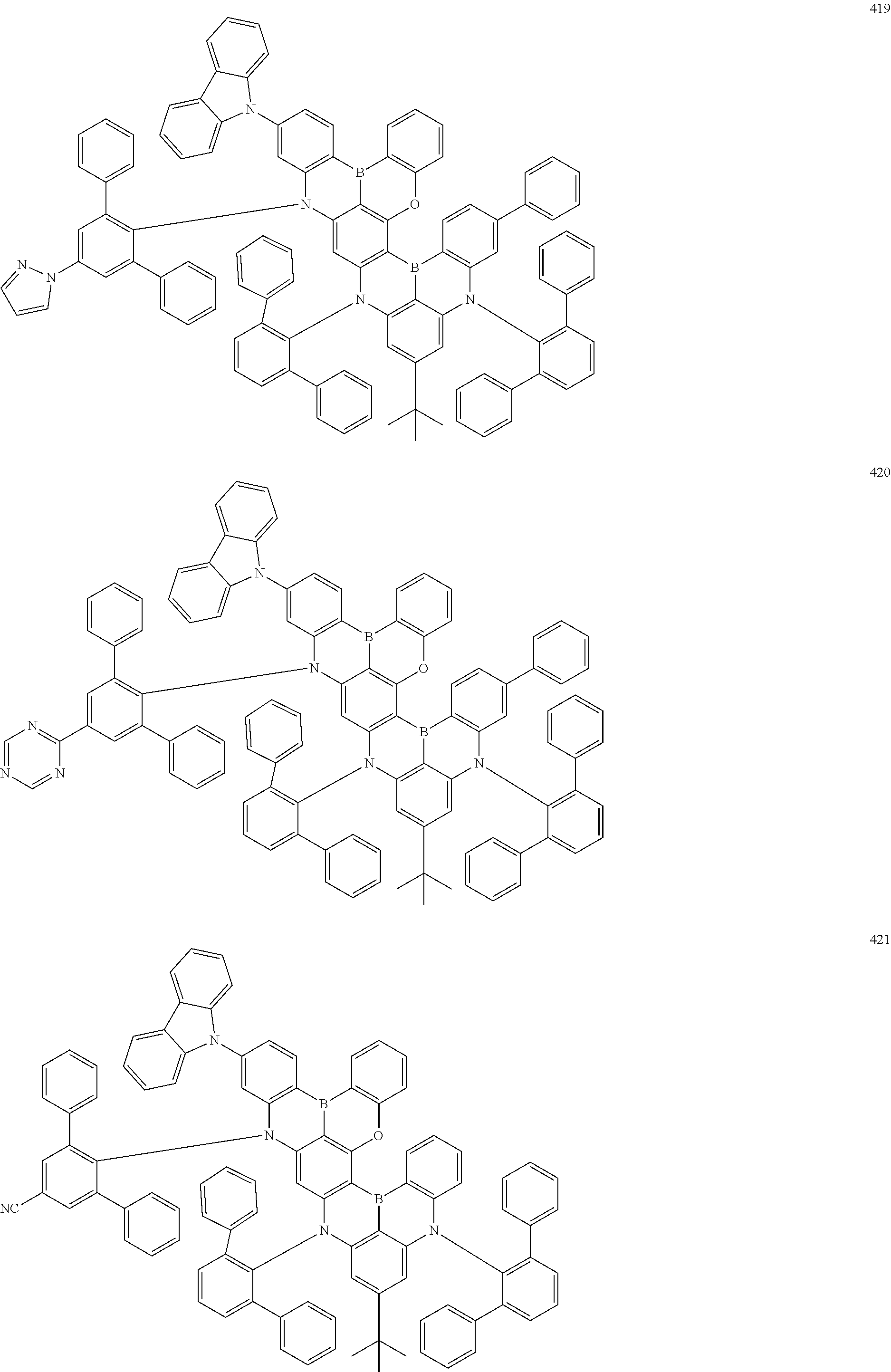 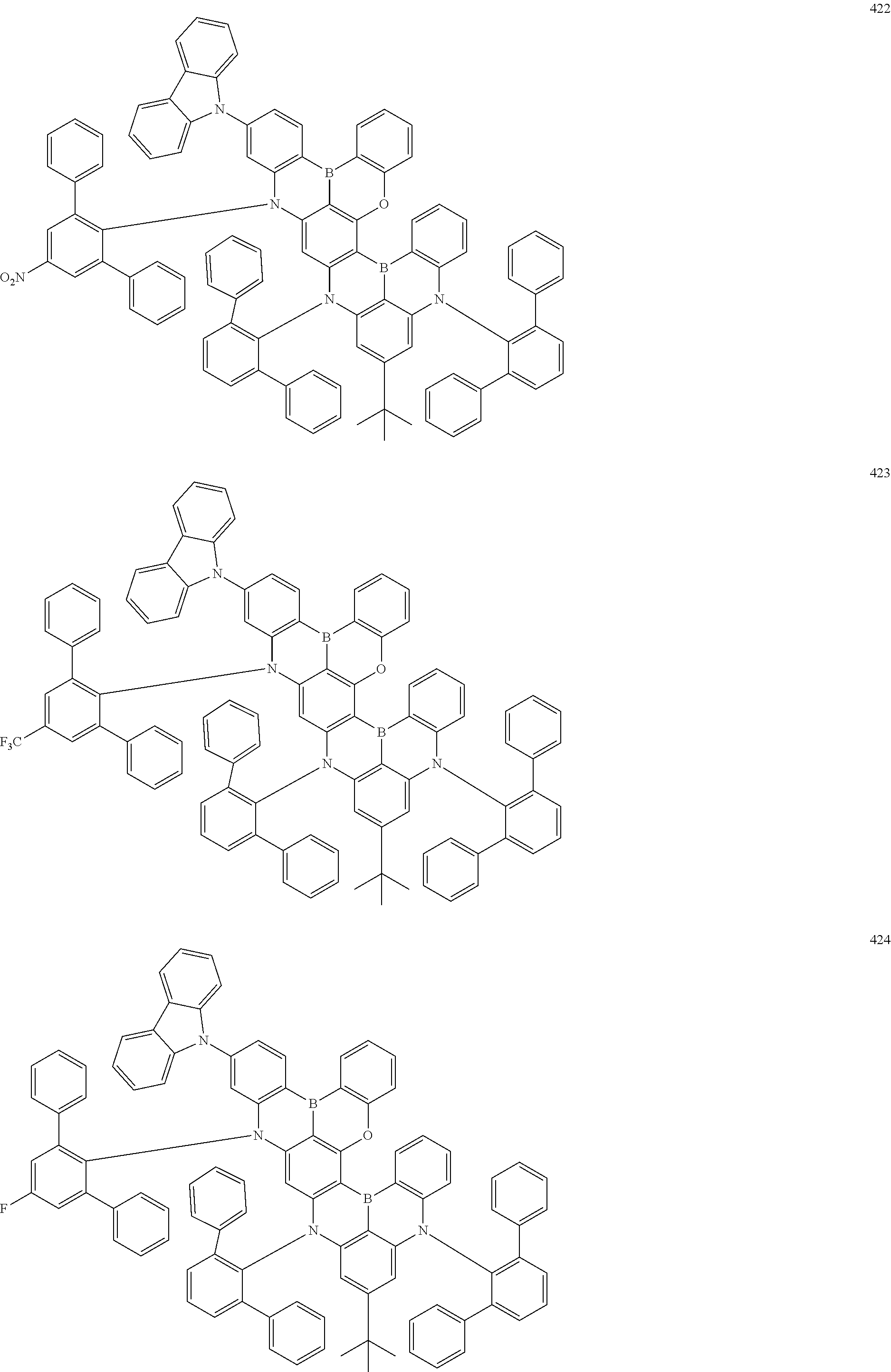 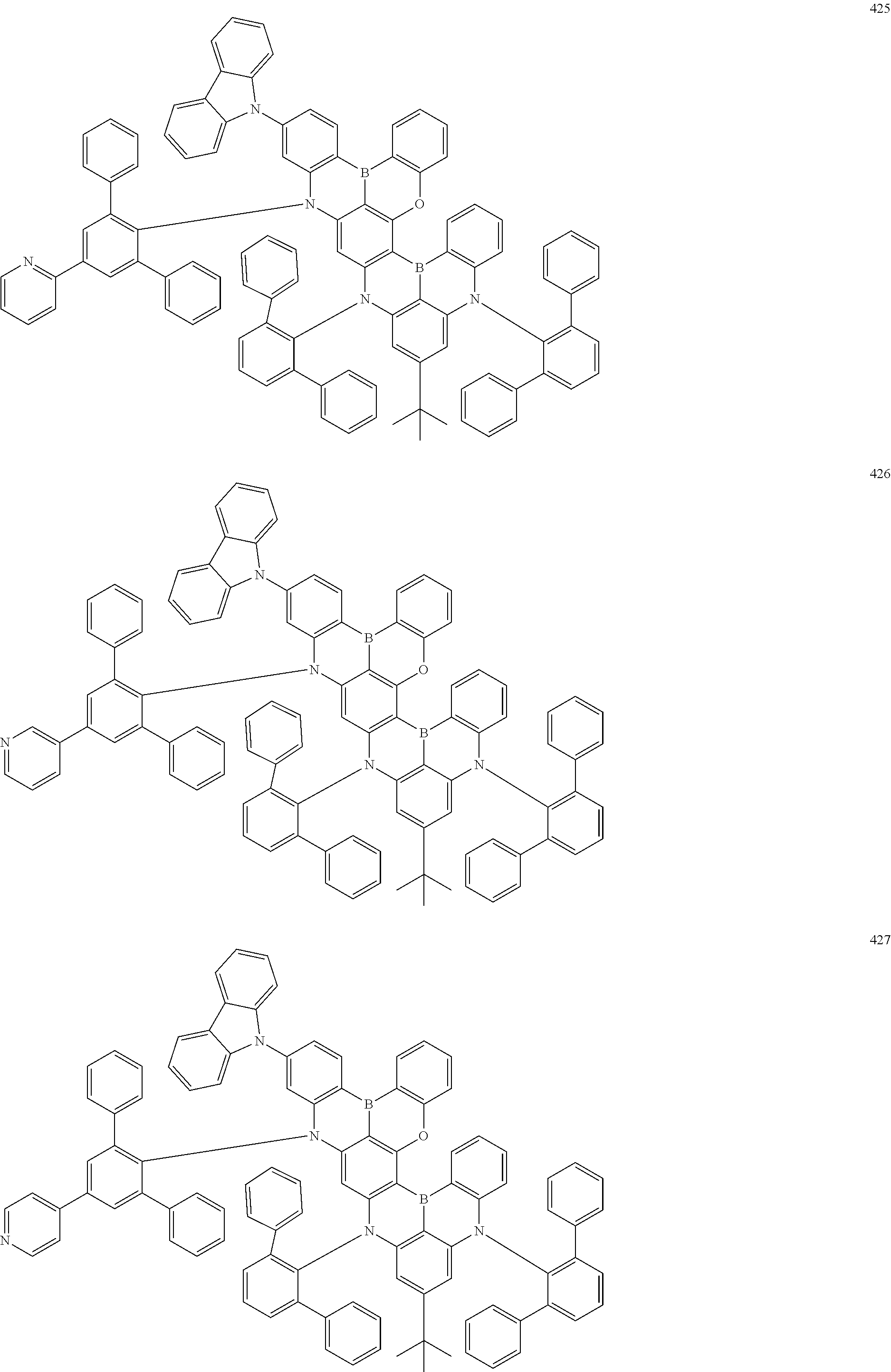 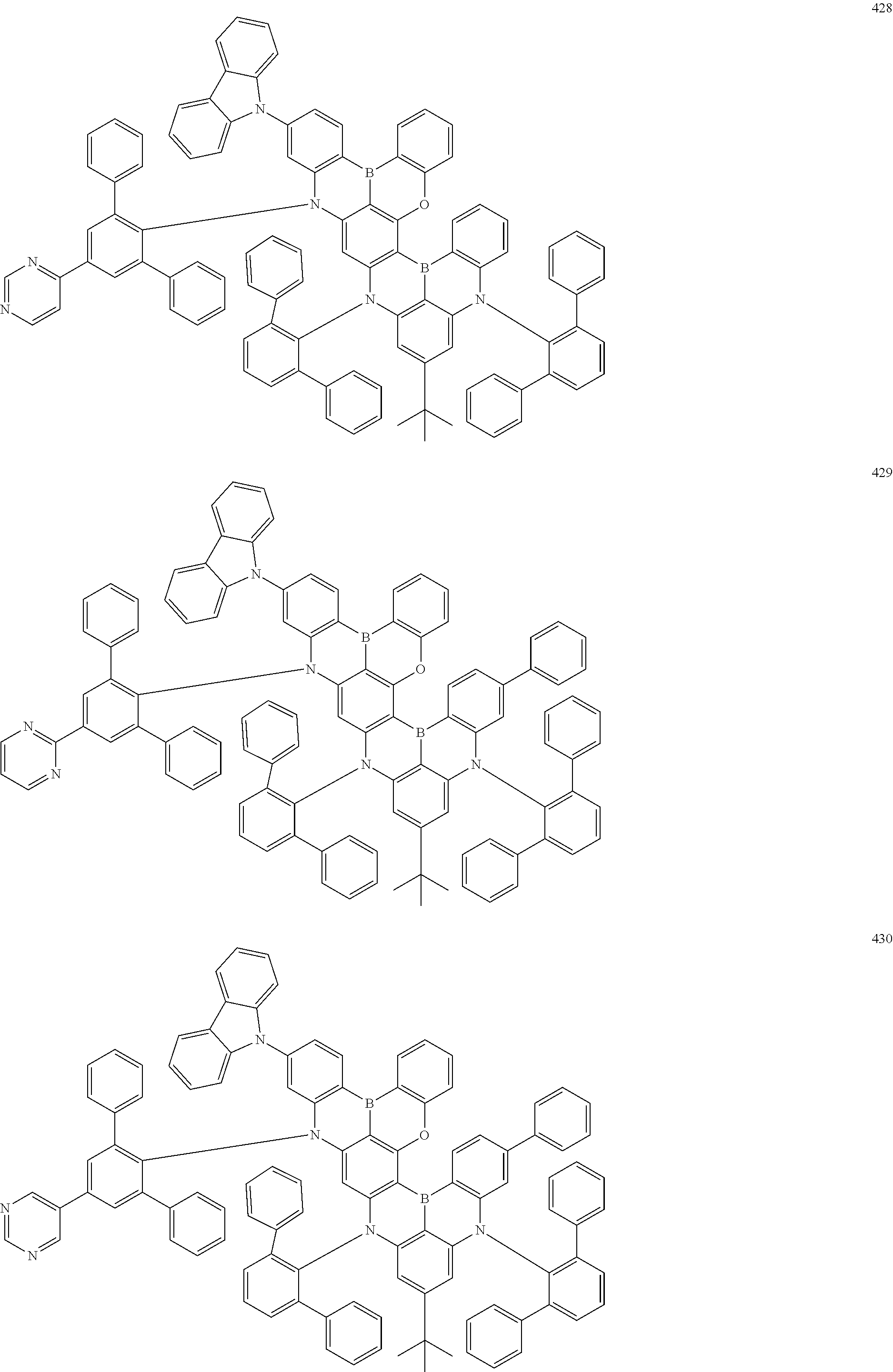 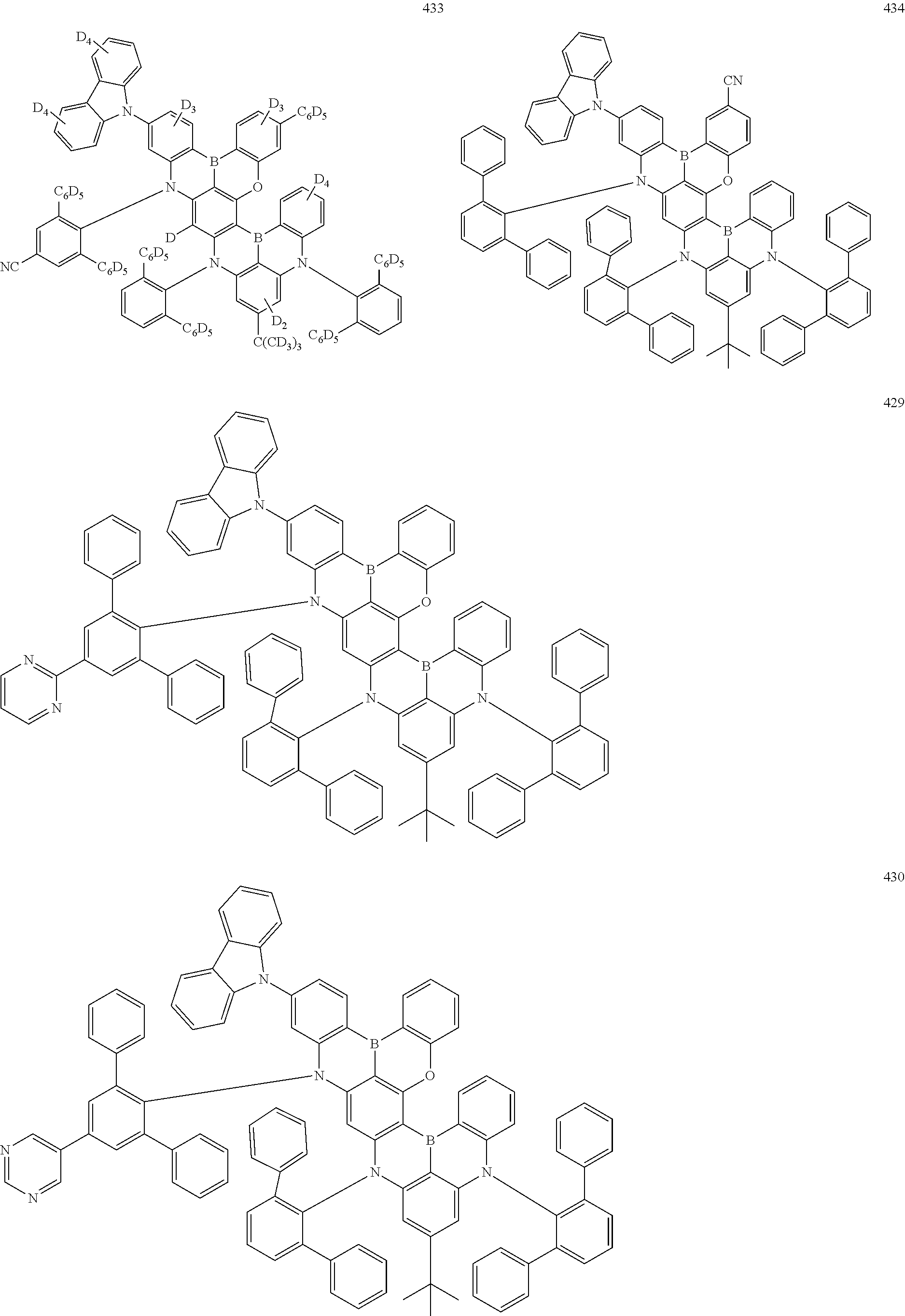 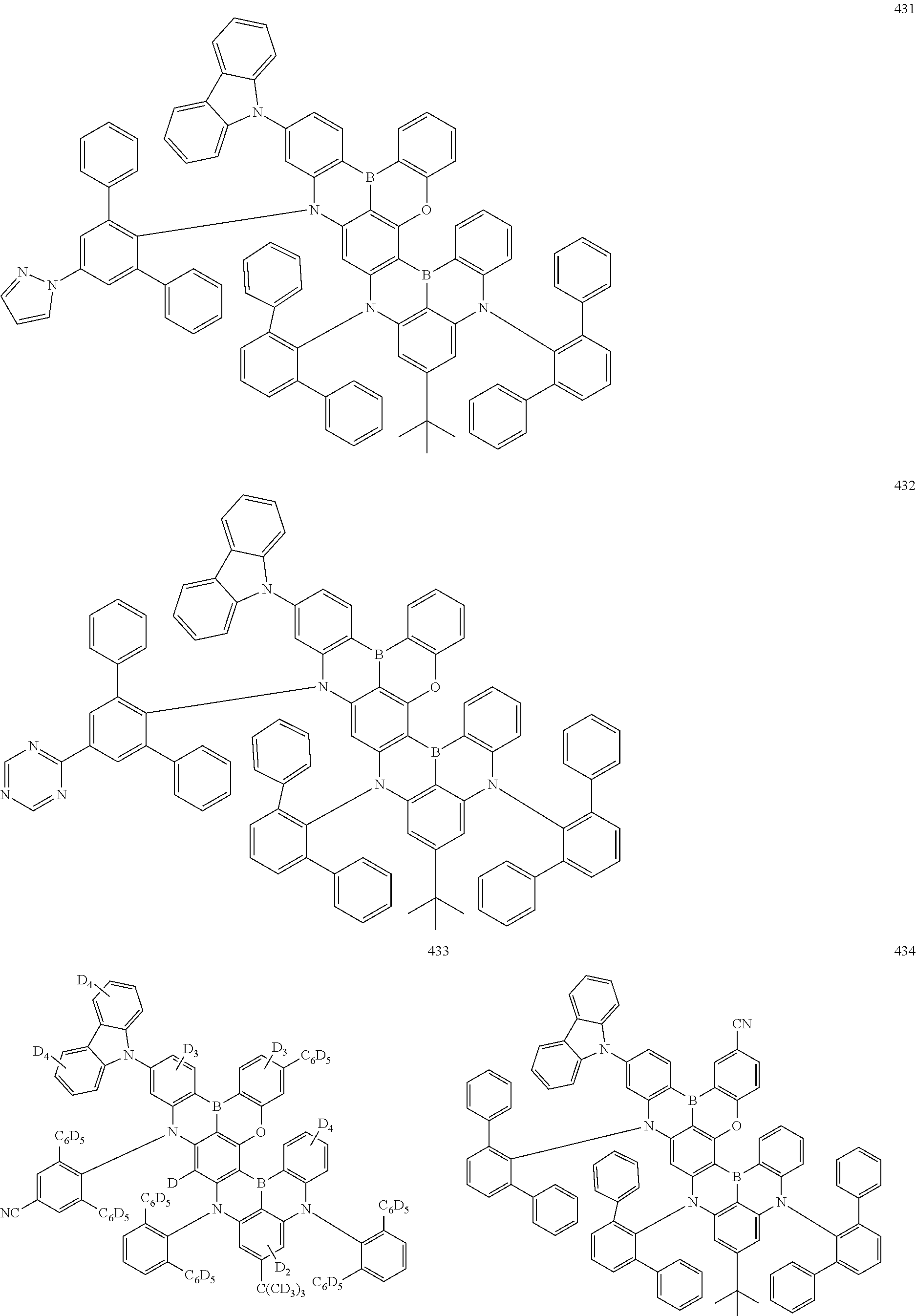
wherein, in Compound Group 1, D is a deuterium atom.

10. A fused polycyclic compound represented by Formula 1: 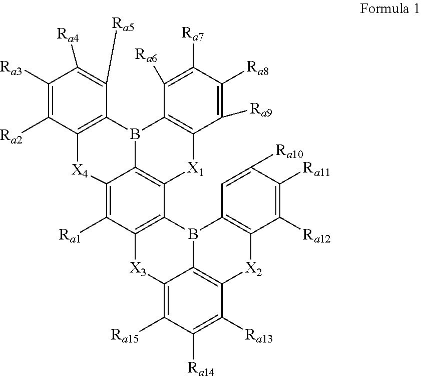
where, in Formula 1 above,
X₁ to X₄ are each independently O, S, or NRₙ, wherein at least one of X₁ to X₄ is NRₙ,
each Rₙ is independently a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, E_{w}, or a group represented by Formula 2,
each E_{w} is independently a fluorine atom, a cyano group, a nitro group, a trifluoromethyl group, a substituted or unsubstituted formyl group, a substituted or unsubstituted pyridine group, a substituted or unsubstituted pyrimidine group, a substituted or unsubstituted pyrazole group, or a substituted or unsubstituted triazine group,
Rₐ₁ to Rₐ₉ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w},
adjacent two or more of Rₐ₂ to Rₐ₉ are optionally bonded together to form a ring, and
Rₐ₁₀ to Rₐ₁₅ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms: 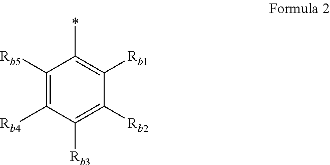
wherein, in Formula 2,
R_{b1} to R_{b5} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w},
wherein the fused polycyclic compound optionally comprises a deuterium atom, and
wherein, the fused polycyclic compound satisfies at least one of Conditions 1 to 3:
Condition 1
at least one of Rₙ is E_{w},
Condition 2
at least one of Rₙ is represented by Formula 2, and
at least one of R_{b1} to R_{b5} in Formula 2 is E_{w},
Condition 3
at least one of Rₐ₁ to Rₐ₉ is E_{w}.

11. The fused polycyclic compound of claim 10, wherein Formula 1 is represented by one of Formula 1-A1 to Formula 1-A5: 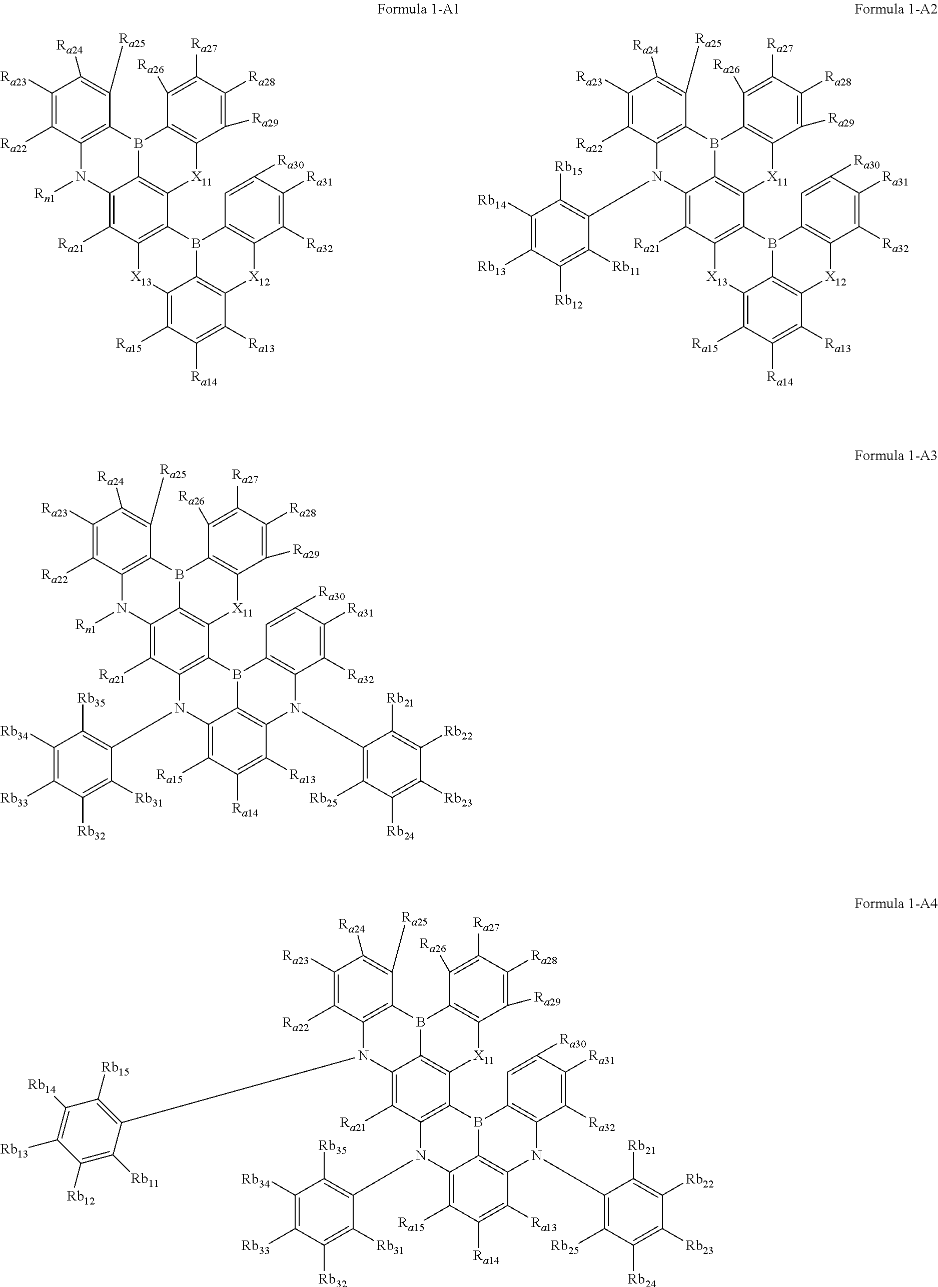 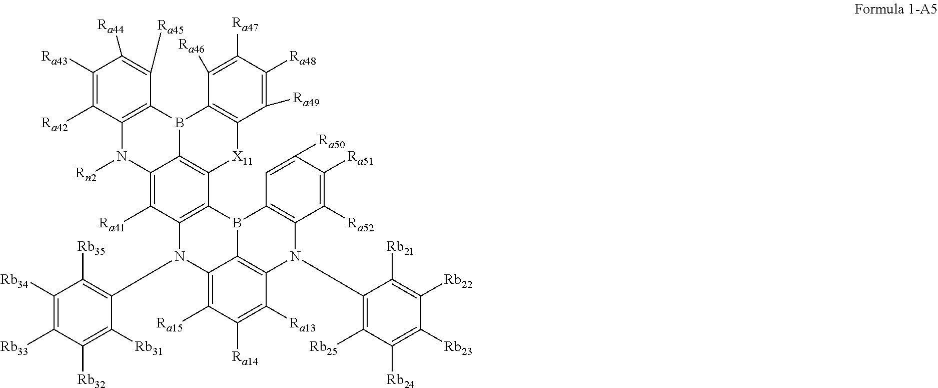
wherein, in Formula 1-A1 and Formula 1-A3,
Rₙ₁ is E_{w},
in Formula 1-A2 and Formula 1-A4,
at least one among R_{b11} to R_{b15} is E_{w}, and the others are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
in Formula 1-A5,
Rₙ₂ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one among Rₐ₄₁ to Rₐ₄₉ is E_{w}, and the others are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Rₐ₅₀ to Rₐ₅₂ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
in Formula 1-A1 to Formula 1-A5,
X₁₁ to X₁₃ are each independently O or S,
Rₐ₂₁ to Rₐ₃₂ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{b21} to R_{b25}, and R_{b31} to R_{b35} each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
Rₐ₁₃ to Rₐ₁₅ are the same as defined in Formula 1.

12. The fused polycyclic compound of claim 11, wherein Formula 1-A4 is represented by one of Formula 1-A41 to Formula 1-A43: 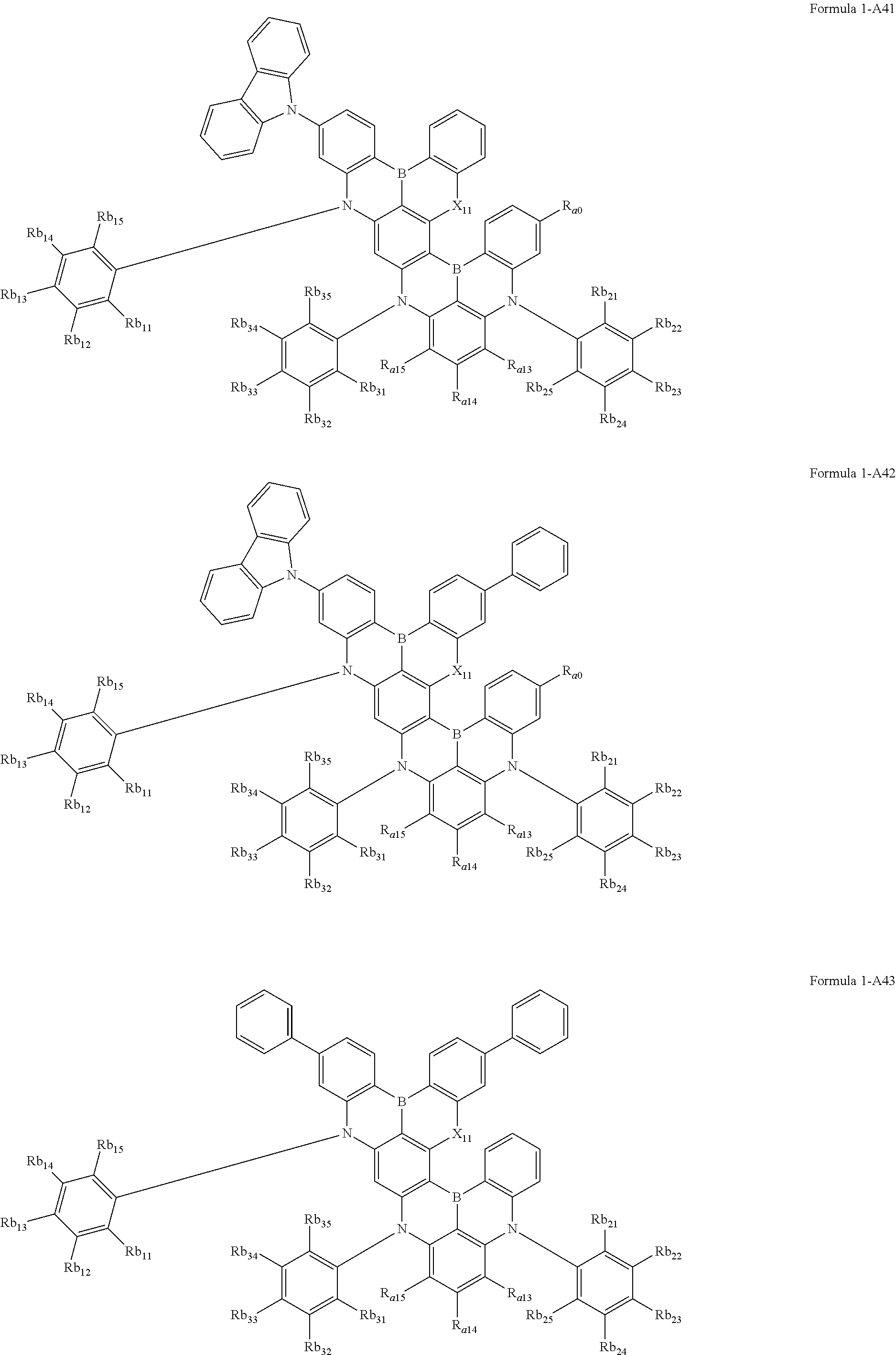
wherein, in Formula 1-A41 to Formula 1-A43,
Rₐ₀ is a hydrogen atom, a deuterium atom, or a substituted or unsubstituted phenyl group,
Rₐ₁₃ to Rₐ₁₅, R_{b11} to R_{b15}, R_{b21} to R_{b25}, R_{b31} to R_{b35}, and X₁₁ are the same as defined in Formula 1-A4.

13. The fused polycyclic compound of claim 11, wherein, in Formula 1-A2 and Formula 1-A4, a first cyclic group comprising R_{b11} to R_{b15} is represented by one of R1-B1 to R1-B144: 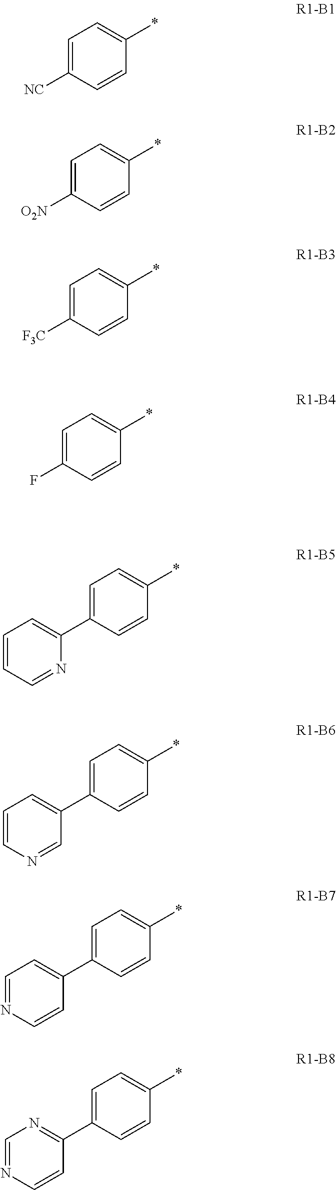 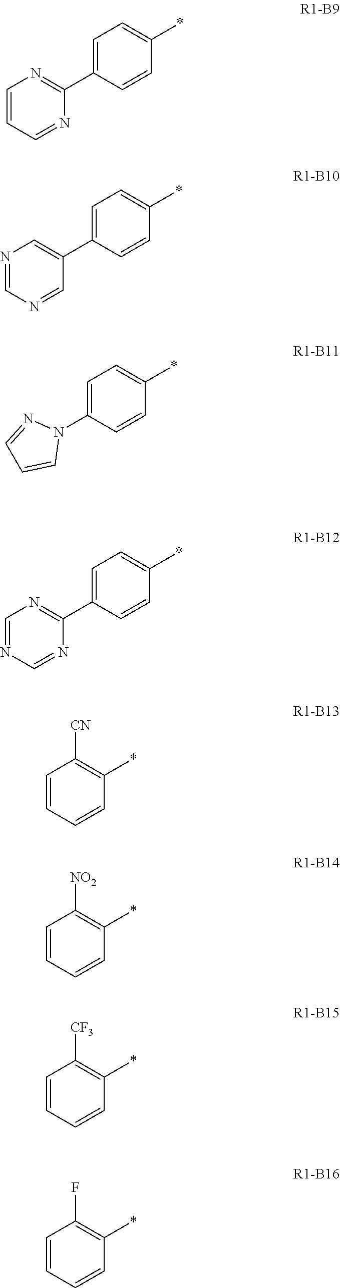 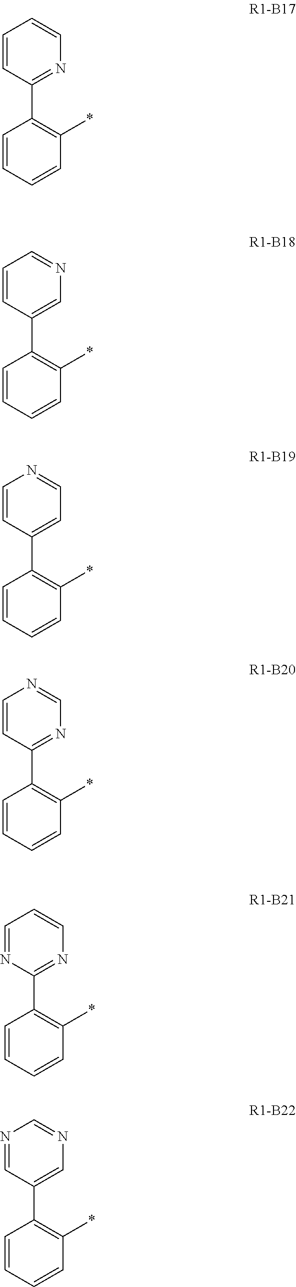 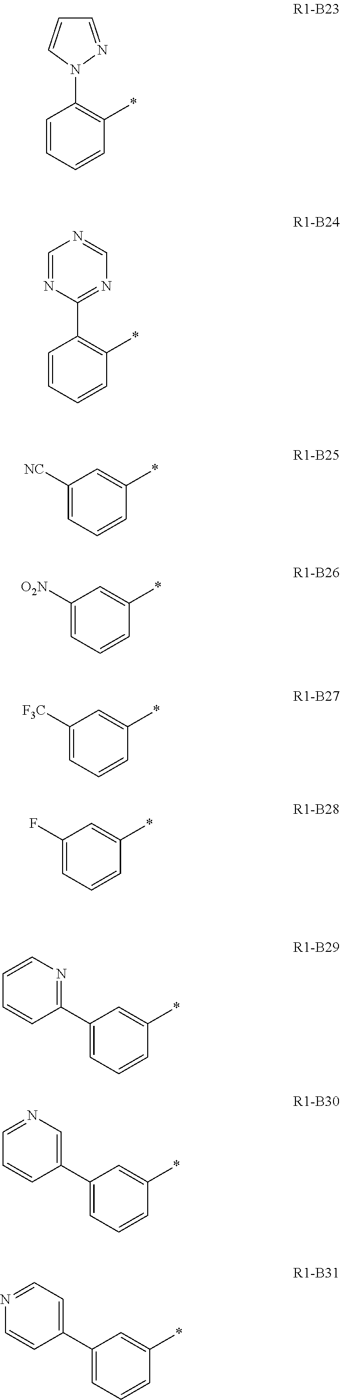 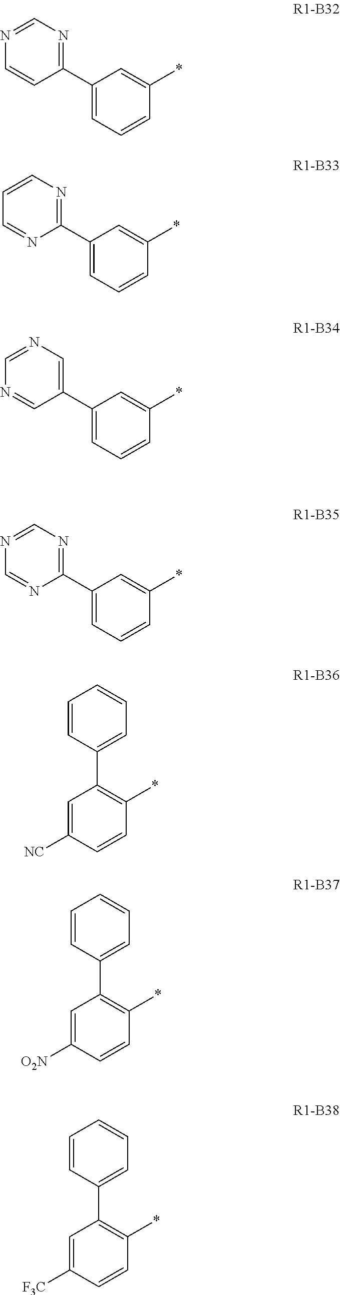 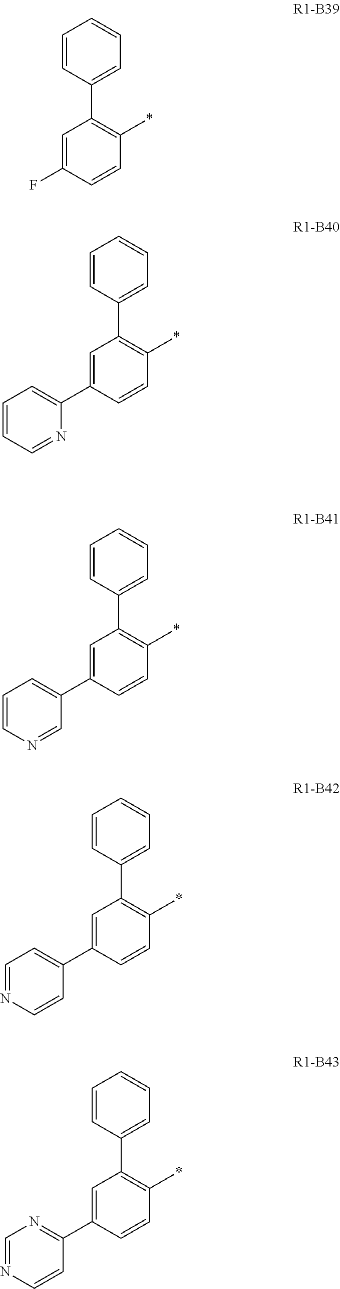 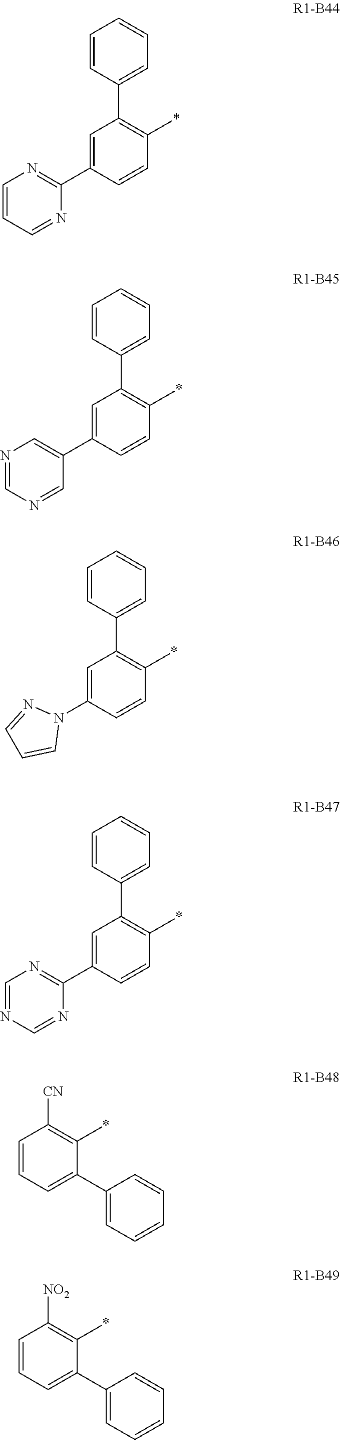 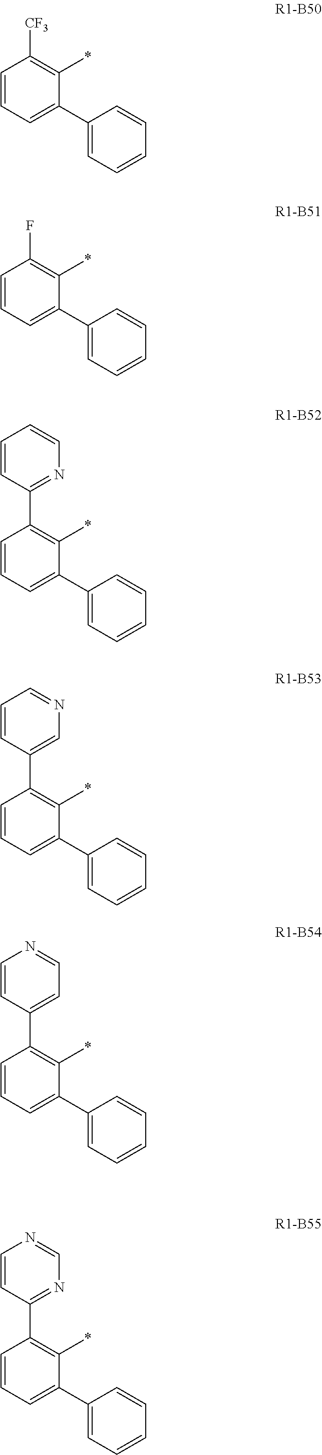 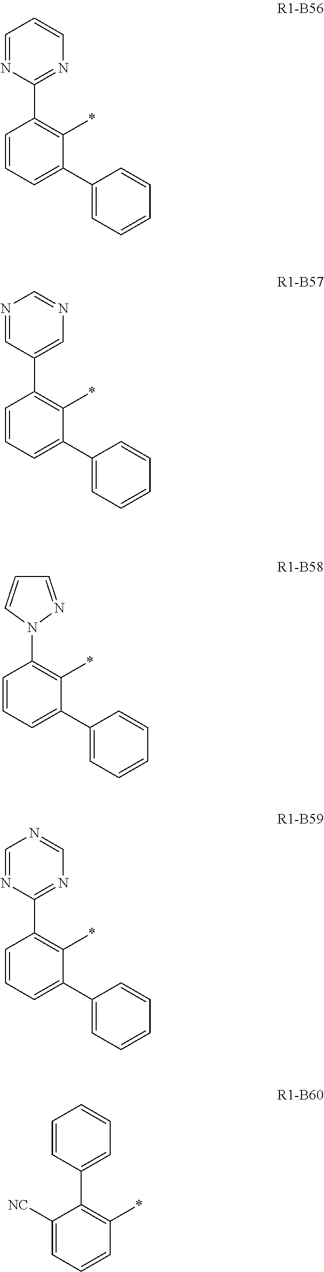 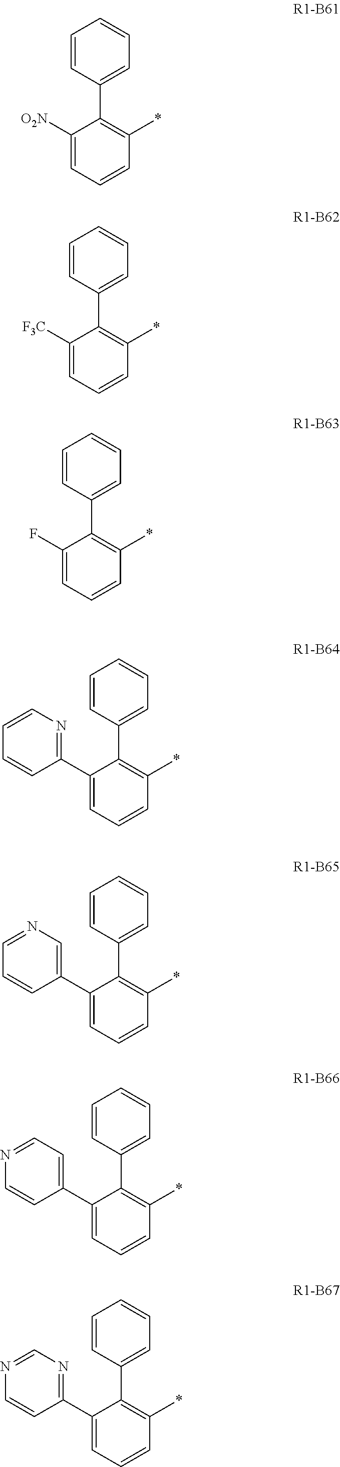 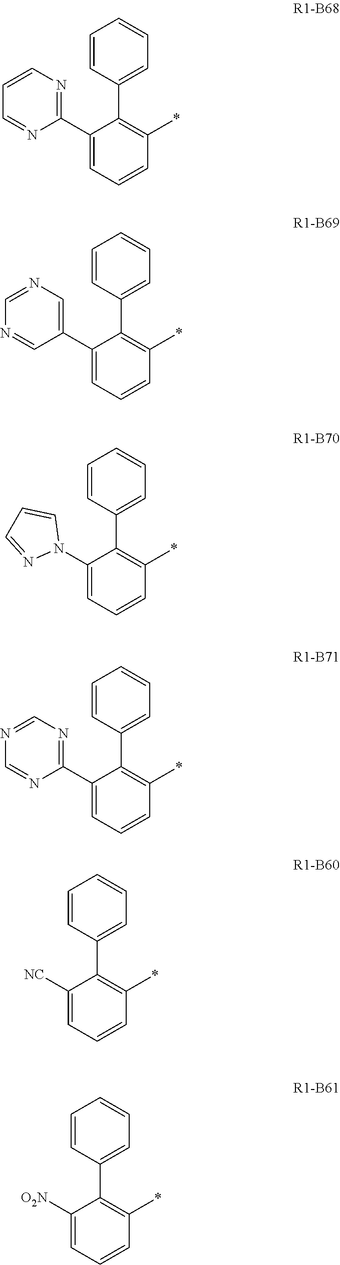 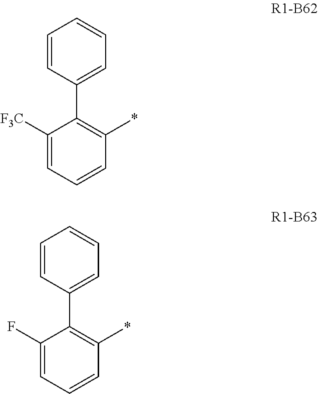 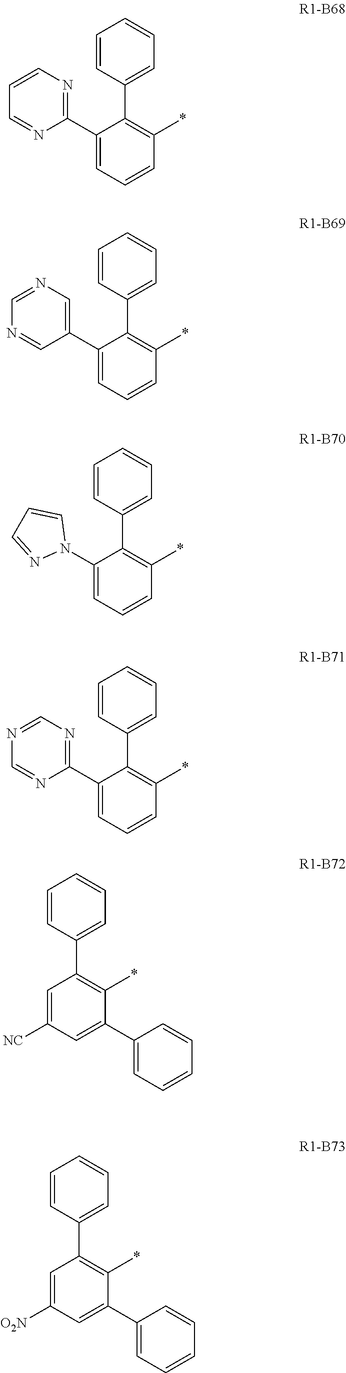 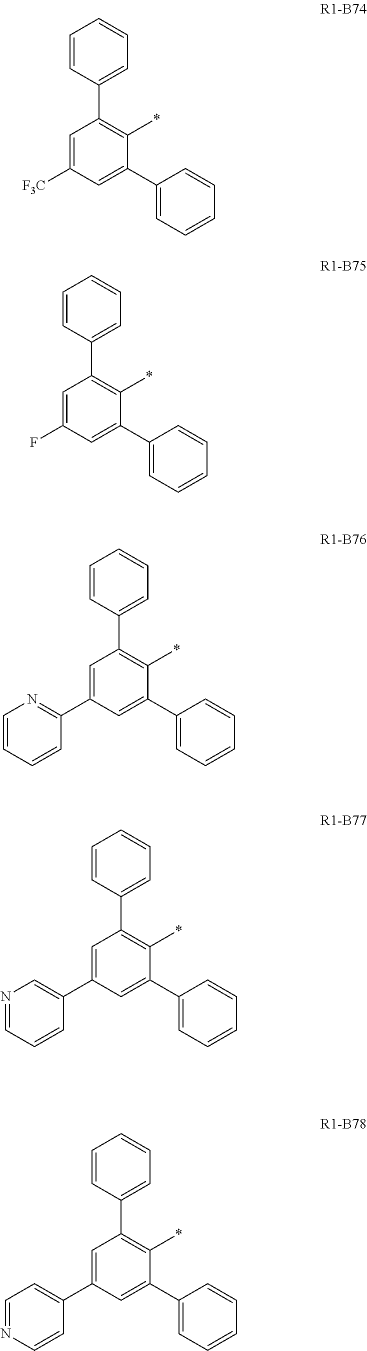 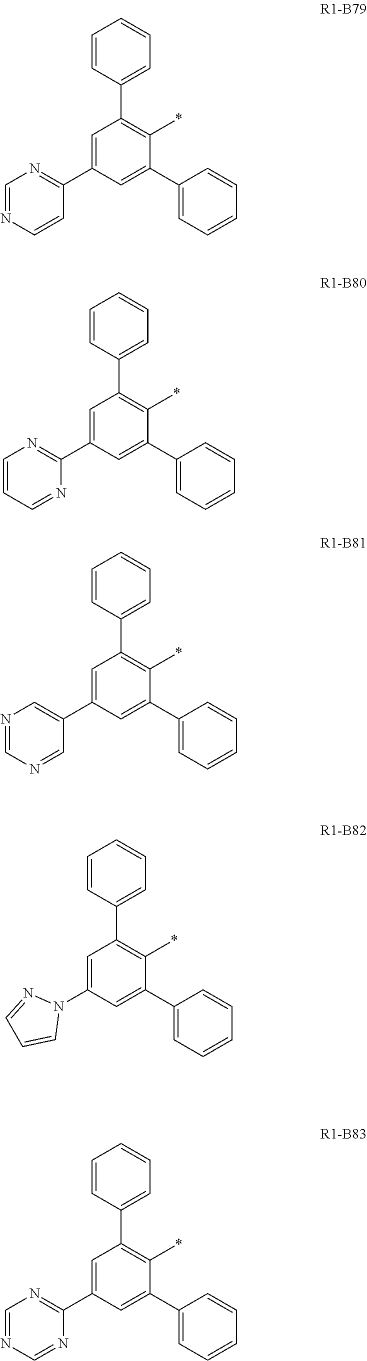 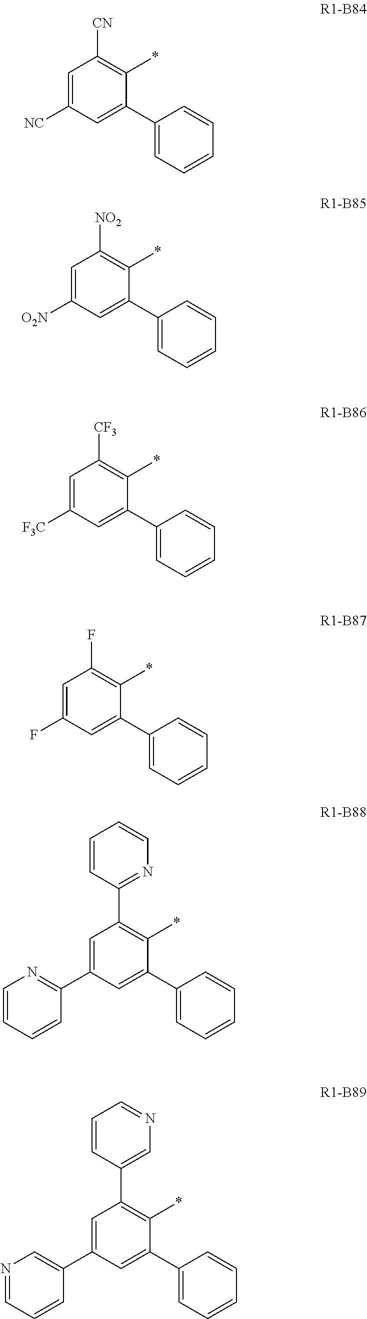 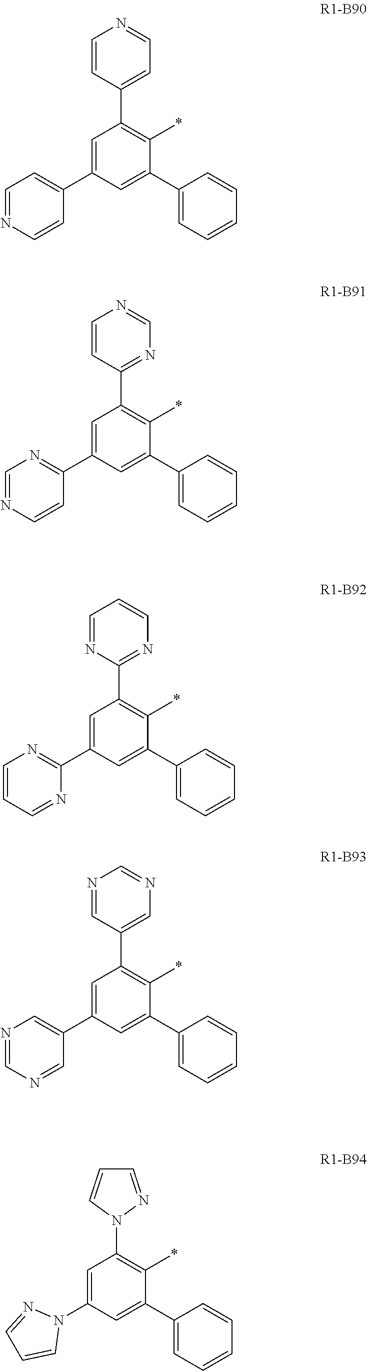 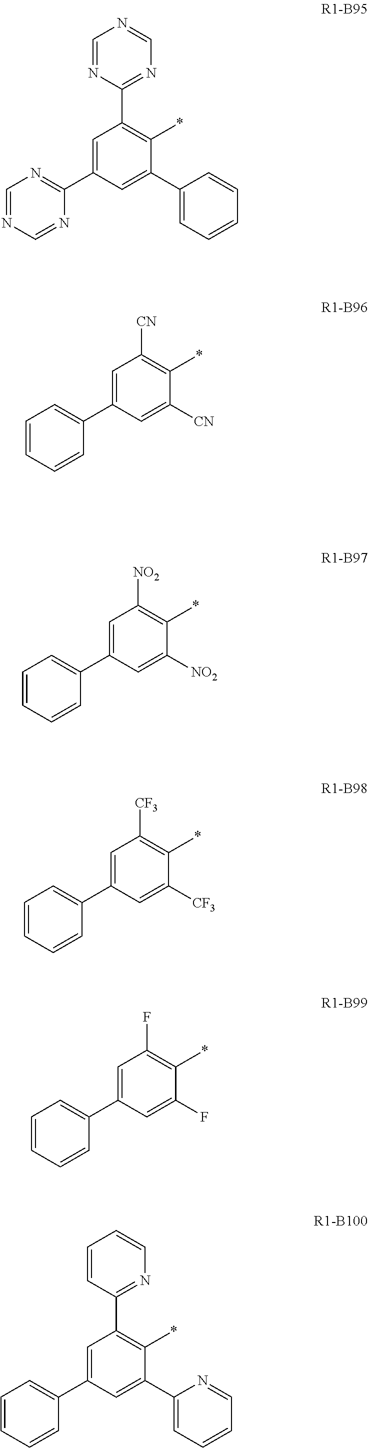 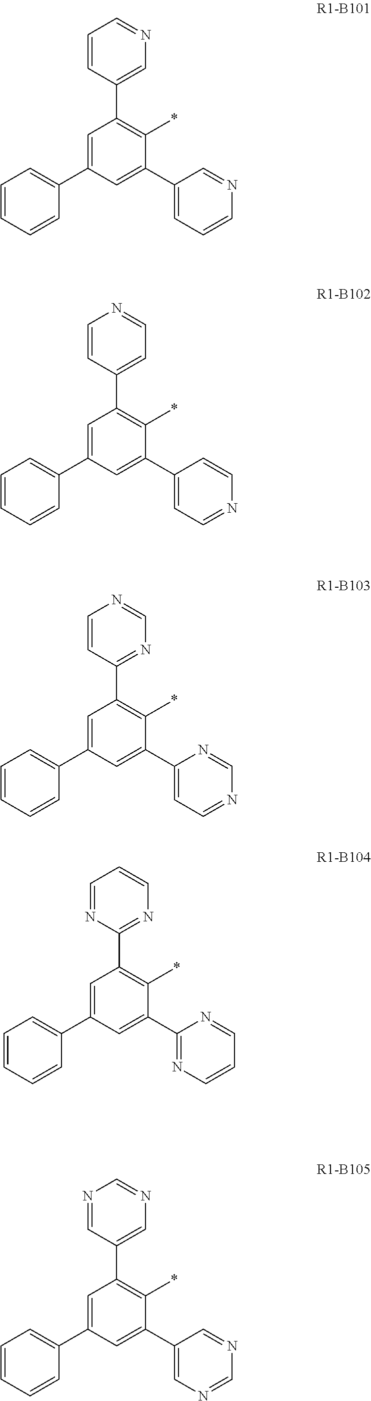 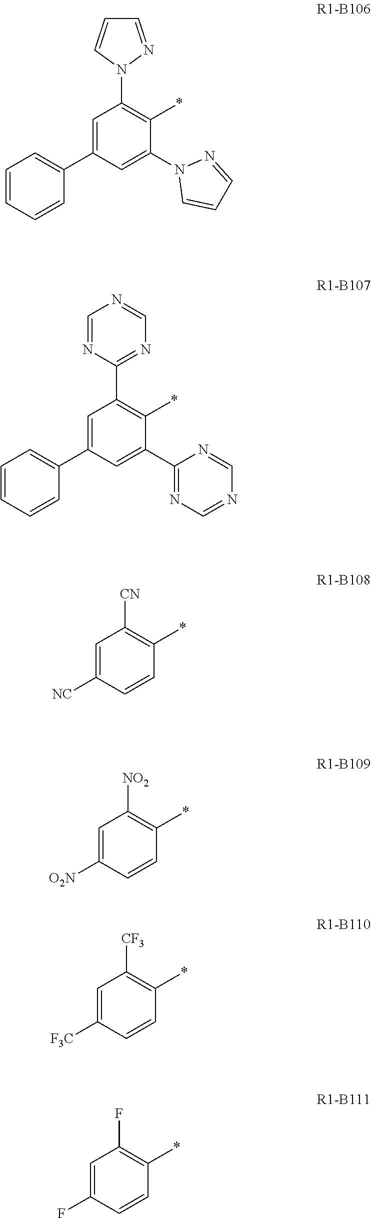 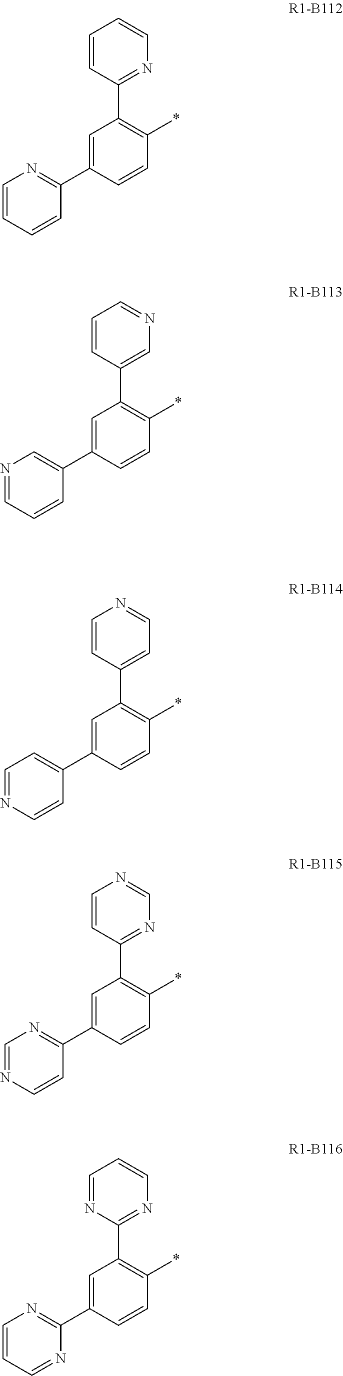 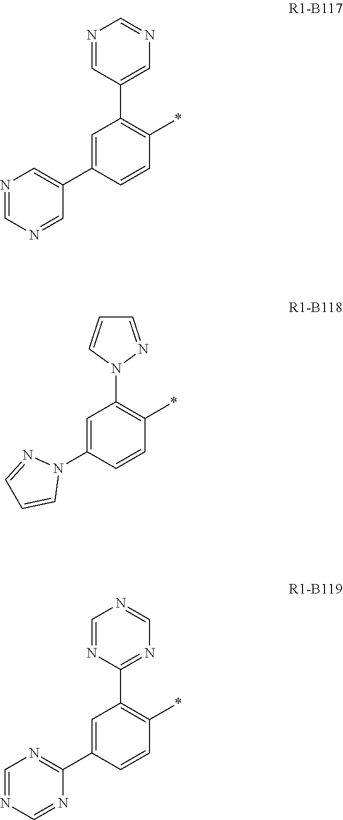 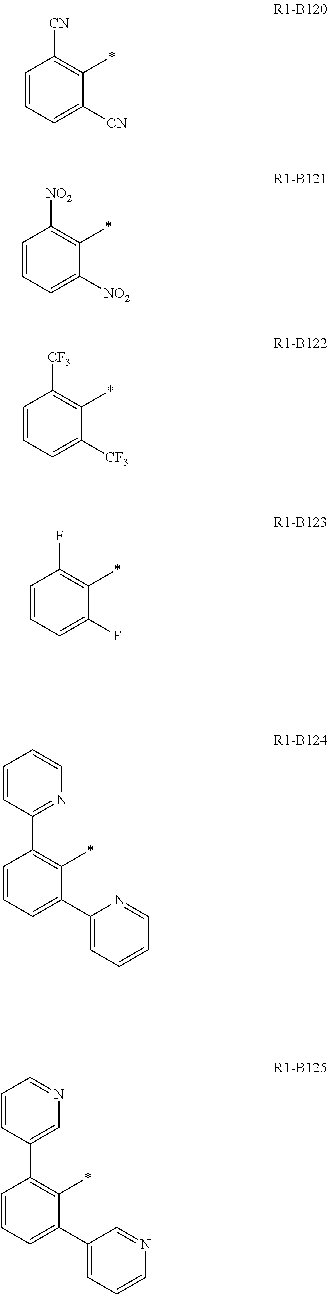 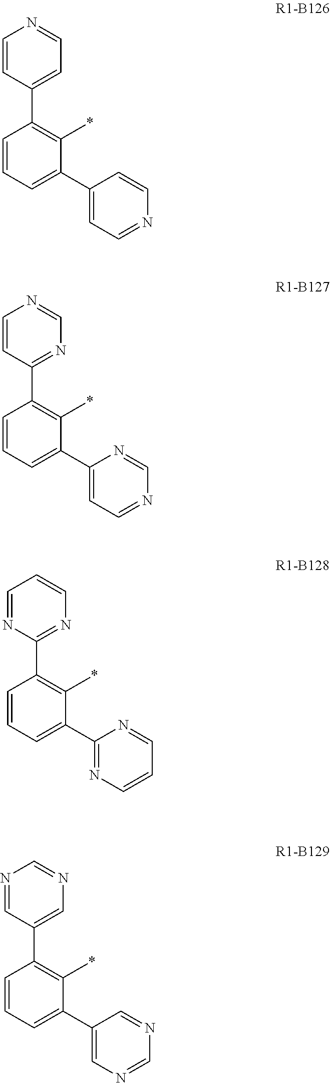 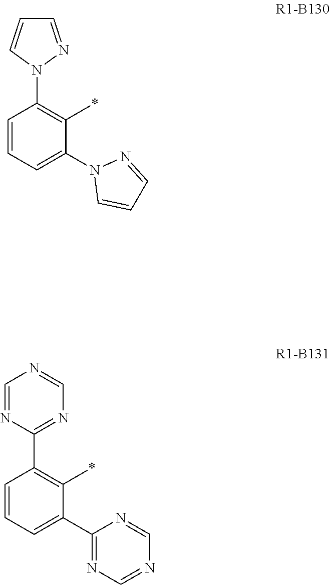 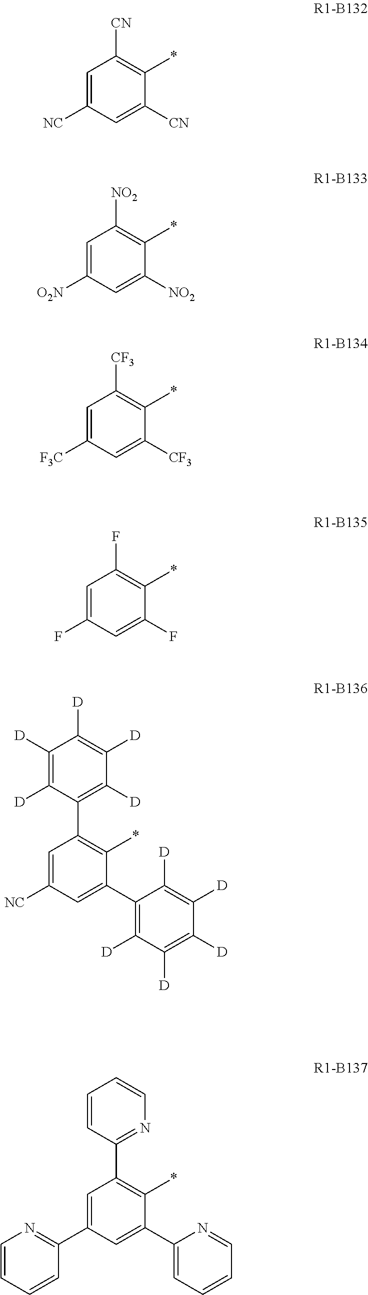 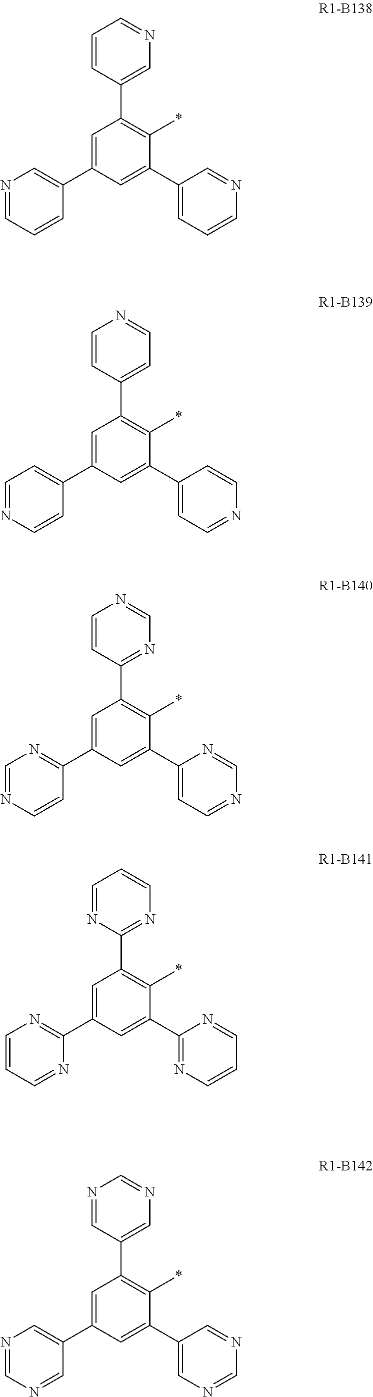 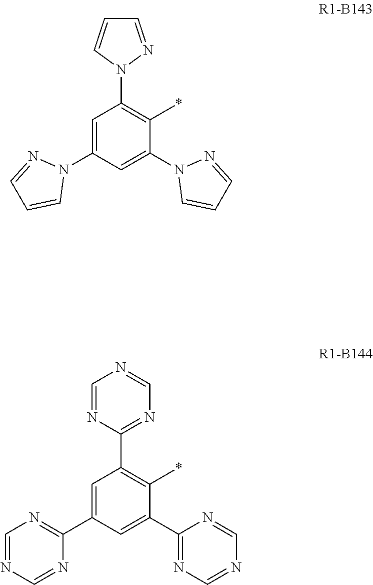
wherein, in R1-B136, D is a deuterium atom.

14. The fused polycyclic compound of claim 11, wherein, in Formula 1-A3 to Formula 1-A5 a second cyclic group comprising R_{b21} to R_{b25}, and a third cyclic group comprising R_{b31} to R_{b35} are each independently represented by one of R2-B1 to R2-B4: 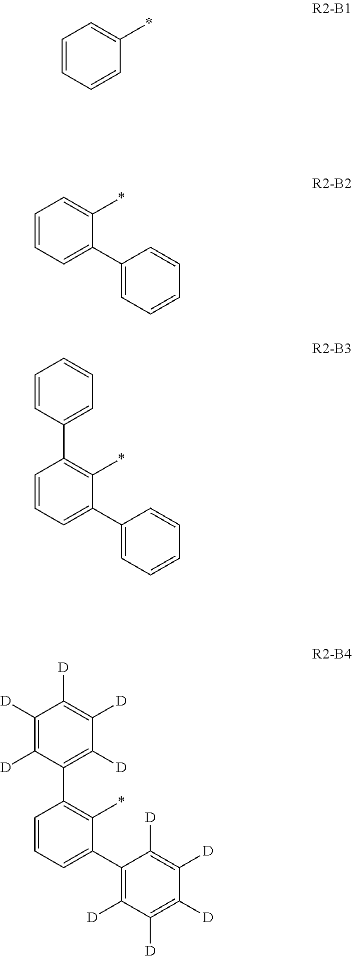
wherein, in R2-B4, D is a deuterium atom.

15. The fused polycyclic compound of claim 10, wherein Formula 1 is represented by Formula 1-B: 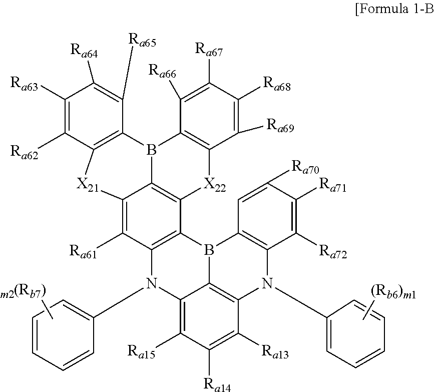
wherein, in Formula 1-B,
X₂₁ and X₂₂ are each independently O, S, or NRₙ₃, wherein at least one or X₂₁ or X₂₂ is NRₙ₃,
each Rₙ₃ is independently a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, E_{w}, or a group represented by Formula 2,
m1 and m2 are each independently an integer of 0 to 5,
R_{b6} and R_{b7} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w},
Rₐ₆₁ to Rₐ₆₉ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w},
Rₐ₇₀ to Rₐ₇₂ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
provided that at least one of Rₙ₃, R_{b6}, R_{b7}, or Rₐ₆₁ to Rₐ₆₉ comprises E_{w}, and
Rₐ₁₃ to Rₐ₁₅ are the same as defined in Formula 1.

16. The fused polycyclic compound of claim 10, wherein, in Formula 1, Rₐ₁₃ to Rₐ₁₅ are each independently a hydrogen atom, a deuterium atom, or a substituted or unsubstituted t-butyl group.

17. The fused polycyclic compound of claim 10, wherein Formula 1 is represented by a compound in Compound Group 1: 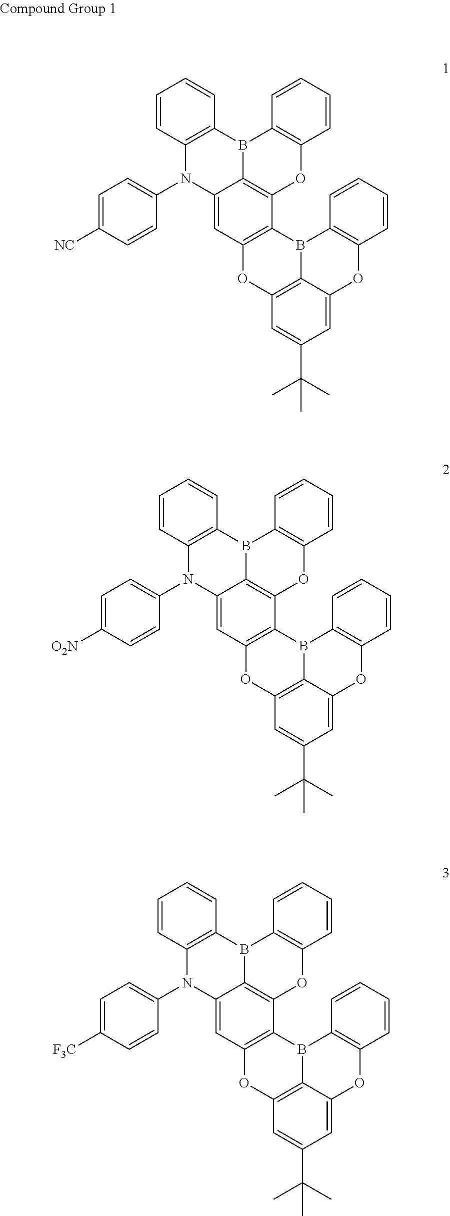 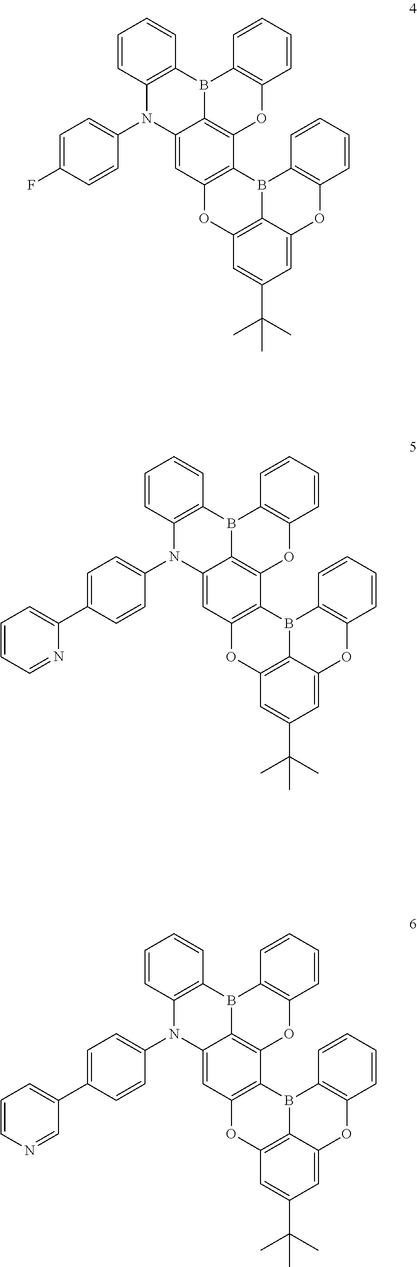 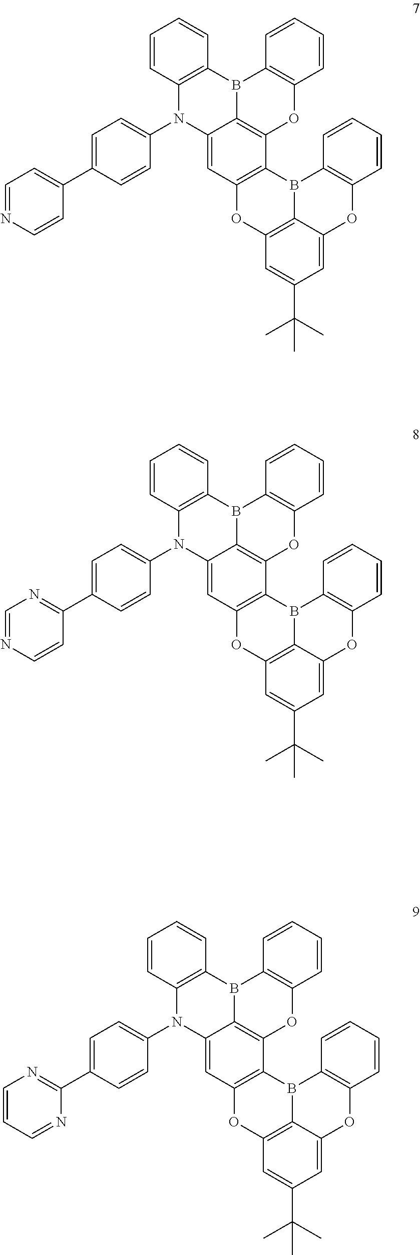 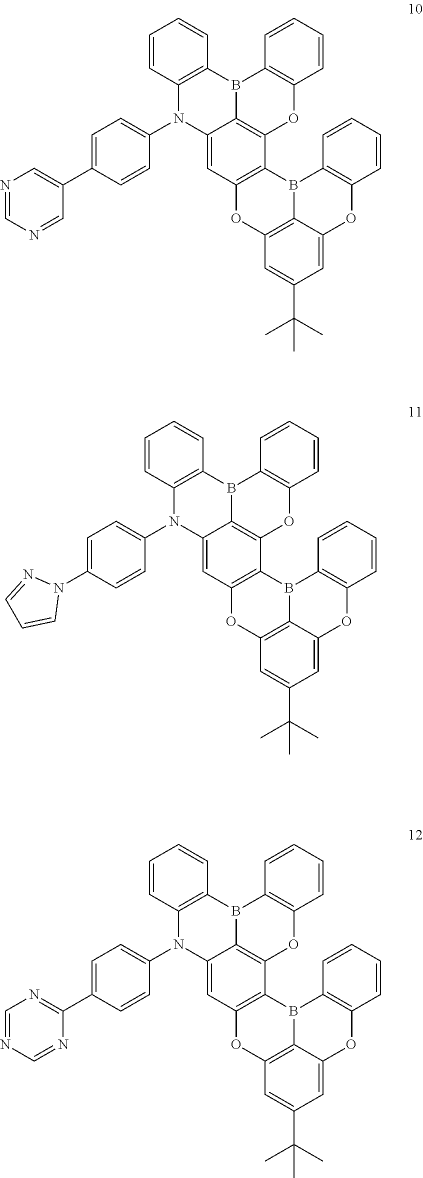 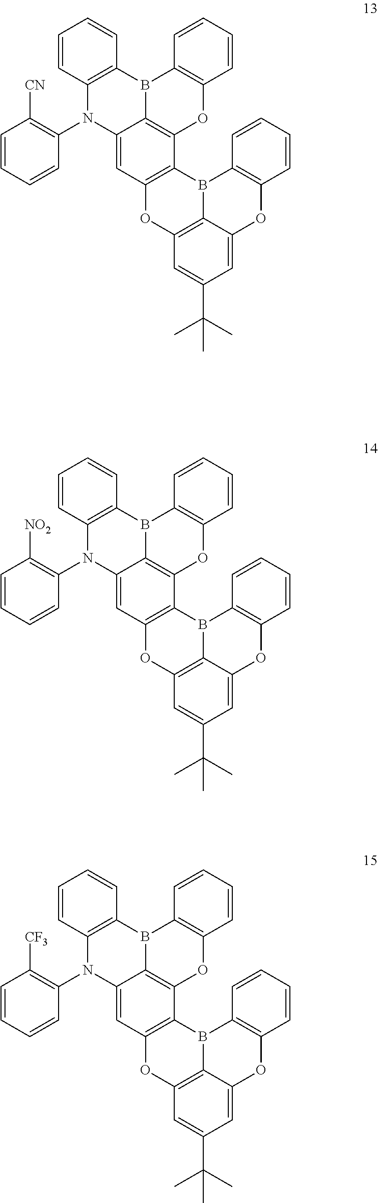 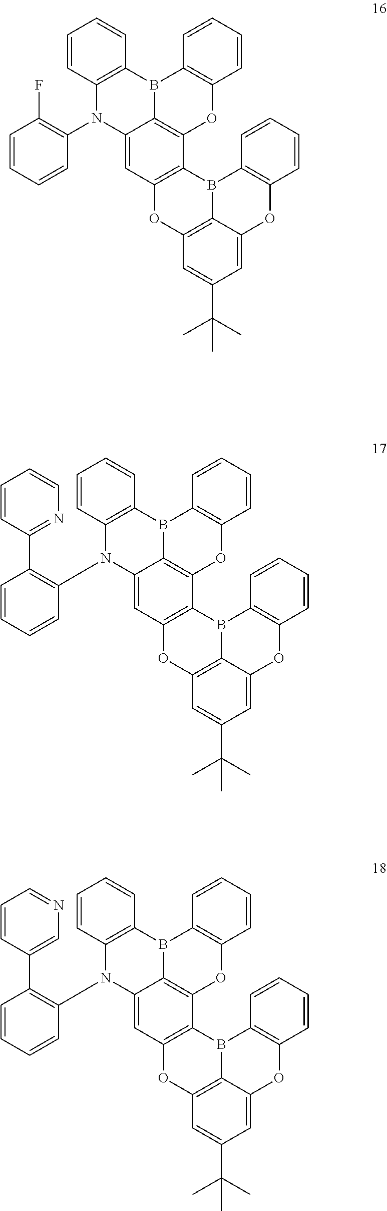 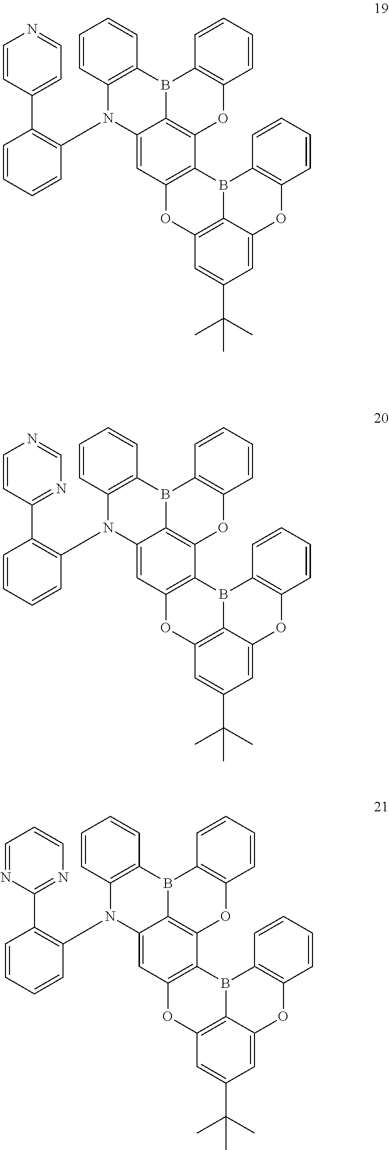 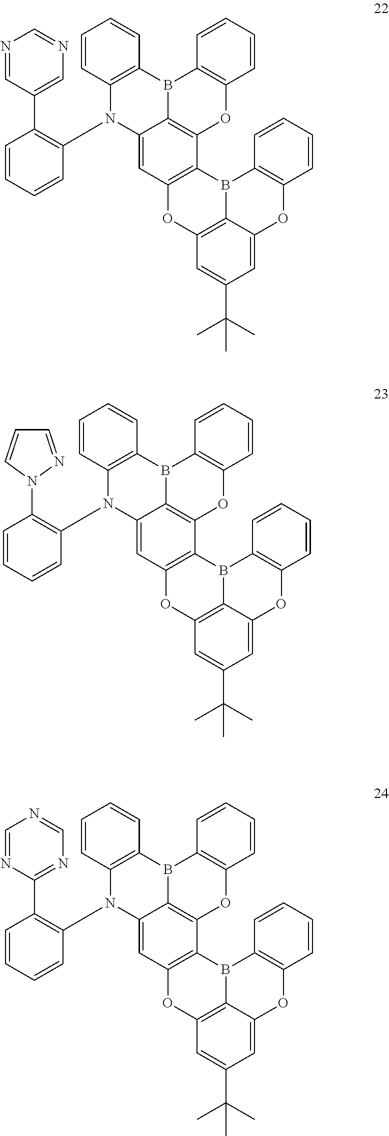 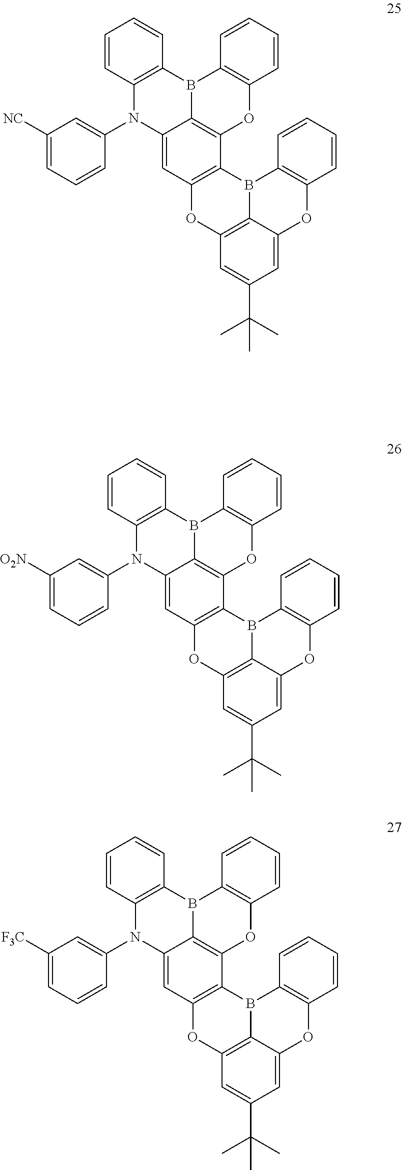 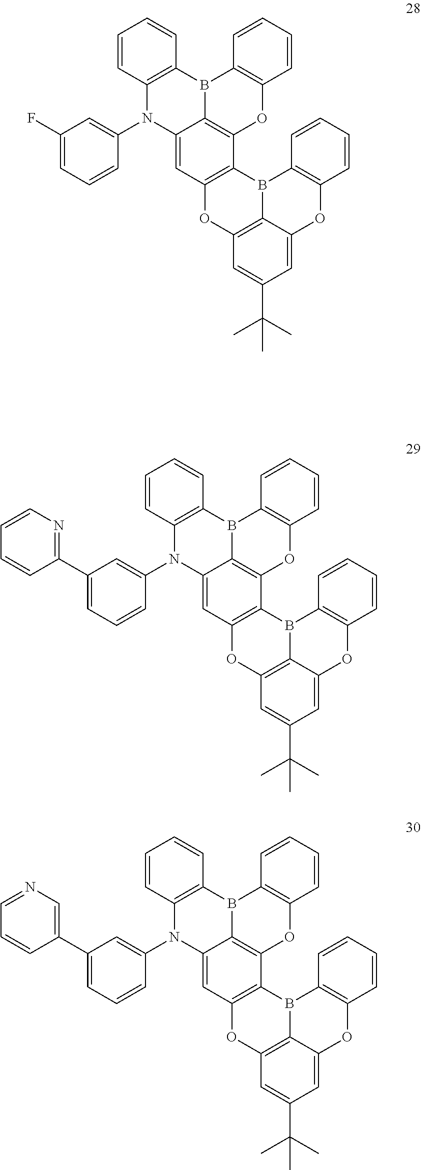 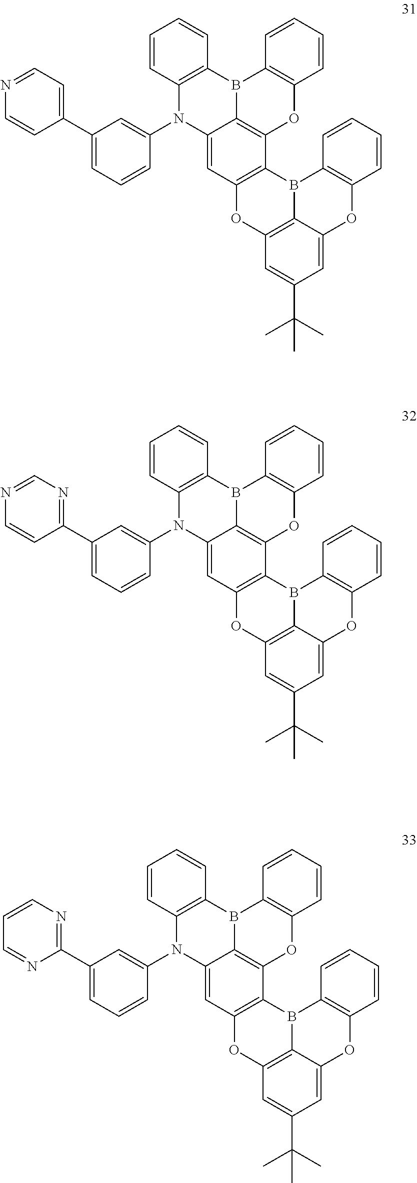 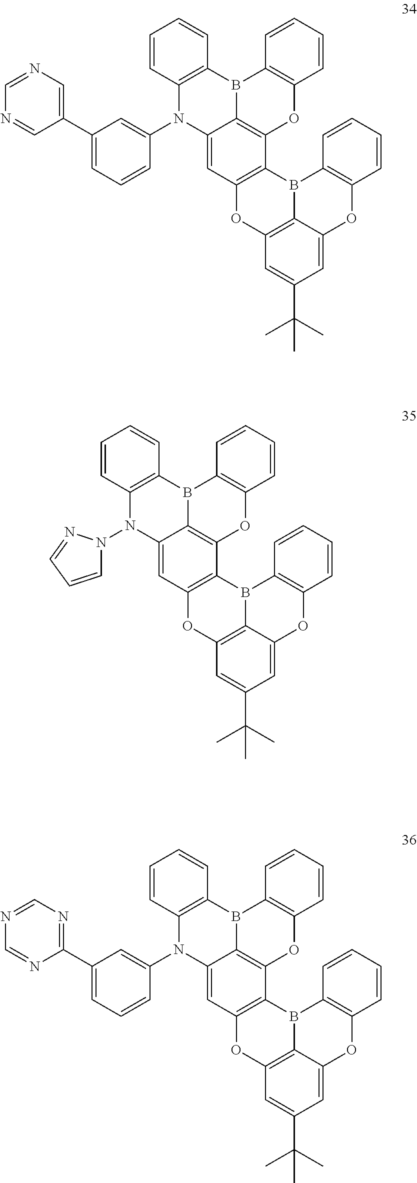 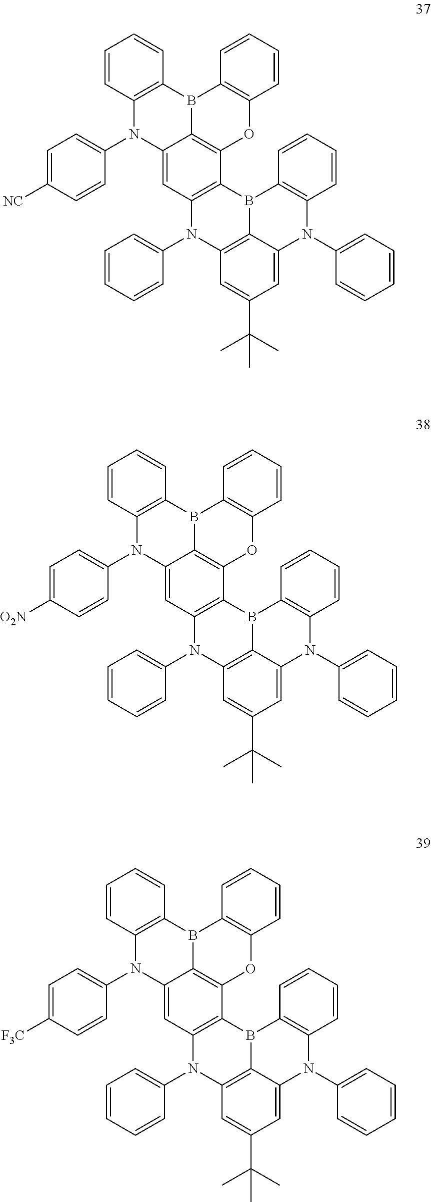 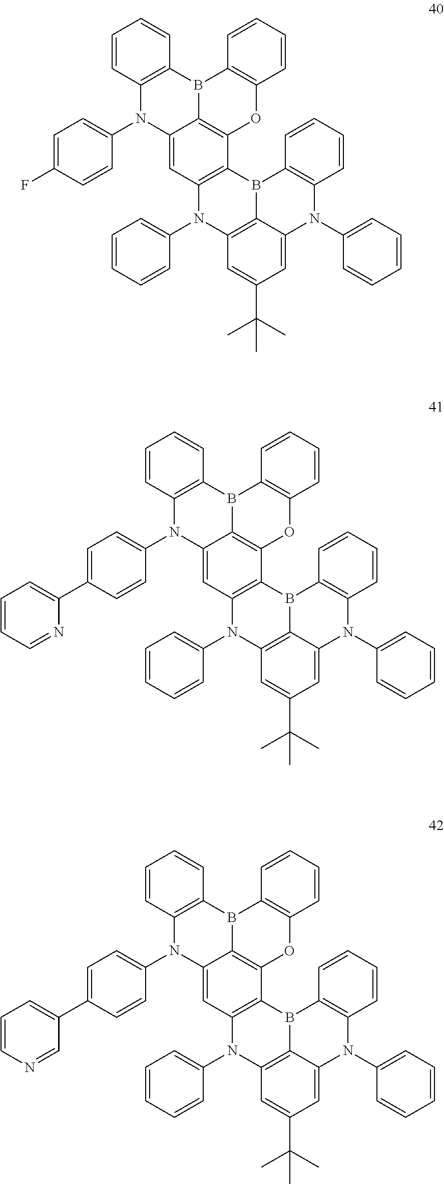 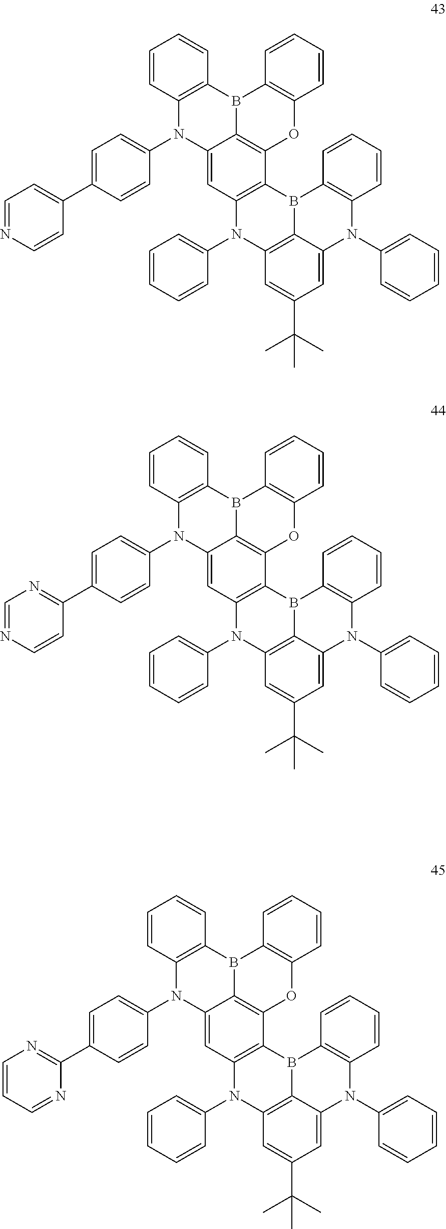 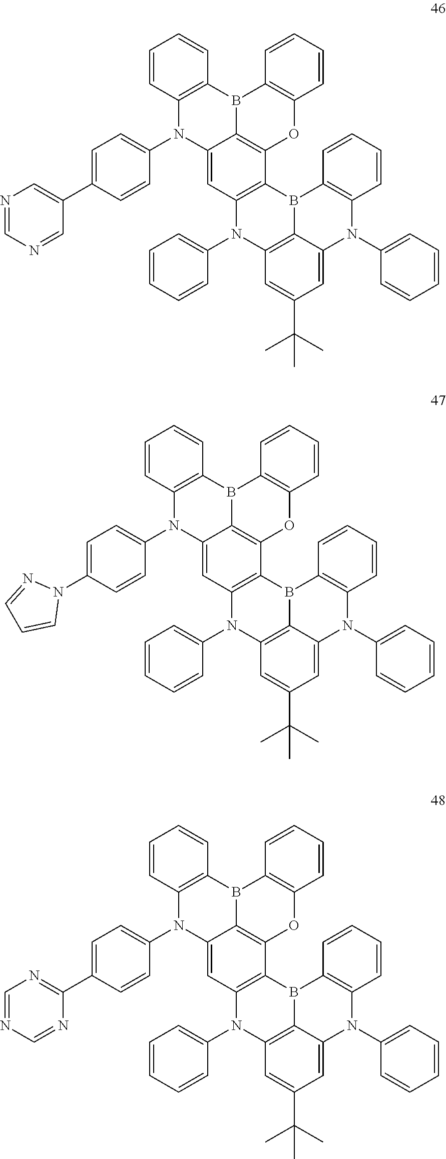 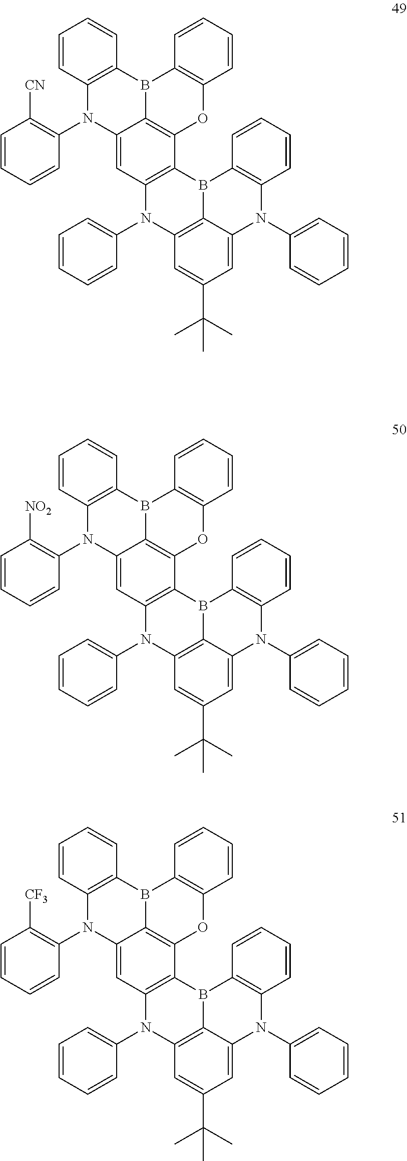 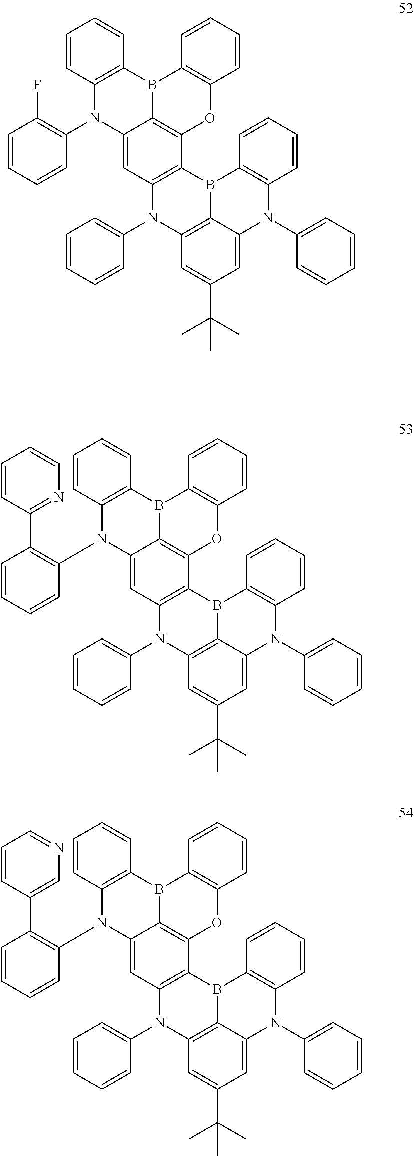 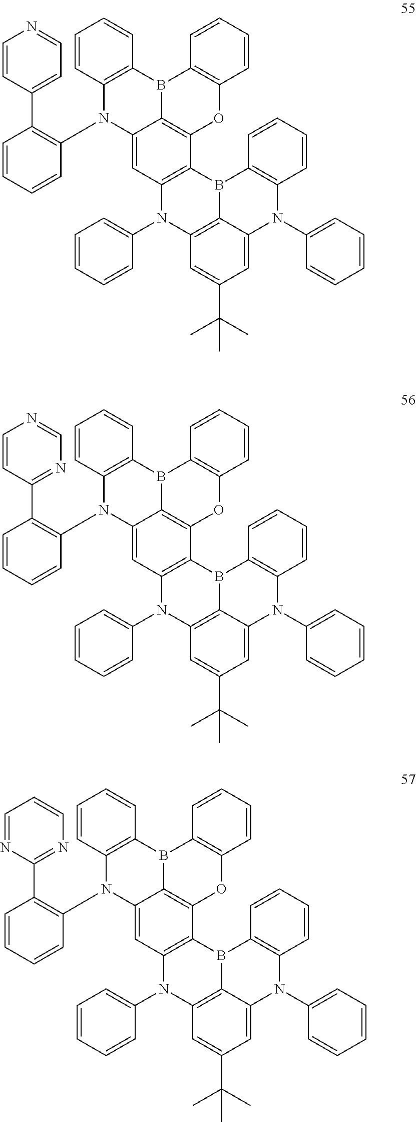 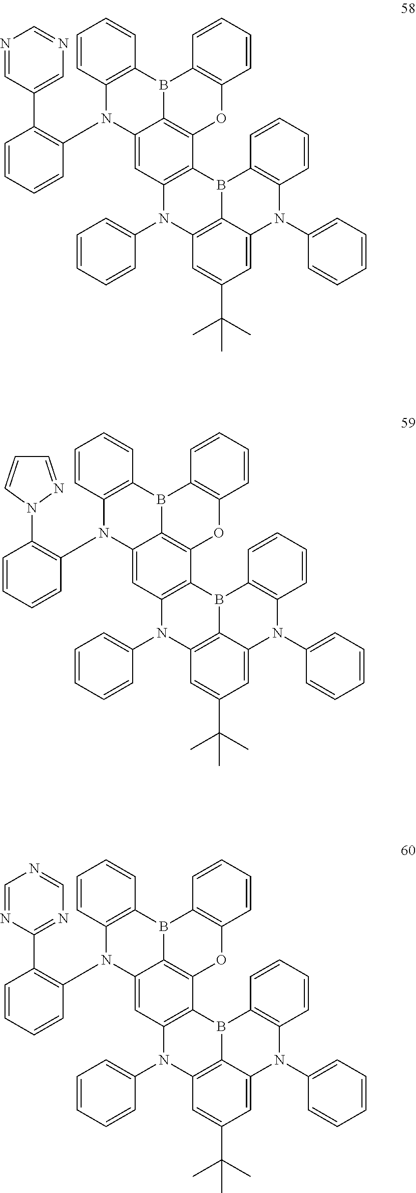 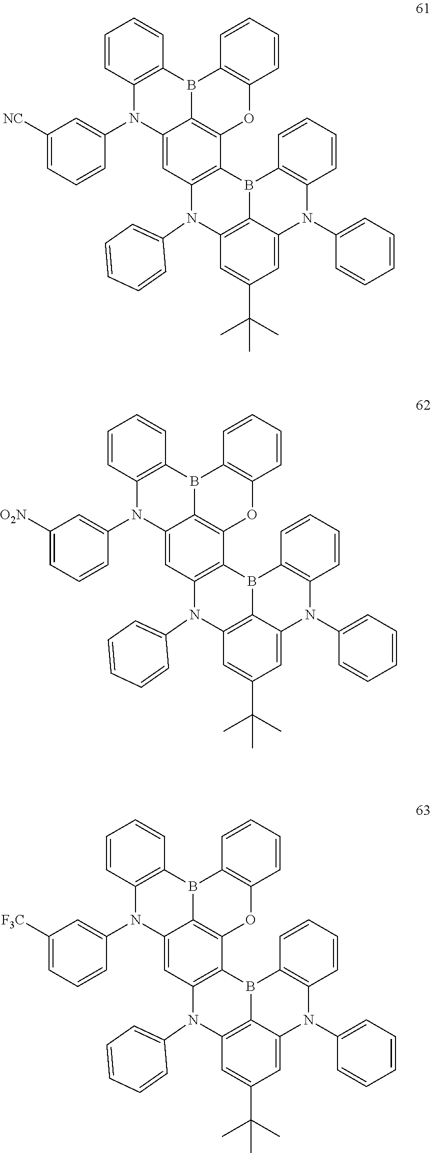 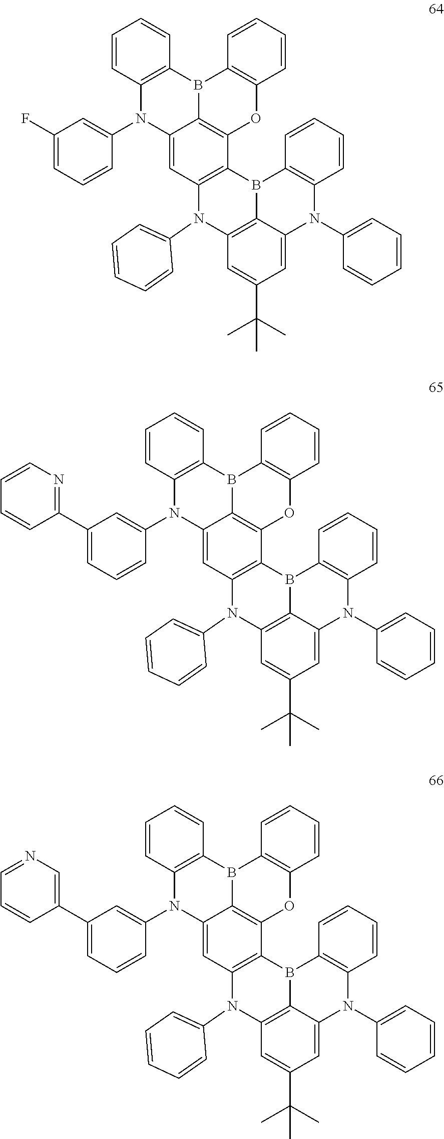 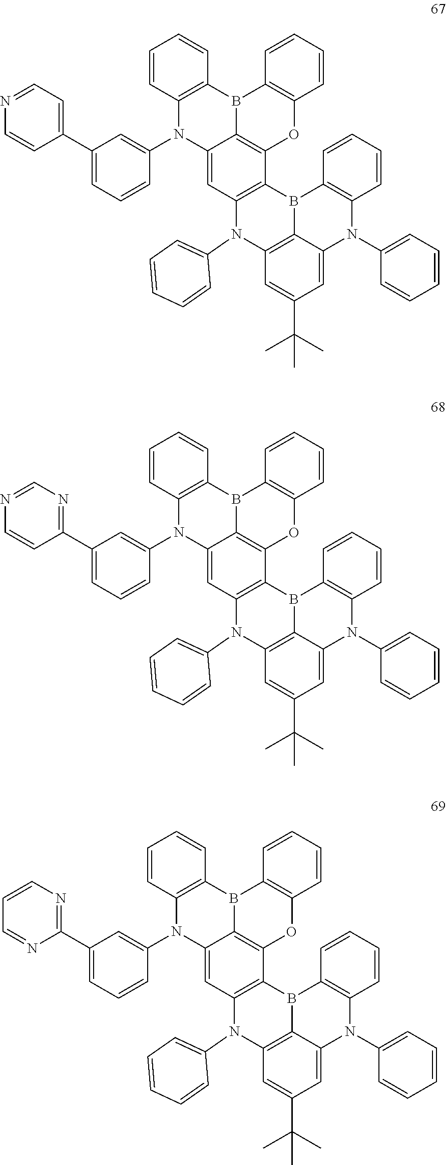 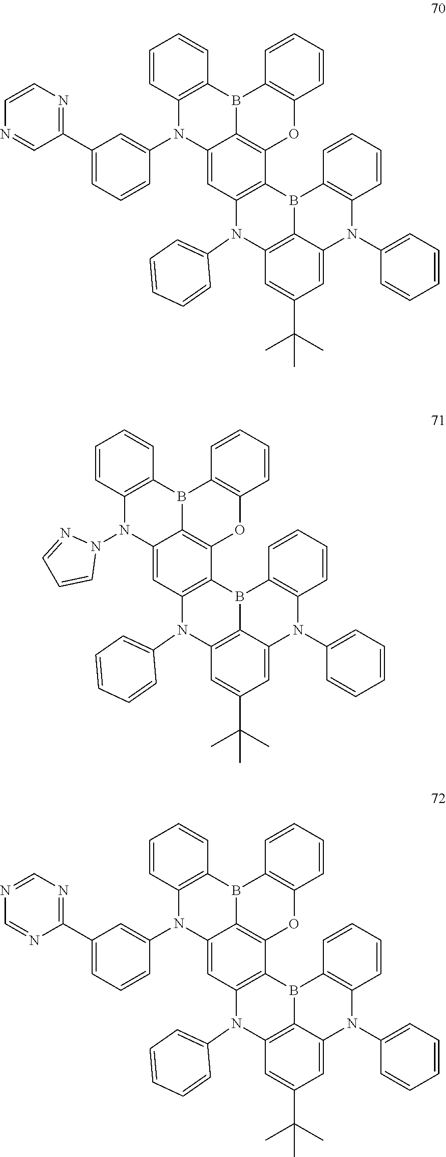 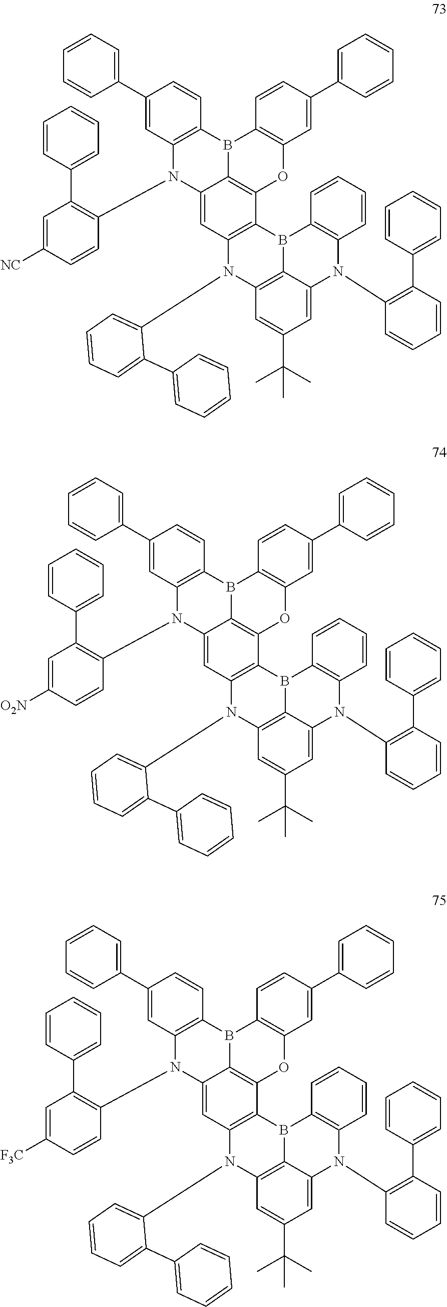 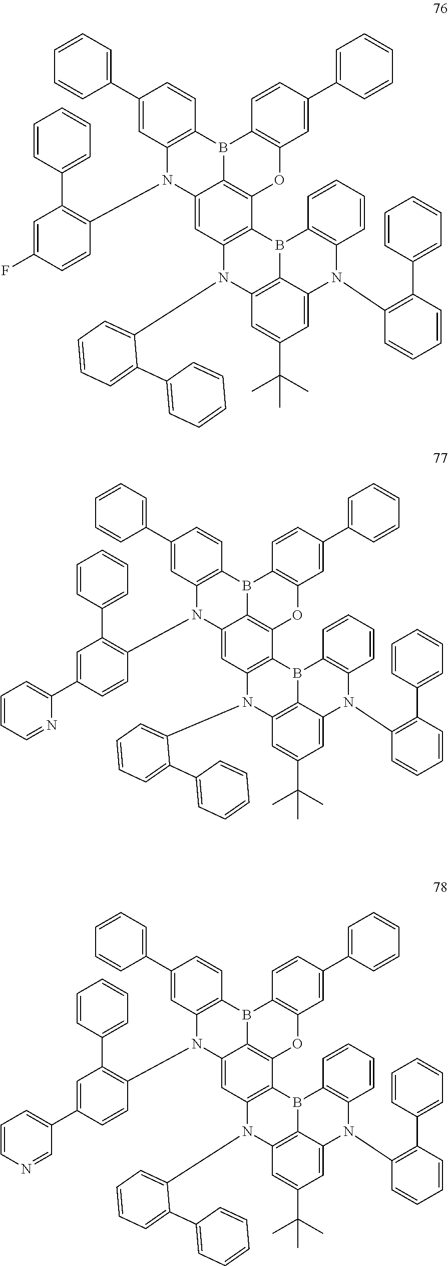 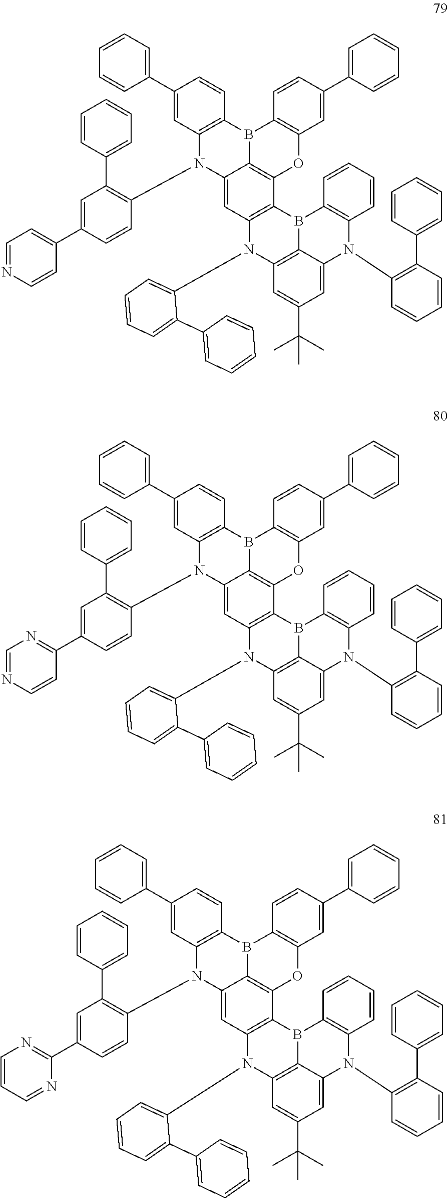 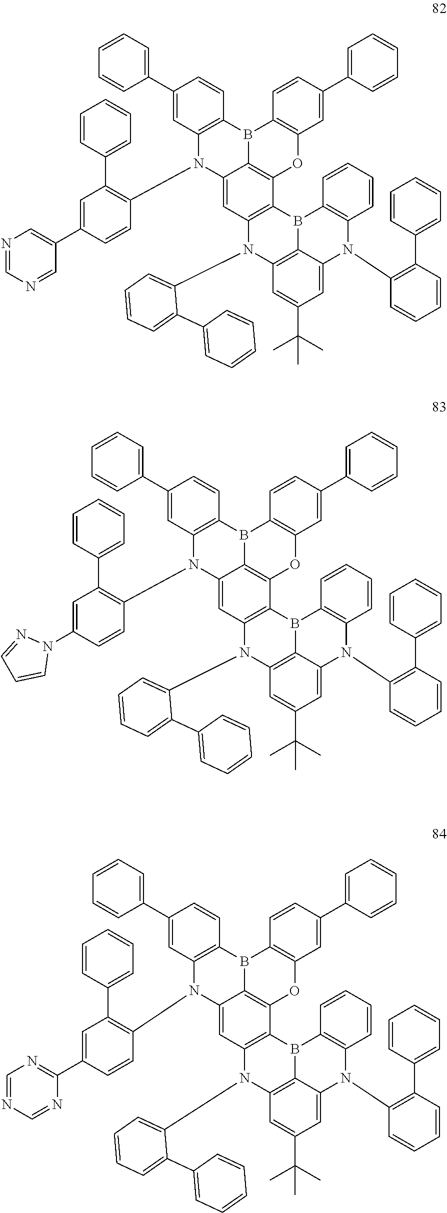 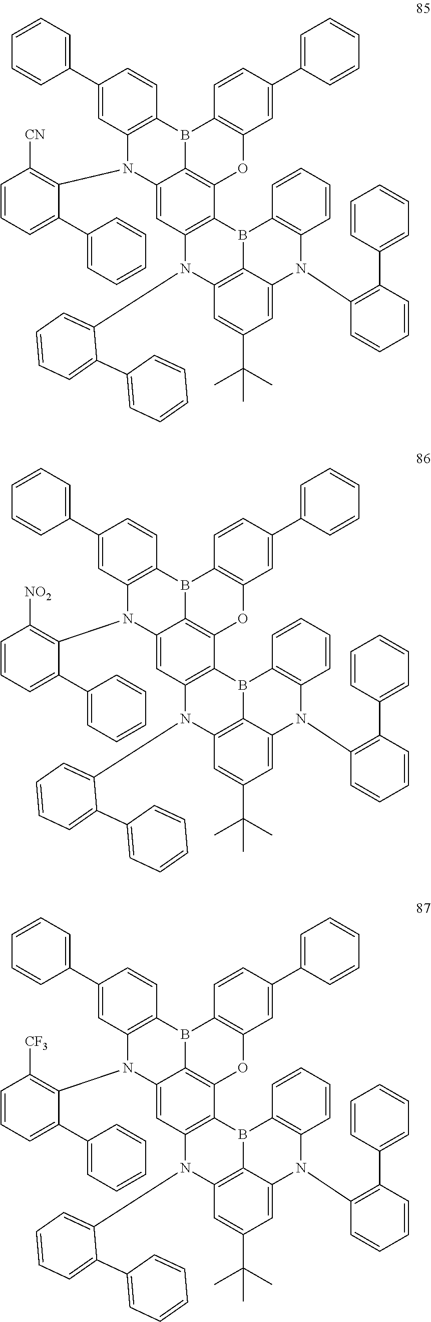 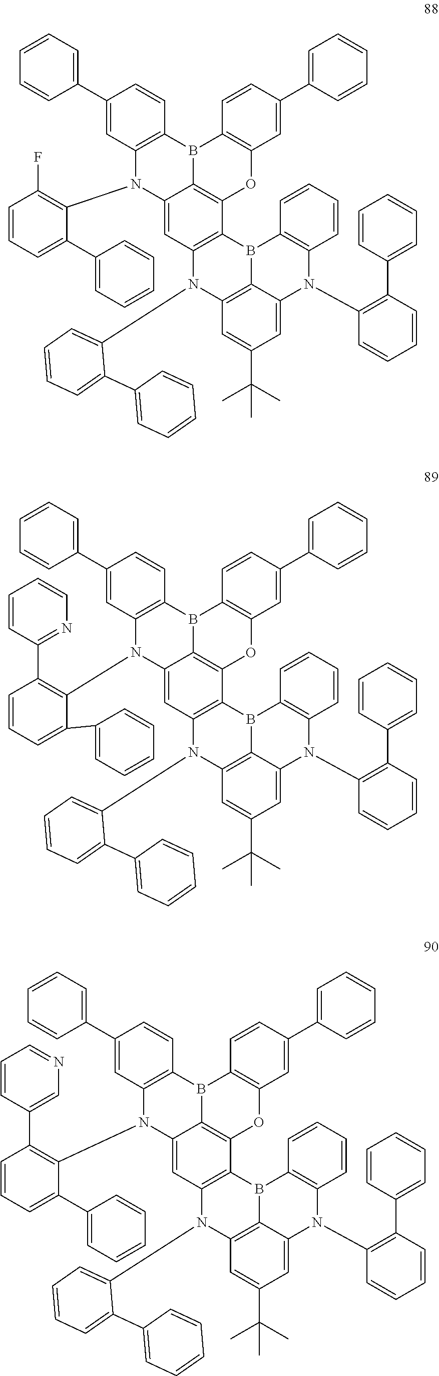 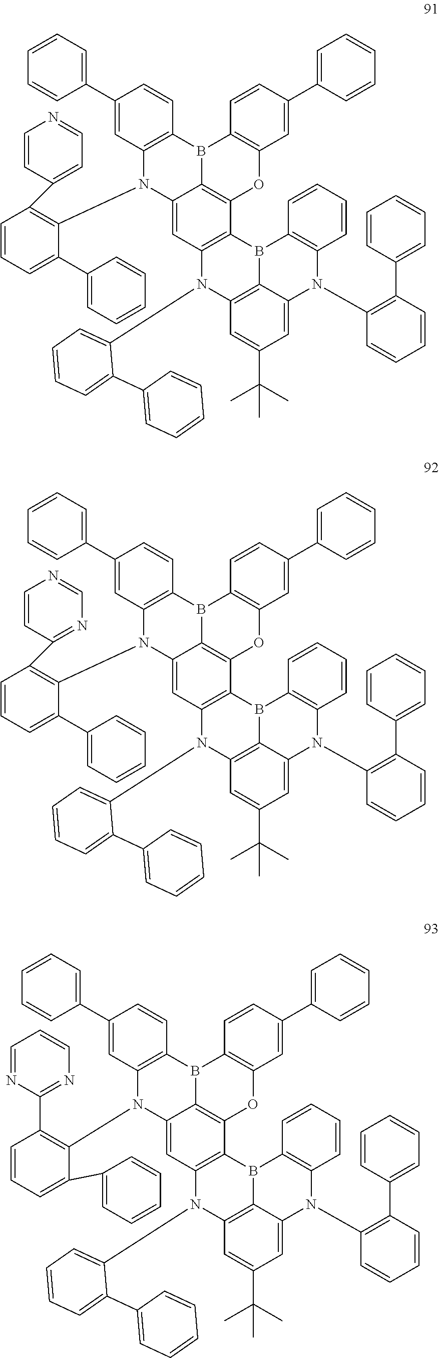 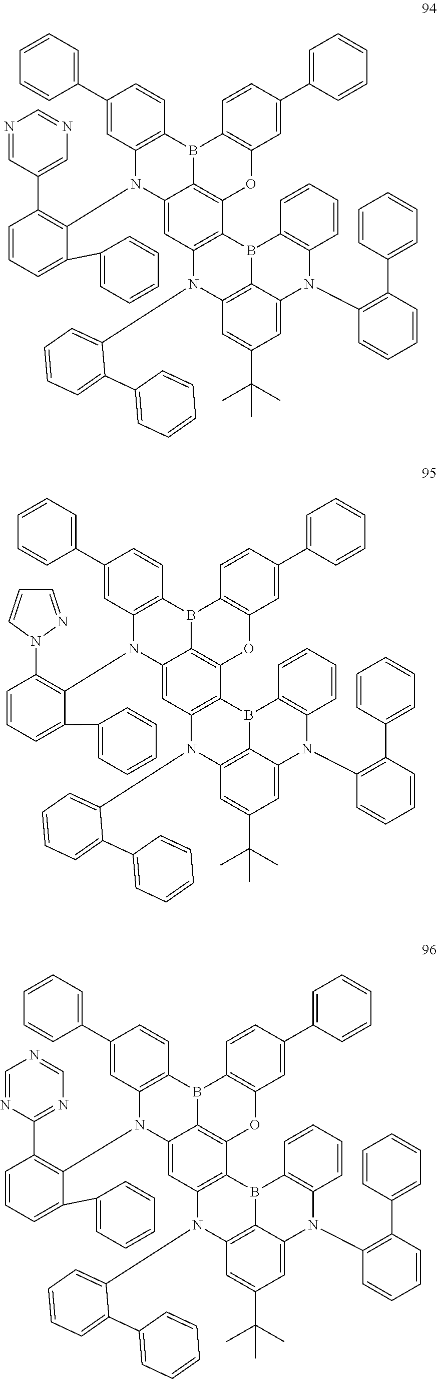 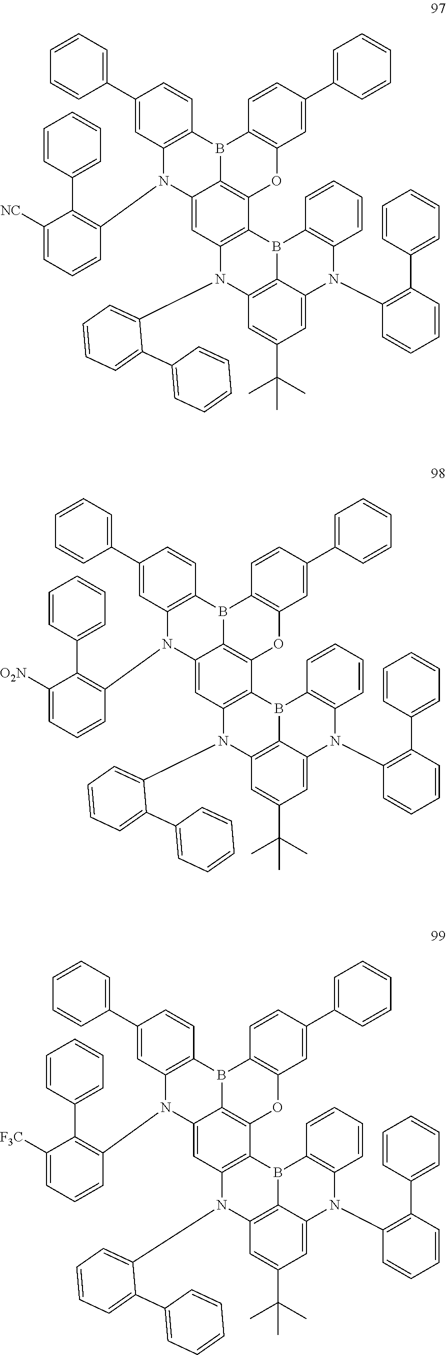 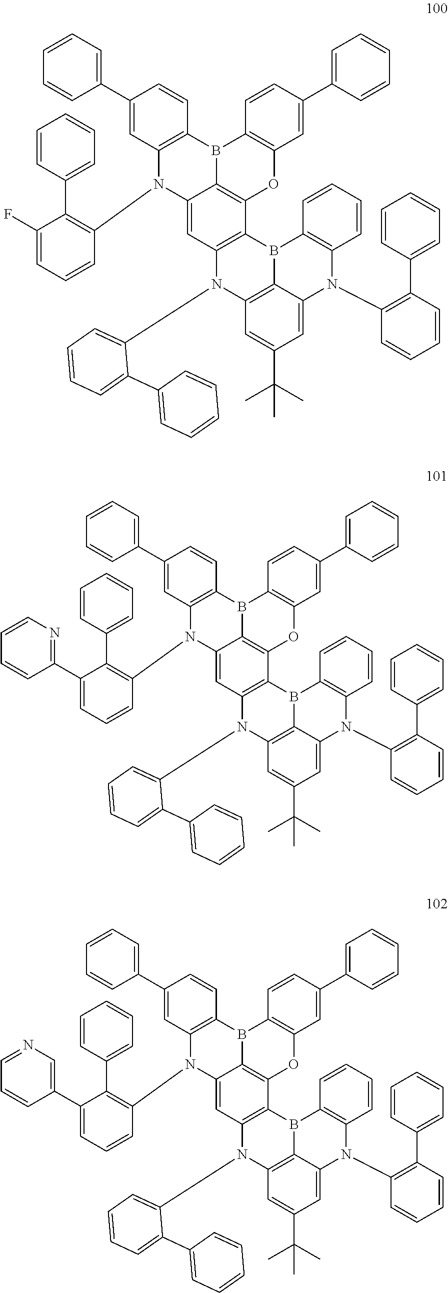 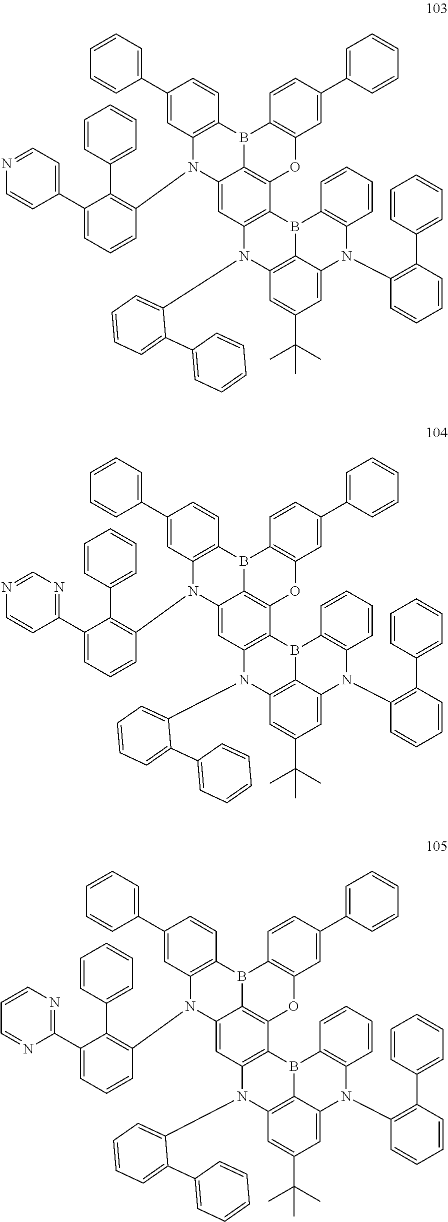 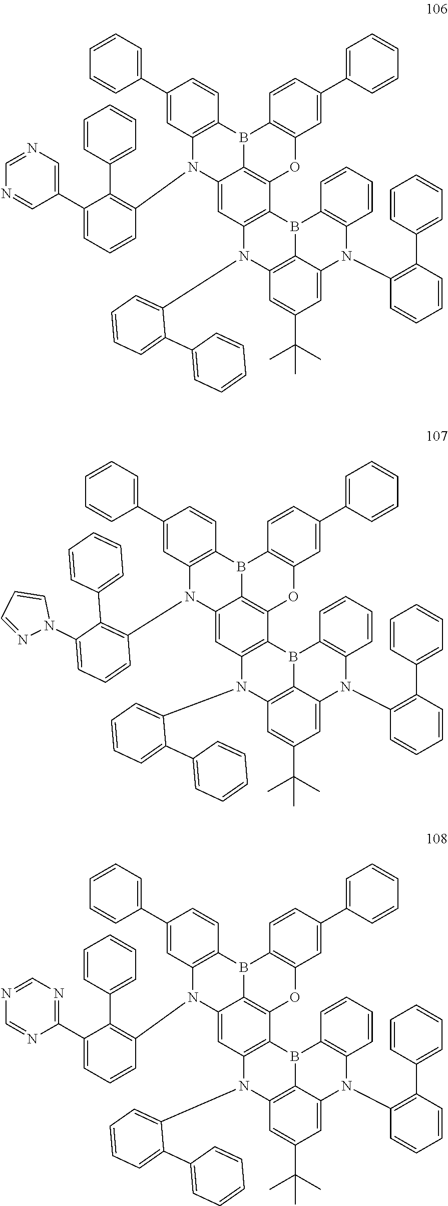 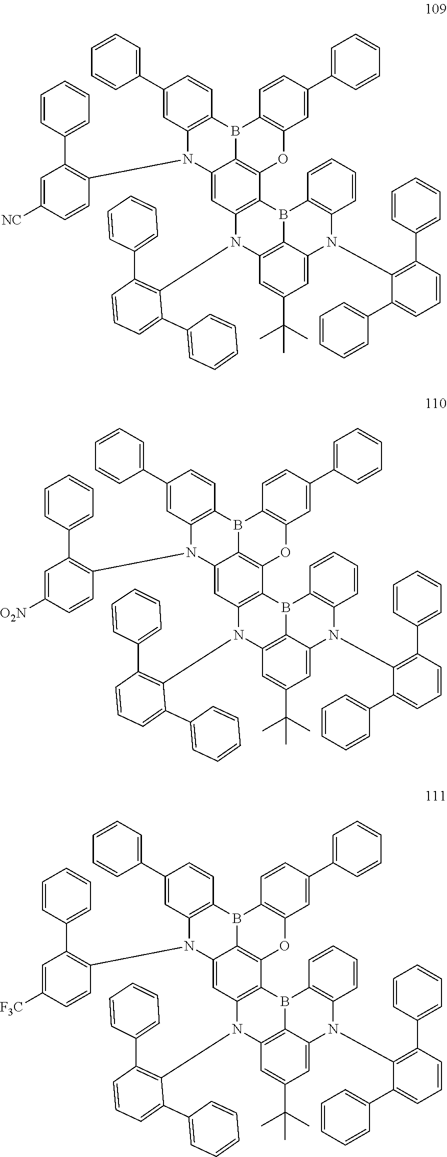 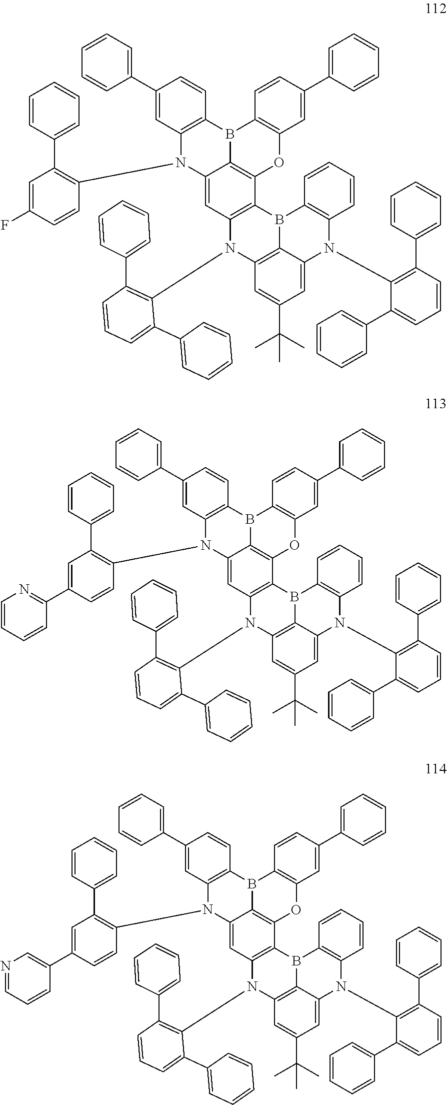 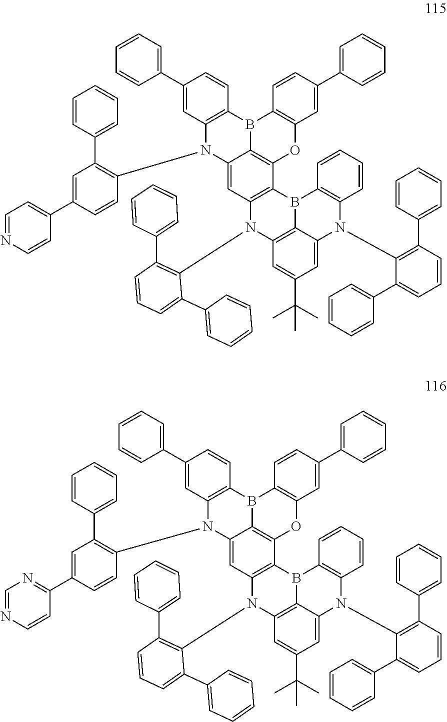 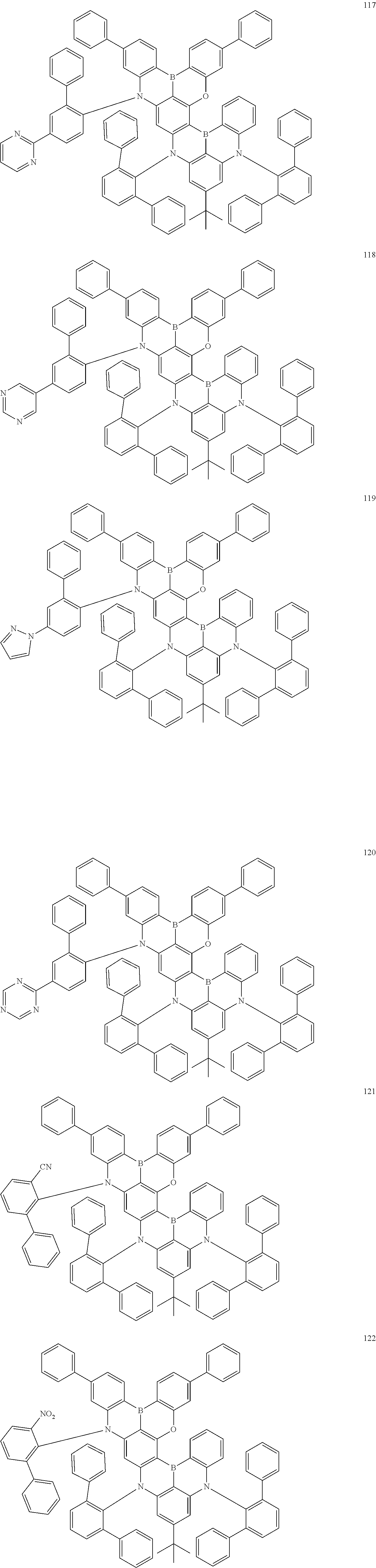 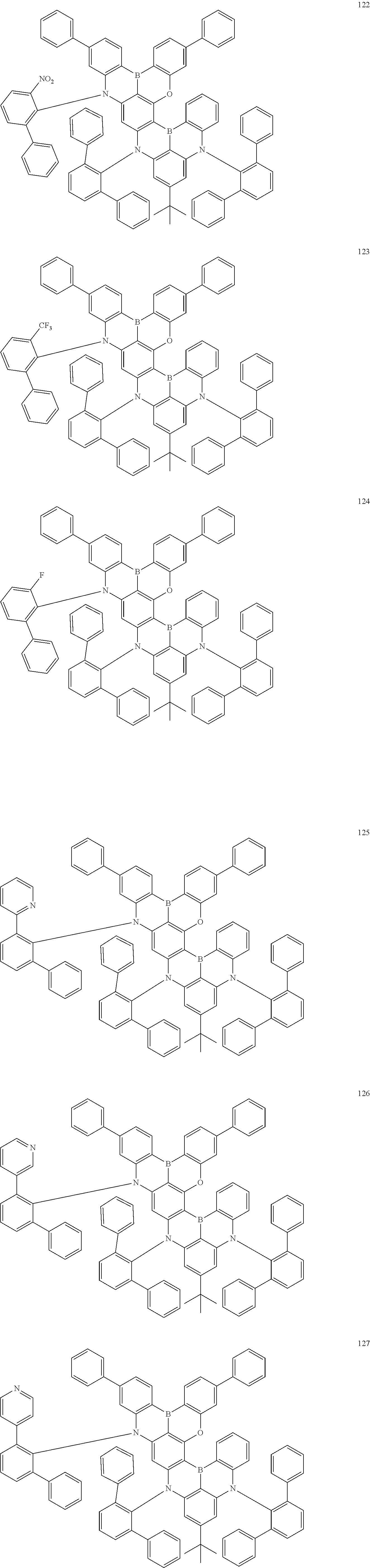 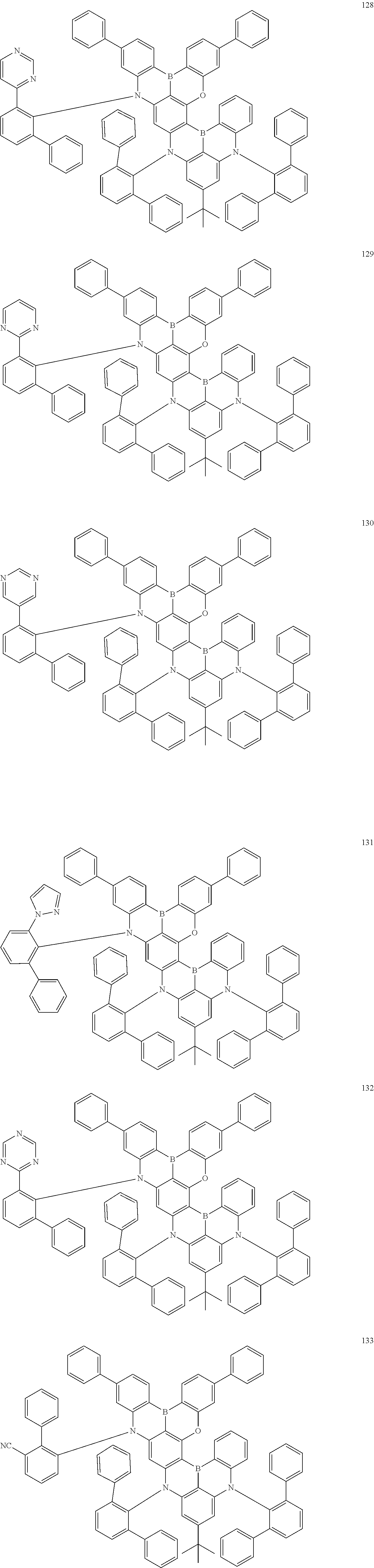 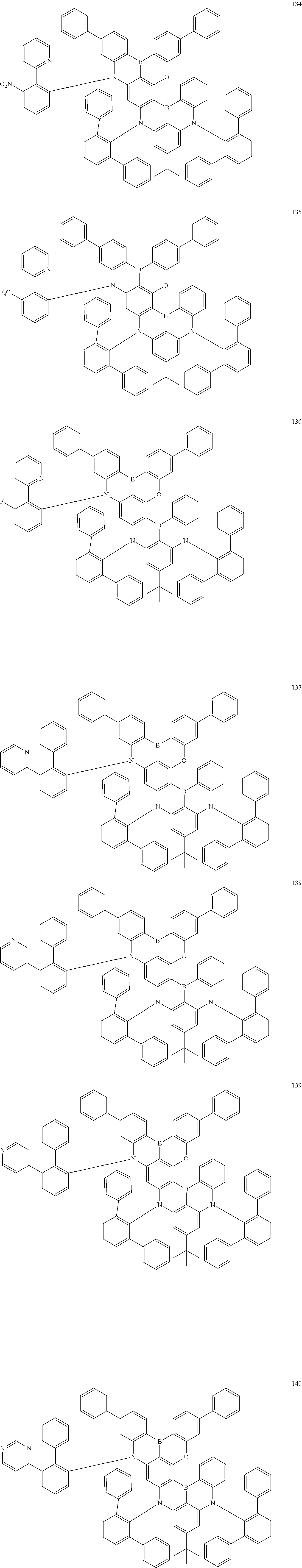 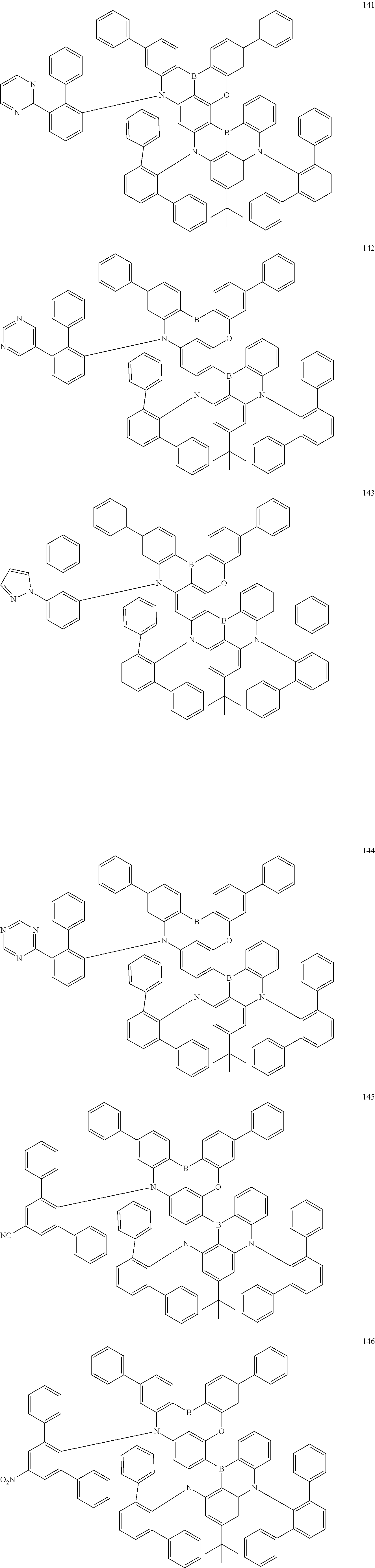 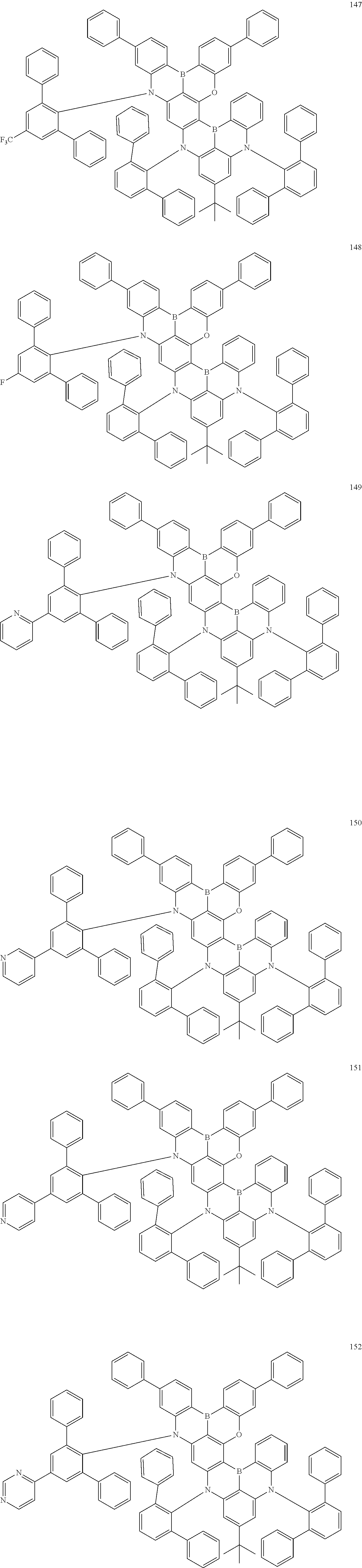 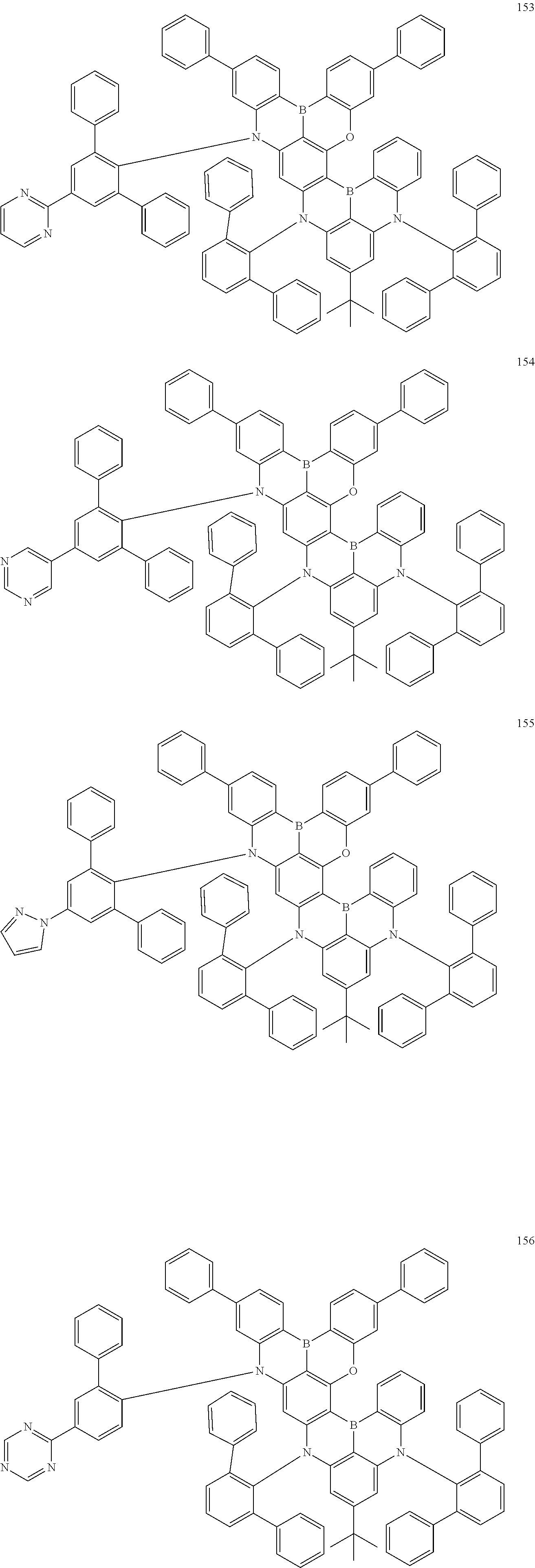 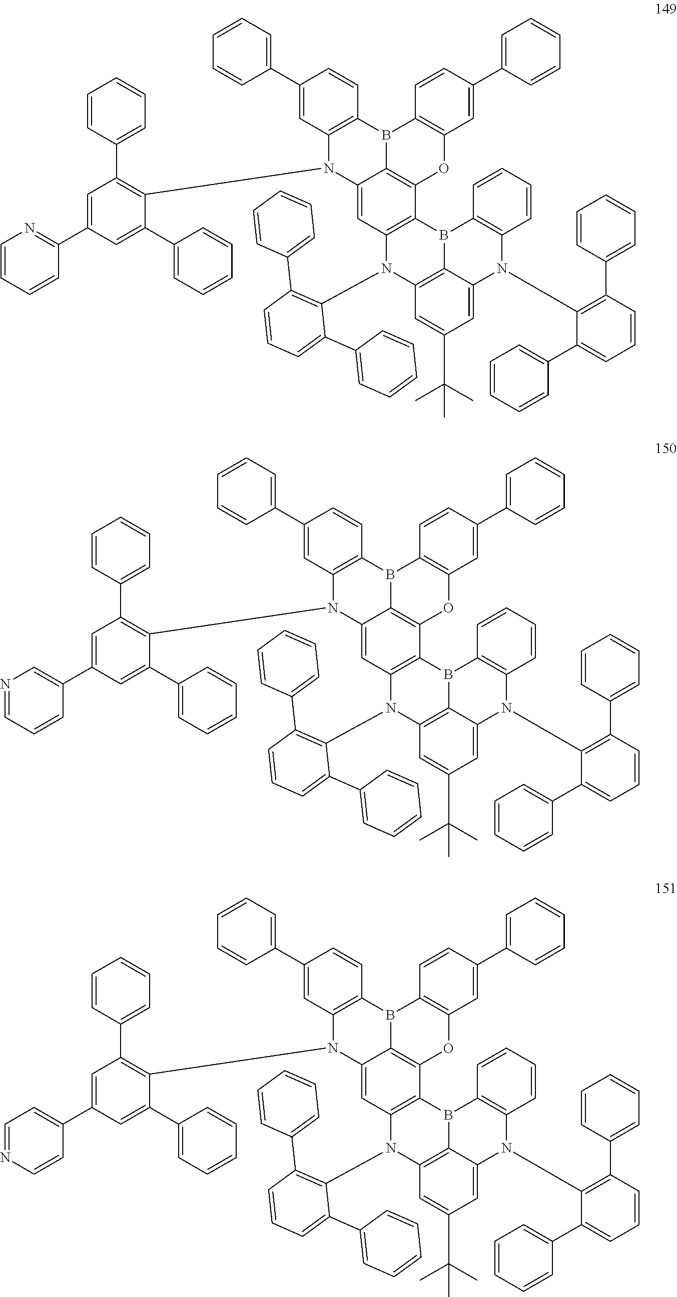 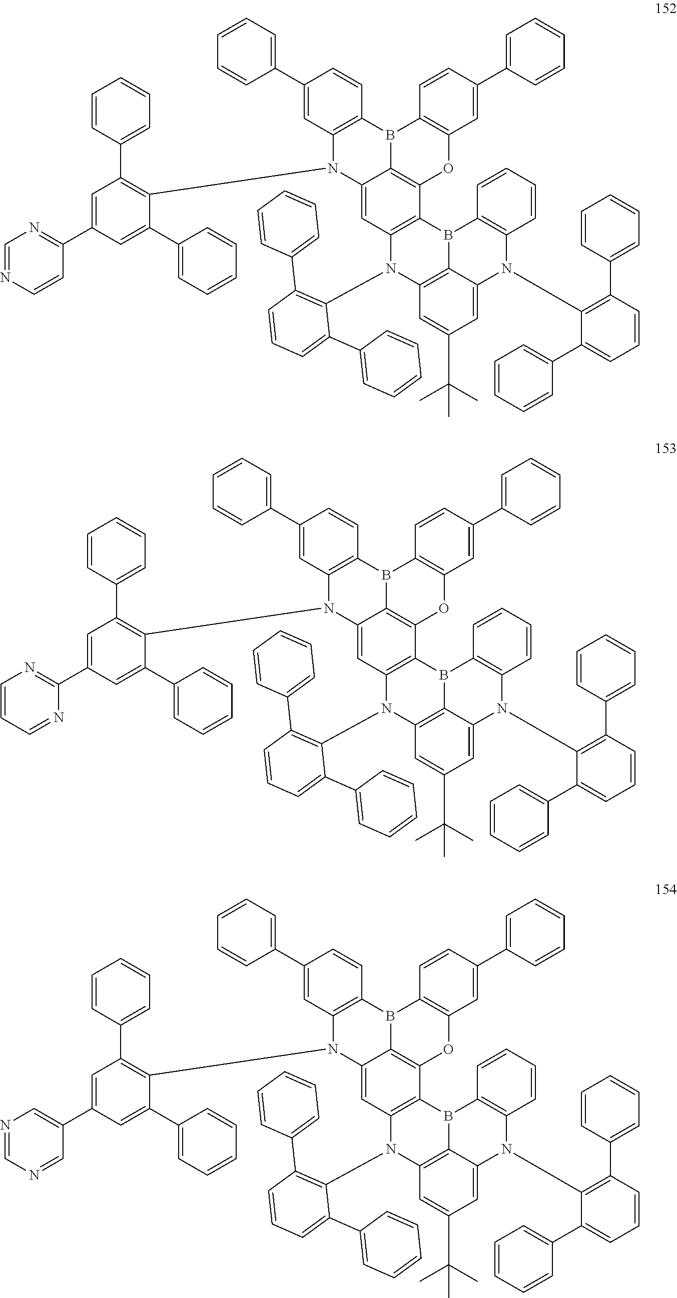 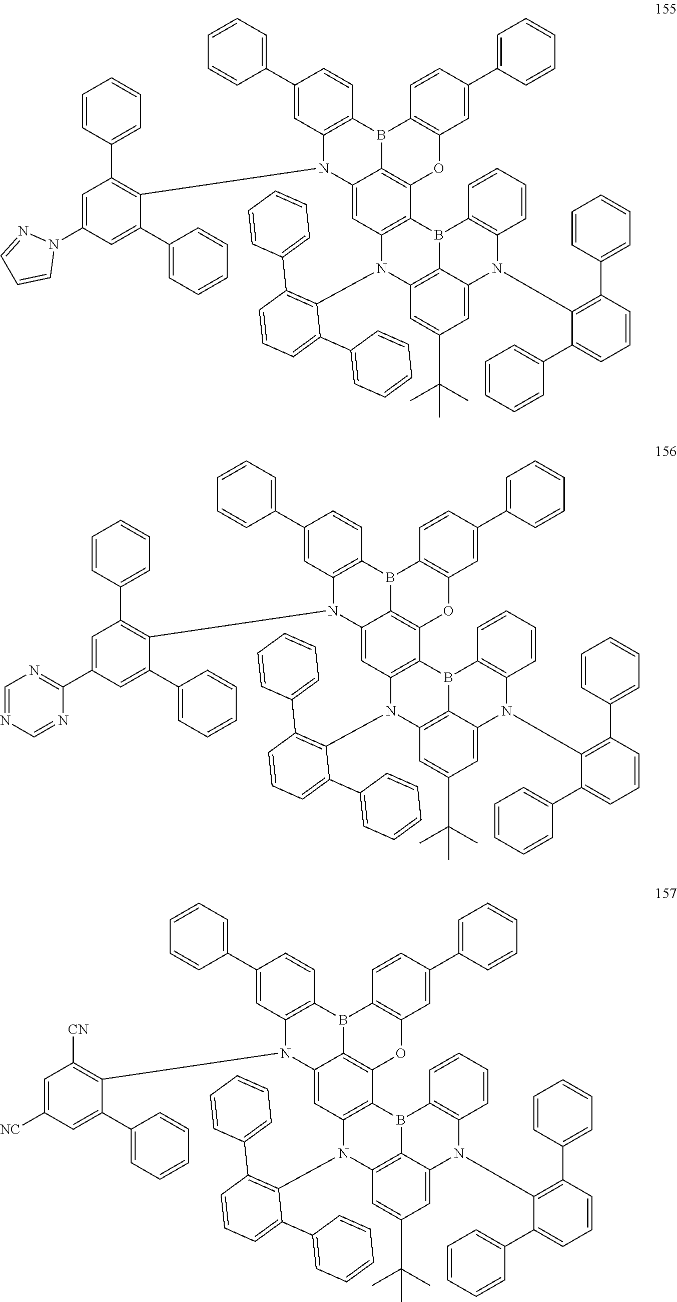 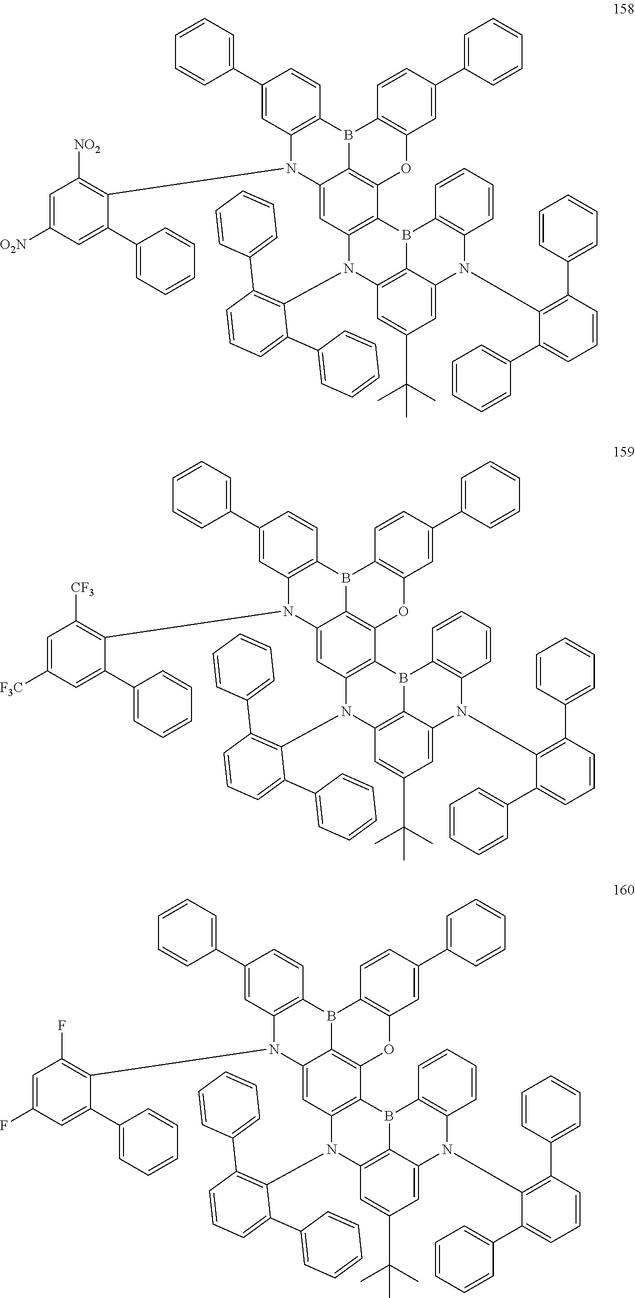 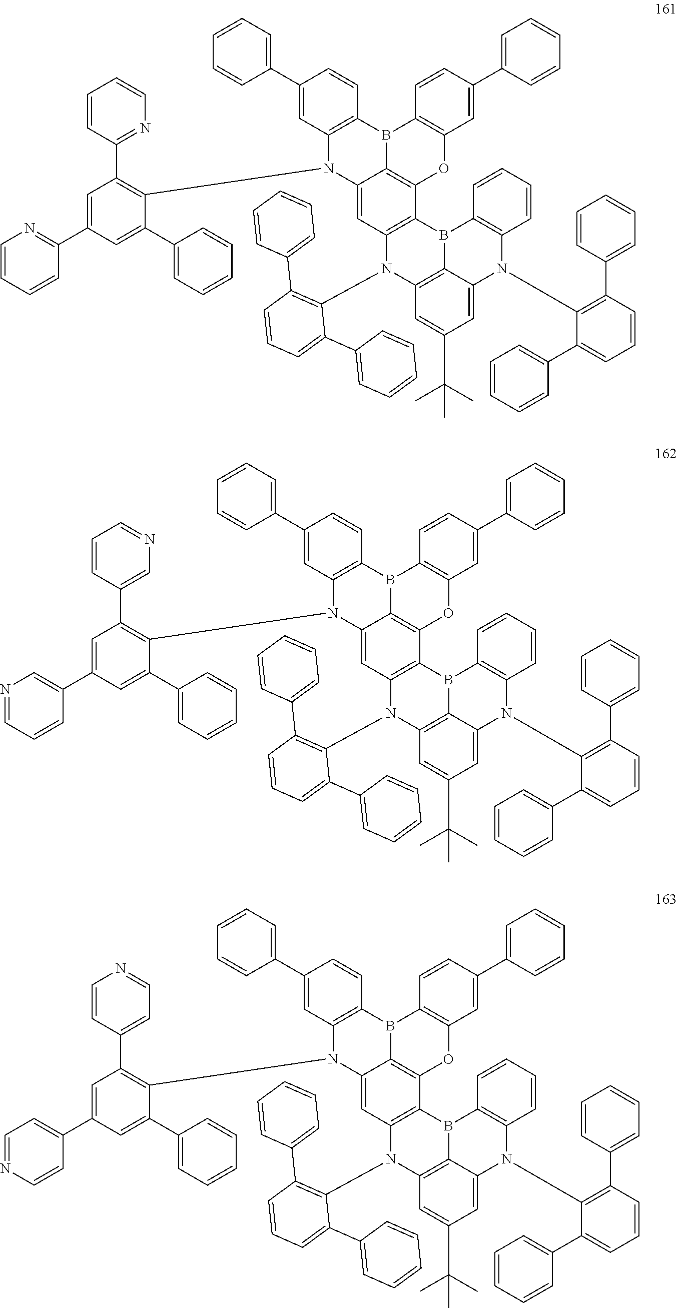 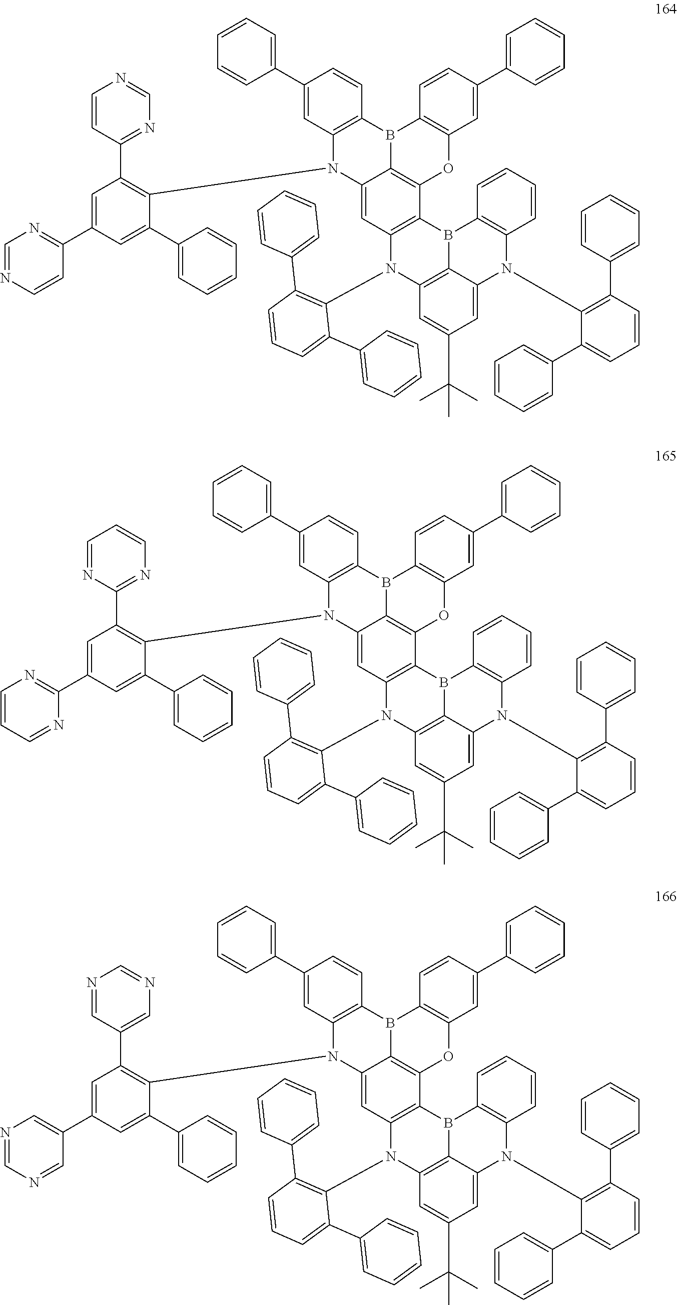 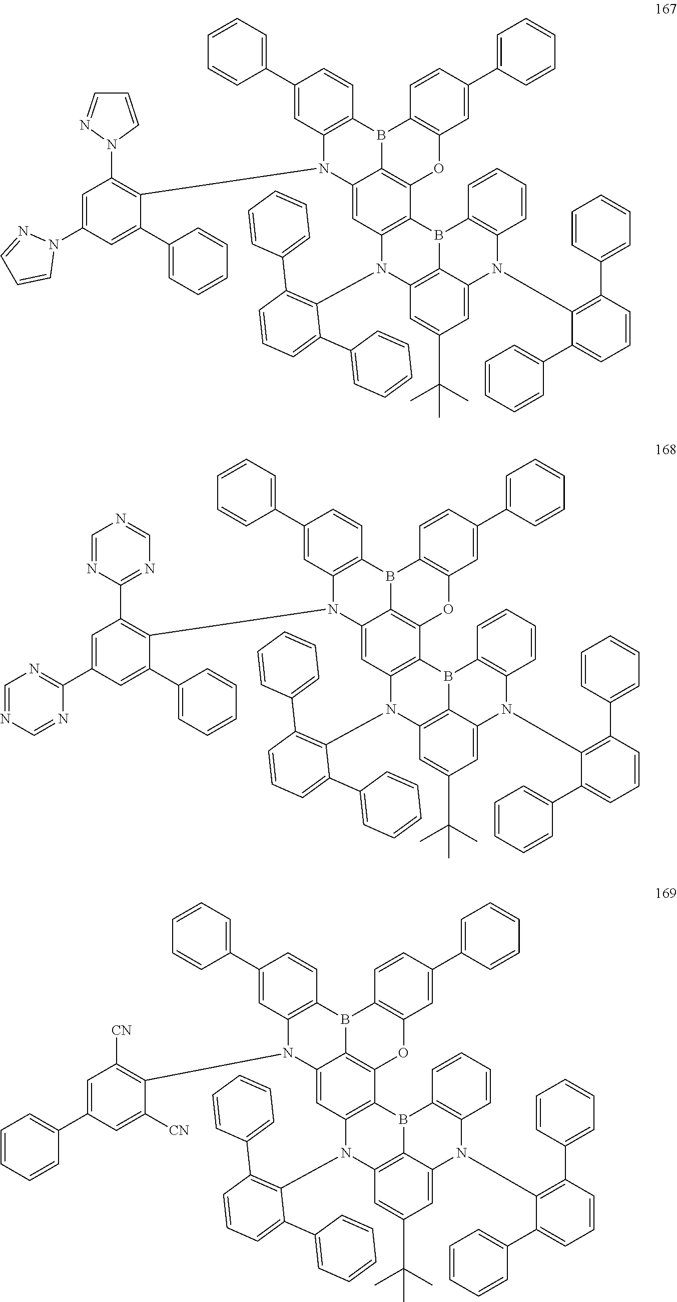 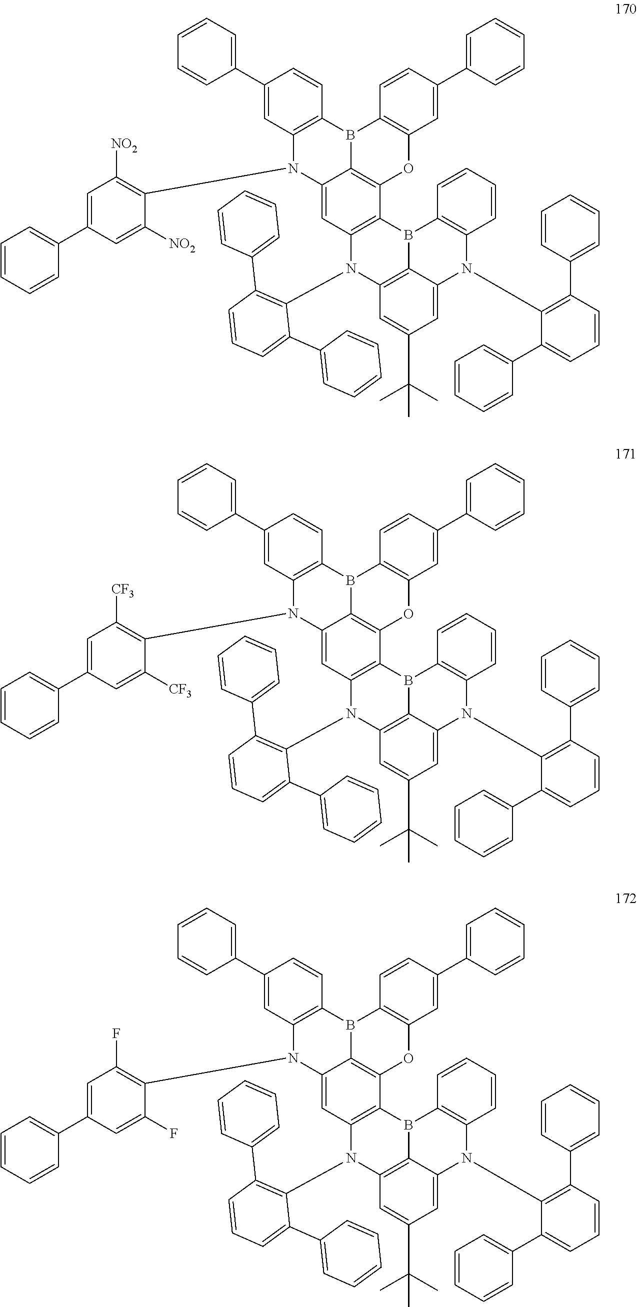 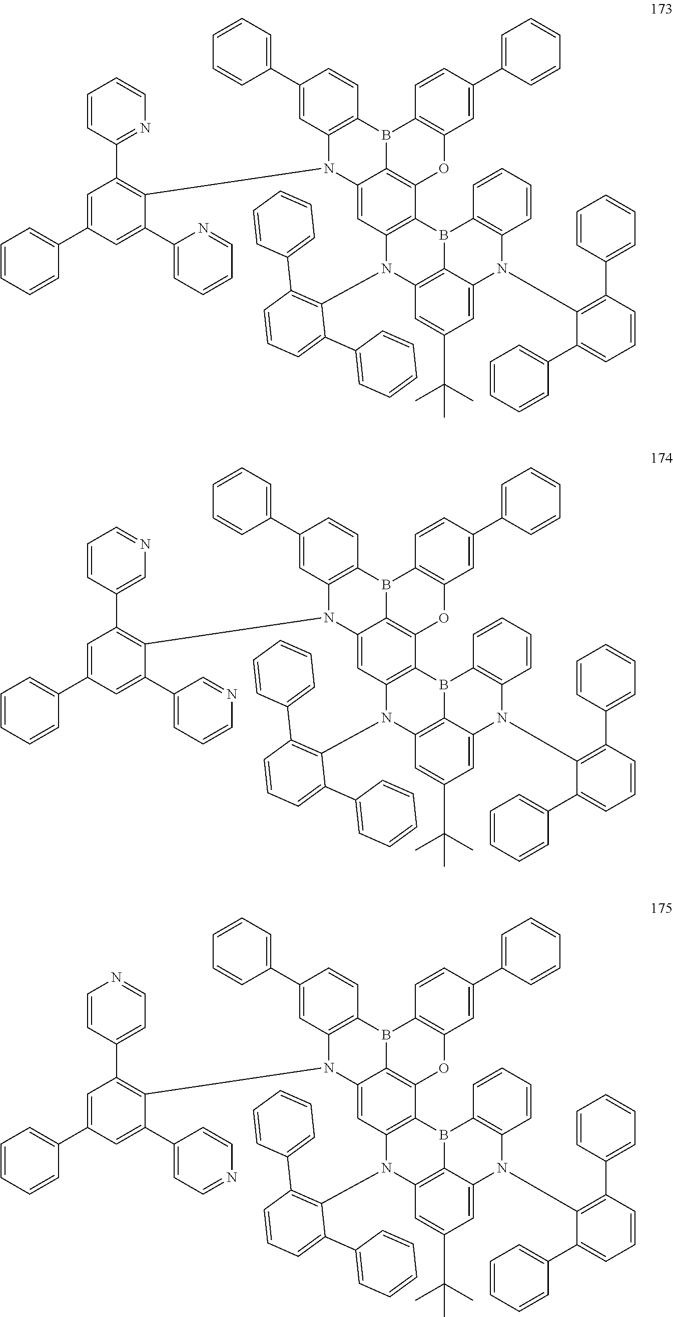 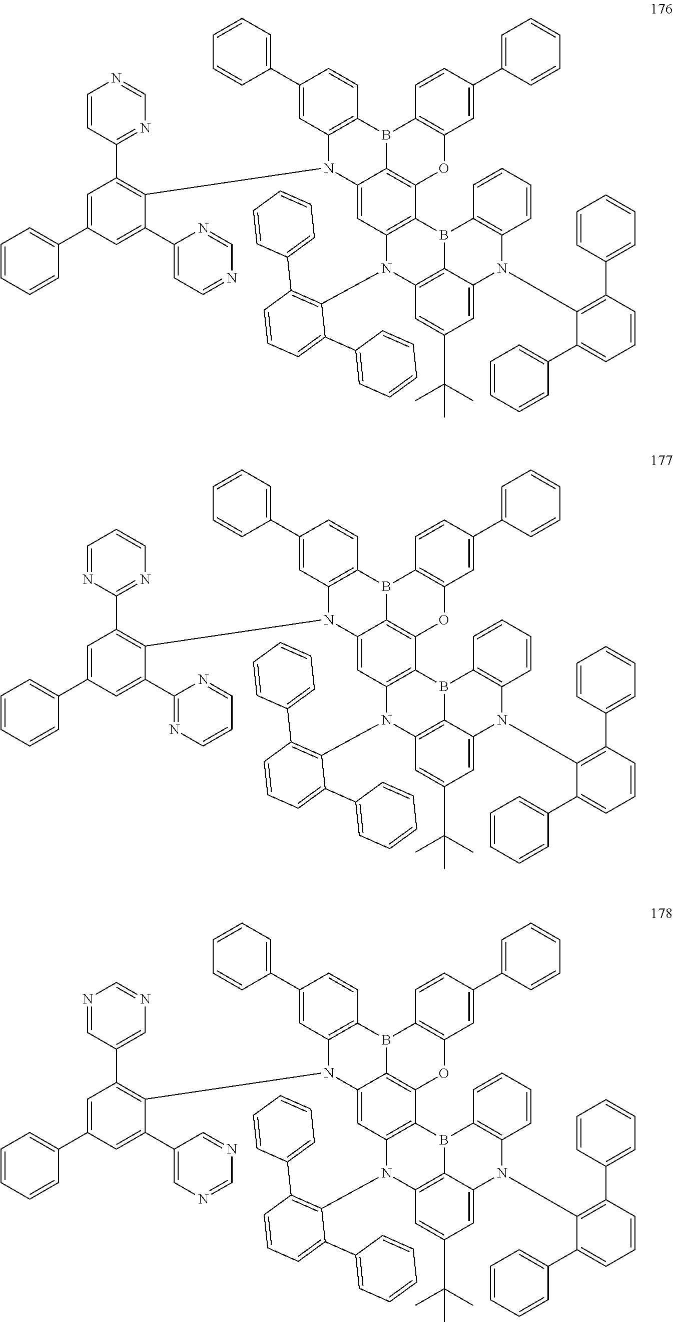 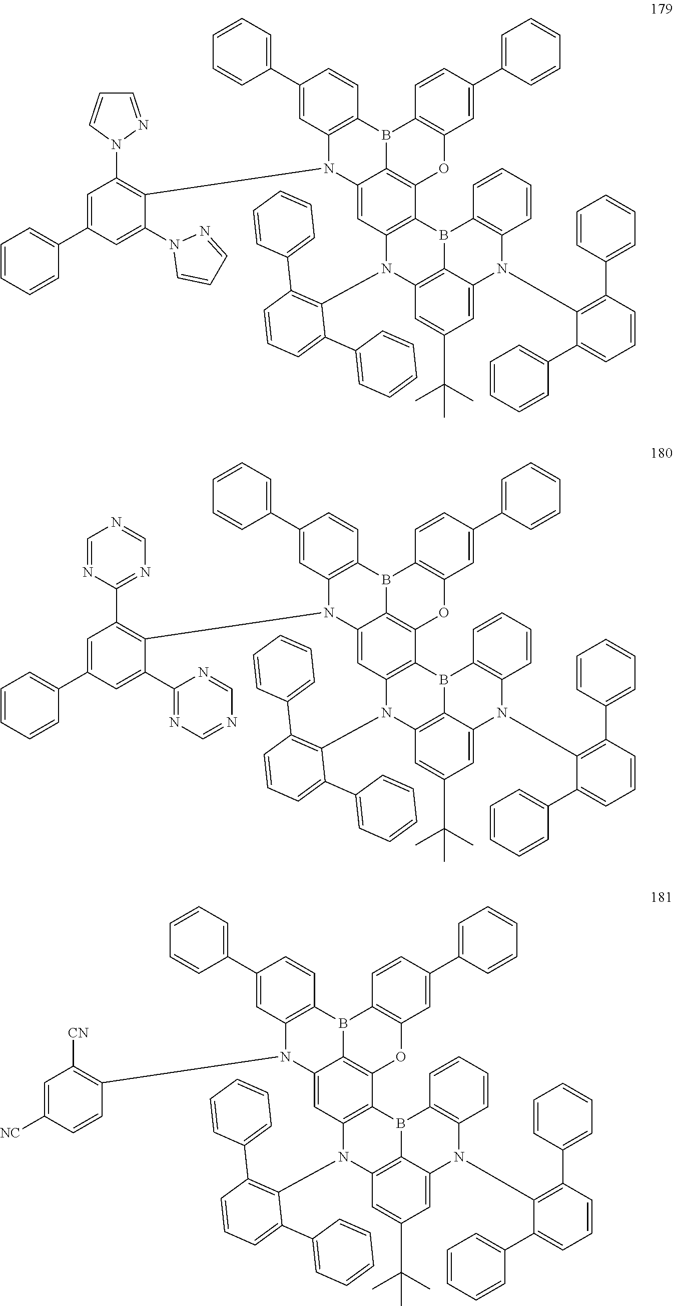 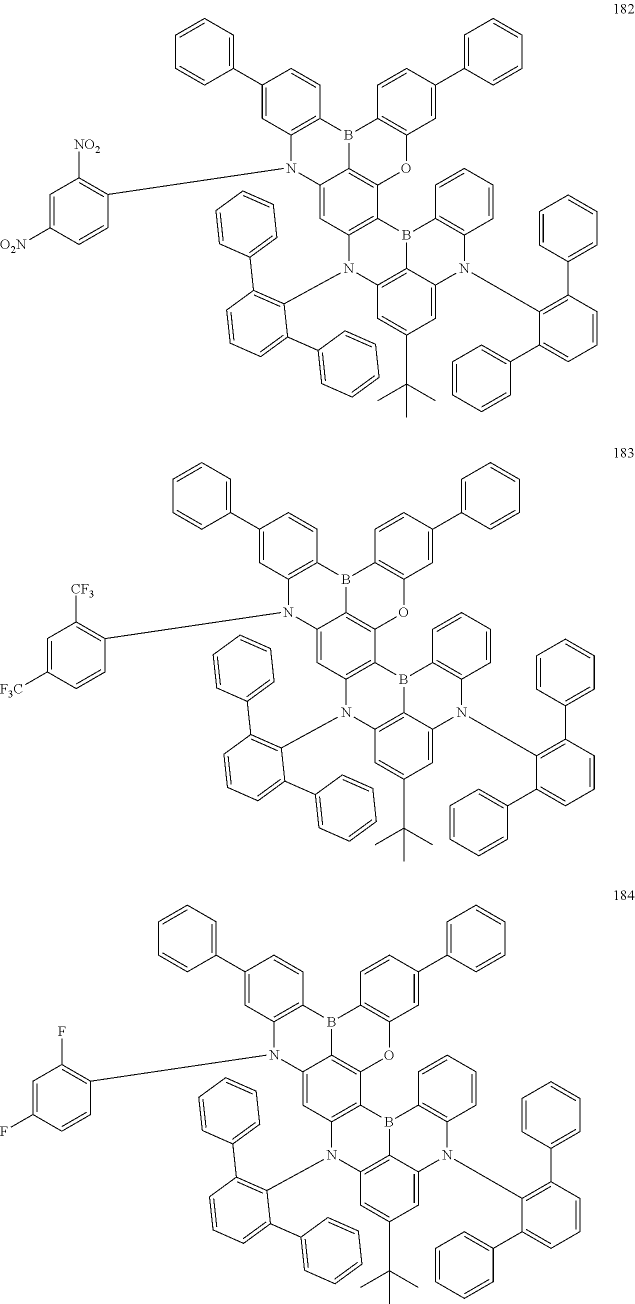 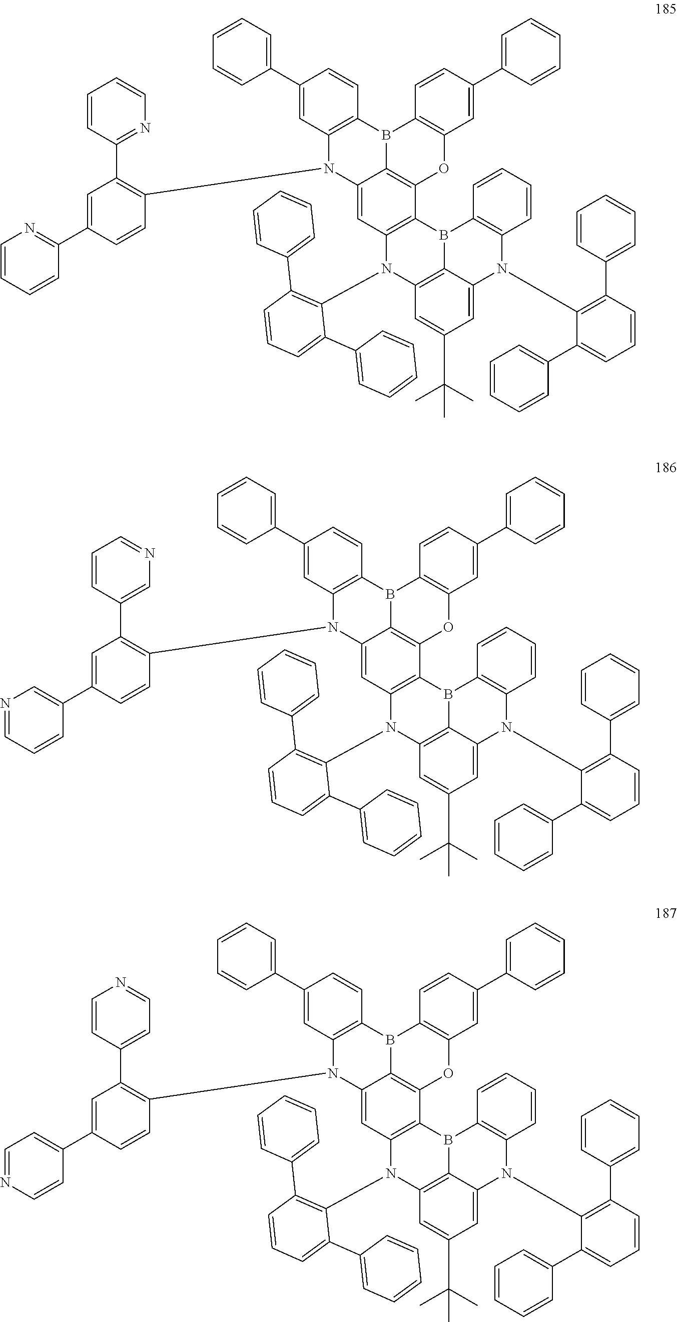 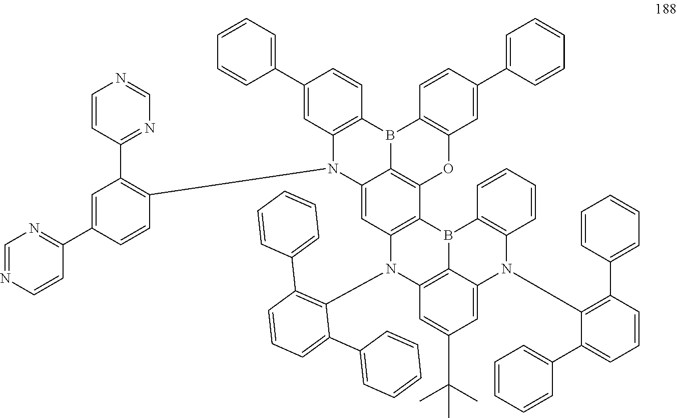 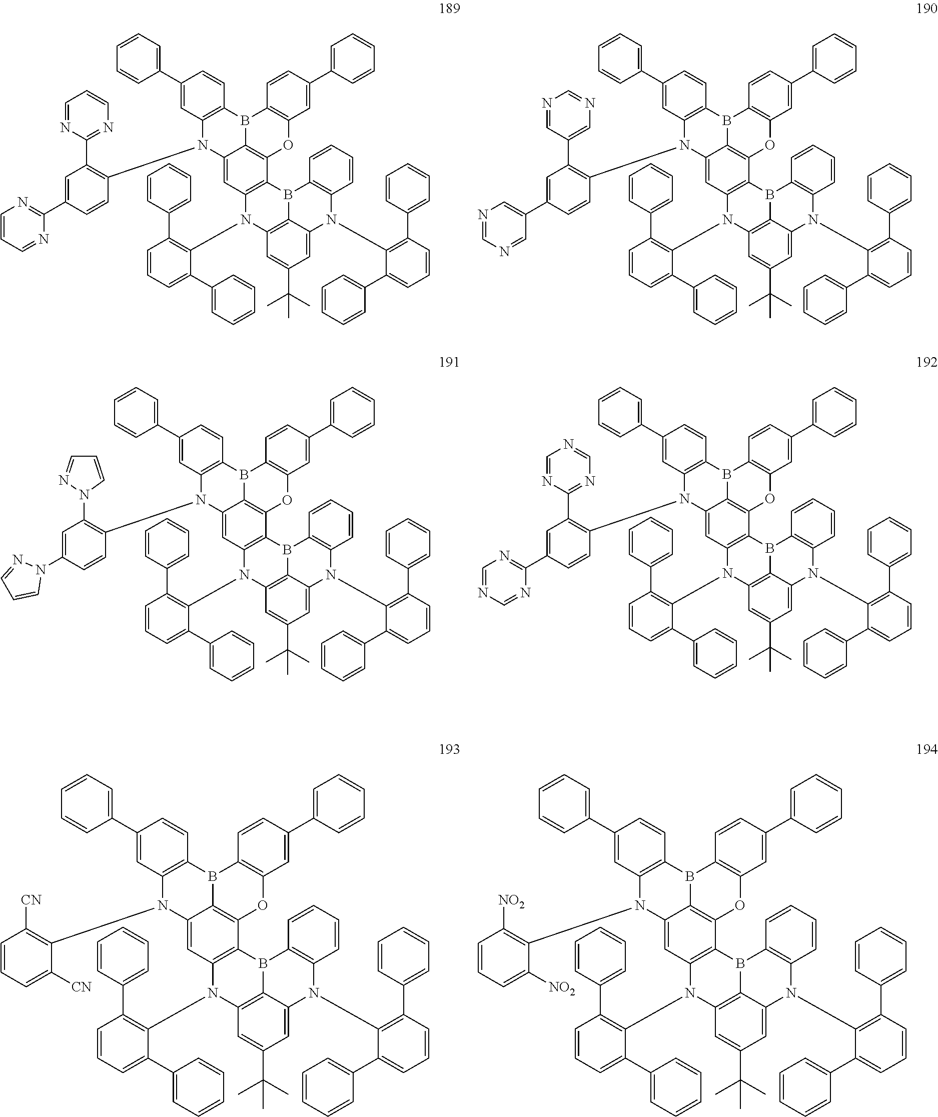 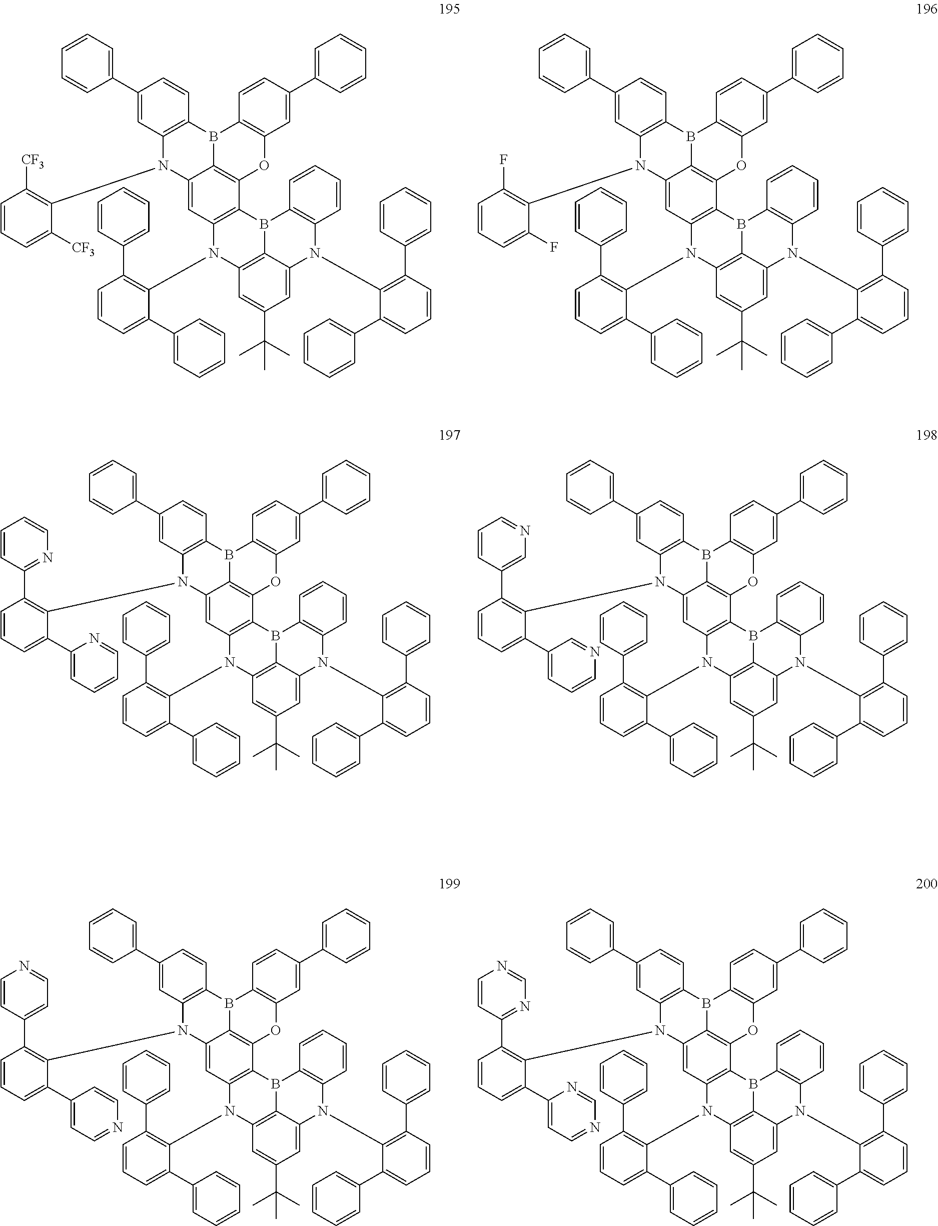 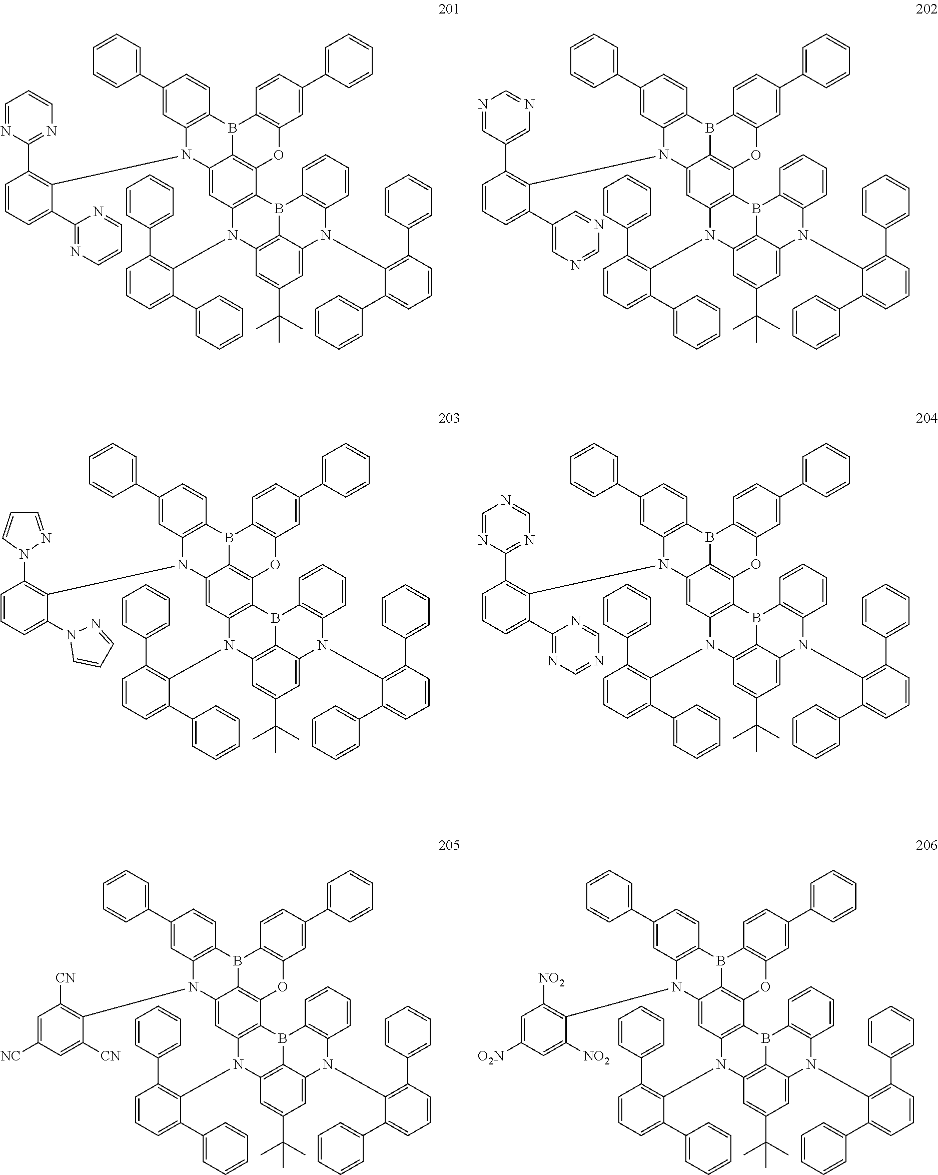 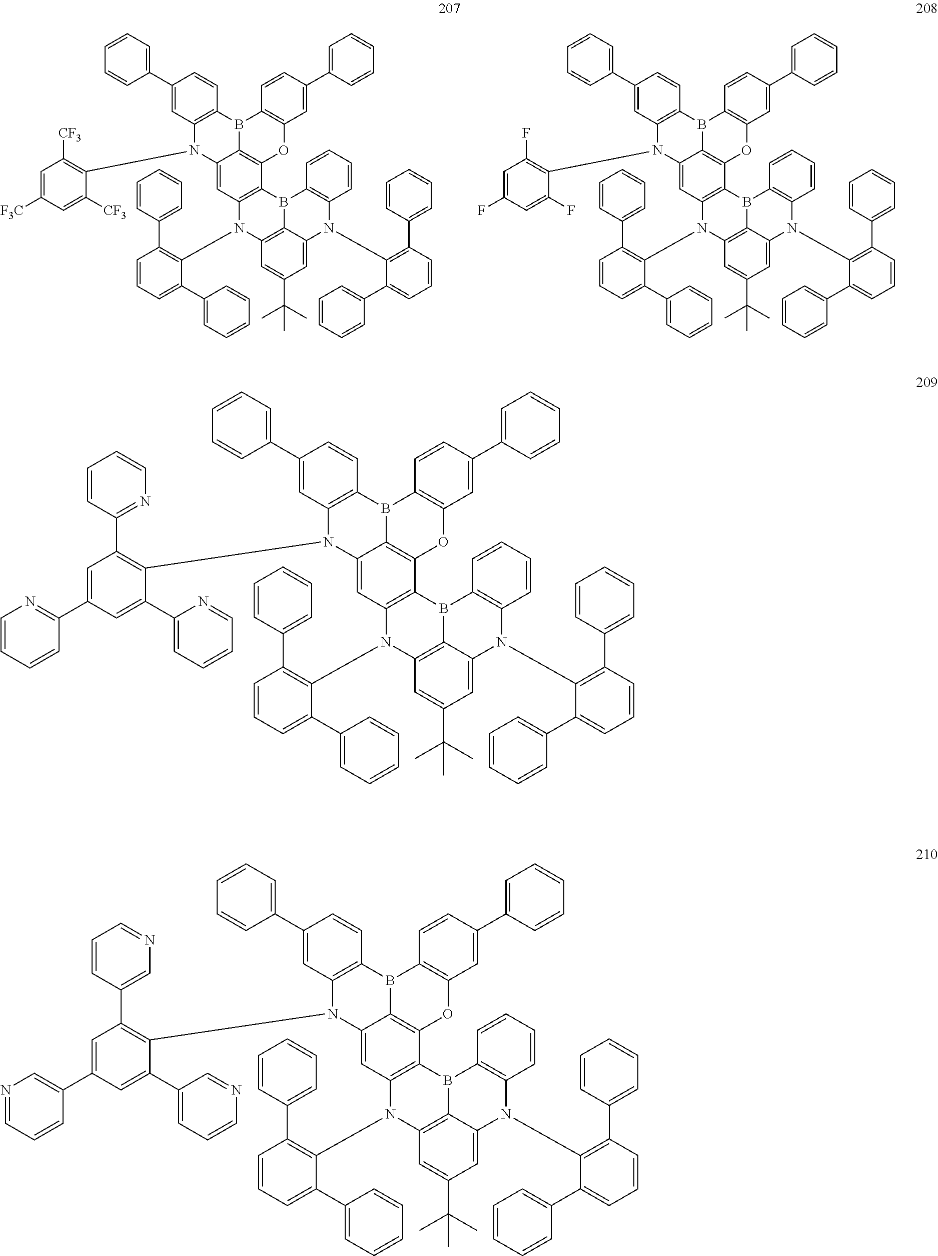 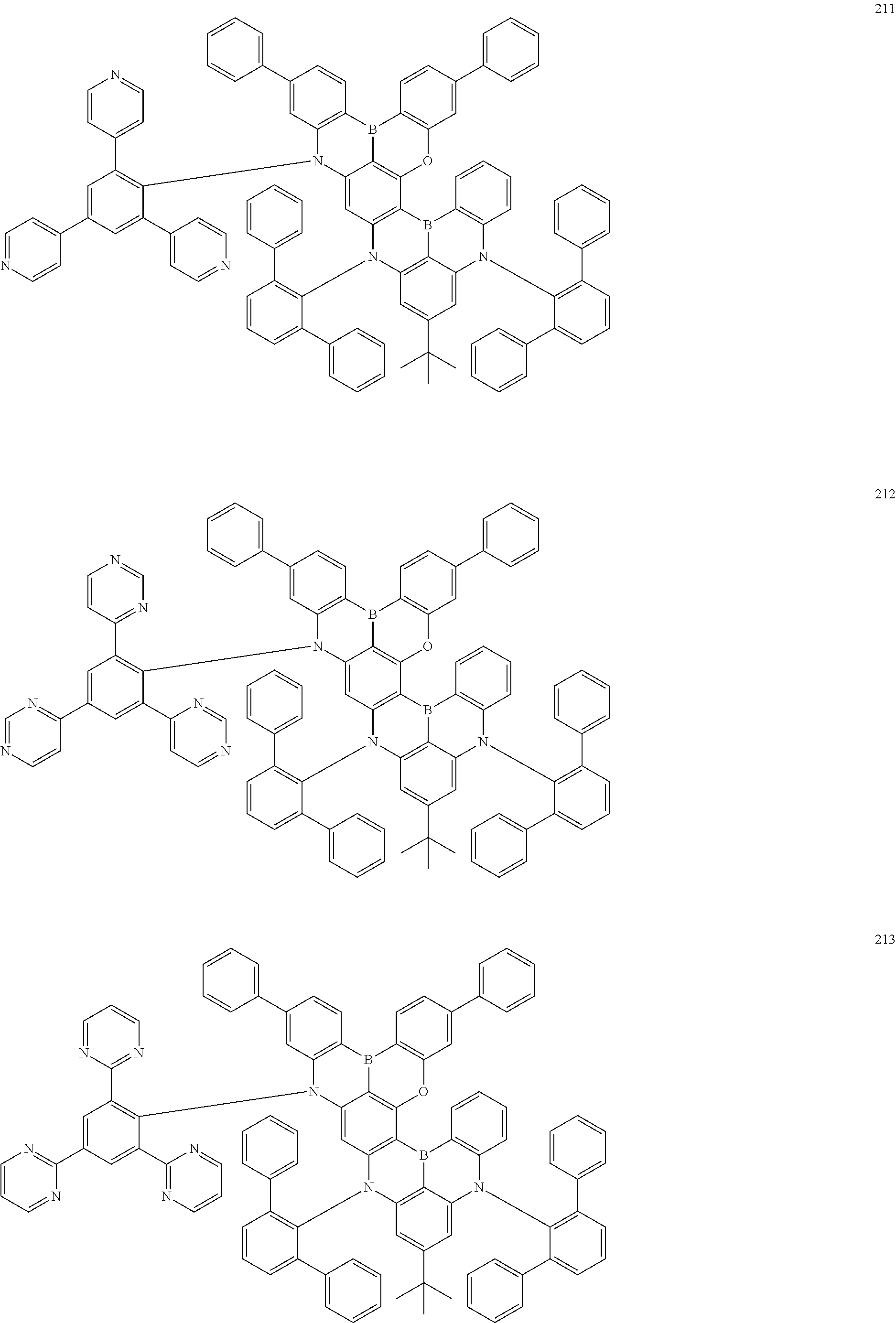 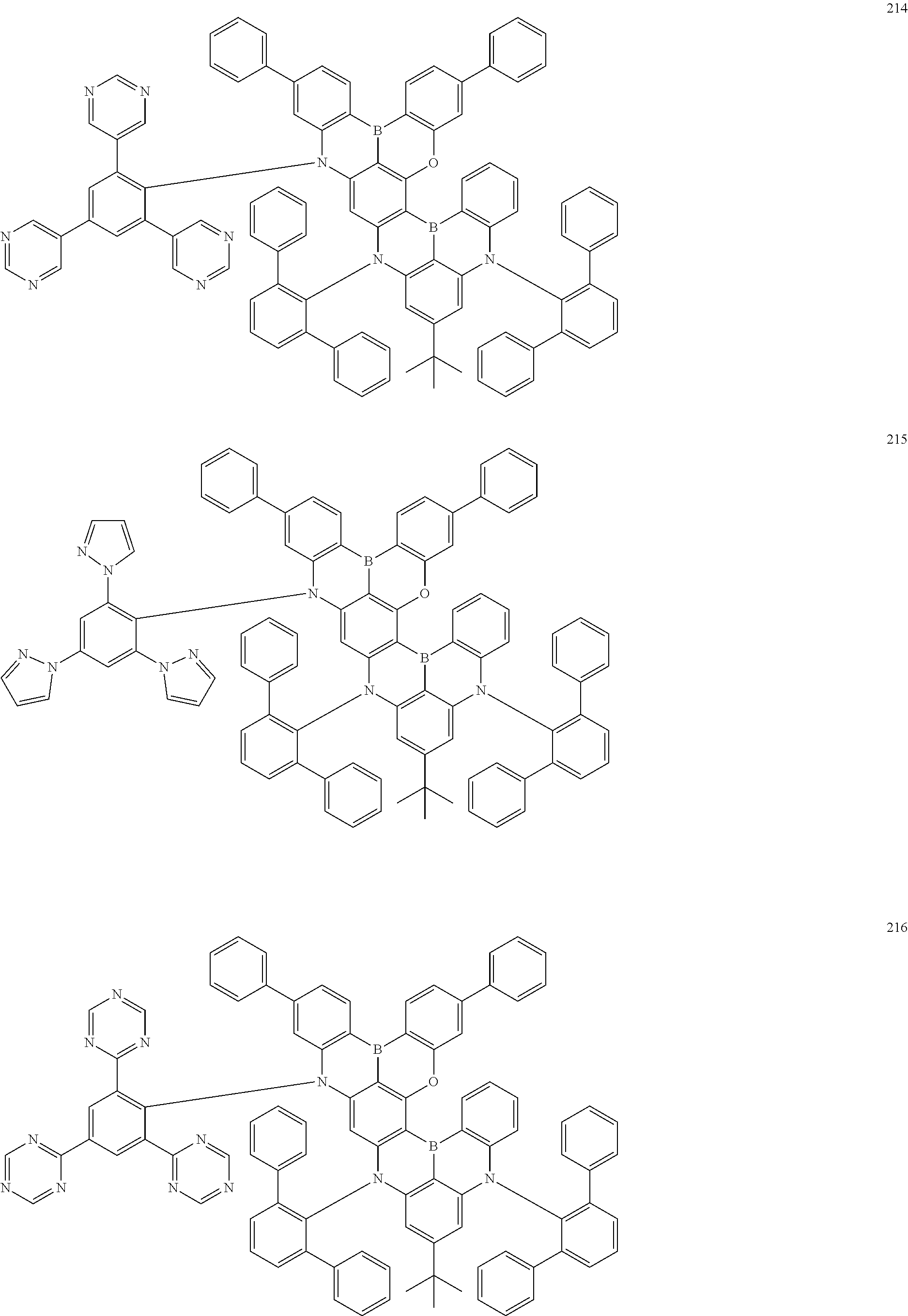 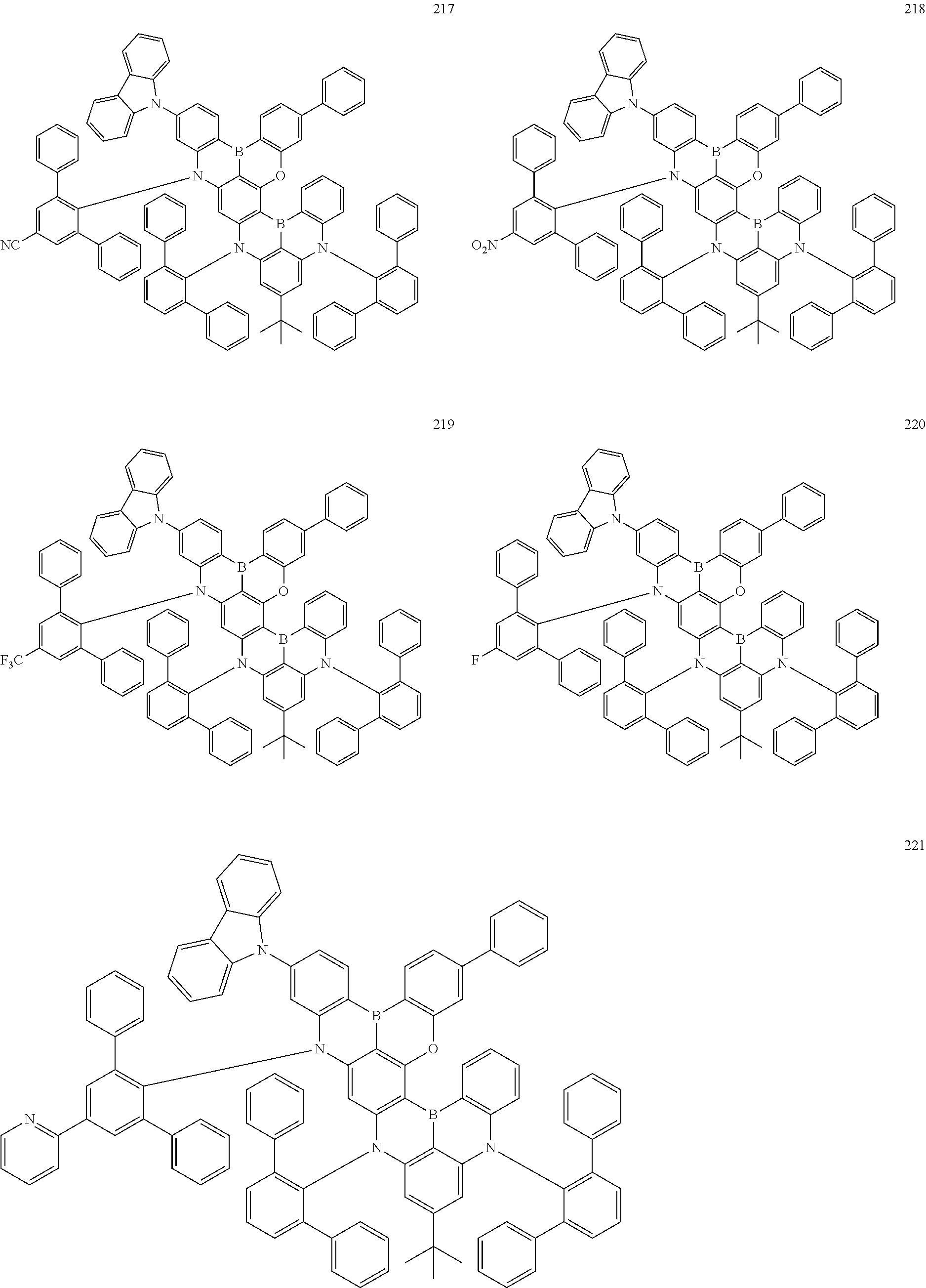 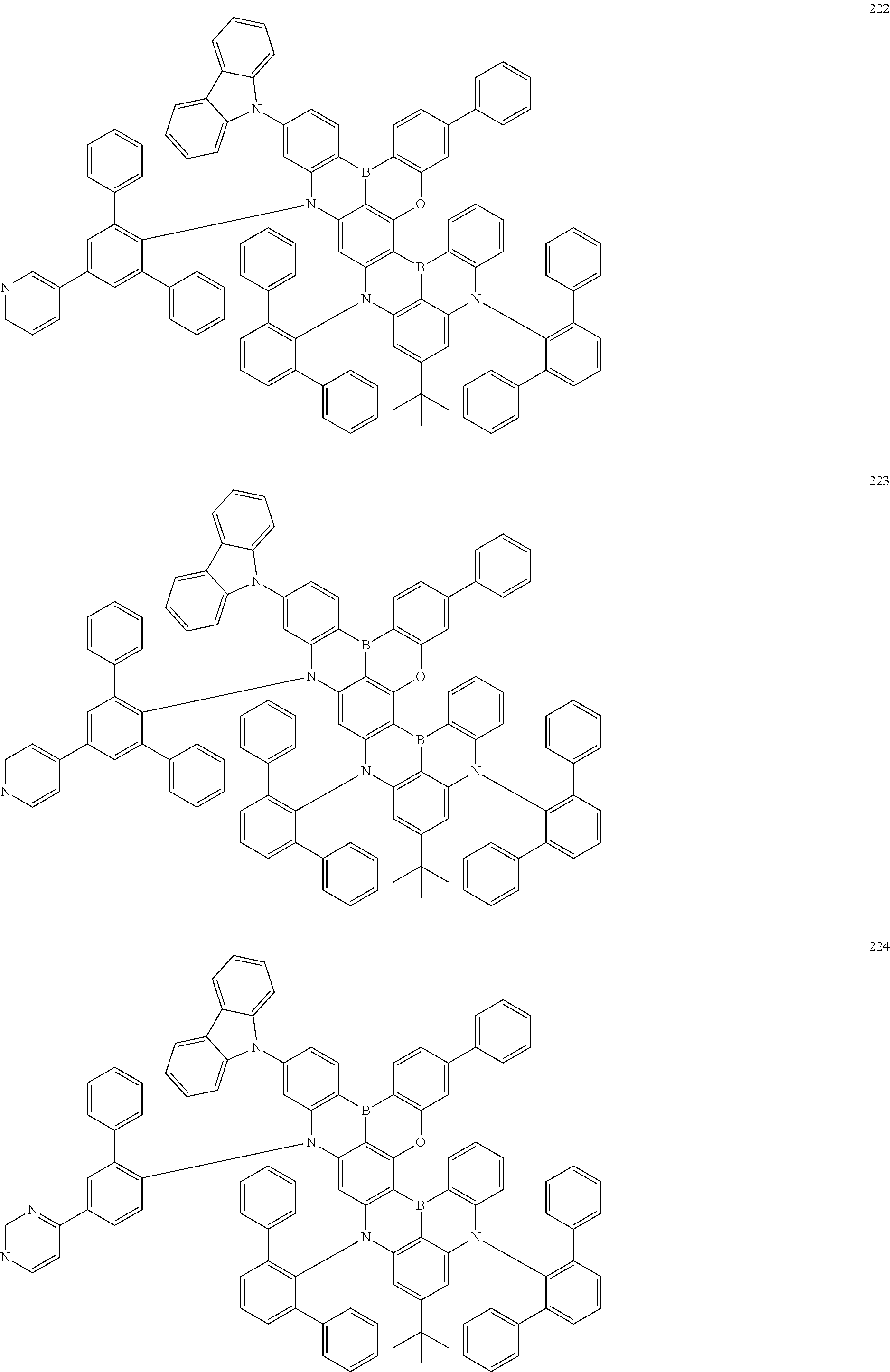 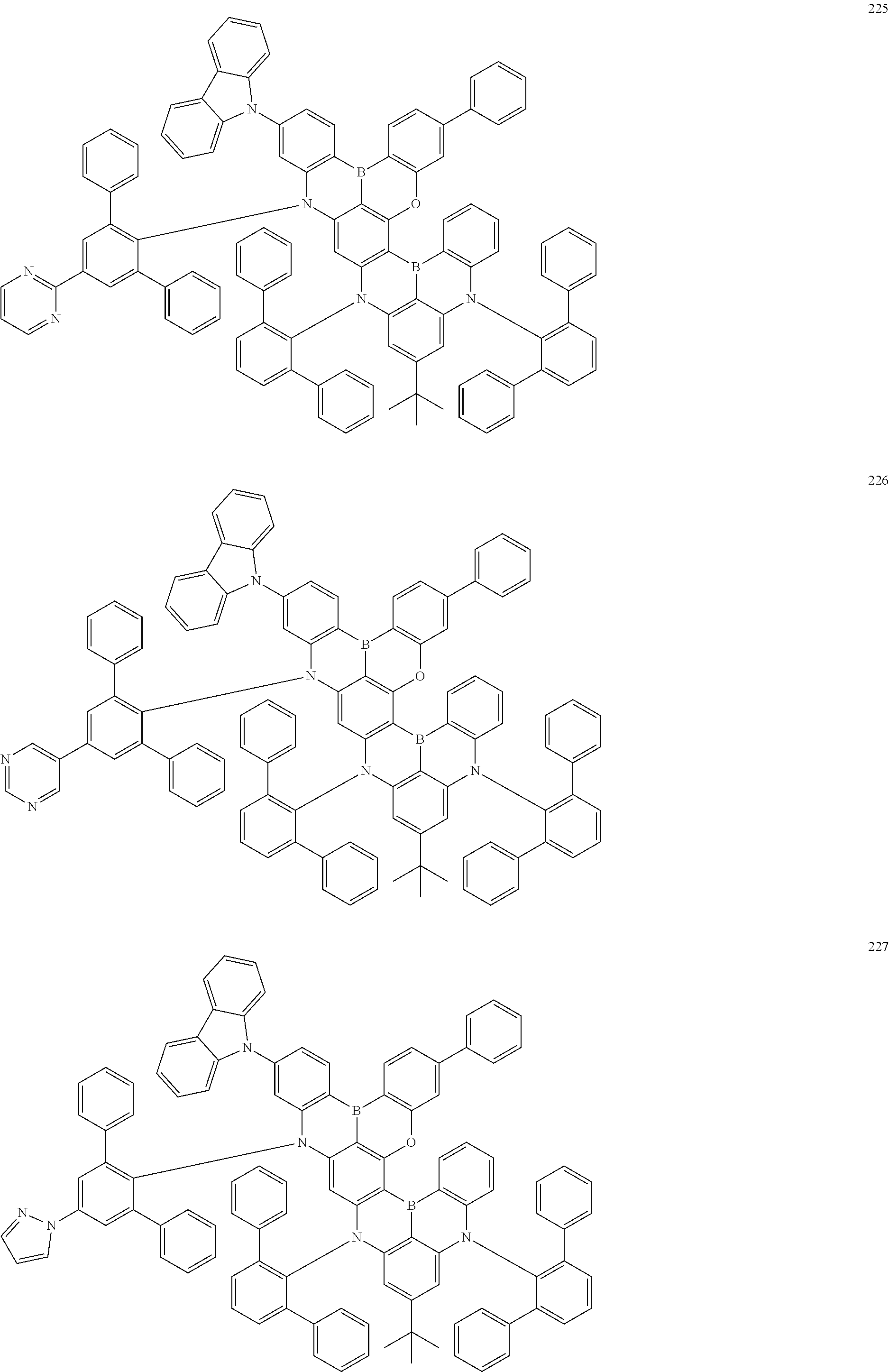 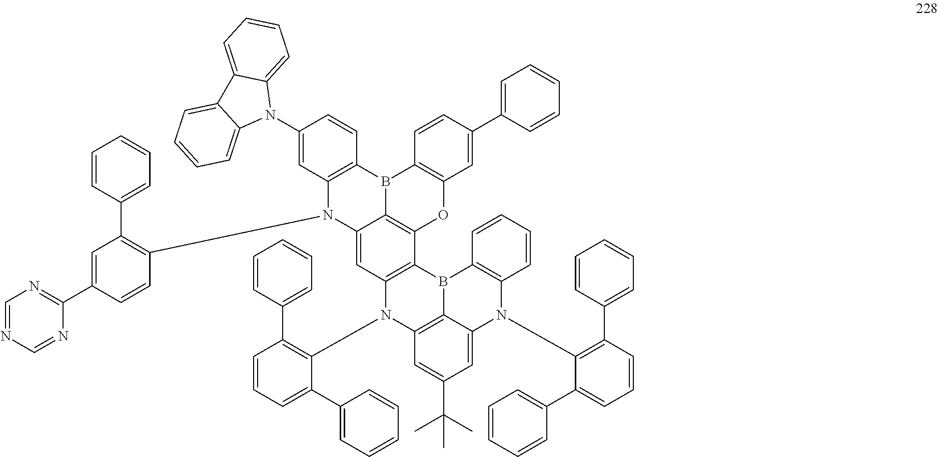 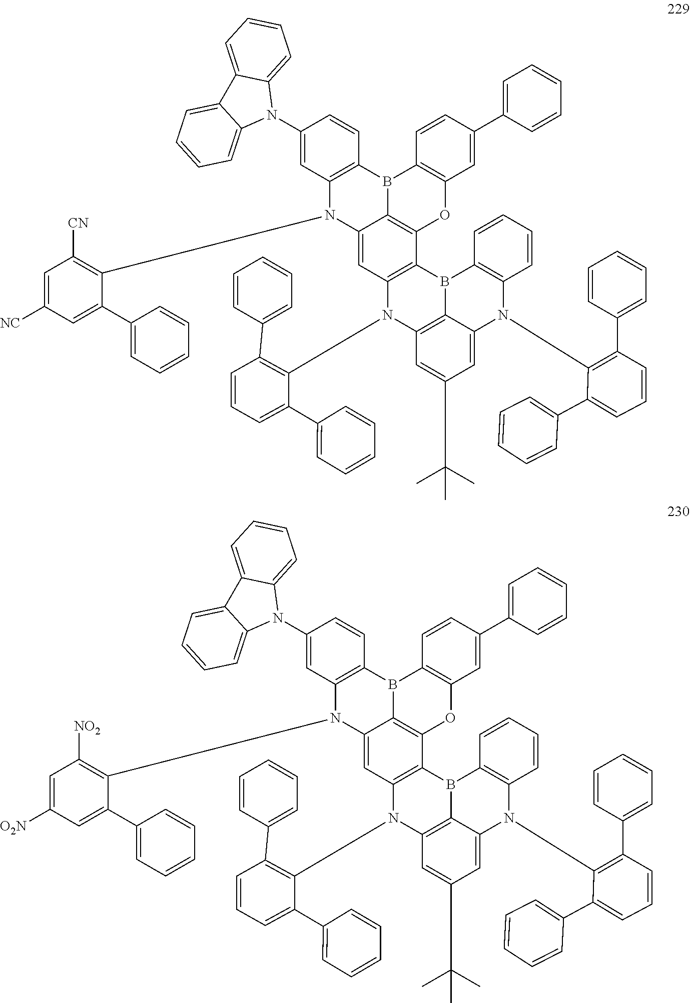 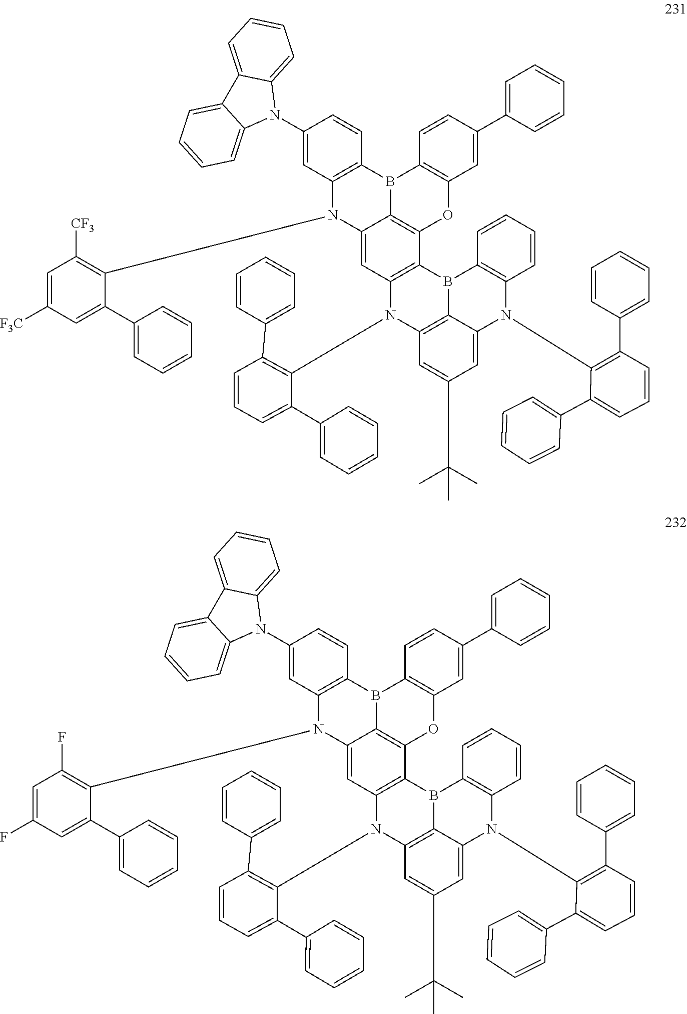 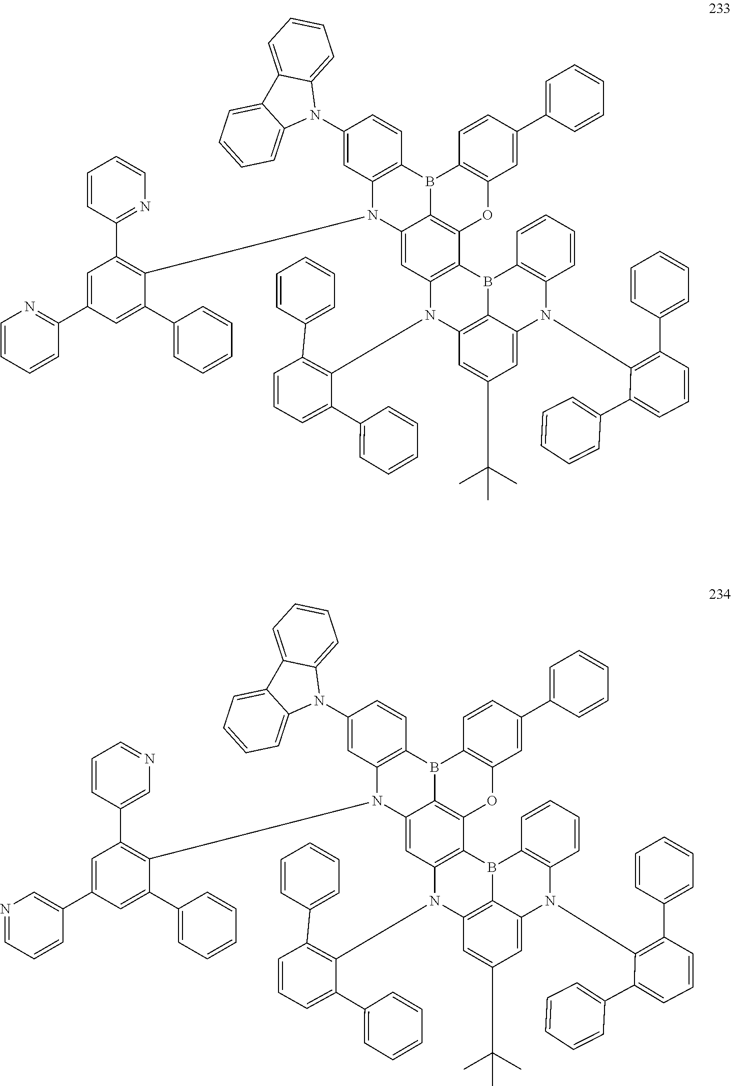 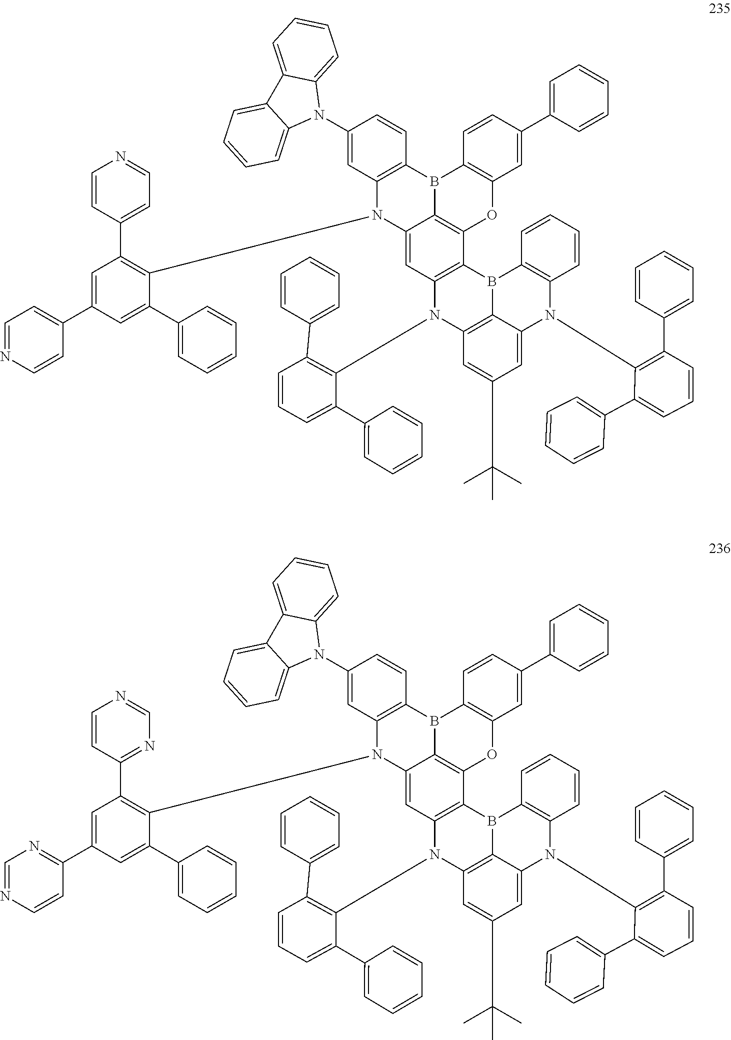 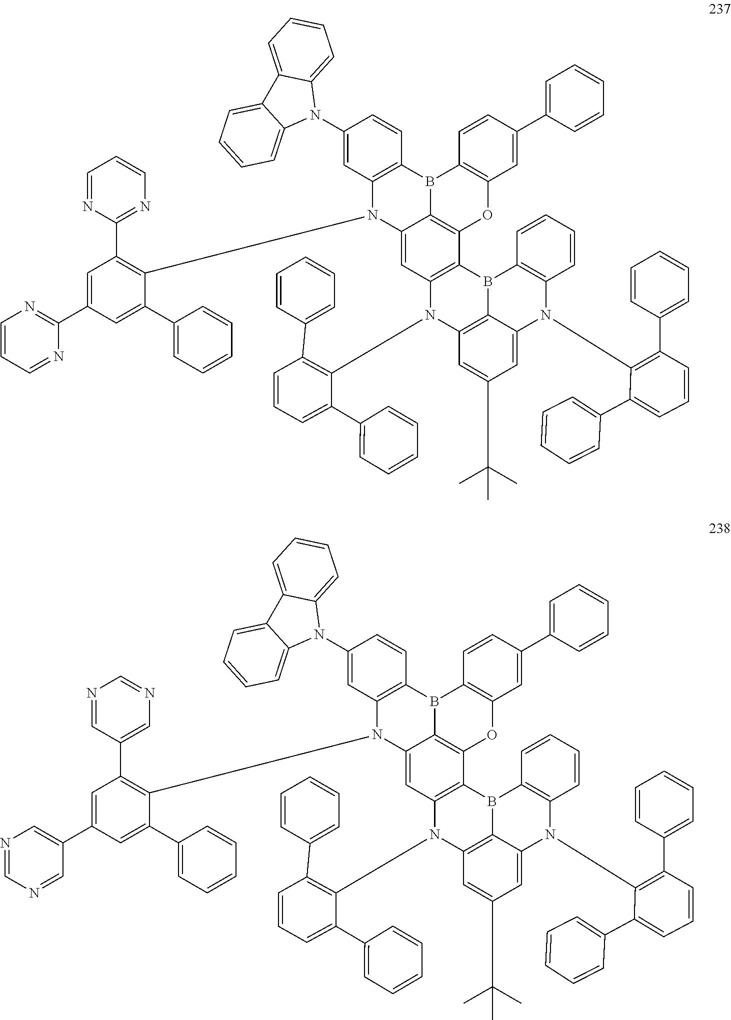 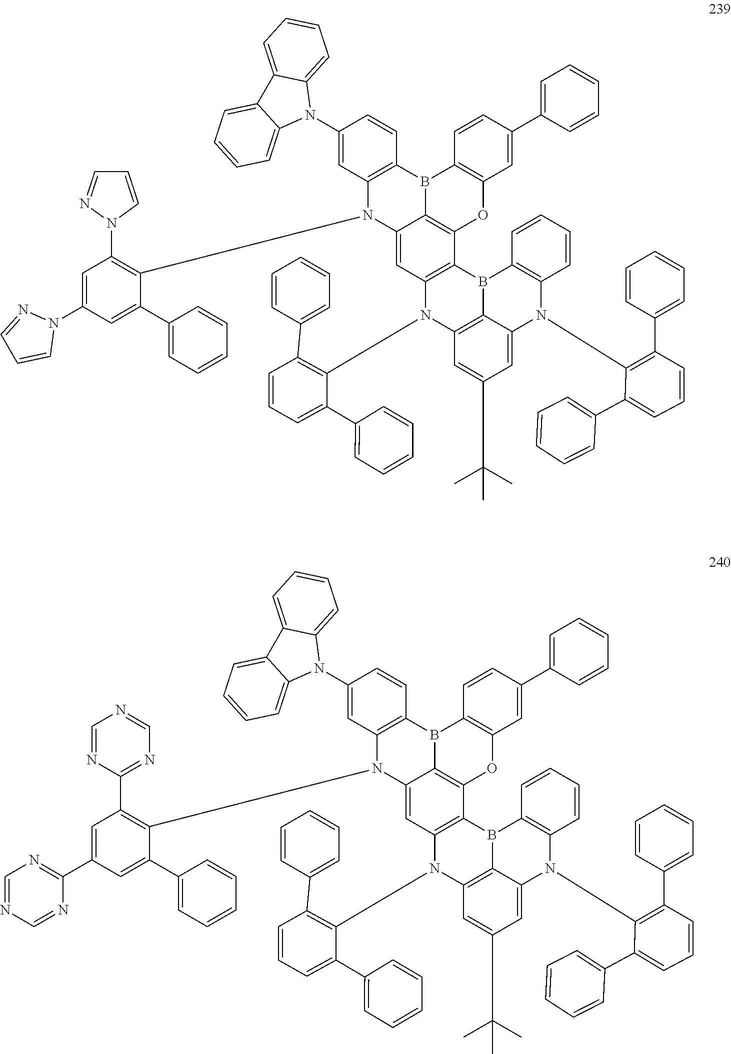 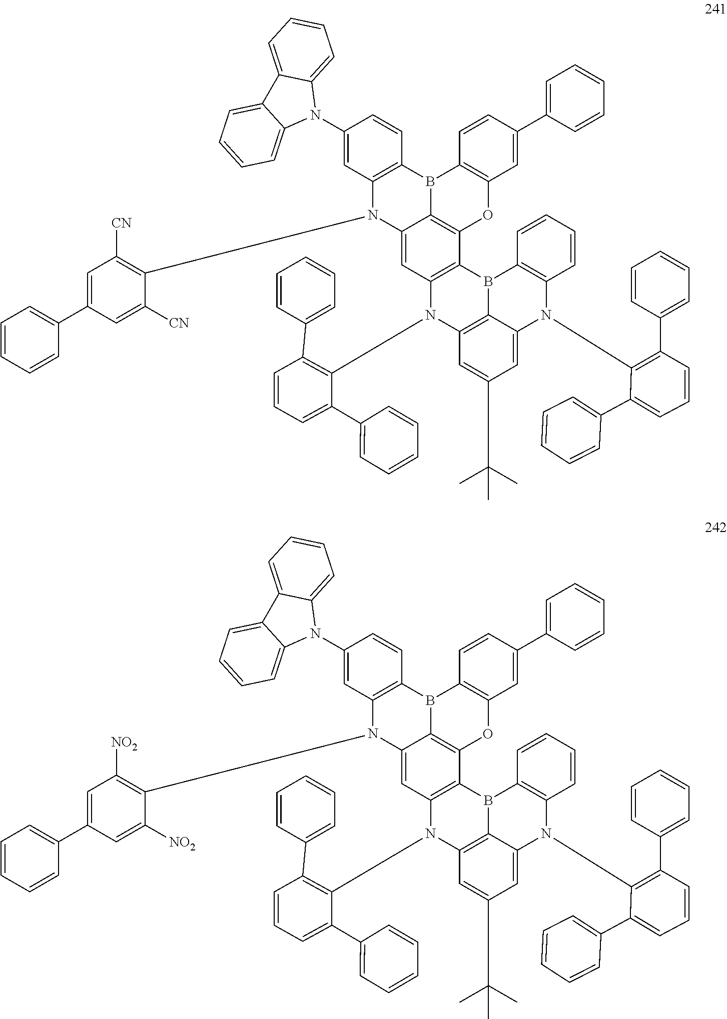 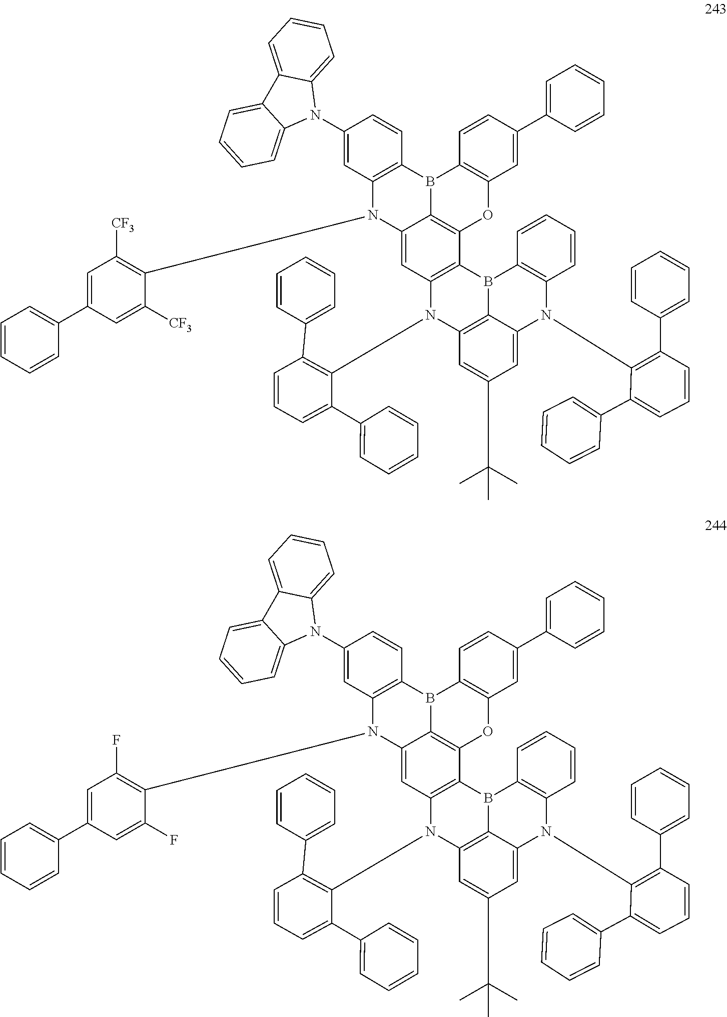 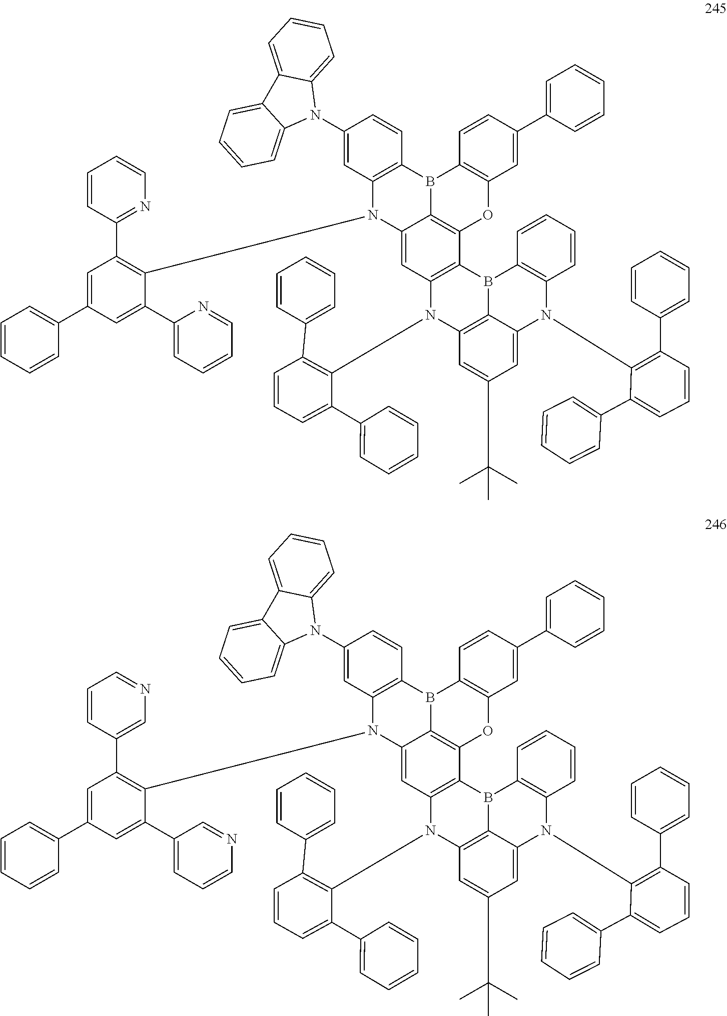 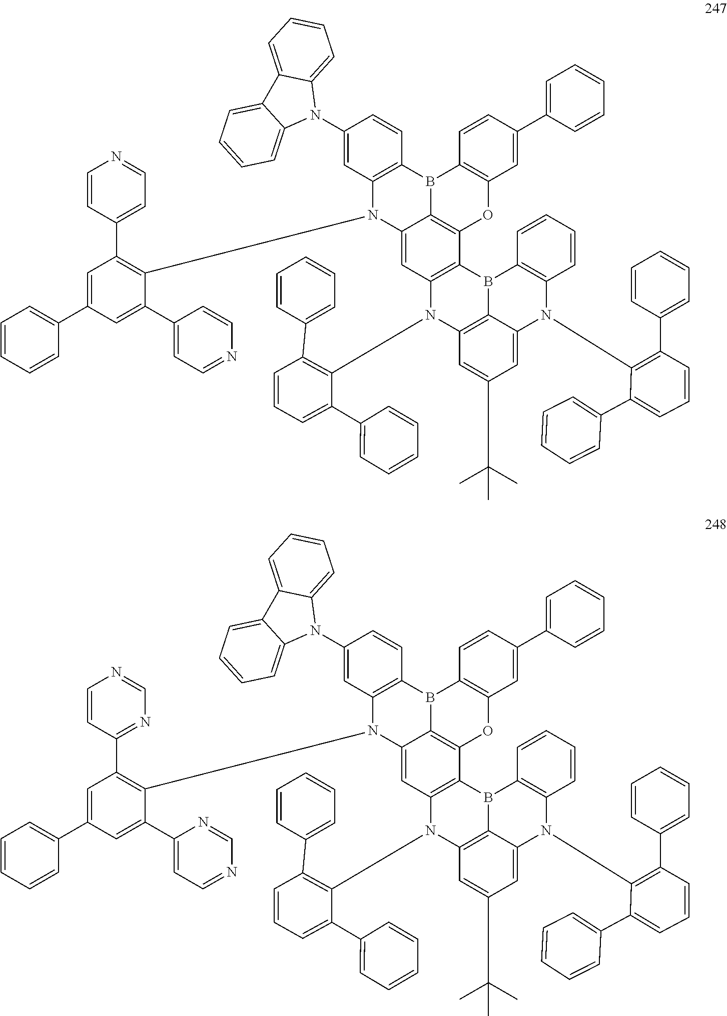 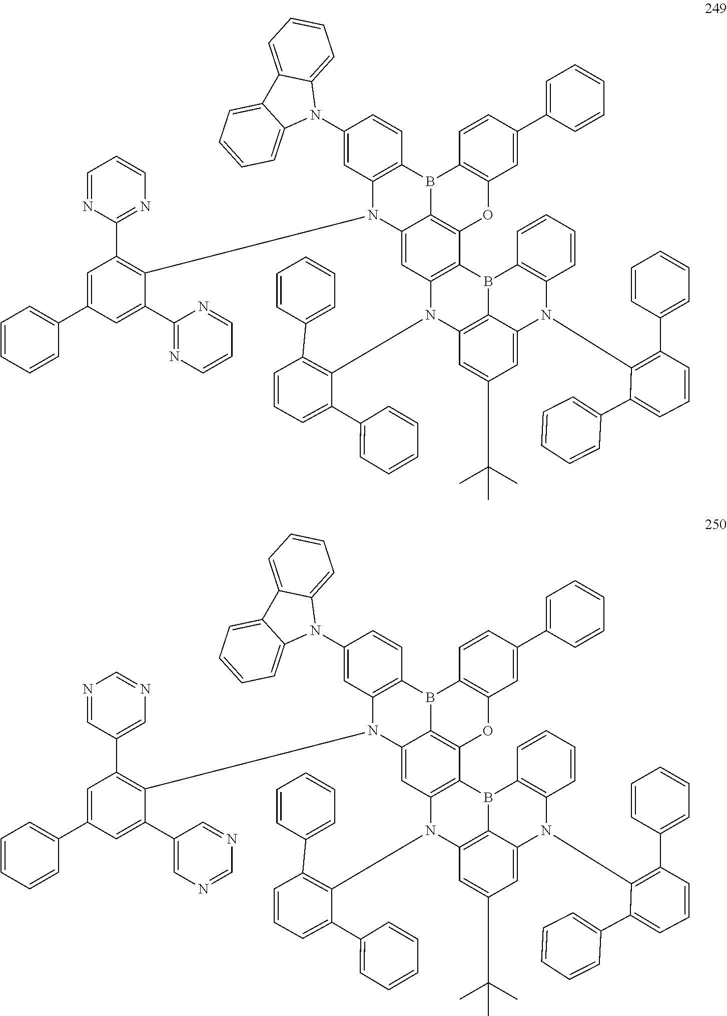 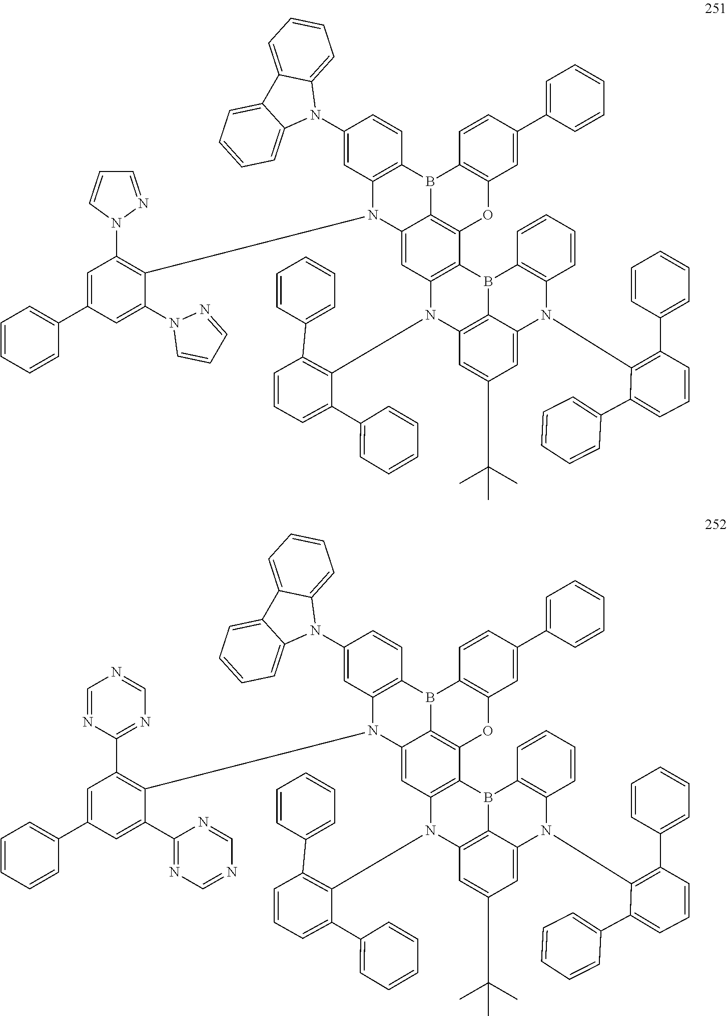 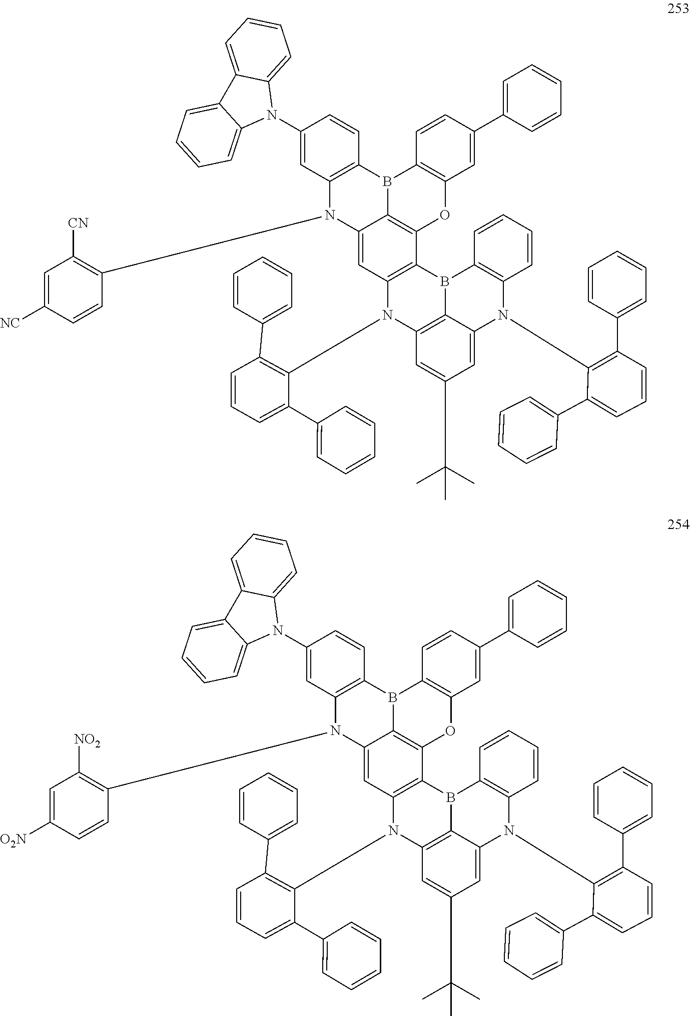 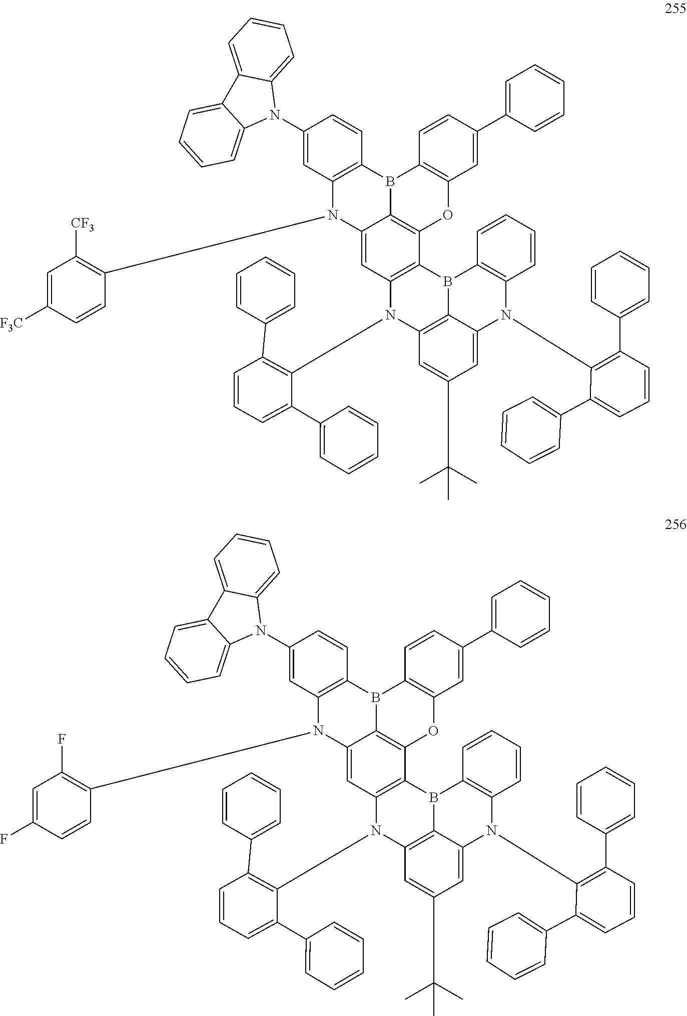 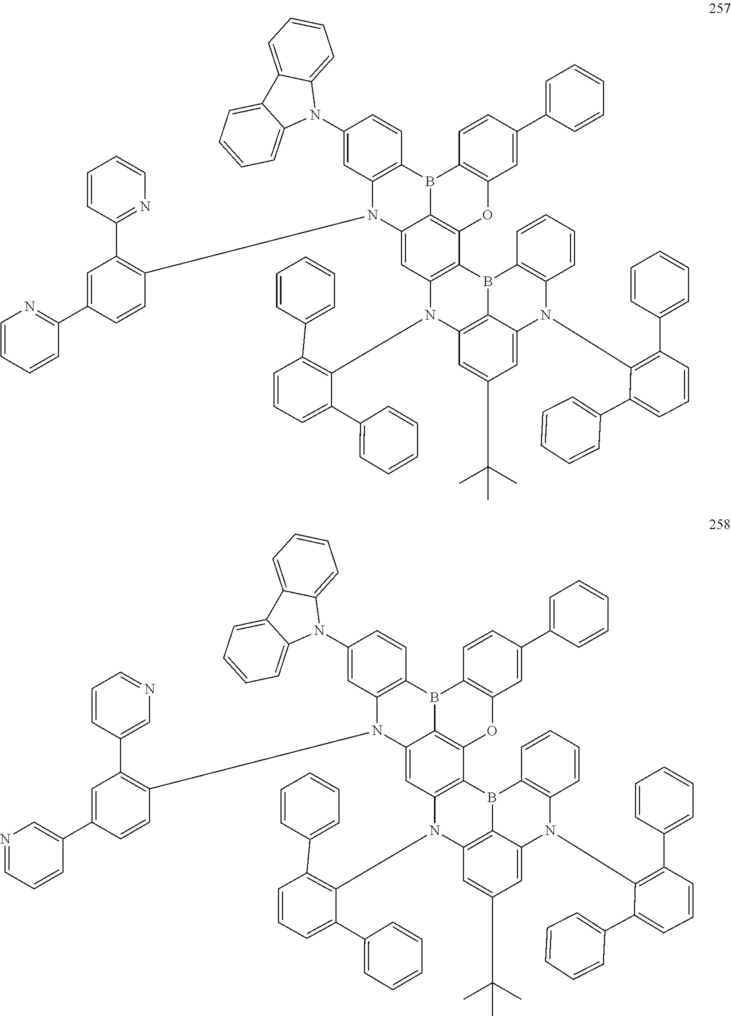 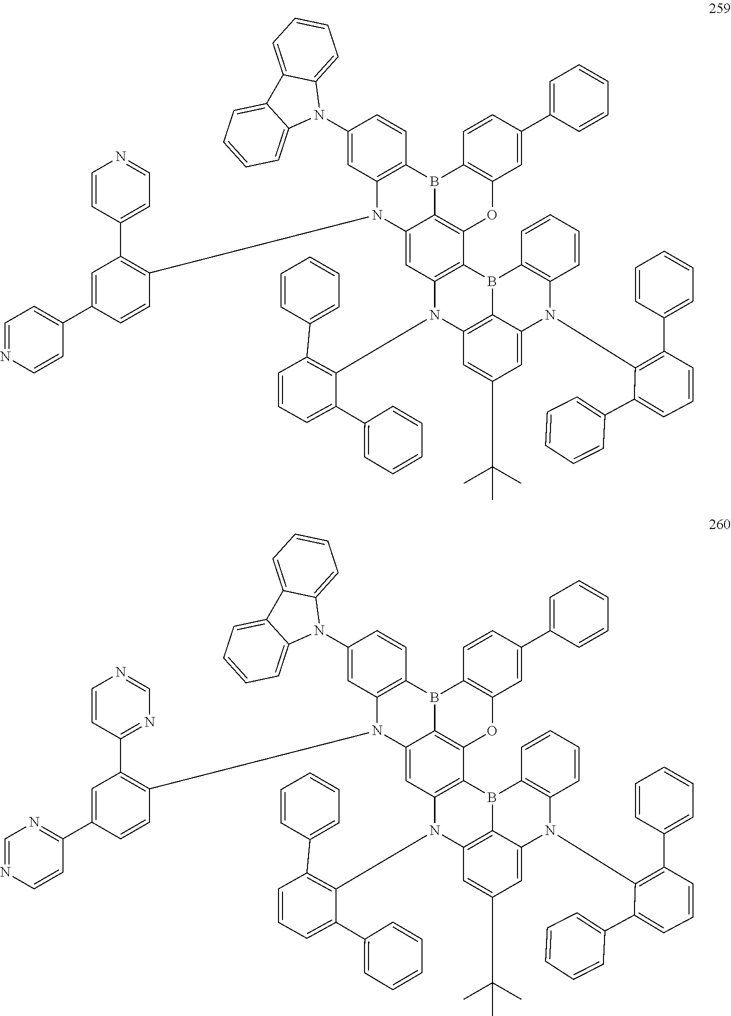 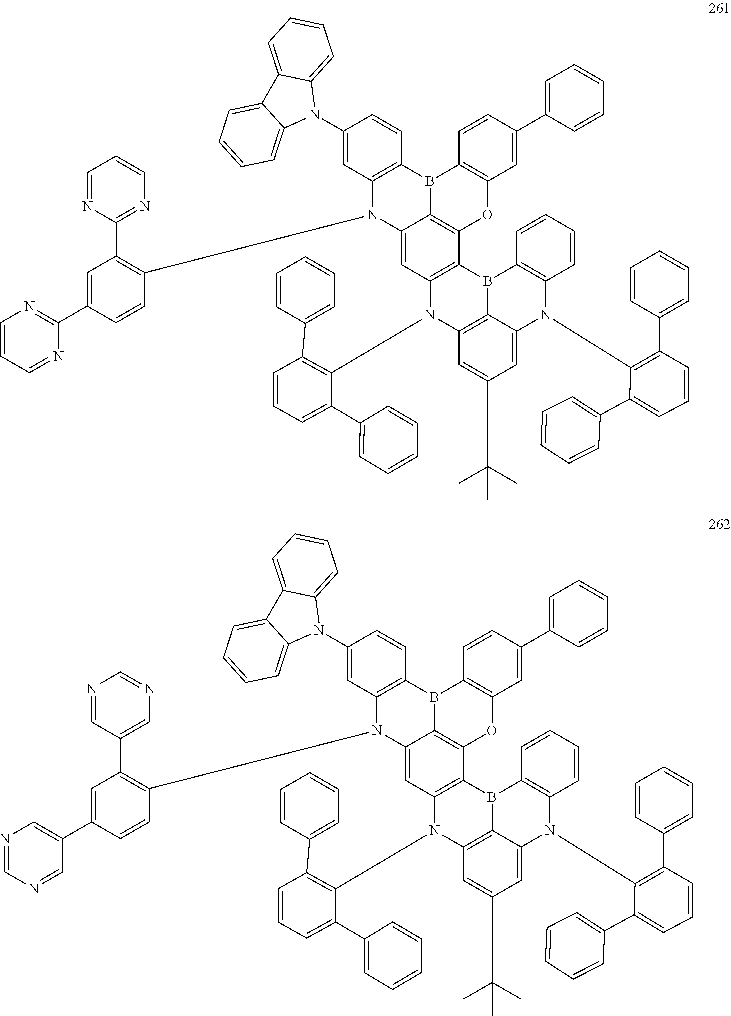 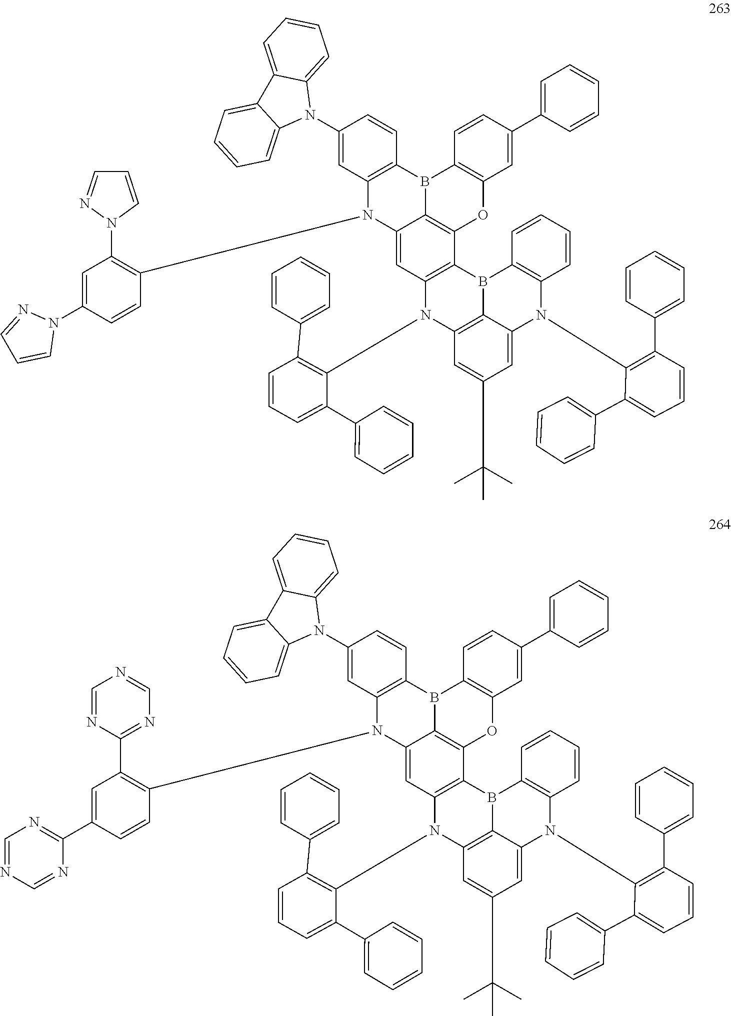 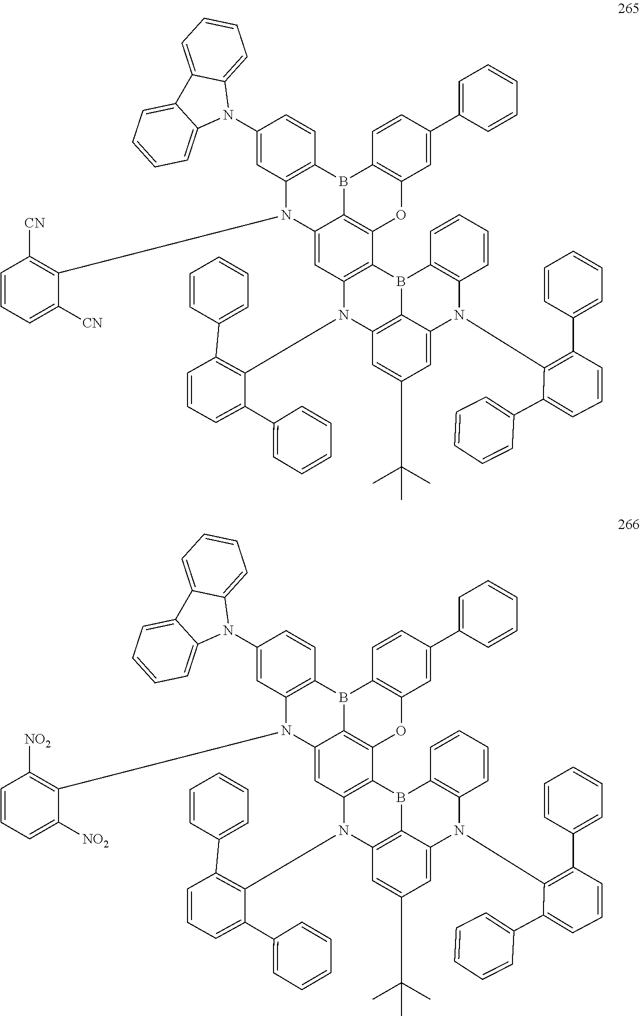 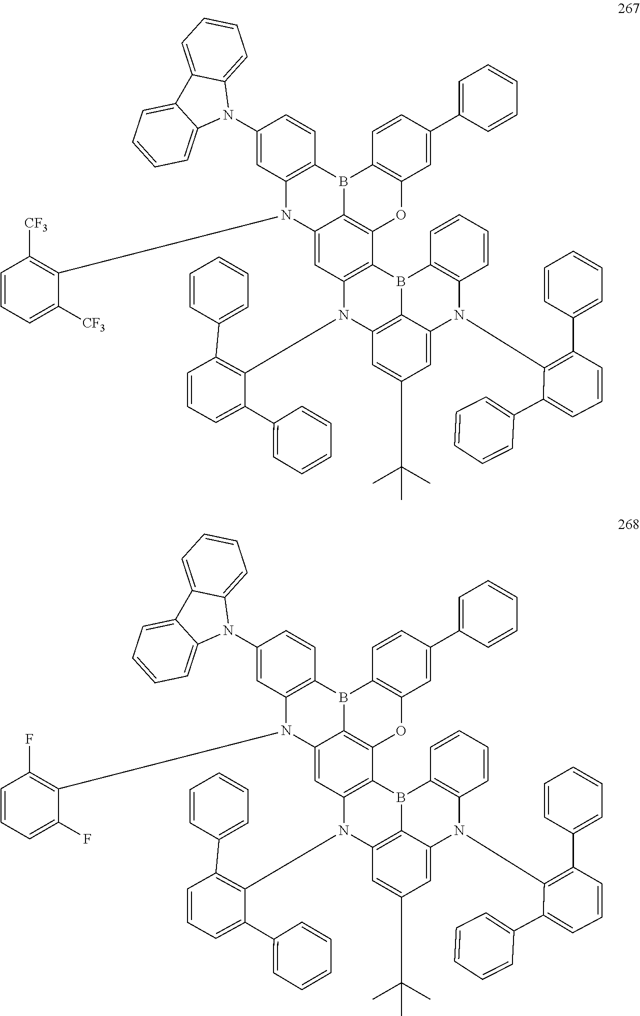 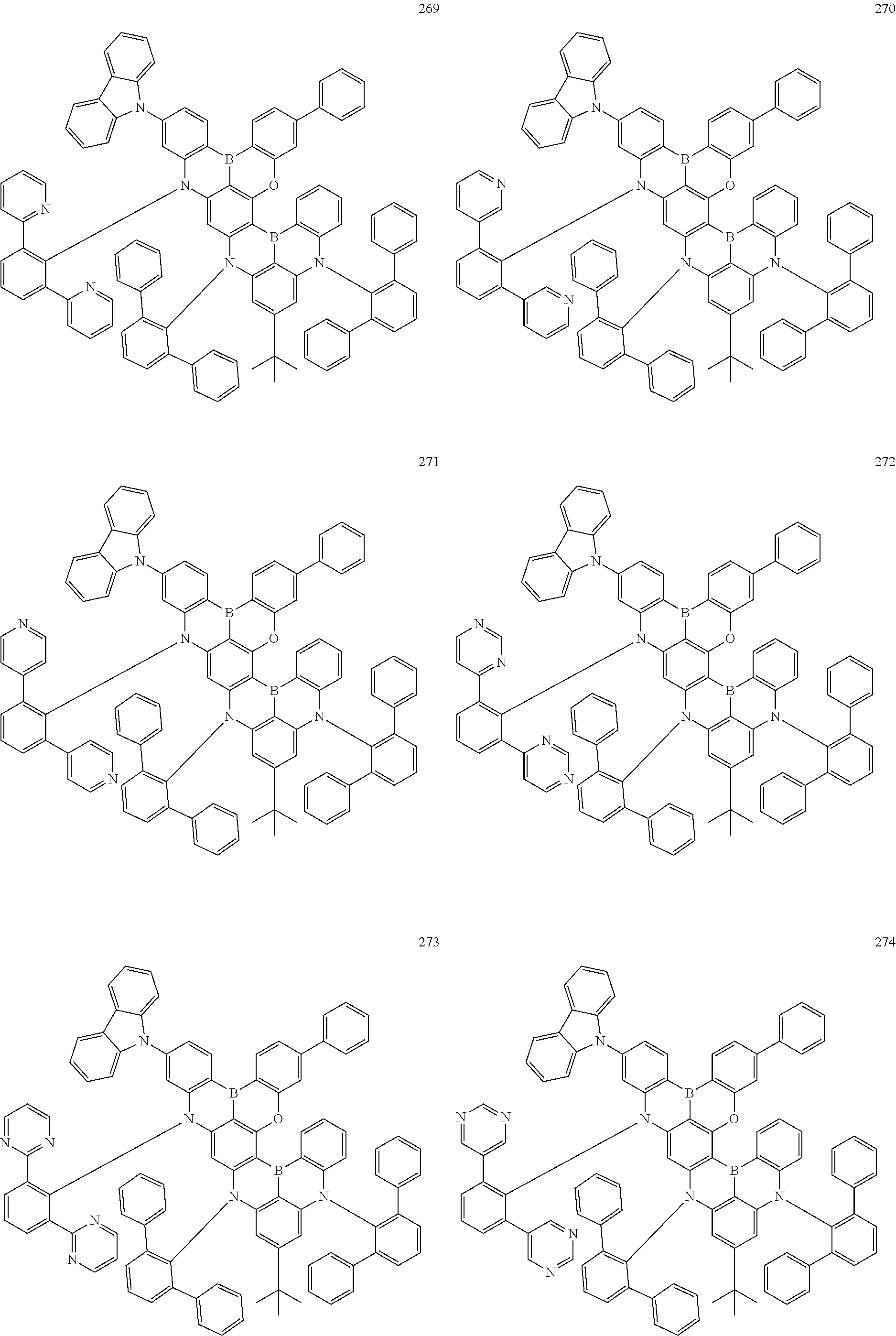 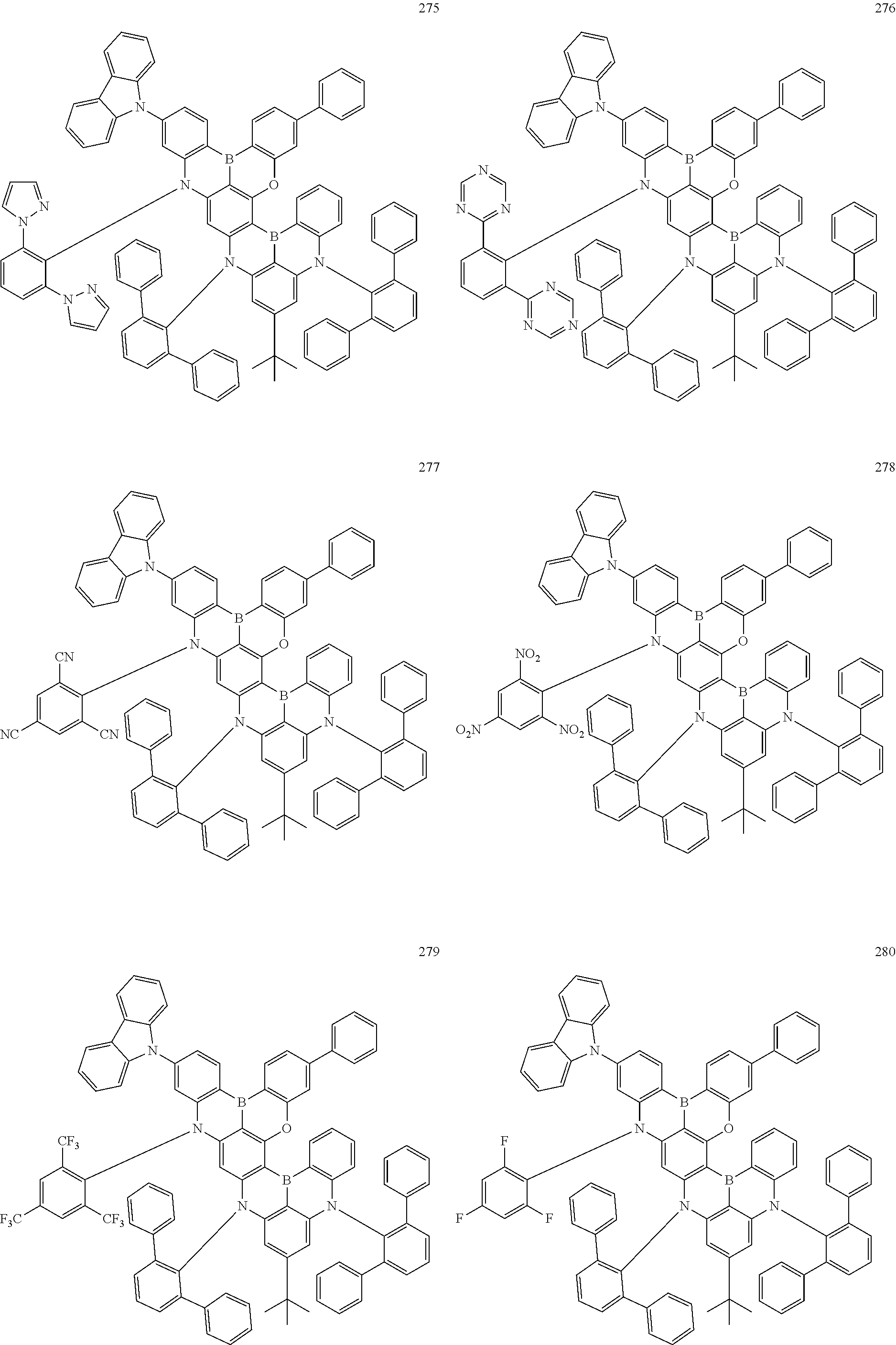 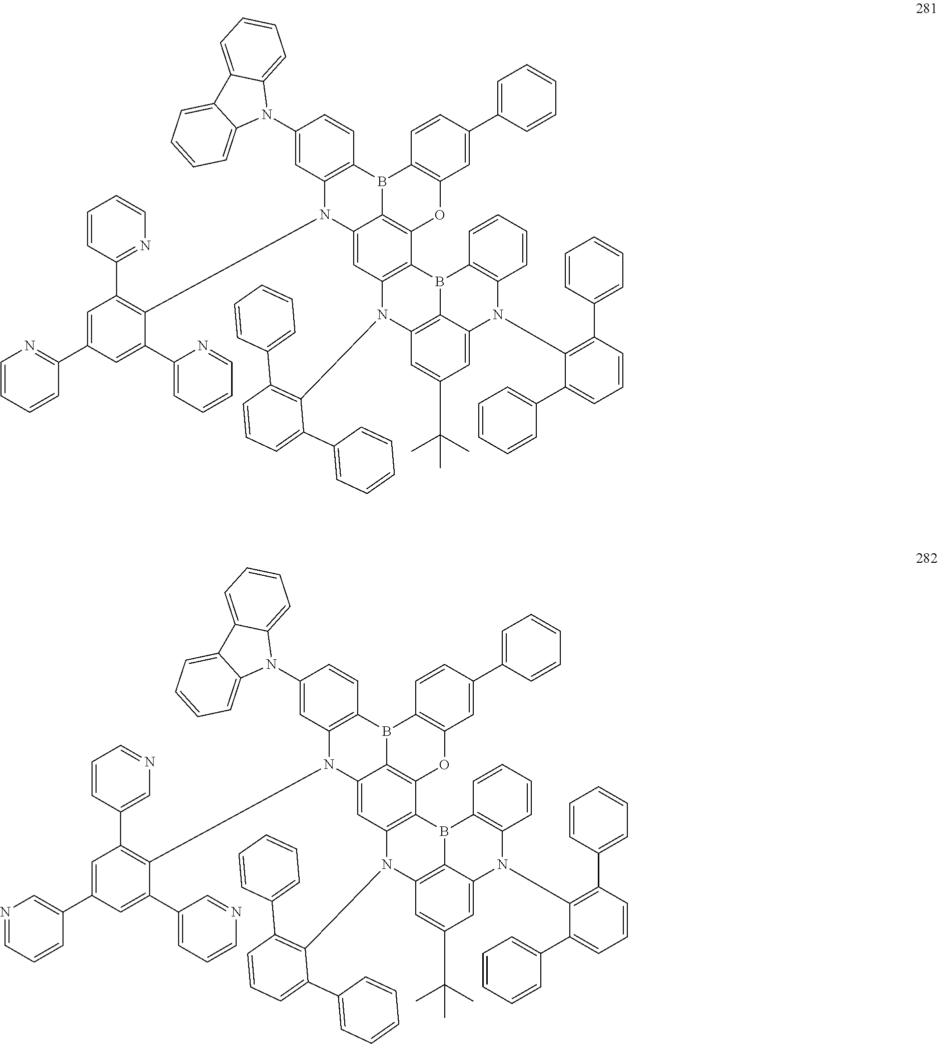 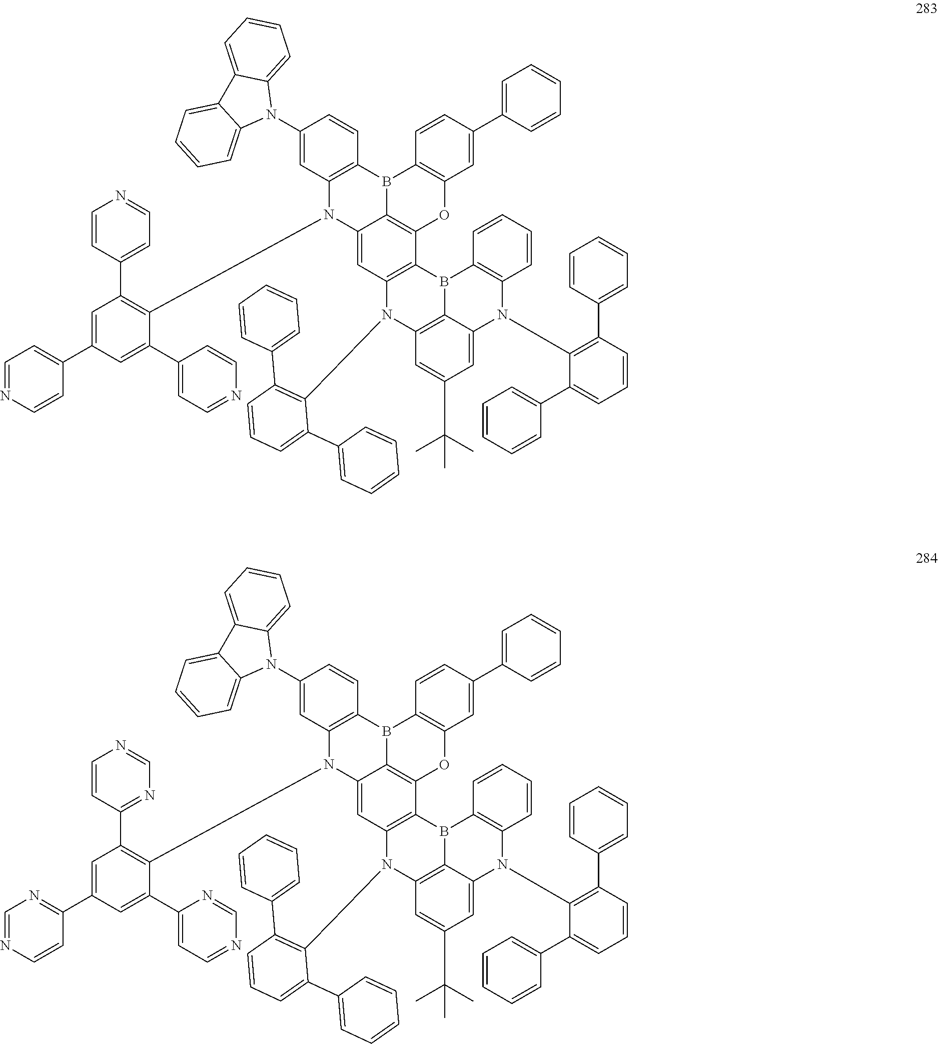 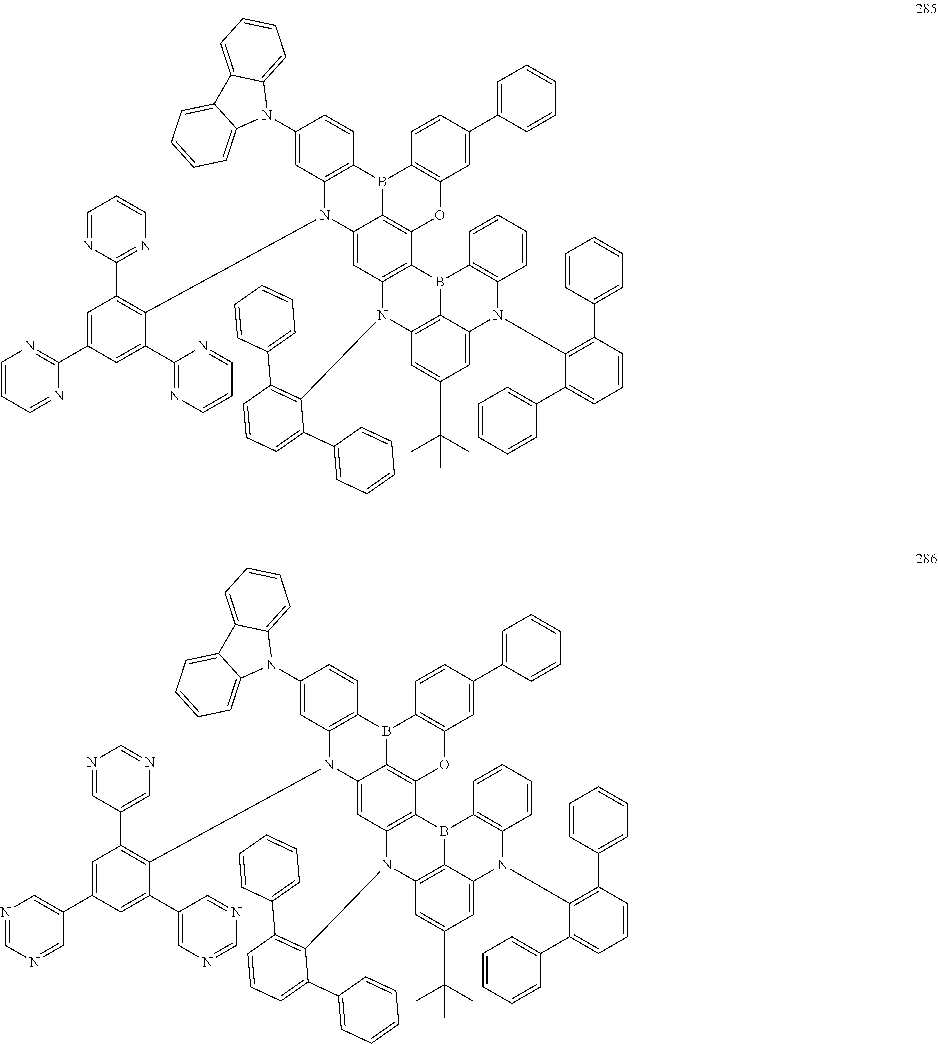 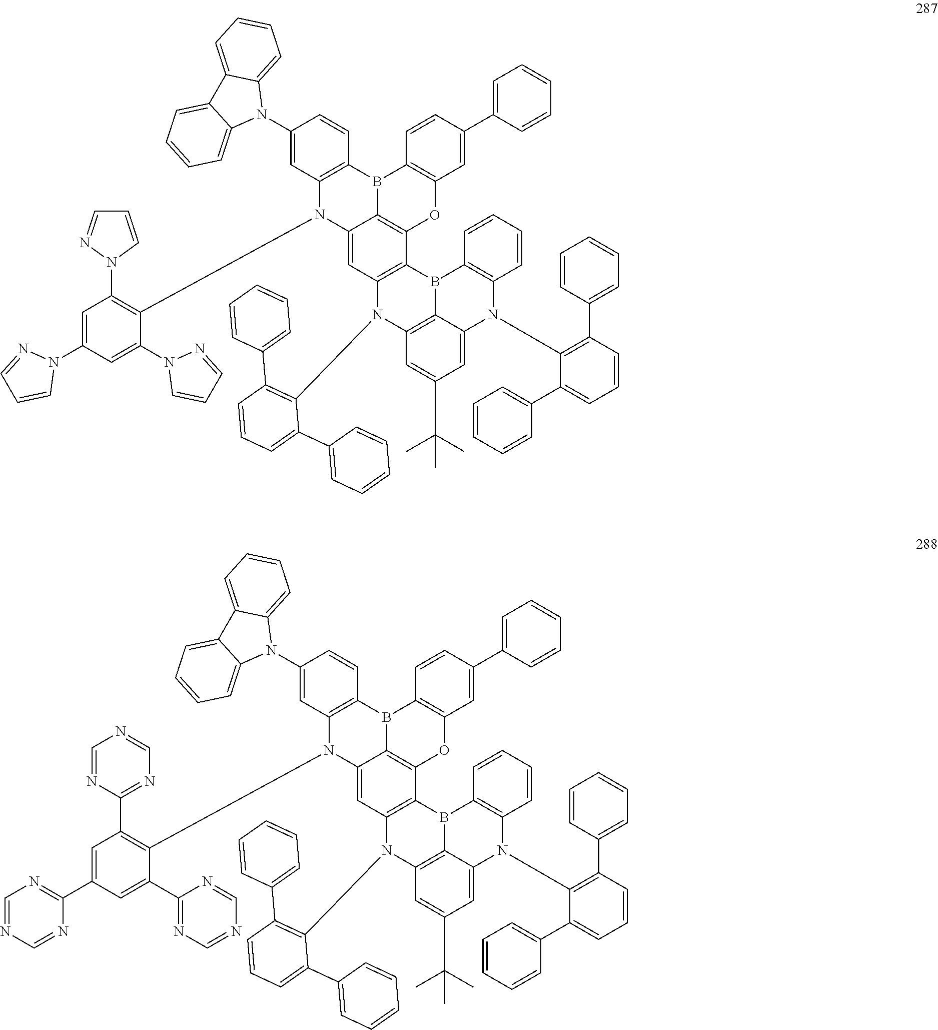 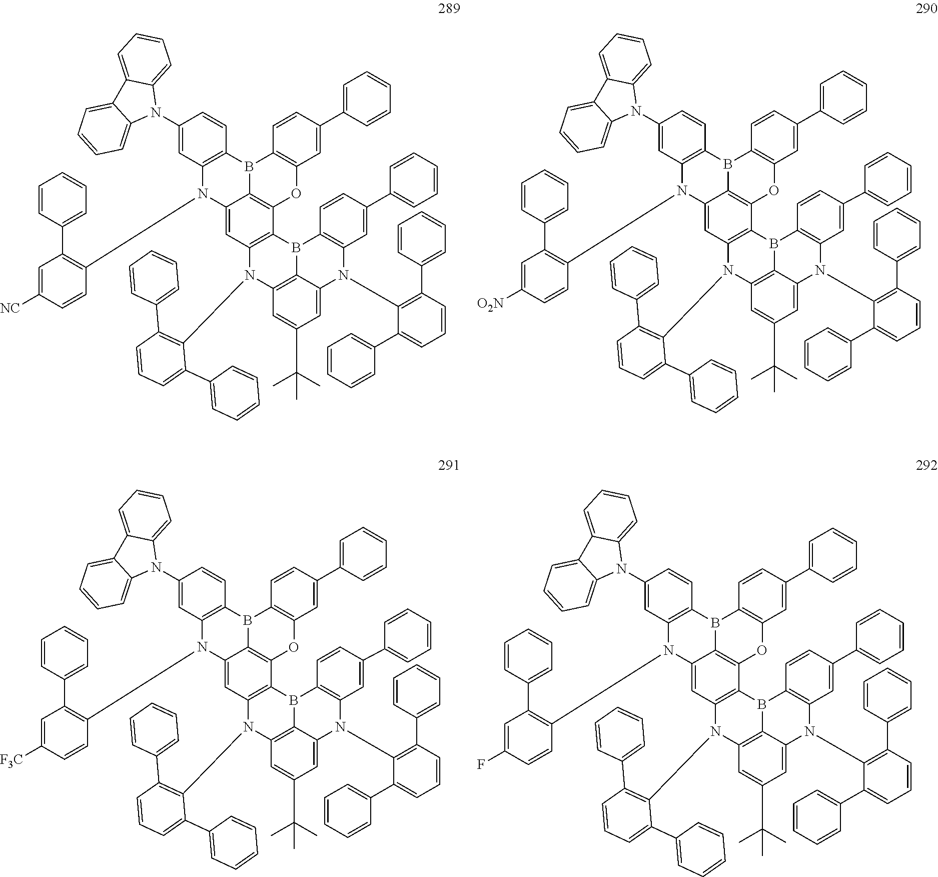 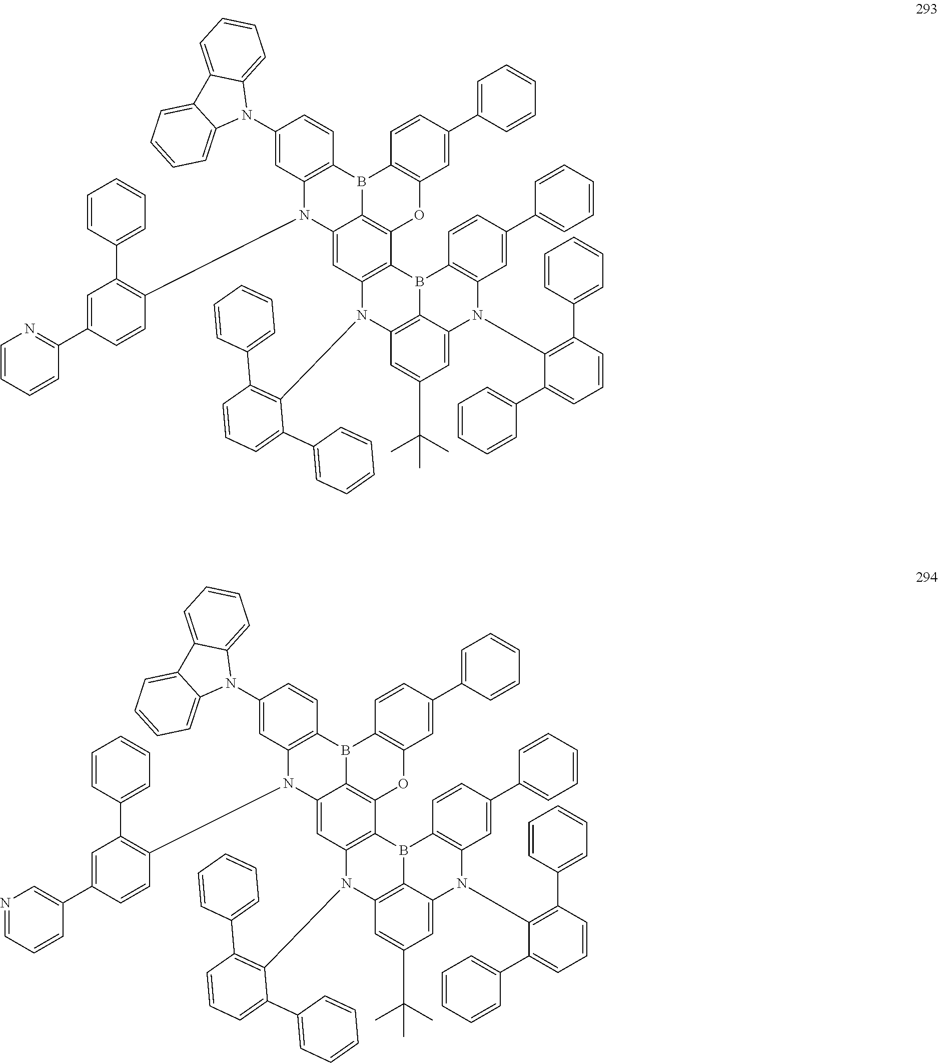 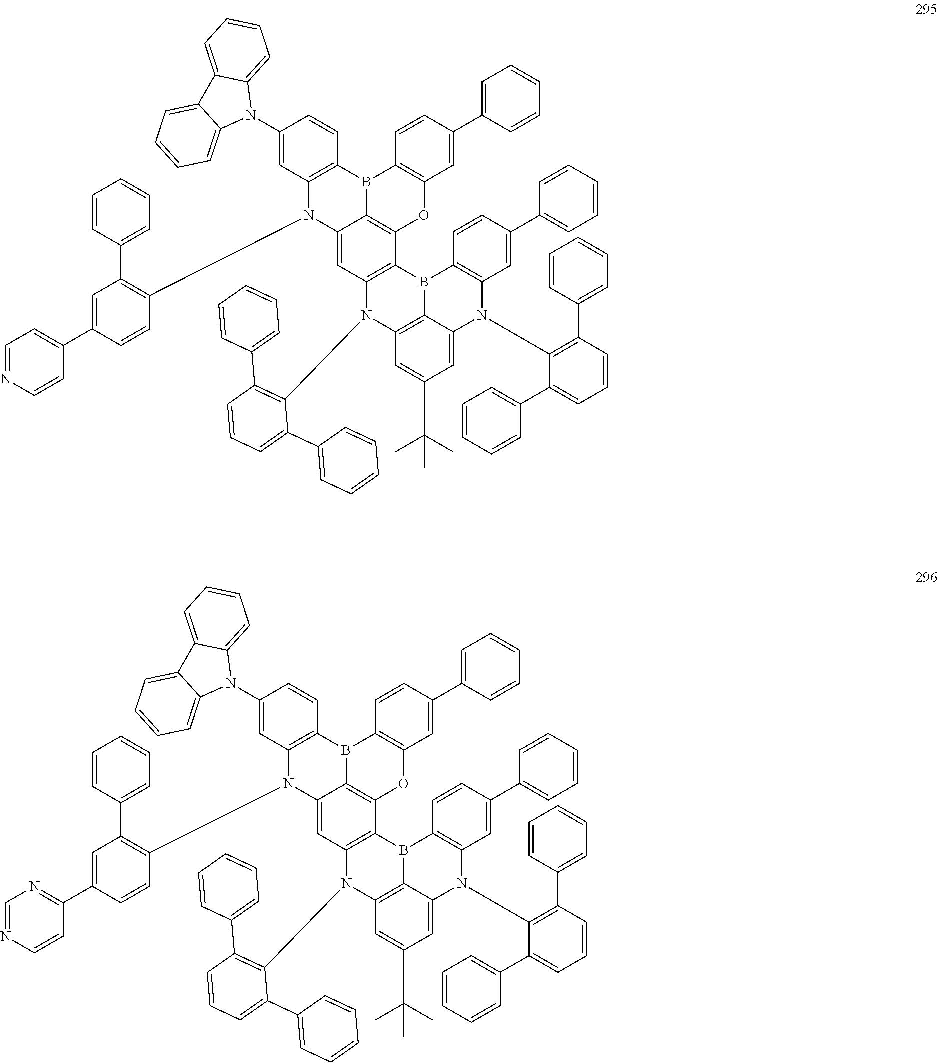 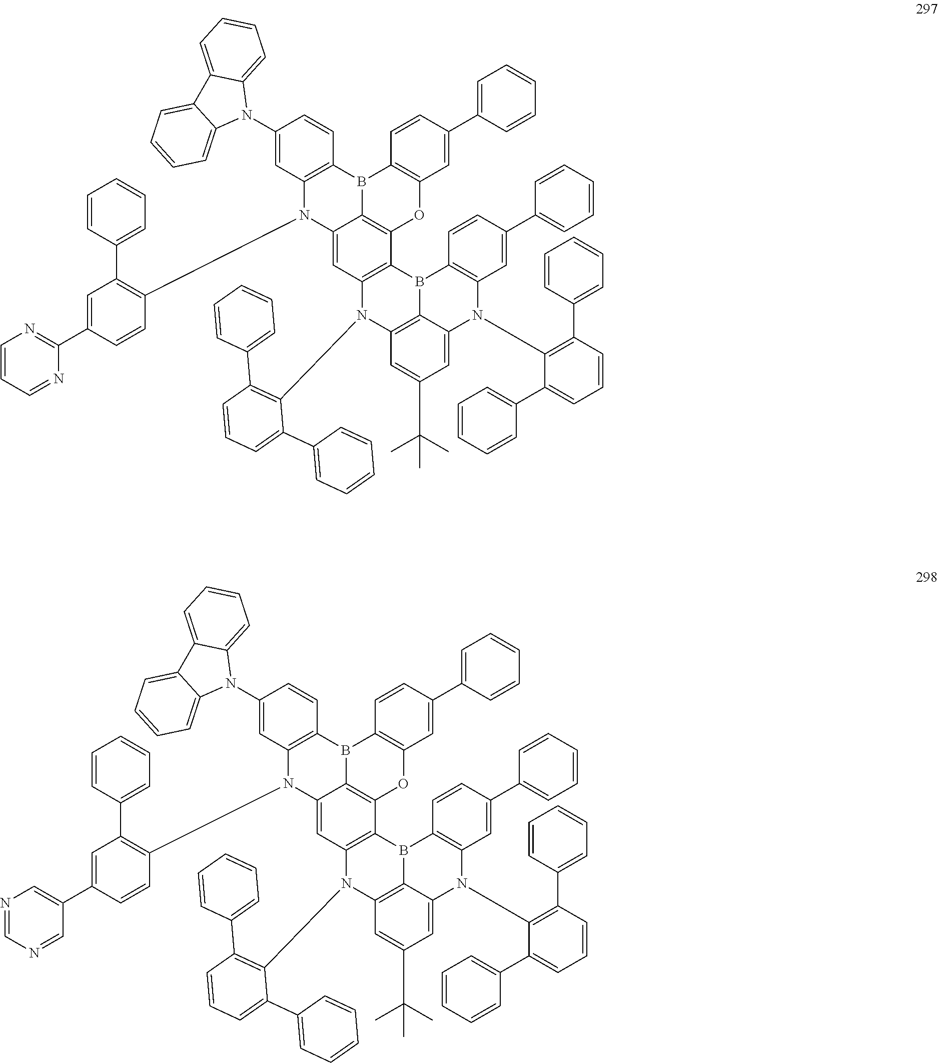 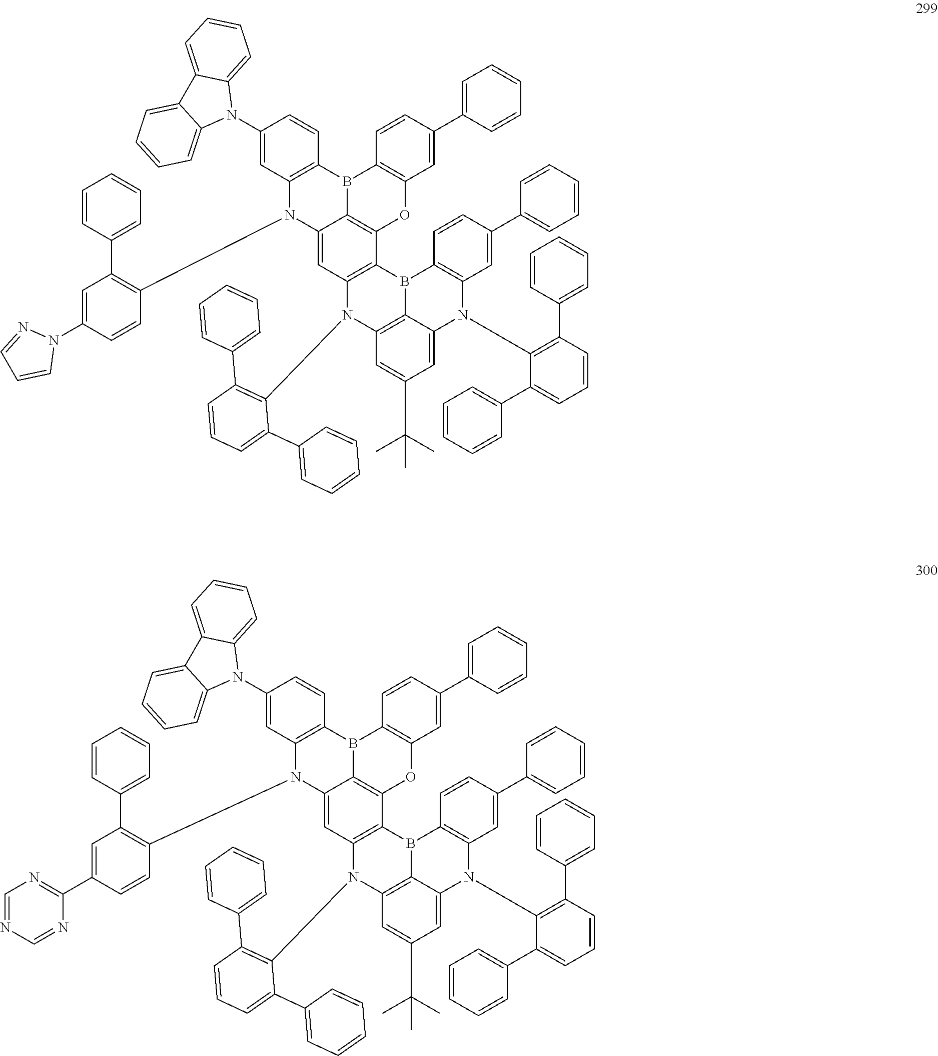 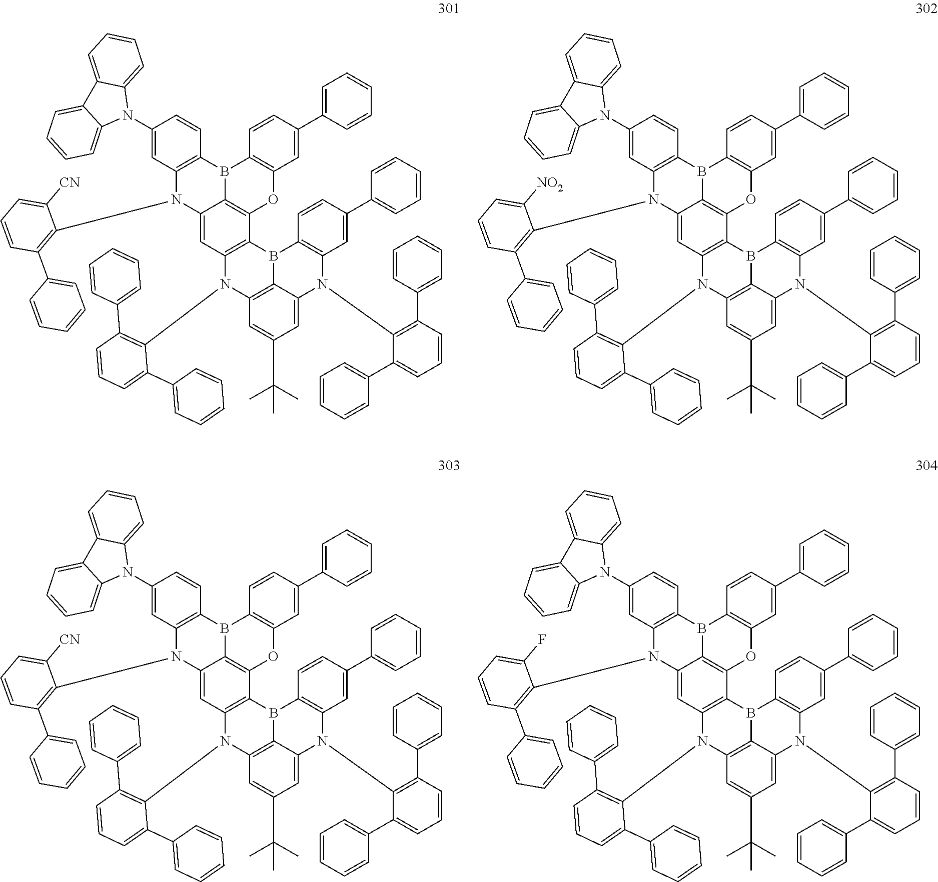 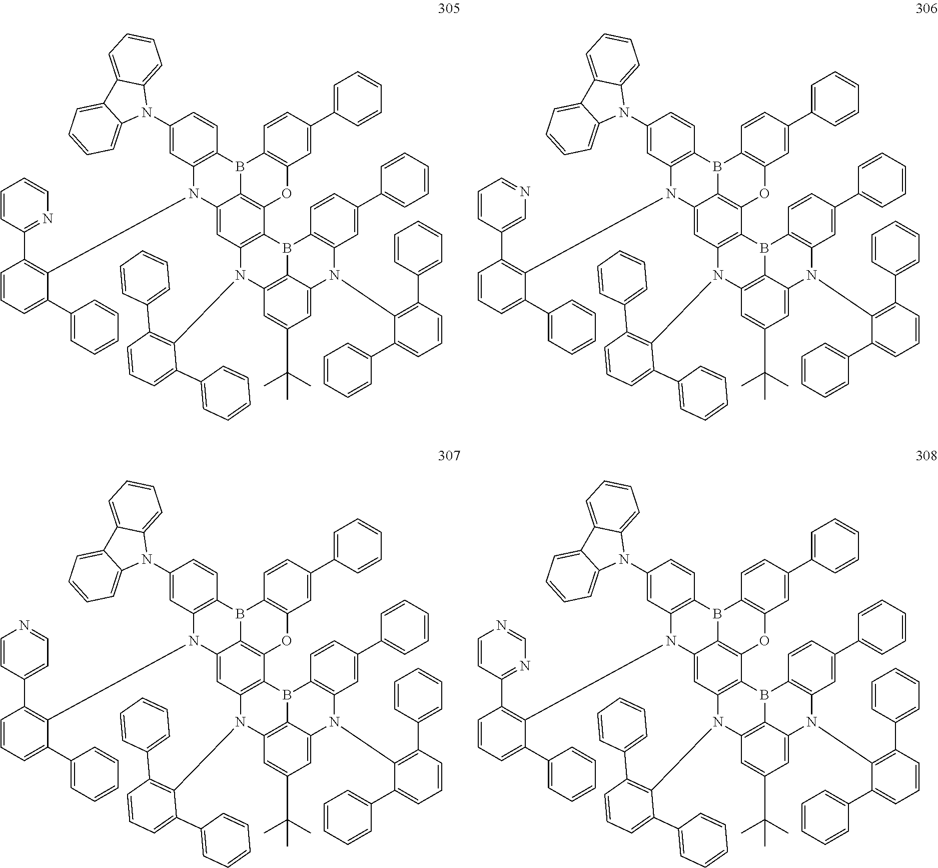 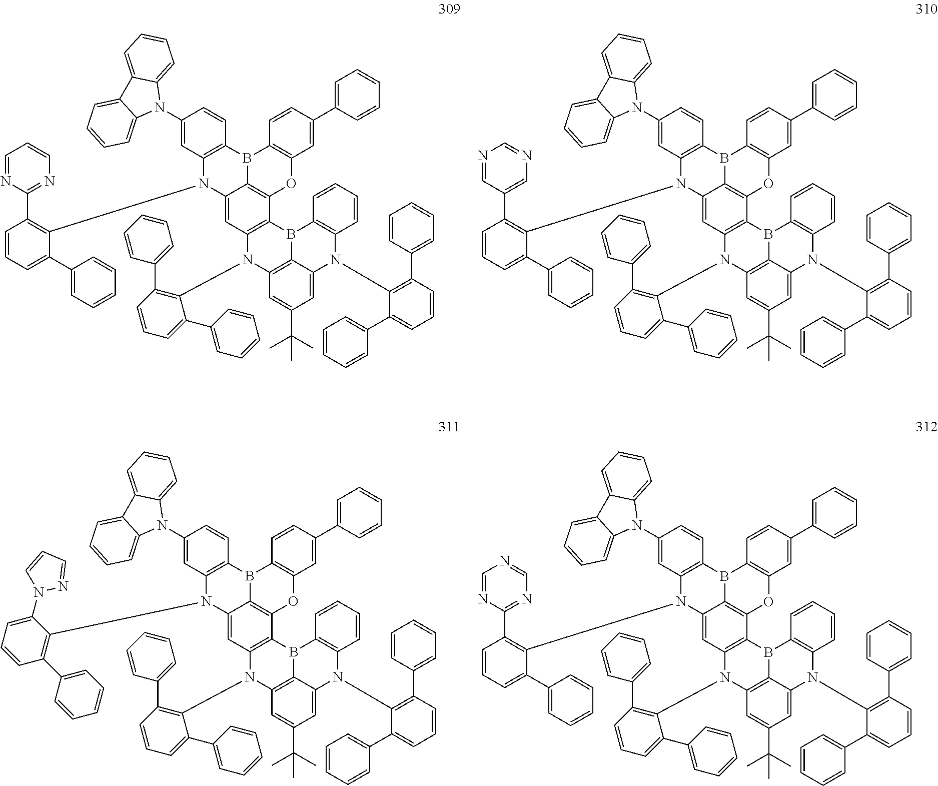 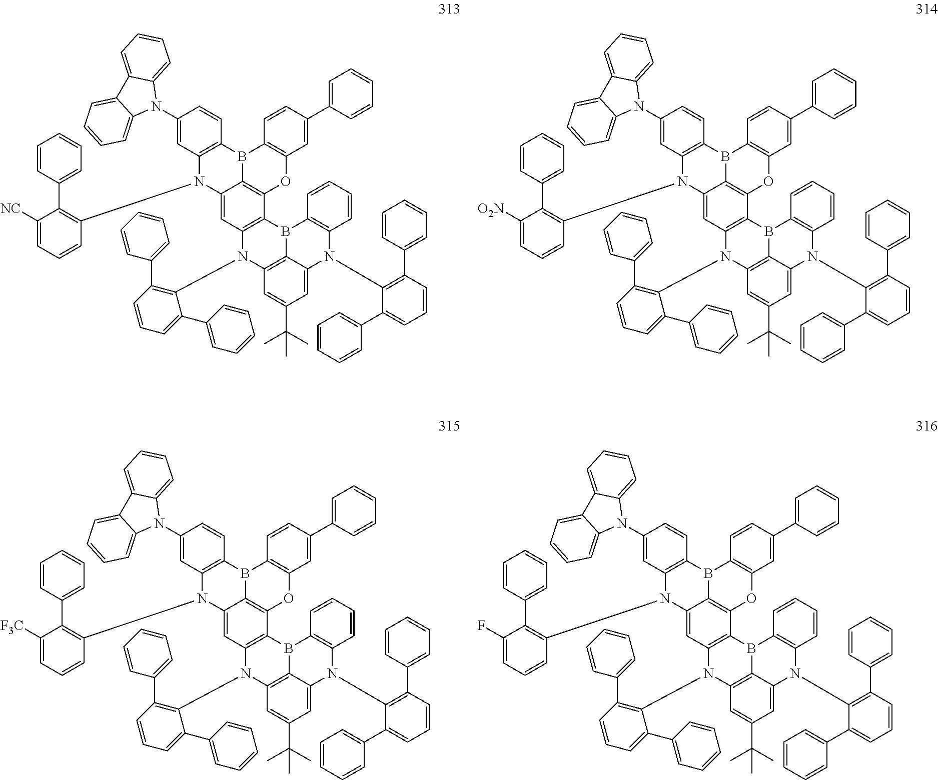 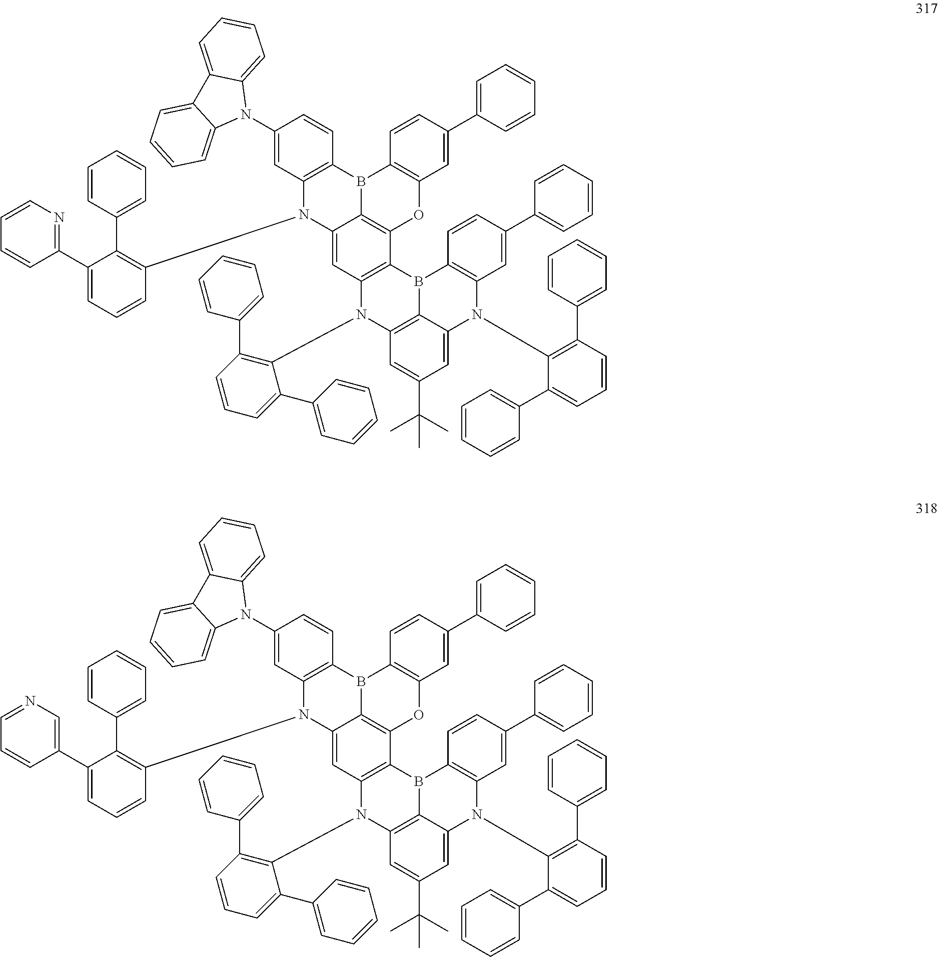 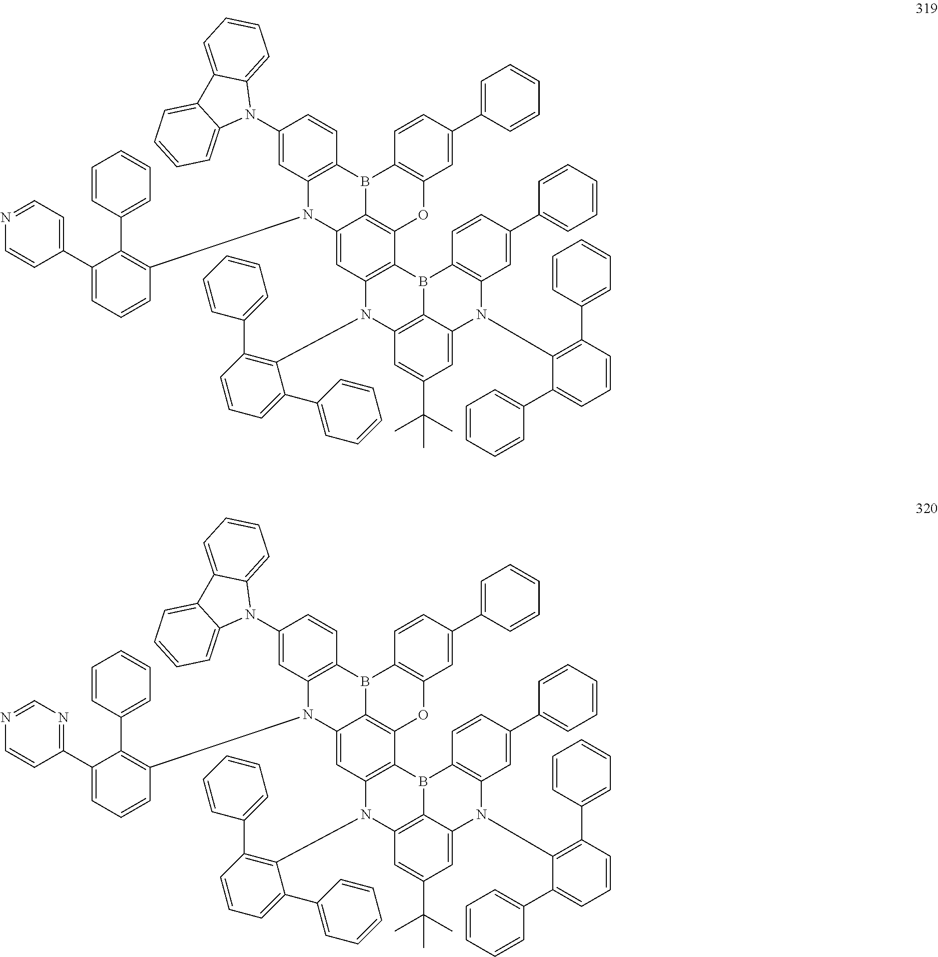 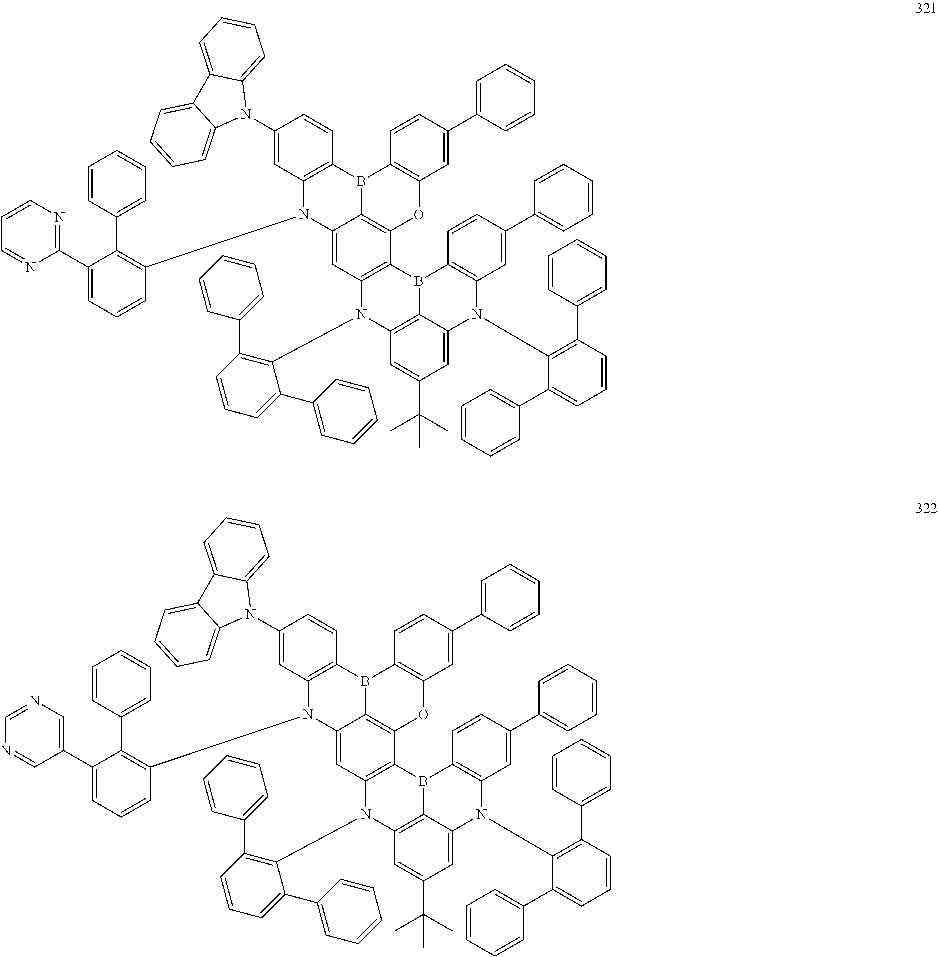 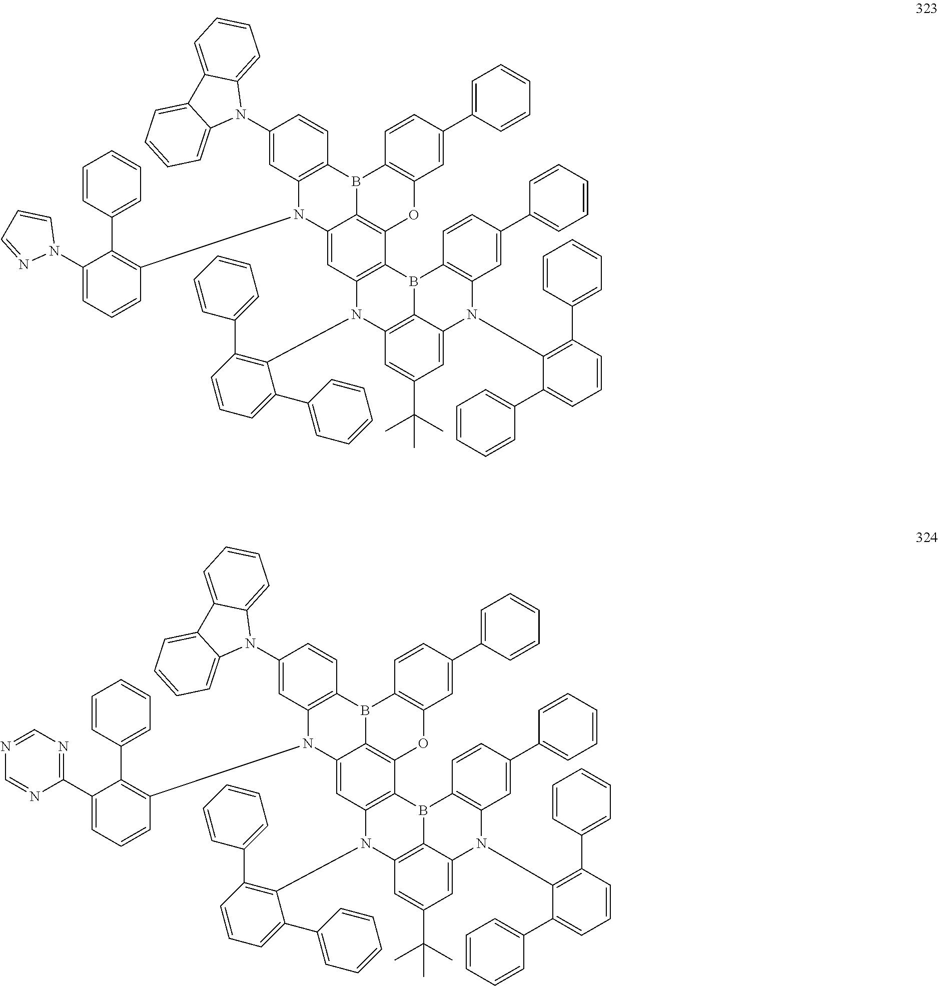 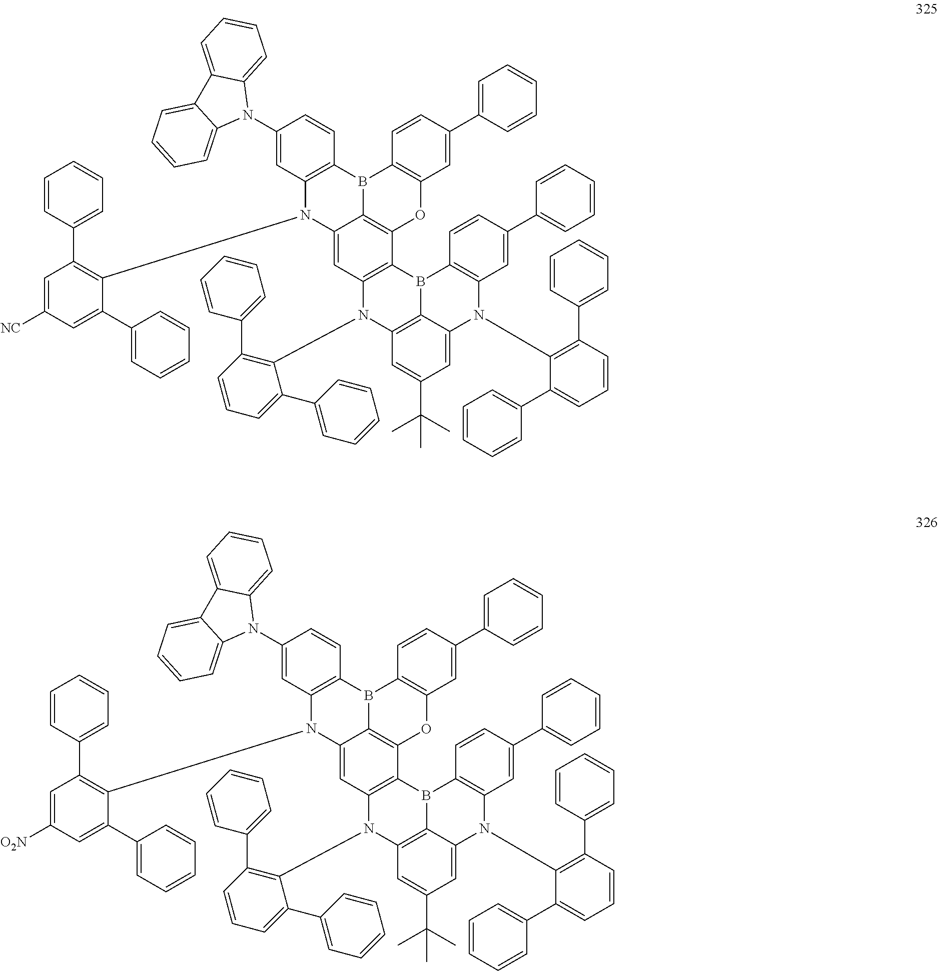 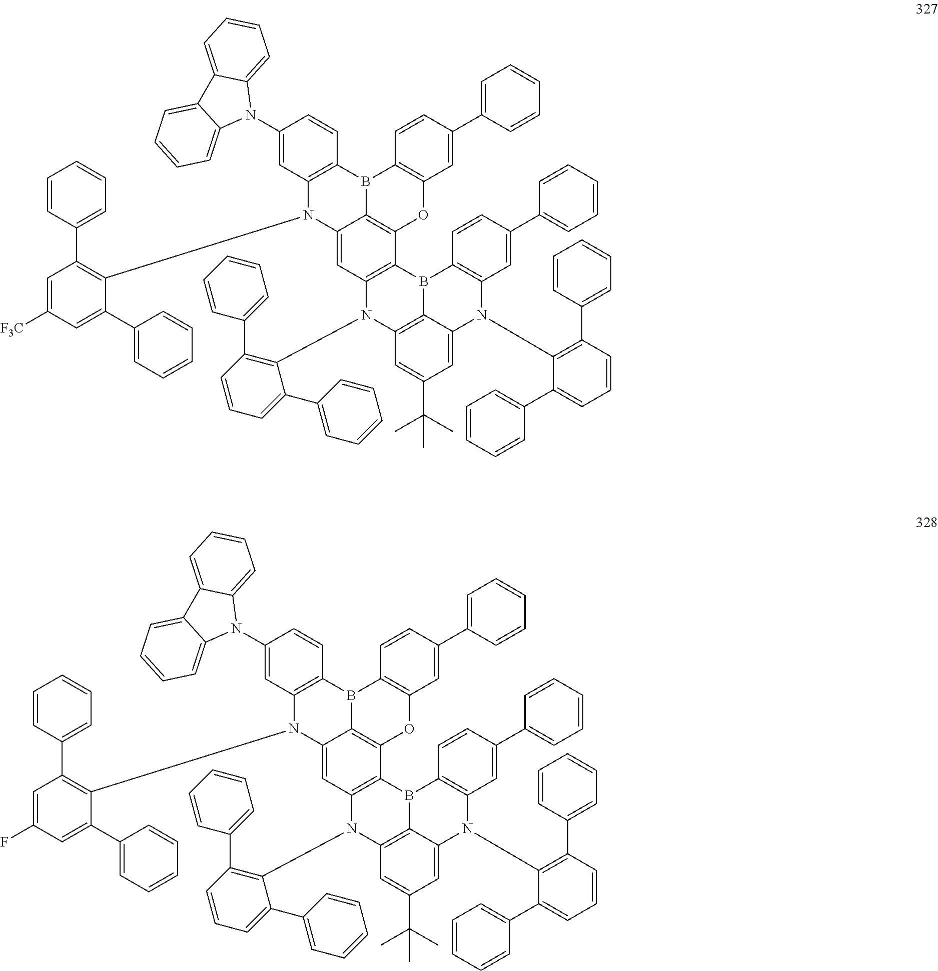 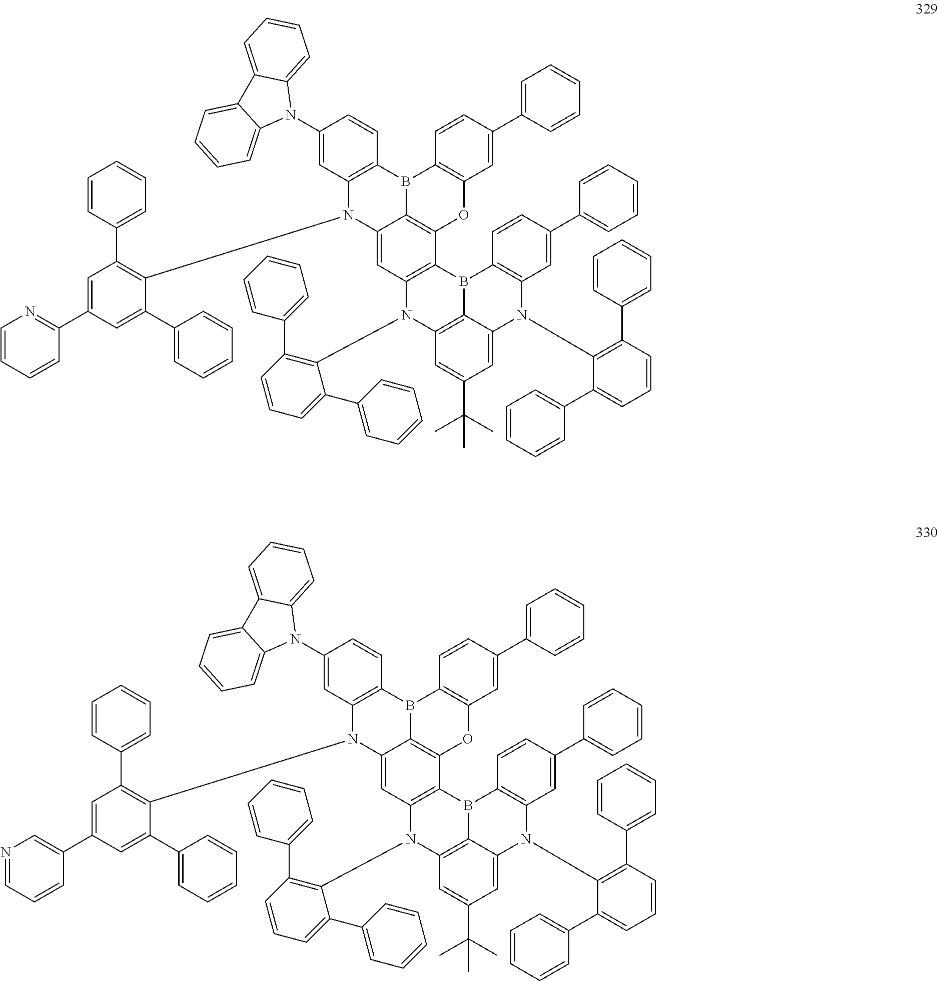 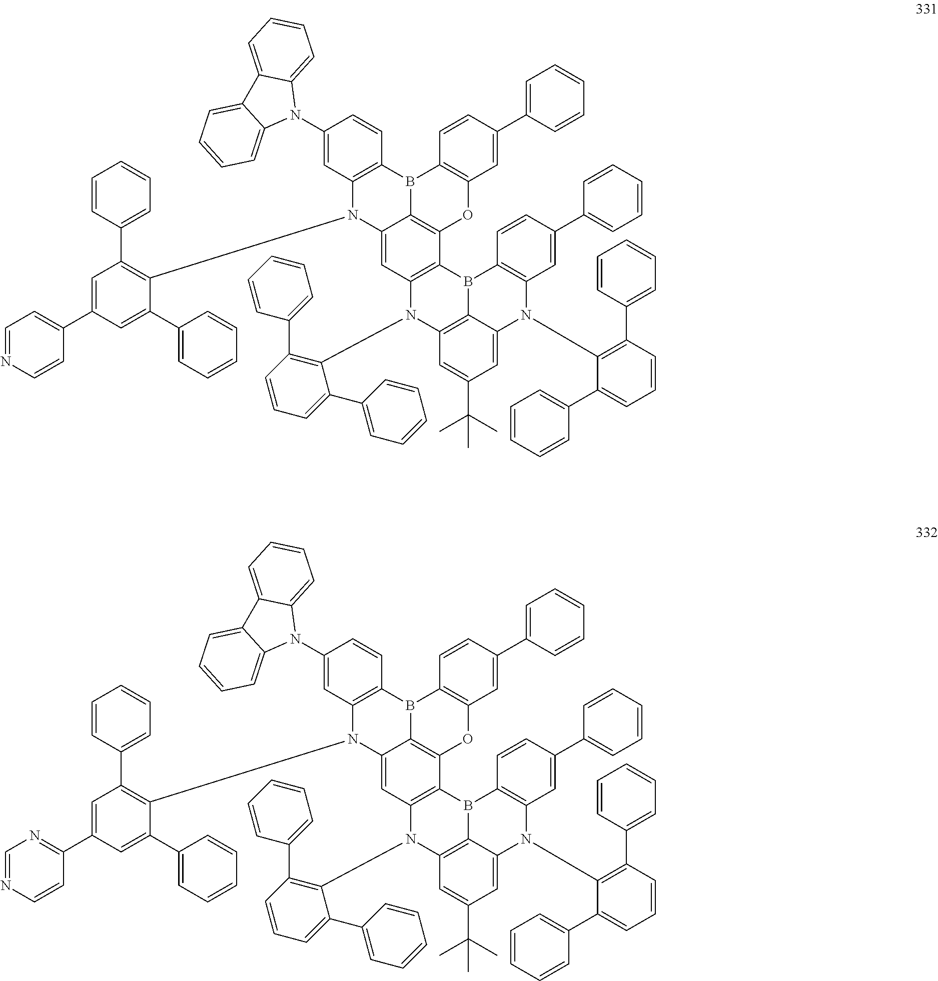 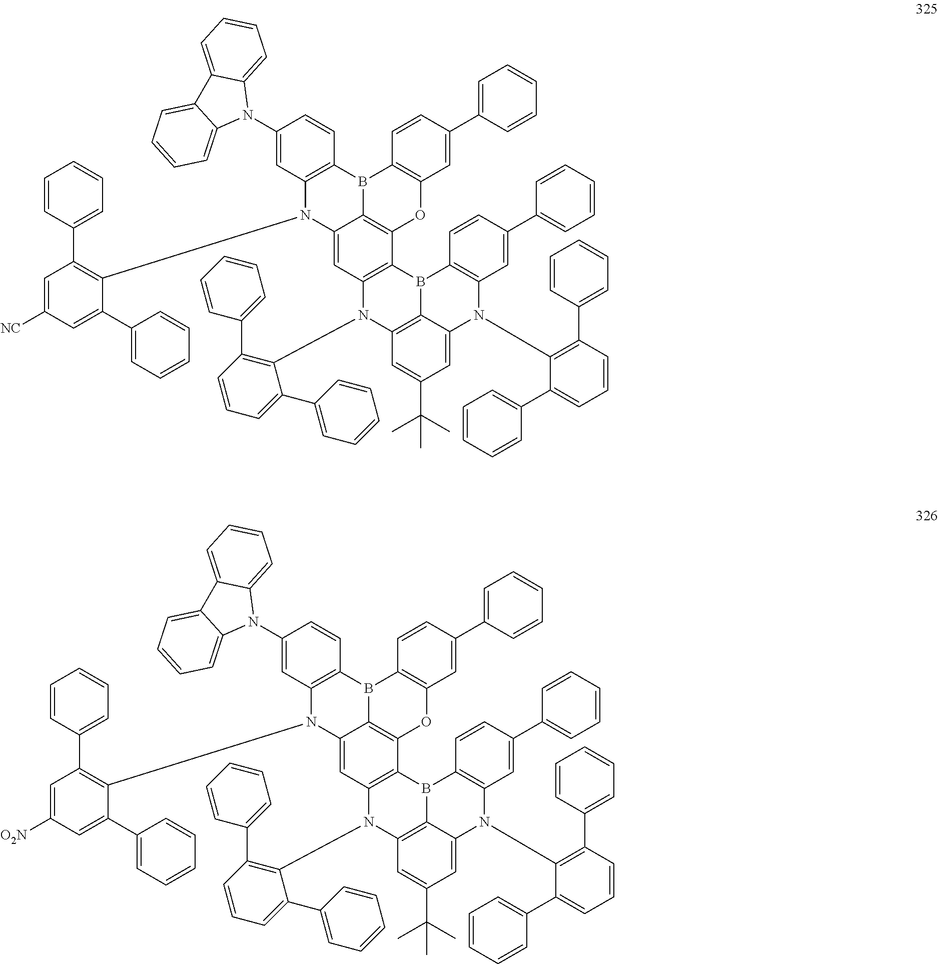 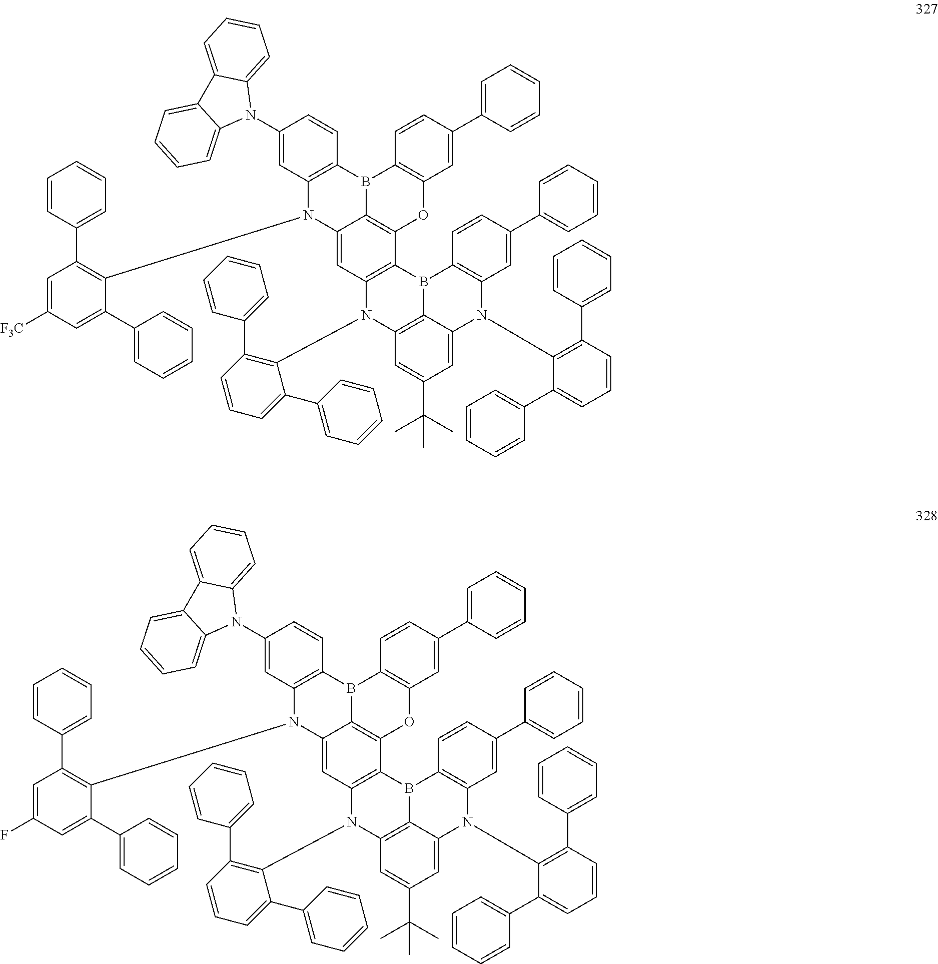 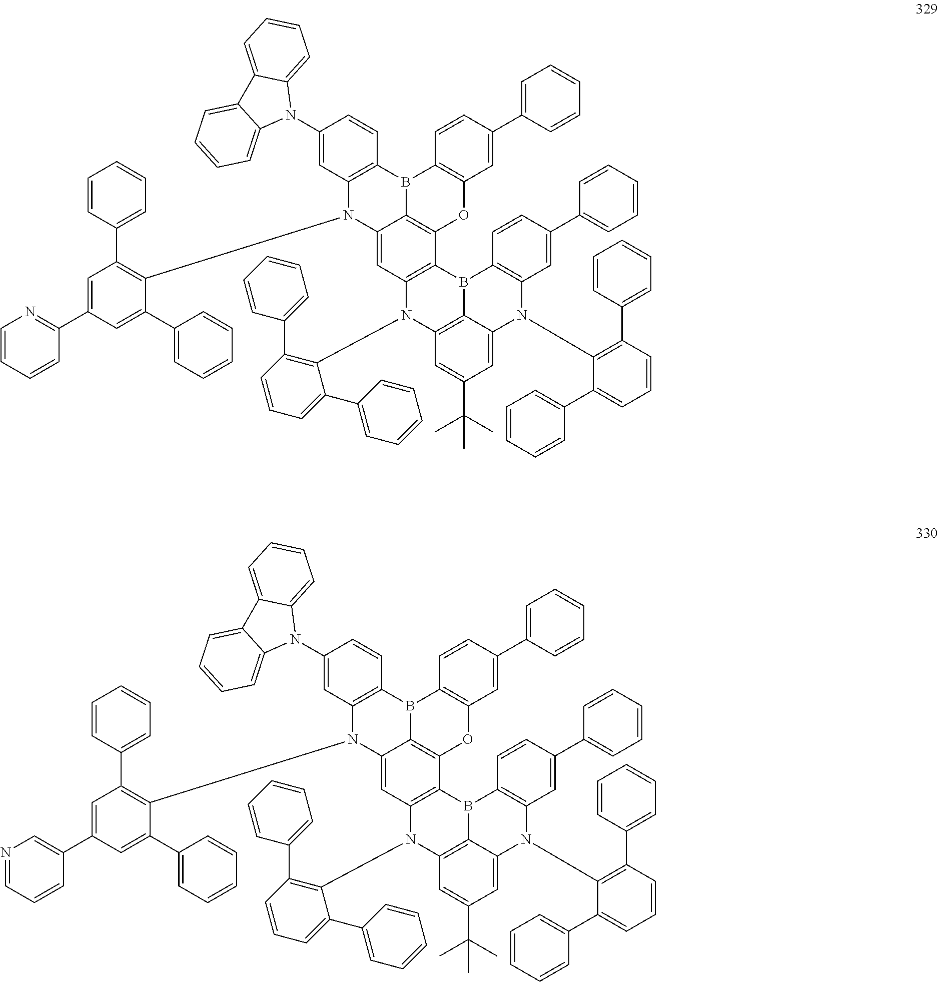 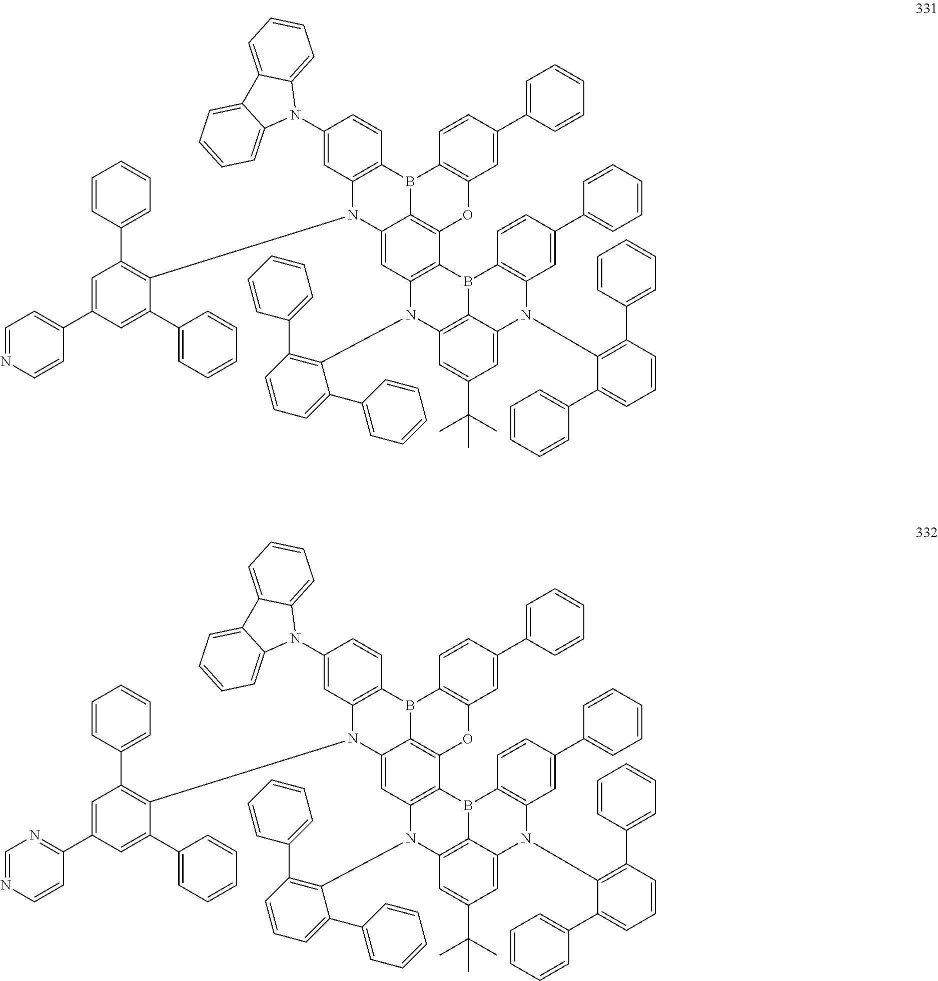 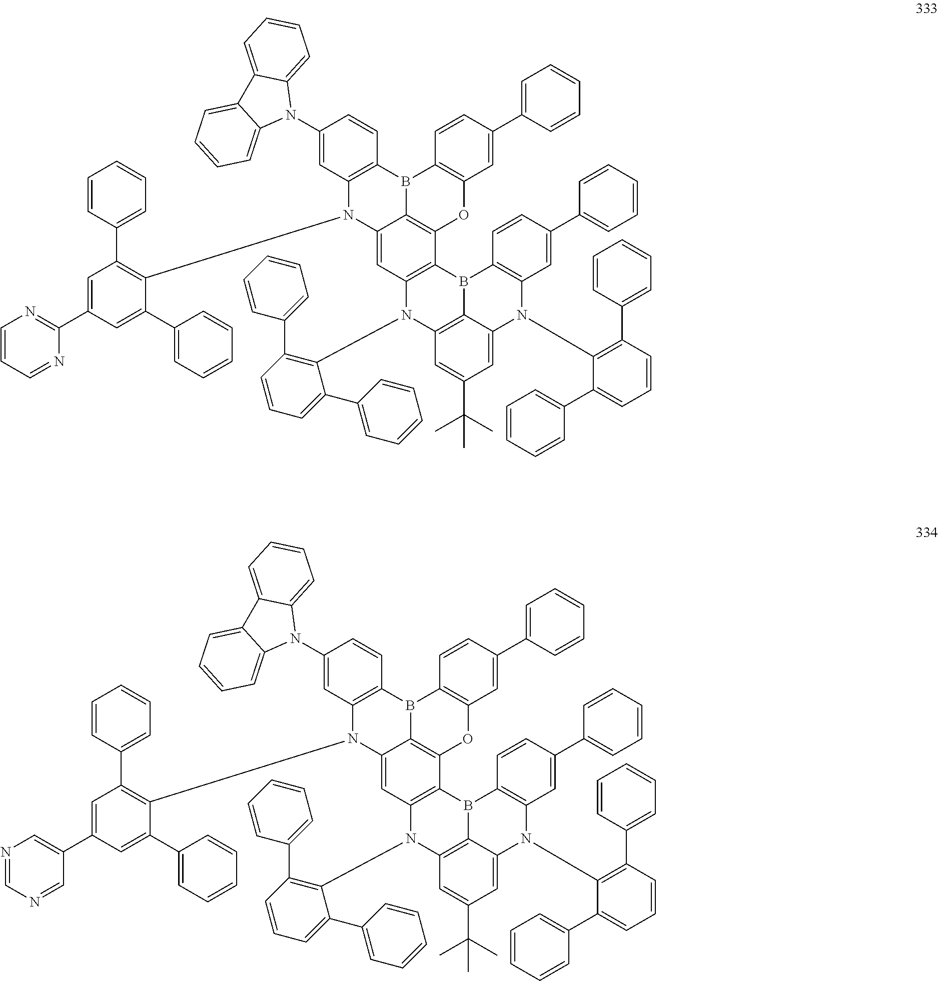 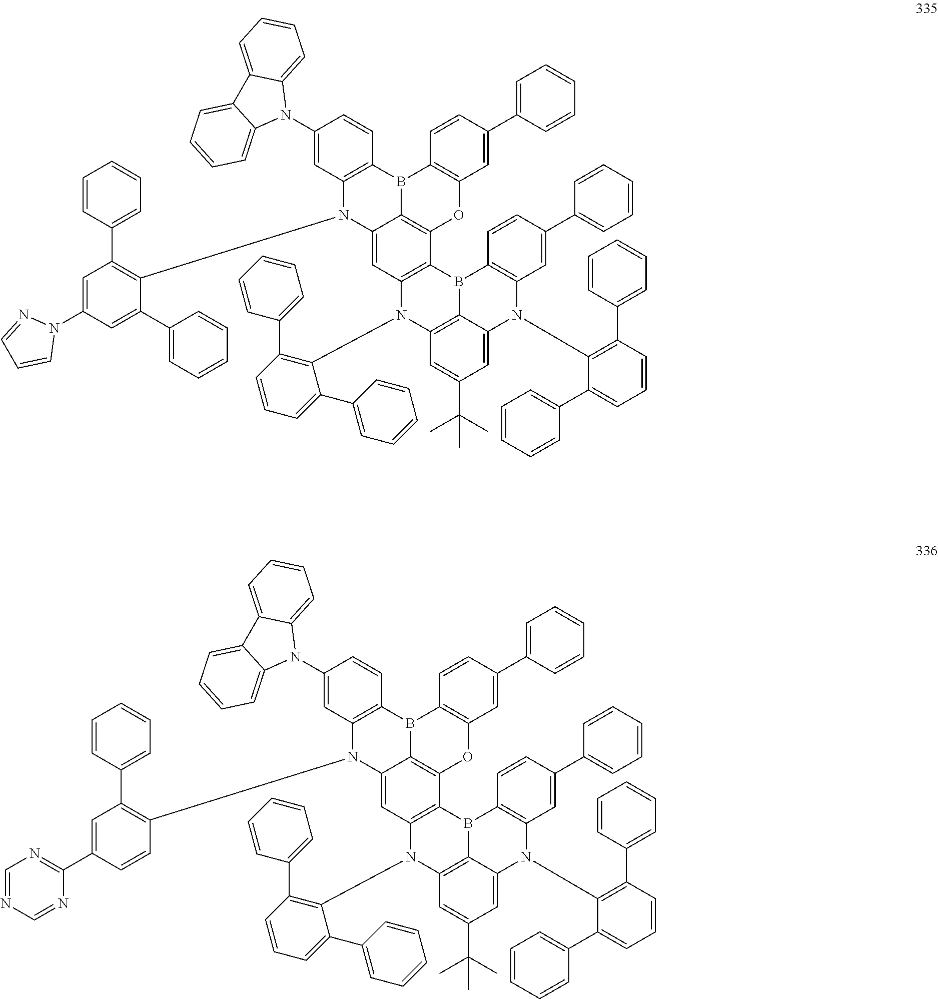 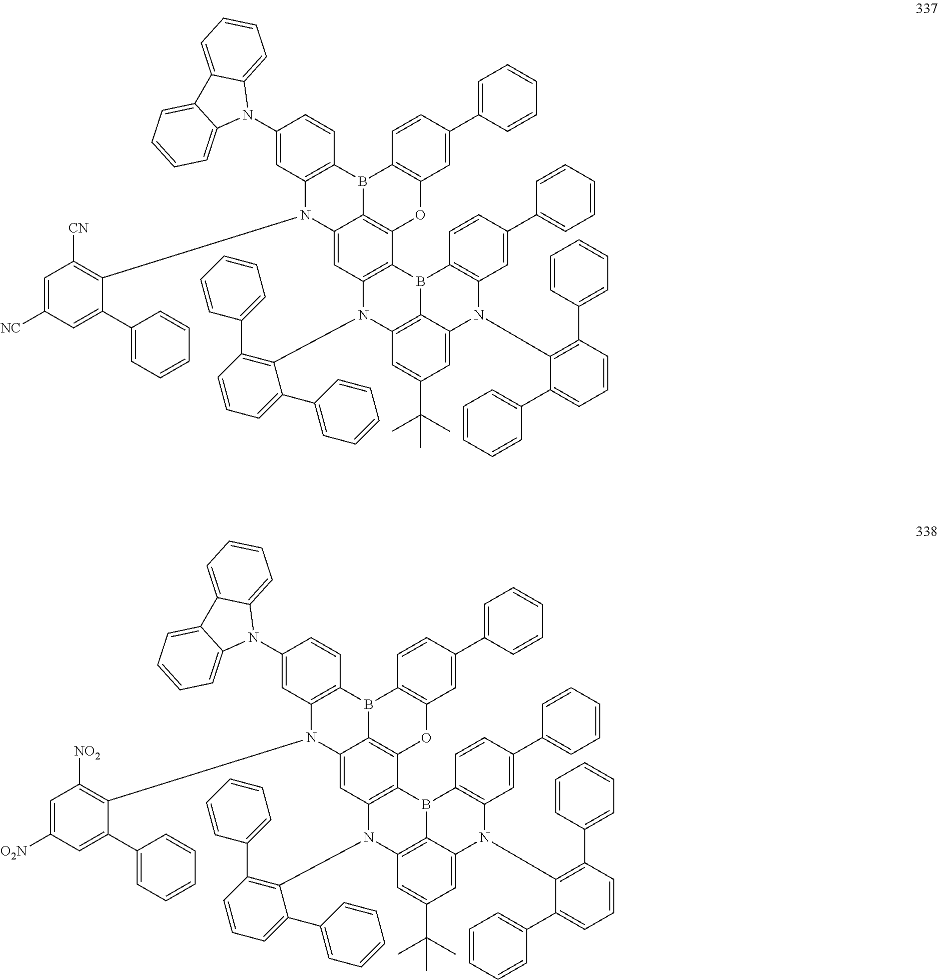 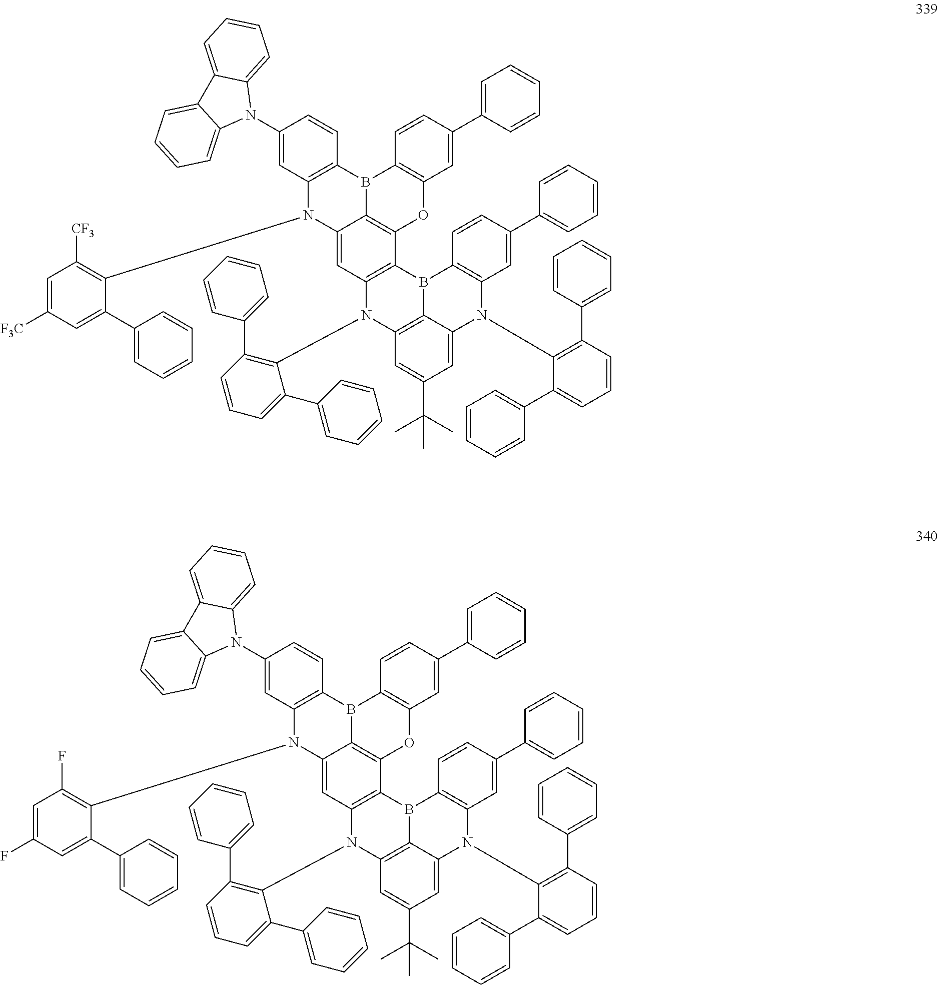 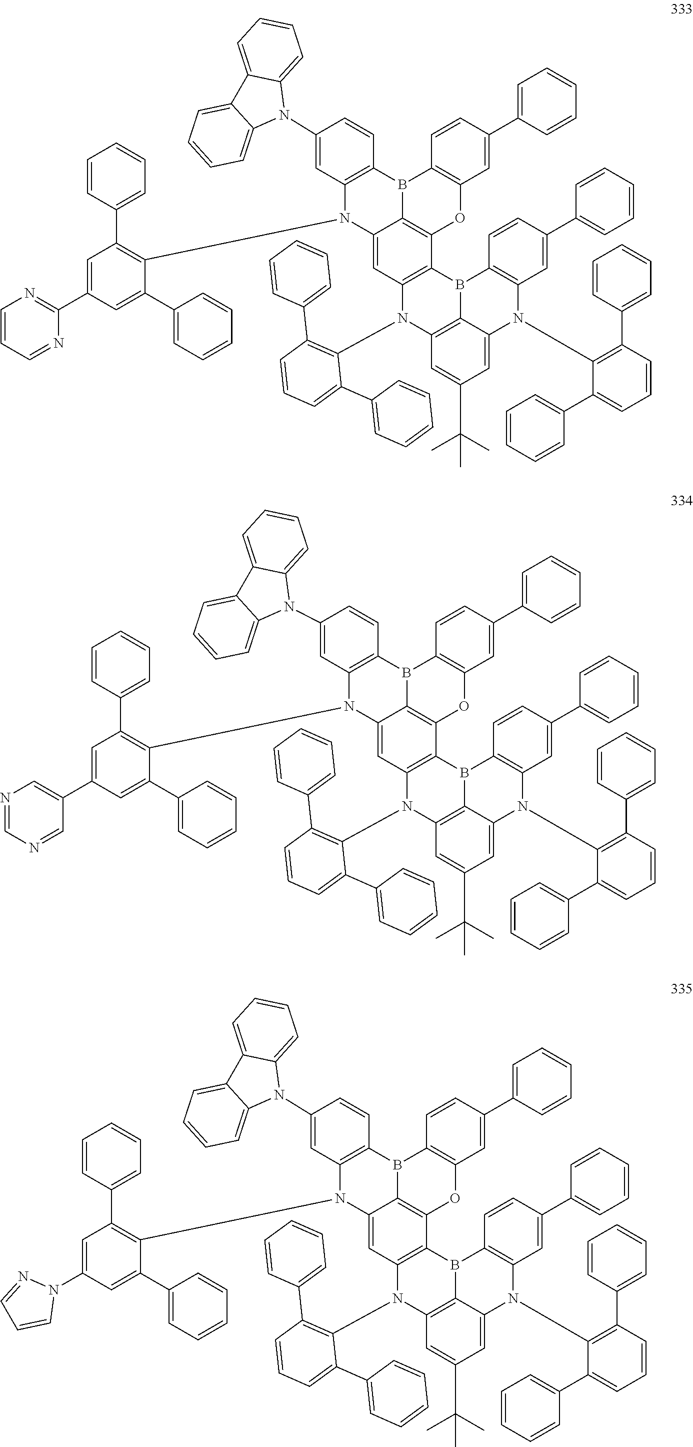 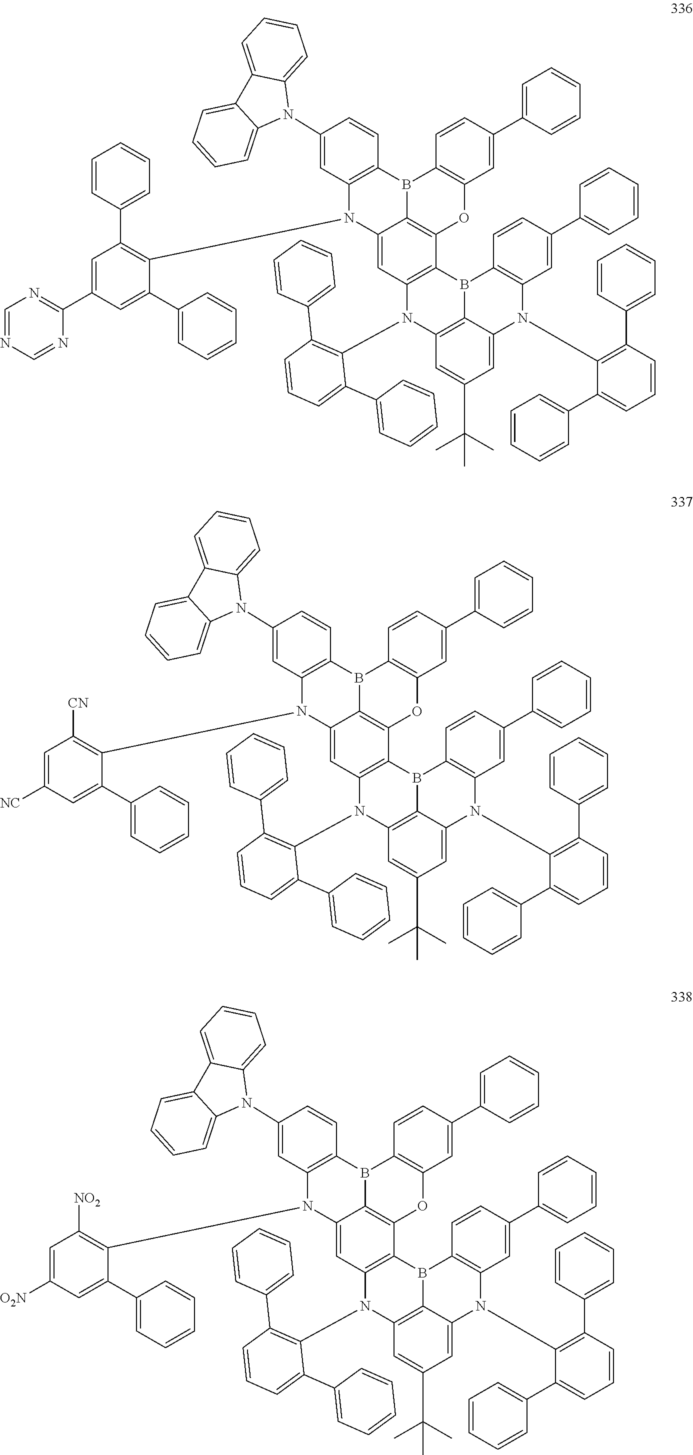 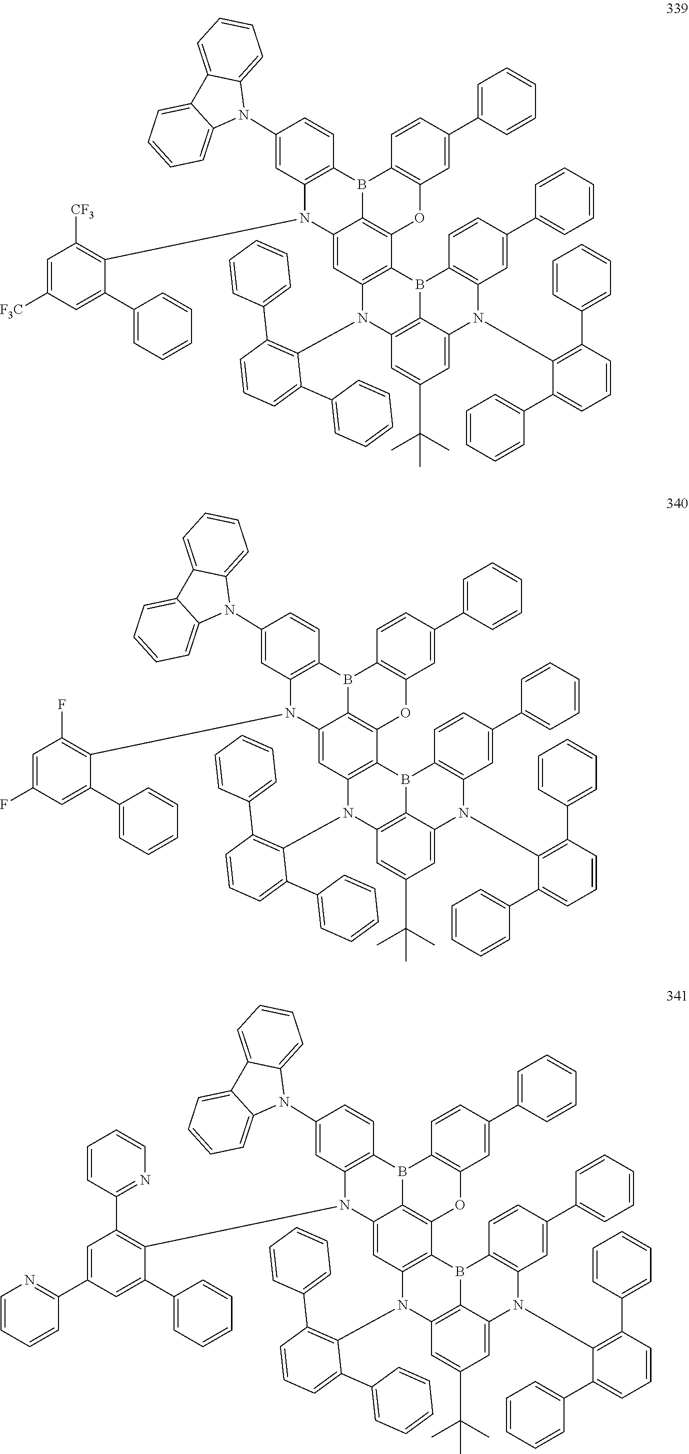 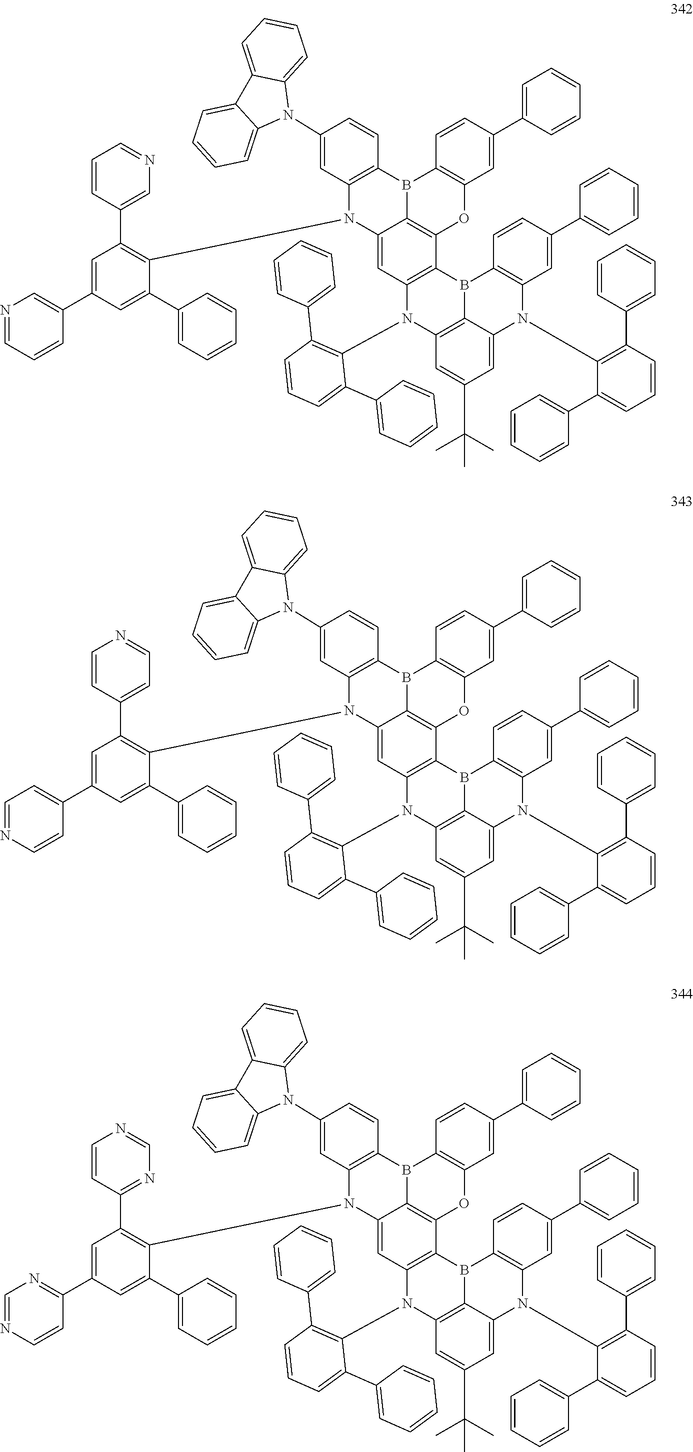 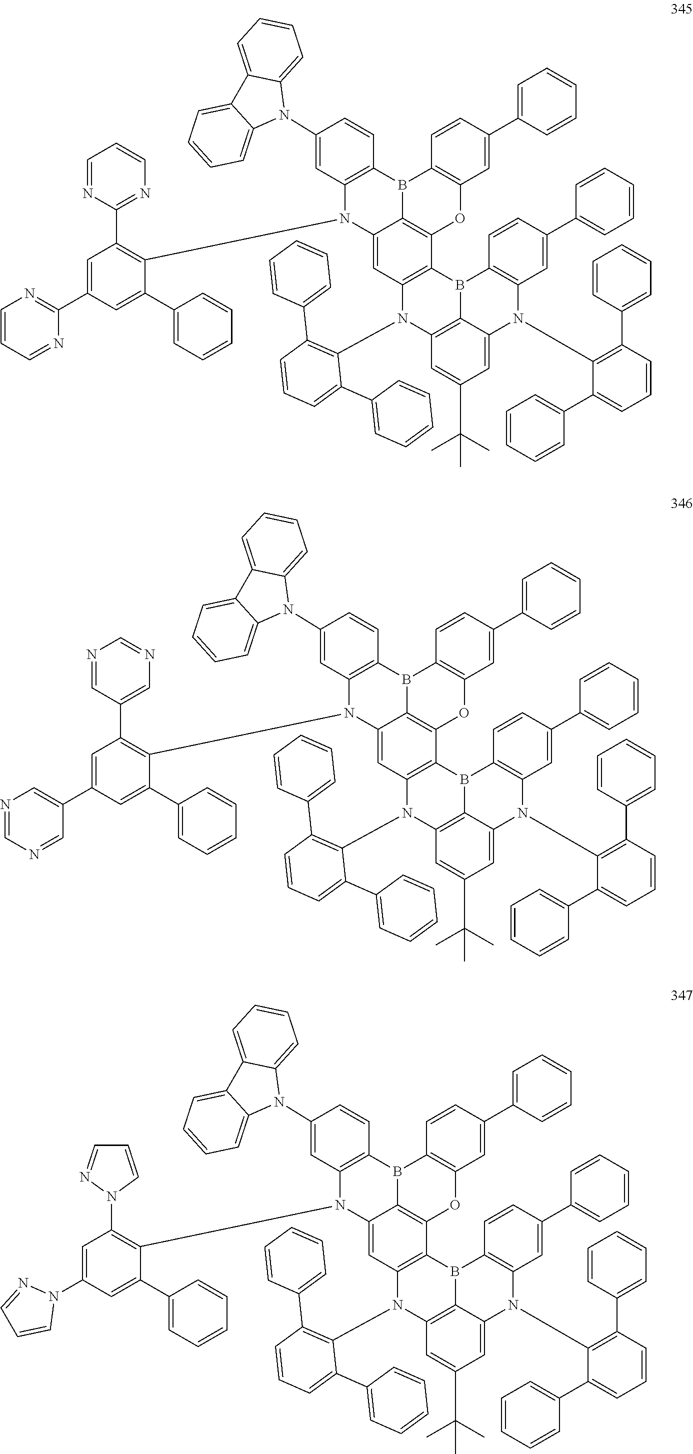 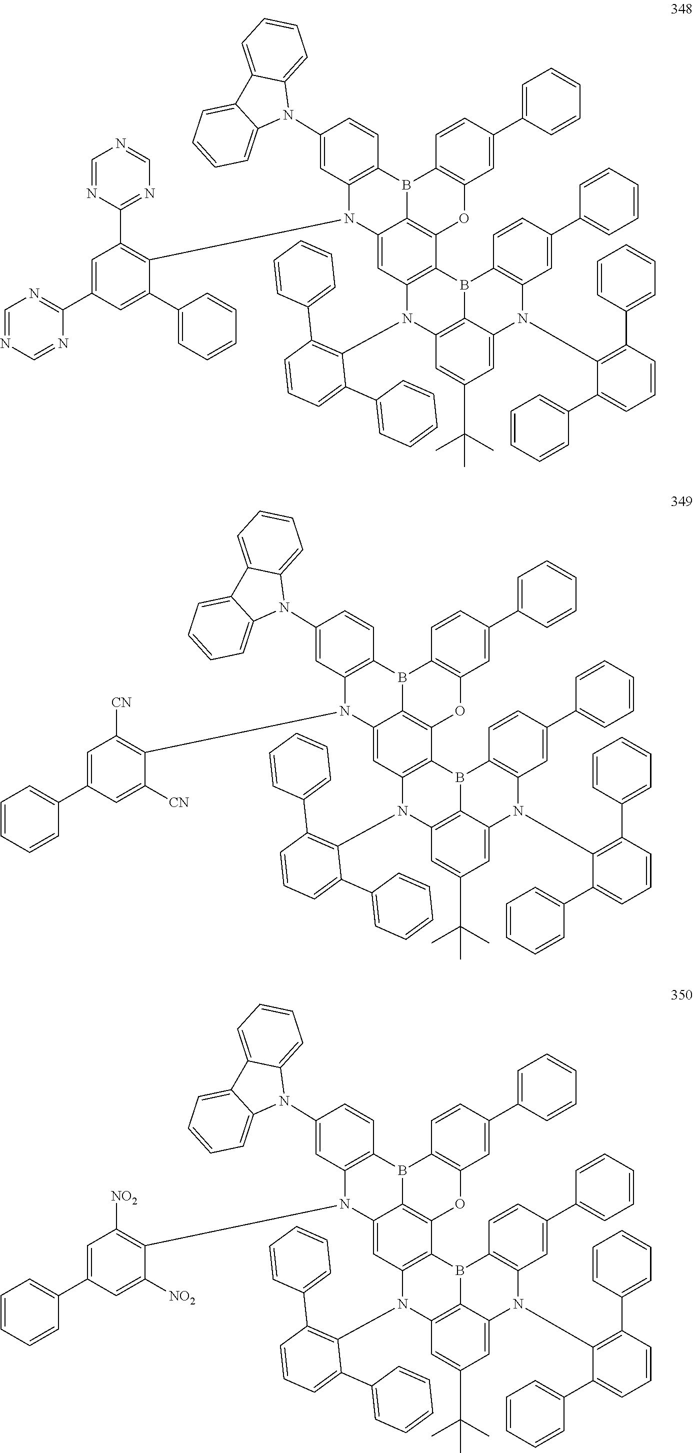 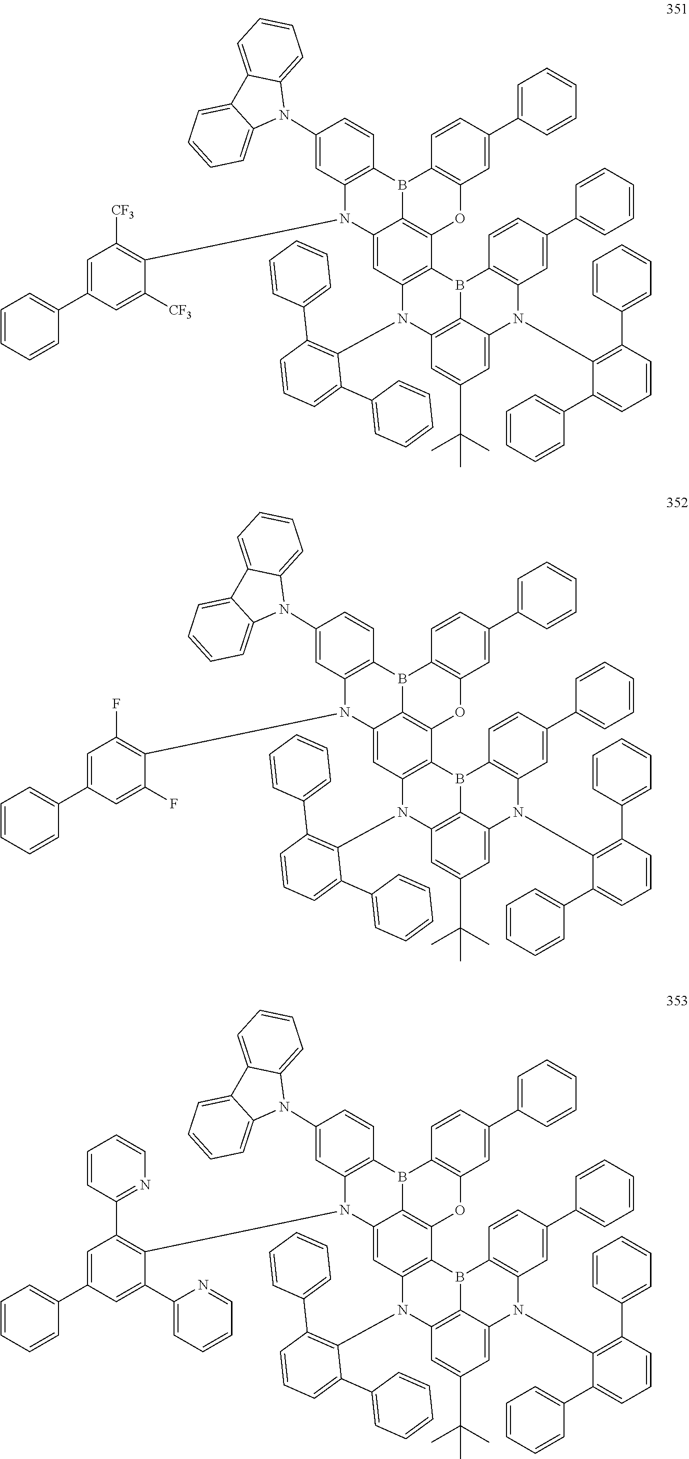 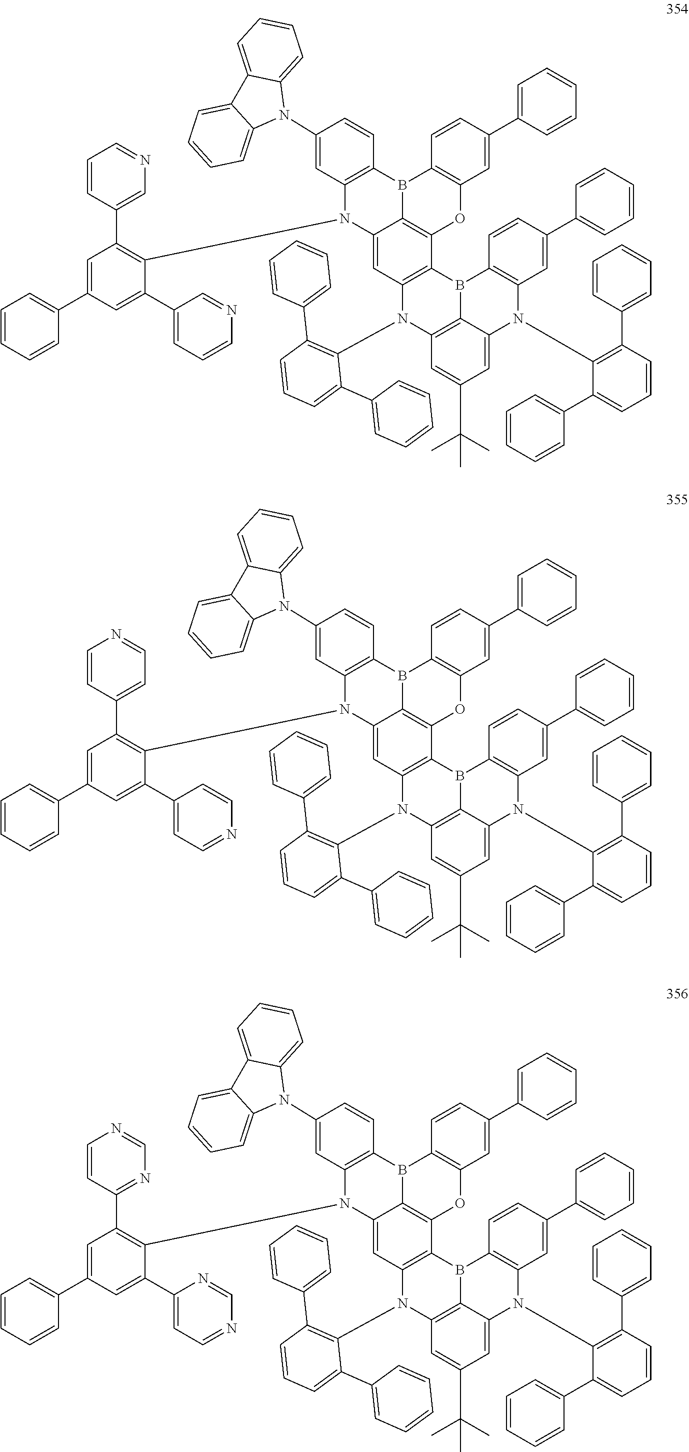 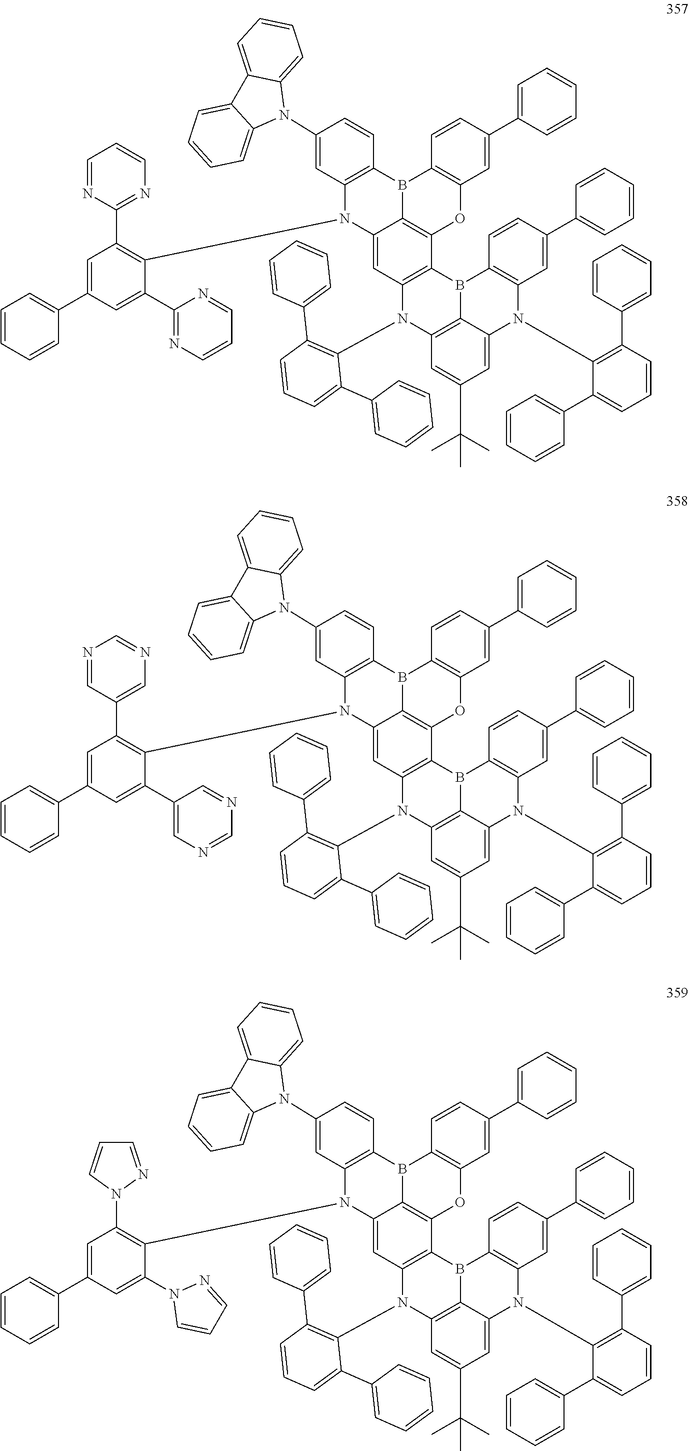 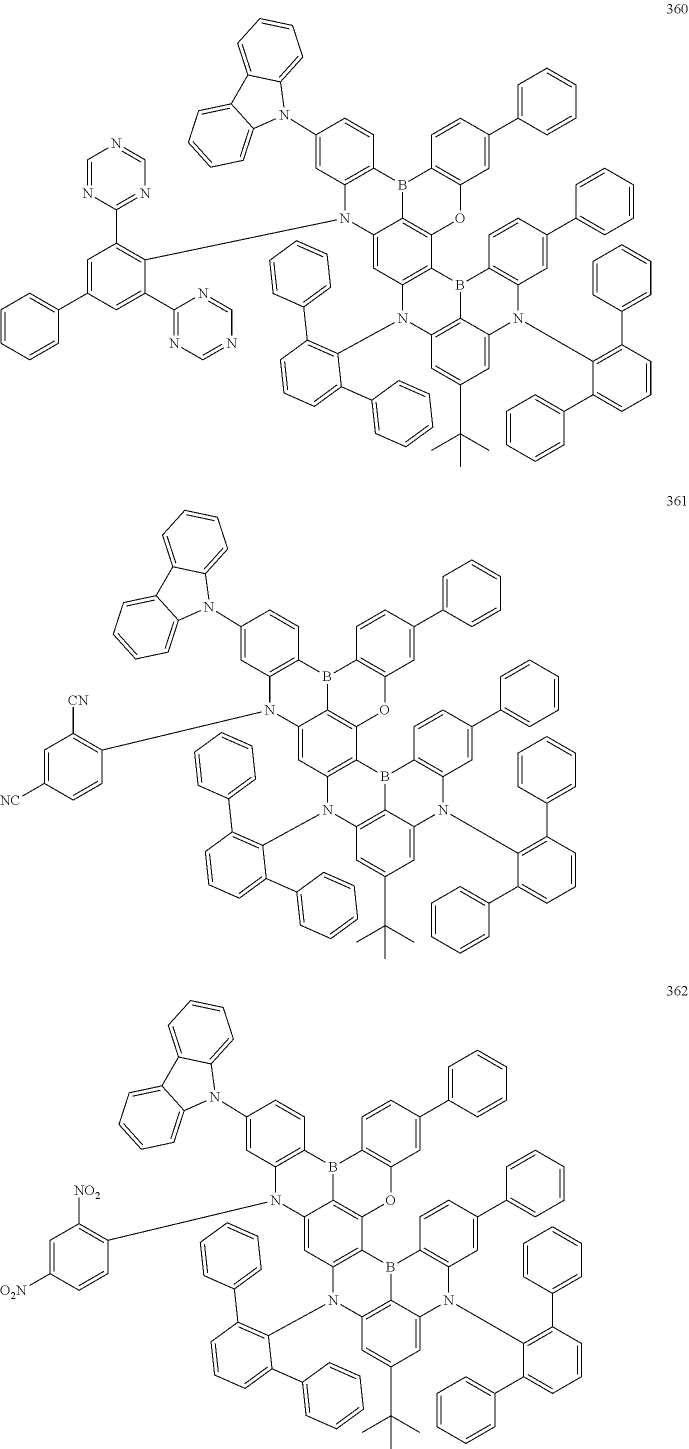 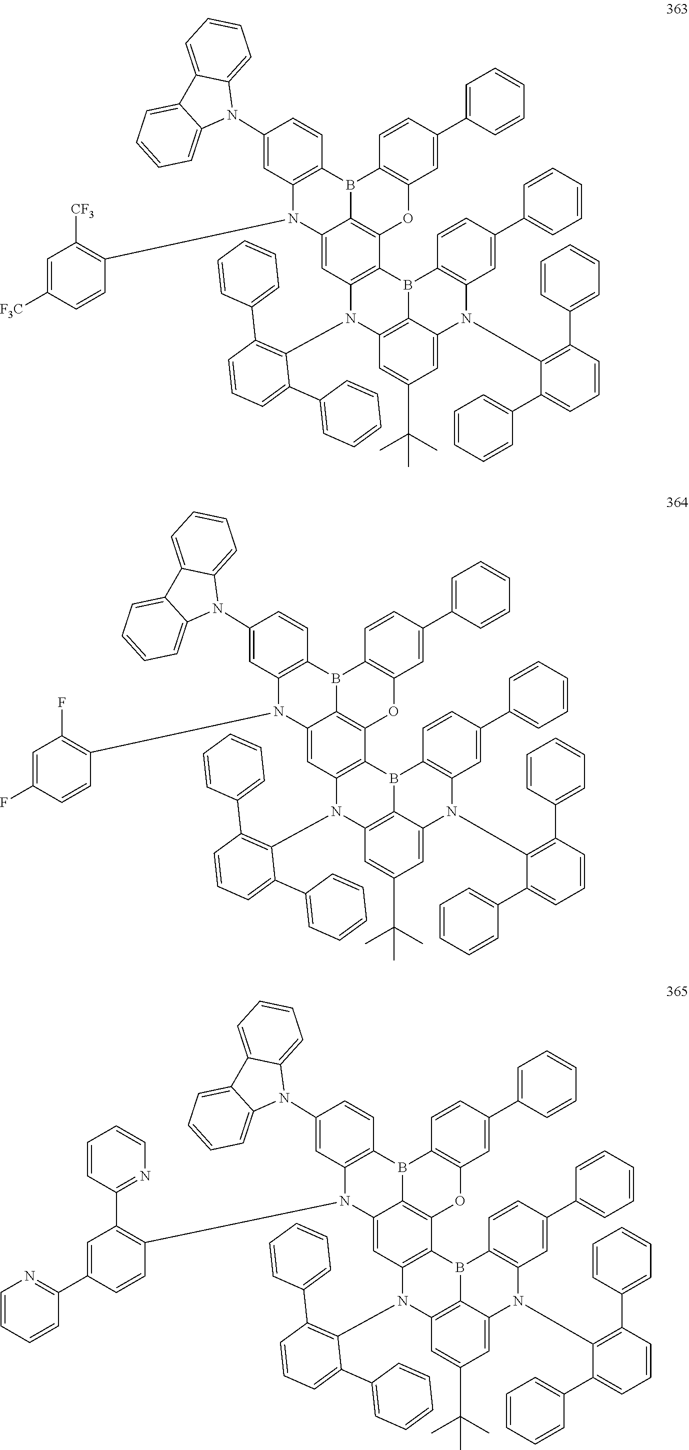 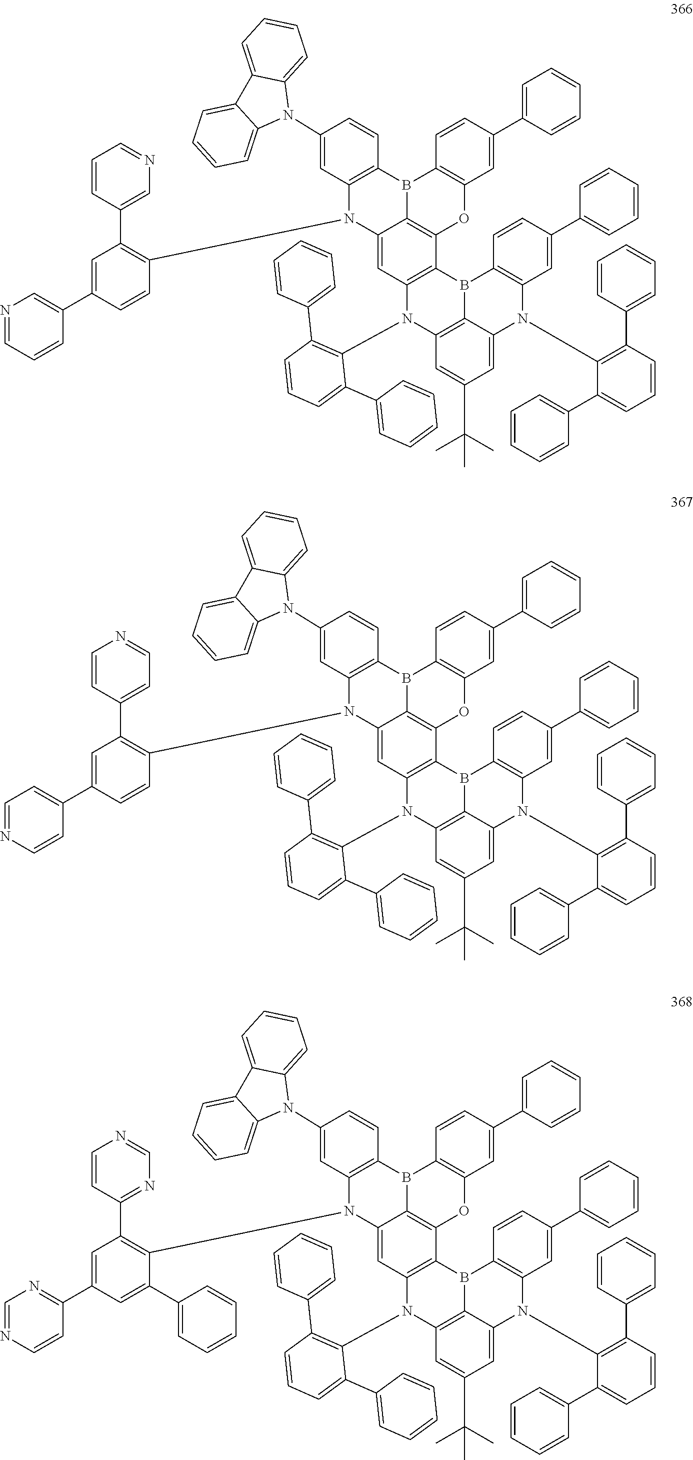 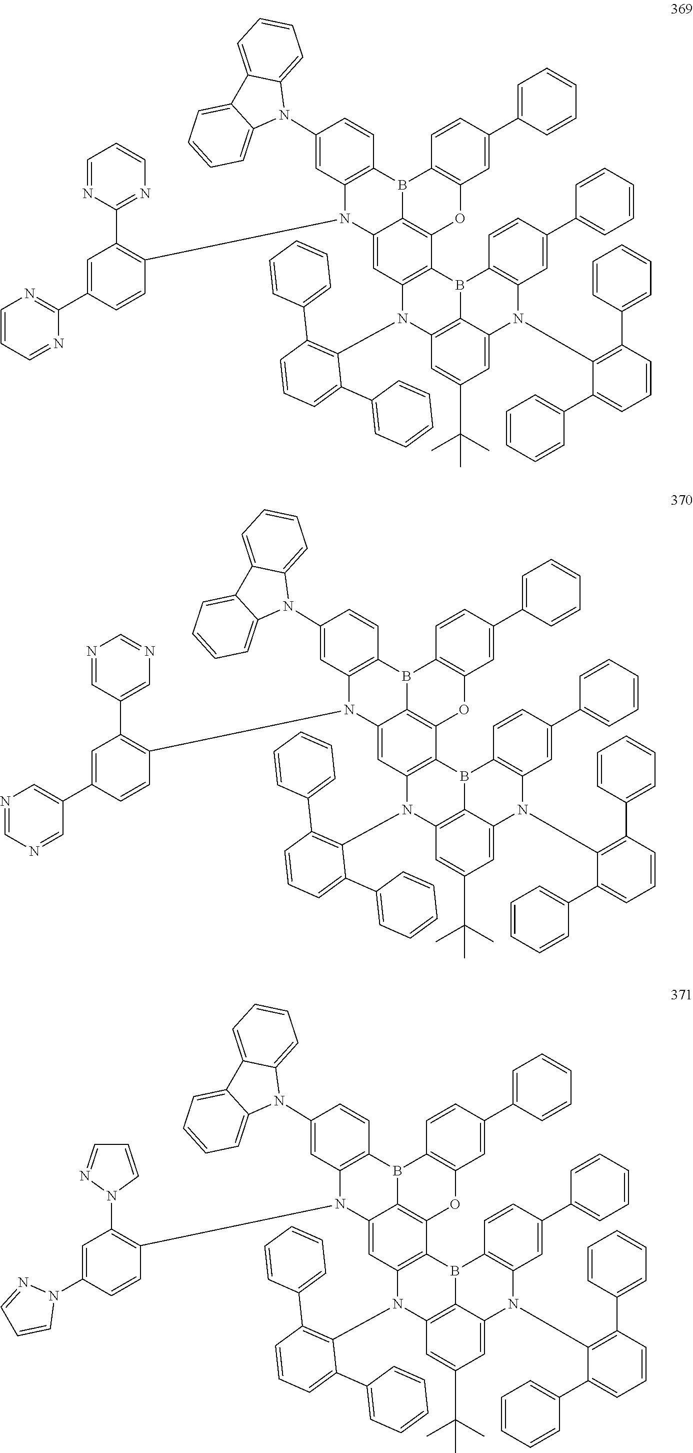 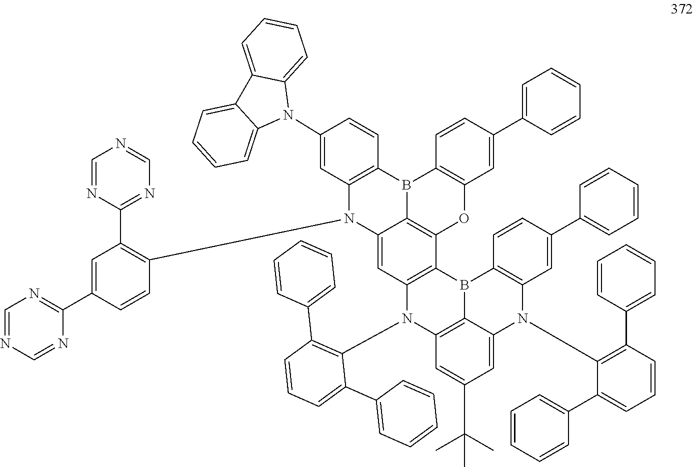 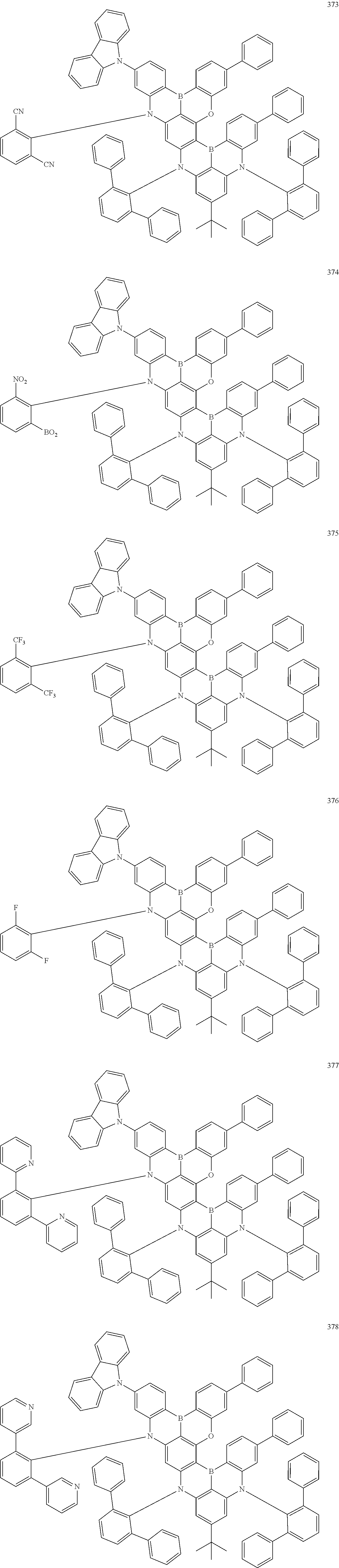 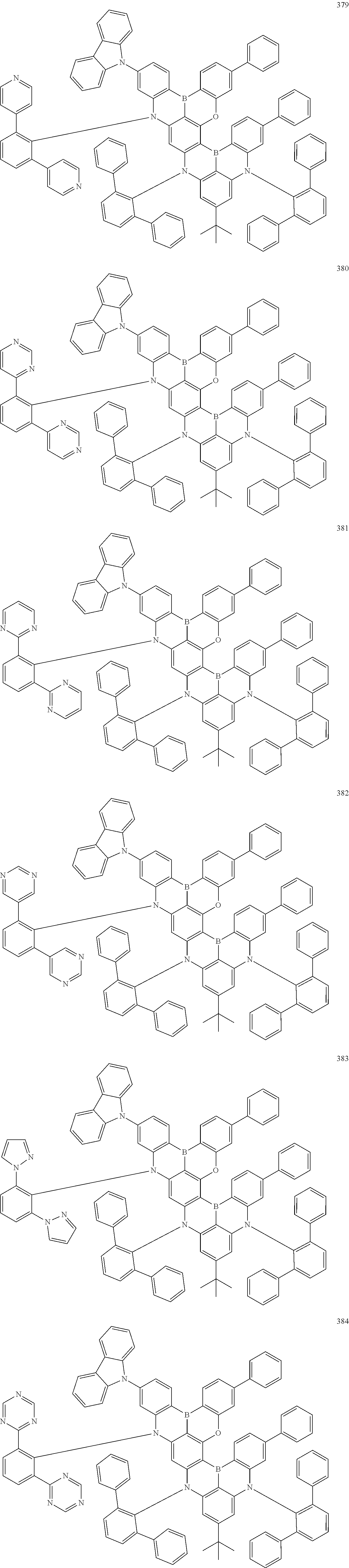 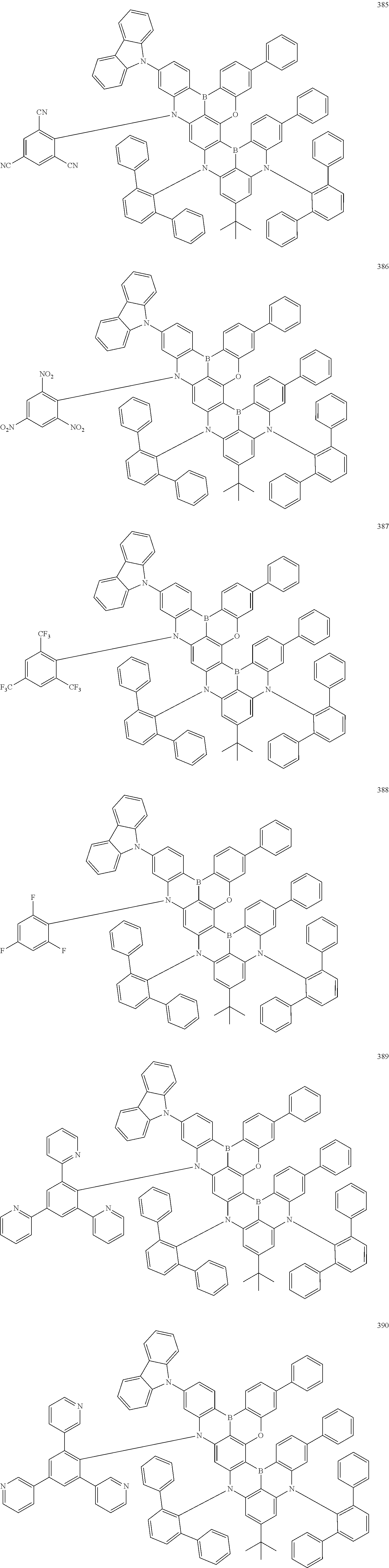 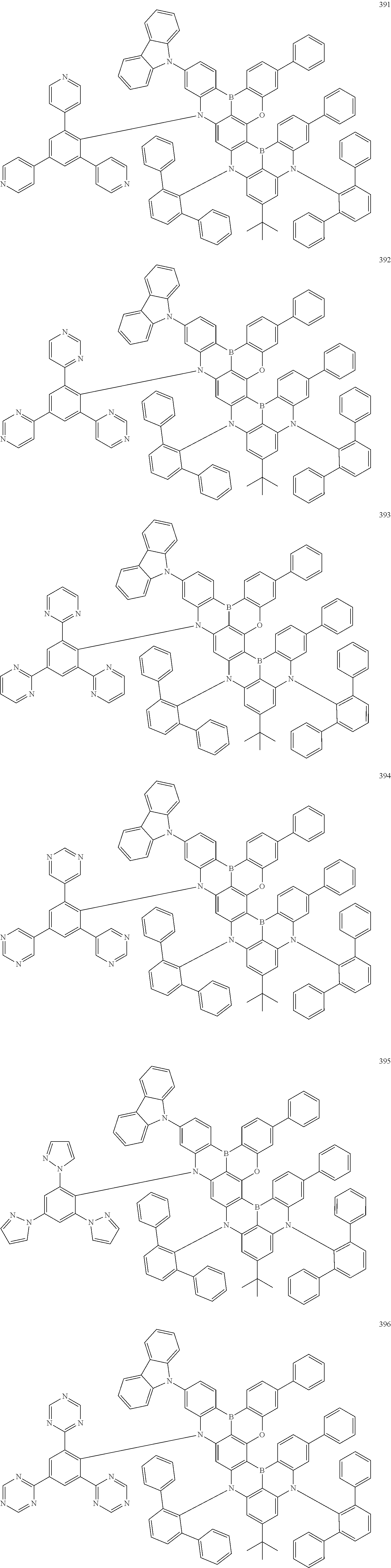 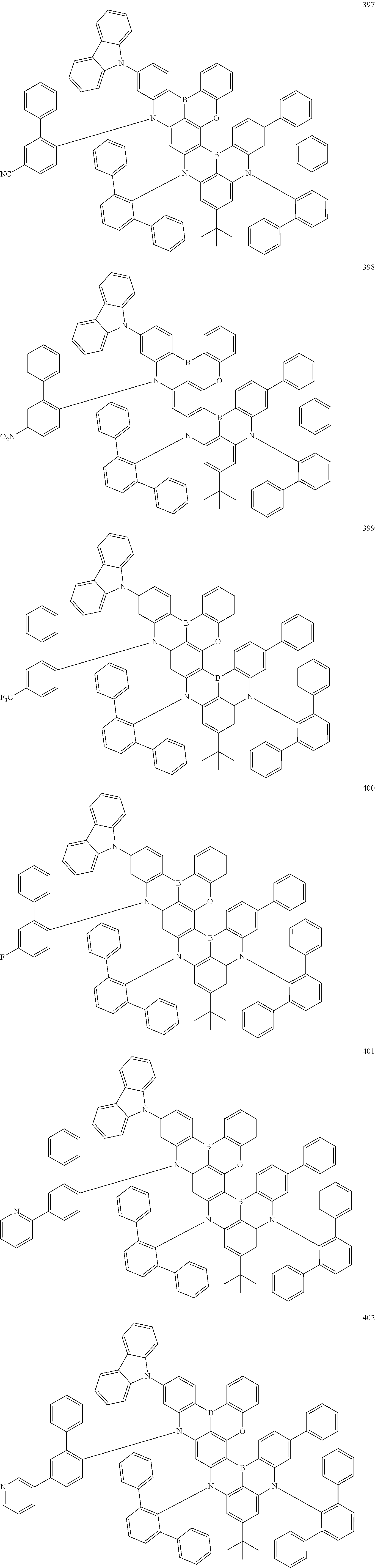 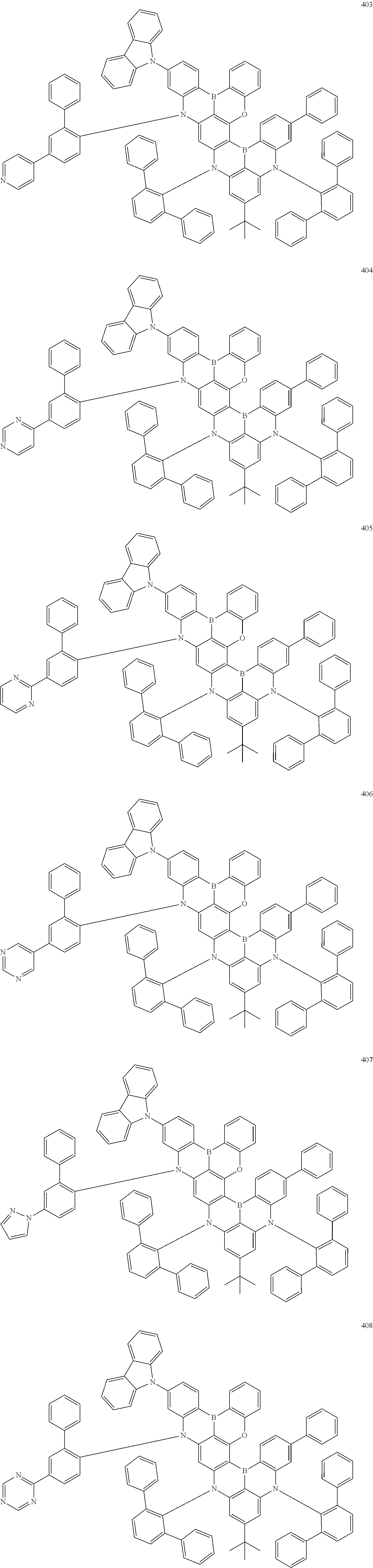 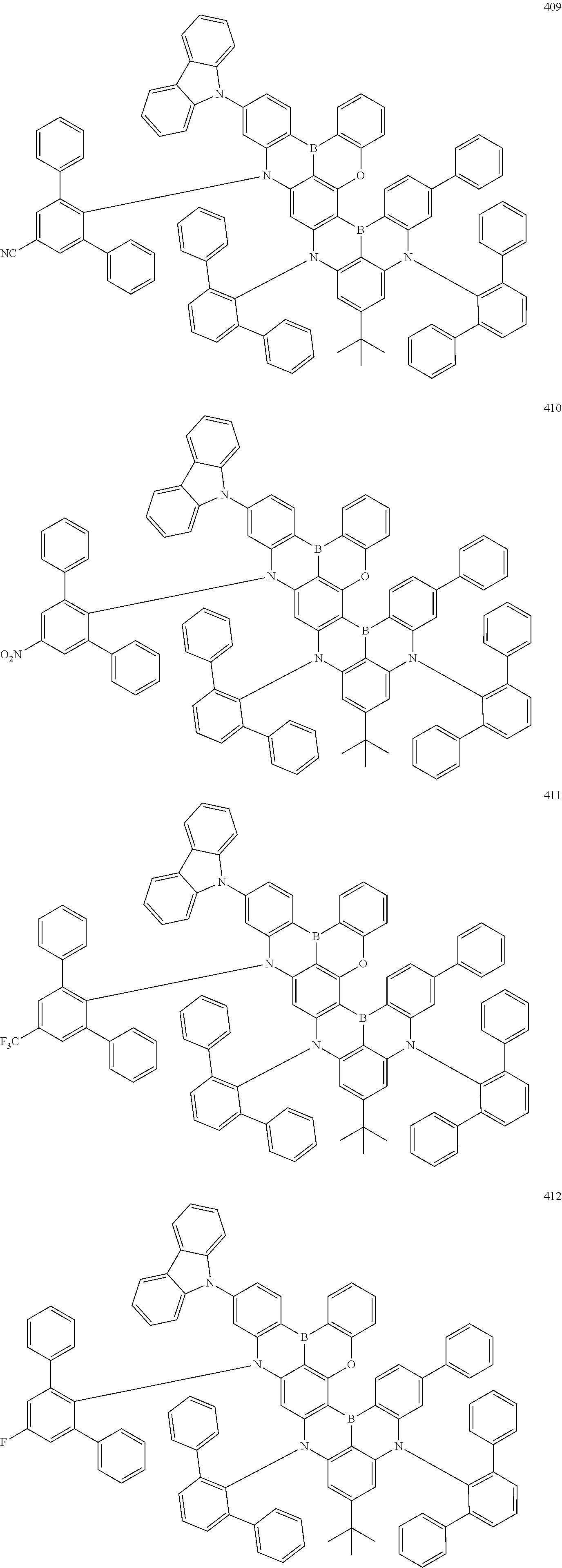 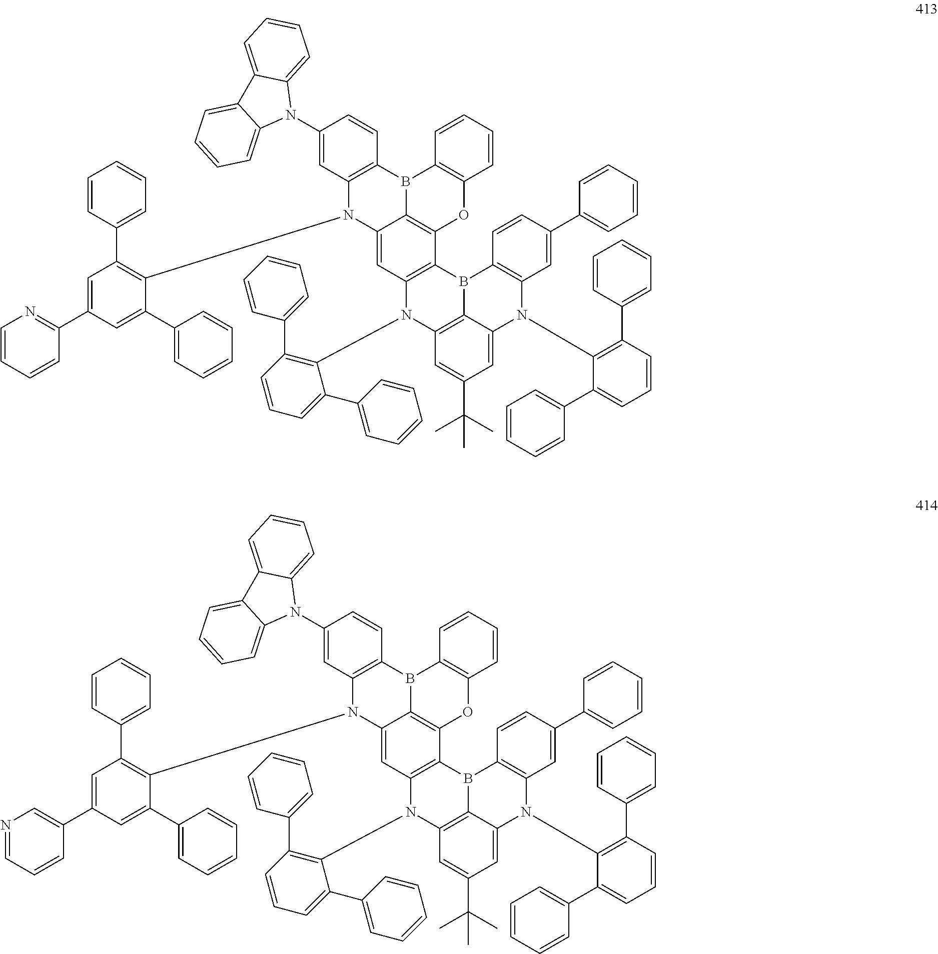 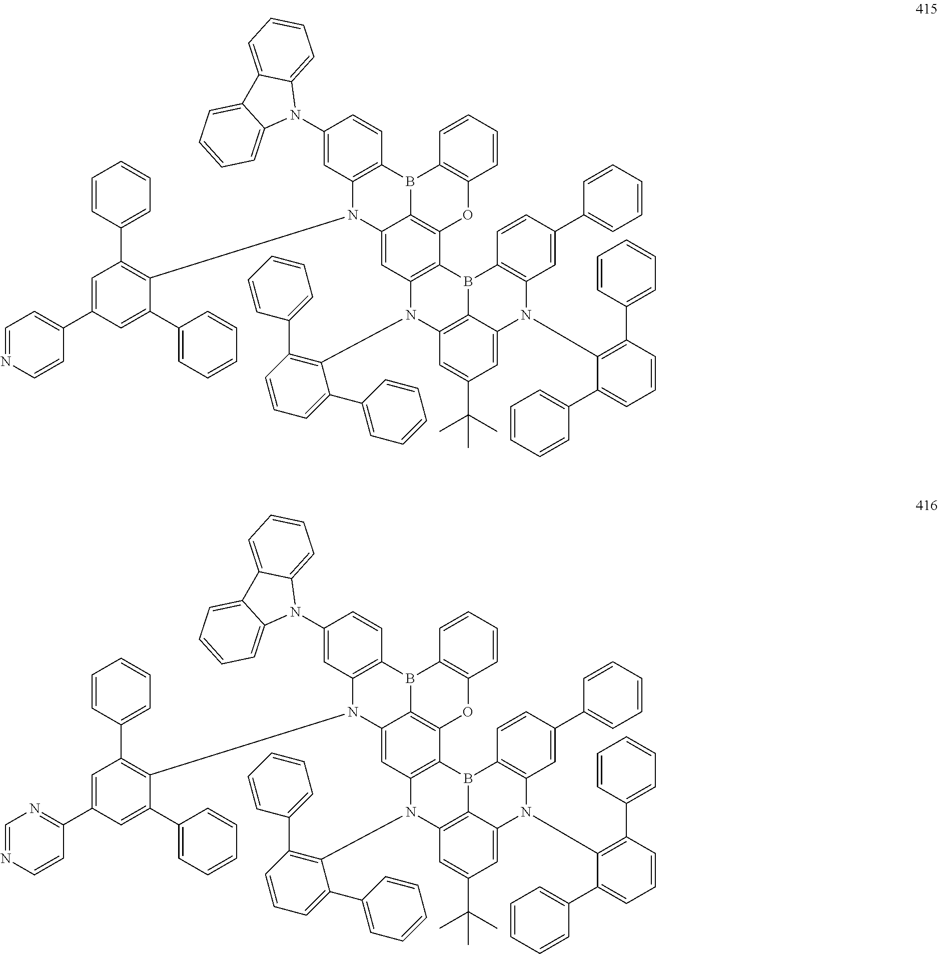 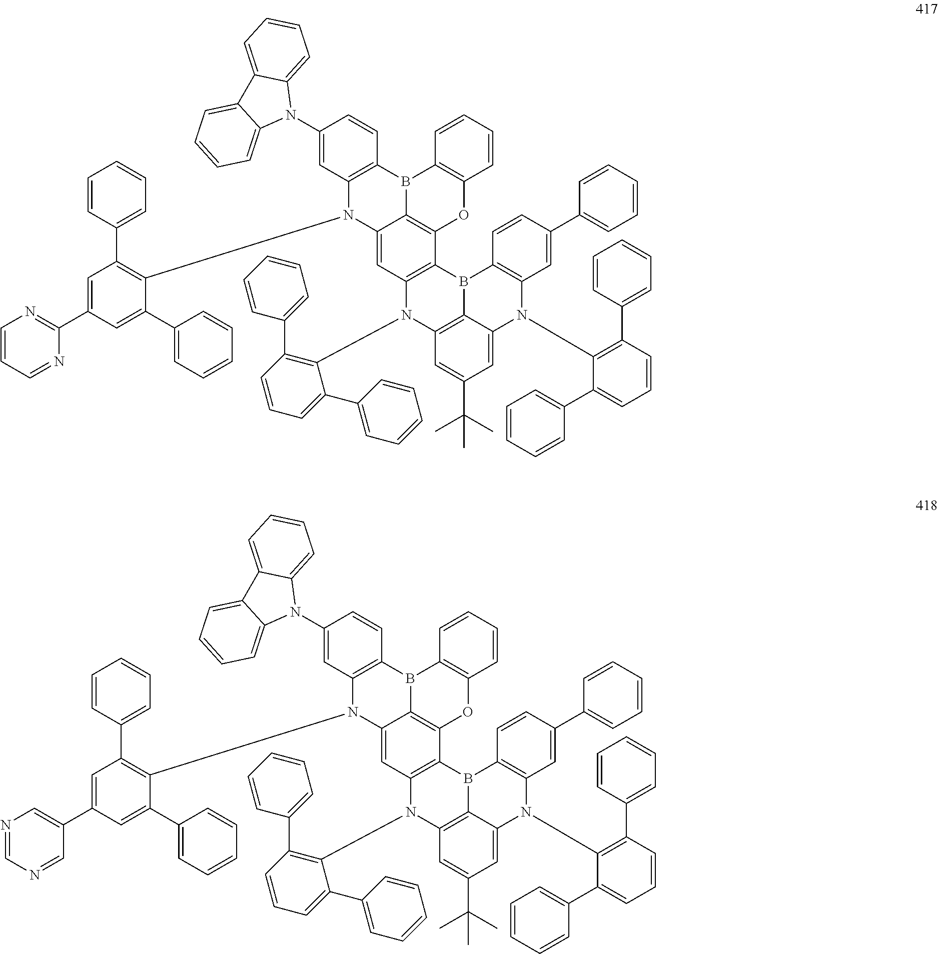 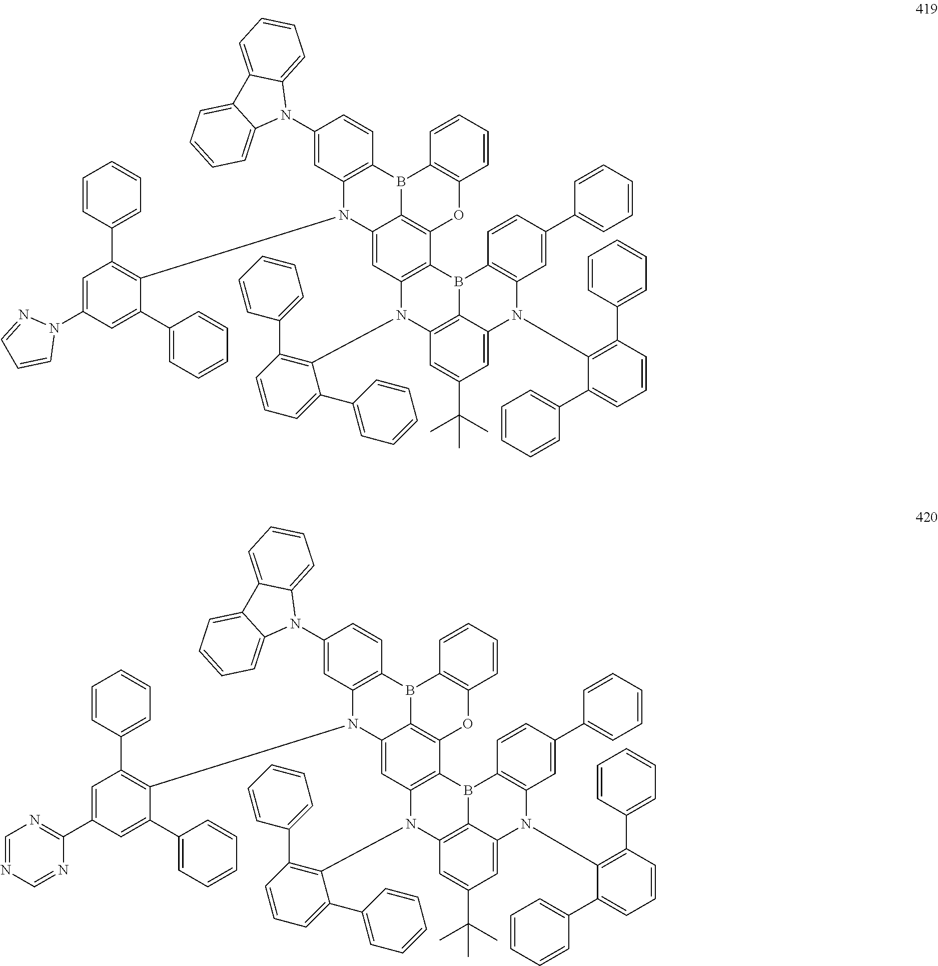 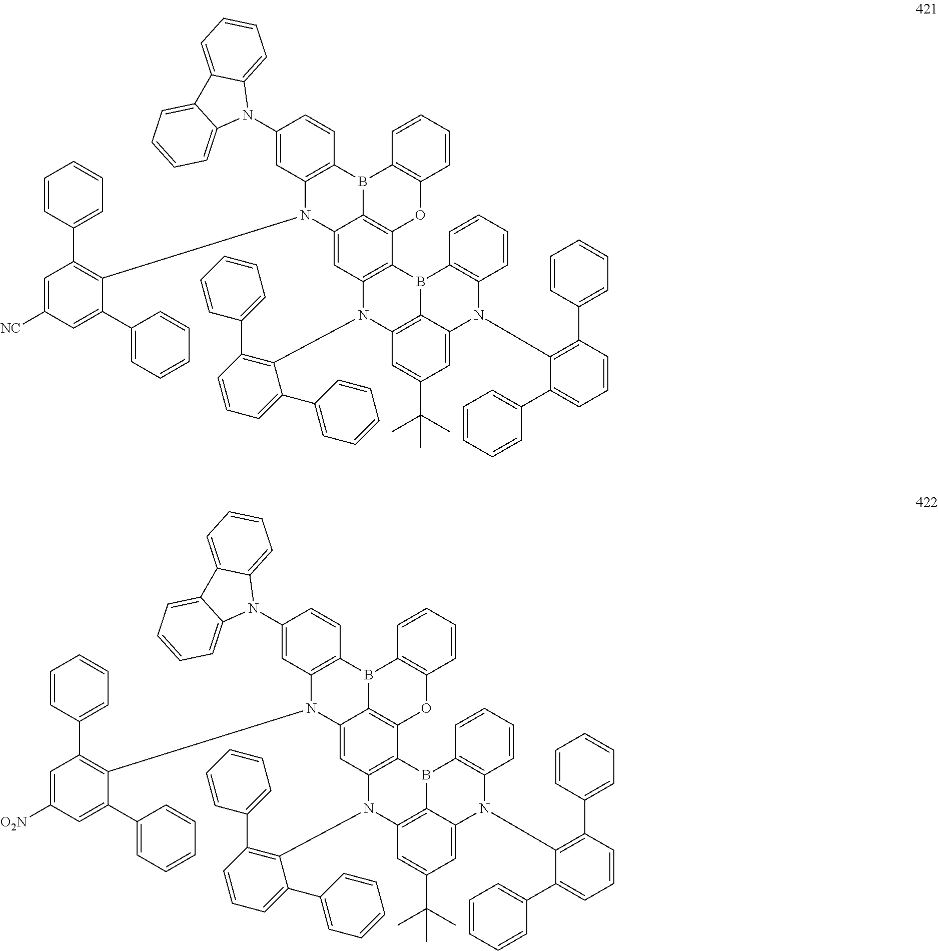 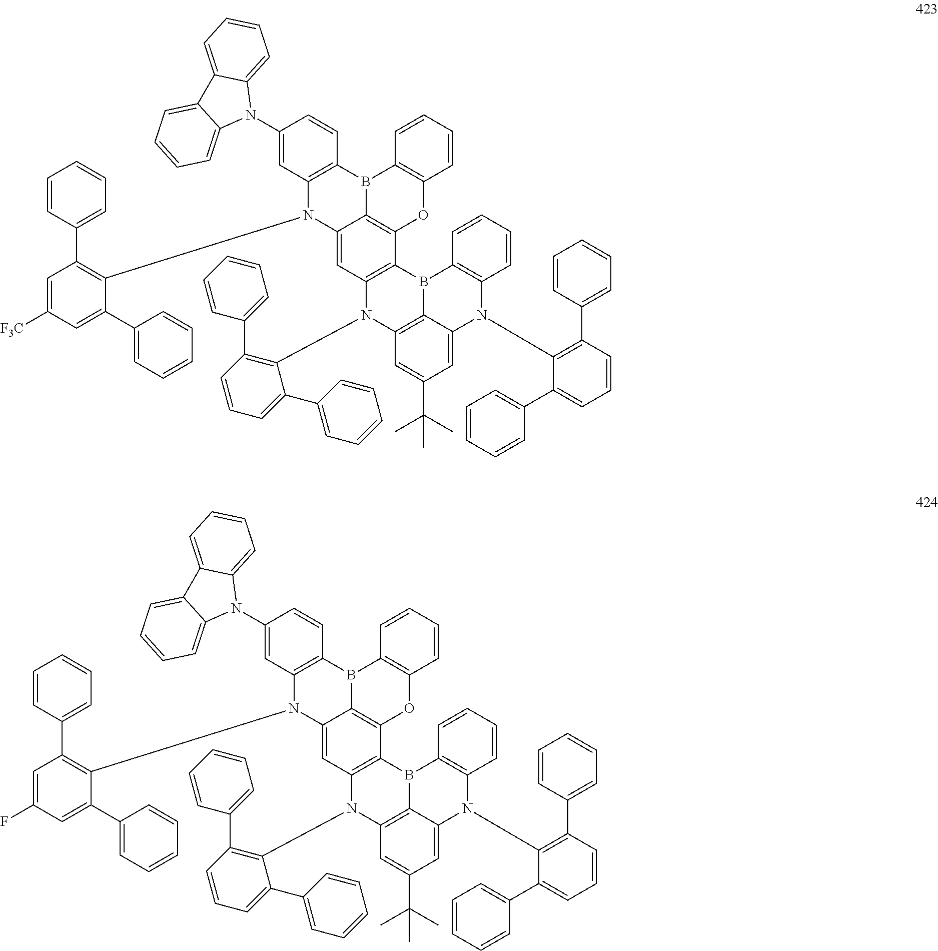 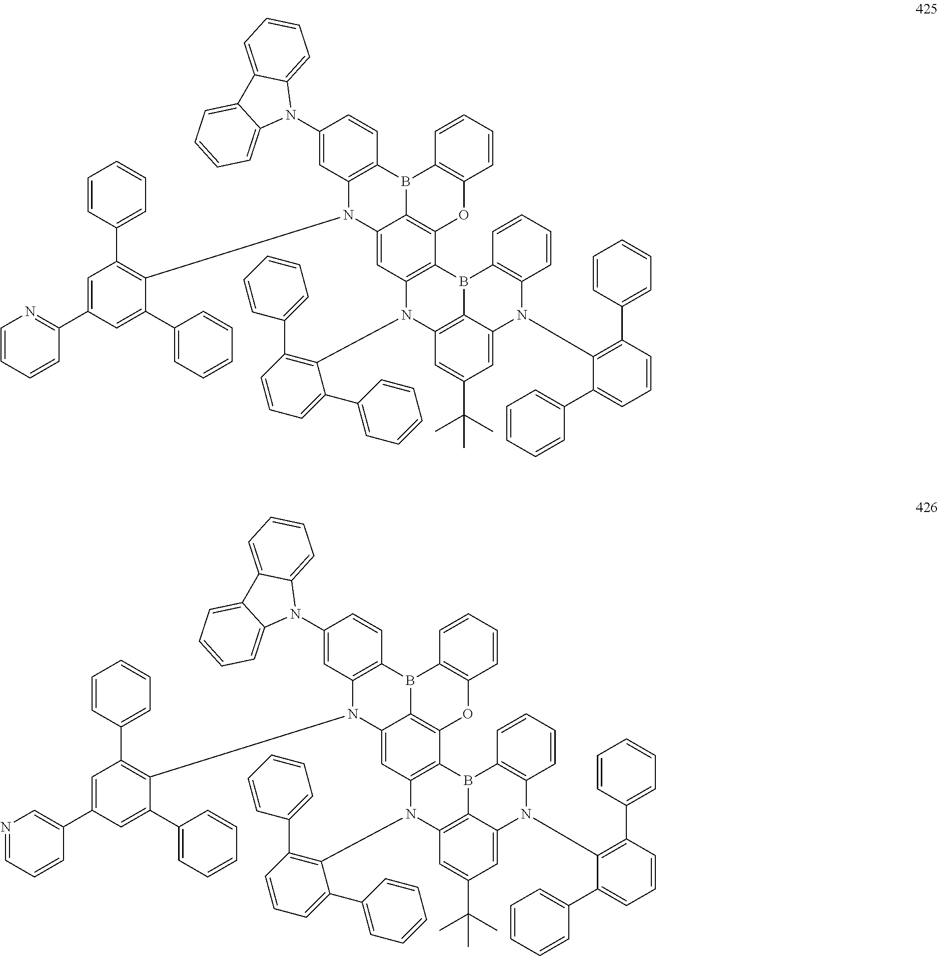 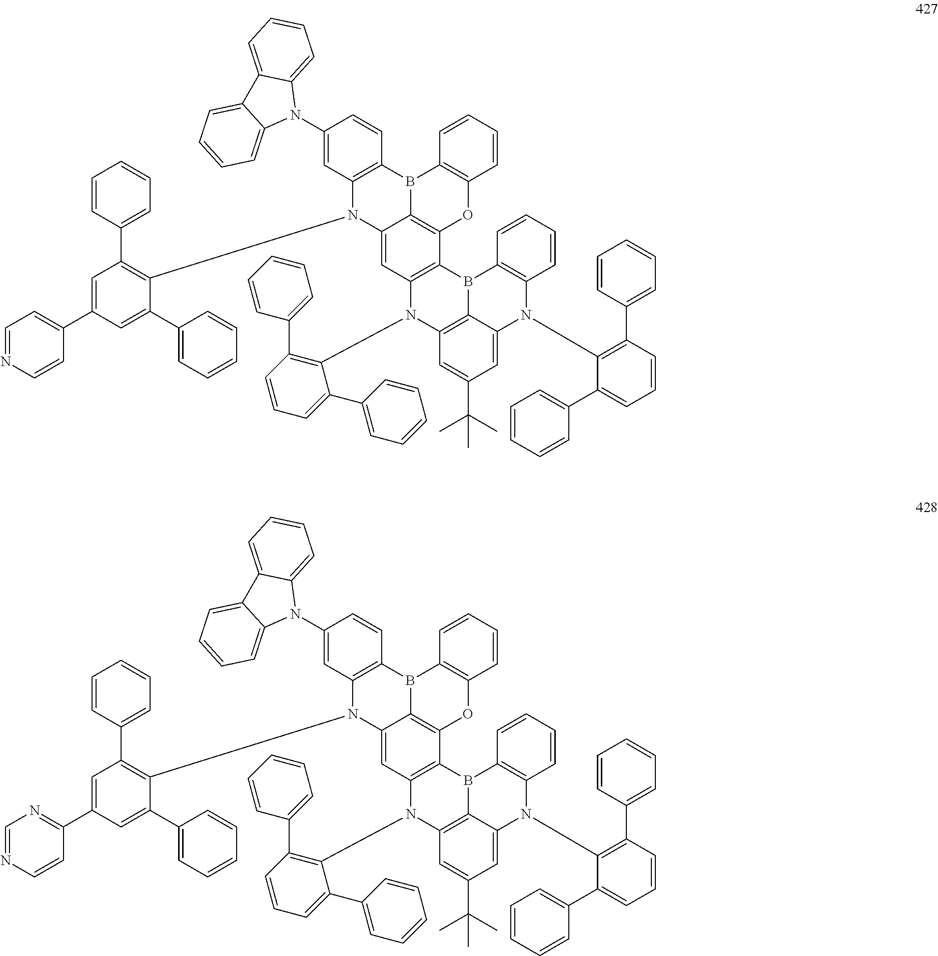 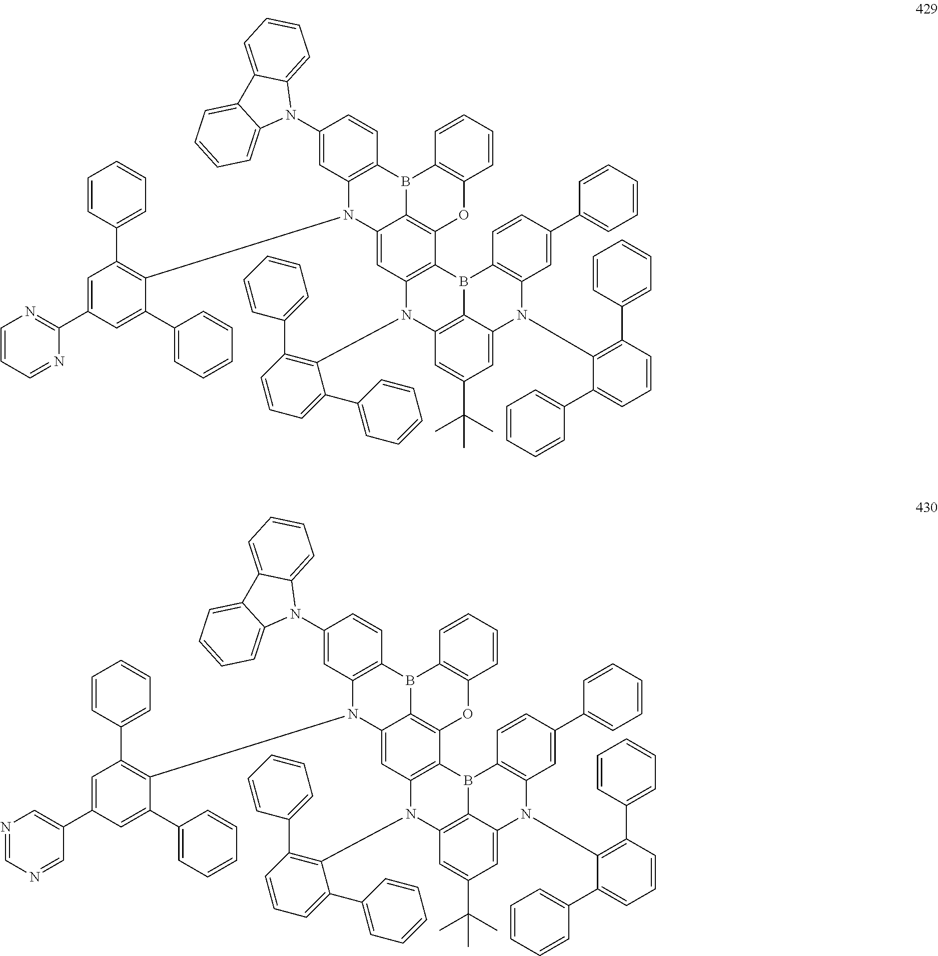 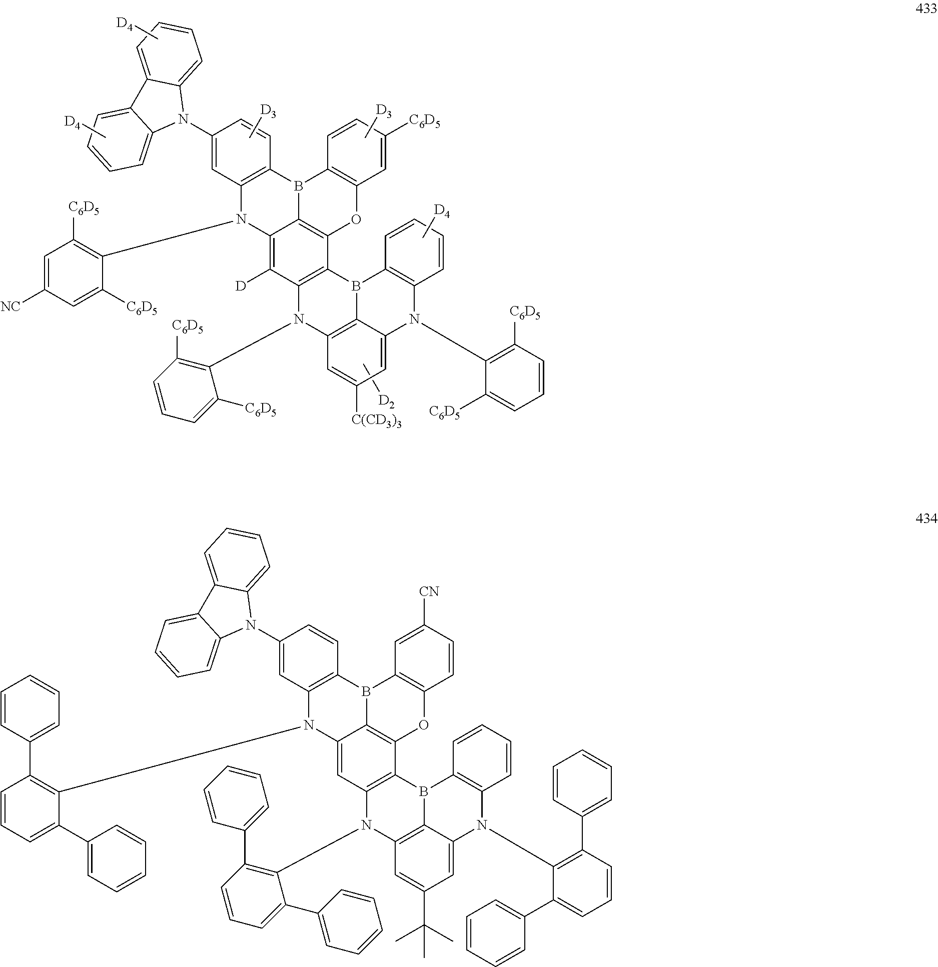 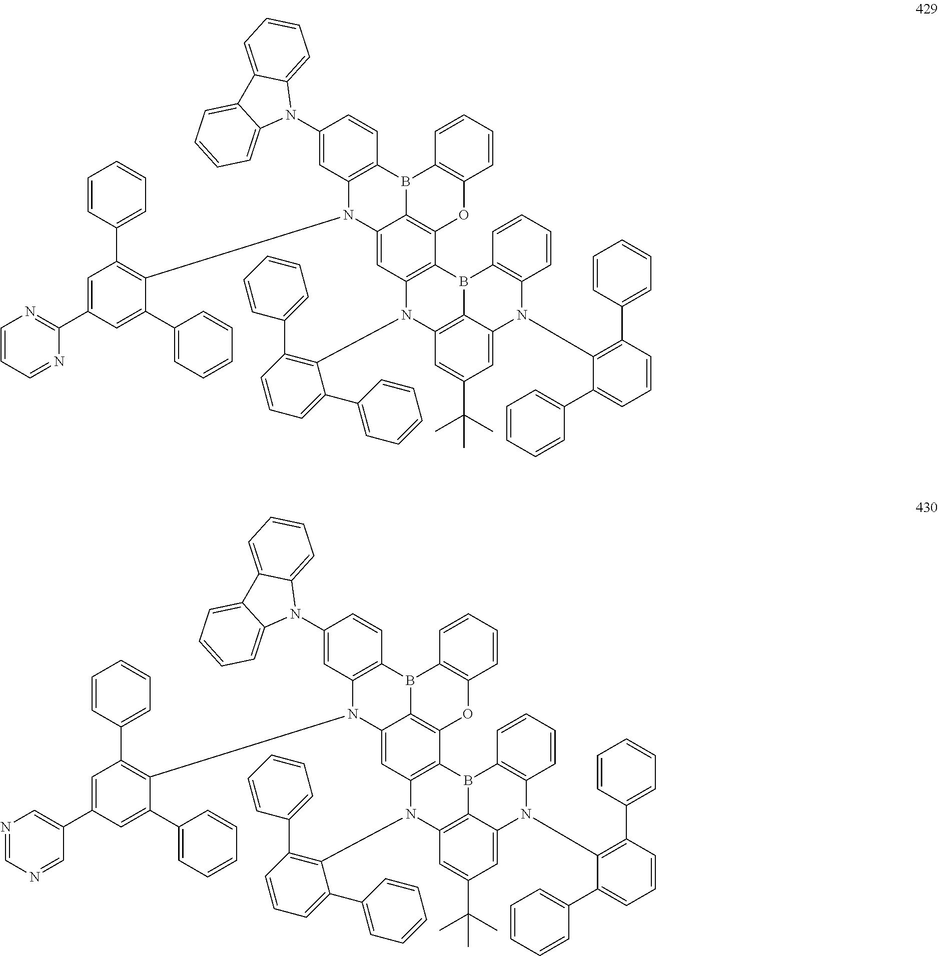 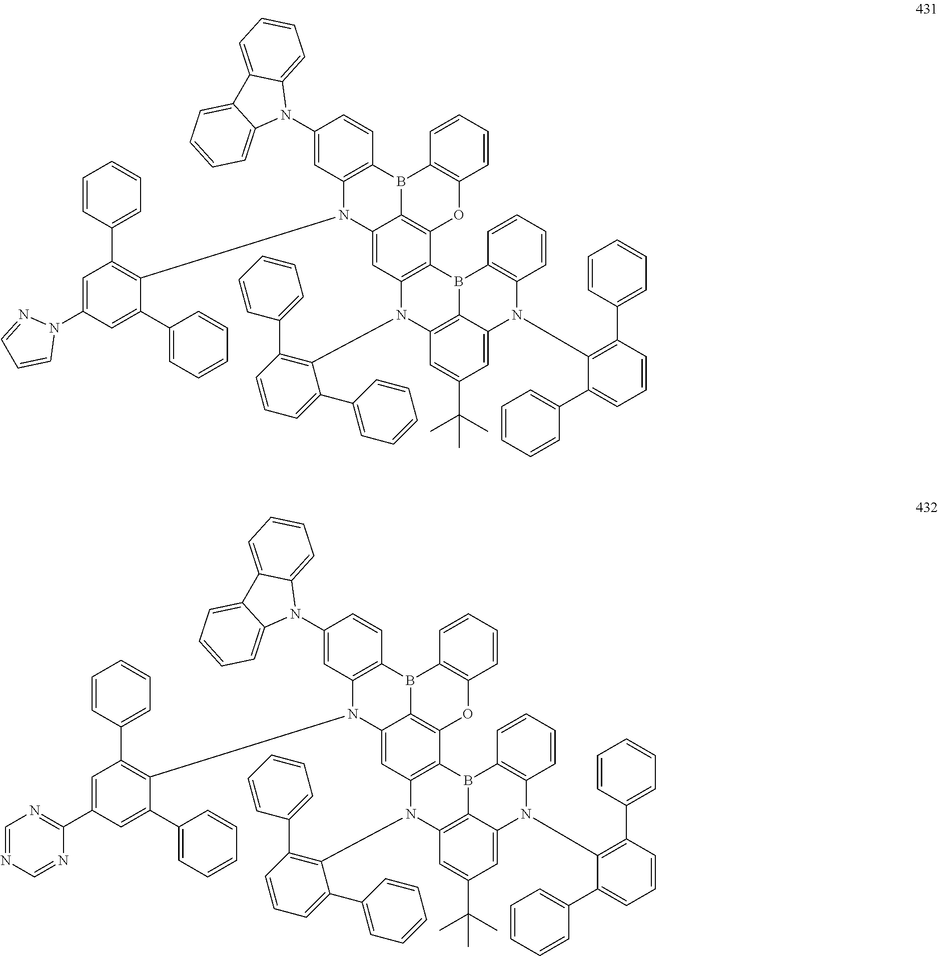 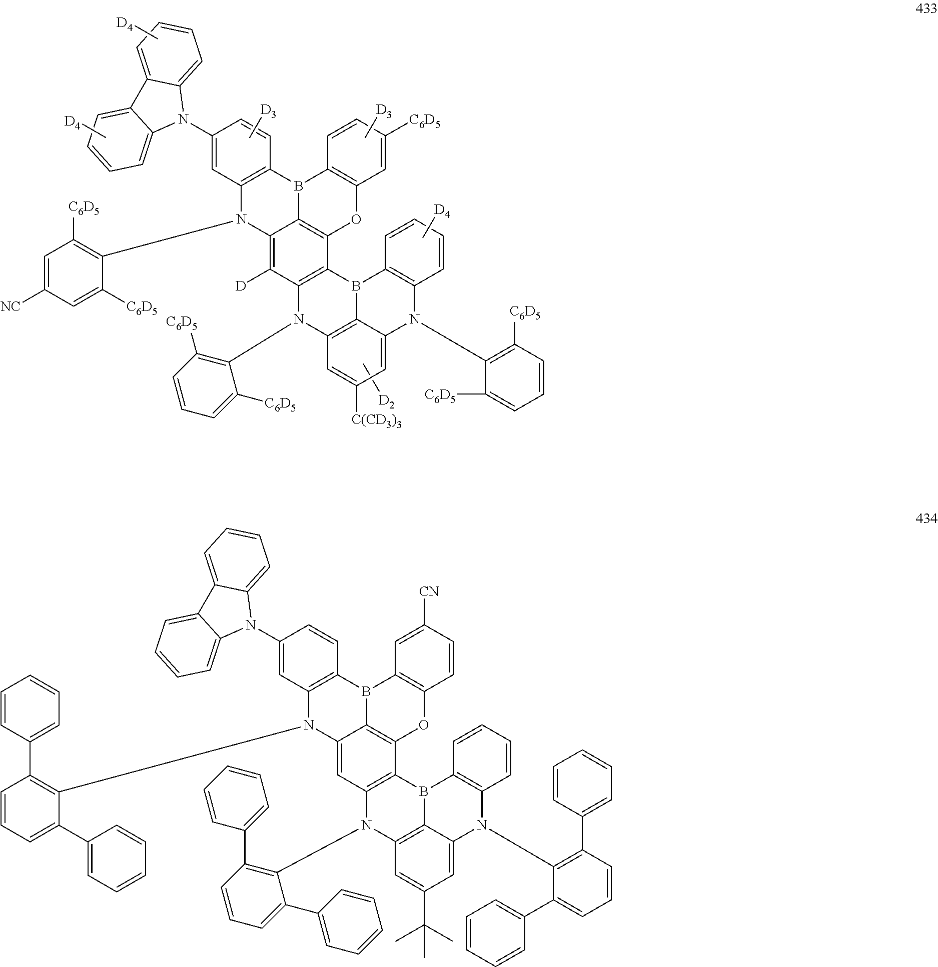
wherein, in Compound Group 1, D is a deuterium atom.

18. An electronic apparatus comprising a display device configured to provide an image,
wherein the display device comprises a base layer, a circuit layer disposed on the base layer, and a display element layer disposed on the circuit layer and comprising a light-emitting element,
the light-emitting element comprises a first electrode, a second electrode disposed on the first electrode, and an emission layer disposed between the first electrode and the second electrode, wherein the emission layer comprises a fused polycyclic compound represented by Formula 1: 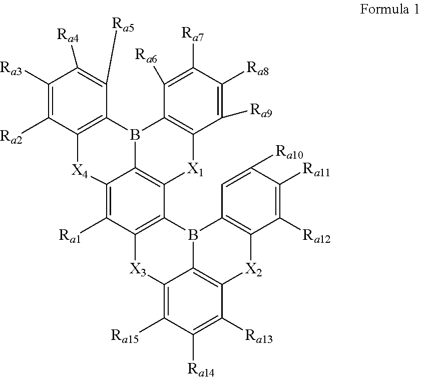
wherein, in Formula 1,
X₁ to X₄ are each independently O, S, or NRₙ, wherein at least one of X₁ to X₄ is NRₙ,
each Rₙ is independently a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, E_{w}, or a group represented by Formula 2,
each E_{w} is independently a fluorine atom, a cyano group, a nitro group, a trifluoromethyl group, a substituted or unsubstituted formyl group, a substituted or unsubstituted pyridine group, a substituted or unsubstituted pyrimidine group, a pyrazole group, or a substituted or unsubstituted triazine group,
Rₐ₁ to Rₐ₉ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w},
adjacent two or more of Rₐ₂ to Rₐ₉ are optionally bonded together to form a ring, and
Rₐ₁₀ to Rₐ₁₅ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms: 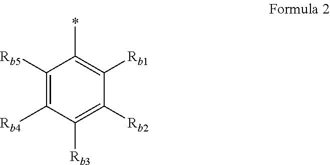
wherein, in Formula 2,
R_{b1} to R_{b5} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or E_{w},
wherein the fused polycyclic compound optionally comprises a deuterium atom,
wherein, the fused polycyclic compound satisfies at least one of Conditions 1 to 3:
Condition 1
at least one Rₙ is E_{w},
Condition 2
at least one Rₙ is represented by Formula 2, and
at least one of R_{b1} to R_{b5} is E_{w},
Condition 3
at least one of Rₐ₁ to Rₐ₉ is E_{w}.

19. The electronic apparatus of claim 18, further comprising at least one of a light control layer or a color filter layer,
wherein the light control layer comprises quantum dots, and the color filter layer comprises a pigment or a dye.

20. The electronic apparatus of claim 18, further comprising at least one of a processor, a memory, or a power module.
